(19) United States
(12) Patent Application Publication
(10) Pub. No.: US 2025/0059222 A1
(43) Pub. Date: Feb. 20, 2025

(54) ORGANIC COMPOUND AND ORGANIC ELECTROLUMINESCENT DEVICE USING SAME

(71) Applicant: SOLUS ADVANCED MATERIALS CO., LTD., Iksan-si, Jeollabuk-do (KR)

(72) Inventors: Minsik EUM, Yongin-si, Gyeonggi-do (KR); Jaeyi SIM, Yongin-si, Gyeonggi-do (KR); Woojae PARK, Yongin-si, Gyeonggi-do (KR); Jinwoong KIM, Yongin-si, Gyeonggi-do (KR); Jeongkeun PARK, Yongin-si, Gyeonggi-do (KR)

(73) Assignee: SOLUS ADVANCED MATERIALS CO., LTD., Iksan-si, Jeollabuk-do (KR)

(21) Appl. No.: 18/695,697

(22) PCT Filed: Sep. 26, 2022
(86) PCT No.: PCT/KR2022/014379

§ 371 Date: Oct. 24, 2024

(30) Foreign Application Priority Data
Sep. 27, 2021 (KR) 10-2021-0127280

(51) Int. Cl. C07F 9/6568; H10K 85/60

(52) U.S. Cl. CPC C07F 9/65685; H10K 85/615; H10K 85/654; H10K 85/656

(57) ABSTRACT

A novel compound and an organic electroluminescent device using the novel compound are disclosed. The compound has excellent electron-transporting capability. Organic electroluminescent devices containing the novel compound in one or more organic layers such as a light-emitting layer, an electron transport layer, or an electron transport auxiliary layer show improved luminous efficiency, driving voltage, lifespan, and the like.

### TECHNICAL FIELD

The present disclosure relates to a novel organic compound and an organic electroluminescent device using the same and, more particularly, to a compound having excellent electron transporting ability and light emitting ability, and an organic electroluminescent device improved in terms of luminous efficiency, driving voltage, life, etc. by including the compound in one or more organic layers.

### BACKGROUND ART

In organic electroluminescent devices (hereinafter, “EL devices”), upon application of voltage between two electrodes, holes are injected from an anode to an organic layer and electrons are injected from a cathode into the organic layer. Injected holes and electrons meet each other to form excitons, and light emission occurs when the excitons fall to a ground state. In this case, materials used for the organic layer may be classified into, for example, luminescent materials, hole injection materials, hole transport materials, electron transport materials and electron injection materials depending on their functions.

Light emitting materials of an organic EL device may be classified into blue, green, and red luminescent materials depending on their emission colors. Furthermore, yellow and orange luminescent materials may be used as a luminescent material for realizing better natural colors. In addition, a host/dopant system may be employed in the luminescent material to increase color purity and luminous efficiency through energy transfer. Dopant materials may be classified into fluorescent dopants using organic materials and phosphorescent dopants using metal complex compounds which include heavy atoms such as Ir and Pt. The developed phosphorescent materials may improve the luminous efficiency theoretically up to four times as compared to fluorescent materials, so attention is given to phosphorescent dopants as well as phosphorescent host materials.

To date, NPB, BCP and Alq₃ are widely known as materials used in the hole injection layer, the hole transporting layer, the hole blocking layer and the electron transporting layer, and anthracene derivatives have been reported as fluorescent dopant/host materials for luminescent materials. Particularly, metal complex compounds including Ir, such as Firpic, Ir(ppy)₃, and (acac) (btp)₂Ir, are known as phosphorescent dopant materials for efficiency improvement among luminescent materials, and they are used as blue, green and red dopant materials. Until now, CBP has shown excellent properties as a phosphorescent host material.

However, conventional materials, despite their good luminescence properties, have low glass transition temperatures and poor thermal stability and thus are not satisfactory in terms of life characteristics of organic EL devices. Accordingly, there is a demand for luminescent materials having excellent thermal stability as well as high luminescence performance.

### DISCLOSURE OF INVENTION

### Technical Problem

The present disclosure is to provide a novel compound that has improved electron injection and transport ability and is superb in thermal stability and electroluminescence and thus can be used as a material for organic layers, particularly for light-emitting layers, electron transport layers, or electron transport auxiliary layers, in an organic electroluminescent device.

In addition, the present disclosure is also to provide an organic electroluminescent device including the novel compound, which exhibits low driving voltage, high efficiency, and enhanced lifespan properties.

### Solution to Problem

To achieve the goals, the present disclosure provides a compound represented by the following chemical formula 1:

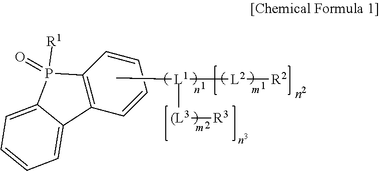

(wherein,
R¹ is selected from the group consisting of an alkyl group of C₁-C₁₂, an aryl group of C₆-C₂₀, and a heteroaryl group of 5 to 20 nuclear atoms,
n¹ is an integer of 0 to 2,
n² and n³ are each 0 or 1, with 1≤n²+n³≤2,
m¹ and m² are each an integer of 0 to 2,
L¹, L², and L³, which are same or different, are each independently an arylene group of C₆-C₁₄ or a heteroarylene group of 3 to 14 nuclear atoms,
R² and R³, which are same or different, are each independently selected from the group consisting of a hydrogen atom, a deuterium atom (D), a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, an arylamine group of C₆-C₆₀, a heteroarylamine group of 5 to 60 nuclear atoms, and an (aryl) (heteroaryl)amine group of (C₆-C₆₀) (5 to 60 nuclear atoms),
the alkyl, aryl, and heteroaryl groups in R¹, the arylene and heteroarylene groups in L¹, L², and L³, and the hydrazino, hydrazono, alkyl, alkenyl, alkynyl, cycloalkyl, heterocycloalkyl, cycloalkenyl, heterocycloalkenyl, aryl, heteroaryl, alkyloxy, aryloxy, alkylsilyl, arylsilyl, alkylboron, arylboron, arylphosphine, arylphosphine oxide, arylamine, heteroarylamine, and (aryl) (heteroaryl)amine groups in R² and R³ are each independently substituted or unsubstituted with one or more substituents selected from the group consisting of the group consisting of a deuterium atom, a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀, wherein, when ex is ting, two or more substituents are same or different).

In addition, the present disclosure provides an organic electroluminescent device including: an anode; a cathode; and one or more layers interposed between the anode and the cathode, wherein at least one of the one or more organic includes the organic compound described above.

The organic layer including the organic compound may be any one selected from the group consisting of a light-emitting layer, an electron transport layer, and an electron transport auxiliary layer.

### Advantageous Effects of Invention

With excellent electron transporting ability and light emitting ability, the compound of the present disclosure can be used as a material for an organic layer in organic electroluminescent devices. Employment of the compound of the present disclosure as any one of host materials, electron transport layer materials, and electron transport auxiliary layer materials allows for the fabrication of an organic electroluminescent device that exhibits lower driving voltage, higher luminous efficiency, and longer lifespan properties than conventional materials and furthermore ensures the provision of an improvement in terms of performance and lifespan for display panels.

### BRIEF DESCRIPTION OF DRAWINGS

FIG. 1 is a schematic cross sectional view of an organic EL device according to a first embodiment of the present disclosure.

FIG. 2 is a schematic cross sectional view of an organic EL device according to a second embodiment of the present disclosure.

FIG. 3 is a schematic cross sectional view of an organic EL device according to a third embodiment of the present disclosure.

### DESCRIPTION OF REFERENCE NUMERALS

100: Anode,
200: Cathode,
300: Organic layer,
310: Hole injection layer,
320: hole transport layer,
330: light-emitting layer,
340: electron transport layer,
350: electron injection layer,
360: electron transport auxiliary layer

### MODE FOR CARRYING OUT THE INVENTION

Below, a detailed description will be given of the present disclosure.

### <Novel Organic Compound>

The present disclosure provides a novel compound with excellent electron transporting ability and light emitting ability, which can be thus used as a high-efficiency material (e.g., host) for a light emitting layer or electron transport layer or electron transport auxiliary layer in organic electroluminescence (EL) devices.

In detail, the compound represented by chemical formula 1 according to the present disclosure is a dibenzophosphole 5-oxide derivative structured to have an alkyl group, aryl group, or heteroaryl group attached to the position 5 thereof and a heteroaryl group and/or an aryl group [e.g., electron withdrawing group (EWG)] introduced through directly or via a linker to a side thereof. Here, dibenzophosphole 5-oxide numbering is as follows:

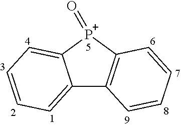 [SMILES: O=[P+]1c2ccccc2-c2ccccc21]

The compound of chemical formula 1 is a dibenzophosphole 5-oxide derivative that is structured to have phosphine oxide introduced into position 5 of the fluorene framework highly capable of electron transport and which has high dipole moment. With excellent electron transporting ability, the compound of the present disclosure can achieve low driving voltage, high efficiency and long lifespan effects when used as a material for light-emitting layers, electron transport layers or electron transport auxiliary layers in organic EL devices.

In addition, the compound of chemical formula 1 not only has conjugated bonds but can also regulate energy levels depending on the type of substituents introduced (e.g., EWG), thus finding applications as a material (e.g., blue, red, green N-type host) in the light-emitting layer of organic electroluminescent devices.

Furthermore, the compound of chemical formula 1 possesses electron-withdrawing properties due to the phosphine oxide part. Therefore, the compound can be used as a material for an auxiliary layer interposed between the light-emitting layer and the electron transport layer (hereinafter referred to as “electron transport auxiliary layer”). Particularly, when the compound of chemical formula 1 is included in the organic EL device as an electron transport auxiliary layer material, the device can experience an increase in light emission and current efficiency due to the triplet-triplet fusion (TTF) effect. Additionally, since the compound of chemical formula 1 can prevent the diffusion of excitons generated in the light-emitting layer to the adjacent electron transport layer, the number of excitons contributing to emission within the light-emitting layer increase, thus bringing about an improvement in luminous efficiency, durability and stability, and lifespan of the device.

Moreover, the compound of the present disclosure is electrochemically stable, has high triplet energy, and exhibits excellent glass transition temperature and thermal stability. Also, because having a higher molecular weight compared to conventional materials for organic EL devices, the compound of the present disclosure boasts superior glass transition temperature and thermal stability.

Furthermore, organic EL devices containing the compound of chemical formula 1 can operate at low voltage, with the resultant improvement in lifespan. The performance of full-color organic light-emitting panels to which such organic EL devices are applied can also be maximized.

In the compound represented by chemical formula 1 according to the present disclosure, R¹ is selected from the group consisting of an alkyl group of C₁-C₁₂, an aryl group of C₆-C₂₀, and an heteroaryl of 5 to 20 nuclear atoms, and specifically, may be selected from the group consisting of an alkyl group of C₁-C₆, an aryl group of C₆-C₁₂, and a heteroaryl group of 5 to 12 nuclear atoms. For example, R¹ may be selected from the group consisting of methyl, ethyl, propyl, butyl, phenyl, biphenyl, naphthyl, pyridine, pyrimidine, and triazine.

The alkyl, aryl, and heteroaryl groups in R¹ may be each independently substituted or unsubstituted with at least one substituent selected from the group consisting of a deuterium, a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀, wherein when two or more substituent, if present, are same or different.

According to R¹, the compound represented by chemical formula 1 may be exemplified by the compounds represented by the following chemical formula 2 or 3, but with no limitations thereto.

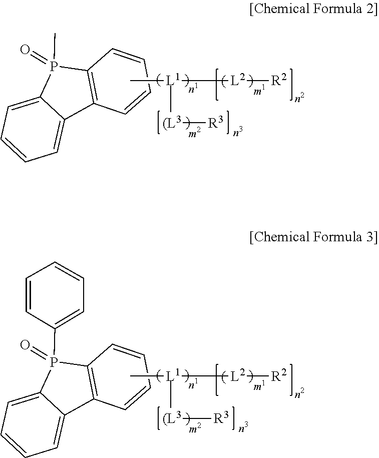

wherein,
n¹, n², n³, m¹, m², L¹, L², L³, R², and R³ are each defined as in chemical formula 1, above.

In the compound represented by chemical formula 1 according to the present disclosure, n¹ is an integer of 0 to 2. Here, when n¹ is 0, L¹ is a direct bond (single bond). When n¹ is 1 or 2, L¹, which serves as a linker, is an arylene group of C₆-C₁₄ or a heteroaryl group of 3 to 14 nuclear atoms. In this regard, n² and n³ are each independently 0 or 1, with the proviso of 1≤n²+n³≤2. According to n² and n³, L¹ may be a divalent or trivalent linker. Two or more L¹, if present, may be same or different.

The arylene and heteroarylene groups of L¹ may be substituted or unsubstituted with at least one substituent selected from the group consisting of a deuterium atom, a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀. In this regard, when two or more substituents ex is t, they may be same or different.

According to an embodiment, L¹ may be a linker selected from the group consisting of the following linkers L1-1 to L1-12:

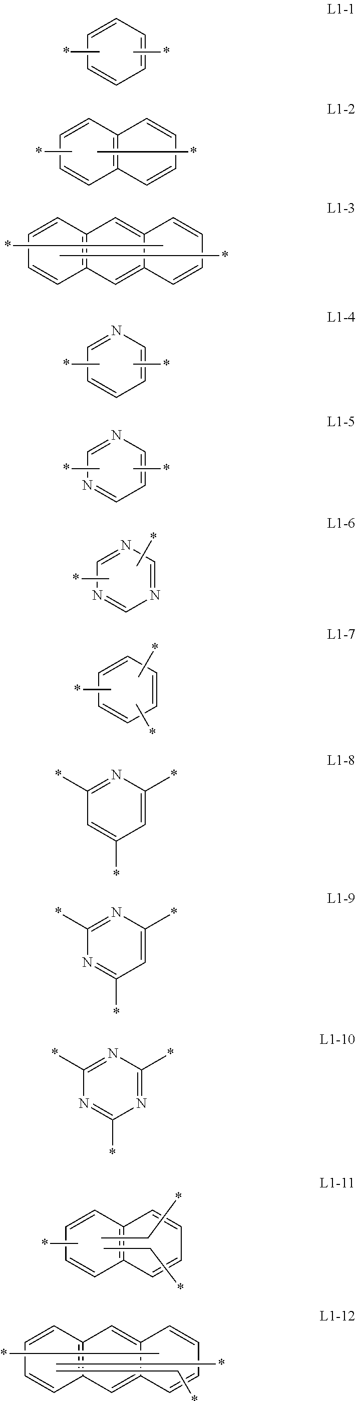

wherein,
* denotes a site where is combined with the dibenzophosphole 5-oxide moiety

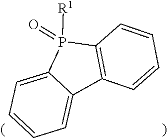

and L² in chemical formula 1.

The hydrogen atoms of the linkers L1-1 to L1-12 may be substituted or unsubstituted with at least one substituent selected from the group consisting of a deuterium atom (D), a halogen group, a cyano group, a nitro group, an alkyl group of C₁-C₁₂, an aryl group of C₆-C₁₀, and a heteroaryl group of 5-10 nuclear atoms.

According to n² and n³, the compound represented by chemical formula 1 may be exemplified by the compound represented by the following chemical formula 4 or 5, but with no limitations to:

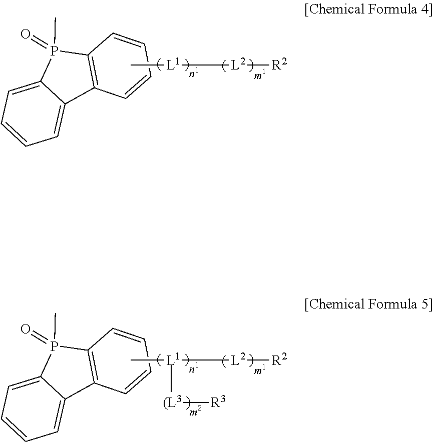

wherein,
n¹, m¹, m², L¹, L², L³, R², and R³ are each defined as in chemical formula 1, above.

In the compound represented by chemical formula 1 according to the present disclosure, m¹ and m² are each an integer of 0 to 2. Here, when m¹ is 0, L² is a direct bond (single bond). When m¹ is 1 or 2, L², which serves as a divalent linker, is an arylene group of C₆-C₁₄ or a heteroaryl group of 3 to 14 nuclear atoms. When m² is 0, L³ is a direct bond (single bond). When m² is 1 or 2, L³, which serves as a divalent linker, is an arylene group of C₆-C₁₄ or a heteroaryl group of 3 to 14 nuclear atoms. In this regard, L² and L³ may be same or different.

The arylene and heteroarylene groups of L² and L³ may be substituted or unsubstituted with at least one substituent selected from the group consisting of a deuterium atom, a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀. Two or more substituents, if present, may be same or different.

According to an embodiment, L² and L³, which are same or different, may each be independently a linker selected from the group consisting of the following linkers L²-1 to L²-6:

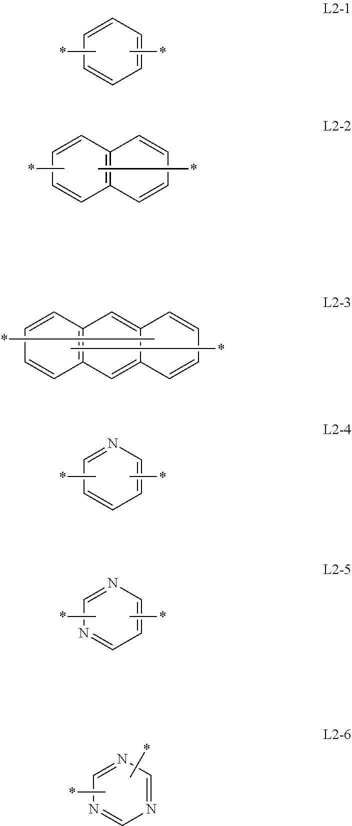

wherein,
* denotes a site where is combined with L¹ and R² in chemical formula 1.

The hydrogen atoms of the linkers L²-1 to L²-6 may be substituted or unsubstituted with at least one substituent selected from the group consisting of a deuterium atom (D), a halogen group, a cyano group, a nitro group, an alkyl group of C₁-C₁₂, an aryl group of C₆-C₁₀, and a heteroaryl group of 5-10 nuclear atoms.

In the compound represented by chemical formula 1 according to the present disclosure, R² and R³ are same or different and are each independently selected from the group consisting of a hydrogen atom, a deuterium atom (D), a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, an arylamine group of C₆-C₆₀, a heteroarylamine group of 5 to 60 nuclear atoms, and an (aryl) (heteroaryl)amine group of (C₆-C₆₀) (5 to 60 nuclear atoms) and specifically, may be selected from the group consisting of a hydrogen atom, a deuterium atom (D), a halogen group, a hydroxy group, a cyano group, a nitro group, an amino group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, and a heteroaryl group of 5 to 60 nuclear atoms.

The hydrazino, hydrazono, alkyl, alkenyl, alkynyl, cycloalkyl, heterocycloalkyl, cycloalkenyl, heterocycloalkenyl, aryl, heteroaryl, alkyloxy, aryloxy, alkylsilyl, arylsilyl, alkylboron, arylboron, arylphosphine, arylphosphine oxide, arylamine, heteroarylamine, and (aryl) (heteroaryl)amine groups of R² and R³ are each independently substituted or unsubstituted with at least one substituent selected from the group consisting of a deuterium atom, a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀. In this regard, two or more substituents are same or different.

According to an embodiment, R² and R³ are same or different and may each be independently any one of the substituents represented by the following chemical formulas a to j, but with no limitations thereto:

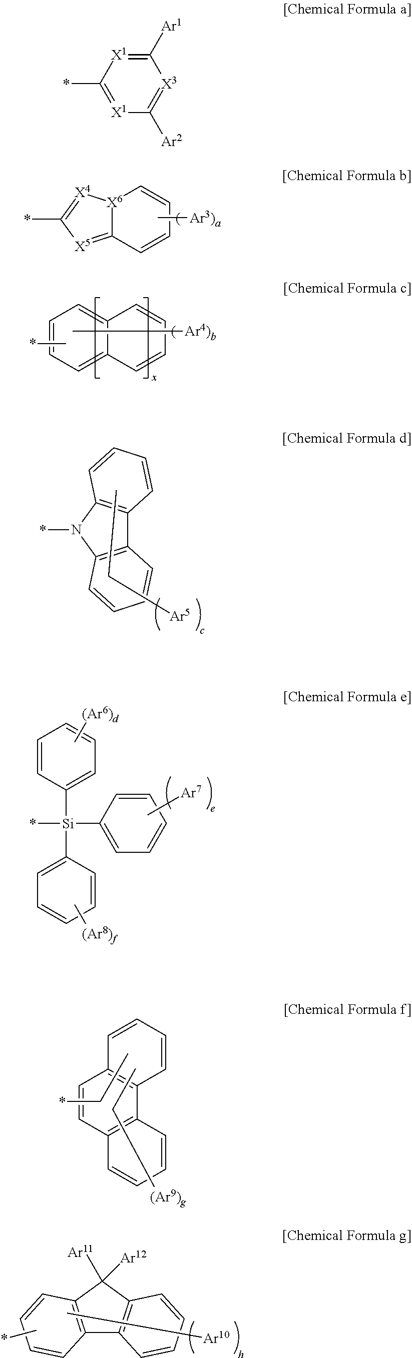

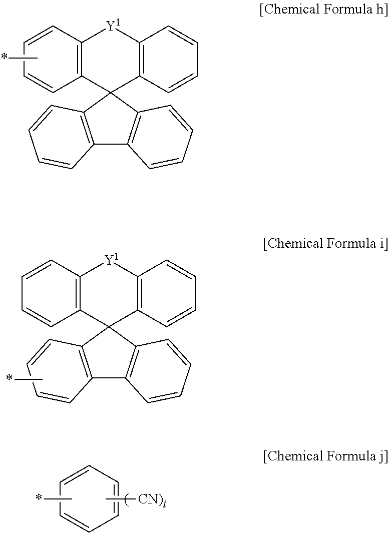

X¹ to X³ are same or different and are each independently N or C(Ar¹³), with a proviso that at least one of X¹ to X³ is N,
X⁴ to X⁶ are same or different and are each independently N or C(Ar¹⁴), with a proviso that at least one of X⁴ to X⁶ is N,
a is an integer of 0 to 4,
b and h are each an integer of 0 to 7,
x is 0 or 1,
c and g are each an integer of 0 to 8,
d, e, f, and I are each an integer of 0 to 5,
Y¹ and Y² are each independently O or S, and
Ar¹ to Ar¹⁴ are same or different and are each independently selected from the group consisting of a hydrogen atom, a deuterium atom, a halogen group, a cyano group, a nitro group, an amino group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀,
the alkyl, alkenyl, alkynyl, cycloalkyl, heterocycloalkyl, aryl, heteroaryl, alkyloxy, aryloxy, alkylsilyl, arylsilyl, alkylboron, arylboron, arylphosphine, arylphosphine oxide, and arylamine groups of Ar¹ to Ar¹⁴ are each independently substituted or unsubstituted with one or more substituents selected from the group consisting of a deuterium atom, a halogen group, a cyano group, a nitro group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀. In this regard, two or more substituents, if present, are same or different.

According to R² and R³, the compound represented by chemical formula 1 is exemplified by the compound represented by any one of the following chemical formulas 6 to 10, but with no limitations thereto:

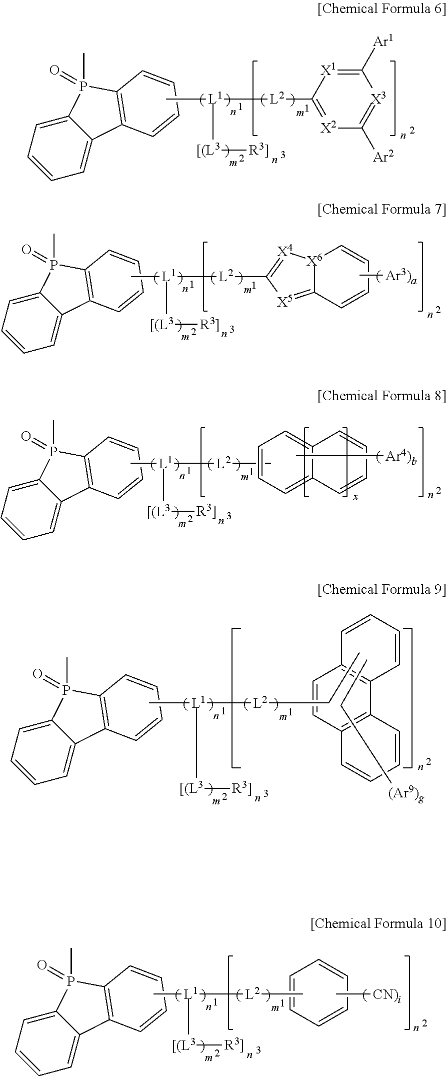

wherein,
n¹, n², n³, m¹, m², L¹, L², L³, and R³ are each defined as in chemical formula 1, and
X¹ to X⁶, a, b, g, i, x, Ar¹ to Ar⁴, and Ar⁹ are each defined as in chemical formulas a to j.

In detail, examples of the compound represented by chemical formula 1 include, but are not limited to, the compounds of the following chemical formulas 11 to 30:

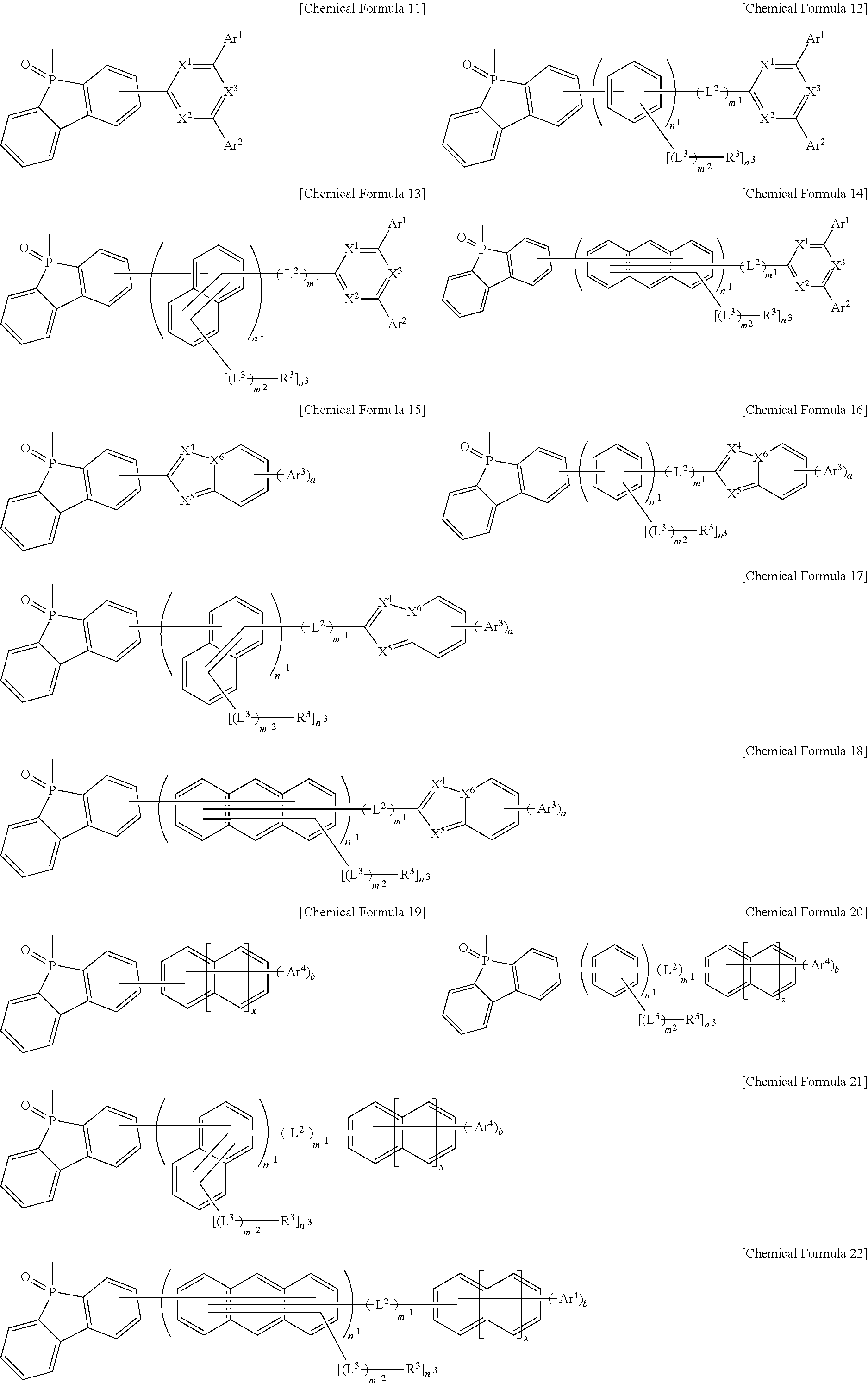

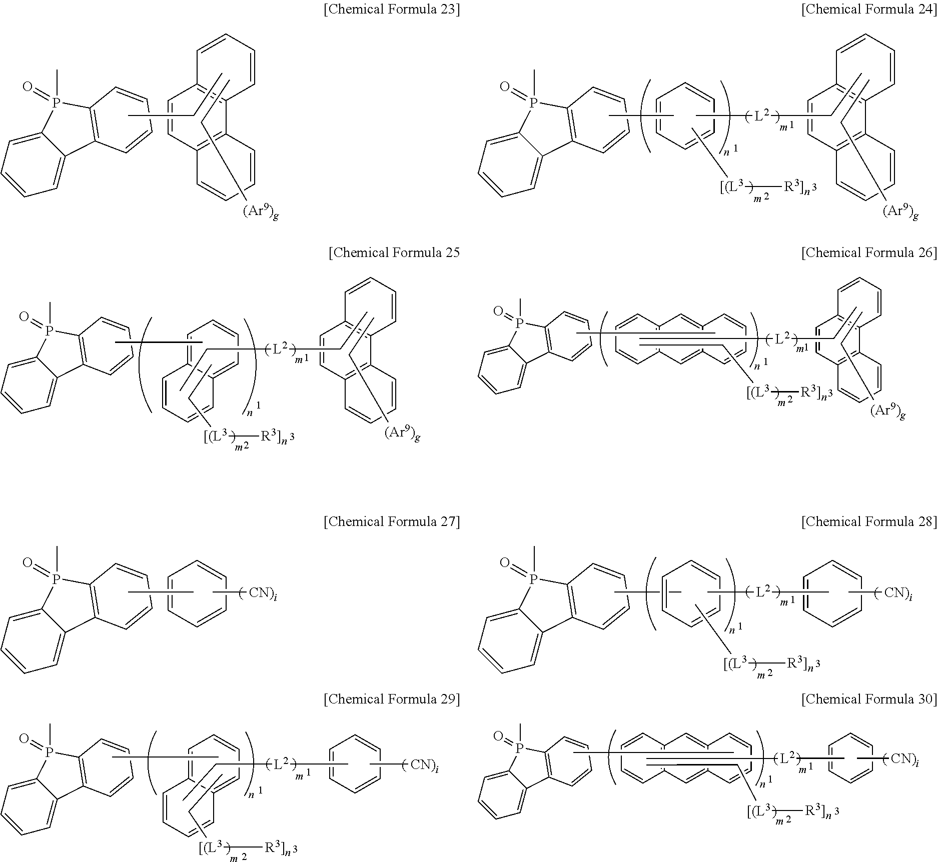

wherein,
n¹, n³, m¹, m², L², L³, and R³ are defined as in chemical formula 1, and
X¹ to X⁶, a, b, g, i, x, Ar¹ to Ar⁴, and Ar⁹ are defined as in chemical formulas a to j.

The compound represented by chemical formula 1 according to the present disclosure may be embodied by any one of the following compounds A-1 to D-48, but is not limited to:

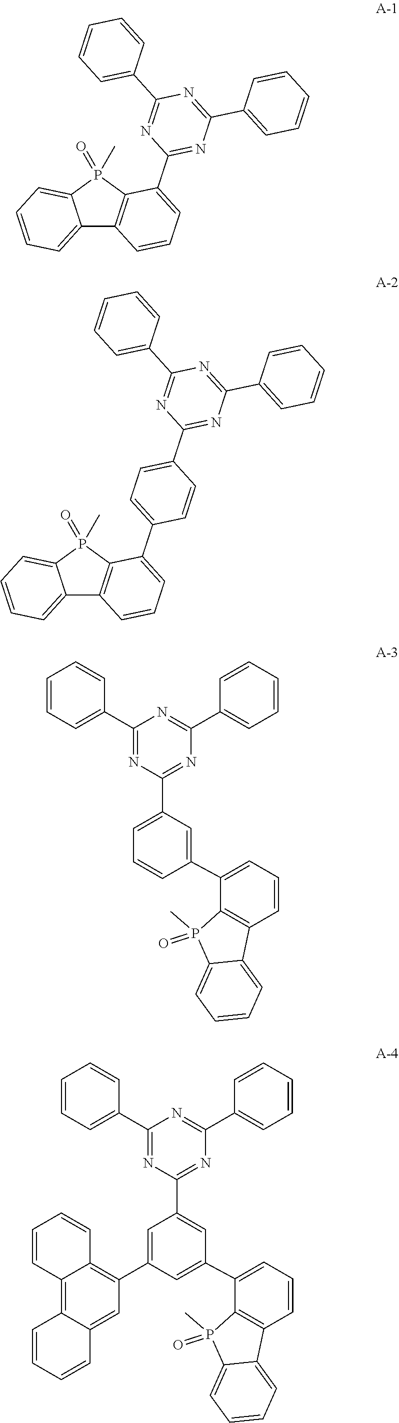

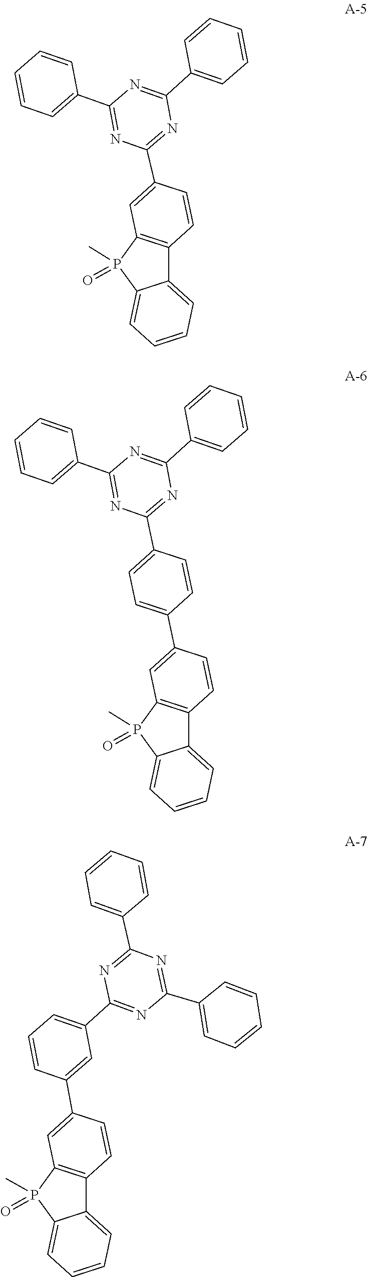 [SMILES: CP1(=O)c2ccccc2-c2ccc(-c3nc(-c4ccccc4)nc(-c4ccccc4)n3)cc21 ; CP1(=O)c2ccccc2-c2ccc(-c3ccc(-c4nc(-c5ccccc5)nc(-c5ccccc5)n4)cc3)cc21 ; CP1(=O)c2ccccc2-c2ccc(-c3cccc(-c4nc(-c5ccccc5)nc(-c5ccccc5)n4)c3)cc21]

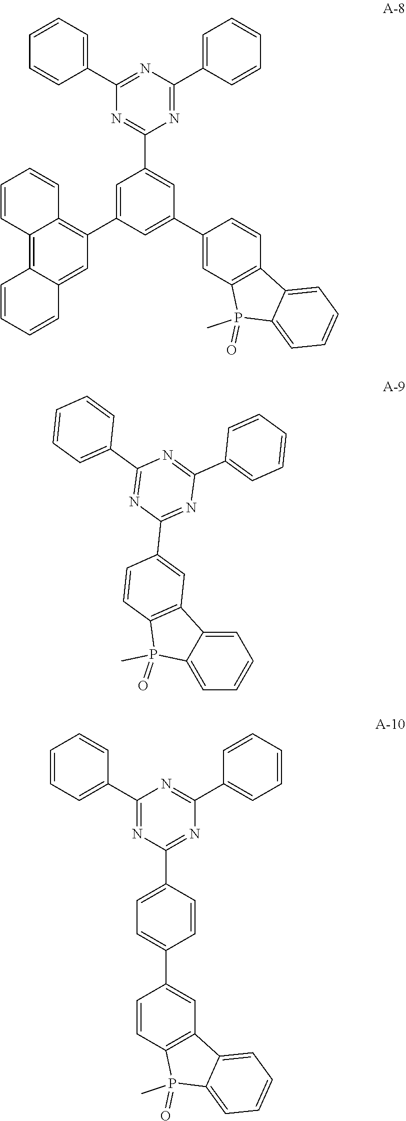 [SMILES: CP1(=O)c2ccccc2-c2ccc(-c3cc(-c4nc(-c5ccccc5)nc(-c5ccccc5)n4)cc(-c4cc5ccccc5c5ccccc45)c3)cc21 ; CP1(=O)c2ccccc2-c2cc(-c3nc(-c4ccccc4)nc(-c4ccccc4)n3)ccc21 ; CP1(=O)c2ccccc2-c2cc(-c3ccc(-c4nc(-c5ccccc5)nc(-c5ccccc5)n4)cc3)ccc21]

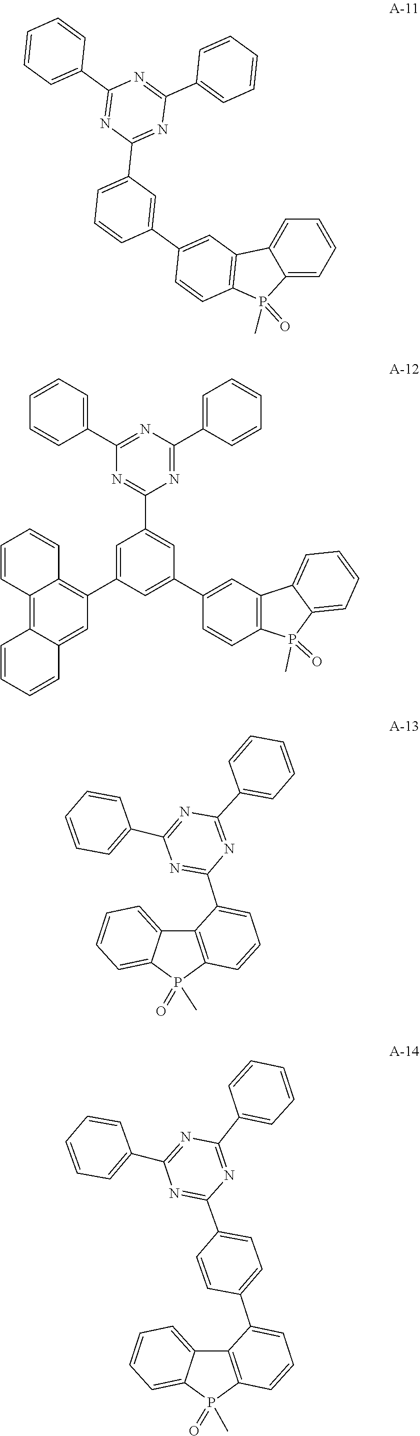 [SMILES: CP1(=O)c2ccccc2-c2cc(-c3cccc(-c4nc(-c5ccccc5)nc(-c5ccccc5)n4)c3)ccc21 ; CP1(=O)c2ccccc2-c2cc(-c3cc(-c4nc(-c5ccccc5)nc(-c5ccccc5)n4)cc(-c4cc5ccccc5c5ccccc45)c3)ccc21 ; CP1(=O)c2ccccc2-c2c(-c3nc(-c4ccccc4)nc(-c4ccccc4)n3)cccc21 ; CP1(=O)c2ccccc2-c2c(-c3ccc(-c4nc(-c5ccccc5)nc(-c5ccccc5)n4)cc3)cccc21]

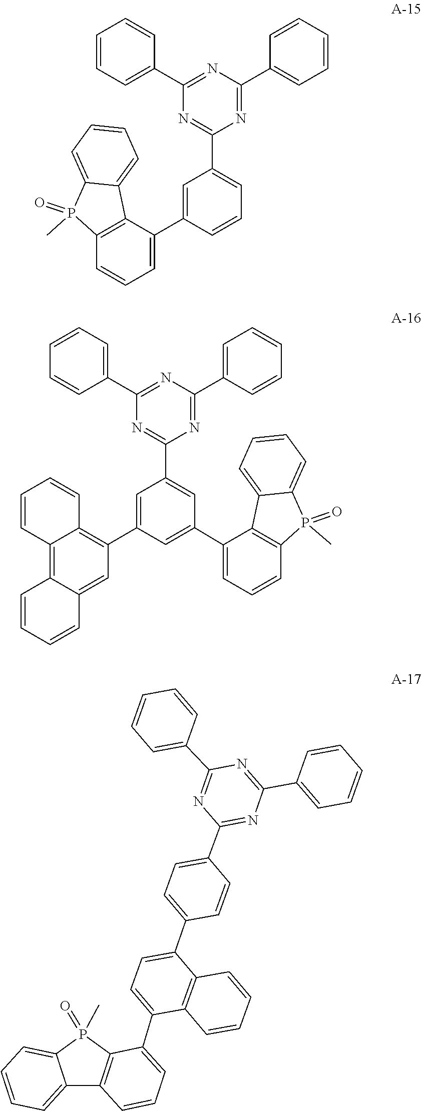 [SMILES: CP1(=O)c2ccccc2-c2c(-c3cccc(-c4nc(-c5ccccc5)nc(-c5ccccc5)n4)c3)cccc21 ; CP1(=O)c2ccccc2-c2c(-c3cc(-c4nc(-c5ccccc5)nc(-c5ccccc5)n4)cc(-c4cc5ccccc5c5ccccc45)c3)cccc21 ; CP1(=O)c2ccccc2-c2cccc(-c3ccc(-c4ccc(-c5nc(-c6ccccc6)nc(-c6ccccc6)n5)cc4)c4ccccc34)c21]

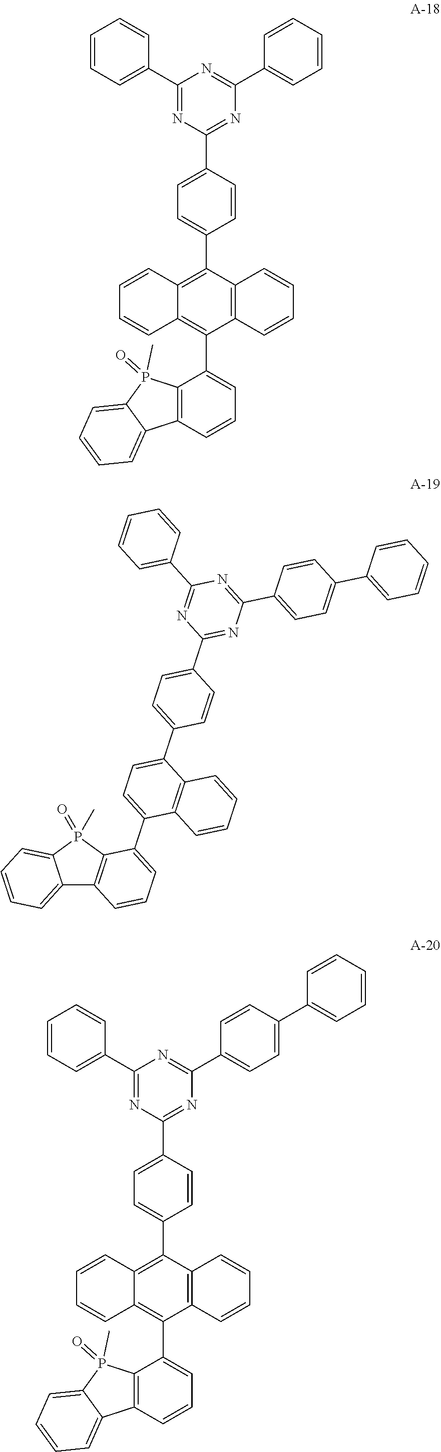 [SMILES: CP1(=O)c2ccccc2-c2cccc(-c3c4ccccc4c(-c4ccc(-c5nc(-c6ccccc6)nc(-c6ccccc6)n5)cc4)c4ccccc34)c21 ; CP1(=O)c2ccccc2-c2cccc(-c3ccc(-c4ccc(-c5nc(-c6ccccc6)nc(-c6ccc(-c7ccccc7)cc6)n5)cc4)c4ccccc34)c21 ; CP1(=O)c2ccccc2-c2cccc(-c3c4ccccc4c(-c4ccc(-c5nc(-c6ccccc6)nc(-c6ccc(-c7ccccc7)cc6)n5)cc4)c4ccccc34)c21]

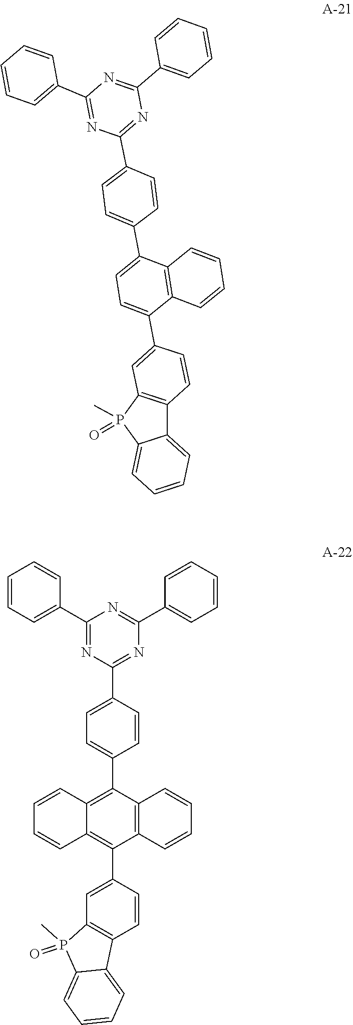 [SMILES: CP1(=O)c2ccccc2-c2ccc(-c3ccc(-c4ccc(-c5nc(-c6ccccc6)nc(-c6ccccc6)n5)cc4)c4ccccc34)cc21 ; CP1(=O)c2ccccc2-c2ccc(-c3c4ccccc4c(-c4ccc(-c5nc(-c6ccccc6)nc(-c6ccccc6)n5)cc4)c4ccccc34)cc21]

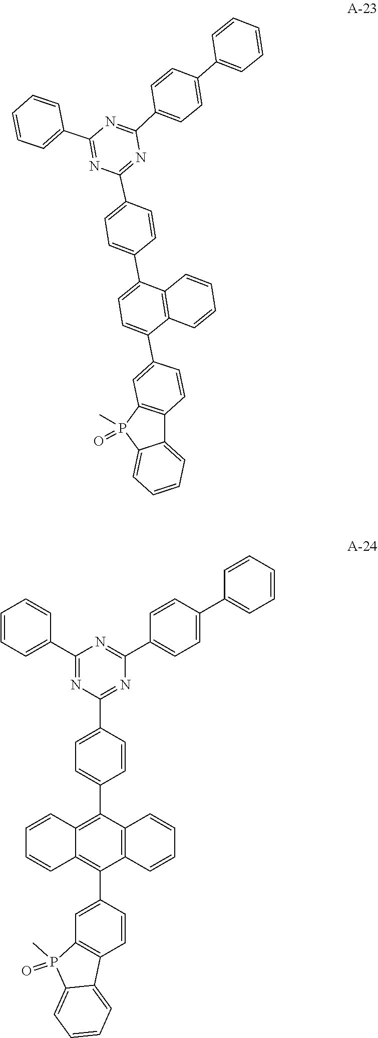 [SMILES: CP1(=O)c2ccccc2-c2ccc(-c3ccc(-c4ccc(-c5nc(-c6ccccc6)nc(-c6ccc(-c7ccccc7)cc6)n5)cc4)c4ccccc34)cc21 ; CP1(=O)c2ccccc2-c2ccc(-c3c4ccccc4c(-c4ccc(-c5nc(-c6ccccc6)nc(-c6ccc(-c7ccccc7)cc6)n5)cc4)c4ccccc34)cc21]

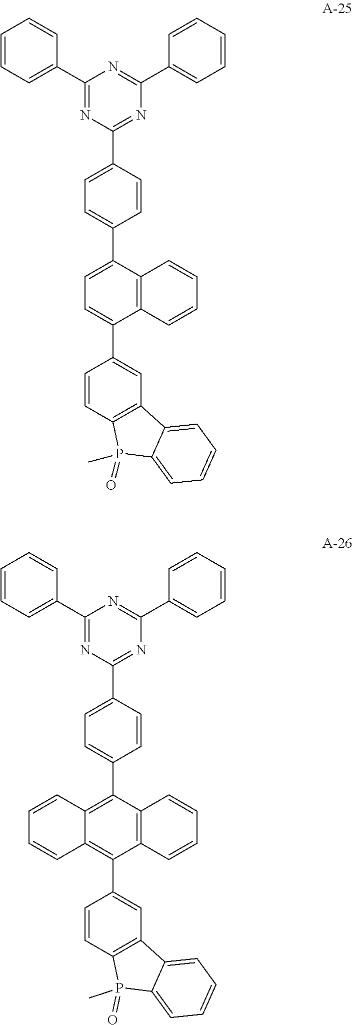 [SMILES: CP1(=O)c2ccccc2-c2cc(-c3ccc(-c4ccc(-c5nc(-c6ccccc6)nc(-c6ccccc6)n5)cc4)c4ccccc34)ccc21 ; CP1(=O)c2ccccc2-c2cc(-c3c4ccccc4c(-c4ccc(-c5nc(-c6ccccc6)nc(-c6ccccc6)n5)cc4)c4ccccc34)ccc21]

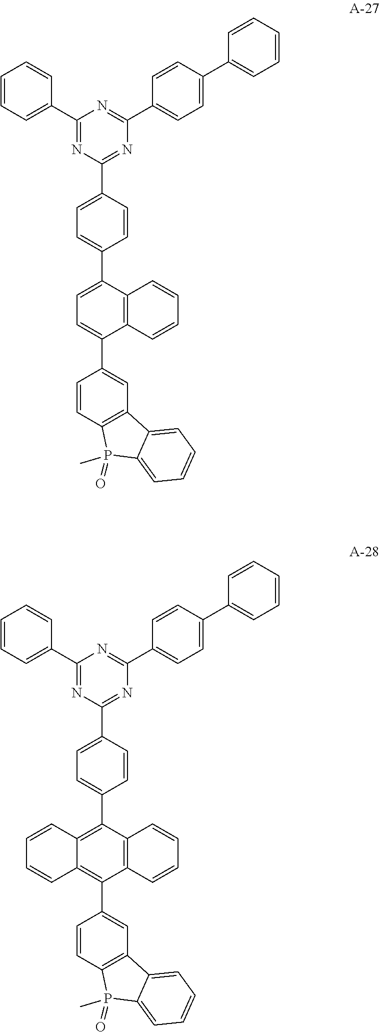 [SMILES: CP1(=O)c2ccccc2-c2cc(-c3ccc(-c4ccc(-c5nc(-c6ccccc6)nc(-c6ccc(-c7ccccc7)cc6)n5)cc4)c4ccccc34)ccc21 ; CP1(=O)c2ccccc2-c2cc(-c3c4ccccc4c(-c4ccc(-c5nc(-c6ccccc6)nc(-c6ccc(-c7ccccc7)cc6)n5)cc4)c4ccccc34)ccc21]

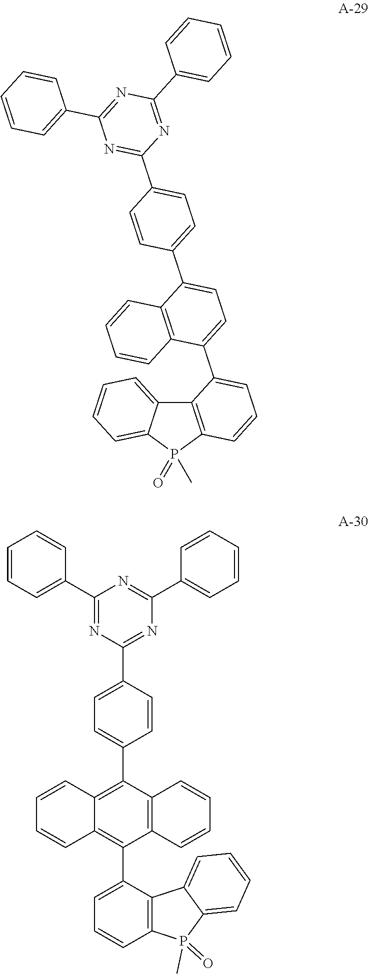 [SMILES: CP1(=O)c2ccccc2-c2c(-c3ccc(-c4ccc(-c5nc(-c6ccccc6)nc(-c6ccccc6)n5)cc4)c4ccccc34)cccc21 ; CP1(=O)c2ccccc2-c2c(-c3c4ccccc4c(-c4ccc(-c5nc(-c6ccccc6)nc(-c6ccccc6)n5)cc4)c4ccccc34)cccc21]

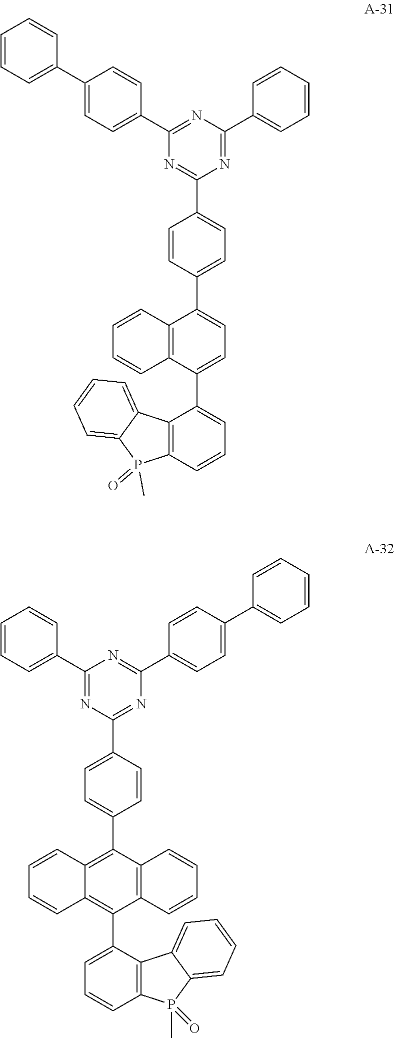 [SMILES: CP1(=O)c2ccccc2-c2c(-c3ccc(-c4ccc(-c5nc(-c6ccccc6)nc(-c6ccc(-c7ccccc7)cc6)n5)cc4)c4ccccc34)cccc21 ; CP1(=O)c2ccccc2-c2c(-c3c4ccccc4c(-c4ccc(-c5nc(-c6ccccc6)nc(-c6ccc(-c7ccccc7)cc6)n5)cc4)c4ccccc34)cccc21]

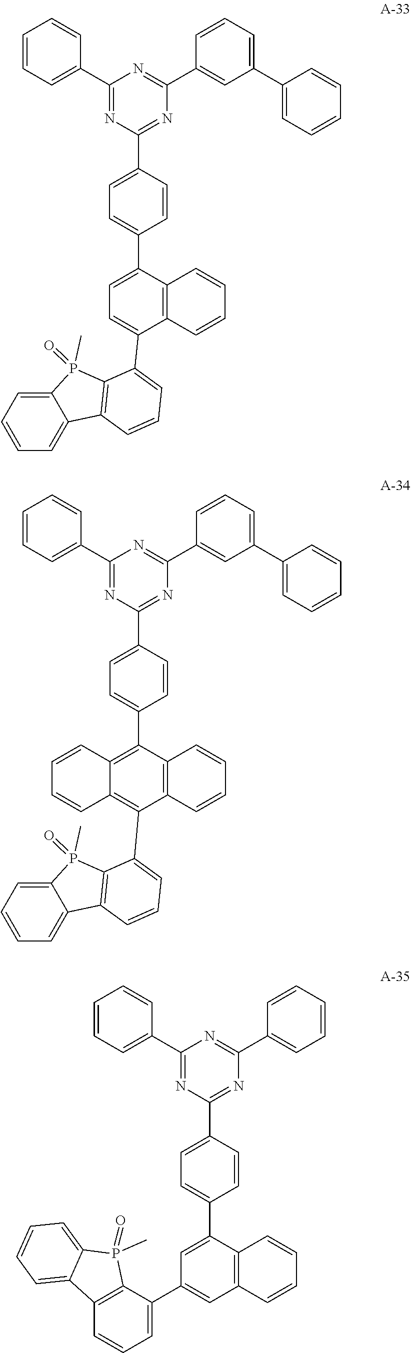

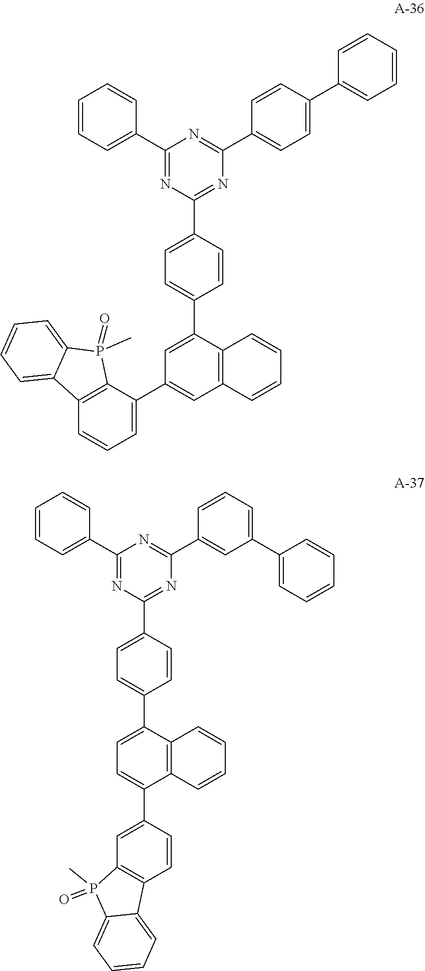 [SMILES: CP1(=O)c2ccccc2-c2cccc(-c3cc(-c4ccc(-c5nc(-c6ccccc6)nc(-c6ccc(-c7ccccc7)cc6)n5)cc4)c4ccccc4c3)c21 ; CP1(=O)c2ccccc2-c2ccc(-c3ccc(-c4ccc(-c5nc(-c6ccccc6)nc(-c6cccc(-c7ccccc7)c6)n5)cc4)c4ccccc34)cc21]

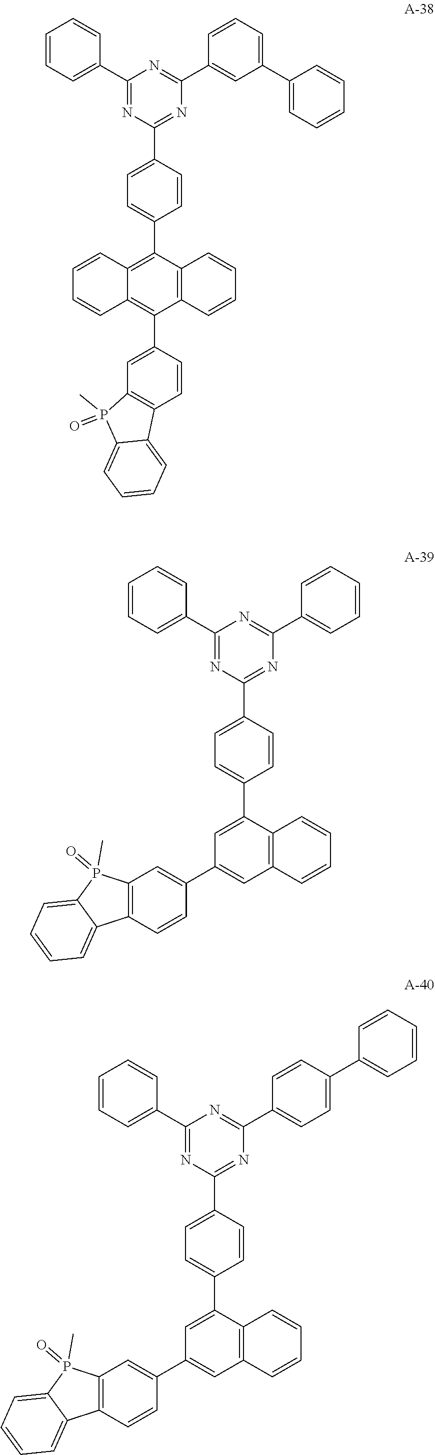 [SMILES: CP1(=O)c2ccccc2-c2ccc(-c3c4ccccc4c(-c4ccc(-c5nc(-c6ccccc6)nc(-c6cccc(-c7ccccc7)c6)n5)cc4)c4ccccc34)cc21 ; CP1(=O)c2ccccc2-c2ccc(-c3cc(-c4ccc(-c5nc(-c6ccccc6)nc(-c6ccccc6)n5)cc4)c4ccccc4c3)cc21 ; CP1(=O)c2ccccc2-c2ccc(-c3cc(-c4ccc(-c5nc(-c6ccccc6)nc(-c6ccc(-c7ccccc7)cc6)n5)cc4)c4ccccc4c3)cc21]

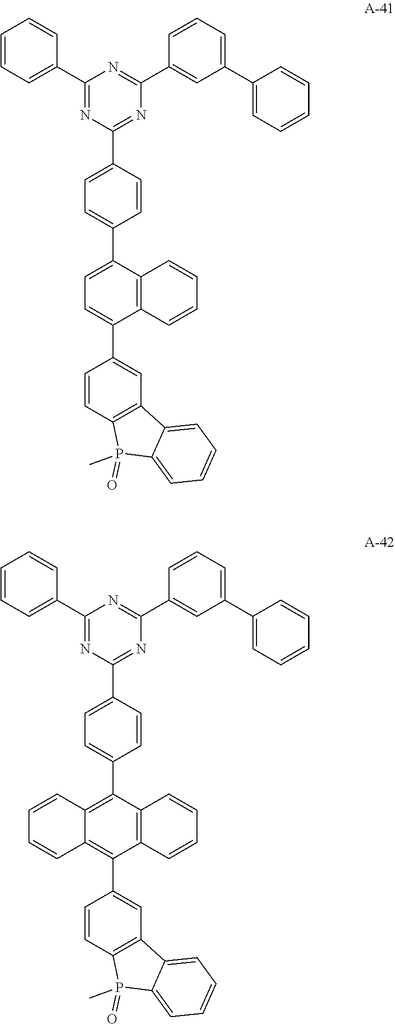 [SMILES: CP1(=O)c2ccccc2-c2cc(-c3ccc(-c4ccc(-c5nc(-c6ccccc6)nc(-c6cccc(-c7ccccc7)c6)n5)cc4)c4ccccc34)ccc21 ; CP1(=O)c2ccccc2-c2cc(-c3c4ccccc4c(-c4ccc(-c5nc(-c6ccccc6)nc(-c6cccc(-c7ccccc7)c6)n5)cc4)c4ccccc34)ccc21]

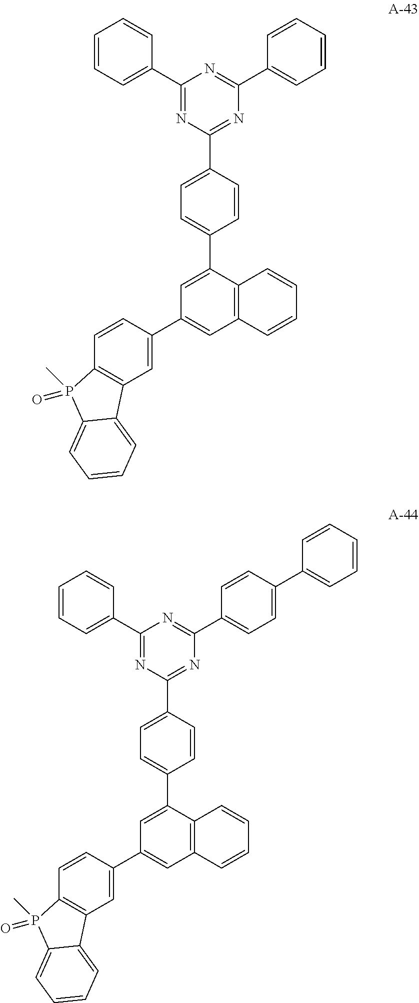 [SMILES: CP1(=O)c2ccccc2-c2cc(-c3cc(-c4ccc(-c5nc(-c6ccccc6)nc(-c6ccccc6)n5)cc4)c4ccccc4c3)ccc21 ; CP1(=O)c2ccccc2-c2cc(-c3cc(-c4ccc(-c5nc(-c6ccccc6)nc(-c6ccc(-c7ccccc7)cc6)n5)cc4)c4ccccc4c3)ccc21]

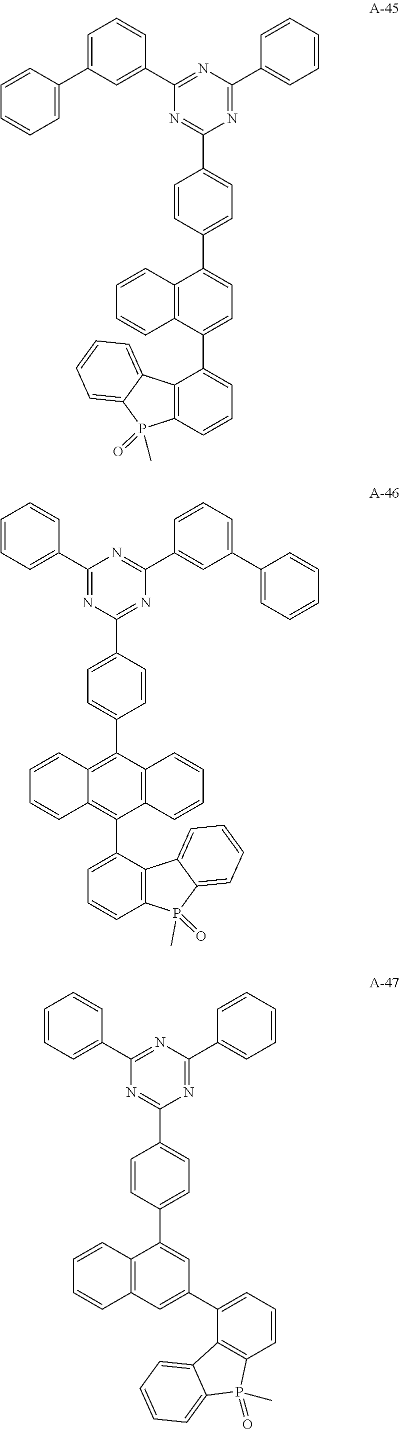 [SMILES: CP1(=O)c2ccccc2-c2c(-c3ccc(-c4ccc(-c5nc(-c6ccccc6)nc(-c6cccc(-c7ccccc7)c6)n5)cc4)c4ccccc34)cccc21 ; CP1(=O)c2ccccc2-c2c(-c3c4ccccc4c(-c4ccc(-c5nc(-c6ccccc6)nc(-c6cccc(-c7ccccc7)c6)n5)cc4)c4ccccc34)cccc21 ; CP1(=O)c2ccccc2-c2c(-c3cc(-c4ccc(-c5nc(-c6ccccc6)nc(-c6ccccc6)n5)cc4)c4ccccc4c3)cccc21]

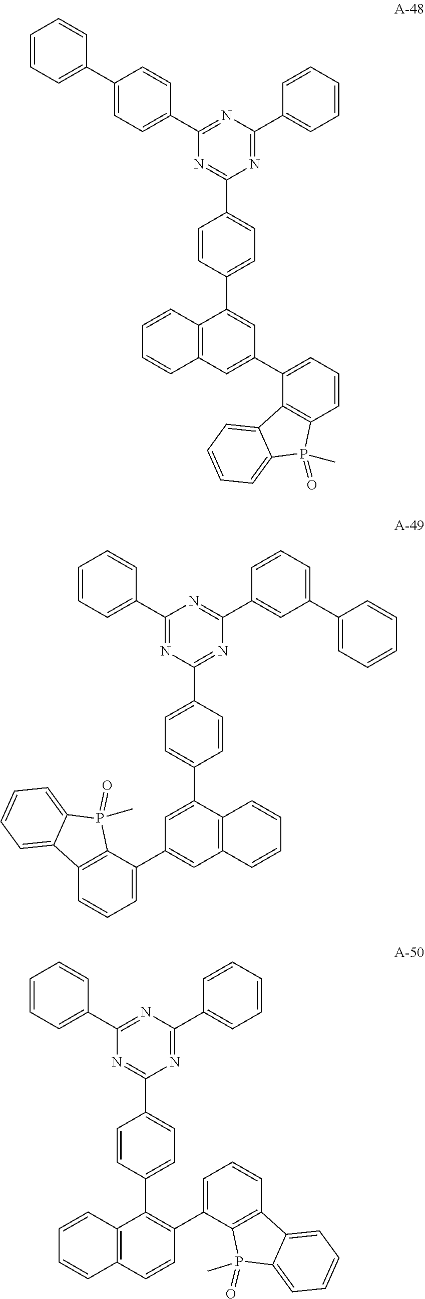 [SMILES: CP1(=O)c2ccccc2-c2c(-c3cc(-c4ccc(-c5nc(-c6ccccc6)nc(-c6ccc(-c7ccccc7)cc6)n5)cc4)c4ccccc4c3)cccc21 ; CP1(=O)c2ccccc2-c2cccc(-c3cc(-c4ccc(-c5nc(-c6ccccc6)nc(-c6cccc(-c7ccccc7)c6)n5)cc4)c4ccccc4c3)c21 ; CP1(=O)c2ccccc2-c2cccc(-c3ccc4ccccc4c3-c3ccc(-c4nc(-c5ccccc5)nc(-c5ccccc5)n4)cc3)c21]

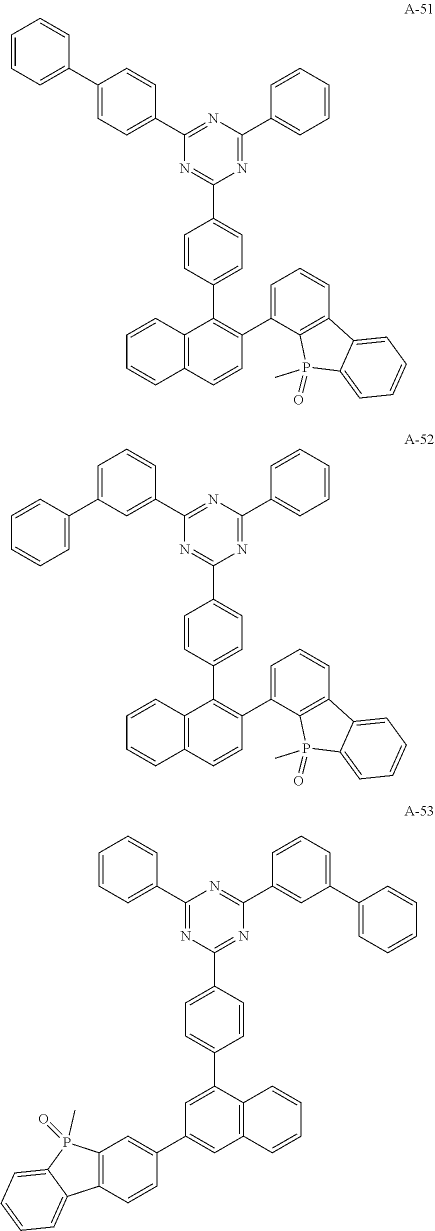 [SMILES: CP1(=O)c2ccccc2-c2cccc(-c3ccc4ccccc4c3-c3ccc(-c4nc(-c5ccccc5)nc(-c5ccc(-c6ccccc6)cc5)n4)cc3)c21 ; CP1(=O)c2ccccc2-c2cccc(-c3ccc4ccccc4c3-c3ccc(-c4nc(-c5ccccc5)nc(-c5cccc(-c6ccccc6)c5)n4)cc3)c21 ; CP1(=O)c2ccccc2-c2ccc(-c3cc(-c4ccc(-c5nc(-c6ccccc6)nc(-c6cccc(-c7ccccc7)c6)n5)cc4)c4ccccc4c3)cc21]

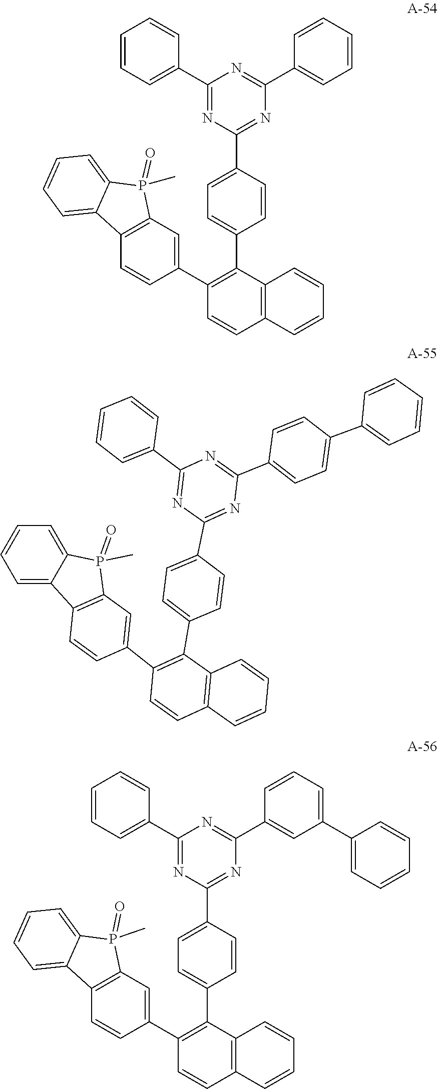 [SMILES: CP1(=O)c2ccccc2-c2ccc(-c3ccc4ccccc4c3-c3ccc(-c4nc(-c5ccccc5)nc(-c5ccccc5)n4)cc3)cc21 ; CP1(=O)c2ccccc2-c2ccc(-c3ccc4ccccc4c3-c3ccc(-c4nc(-c5ccccc5)nc(-c5ccc(-c6ccccc6)cc5)n4)cc3)cc21 ; CP1(=O)c2ccccc2-c2ccc(-c3ccc4ccccc4c3-c3ccc(-c4nc(-c5ccccc5)nc(-c5cccc(-c6ccccc6)c5)n4)cc3)cc21]

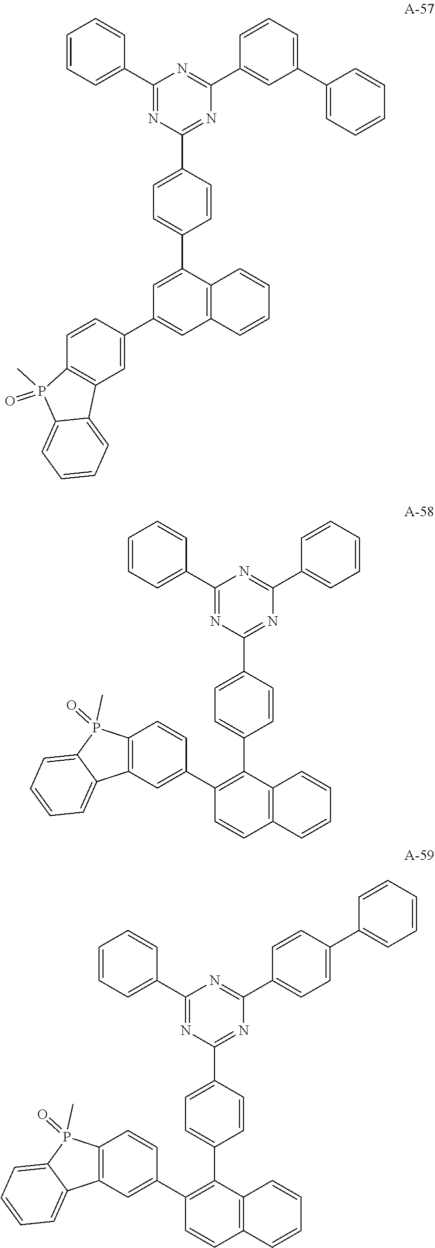 [SMILES: CP1(=O)c2ccccc2-c2cc(-c3cc(-c4ccc(-c5nc(-c6ccccc6)nc(-c6cccc(-c7ccccc7)c6)n5)cc4)c4ccccc4c3)ccc21 ; CP1(=O)c2ccccc2-c2cc(-c3ccc4ccccc4c3-c3ccc(-c4nc(-c5ccccc5)nc(-c5ccccc5)n4)cc3)ccc21 ; CP1(=O)c2ccccc2-c2cc(-c3ccc4ccccc4c3-c3ccc(-c4nc(-c5ccccc5)nc(-c5ccc(-c6ccccc6)cc5)n4)cc3)ccc21]

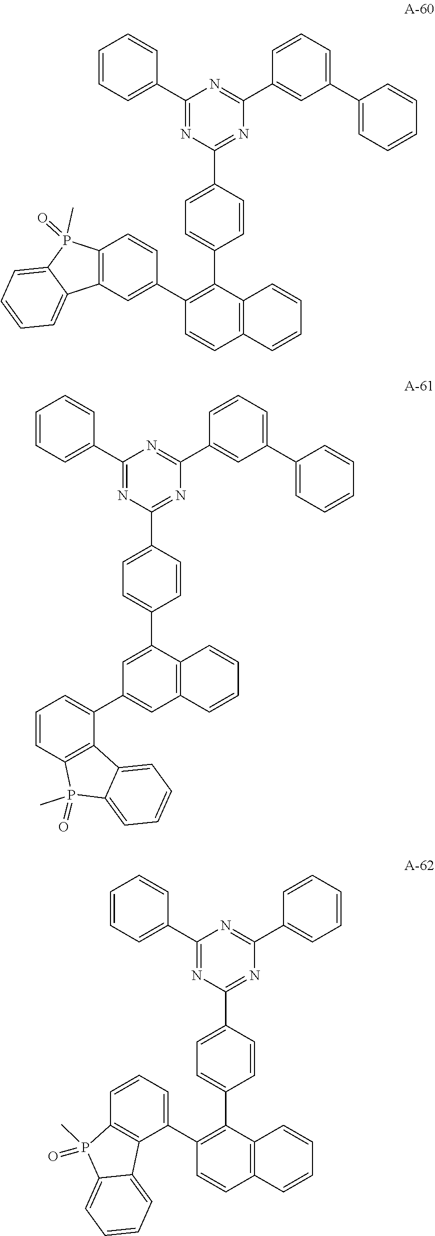 [SMILES: CP1(=O)c2ccccc2-c2cc(-c3ccc4ccccc4c3-c3ccc(-c4nc(-c5ccccc5)nc(-c5cccc(-c6ccccc6)c5)n4)cc3)ccc21 ; CP1(=O)c2ccccc2-c2c(-c3cc(-c4ccc(-c5nc(-c6ccccc6)nc(-c6cccc(-c7ccccc7)c6)n5)cc4)c4ccccc4c3)cccc21 ; CP1(=O)c2ccccc2-c2c(-c3ccc4ccccc4c3-c3ccc(-c4nc(-c5ccccc5)nc(-c5ccccc5)n4)cc3)cccc21]

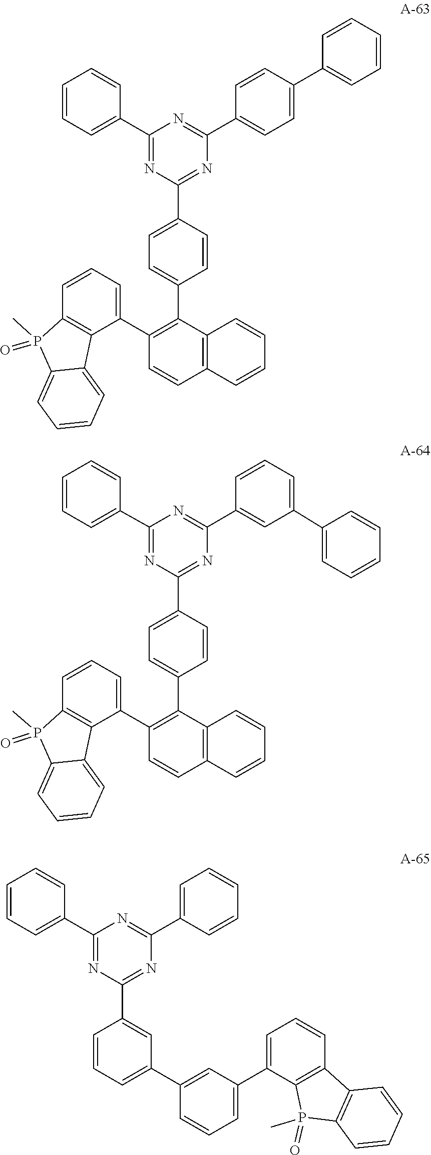

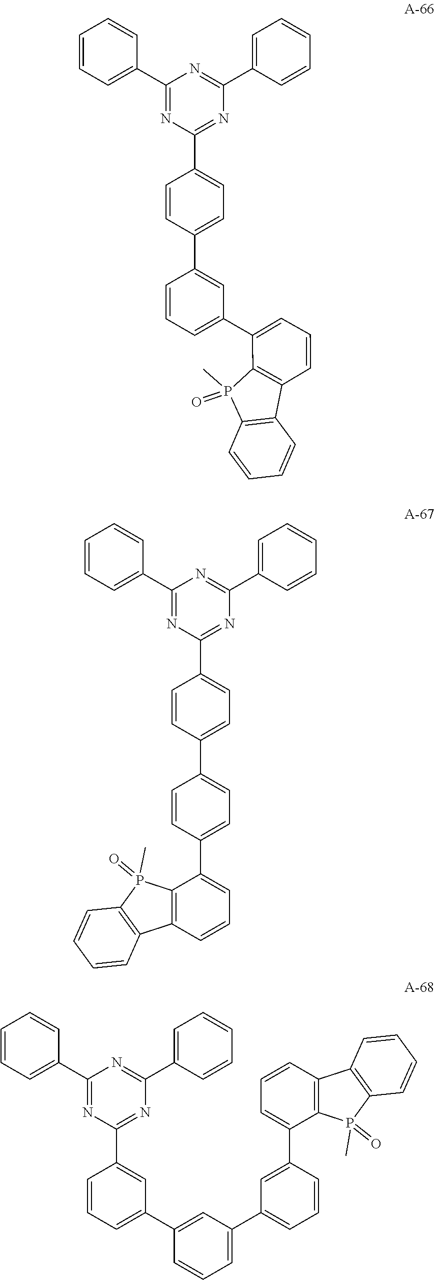 [SMILES: CP1(=O)c2ccccc2-c2cccc(-c3cccc(-c4ccc(-c5nc(-c6ccccc6)nc(-c6ccccc6)n5)cc4)c3)c21 ; CP1(=O)c2ccccc2-c2cccc(-c3ccc(-c4ccc(-c5nc(-c6ccccc6)nc(-c6ccccc6)n5)cc4)cc3)c21 ; CP1(=O)c2ccccc2-c2cccc(-c3cccc(-c4cccc(-c5cccc(-c6nc(-c7ccccc7)nc(-c7ccccc7)n6)c5)c4)c3)c21]

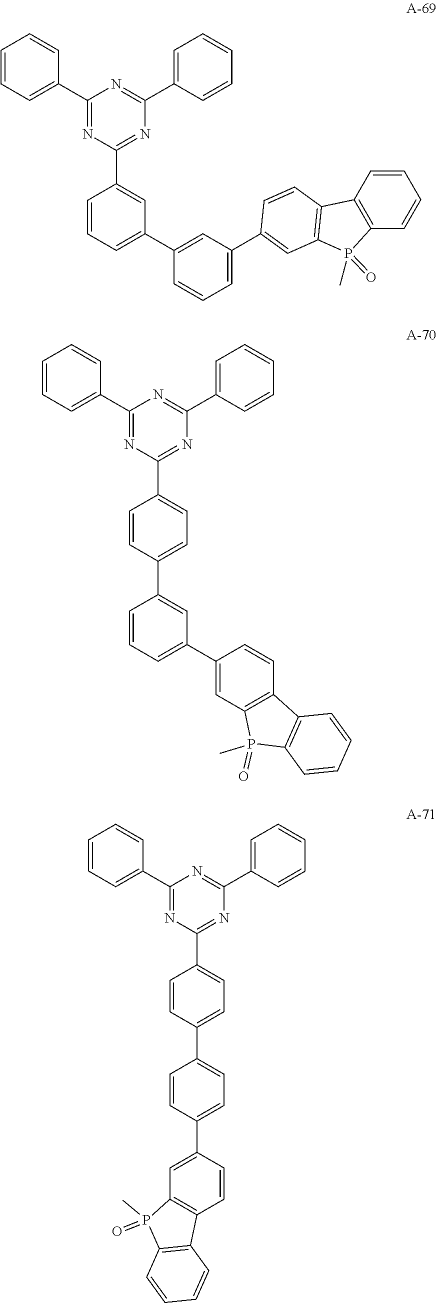 [SMILES: CP1(=O)c2ccccc2-c2ccc(-c3cccc(-c4cccc(-c5nc(-c6ccccc6)nc(-c6ccccc6)n5)c4)c3)cc21 ; CP1(=O)c2ccccc2-c2ccc(-c3cccc(-c4ccc(-c5nc(-c6ccccc6)nc(-c6ccccc6)n5)cc4)c3)cc21 ; CP1(=O)c2ccccc2-c2ccc(-c3ccc(-c4ccc(-c5nc(-c6ccccc6)nc(-c6ccccc6)n5)cc4)cc3)cc21]

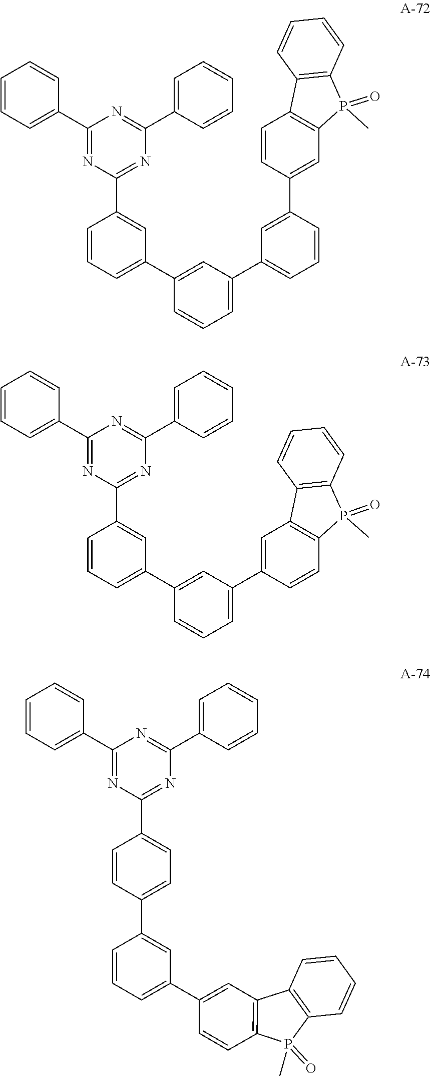

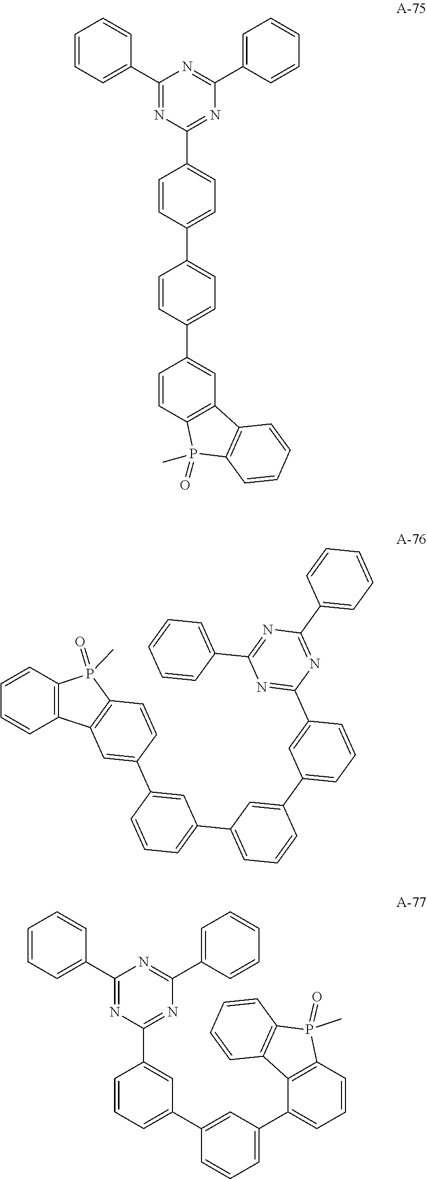 [SMILES: CP1(=O)c2ccccc2-c2cc(-c3ccc(-c4ccc(-c5nc(-c6ccccc6)nc(-c6ccccc6)n5)cc4)cc3)ccc21 ; CP1(=O)c2ccccc2-c2cc(-c3cccc(-c4cccc(-c5cccc(-c6nc(-c7ccccc7)nc(-c7ccccc7)n6)c5)c4)c3)ccc21 ; CP1(=O)c2ccccc2-c2c(-c3cccc(-c4cccc(-c5nc(-c6ccccc6)nc(-c6ccccc6)n5)c4)c3)cccc21]

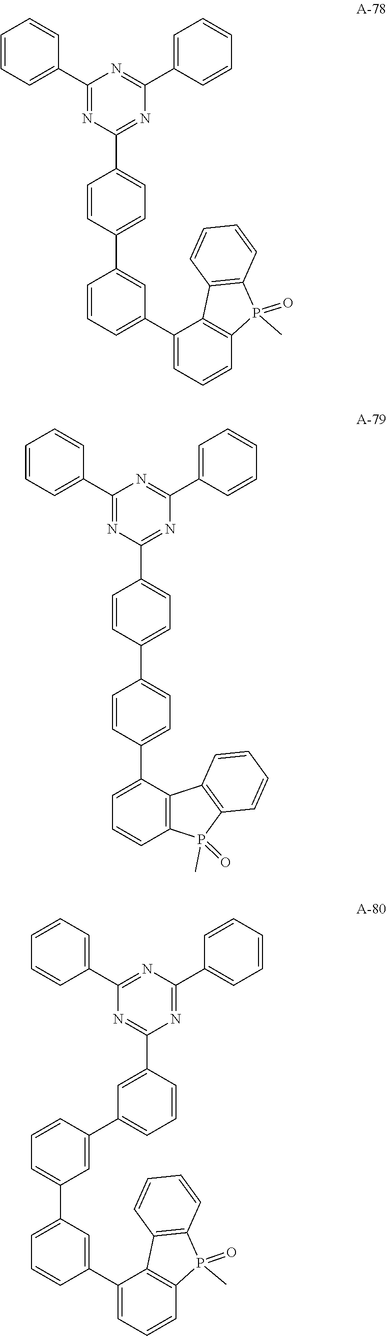 [SMILES: CP1(=O)c2ccccc2-c2c(-c3cccc(-c4ccc(-c5nc(-c6ccccc6)nc(-c6ccccc6)n5)cc4)c3)cccc21 ; CP1(=O)c2ccccc2-c2c(-c3ccc(-c4ccc(-c5nc(-c6ccccc6)nc(-c6ccccc6)n5)cc4)cc3)cccc21 ; CP1(=O)c2ccccc2-c2c(-c3cccc(-c4cccc(-c5cccc(-c6nc(-c7ccccc7)nc(-c7ccccc7)n6)c5)c4)c3)cccc21]

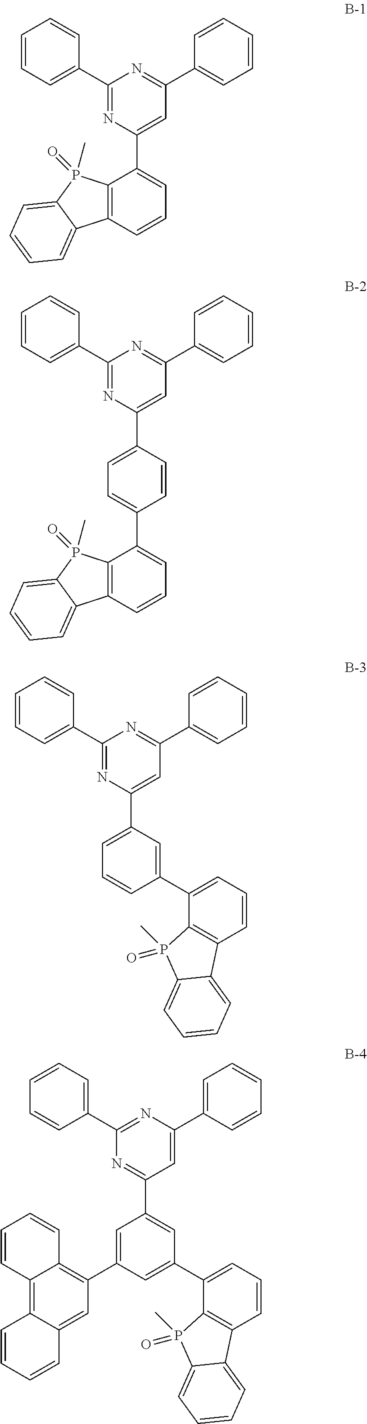

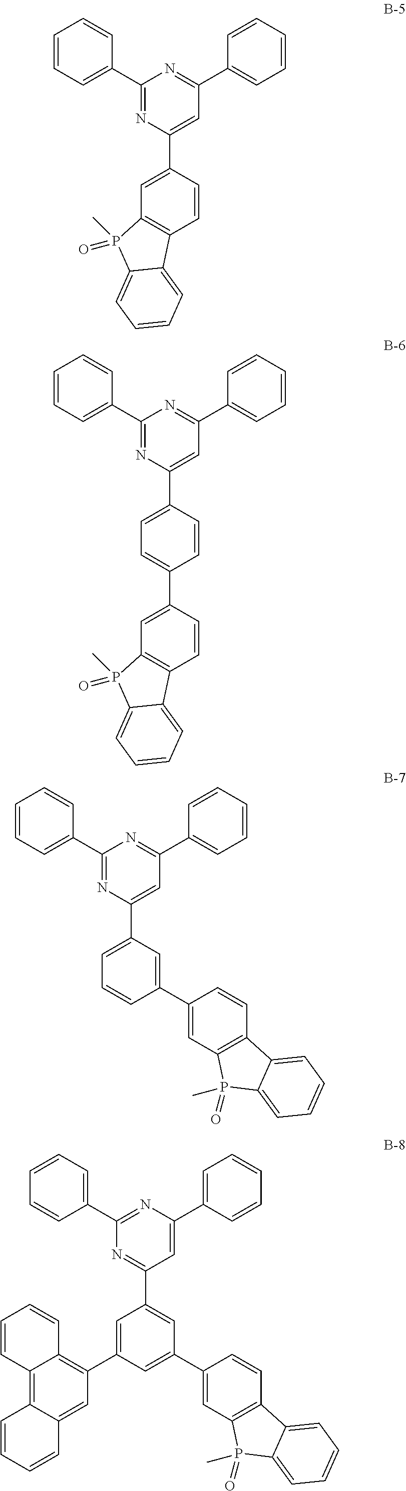

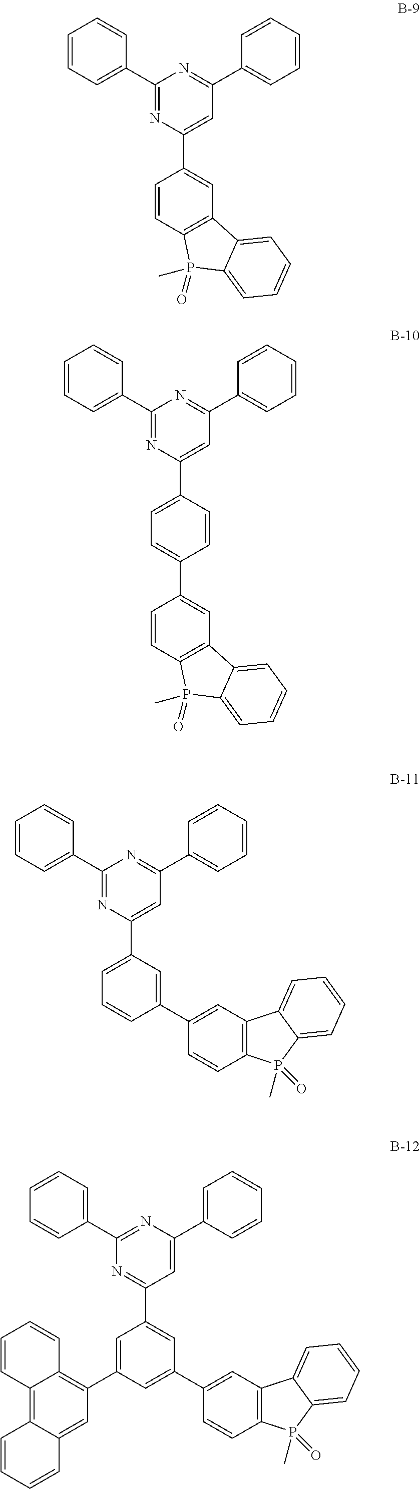 [SMILES: CP1(=O)c2ccccc2-c2cc(-c3cc(-c4ccccc4)nc(-c4ccccc4)n3)ccc21 ; CP1(=O)c2ccccc2-c2cc(-c3ccc(-c4cc(-c5ccccc5)nc(-c5ccccc5)n4)cc3)ccc21 ; CP1(=O)c2ccccc2-c2cc(-c3cccc(-c4cc(-c5ccccc5)nc(-c5ccccc5)n4)c3)ccc21 ; CP1(=O)c2ccccc2-c2cc(-c3cc(-c4cc(-c5ccccc5)nc(-c5ccccc5)n4)cc(-c4cc5ccccc5c5ccccc45)c3)ccc21]

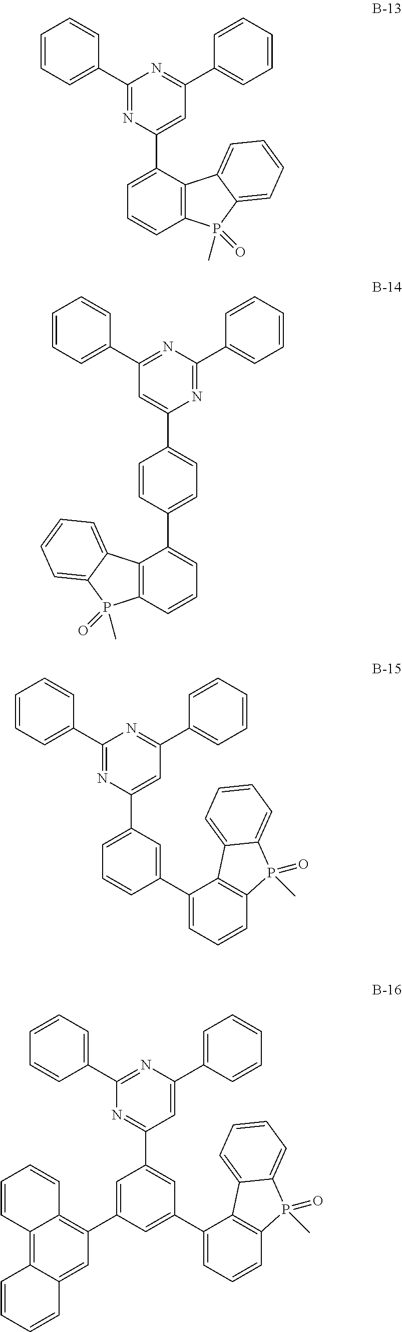 [SMILES: CP1(=O)c2ccccc2-c2c(-c3cc(-c4ccccc4)nc(-c4ccccc4)n3)cccc21 ; CP1(=O)c2ccccc2-c2c(-c3ccc(-c4cc(-c5ccccc5)nc(-c5ccccc5)n4)cc3)cccc21 ; CP1(=O)c2ccccc2-c2c(-c3cccc(-c4cc(-c5ccccc5)nc(-c5ccccc5)n4)c3)cccc21 ; CP1(=O)c2ccccc2-c2c(-c3cc(-c4cc(-c5ccccc5)nc(-c5ccccc5)n4)cc(-c4cc5ccccc5c5ccccc45)c3)cccc21]

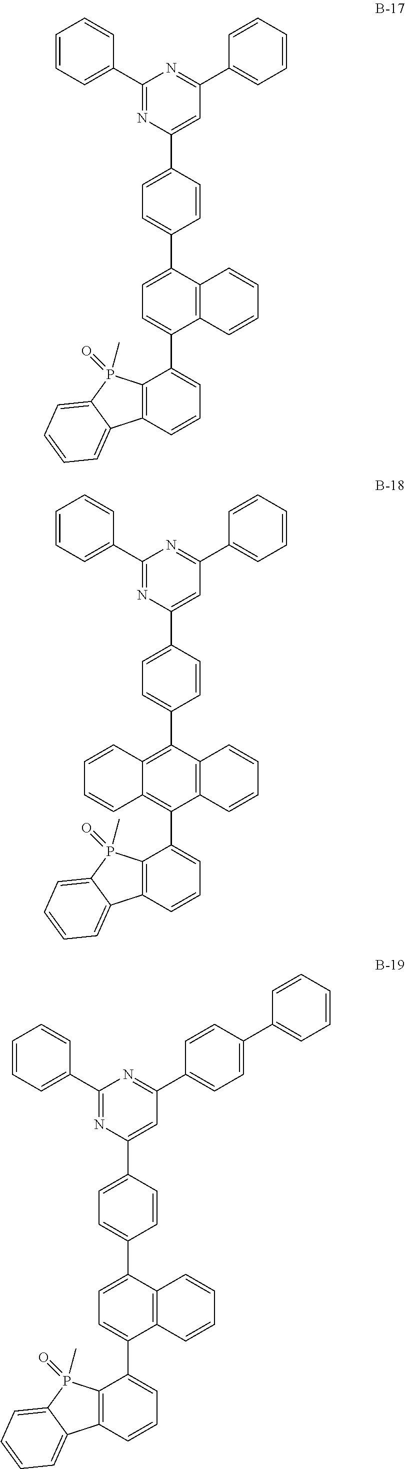

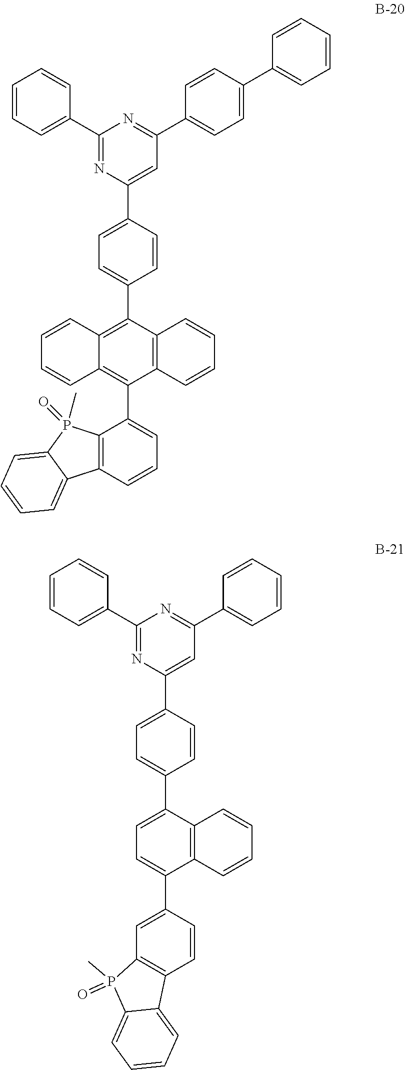 [SMILES: CP1(=O)c2ccccc2-c2cccc(-c3c4ccccc4c(-c4ccc(-c5cc(-c6ccc(-c7ccccc7)cc6)nc(-c6ccccc6)n5)cc4)c4ccccc34)c21 ; CP1(=O)c2ccccc2-c2ccc(-c3ccc(-c4ccc(-c5cc(-c6ccccc6)nc(-c6ccccc6)n5)cc4)c4ccccc34)cc21]

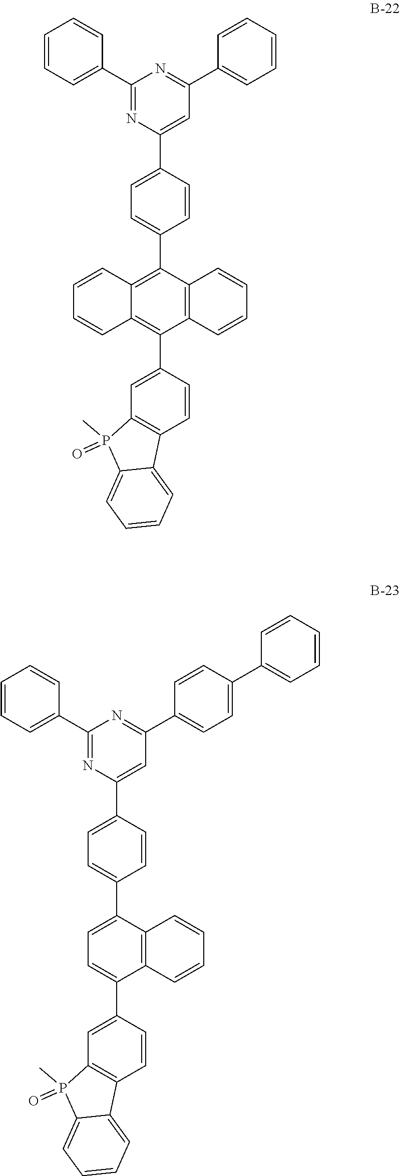 [SMILES: CP1(=O)c2ccccc2-c2ccc(-c3c4ccccc4c(-c4ccc(-c5cc(-c6ccccc6)nc(-c6ccccc6)n5)cc4)c4ccccc34)cc21 ; CP1(=O)c2ccccc2-c2ccc(-c3ccc(-c4ccc(-c5cc(-c6ccc(-c7ccccc7)cc6)nc(-c6ccccc6)n5)cc4)c4ccccc34)cc21]

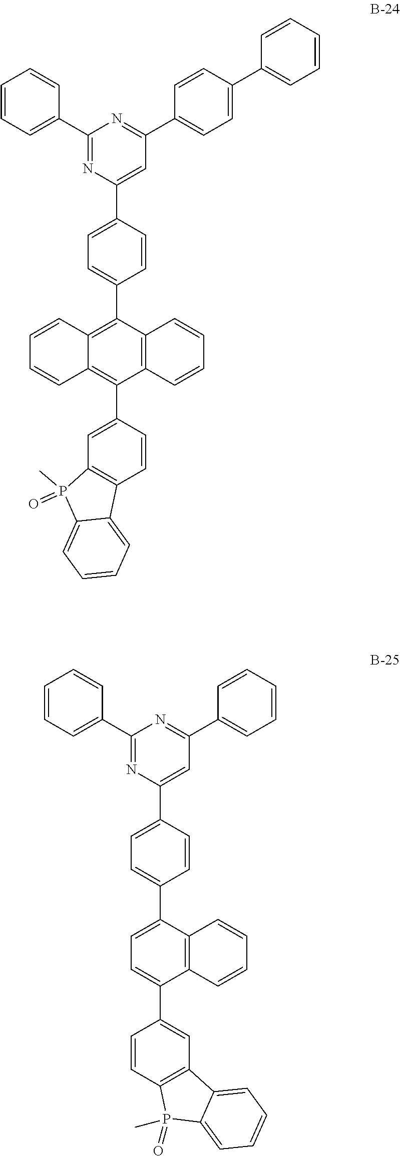 [SMILES: CP1(=O)c2ccccc2-c2ccc(-c3c4ccccc4c(-c4ccc(-c5cc(-c6ccc(-c7ccccc7)cc6)nc(-c6ccccc6)n5)cc4)c4ccccc34)cc21 ; CP1(=O)c2ccccc2-c2cc(-c3ccc(-c4ccc(-c5cc(-c6ccccc6)nc(-c6ccccc6)n5)cc4)c4ccccc34)ccc21]

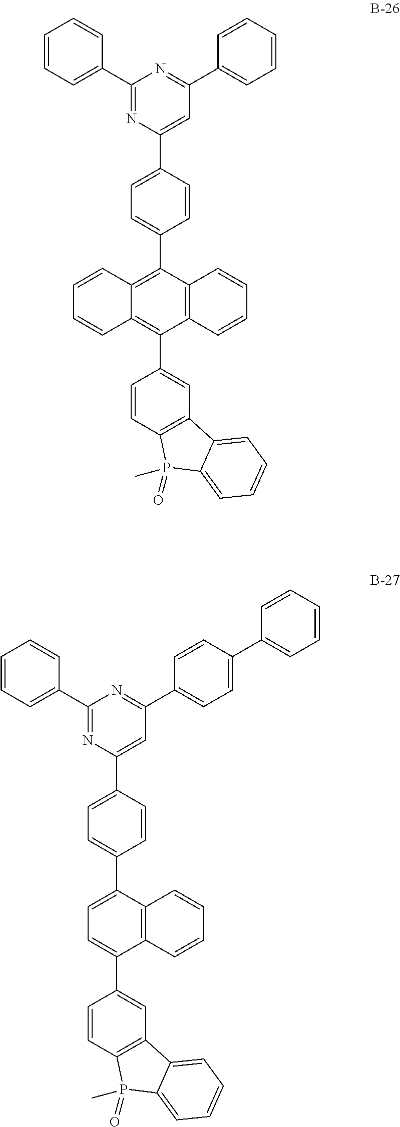 [SMILES: CP1(=O)c2ccccc2-c2cc(-c3c4ccccc4c(-c4ccc(-c5cc(-c6ccccc6)nc(-c6ccccc6)n5)cc4)c4ccccc34)ccc21 ; CP1(=O)c2ccccc2-c2cc(-c3ccc(-c4ccc(-c5cc(-c6ccc(-c7ccccc7)cc6)nc(-c6ccccc6)n5)cc4)c4ccccc34)ccc21]

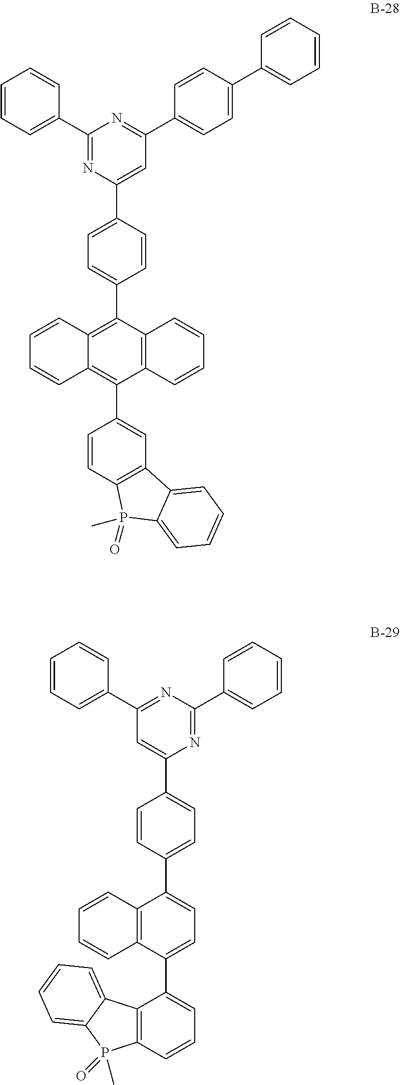 [SMILES: CP1(=O)c2ccccc2-c2cc(-c3c4ccccc4c(-c4ccc(-c5cc(-c6ccc(-c7ccccc7)cc6)nc(-c6ccccc6)n5)cc4)c4ccccc34)ccc21 ; CP1(=O)c2ccccc2-c2c(-c3ccc(-c4ccc(-c5cc(-c6ccccc6)nc(-c6ccccc6)n5)cc4)c4ccccc34)cccc21]

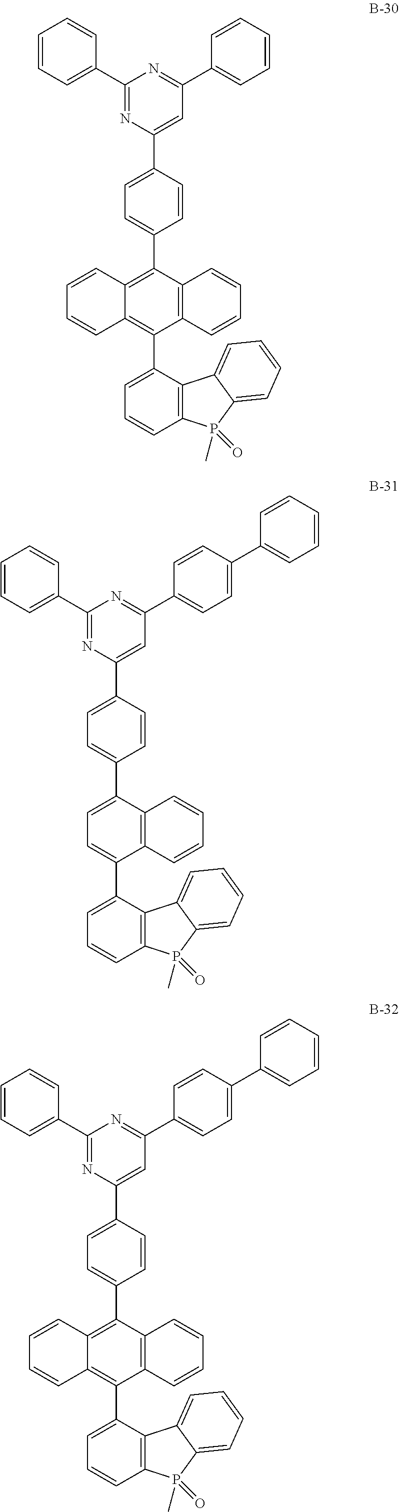 [SMILES: CP1(=O)c2ccccc2-c2c(-c3c4ccccc4c(-c4ccc(-c5cc(-c6ccccc6)nc(-c6ccccc6)n5)cc4)c4ccccc34)cccc21 ; CP1(=O)c2ccccc2-c2c(-c3ccc(-c4ccc(-c5cc(-c6ccc(-c7ccccc7)cc6)nc(-c6ccccc6)n5)cc4)c4ccccc34)cccc21 ; CP1(=O)c2ccccc2-c2c(-c3c4ccccc4c(-c4ccc(-c5cc(-c6ccc(-c7ccccc7)cc6)nc(-c6ccccc6)n5)cc4)c4ccccc34)cccc21]

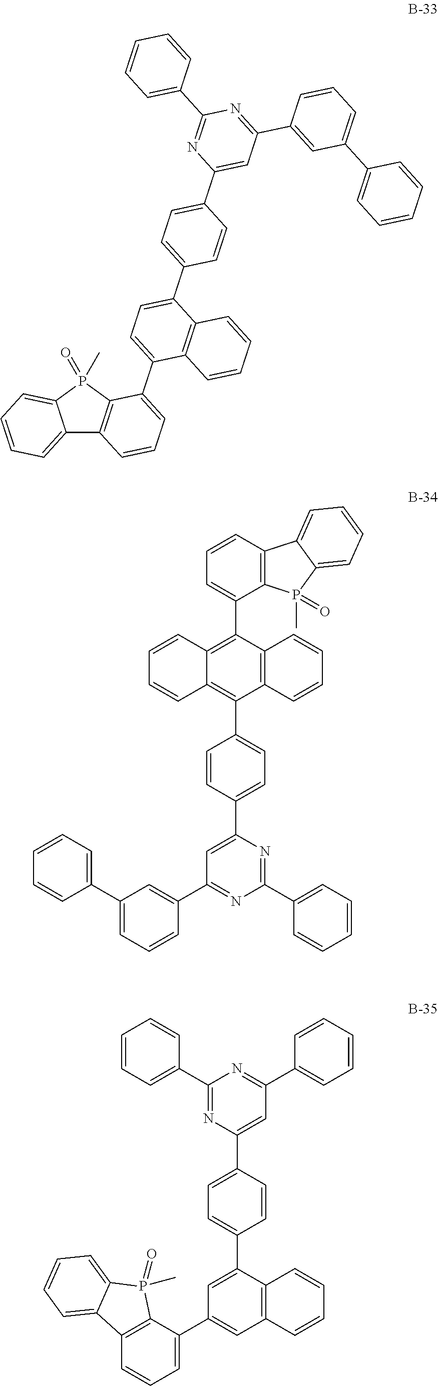 [SMILES: CP1(=O)c2ccccc2-c2cccc(-c3ccc(-c4ccc(-c5cc(-c6cccc(-c7ccccc7)c6)nc(-c6ccccc6)n5)cc4)c4ccccc34)c21 ; CP1(=O)c2ccccc2-c2cccc(-c3c4ccccc4c(-c4ccc(-c5cc(-c6cccc(-c7ccccc7)c6)nc(-c6ccccc6)n5)cc4)c4ccccc34)c21 ; CP1(=O)c2ccccc2-c2cccc(-c3cc(-c4ccc(-c5cc(-c6ccccc6)nc(-c6ccccc6)n5)cc4)c4ccccc4c3)c21]

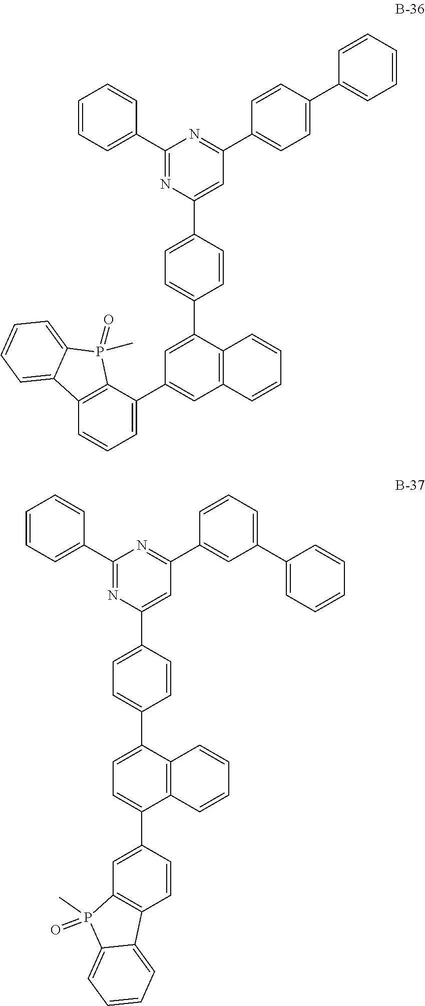 [SMILES: CP1(=O)c2ccccc2-c2cccc(-c3cc(-c4ccc(-c5cc(-c6ccc(-c7ccccc7)cc6)nc(-c6ccccc6)n5)cc4)c4ccccc4c3)c21 ; CP1(=O)c2ccccc2-c2ccc(-c3ccc(-c4ccc(-c5cc(-c6cccc(-c7ccccc7)c6)nc(-c6ccccc6)n5)cc4)c4ccccc34)cc21]

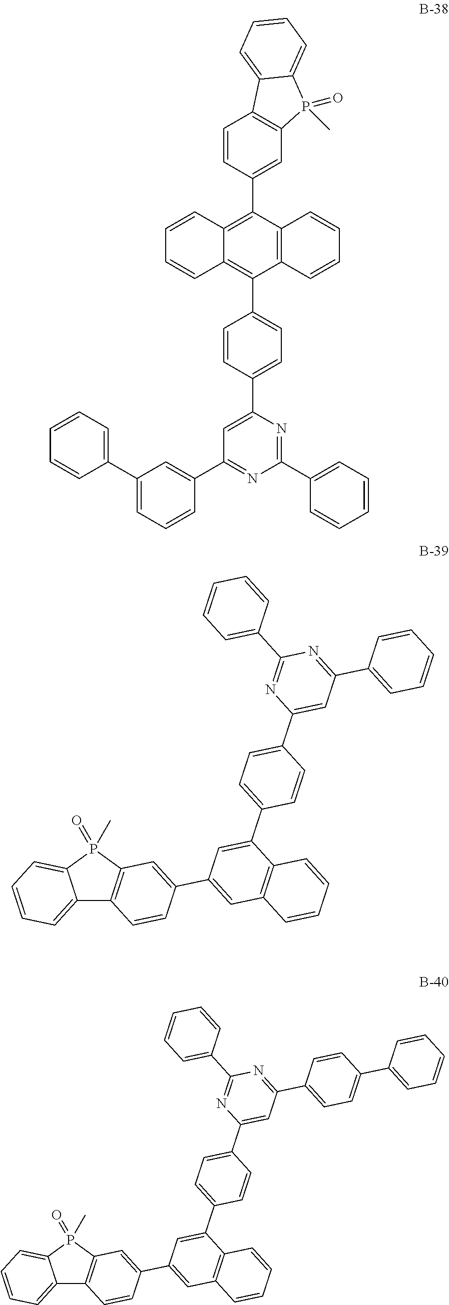 [SMILES: CP1(=O)c2ccccc2-c2ccc(-c3c4ccccc4c(-c4ccc(-c5cc(-c6cccc(-c7ccccc7)c6)nc(-c6ccccc6)n5)cc4)c4ccccc34)cc21 ; CP1(=O)c2ccccc2-c2ccc(-c3cc(-c4ccc(-c5cc(-c6ccccc6)nc(-c6ccccc6)n5)cc4)c4ccccc4c3)cc21 ; CP1(=O)c2ccccc2-c2ccc(-c3cc(-c4ccc(-c5cc(-c6ccc(-c7ccccc7)cc6)nc(-c6ccccc6)n5)cc4)c4ccccc4c3)cc21]

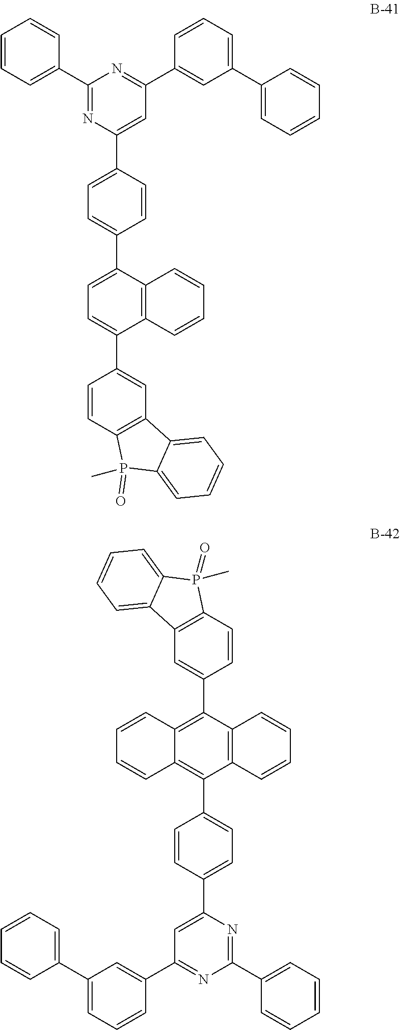 [SMILES: CP1(=O)c2ccccc2-c2cc(-c3ccc(-c4ccc(-c5cc(-c6cccc(-c7ccccc7)c6)nc(-c6ccccc6)n5)cc4)c4ccccc34)ccc21 ; CP1(=O)c2ccccc2-c2cc(-c3c4ccccc4c(-c4ccc(-c5cc(-c6cccc(-c7ccccc7)c6)nc(-c6ccccc6)n5)cc4)c4ccccc34)ccc21]

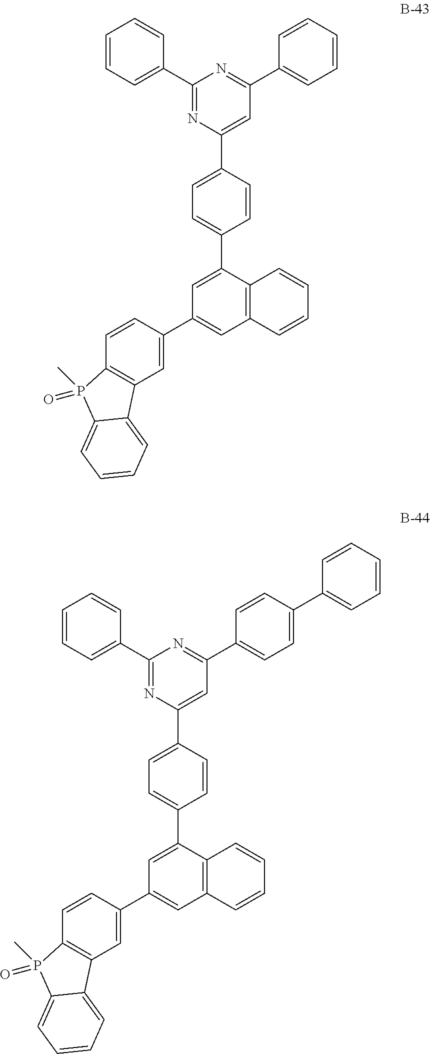 [SMILES: CP1(=O)c2ccccc2-c2cc(-c3cc(-c4ccc(-c5cc(-c6ccccc6)nc(-c6ccccc6)n5)cc4)c4ccccc4c3)ccc21 ; CP1(=O)c2ccccc2-c2cc(-c3cc(-c4ccc(-c5cc(-c6ccc(-c7ccccc7)cc6)nc(-c6ccccc6)n5)cc4)c4ccccc4c3)ccc21]

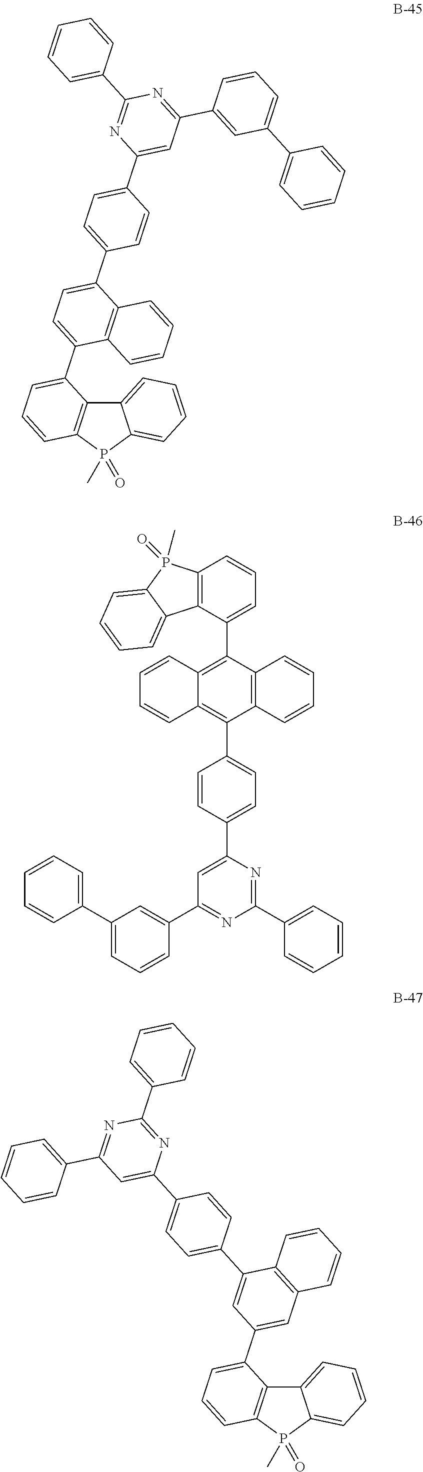 [SMILES: CP1(=O)c2ccccc2-c2c(-c3ccc(-c4ccc(-c5cc(-c6cccc(-c7ccccc7)c6)nc(-c6ccccc6)n5)cc4)c4ccccc34)cccc21 ; CP1(=O)c2ccccc2-c2c(-c3c4ccccc4c(-c4ccc(-c5cc(-c6cccc(-c7ccccc7)c6)nc(-c6ccccc6)n5)cc4)c4ccccc34)cccc21 ; CP1(=O)c2ccccc2-c2c(-c3cc(-c4ccc(-c5cc(-c6ccccc6)nc(-c6ccccc6)n5)cc4)c4ccccc4c3)cccc21]

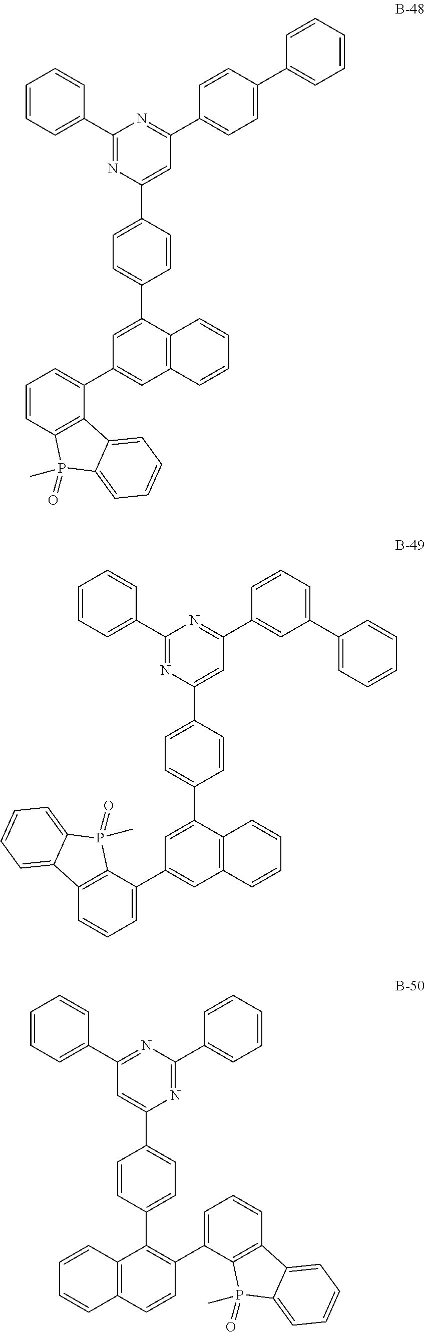 [SMILES: CP1(=O)c2ccccc2-c2c(-c3cc(-c4ccc(-c5cc(-c6ccc(-c7ccccc7)cc6)nc(-c6ccccc6)n5)cc4)c4ccccc4c3)cccc21 ; CP1(=O)c2ccccc2-c2cccc(-c3cc(-c4ccc(-c5cc(-c6cccc(-c7ccccc7)c6)nc(-c6ccccc6)n5)cc4)c4ccccc4c3)c21 ; CP1(=O)c2ccccc2-c2cccc(-c3ccc4ccccc4c3-c3ccc(-c4cc(-c5ccccc5)nc(-c5ccccc5)n4)cc3)c21]

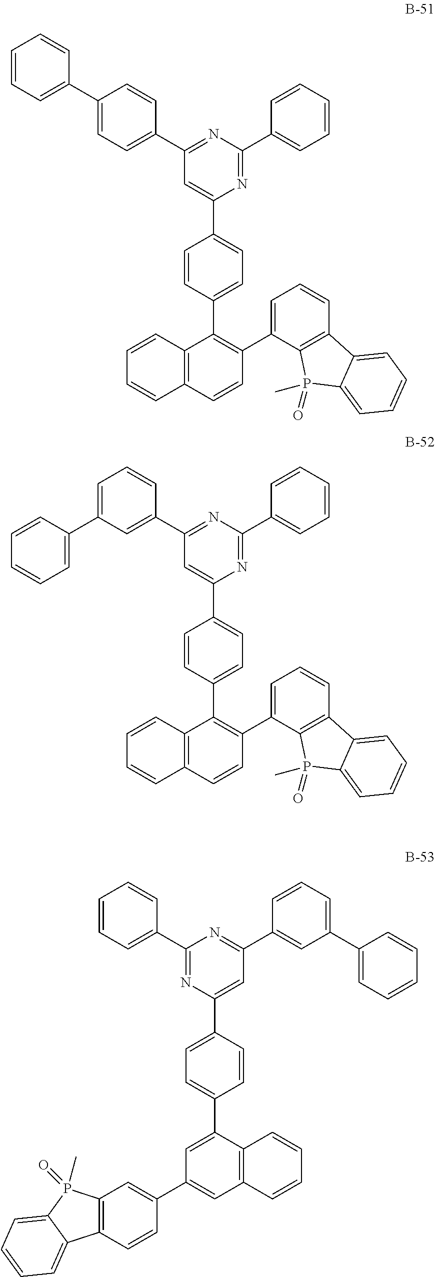 [SMILES: CP1(=O)c2ccccc2-c2cccc(-c3ccc4ccccc4c3-c3ccc(-c4cc(-c5ccc(-c6ccccc6)cc5)nc(-c5ccccc5)n4)cc3)c21 ; CP1(=O)c2ccccc2-c2cccc(-c3ccc4ccccc4c3-c3ccc(-c4cc(-c5cccc(-c6ccccc6)c5)nc(-c5ccccc5)n4)cc3)c21 ; CP1(=O)c2ccccc2-c2ccc(-c3cc(-c4ccc(-c5cc(-c6cccc(-c7ccccc7)c6)nc(-c6ccccc6)n5)cc4)c4ccccc4c3)cc21]

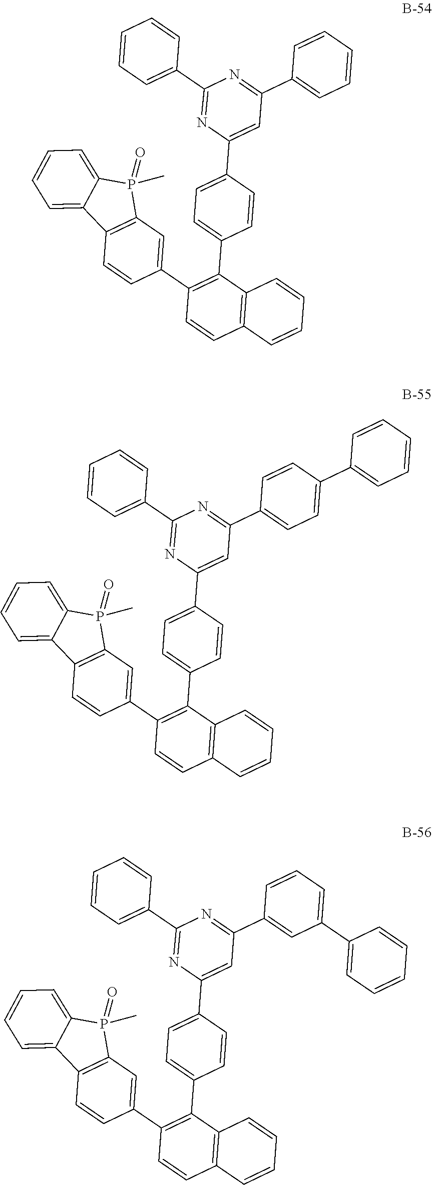 [SMILES: CP1(=O)c2ccccc2-c2ccc(-c3ccc4ccccc4c3-c3ccc(-c4cc(-c5ccccc5)nc(-c5ccccc5)n4)cc3)cc21 ; CP1(=O)c2ccccc2-c2ccc(-c3ccc4ccccc4c3-c3ccc(-c4cc(-c5ccc(-c6ccccc6)cc5)nc(-c5ccccc5)n4)cc3)cc21 ; CP1(=O)c2ccccc2-c2ccc(-c3ccc4ccccc4c3-c3ccc(-c4cc(-c5cccc(-c6ccccc6)c5)nc(-c5ccccc5)n4)cc3)cc21]

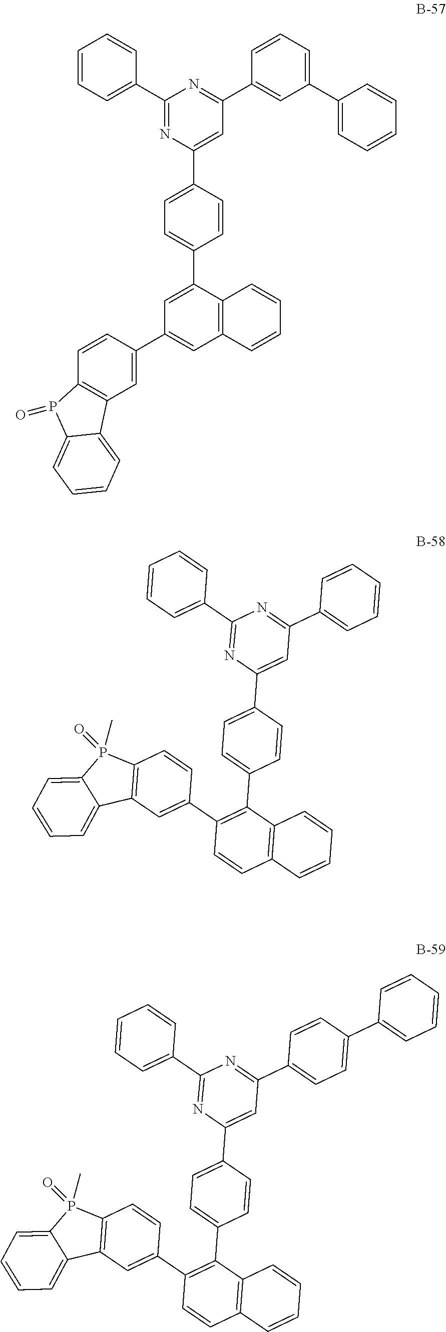

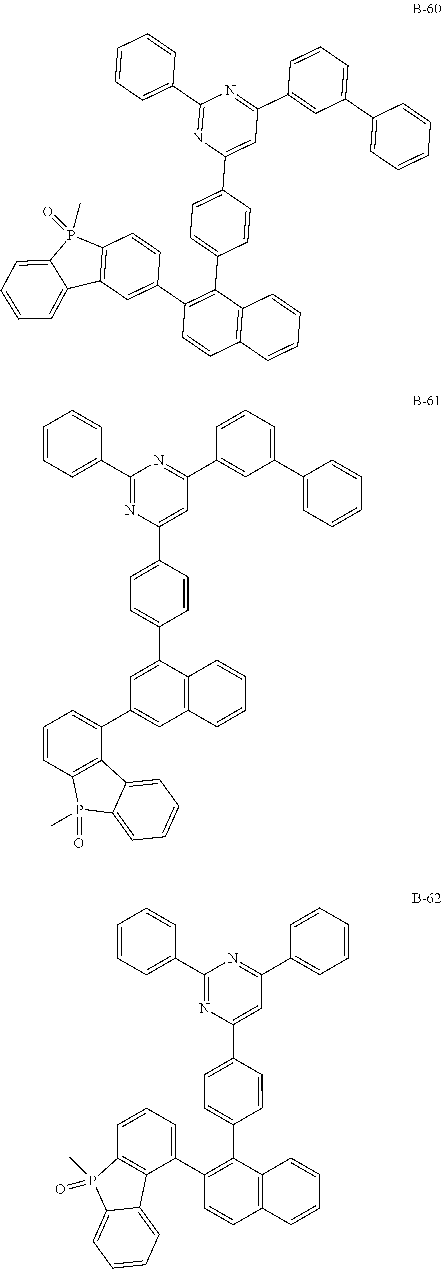 [SMILES: CP1(=O)c2ccccc2-c2cc(-c3ccc4ccccc4c3-c3ccc(-c4cc(-c5cccc(-c6ccccc6)c5)nc(-c5ccccc5)n4)cc3)ccc21 ; CP1(=O)c2ccccc2-c2c(-c3cc(-c4ccc(-c5cc(-c6cccc(-c7ccccc7)c6)nc(-c6ccccc6)n5)cc4)c4ccccc4c3)cccc21 ; CP1(=O)c2ccccc2-c2c(-c3ccc4ccccc4c3-c3ccc(-c4cc(-c5ccccc5)nc(-c5ccccc5)n4)cc3)cccc21]

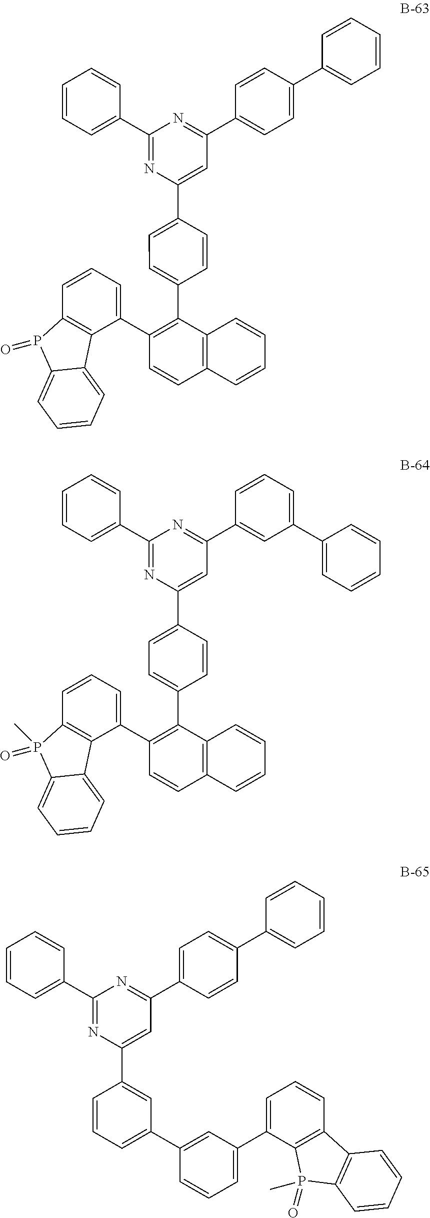

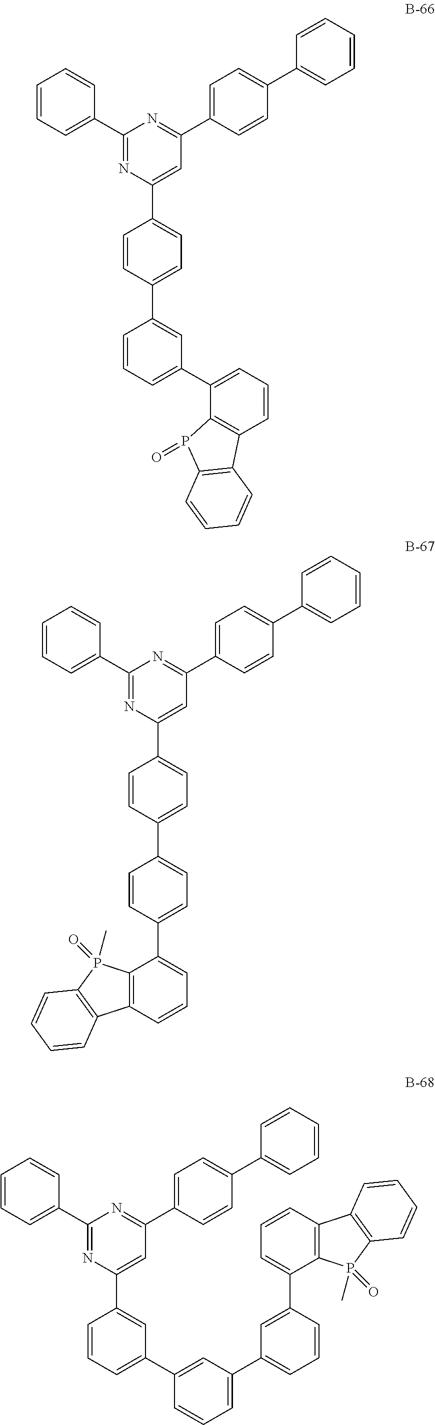

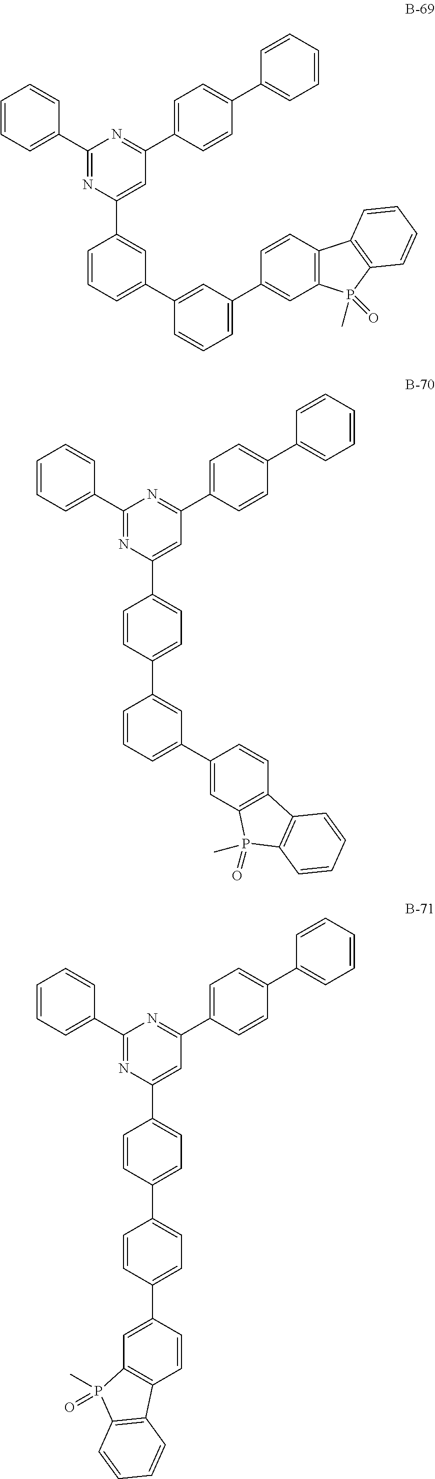 [SMILES: CP1(=O)c2ccccc2-c2ccc(-c3cccc(-c4cccc(-c5cc(-c6ccc(-c7ccccc7)cc6)nc(-c6ccccc6)n5)c4)c3)cc21 ; CP1(=O)c2ccccc2-c2ccc(-c3cccc(-c4ccc(-c5cc(-c6ccc(-c7ccccc7)cc6)nc(-c6ccccc6)n5)cc4)c3)cc21 ; CP1(=O)c2ccccc2-c2ccc(-c3ccc(-c4ccc(-c5cc(-c6ccc(-c7ccccc7)cc6)nc(-c6ccccc6)n5)cc4)cc3)cc21]

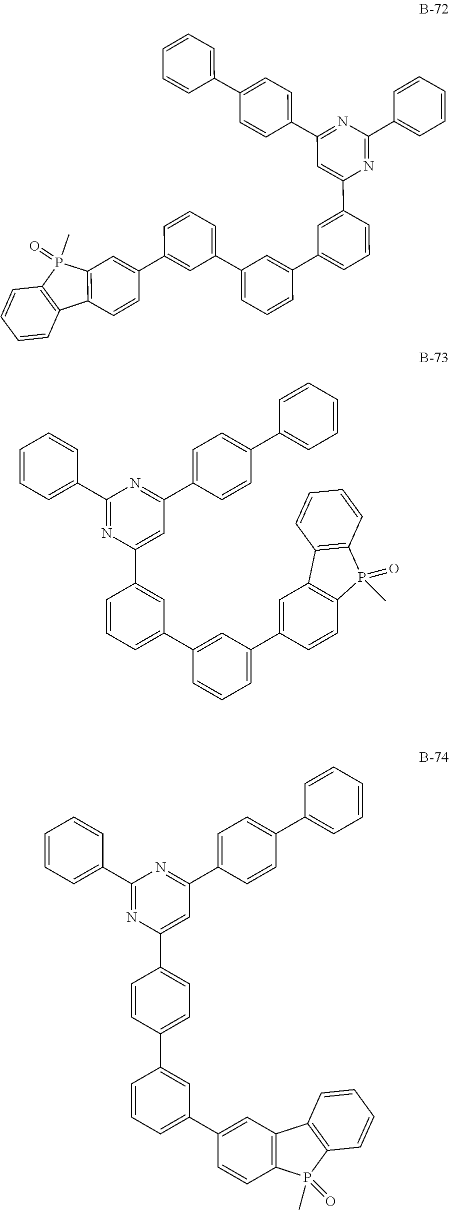 [SMILES: CP1(=O)c2ccccc2-c2ccc(-c3cccc(-c4cccc(-c5cccc(-c6cc(-c7ccc(-c8ccccc8)cc7)nc(-c7ccccc7)n6)c5)c4)c3)cc21 ; CP1(=O)c2ccccc2-c2cc(-c3cccc(-c4cccc(-c5cc(-c6ccc(-c7ccccc7)cc6)nc(-c6ccccc6)n5)c4)c3)ccc21 ; CP1(=O)c2ccccc2-c2cc(-c3cccc(-c4ccc(-c5cc(-c6ccc(-c7ccccc7)cc6)nc(-c6ccccc6)n5)cc4)c3)ccc21]

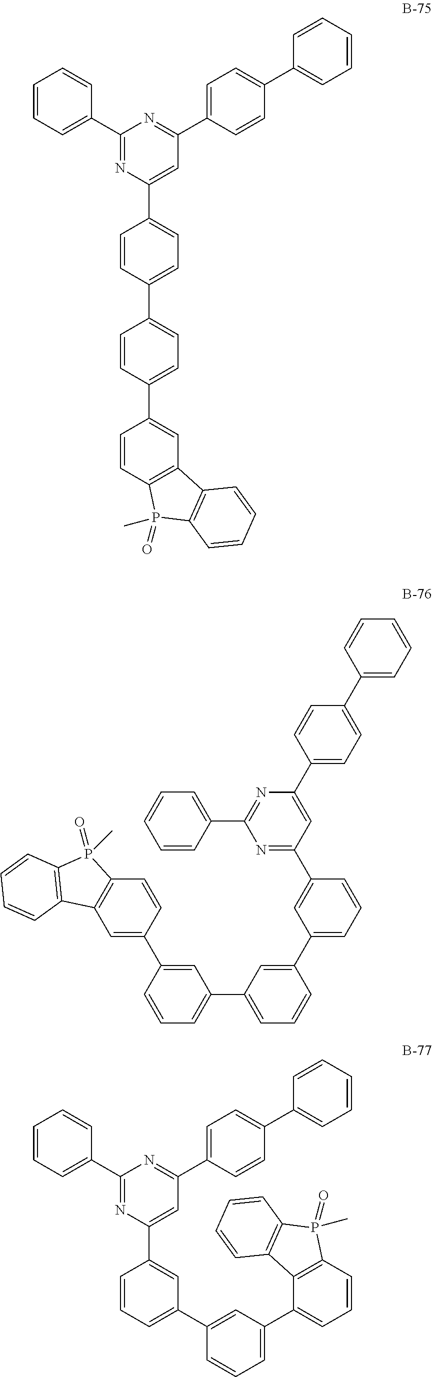

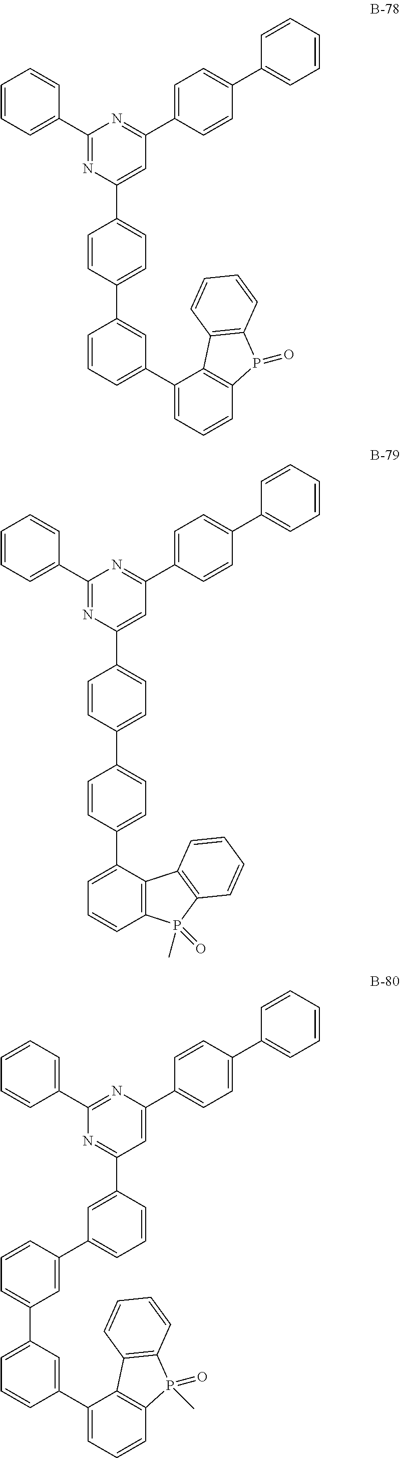

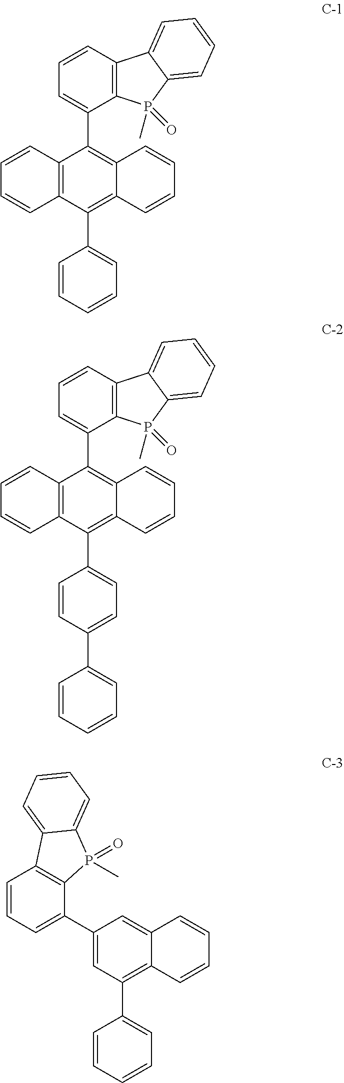

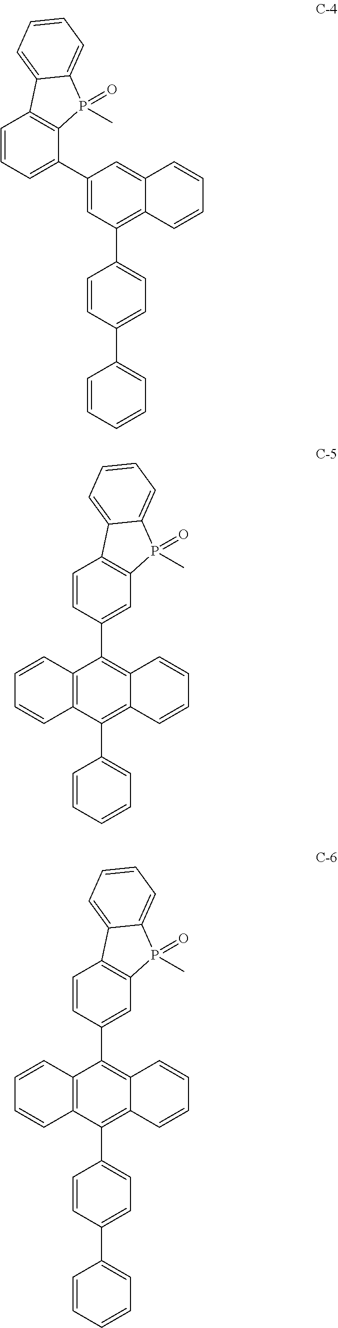

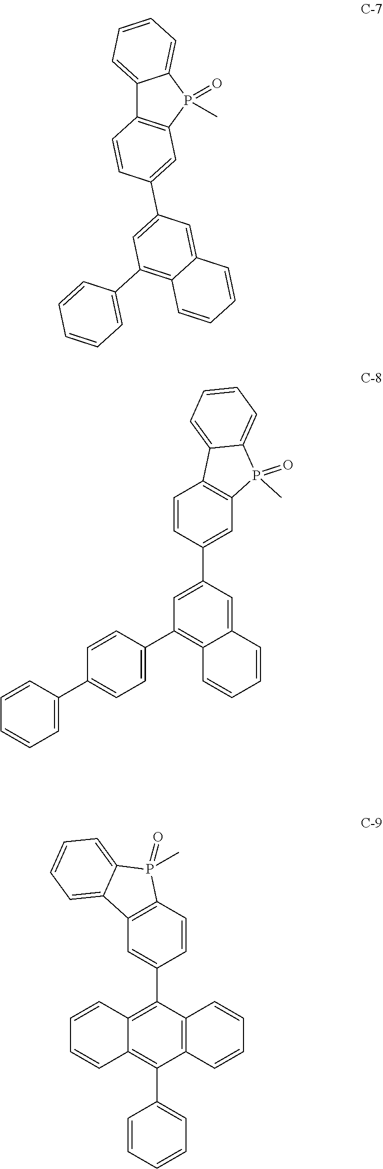 [SMILES: CP1(=O)c2ccccc2-c2ccc(-c3cc(-c4ccccc4)c4ccccc4c3)cc21 ; CP1(=O)c2ccccc2-c2ccc(-c3cc(-c4ccc(-c5ccccc5)cc4)c4ccccc4c3)cc21 ; CP1(=O)c2ccccc2-c2cc(-c3c4ccccc4c(-c4ccccc4)c4ccccc34)ccc21]

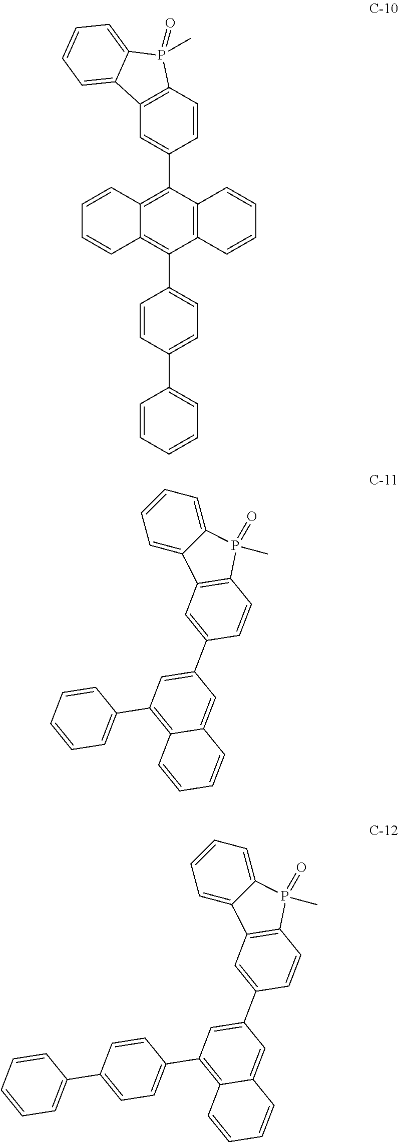

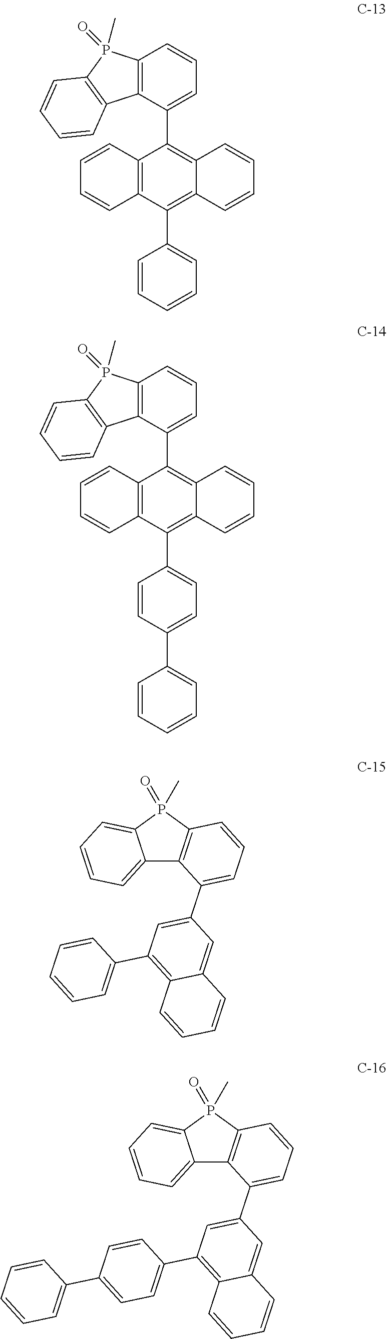

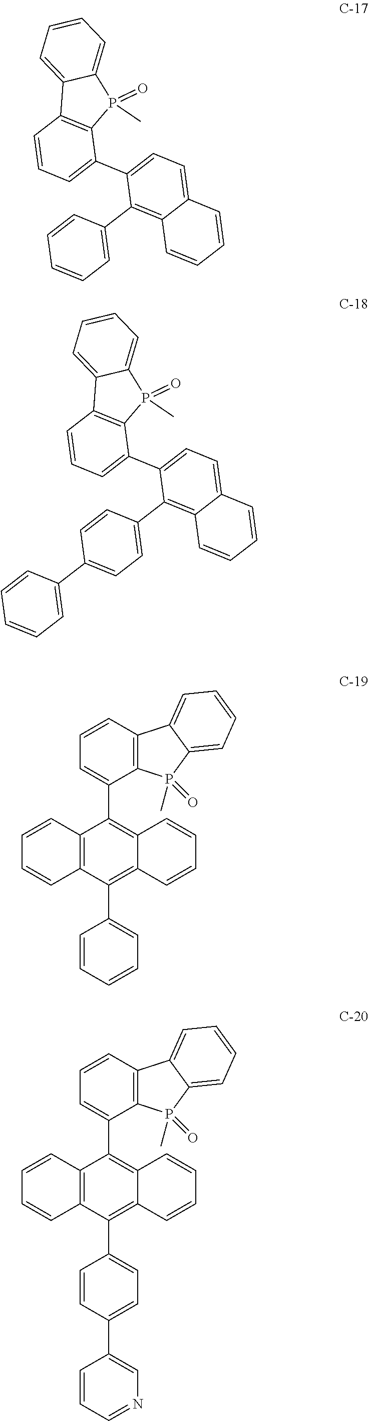

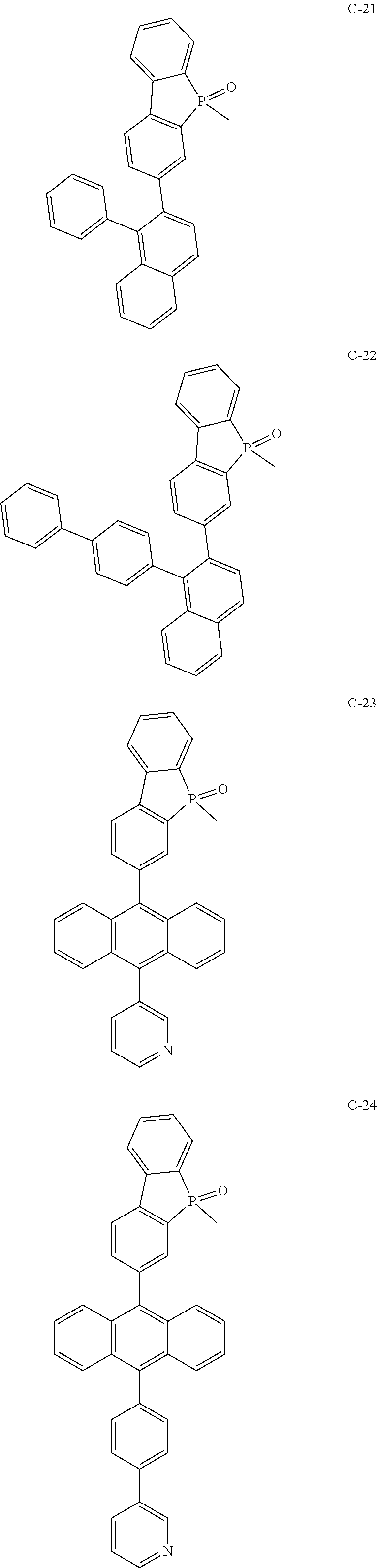

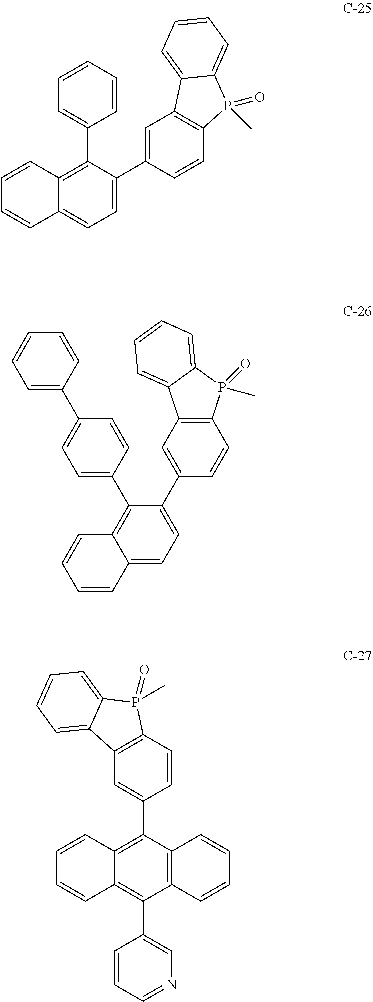 [SMILES: CP1(=O)c2ccccc2-c2cc(-c3ccc4ccccc4c3-c3ccccc3)ccc21 ; CP1(=O)c2ccccc2-c2cc(-c3ccc4ccccc4c3-c3ccc(-c4ccccc4)cc3)ccc21 ; CP1(=O)c2ccccc2-c2cc(-c3c4ccccc4c(-c4cccnc4)c4ccccc34)ccc21]

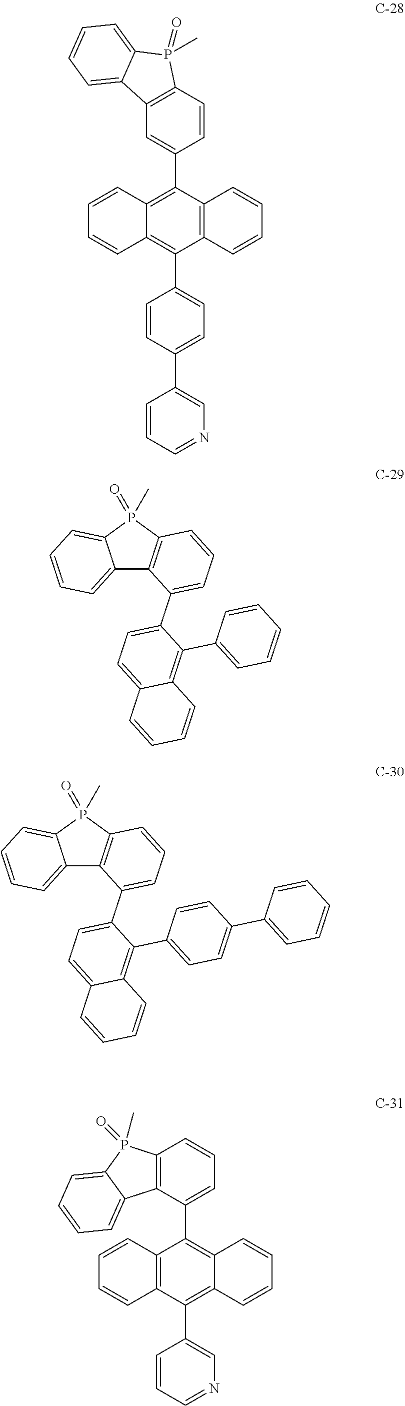

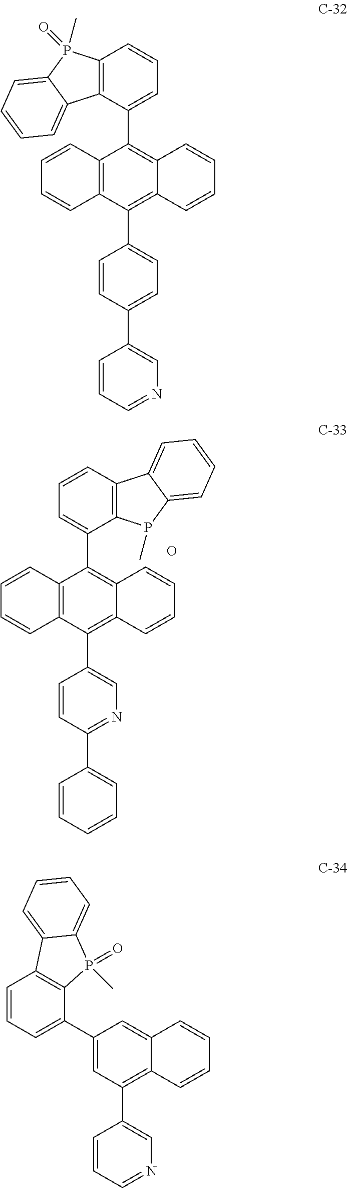

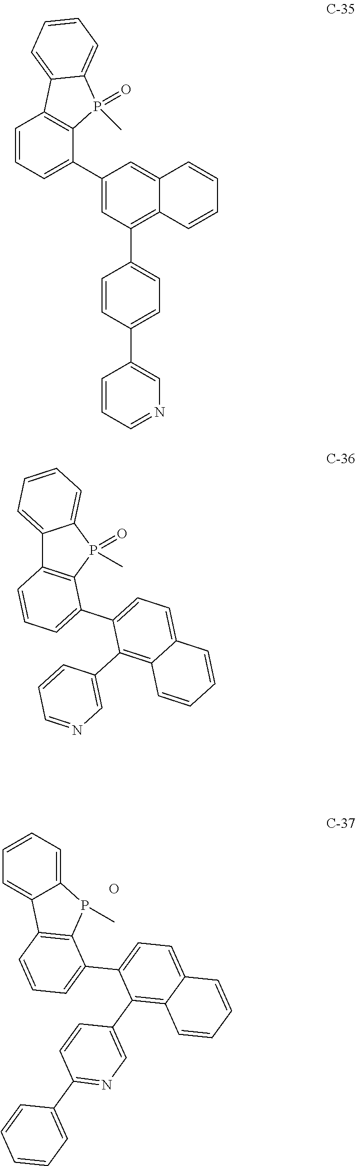

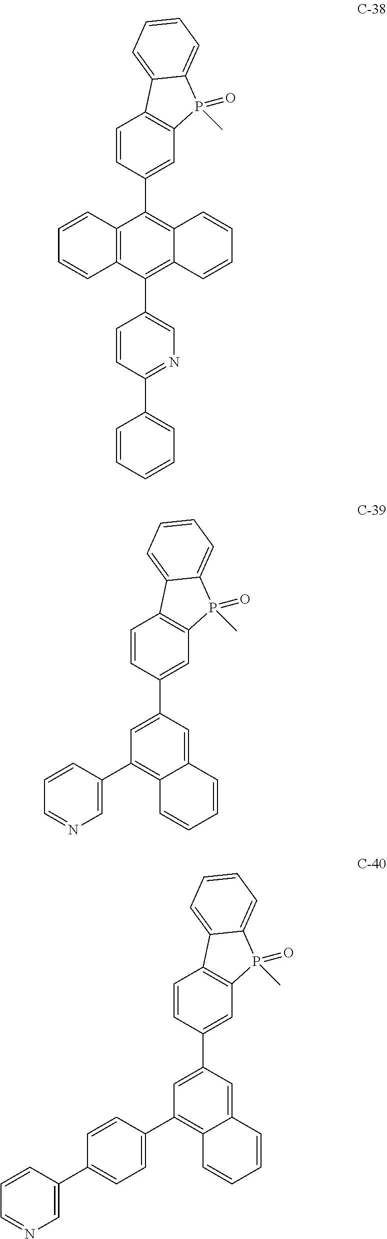 [SMILES: CP1(=O)c2ccccc2-c2ccc(-c3c4ccccc4c(-c4ccc(-c5ccccc5)nc4)c4ccccc34)cc21 ; CP1(=O)c2ccccc2-c2ccc(-c3cc(-c4cccnc4)c4ccccc4c3)cc21 ; CP1(=O)c2ccccc2-c2ccc(-c3cc(-c4ccc(-c5cccnc5)cc4)c4ccccc4c3)cc21]

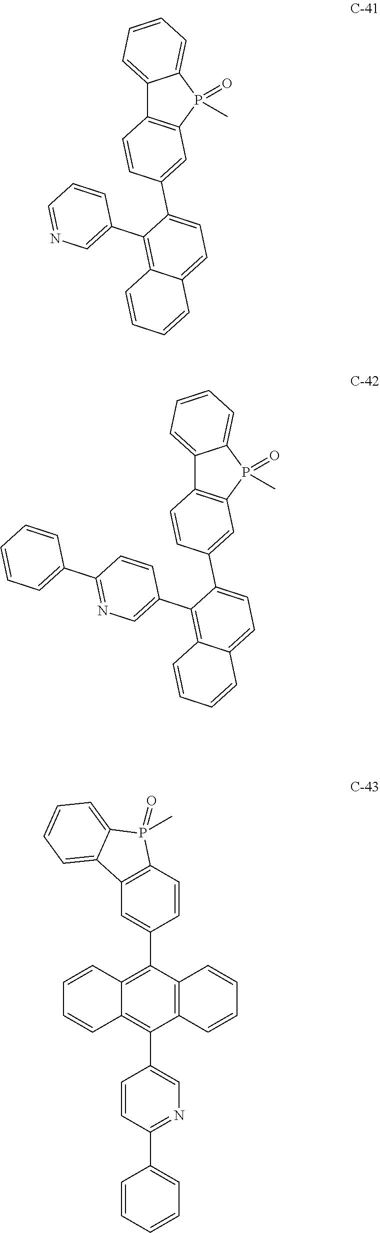 [SMILES: CP1(=O)c2ccccc2-c2ccc(-c3ccc4ccccc4c3-c3cccnc3)cc21 ; CP1(=O)c2ccccc2-c2ccc(-c3ccc4ccccc4c3-c3ccc(-c4ccccc4)nc3)cc21 ; CP1(=O)c2ccccc2-c2cc(-c3c4ccccc4c(-c4ccc(-c5ccccc5)nc4)c4ccccc34)ccc21]

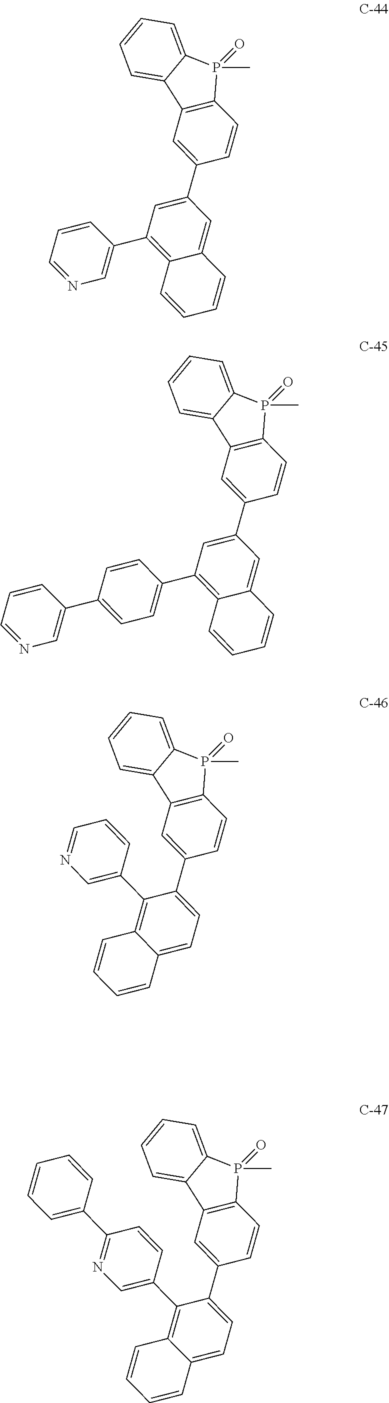

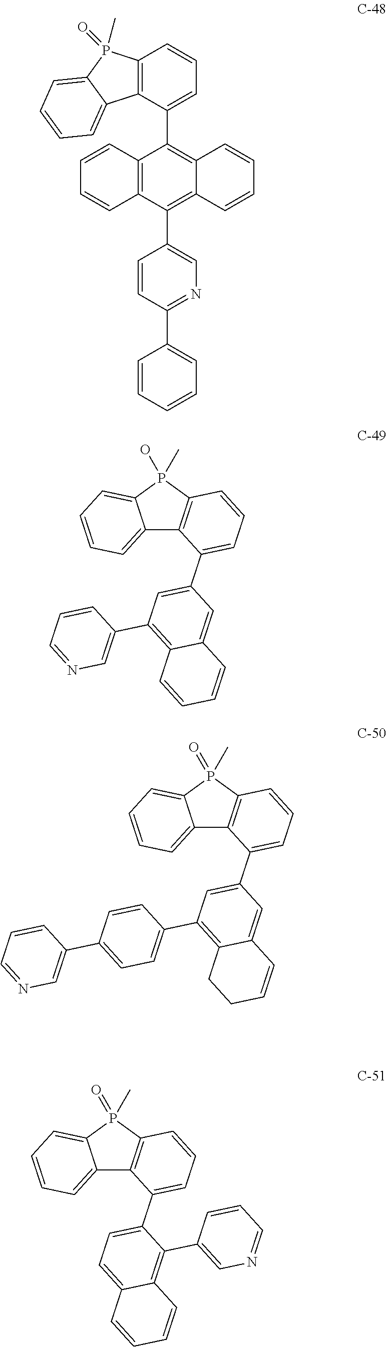

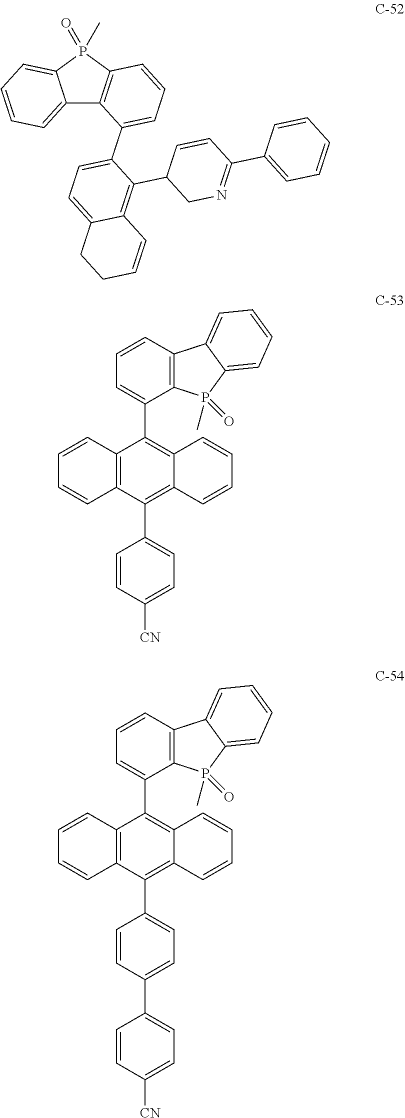 [SMILES: CP1(=O)c2ccccc2-c2c(-c3ccc4c(c3C3C=CC(c5ccccc5)=NC3)C=CCC4)cccc21 ; CP1(=O)c2ccccc2-c2cccc(-c3c4ccccc4c(-c4ccc(C#N)cc4)c4ccccc34)c21 ; CP1(=O)c2ccccc2-c2cccc(-c3c4ccccc4c(-c4ccc(-c5ccc(C#N)cc5)cc4)c4ccccc34)c21]

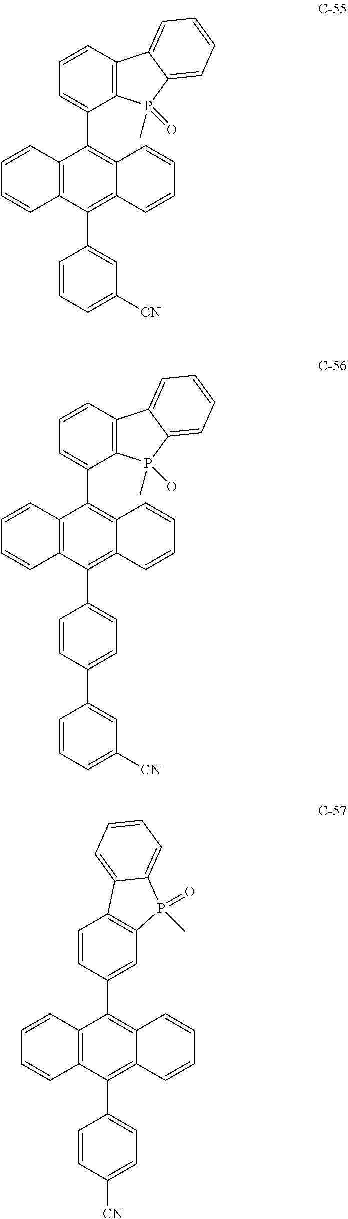

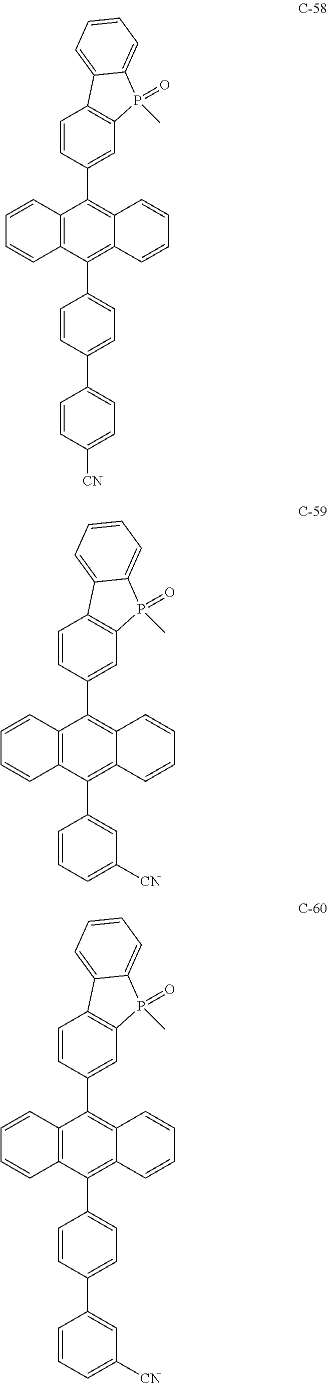

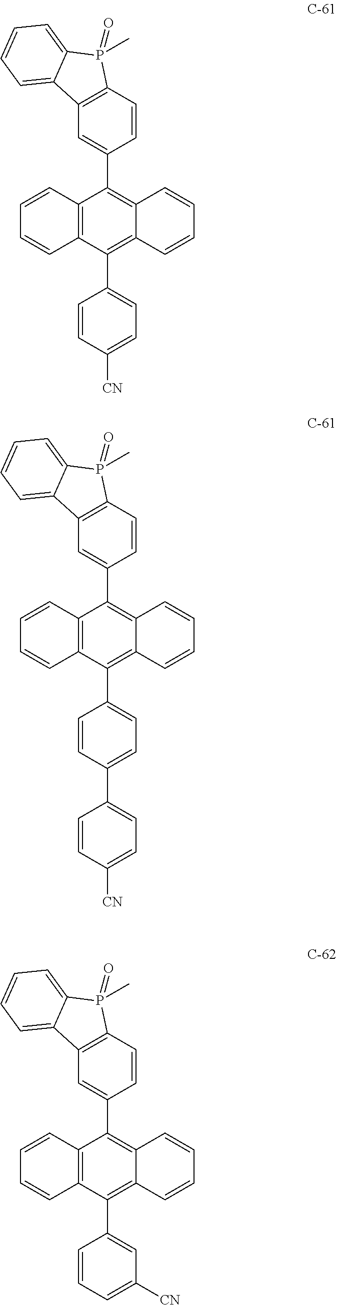 [SMILES: CP1(=O)c2ccccc2-c2cc(-c3c4ccccc4c(-c4ccc(C#N)cc4)c4ccccc34)ccc21 ; CP1(=O)c2ccccc2-c2cc(-c3c4ccccc4c(-c4ccc(-c5ccc(C#N)cc5)cc4)c4ccccc34)ccc21 ; CP1(=O)c2ccccc2-c2cc(-c3c4ccccc4c(-c4cccc(C#N)c4)c4ccccc34)ccc21]

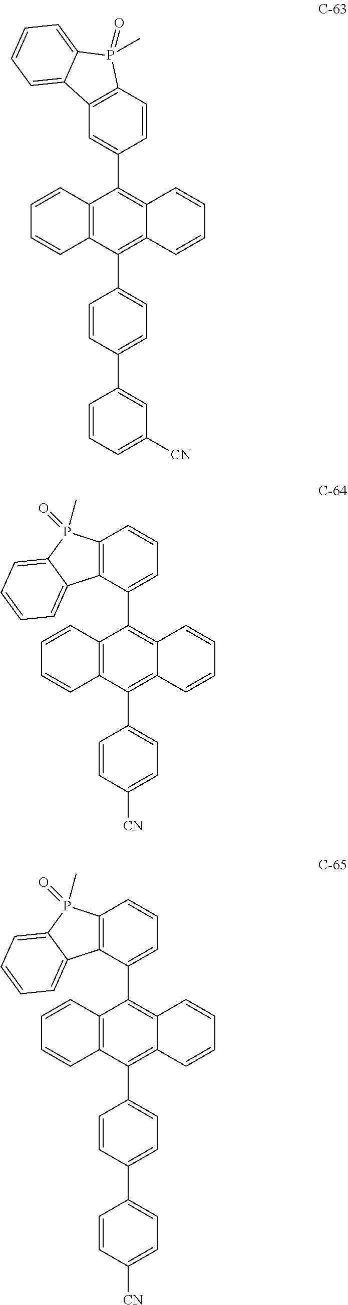 [SMILES: CP1(=O)c2ccccc2-c2cc(-c3c4ccccc4c(-c4ccc(-c5cccc(C#N)c5)cc4)c4ccccc34)ccc21 ; CP1(=O)c2ccccc2-c2c(-c3c4ccccc4c(-c4ccc(C#N)cc4)c4ccccc34)cccc21 ; CP1(=O)c2ccccc2-c2c(-c3c4ccccc4c(-c4ccc(-c5ccc(C#N)cc5)cc4)c4ccccc34)cccc21]

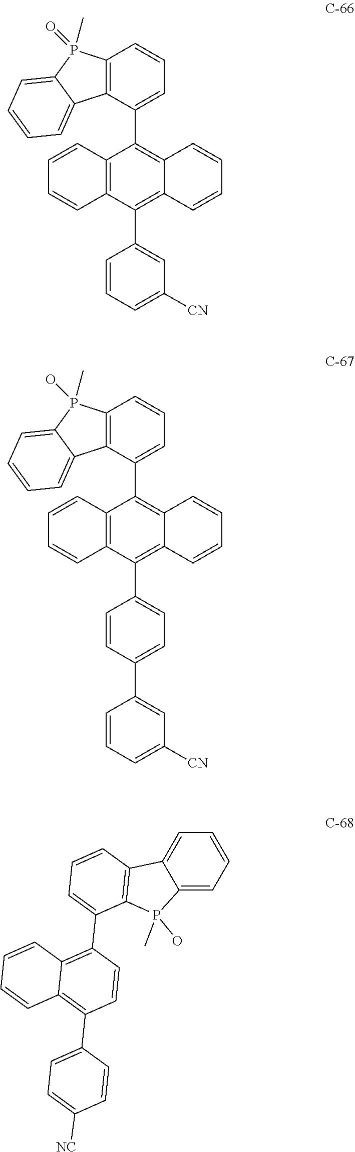

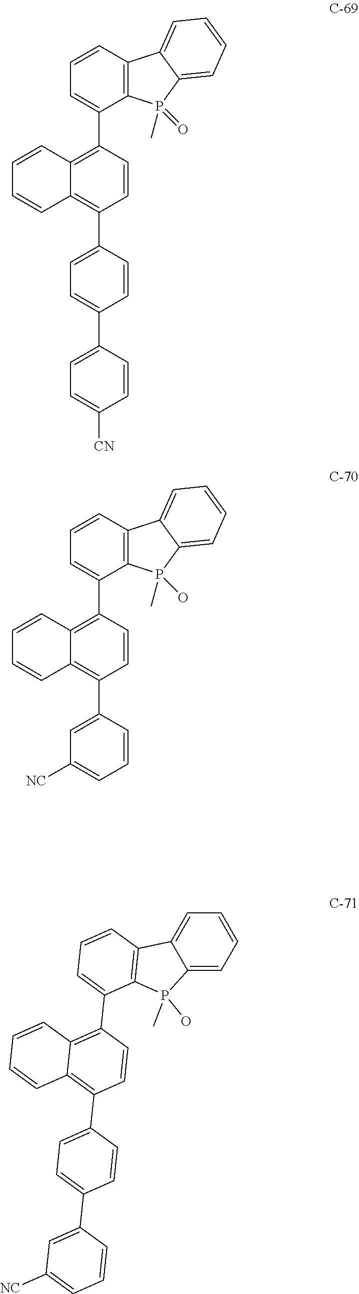

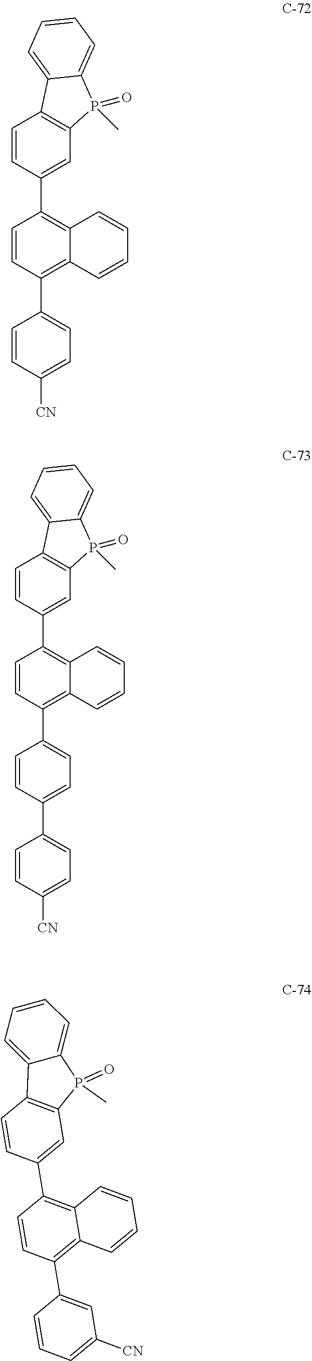 [SMILES: CP1(=O)c2ccccc2-c2ccc(-c3ccc(-c4ccc(C#N)cc4)c4ccccc34)cc21 ; CP1(=O)c2ccccc2-c2ccc(-c3ccc(-c4ccc(-c5ccc(C#N)cc5)cc4)c4ccccc34)cc21 ; CP1(=O)c2ccccc2-c2ccc(-c3ccc(-c4cccc(C#N)c4)c4ccccc34)cc21]

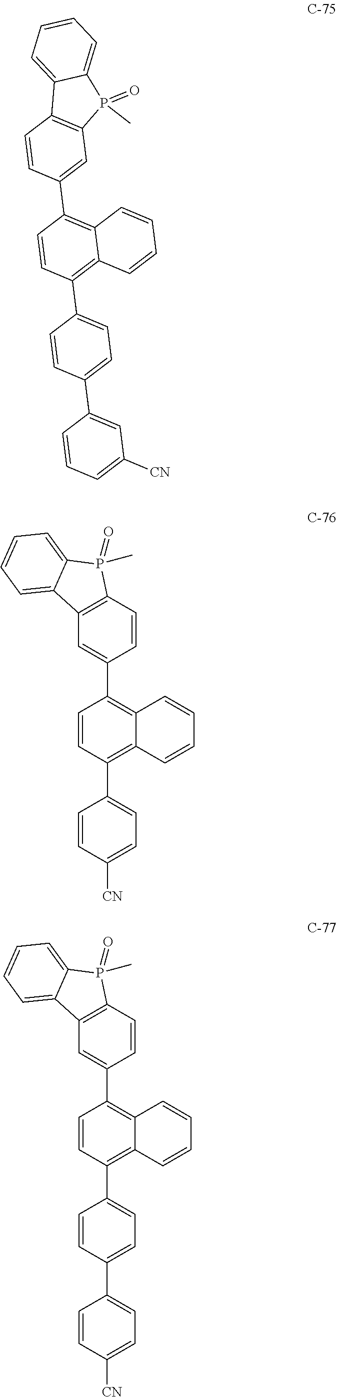

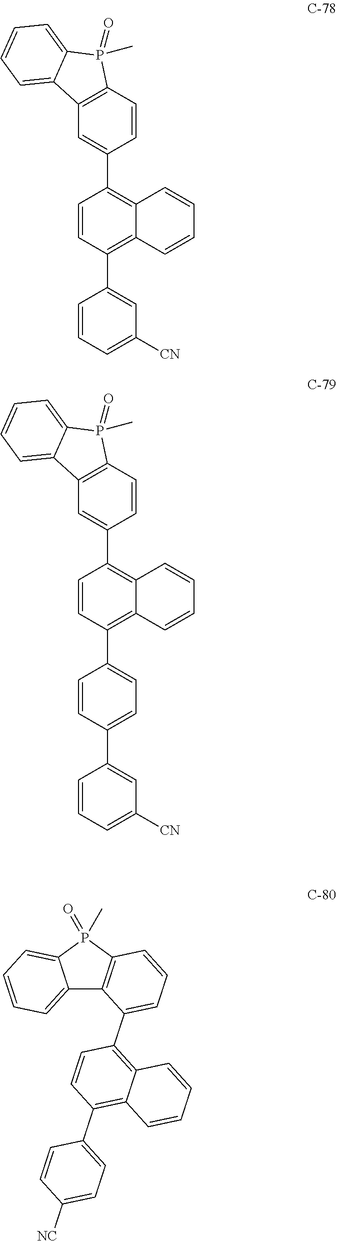

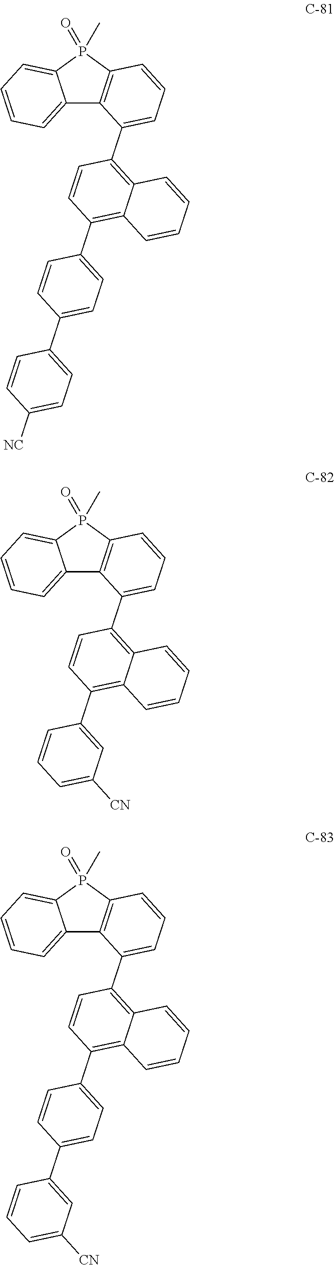 [SMILES: CP1(=O)c2ccccc2-c2c(-c3ccc(-c4ccc(-c5ccc(C#N)cc5)cc4)c4ccccc34)cccc21 ; CP1(=O)c2ccccc2-c2c(-c3ccc(-c4cccc(C#N)c4)c4ccccc34)cccc21 ; CP1(=O)c2ccccc2-c2c(-c3ccc(-c4ccc(-c5cccc(C#N)c5)cc4)c4ccccc34)cccc21]

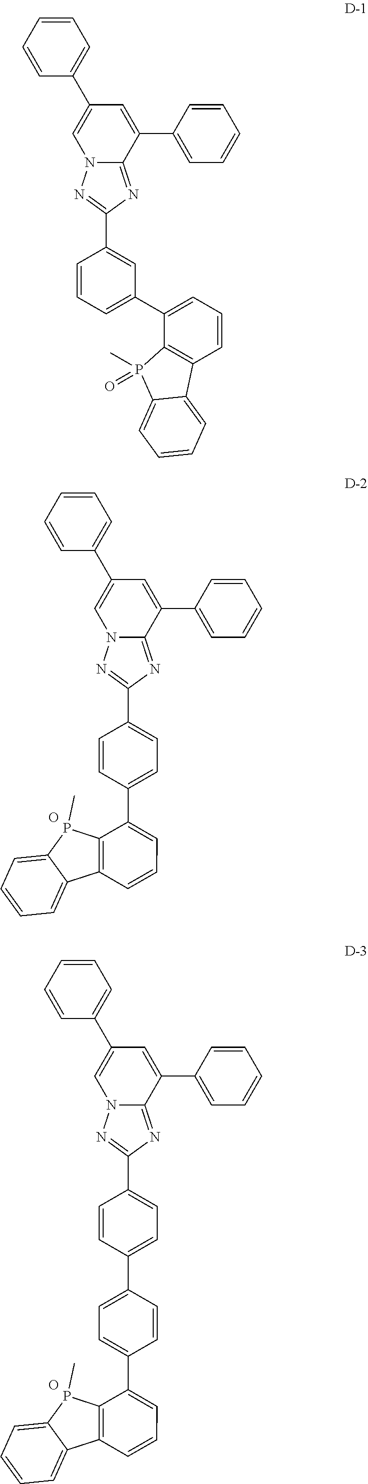

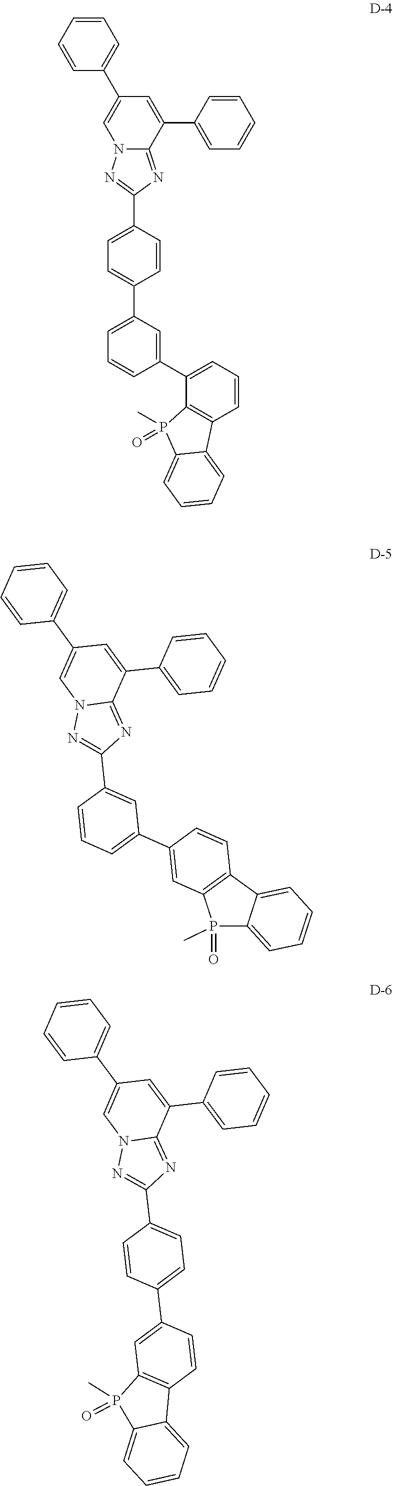 [SMILES: CP1(=O)c2ccccc2-c2cccc(-c3cccc(-c4ccc(-c5nc6c(-c7ccccc7)cc(-c7ccccc7)cn6n5)cc4)c3)c21 ; CP1(=O)c2ccccc2-c2ccc(-c3cccc(-c4nc5c(-c6ccccc6)cc(-c6ccccc6)cn5n4)c3)cc21 ; CP1(=O)c2ccccc2-c2ccc(-c3ccc(-c4nc5c(-c6ccccc6)cc(-c6ccccc6)cn5n4)cc3)cc21]

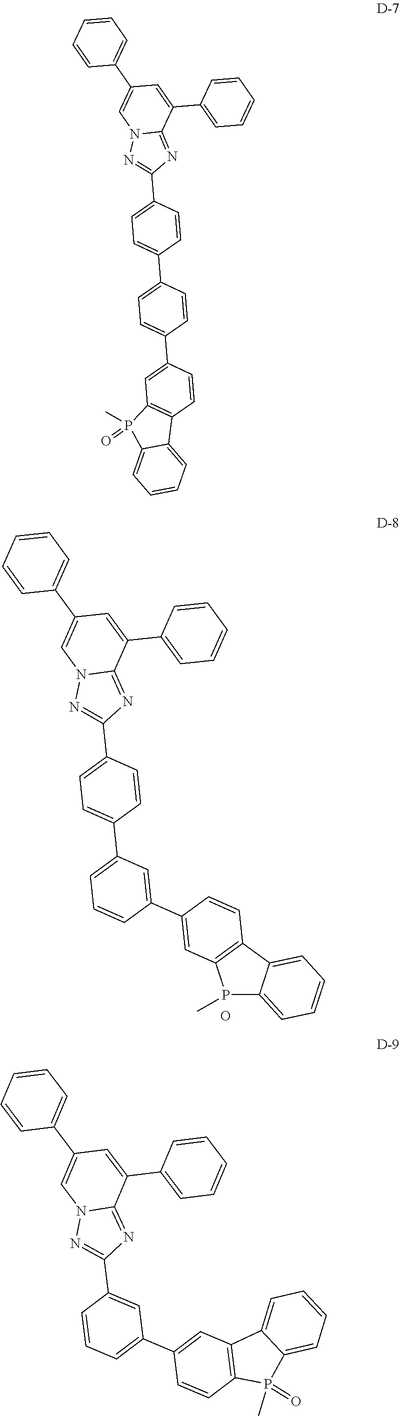

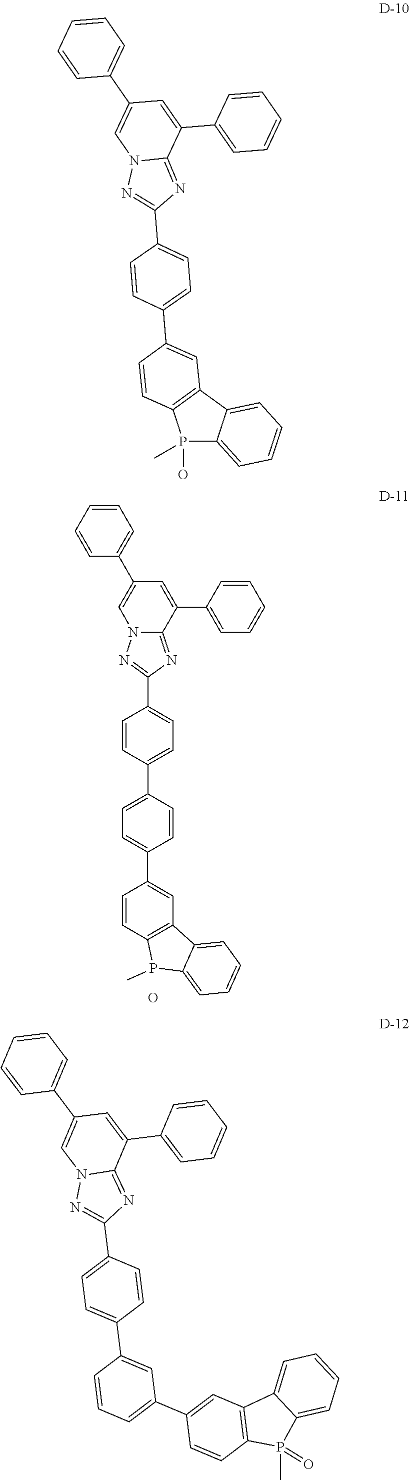

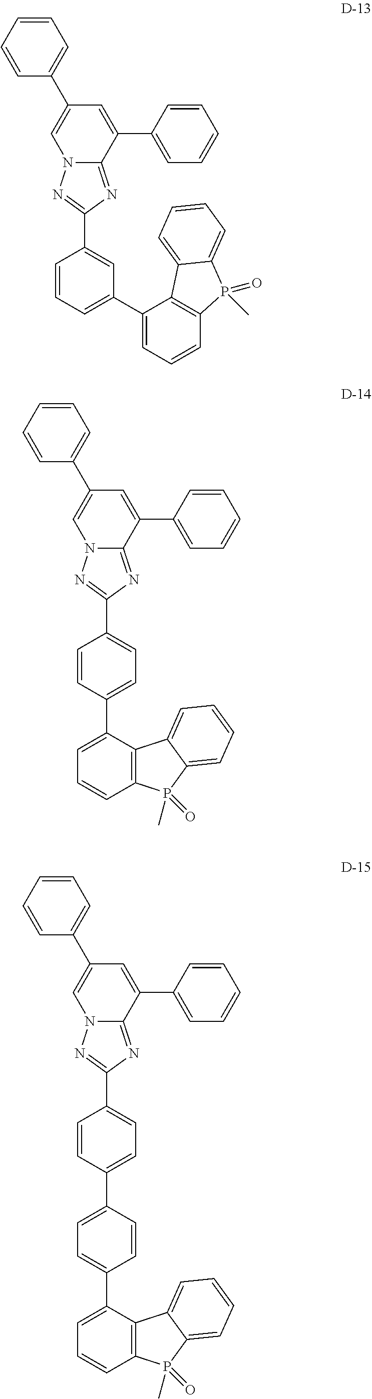 [SMILES: CP1(=O)c2ccccc2-c2c(-c3cccc(-c4nc5c(-c6ccccc6)cc(-c6ccccc6)cn5n4)c3)cccc21 ; CP1(=O)c2ccccc2-c2c(-c3ccc(-c4nc5c(-c6ccccc6)cc(-c6ccccc6)cn5n4)cc3)cccc21 ; CP1(=O)c2ccccc2-c2c(-c3ccc(-c4ccc(-c5nc6c(-c7ccccc7)cc(-c7ccccc7)cn6n5)cc4)cc3)cccc21]

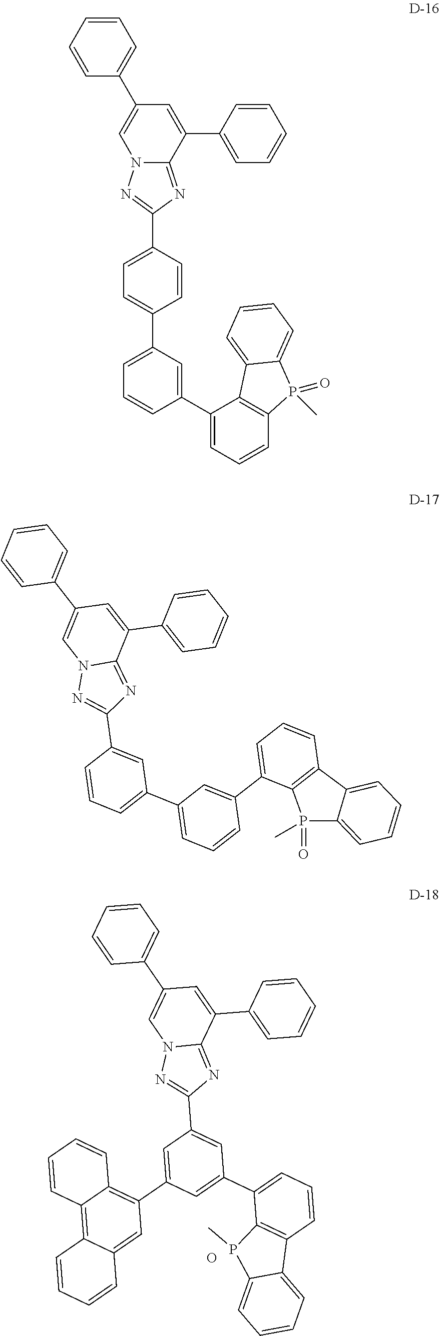

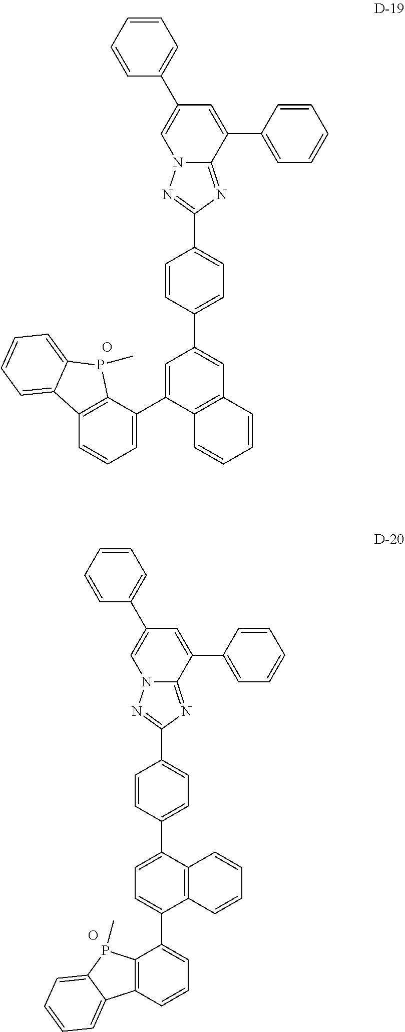

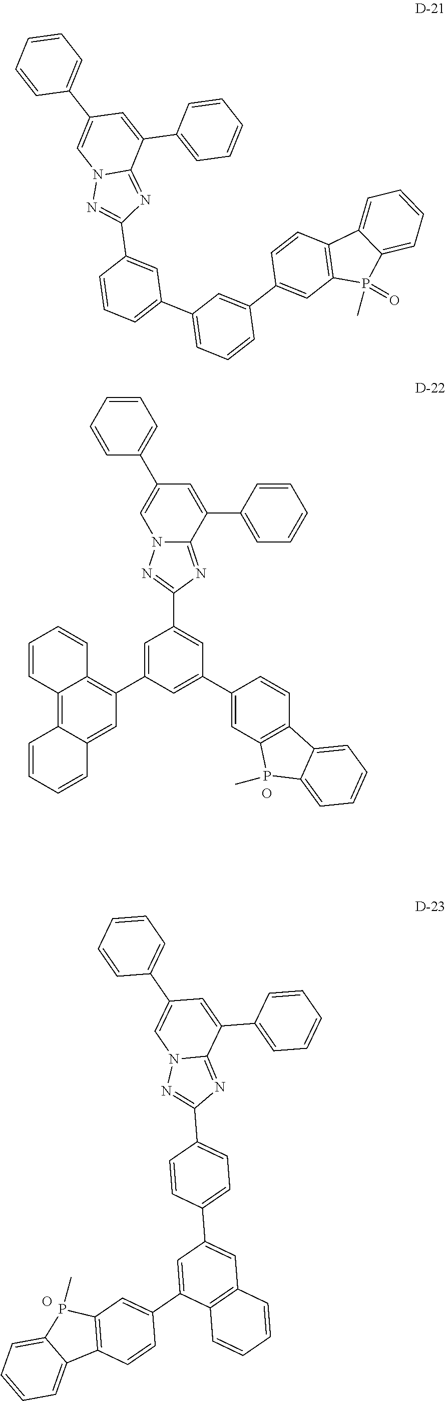

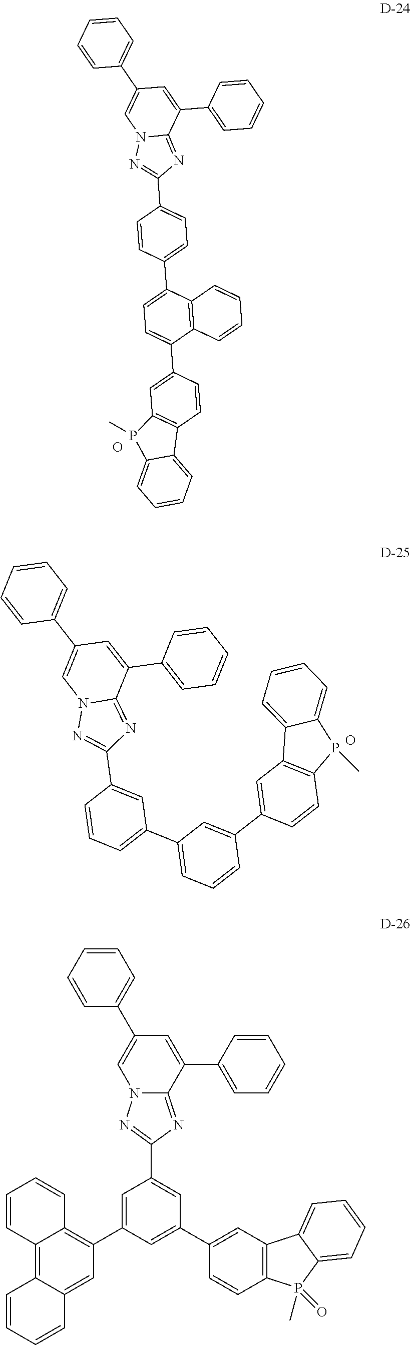

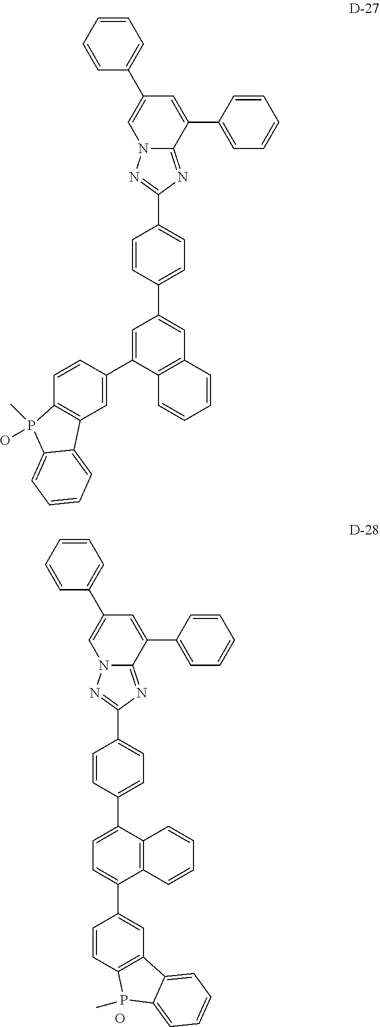

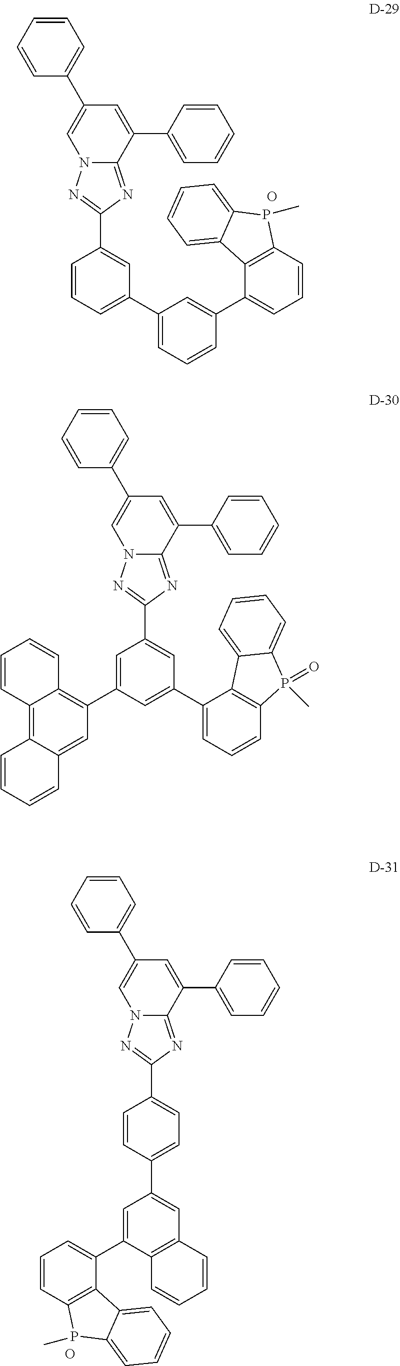

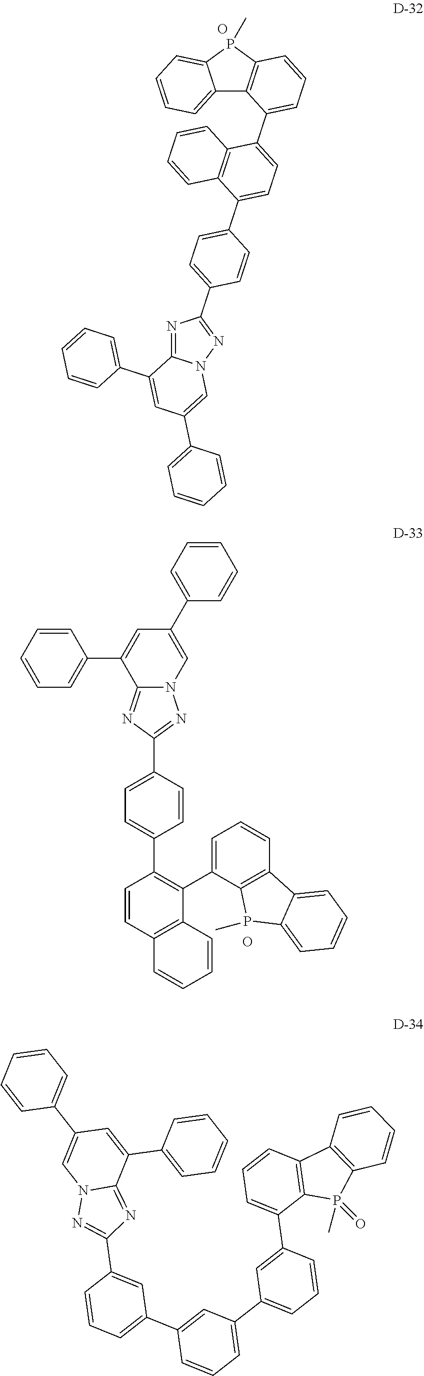

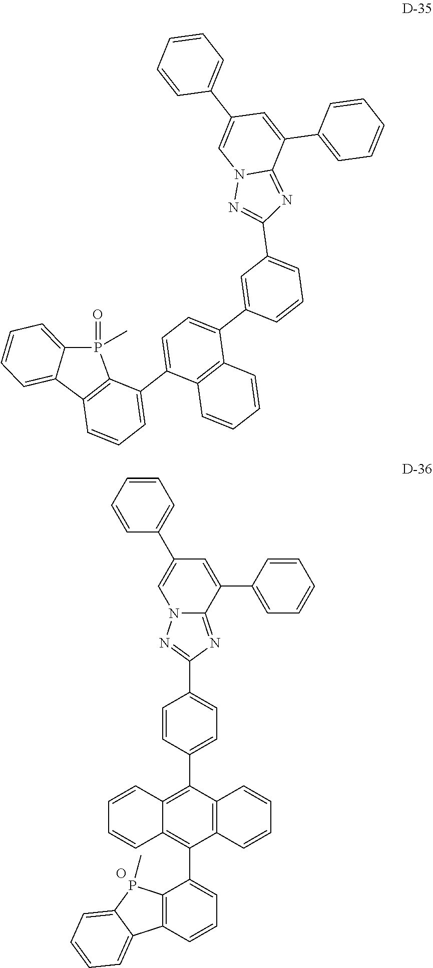

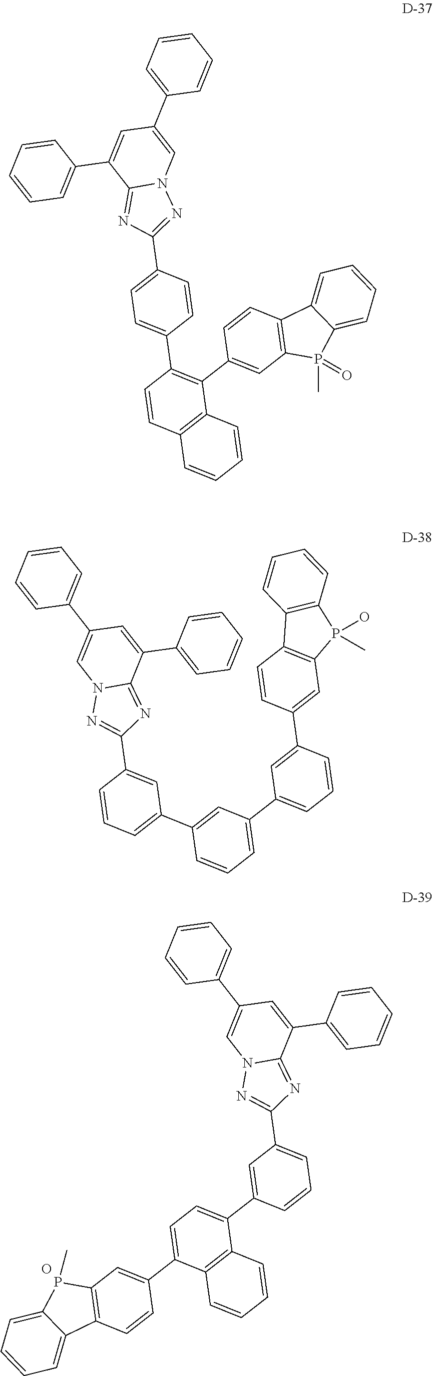

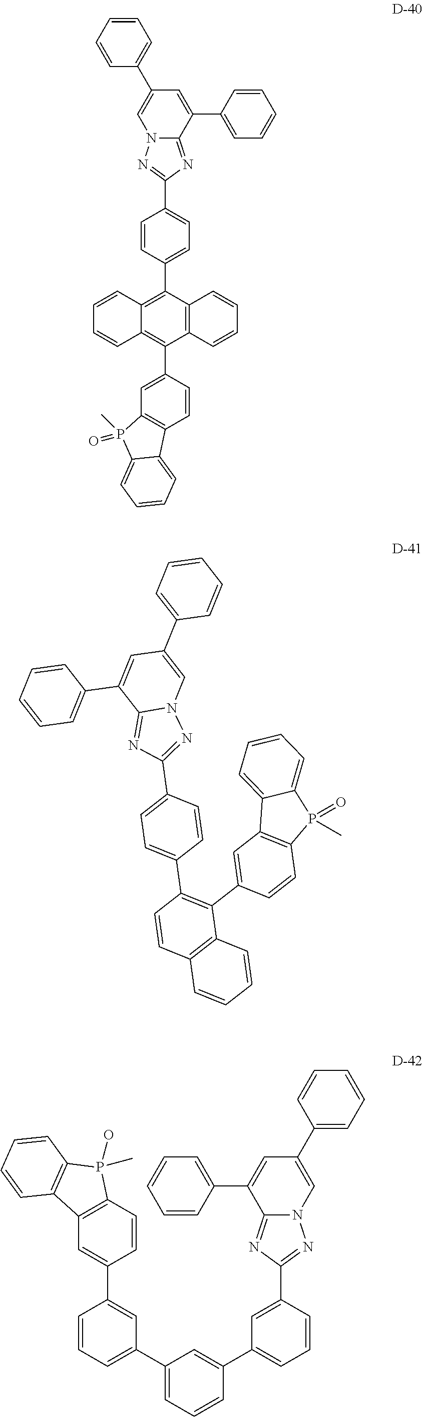

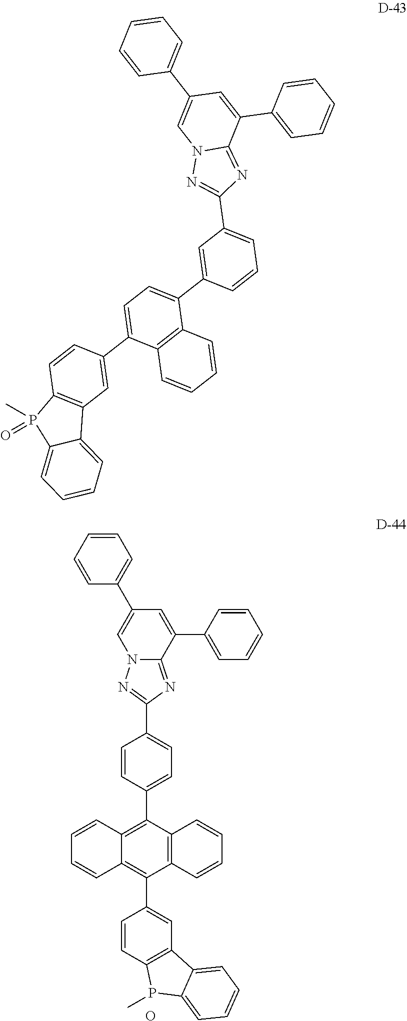

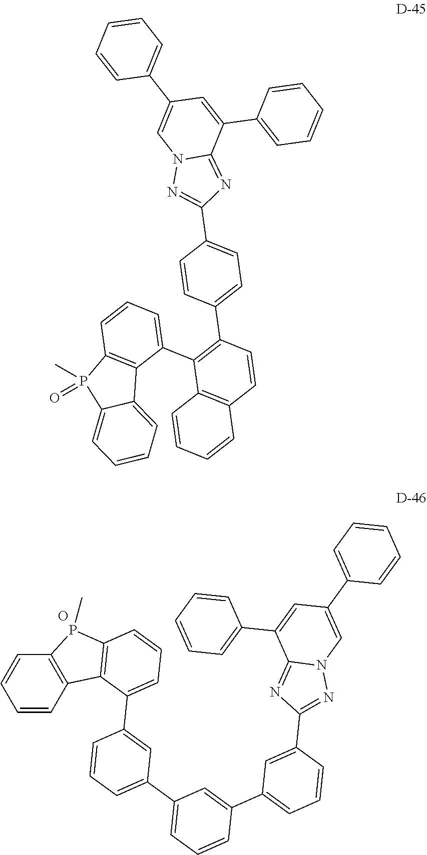

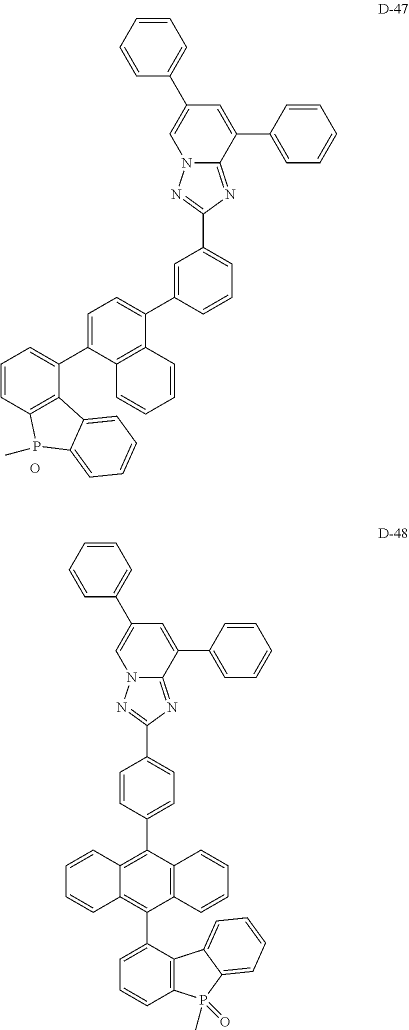

As used herein, “alkyl” refers to a monovalent radical derived from a saturated, linear, or branched hydrocarbon having 1 to 40 carbon atoms. Examples of such alkyl include, but are not limited to, methyl, ethyl, propyl, isobutyl, sec-butyl, pentyl, iso-amyl, hexyl, and the like.

As used herein, “alkenyl” refers to a monovalent radical derived from an unsaturated, linear or branched hydrocarbon of 2 to 40 carbon atoms, with at least one carbon-carbon double bond therein. Examples of such alkenyl include, but are not limited to, vinyl, allyl, isopropenyl, 2-butenyl, and the like.

As used herein, “alkynyl” refers to a monovalent radical derived from an unsaturated, linear or branched hydrocarbon of 2 to 40 carbon atoms, with at least one carbon-carbon triple bond therein. Examples of such alkynyl include, but are not limited to, ethynyl, 2-propynyl, or the like.

As used herein, “cycloalkyl” refers to a monovalent radical derived from a monocyclic or polycyclic non-aromatic hydrocarbon of 3 to 40 carbon atoms. Examples of such cycloalkyl include, but are not limited to, cyclopropyl, cyclopentyl, cyclohexyl, norbornyl, adamantine, or the like.

As used herein, “heterocycloalkyl” refers to a monovalent radical derived from a non-aromatic hydrocarbon of 3 to 40 nuclear atoms, where one or more carbons and preferably one to three carbons in the ring are substituted with a heteroatom such as N, O, S or Se. Examples of such heterocycloalkyl include, but are not limited to, morpholine, piperazine, or the like.

As used herein, “aryl” refers to a monovalent radical derived from an aromatic hydrocarbon of C₆ to C₆₀ structured to consist of a single ring or have two or more rings combined with each other. In addition, a form in which two or more rings are pendant (e.g., simply attached) to or condensed with each other may also be included. Examples of such aryl include, but are not limited to, phenyl, naphthyl, phenanthryl, anthryl, or the like.

As used herein, “heteroaryl” refers to a monovalent radical derived from a monoheterocyclic or polyheterocyclic aromatic hydrocarbon of 5 to 60 nuclear atoms wherein one or more carbons and preferably one to three carbons in the ring are substituted with a heteroatom such as N, O, S or Se and which may include a form in which two or more rings are pendant to or condensed with each other or a form condensed with an aryl group. Examples of such heteroaryl include, but are not limited to, 6-membered monocyclic rings such as pyridyl, pyrazinyl, pyrimidinyl, pyridazinyl, and triazinyl; polycyclic ring such as phenoxathienyl, indolizinyl, indolyl, purinyl, quinolyl, benzothiazole and carbazolyl; 2-furanyl; N-imidazolyl; 2-isoxazolyl; 2-pyridinyl; 2-pyrimidinyl, or the like.

As used herein, “alkyloxy” refers to a monovalent radical represented by R′O—, where R′ is an alkyl group of 1 to 40 carbon atoms and may have a linear, branched or cyclic structure. Examples of such alkyloxy include, but are not limited to, methoxy, ethoxy, n-propoxy, 1-propoxy, t-butoxy, n-butoxy, pentoxy, or the like.

As used herein, “aryloxy” refers to a monovalent radical represented by RO—, where R is an aryl group of 5 to 40 carbon atoms. Examples of such aryloxy may include, but are not limited to, phenyloxy, naphthyloxy, diphenyloxy, or the like.

As used herein, “alkylsilyl” refers to a silyl radical substituted with an alkyl group of 1 to 40 carbon atoms and is intended to encompass di- and tri-alkylsilyl as well as mono-alkylsilyl. In addition, “arylsilyl” refers to a silyl radical substituted with an aryl group of 5 to 60 carbon atoms and is intended to encompass poly-arylsilyl such as di- and tri-arylsilyl as well as mono-arylsilyl.

As used herein, “alkylboron” refers to a boron radical substituted with an alkyl group of 1 to 40 carbon atoms, and “arylboron” refers to a boron radical substituted with an aryl group of 6 to 60 carbon atoms.

As used herein, “alkylphosphinyl” refers to a phosphine radical substituted with an alkyl group of 1 to 40 carbon atoms and is intended to encompass di-alkylphosphinyl as well as mono-alkylphosphinyl. As used herein, “arylphosphinyl” refers to a phosphine substituted with a monoaryl or diaryl of 6 to 60 carbon atoms, and is intended to encompass di-arylphosphinyl as well as mono-arylphosphinyl.

As used herein, “arylamine” refers to an amine substituted with an aryl group of 6 to 60 carbon atoms and is indented to encompass mono- and diheteroarylamines.

As used herein, “heteroarylamine” refers to an amine substituted with a heteroaryl group of 5 to 60 nuclear atoms and is intended to encompass mono- and diheteroarylamine.

As used herein, “(hetero)arylamine” refers to amine substituted with an aryl group of 6 to 60 carbon atoms (a heteroaryl group of 5 to 60 nuclear atoms.

As used herein, “fused ring” refers to a fused aliphatic ring of 3 to 40 carbon atoms, a fused aromatic ring of 6 to 60 carbon atoms, a fused heteroaliphatic ring of 3 to 60 nuclear atoms, a fused heteroaromatic ring of 5 to 60 nuclear atoms, or a combination thereof

### <Organic Electroluminescent Device>

Also, the present disclosure provides an organic electroluminescent device (hereinafter, “organic EL device”) including the compound represented by chemical formula 1.

More specifically, the organic EL device according to the present disclosure includes an anode (100), a cathode (200), and at least one organic layer (300) interposed between the anode and the cathode, wherein the at least one organic layer includes the compound represented by chemical formula 1. In this regard, the compound may be used solely or in combination with (an)other compound(s) of chemical formula 1.

The at least one organic layer (300) may include at least one of a hole injection layer (310), a hole transport layer (320), a light-emitting layer (330), an electron transport auxiliary layer (360), an electron transport layer (340), and an electron injection layer (350) and includes the compound represented by chemical formula 1. Specifically, the organic layer including the compound of chemical formula 1 may be at least one of a light-emitting layer (330), an electron transport layer (340), and an electron transport auxiliary layer (360).

According to an embodiment, the at least one organic layer includes a hole injection layer, a hole transport layer, a light-emitting layer, an electron transport layer, and an electron injection layer and optionally further includes an electron transport auxiliary layer, wherein the light-emitting layer contains a host and a dopant, the host being a compound represented by chemical formula 1. In this regard, the light-emitting layer of the present disclosure may contain a compound known in the art as a second host in addition to the compound of chemical formula 1.

In the present disclosure, the host may be contained in an amount of about 70 to 99.9% by weight, based on the total weight of the light-emitting layer, with the content of the dopant amounting to about 0.1 to 30% by weight.

When the compound represented by chemical formula 1 is included as a material for the light-emitting layer in an organic EL device, specifically as a host material for blue, green, and red phosphorescent light, the binding force between holes and electrons in the light-emitting layer increases, thus improving the efficiency (luminous efficiency and power efficiency), lifespan, brightness, and operating voltage of organic electroluminescent devices. Specifically, the compound represented by Chemical Formula 1 is preferably included as a green and/or red phosphorescent host, fluorescent host, or dopant material in organic EL devices. Particularly preferably, the compound represented by chemical formula 1 of the present disclosure is a high-efficiency green phosphorescent exciplex N-type host material for the light-emitting layer.

In another embodiment, the at least one organic layer may include a hole injection layer, hole transport layer, light-emitting layer, electron transport layer, and electron injection layer, and optionally, an additional electron transport assisting layer. The electron transport layer contains the compound represented by chemical formula 1. Here, the compound represented by chemical formula 1 is included as an electron transport layer material in the organic EL device. In such organic EL devices, electrons can be easily injected from the cathode or electron injection layer to the electron transport layer due to the compound of chemical formula 1, and can also move quickly from the electron transport layer to the light-emitting layer, resulting in a high binding force between holes and electrons in the light-emitting layer. Therefore, the organic electroluminescent devices of this invention exhibit excellent luminous efficiency, power efficiency, and brightness. Moreover, the compound of chemical formula 1 has excellent thermal stability and electrochemical stability, which can confer improved performance to organic electroluminescent devices.

The compound of chemical formula 1 can be used alone or in combination with an electron transport layer material known in the art.

So long as it is commonly known in the art, any electron transport material may be used in combination with the compound of chemical formula 1. Non-limiting examples of available electron transport materials include oxazole compounds, isoxazole compounds, triazole compounds, isothiazole compounds, oxadiazole compounds, thiadiazole compounds, perylene compounds, aluminum complexes (e.g., Alq3, tris(8-quinolinolato)-aluminum), gallium complexes (e.g., Gaq′2OPiv, Gaq′20Ac, 2(Gaq′2)), etc. These can be used alone or in combination.

When the compound of chemical formula 1 is used in combination with an electron transport layer material, the mixing ratio therebetween is not particularly limited and can be appropriately adjusted within the range known in the field.

In another embodiment, the at least one organic layer includes a hole injection layer, a hole transport layer, a light-emitting layer, an electron transport auxiliary layer, an electron transport layer, and electron injection layer, where the electron transport auxiliary layer contains the compound represented by chemical formula 1. In this regard, the compound represented by chemical formula 1 is included as an electron transport auxiliary layer material in the organic EL device. At this time, the compound of chemical formula 1 possesses a high triplet energy. Therefore, when the compound of chemical formula 1 is included as an electron transport auxiliary layer material, the efficiency of the organic electroluminescent device can be increased due to the triplet-triplet fusion (TTF) effect. Additionally, since the compound of chemical formula 1 can prevent the diffusion of excitons generated in the light-emitting layer to the adjacent electron transport layer, the number of excitons contributing to emission within the light-emitting layer increase, thus bringing about an improvement in luminous efficiency, durability and stability, and lifespan of the device.

The compound of chemical formula 1 may be used alone or in combination with an electron transport layer auxiliary material known in the field.

So long as it is commonly known in the art, any electron transport auxiliary layer material may be used in combination with the compound of chemical formula 1. Examples of the electron transport auxiliary layer material include, but are not limited to, oxadiazole derivatives, triazole derivatives, phenanthroline derivatives (e.g., BCP), and heteroring derivatives bearing nitrogen.

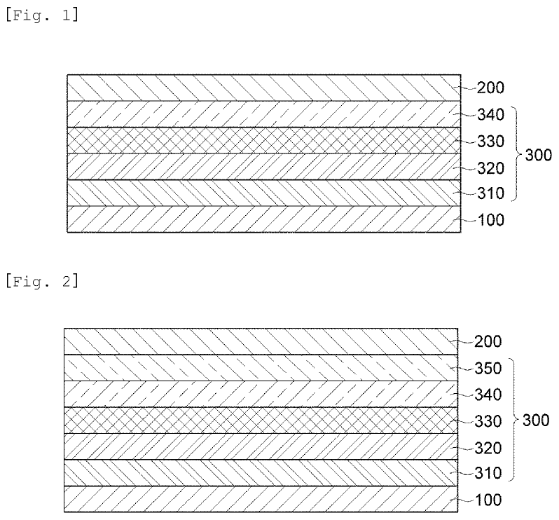

The structure of the organic EL device of the present disclosure is not particularly limited. For example, the organic EL device may have a structure in which an anode (100), at least one organic layer (300), and a cathode (200) are sequentially stacked on a substrate (see FIGS. 1 to 3). In addition, an insulating layer or an adhesive layer, although no shown, may be further inserted at the interfaces between the electrodes and the organic layer.

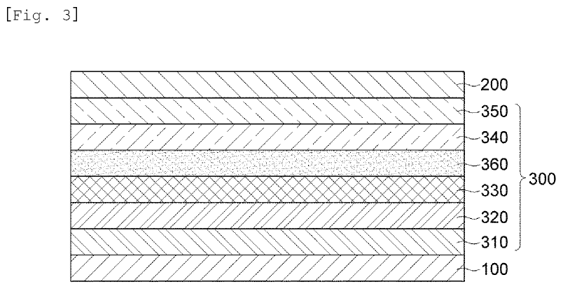

According to an embodiment, as shown in FIG. 1, the organic EL device may have a structure in which an anode (100), a hole injection layer (310), a hole transport layer (320), a light-emitting layer (330), an electron transport layer (340), and a cathode (200) are sequentially stacked on a substrate. Optionally, as shown in FIG. 2, an electron injection layer (350) may be positioned between the electron transport layer (340) and the cathode (200). Furthermore, an electron transport auxiliary layer (360) may be disposed between the light-emitting layer (330) and the electron transport layer (340) (see FIG. 3).

The organic EL device of the present disclosure may be fabricated by forming organic layers and electrodes using methods and materials known in the art, except that at least one of the aforementioned organic layers (300) [e.g., light-emitting layer (300), electron transport layer (340), or electron transport auxiliary layer (360)] include the compound represented by chemical formula 1.

The organic layer may be formed by a vacuum deposition method or a solution coating method. Examples of the solution coating method may include, but are not limited to, spin coating, dip coating, doctor blading, inkjet printing, thermal transfer, and the like.

No particular limitations are imparted to the substrate available in the present disclosure. Non-limiting examples of the substrate include silicon wafers, quartz, glass plates, metal plates, plastic films, sheets, or the like.

Anode materials may be exemplified by, but are not limited to, metals such as vanadium, chromium, copper, zinc and gold or an alloy thereof; metal oxides such as zinc oxide, indium oxide, indium tin oxide (ITO), and indium zinc oxide (IZO); combinations of oxides and metals such as ZnO:Al or SnO₂:Sb; conductive polymers such as polythiophene, poly(3-methylthiophene), poly[3,4-(ethylene-1,2-dioxy)thiophene](PEDT), polypyrrole, and polyaniline; and carbon black, or the like.

Examples of materials of the cathode include, but is not limited to, a metal such as magnesium, calcium, sodium, potassium, titanium, indium, yttrium, lithium, gadolinium, aluminum, silver, tin and lead or an alloy thereof; a multi-layered material such as LiF/Al and LiO₂/Al, or the like.

In addition, so long as it is known in the art, any material is used for the hole injection layer, the hole transporting layer, the electron injection layer, and the electron transporting layer, without limitations thereto.

A better understanding of the present disclosure may be obtained through the following examples, which are set forth to illustrate, but are not construed to limit, the present disclosure.

### [Preparation Example 1] Synthesis of 5-Methyl-4-(4,4,5,5-tetramethyl-1,3,2-dioxaborolan-2-yl)benzo[b]phosphindole 5-oxide

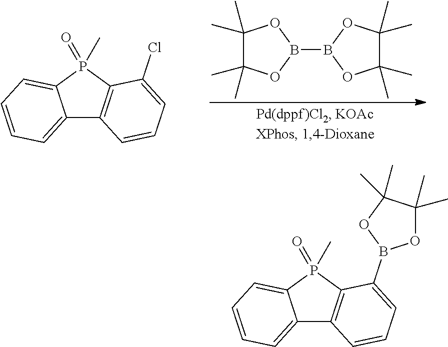

In 1,4-dioxane, 4-chloro-5-methylbenzo[b]phosphindole 5-oxide (50.0 g, 201.09 mmol), 4,4,4′,4′,5,5,5′,5′-octamethyl-2,2′-bi(1,3,2-dioxaborolane) (61.28 g, 241.3 mmol), Pd(dppf)Cl₂ (8.21 g, 10.05 mmol), XPhos (9.59 g, 20.11 mmol), and KOAc (49.47 g, 492.17 mmol) were heated together under reflux for 12 hours. After completion of the reaction, an organic layer was obtained with methylene chloride, added with MgSO₄, and then filtered. The solvent was removed from the filtered organic layer, followed by column chromatography to afford the target compound 5-methyl-4-(4,4,5,5-tetramethyl-1,3,2-dioxaborolan-2-yl)benzo[b]phosphindole 5-oxide (56.09 g, yield 82%).

¹H-NMR: δ 1.20 (s, 24H), 1.98 (s, 3H), 7.46 (t, 1H), 7.61 (t, 1H), 7.79 (t, 1H), 7.87 (d, 1H), 7.95 (d, 2H), 8.05 (d, 1H)

[LCMS]: 340

### [Preparation Example 2] Synthesis of 5-methyl-3-(4,4,5,5-tetramethyl-1,3,2-dioxaborolan-2-yl)benzo[b]phosphindole 5-oxide

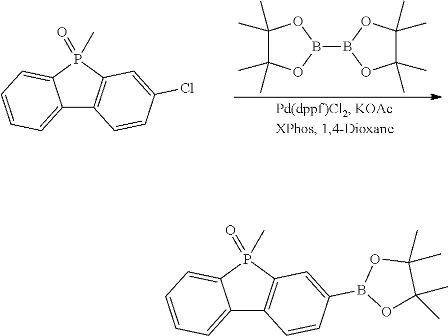

In 1,4-dioxane, 3-chloro-5-methylbenzo[b]phosphindole 5-oxide (50.0 g, 201.09 mmol), 4,4,4′,4′,5,5,5′,5′-octamethyl-2,2′-bi(1,3,2-dioxaborolane) (61.28 g, 241.3 mmol), Pd(dppf)Cl₂ (8.21 g, 10.05 mmol), XPhos (9.59 g, 20.11 mmol), and KOAc (49.47 g, 492.17 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound 5-methyl-3-(4,4,5,5-tetramethyl-1,3,2-dioxaborolan-2-yl)benzo[b]phosphindole 5-oxide (56.09 g, yield 82%).

¹H-NMR: δ 1.20 (s, 24H), 1.98 (s, 3H), 7.46 (t, 1H), 7.61 (t, 1H), 7.79 (t, 1H), 7.86 (s, 1H), 7.95 (d, 2H), 8.05 (d, 1H)

[LCMS]: 340

### [Preparation Example 3] Synthesis of 5-Methyl-2-(4,4,5,5-tetramethyl-1,3,2-dioxaborolan-2-yl)benzo[b]phosphindole 5-oxide

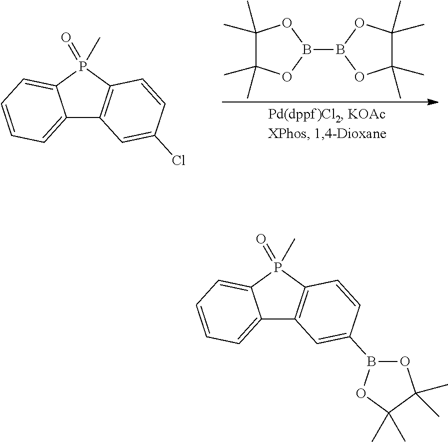

In 1,4-dioxane, 2-chloro-5-methylbenzo[b]phosphindole 5-oxide (50.0 g, 201.09 mmol), 4,4,4′,4′,5,5,5′,5′-octamethyl-2,2′-bi(1,3,2-dioxaborolane) (61.28 g, 241.3 mmol), Pd(dppf)Cl₂ (8.21 g, 10.05 mmol), and XPhos (9.59 g, 20.11 mmol), and KOAc (49.47 g, 492.17 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound 5-methyl-2-(4,4,5,5-tetramethyl-1,3,2-dioxaborolan-2-yl)benzo[b]phosphindole 5-oxide (56.09 g, yield 82%).

¹H-NMR: δ 1.20 (s, 24H), 1.98 (s, 3H), 7.47 (d, 1H), 7.61 (t, 1H), 7.78 (t, 1H), 7.86 (s, 1H), 7.95 (d, 2H), 8.05 (d, 1H)

[LCMS]: 340

### [Preparation Example 4] Synthesis of 5-Methyl-1-(4,4,5,5-tetramethyl-1,3,2-dioxaborolan-2-yl)benzo[b]phosphindole 5-oxide

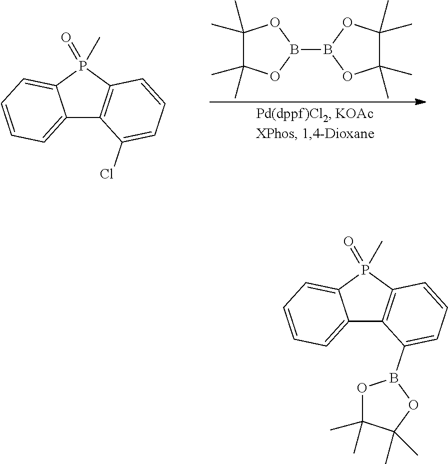

In 1,4-dioxane, 1-chloro-5-methylbenzo[b]phosphindole 5-oxide (50.0 g, 201.09 mmol), 4,4,4′,4′,5,5,5′,5′-octamethyl-2,2′-bi(1,3,2-dioxaborolane) (61.28 g, 241.3 mmol), Pd(dppf)Cl₂ (8.21 g, 10.05 mmol), XPhos (9.59 g, 20.11 mmol), and KOAc (49.47 g, 492.17 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound 5-methyl-1-(4,4,5,5-tetramethyl-1,3,2-dioxaborolan-2-yl)benzo[b]phosphindole 5-oxide (56.09 g, yield 82%).

¹H-NMR: δ 1.20 (s, 24H), 1.98 (s, 3H), 7.47 (d, 1H), 7.60 (t, 1H), 7.78 (t, 1H), 7.85 (s, 1H), 7.9 (d, 2H), 8.05 (d, 1H)

[LCMS]: 340

### [Synthesis Example 1-1] Synthesis of Compound A-6

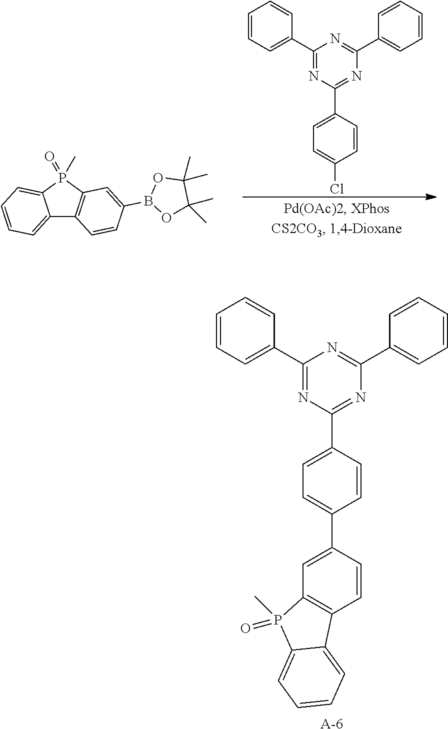

In 200 ml of 1,4-dioxane, the target compound of Preparation Example 2 (10 g, 29.4 mmol), 2-(4-chlorophenyl)-4,6-diphenyl-1,3,5-triazine (11.12 g, 32.34 mmol), Pd(OAc)₂ (0.33 g, 1.47 mmol), Cs₂CO₃ (28.73 g, 88.19 mmol), and Xphos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-6 (11.04 g, yield 72%).

[LCMS]: 521

### [Synthesis Example 1-2] Synthesis of Compound A-2

Compound A-2 was synthesized in the same manner as in Synthesis Example 1-1 with the exception of using the target compound of Preparation Example 1 instead of the target compound of Preparation Example 2.

[LCMS]: 521

### [Synthesis Example 1-3] Synthesis of Compound A-10

Compound A-10 was synthesized in the same manner as in Synthesis Example 1-1 with the exception of using the target compound of Preparation Example 3 instead of the target compound of Preparation Example 2.

[LCMS]: 521

### [Synthesis Example 1-4] Synthesis of Compound A-14

Compound A-14 was synthesized in the same manner as in Synthesis Example 1-1 with the exception of using the target compound of Preparation Example 4 instead of the target compound of Preparation Example 2.

[LCMS]: 521

### [Synthesis Example 1-5] Synthesis of Compound B-2

Compound B-2 was synthesized in the same manner as in Synthesis Example 1-1 with the exception of using 4-(4-chlorophenyl)-2,6-diphenylpyrimidine instead of 2-(4-chlorophenyl)-4,6-diphenyl-1,3,5-triazine.

[LCMS]: 521

### [Synthesis Example 1-6] Synthesis of Compound B-6

Compound B-6 was synthesized in the same manner as in Synthesis Example 1-1 with the exception of using the target compound of Preparation Example 1 and 4-(4-chlorophenyl)-2,6-diphenylpyrimidine instead of the target compound of Preparation Example 2 and 2-(4-chlorophenyl)-4,6-diphenyl-1,3,5-triazine, respectively.

[LCMS]: 521

### [Synthesis Example 1-7] Synthesis of Compound B-10

Compound B-10 was synthesized in the same manner as in Synthesis Example 1-1 with the exception of using the target compound of Preparation Example 3 and 4-(4-chlorophenyl)-2,6-diphenylpyrimidine instead of the target compound of Preparation Example 2 and 2-(4-chlorophenyl)-4,6-diphenyl-1,3,5-triazine, respectively.

[LCMS]: 521

### [Synthesis Example 1-8] Synthesis of Compound B-14

Compound B-14 was synthesized in the same manner as in Synthesis Example 1-1 with the exception of using the target compound of Preparation Example 4 and 4-(4-chlorophenyl)-2,6-diphenylpyrimidine instead of the target compound of Preparation Example 2 and 2-(4-chlorophenyl)-4,6-diphenyl-1,3,5-triazine, respectively.

[LCMS]: 521

### [Synthesis Example 2-1] Synthesis of Compound A-7

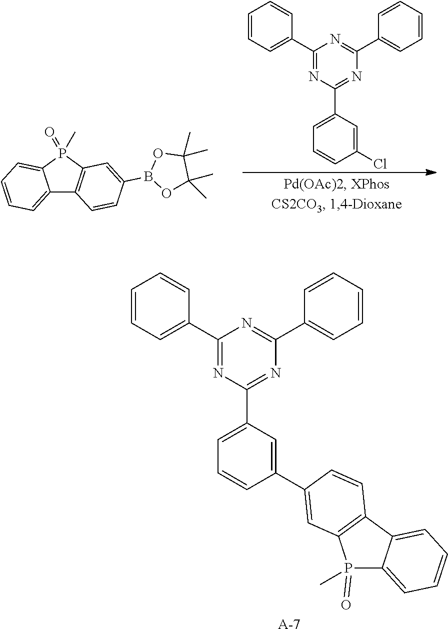 [SMILES: CC1(C)OB(c2ccc3c(c2)P(C)(=O)c2ccccc2-3)OC1(C)C ; Clc1cccc(-c2nc(-c3ccccc3)nc(-c3ccccc3)n2)c1 ; CP1(=O)c2ccccc2-c2ccc(-c3cccc(-c4nc(-c5ccccc5)nc(-c5ccccc5)n4)c3)cc21 ; "A-7"]

In 200 ml of 1,4-dioxane, the target compound of Preparation Example 2 (10 g, 29.4 mmol), 2-(3-chlorophenyl)-4,6-diphenyl-1,3,5-triazine (11.12 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-7 (11.04 g, yield 72%).

[LCMS]: 521

### [Synthesis Example 2-2] Synthesis of Compound A-3

Compound A-3 was synthesized in the same manner as in Synthesis Example 2-1 with the exception of using the target compound of Preparation Example 1 instead of the target compound of Preparation Example 2.

[LCMS]: 521

### [Synthesis Example 2-3] Synthesis of Compound A-11

Compound A-11 was synthesized in the same manner as in Synthesis Example 2-1 with the exception of using the target compound of Preparation Example 3 instead of the target compound of Preparation Example 2.

[LCMS]: 521

### [Synthesis Example 2-4] Synthesis of Compound A-15

Compound A-15 was synthesized in the same manner as in Synthesis Example 2-1 with the exception of using the target compound of Preparation Example 4 instead of the target compound of Preparation Example 2.

[LCMS]: 521

### [Synthesis Example 2-5] Synthesis of Compound B-3

Compound B-3 was synthesized in the same manner as in Synthesis Example 2-1 with the exception of using 4-(3-chlorophenyl)-2,6-diphenylpyrimidine instead of 2-(3-chlorophenyl)-4,6-diphenyl-1,3,5-triazine.

[LCMS]: 521

### [Synthesis Example 2-6] Synthesis of Compound B-7

Compound B-7 was synthesized in the same manner as in Synthesis Example 2-1 with the exception of using the target compound of Preparation Example 1 and 4-(3-chlorophenyl)-2,6-diphenylpyrimidine instead of the target compound of Preparation Example 2 and 2-(3-chlorophenyl)-4,6-diphenyl-1,3,5-triazine, respectively.

[LCMS]: 521

### [Synthesis Example 2-7] Synthesis of Compound B-11

Compound B-11 was synthesized in the same manner as in Synthesis Example 2-1 with the exception of using the target compound of Preparation Example 3 and 4-(3-chlorophenyl)-2,6-diphenylpyrimidine instead of the target compound of Preparation Example 2 and 2-(3-chlorophenyl)-4,6-diphenyl-1,3,5-triazine, respectively.

[LCMS]: 521

### [Synthesis Example 2-8] Synthesis of Compound B-15

Compound A-2 was synthesized in the same manner as in Synthesis Example 2-1 with the exception of using the target compound of Preparation Example 4 and 4-(3-chlorophenyl)-2,6-diphenylpyrimidine instead of the target compound of Preparation Example 2 and 2-(3-chlorophenyl)-4,6-diphenyl-1,3,5-triazine, respectively.

[LCMS]: 521

### [Synthesis Example 3-1] Synthesis of Compound A-8

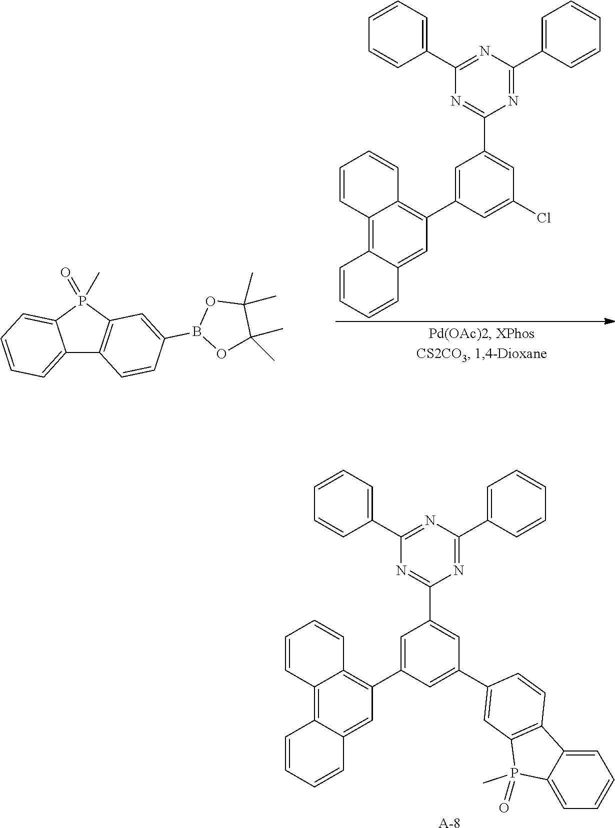 [SMILES: CC1(C)OB(c2ccc3c(c2)P(C)(=O)c2ccccc2-3)OC1(C)C ; Clc1cc(-c2nc(-c3ccccc3)nc(-c3ccccc3)n2)cc(-c2cc3ccccc3c3ccccc23)c1 ; CP1(=O)c2ccccc2-c2ccc(-c3cc(-c4nc(-c5ccccc5)nc(-c5ccccc5)n4)cc(-c4cc5ccccc5c5ccccc45)c3)cc21 ; "A-8"]

In 200 ml of 1,4-dioxane, the target compound of Preparation Example 2 (10 g, 29.4 mmol), 2-(3-chloro-5-(phenanthren-9-yl)phenyl)-4,6-diphenyl-1,3,5-triazine (16.82 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-8 (14.77 g, yield 72%).

[LCMS]: 697

### [Synthesis Example 3-2] Synthesis of Compound A-4

Compound A-4 was synthesized in the same manner as in Synthesis Example 3-1 with the exception of using the target compound of Preparation Example 1 instead of the target compound of Preparation Example 2.

[LCMS]: 697

### [Synthesis Example 3-3] Synthesis of Compound A-12

Compound A-12 was synthesized in the same manner as in Synthesis Example 3-1 with the exception of using the target compound of Preparation Example 3 instead of the target compound of Preparation Example 2.

[LCMS]: 697

### [Synthesis Example 3-4] Synthesis of Compound A-16

Compound A-16 was synthesized in the same manner as in Synthesis Example 3-1 with the exception of using the target compound of Preparation Example 4 instead of the target compound of Preparation Example 2.

[LCMS]: 697

### [Synthesis Example 3-5] Synthesis of Compound B-4

Compound B-4 was synthesized in the same manner as in Synthesis Example 3-1 with the exception of using 4-(3-chloro-5-(phenanthren-9-yl)phenyl)-2,6-diphenylpyrimidine instead of 2-(3-chloro-5-(phenanthren-9-yl)phenyl)-4,6-diphenyl-1,3,5-triazine.

[LCMS]: 697

### [Synthesis Example 3-6] Synthesis of Compound B-8

Compound B-8 was synthesized in the same manner as in Synthesis Example 3-1 with the exception of using the target compound of Preparation Example 1 and 4-(3-chloro-5-(phenanthren-9-yl)phenyl)-2,6-diphenylpyrimidine instead of the target compound of Preparation Example 2 and 2-(3-chloro-5-(phenanthren-9-yl)phenyl)-4,6-diphenyl-1,3,5-triazine, respectively.

[LCMS]: 697

### [Synthesis Example 3-7] Synthesis of Compound B-12

Compound B-12 was synthesized in the same manner as in Synthesis Example 3-1 with the exception of using the target compound of Preparation Example 3 and 4-(3-chloro-5-(phenanthren-9-yl)phenyl)-2,6-diphenylpyrimidine instead of the target compound of Preparation Example 2 and 2-(3-chloro-5-(phenanthren-9-yl)phenyl)-4,6-diphenyl-1,3,5-triazine, respectively.

[LCMS]: 697

### [Synthesis Example 3-8] Synthesis of Compound B-16

Compound B-16 was synthesized in the same manner as in Synthesis Example 3-1 with the exception of using the target compound of Preparation Example 4 and 4-(3-chloro-5-(phenanthren-9-yl)phenyl)-2,6-diphenylpyrimidine instead of the target compound of Preparation Example 2 and 2-(3-chloro-5-(phenanthren-9-yl)phenyl)-4,6-diphenyl-1,3,5-triazine, respectively.

[LCMS]: 697

### [Synthesis Example 4-1] Synthesis of Compound A-21

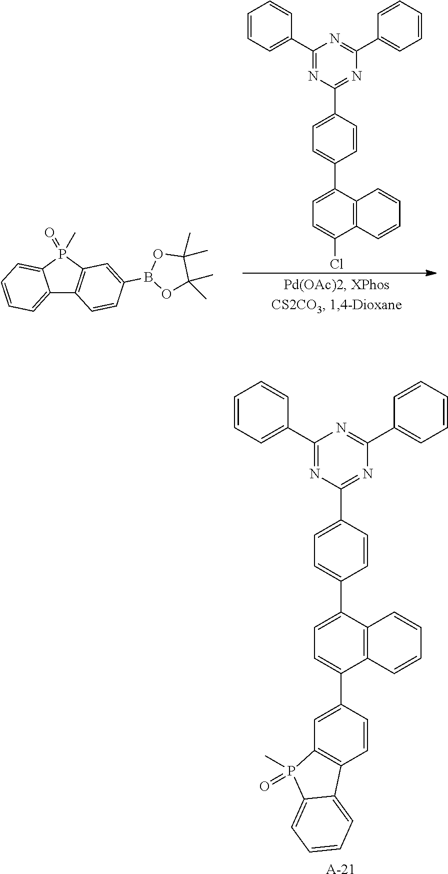

In 200 ml of 1,4-dioxane, the target compound of Preparation Example 2 (10 g, 29.4 mmol), 2-(4-(4-chloronaphthalen-1-yl)phenyl)-4,6-diphenyl-1,3,5-triazine (15.2 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-21 (13.72 g, yield 72%).

[LCMS]: 647

### [Synthesis Example 4-2] Synthesis of Compound A-17

Compound A-17 was synthesized in the same manner as in Synthesis Example 4-1 with the exception of using the target compound of Preparation Example 1 instead of the target compound of Preparation Example 2.

[LCMS]: 647

### [Synthesis Example 4-3] Synthesis of Compound A-25

Compound A-25 was synthesized in the same manner as in Synthesis Example 4-1 with the exception of using the target compound of Preparation Example 3 instead of the target compound of Preparation Example 2.

[LCMS]: 647

### [Synthesis Example 4-4] Synthesis of Compound A-29

Compound A-29 was synthesized in the same manner as in Synthesis Example 4-1 with the exception of using the target compound of Preparation Example 4 instead of the target compound of Preparation Example 2.

[LCMS]: 647

### [Synthesis Example 4-5] Synthesis of Compound B-17

Compound B-17 was synthesized in the same manner as in Synthesis Example 4-1 with the exception of using 4-(4-(4-chloronaphthalen-1-yl)phenyl)-2,6-diphenylpyrimidine instead of 2-(4-(4-chloronaphthalen-1-yl)phenyl)-4,6-diphenyl-1,3,5-triazine.

[LCMS]: 647

### [Synthesis Example 4-6] Synthesis of Compound B-21

Compound B-21 was synthesized in the same manner as in Synthesis Example 4-1 with the exception of using the target compound of Preparation Example 1 and 4-(4-(4-chloronaphthalen-1-yl)phenyl)-2,6-diphenylpyrimidine instead of the target compound of Preparation Example 2 and 2-(4-(4-chloronaphthalen-1-yl)phenyl)-4,6-diphenyl-1,3,5-triazine, respectively.

[LCMS]: 647

### [Synthesis Example 4-7] Synthesis of Compound B-25

Compound B-25 was synthesized in the same manner as in Synthesis Example 4-1 with the exception of using the target compound of Preparation Example 3 and 4-(4-(4-chloronaphthalen-1-yl)phenyl)-2,6-diphenylpyrimidine instead of the target compound of Preparation Example 2 and 2-(4-(4-chloronaphthalen-1-yl)phenyl)-4,6-diphenyl-1,3,5-triazine, respectively.

[LCMS]: 647

### [Synthesis Example 4-8] Synthesis of Compound B-29

Compound B-29 was synthesized in the same manner as in Synthesis Example 4-1 with the exception of using the target compound of Preparation Example 4 and 4-(4-(4-chloronaphthalen-1-yl)phenyl)-2,6-diphenylpyrimidine instead of the target compound of Preparation Example 2 and 2-(4-(4-chloronaphthalen-1-yl)phenyl)-4,6-diphenyl-1,3,5-triazine, respectively.

[LCMS]: 647

### [Synthesis Example 5-1] Synthesis of Compound A-22

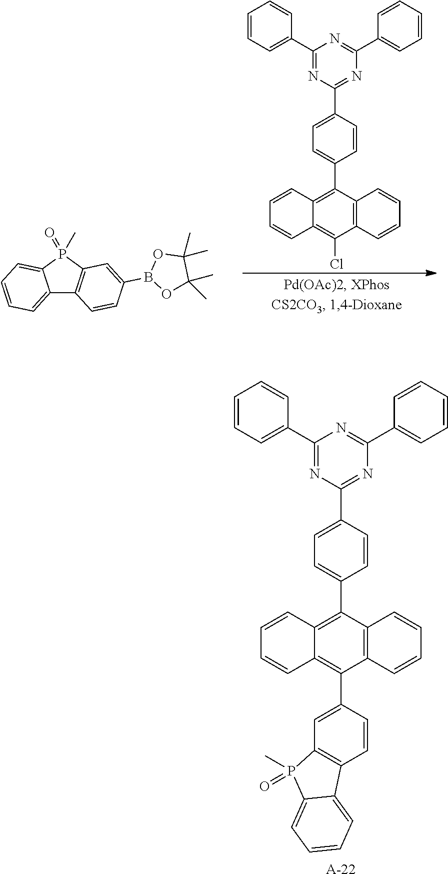

In 200 ml of 1,4-dioxane, the target compound of Preparation Example 2 (10 g, 29.4 mmol), 2-(4-(10-chloroanthracen-9-yl)phenyl)-4,6-diphenyl-1,3,5-triazine (16.82 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-22 (14.77 g, yield 72%).

[LCMS]: 697

### [Synthesis Example 5-2] Synthesis of Compound A-18

Compound A-18 was synthesized in the same manner as in Synthesis Example 5-1 with the exception of using the target compound of Preparation Example 1 instead of the target compound of Preparation Example 2.

[LCMS]: 697

### [Synthesis Example 5-3] Synthesis of Compound A-26

Compound A-26 was synthesized in the same manner as in Synthesis Example 5-1 with the exception of using the target compound of Preparation Example 3 instead of the target compound of Preparation Example 2.

[LCMS]: 697

### [Synthesis Example 5-4] Synthesis of Compound A-30

Compound A-30 was synthesized in the same manner as in Synthesis Example 5-1 with the exception of using the target compound of Preparation Example 4 instead of the target compound of Preparation Example 2.

[LCMS]: 697

### [Synthesis Example 5-5] Synthesis of Compound B-18

Compound B-18 was synthesized in the same manner as in Synthesis Example 5-1 with the exception of using 4-(4-(10-chloroanthracen-9-yl)phenyl)-2,6-diphenylpyrimidine instead of 2-(4-(10-chloroanthracen-9-yl)phenyl)-4,6-diphenyl-1,3,5-triazine.

[LCMS]: 697

### [Synthesis Example 5-6] Synthesis of Compound B-22

Compound B-22 was synthesized in the same manner as in Synthesis Example 5-1 with the exception of using the target compound of Preparation Example 1 and 4-(4-(10-chloroanthracen-9-yl)phenyl)-2,6-diphenylpyrimidine instead of the target compound of Preparation Example 2 and 2-(4-(10-chloroanthracen-9-yl)phenyl)-4,6-diphenyl-1,3,5-triazine, respectively.

[LCMS]: 697

### [Synthesis Example 5-7] Synthesis of Compound B-26

Compound B-26 was synthesized in the same manner as in Synthesis Example 5-1 with the exception of using the target compound of Preparation Example 3 and 4-(4-(10-chloroanthracen-9-yl)phenyl)-2,6-diphenylpyrimidine instead of the target compound of Preparation Example 2 and, 2-(4-(10-chloroanthracen-9-yl)phenyl)-4,6-diphenyl-1,3,5-triazine, respectively.

[LCMS]: 697

### [Synthesis Example 5-8] Synthesis of Compound B-30

Compound B-30 was synthesized in the same manner as in Synthesis Example 5-1 with the exception of using the target compound of Preparation Example 4 and 4-(4-(10-chloroanthracen-9-yl)phenyl)-2,6-diphenylpyrimidine instead of the target compound of Preparation Example 2 and 2-(4-(10-chloroanthracen-9-yl)phenyl)-4,6-diphenyl-1,3,5-triazine, respectively.

[LCMS]: 697

### [Synthesis Example 6-1] Synthesis of Compound A-23

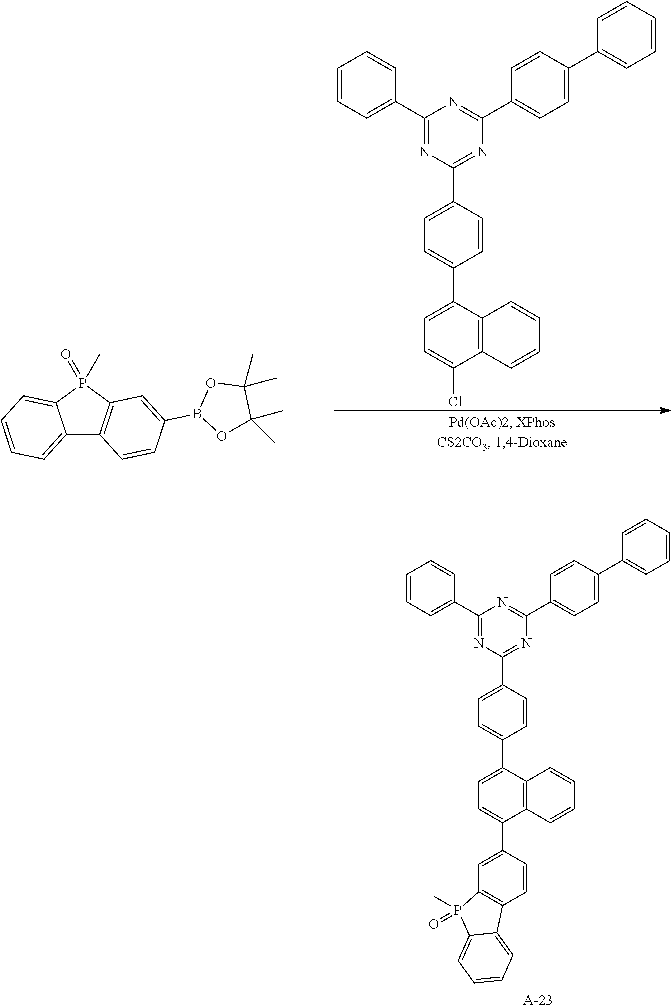

In 200 ml of 1,4-dioxane, the target compound of Preparation Example 2 (10 g, 29.4 mmol), 2-([1,1′-biphenyl]-4-yl)-4-(4-(4-chloronaphthalen-1-yl)phenyl)-6-phenyl-1,3,5-triazine (17.66 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-23 (15.32 g, yield 72%).

[LCMS]: 723

### [Synthesis Example 6-2] Synthesis of Compound A-19

Compound A-19 was synthesized in the same manner as in Synthesis Example 6-1 with the exception of using the target compound of Preparation Example 1 instead of the target compound of Preparation Example 2.

[LCMS]: 723

### [Synthesis Example 6-3] Synthesis of Compound A-27

Compound A-27 was synthesized in the same manner as in Synthesis Example 6-1 with the exception of using the target compound of Preparation Example 3 instead of the target compound of Preparation Example 2.

[LCMS]: 723

### [Synthesis Example 6-4] Synthesis of Compound A-31

Compound A-31 was synthesized in the same manner as in Synthesis Example 6-1 with the exception of using the target compound of Preparation Example 4 instead of the target compound of Preparation Example 2.

[LCMS]: 723

### [Synthesis Example 6-5] Synthesis of Compound B-19

Compound B-19 was synthesized in the same manner as in Synthesis Example 6-1 with the exception of using 6-([1,1′-biphenyl]-4-yl)-4-(4-(4-chloronaphthalen-1-yl)phenyl)-2-phenyl-4,5-dihydropyrimidine instead of 2-([1,1′-biphenyl]-4-yl)-4-(4-(4-chloronaphthalen-1-yl)phenyl)-6-phenyl-1,3,5-triazine.

[LCMS]: 723

### [Synthesis Example 6-6] Synthesis of Compound B-23

Compound B-23 was synthesized in the same manner as in Synthesis Example 6-1 with the exception of using the target compound of Preparation Example 1 and 6-([1,1′-biphenyl]-4-yl)-4-(4-(4-chloronaphthalen-1-yl)phenyl)-2-phenyl-4,5-dihydropyrimidineinstead of the target compound of Preparation Example 2 and 2-([1,1′-biphenyl]-4-yl)-4-(4-(4-chloronaphthalen-1-yl)phenyl)-6-phenyl-1,3,5-triazine, respectively.

[LCMS]: 723

### [Synthesis Example 6-7] Synthesis of Compound B-27

Compound B-27 was synthesized in the same manner as in Synthesis Example 6-1 with the exception of using the target compound of Preparation Example 3 and 6-([1,1′-biphenyl]-4-yl)-4-(4-(4-chloronaphthalen-1-yl)phenyl)-2-phenyl-4,5-dihydropyrimidine instead of the target compound of Preparation Example 2 and 2-([1,1′-biphenyl]-4-yl)-4-(4-(4-chloronaphthalen-1-yl)phenyl)-6-phenyl-1,3,5-triazine, respectively.

[LCMS]: 723

### [Synthesis Example 6-8] Synthesis of Compound B-31

Compound B-31 was synthesized in the same manner as in Synthesis Example 6-1 with the exception of using the target compound of Preparation Example 4 and 6-([1,1′-biphenyl]-4-yl)-4-(4-(4-chloronaphthalen-1-yl)phenyl)-2-phenyl-4,5-dihydropyrimidine instead of the target compound of Preparation Example 2 and 2-([1,1′-biphenyl]-4-yl)-4-(4-(4-chloronaphthalen-1-yl)phenyl)-6-phenyl-1,3,5-triazine, respectively.

[LCMS]: 723

### [Synthesis Example 7-1] Synthesis of Compound A-24

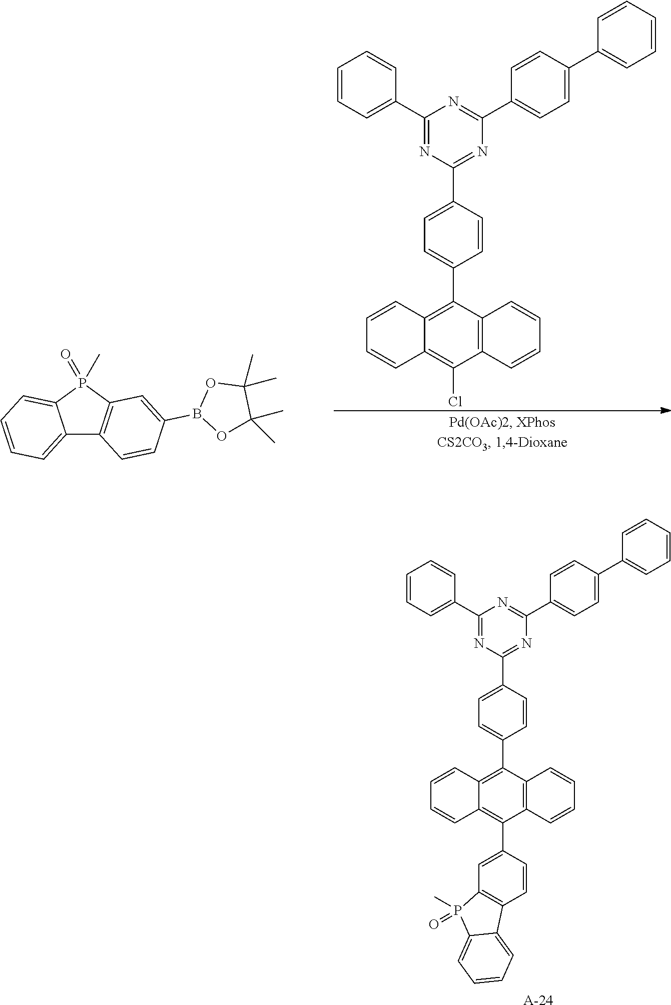

In 200 ml of 1,4-dioxane, the target compound of Preparation Example 2 (10 g, 29.4 mmol), 2-([1,1′-biphenyl]-4-yl)-4-(4-(10-chloroanthracen-9-yl)phenyl)-6-phenyl-1,3,5-triazine (19.28 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-24 (16.38 g, yield 72%).

[LCMS]: 773

### [Synthesis Example 7-2] Synthesis of Compound A-20

Compound A-20 was synthesized in the same manner as in Synthesis Example 7-1 with the exception of using the target compound of Preparation Example 1 instead of the target compound of Preparation Example 2.

[LCMS]: 773

### [Synthesis Example 7-3] Synthesis of Compound A-28

Compound A-28 was synthesized in the same manner as in Synthesis Example 7-1 with the exception of using the target compound of Preparation Example 3 instead of the target compound of Preparation Example 2.

[LCMS]: 773

### [Synthesis Example 7-4] Synthesis of Compound A-32

Compound A-32 was synthesized in the same manner as in Synthesis Example 7-1 with the exception of using the target compound of Preparation Example 4 instead of the target compound of Preparation Example 2.

[LCMS]: 773

### [Synthesis Example 7-5] Synthesis of Compound B-20

Compound B-20 was synthesized in the same manner as in Synthesis Example 7-1 with the exception of using 4-([1,1′-biphenyl]-4-yl)-6-(4-(10-chloroanthracen-9-yl)phenyl)-2-phenylpyrimidine instead of 2-([1,1′-biphenyl]-4-yl)-4-(4-(10-chloroanthracen-9-yl)phenyl)-6-phenyl-1,3,5-triazine.

[LCMS]: 773

### [Synthesis Example 7-6] Synthesis of Compound B-24

Compound B-24 was synthesized in the same manner as in Synthesis Example 7-1 with the exception of using the target compound of Preparation Example 1 and 4-([1,1′-biphenyl]-4-yl)-6-(4-(10-chloroanthracen-9-yl)phenyl)-2-phenylpyrimidine instead of the target compound of Preparation Example 2 and 2-([1,1′-biphenyl]-4-yl)-4-(4-(10-chloroanthracen-9-yl)phenyl)-6-phenyl-1,3,5-triazine, respectively.

[LCMS]: 773

### [Synthesis Example 7-7] Synthesis of Compound B-28

Compound B-28 was synthesized in the same manner as in Synthesis Example 7-1 with the exception of using the target compound of Preparation Example 3 and 4-([1,1′-biphenyl]-4-yl)-6-(4-(10-chloroanthracen-9-yl)phenyl)-2-phenylpyrimidine instead of the target compound of Preparation Example 2 and 2-([1,1′-biphenyl]-4-yl)-4-(4-(10-chloroanthracen-9-yl)phenyl)-6-phenyl-1,3,5-triazine, respectively.

[LCMS]: 773

### [Synthesis Example 7-8] Synthesis of Compound B-32

Compound B-32 was synthesized in the same manner as in Synthesis Example 7-1 with the exception of using the target compound of Preparation Example 4 and 4-([1,1′-biphenyl]-4-yl)-6-(4-(10-chloroanthracen-9-yl)phenyl)-2-phenylpyrimidine instead of the target compound of Preparation Example 2 and 2-([1,1′-biphenyl]-4-yl)-4-(4-(10-chloroanthracen-9-yl)phenyl)-6-phenyl-1,3,5-triazine, respectively.

[LCMS]: 773

### [Synthesis Example 8-1] Synthesis of Compound A-37

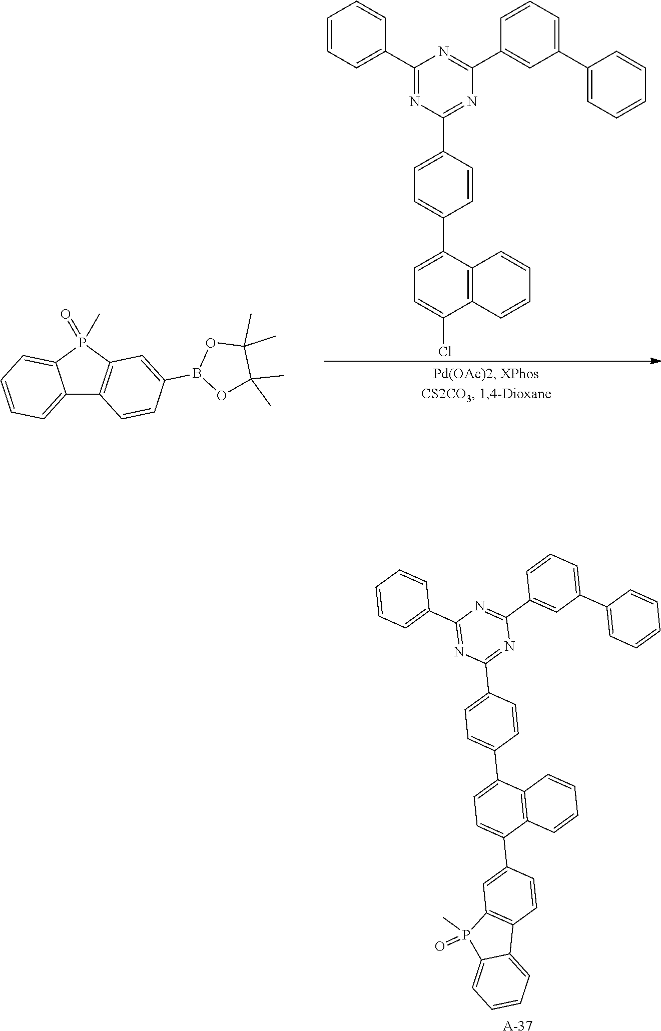

In 200 ml of 1,4-dioxane, the target compound of Preparation Example 2 (10 g, 29.4 mmol), 2-([1,1′-biphenyl]-3-yl)-4-(4-(4-chloronaphthalen-1-yl)phenyl)-6-phenyl-1,3,5-triazine (17.66 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-37 (15.32 g, yield 72%).

[LCMS]: 723

### [Synthesis Example 8-2] Synthesis of Compound A-33

Compound A-33 was synthesized in the same manner as in Synthesis Example 8-1 with the exception of using the target compound of Preparation Example 1 instead of the target compound of Preparation Example 2.

[LCMS]: 723

### [Synthesis Example 8-3] Synthesis of Compound A-41

Compound A-41 was synthesized in the same manner as in Synthesis Example 8-1 with the exception of using the target compound of Preparation Example 3 instead of the target compound of Preparation Example 2.

[LCMS]: 723

### [Synthesis Example 8-4] Synthesis of Compound A-45

Compound A-45 was synthesized in the same manner as in Synthesis Example 8-1 with the exception of using the target compound of Preparation Example 4 instead of the target compound of Preparation Example 2.

[LCMS]: 723

### [Synthesis Example 8-5] Synthesis of Compound B-33

Compound B-33 was synthesized in the same manner as in Synthesis Example 8-1 with the exception of using 4-([1,1′-biphenyl]-3-yl)-6-(4-(4-chloronaphthalen-1-yl)phenyl)-2-phenylpyrimidine instead of 2-([1,1′-biphenyl]-3-yl)-4-(4-(4-chloronaphthalen-1-yl)phenyl)-6-phenyl-1,3,5-triazine.

[LCMS]: 723

### [Synthesis Example 8-6] Synthesis of Compound B-37

Compound B-37 was synthesized in the same manner as in Synthesis Example 8-1 with the exception of using the target compound of Preparation Example 1 and 4-([1,1′-biphenyl]-3-yl)-6-(4-(4-chloronaphthalen-1-yl)phenyl)-2-phenylpyrimidine instead of the target compound of Preparation Example 2 and 2-([1,1′-biphenyl]-3-yl)-4-(4-(4-chloronaphthalen-1-yl)phenyl)-6-phenyl-1,3,5-triazine, respectively.

[LCMS]: 723

### [Synthesis Example 8-7] Synthesis of Compound B-41

Compound B-41 was synthesized in the same manner as in Synthesis Example 8-1 with the exception of using the target compound of Preparation Example 3 and 4-([1,1′-biphenyl]-3-yl)-6-(4-(4-chloronaphthalen-1-yl)phenyl)-2-phenylpyrimidine instead of the target compound of Preparation Example 2 and 2-([1,1′-biphenyl]-3-yl)-4-(4-(4-chloronaphthalen-1-yl)phenyl)-6-phenyl-1,3,5-triazine, respectively.

[LCMS]: 723

### [Synthesis Example 8-8] Synthesis of Compound B-45

Compound B-45 was synthesized in the same manner as in Synthesis Example 8-1 with the exception of using the target compound of Preparation Example 4 and 4-([1,1′-biphenyl]-3-yl)-6-(4-(4-chloronaphthalen-1-yl)phenyl)-2-phenylpyrimidine instead of the target compound of Preparation Example 2 and 2-([1,1′-biphenyl]-3-yl)-4-(4-(4-chloronaphthalen-1-yl)phenyl)-6-phenyl-1,3,5-triazine, respectively.

[LCMS]: 723

### [Synthesis Example 9-1] Synthesis of Compound A-38

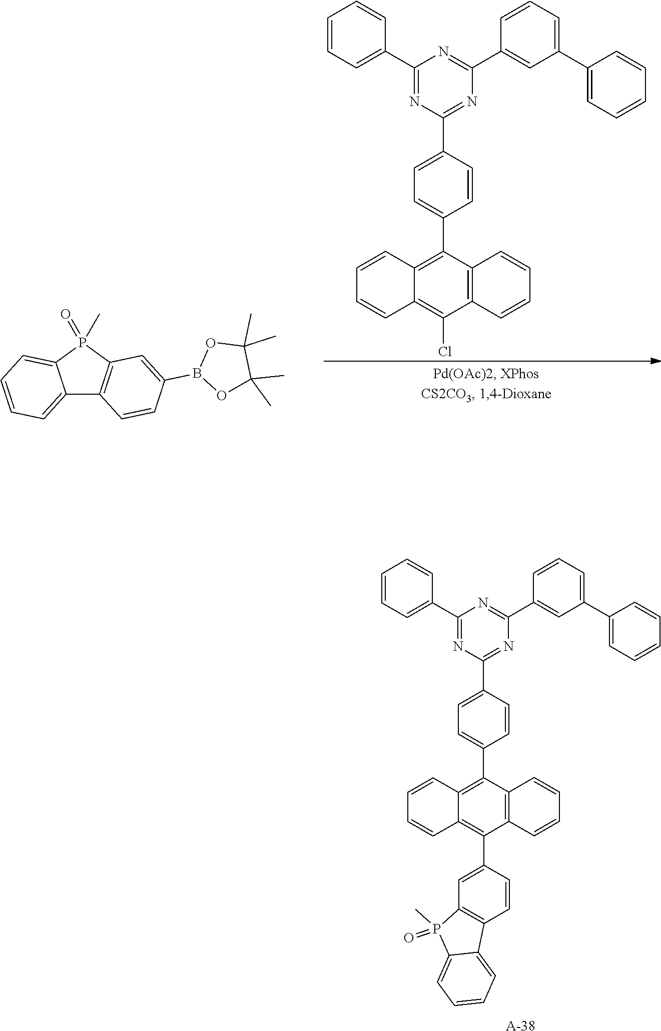

In 200 ml of 1,4-dioxane, the target compound of Preparation Example 2 (10 g, 29.4 mmol), 2-([1,1′-biphenyl]-3-yl)-4-(4-(10-chloroanthracen-9-yl)phenyl)-6-phenyl-1,3,5-triazine (17.66 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-38 (16.38 g, yield 72%).

[LCMS]: 773

### [Synthesis Example 9-2] Synthesis of Compound A-34

Compound A-34 was synthesized in the same manner as in Synthesis Example 9-1 with the exception of using the target compound of Preparation Example 1 instead of the target compound of Preparation Example 2.

[LCMS]: 773

### [Synthesis Example 9-3] Synthesis of Compound A-42

Compound A-42 was synthesized in the same manner as in Synthesis Example 9-1 with the exception of using the target compound of Preparation Example 3 instead of the target compound of Preparation Example 2.

[LCMS]: 773

### [Synthesis Example 9-4] Synthesis of Compound A-46

Compound A-46 was synthesized in the same manner as in Synthesis Example 9-1 with the exception of using the target compound of Preparation Example 4 instead of the target compound of Preparation Example 2.

[LCMS]: 773

### [Synthesis Example 9-5] Synthesis of Compound B-34

Compound B-34 was synthesized in the same manner as in Synthesis Example 9-1 with the exception of using 4-([1,1′-biphenyl]-3-yl)-6-(4-(10-chloroanthracen-9-yl)phenyl)-2-phenylpyrimidine instead of 2-([1,1′-biphenyl]-3-yl)-4-(4-(10-chloroanthracen-9-yl)phenyl)-6-phenyl-1,3,5-triazine.

[LCMS]: 773

### [Synthesis Example 9-6] Synthesis of Compound B-38

Compound B-38 was synthesized in the same manner as in Synthesis Example 9-1 with the exception of using the target compound of Preparation Example 1 and 4-([1,1′-biphenyl]-3-yl)-6-(4-(10-chloroanthracen-9-yl)phenyl)-2-phenylpyrimidine instead of the target compound of Preparation Example 2 and 2-([1,1′-biphenyl]-3-yl)-4-(4-(10-chloroanthracen-9-yl)phenyl)-6-phenyl-1,3,5-triazine, respectively.

[LCMS]: 773

### [Synthesis Example 9-7] Synthesis of Compound B-42

Compound B-42 was synthesized in the same manner as in Synthesis Example 9-1 with the exception of using the target compound of Preparation Example 3 and 4-([1,1′-biphenyl]-3-yl)-6-(4-(10-chloroanthracen-9-yl)phenyl)-2-phenylpyrimidine instead of the target compound of Preparation Example 2 and 2-([1,1′-biphenyl]-3-yl)-4-(4-(10-chloroanthracen-9-yl)phenyl)-6-phenyl-1,3,5-triazine, respectively.

[LCMS]: 773

### [Synthesis Example 9-8] Synthesis of Compound B-46

Compound B-46 was synthesized in the same manner as in Synthesis Example 9-1 with the exception of using the target compound of Preparation Example 4 and 4-([1,1′-biphenyl]-3-yl)-6-(4-(10-chloroanthracen-9-yl)phenyl)-2-phenylpyrimidine instead of the target compound of Preparation Example 2 and 2-([1,1′-biphenyl]-3-yl)-4-(4-(10-chloroanthracen-9-yl)phenyl)-6-phenyl-1,3,5-triazine, respectively.

[LCMS]: 773

### [Synthesis Example 10-1] Synthesis of Compound A-39

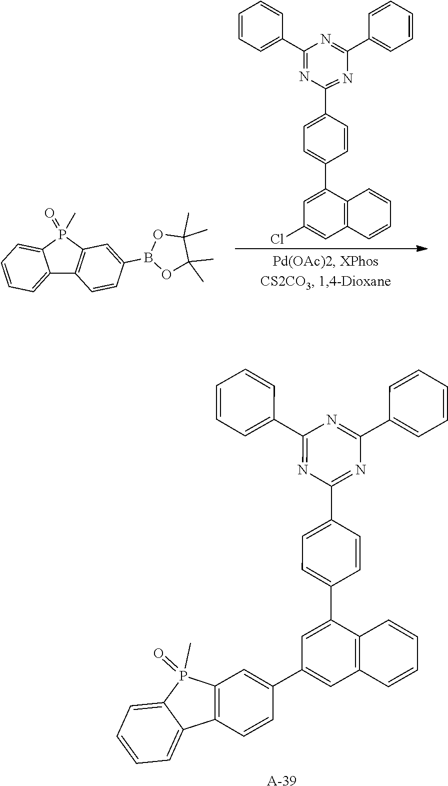 [SMILES: CC1(C)OB(c2ccc3c(c2)P(C)(=O)c2ccccc2-3)OC1(C)C ; Clc1cc(-c2ccc(-c3nc(-c4ccccc4)nc(-c4ccccc4)n3)cc2)c2ccccc2c1 ; CP1(=O)c2ccccc2-c2ccc(-c3cc(-c4ccc(-c5nc(-c6ccccc6)nc(-c6ccccc6)n5)cc4)c4ccccc4c3)cc21 ; "A-39"]

In 200 ml of 1,4-dioxane, the target compound of Preparation Example 2 (10 g, 29.4 mmol), 2-(4-(3-chloronaphthalen-1-yl)phenyl)-4,6-diphenyl-1,3,5-triazine (14.2 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-39 (13.72 g, yield 72%).

[LCMS]: 647

### [Synthesis Example 10-2] Synthesis of Compound A-35

Compound A-35 was synthesized in the same manner as in Synthesis Example 10-1 with the exception of using the target compound of Preparation Example 1 instead of the target compound of Preparation Example 2.

[LCMS]: 647

### [Synthesis Example 10-3] Synthesis of Compound A-43

Compound A-43 was synthesized in the same manner as in Synthesis Example 10-1 with the exception of using the target compound of Preparation Example 3 instead of the target compound of Preparation Example 2.

[LCMS]: 647

### [Synthesis Example 10-4] Synthesis of Compound A-47

Compound A-47 was synthesized in the same manner as in Synthesis Example 10-1 with the exception of using the target compound of Preparation Example 4 instead of the target compound of Preparation Example 2.

[LCMS]: 647

### [Synthesis Example 10-5] Synthesis of Compound B-35

Compound B-35 was synthesized in the same manner as in Synthesis Example 10-1 with the exception of using 4-(4-(3-chloronaphthalen-1-yl)phenyl)-2,6-diphenylpyrimidine instead of 2-(4-(3-chloronaphthalen-1-yl)phenyl)-4,6-diphenyl-1,3,5-triazine.

[LCMS]: 647

### [Synthesis Example 10-6] Synthesis of Compound B-39

Compound B-39 was synthesized in the same manner as in Synthesis Example 10-1 with the exception of using the target compound of Preparation Example 1 and 4-(4-(3-chloronaphthalen-1-yl)phenyl)-2,6-diphenylpyrimidine instead of the target compound of Preparation Example 2 and 2-(4-(3-chloronaphthalen-1-yl)phenyl)-4,6-diphenyl-1,3,5-triazine, respectively.

[LCMS]: 647

### [Synthesis Example 10-7] Synthesis of Compound B-43

Compound B-43 was synthesized in the same manner as in Synthesis Example 10-1 with the exception of using the target compound of Preparation Example 3 and 4-(4-(3-chloronaphthalen-1-yl)phenyl)-2,6-diphenylpyrimidine instead of the target compound of Preparation Example 2 and 2-(4-(3-chloronaphthalen-1-yl)phenyl)-4,6-diphenyl-1,3,5-triazine, respectively.

[LCMS]: 647

### [Synthesis Example 10-8] Synthesis of Compound B-47

Compound B-47 was synthesized in the same manner as in Synthesis Example 10-1 with the exception of using the target compound of Preparation Example 4 and 4-(4-(3-chloronaphthalen-1-yl)phenyl)-2,6-diphenylpyrimidine instead of the target compound of Preparation Example 2 and 2-(4-(3-chloronaphthalen-1-yl)phenyl)-4,6-diphenyl-1,3,5-triazine, respectively.

[LCMS]: 647

### [Synthesis Example 11-1] Synthesis of Compound A-40

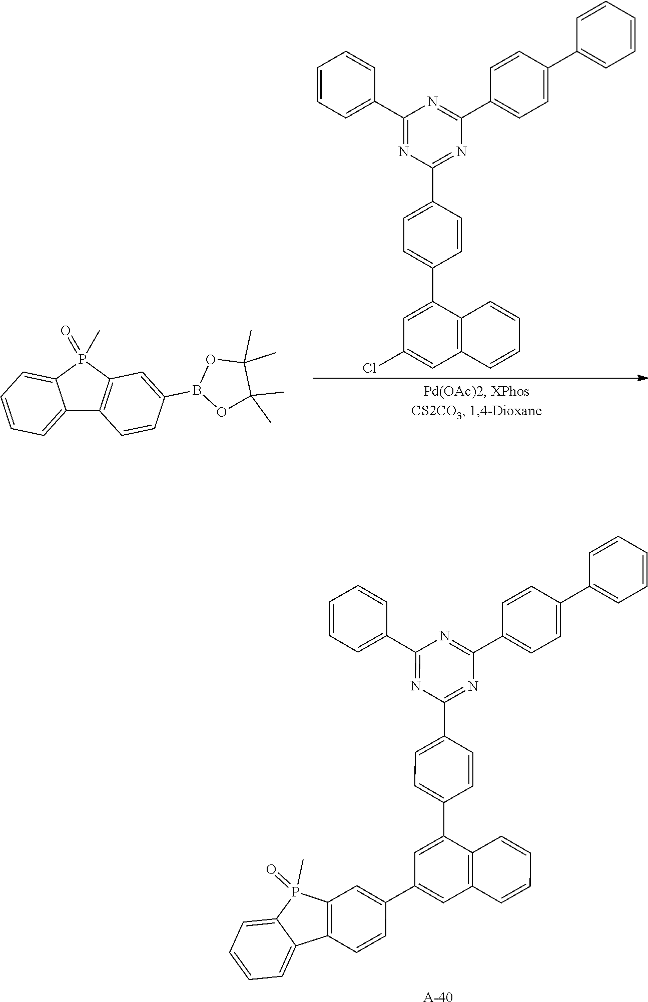 [SMILES: CC1(C)OB(c2ccc3c(c2)P(C)(=O)c2ccccc2-3)OC1(C)C ; Clc1cc(-c2ccc(-c3nc(-c4ccccc4)nc(-c4ccc(-c5ccccc5)cc4)n3)cc2)c2ccccc2c1 ; CP1(=O)c2ccccc2-c2ccc(-c3cc(-c4ccc(-c5nc(-c6ccccc6)nc(-c6ccc(-c7ccccc7)cc6)n5)cc4)c4ccccc4c3)cc21 ; "A-40"]

In 200 ml of 1,4-dioxane, the target compound of Preparation Example 2 (10 g, 29.4 mmol), 2-([1,1′-biphenyl]-4-yl)-4-(4-(3-chloronaphthalen-1-yl)phenyl)-6-phenyl-1,3,5-triazine (17.66 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-40 (15.32 g, yield 72%).

[LCMS]: 723

### [Synthesis Example 11-2] Synthesis of Compound A-36

Compound A-36 was synthesized in the same manner as in Synthesis Example 11-1 with the exception of using the target compound of Preparation Example 1 instead of the target compound of Preparation Example 2.

[LCMS]: 723

### [Synthesis Example 11-3] Synthesis of Compound A-44

Compound A-44 was synthesized in the same manner as in Synthesis Example 11-1 with the exception of using the target compound of Preparation Example 3 instead of the target compound of Preparation Example 2.

[LCMS]: 723

### [Synthesis Example 11-4] Synthesis of Compound A-48

Compound A-48 was synthesized in the same manner as in Synthesis Example 11-1 with the exception of using the target compound of Preparation Example 4 instead of the target compound of Preparation Example 2.

[LCMS]: 723

### [Synthesis Example 11-5] Synthesis of Compound B-36

Compound B-36 was synthesized in the same manner as in Synthesis Example 11-1 with the exception of using 4-([1,1′-biphenyl]-4-yl)-6-(4-(3-chloronaphthalen-1-yl)phenyl)-2-phenylpyrimidine instead of 2-([1,1′-biphenyl]-4-yl)-4-(4-(3-chloronaphthalen-1-yl)phenyl)-6-phenyl-1,3,5-triazine.

[LCMS]: 723

### [Synthesis Example 11-6] Synthesis of Compound B-40

Compound B-40 was synthesized in the same manner as in Synthesis Example 11-1 with the exception of using the target compound of Preparation Example 1 and 4-([1,1′-biphenyl]-4-yl)-6-(4-(3-chloronaphthalen-1-yl)phenyl)-2-phenylpyrimidine instead of the target compound of Preparation Example 2 and 2-([1,1′-biphenyl]-4-yl)-4-(4-(3-chloronaphthalen-1-yl)phenyl)-6-phenyl-1,3,5-triazine, respectively.

[LCMS]: 723

### [Synthesis Example 11-7] Synthesis of Compound B-44

Compound B-44 was synthesized in the same manner as in Synthesis Example 11-1 with the exception of using the target compound of Preparation Example 2 and 4-([1,1′-biphenyl]-4-yl)-6-(4-(3-chloronaphthalen-1-yl)phenyl)-2-phenylpyrimidine instead of the target compound of Preparation Example 3 and 2-([1,1′-biphenyl]-4-yl)-4-(4-(3-chloronaphthalen-1-yl)phenyl)-6-phenyl-1,3,5-triazine, respectively.

[LCMS]: 723

### [Synthesis Example 11-8] Synthesis of Compound B-48

Compound B-48 was synthesized in the same manner as in Synthesis Example 11-1 with the exception of using the target compound of Preparation Example 4 and 4-([1,1′-biphenyl]-4-yl)-6-(4-(3-chloronaphthalen-1-yl)phenyl)-2-phenylpyrimidine instead of the target compound of Preparation Example 2 and 2-([1,1′-biphenyl]-4-yl)-4-(4-(3-chloronaphthalen-1-yl)phenyl)-6-phenyl-1,3,5-triazine, respectively.

[LCMS]: 723

### [Synthesis Example 12-1] Synthesis of Compound A-53

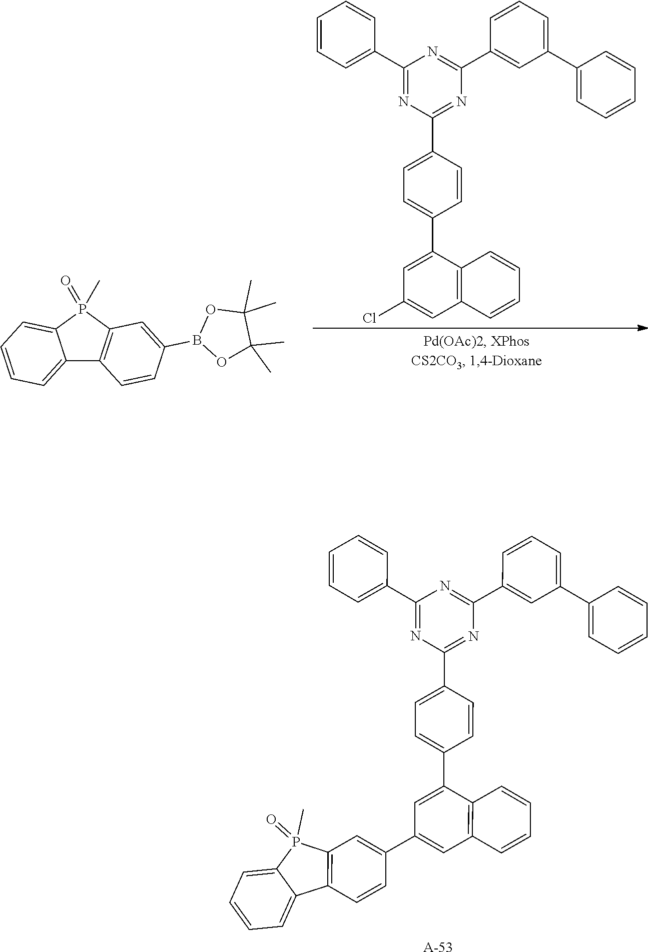 [SMILES: CC1(C)OB(c2ccc3c(c2)P(C)(=O)c2ccccc2-3)OC1(C)C ; Clc1cc(-c2ccc(-c3nc(-c4ccccc4)nc(-c4cccc(-c5ccccc5)c4)n3)cc2)c2ccccc2c1 ; CP1(=O)c2ccccc2-c2ccc(-c3cc(-c4ccc(-c5nc(-c6ccccc6)nc(-c6cccc(-c7ccccc7)c6)n5)cc4)c4ccccc4c3)cc21 ; "A-53"]

In 200 ml of 1,4-dioxane, the target compound of Preparation Example 2 (10 g, 29.4 mmol), 2-([1,1′-biphenyl]-3-yl)-4-(4-(3-chloronaphthalen-1-yl)phenyl)-6-phenyl-1,3,5-triazine (17.66 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-53 (15.32 g, yield 72%).

[LCMS]: 723

### [Synthesis Example 12-2] Synthesis of Compound A-49

Compound A-49 was synthesized in the same manner as in Synthesis Example 12-1 with the exception of using the target compound of Preparation Example 1 instead of the target compound of Preparation Example 2.

[LCMS]: 723

### [Synthesis Example 12-3] Synthesis of Compound A-57

Compound A-57 was synthesized in the same manner as in Synthesis Example 12-1 with the exception of using the target compound of Preparation Example 3 instead of the target compound of Preparation Example 2.

[LCMS]: 723

### [Synthesis Example 12-4] Synthesis of Compound A-61

Compound A-61 was synthesized in the same manner as in Synthesis Example 12-1 with the exception of using the target compound of Preparation Example 4 instead of the target compound of Preparation Example 2.

[LCMS]: 723

### [Synthesis Example 12-5] Synthesis of Compound B-49

Compound B-49 was synthesized in the same manner as in Synthesis Example 12-1 with the exception of using 4-([1,1′-biphenyl]-3-yl)-6-(4-(3-chloronaphthalen-1-yl)phenyl)-2-phenylpyrimidine instead of 2-([1,1′-biphenyl]-3-yl)-4-(4-(3-chloronaphthalen-1-yl)phenyl)-6-phenyl-1,3,5-triazine.

[LCMS]: 723

### [Synthesis Example 12-6] Synthesis of Compound B-53

Compound B-53 was synthesized in the same manner as in Synthesis Example 12-1 with the exception of using the target compound of Preparation Example 1 and 4-([1,1′-biphenyl]-3-yl)-6-(4-(3-chloronaphthalen-1-yl)phenyl)-2-phenylpyrimidine instead of the target compound of Preparation Example 2 and 2-([1,1′-biphenyl]-3-yl)-4-(4-(3-chloronaphthalen-1-yl)phenyl)-6-phenyl-1,3,5-triazine, respectively.

[LCMS]: 723

### [Synthesis Example 12-7] Synthesis of Compound B-57

Compound B-57 was synthesized in the same manner as in Synthesis Example 12-1 with the exception of using the target compound of Preparation Example 3 and 4-([1,1′-biphenyl]-3-yl)-6-(4-(3-chloronaphthalen-1-yl)phenyl)-2-phenylpyrimidine instead of the target compound of Preparation Example 2 and 2-([1,1′-biphenyl]-3-yl)-4-(4-(3-chloronaphthalen-1-yl)phenyl)-6-phenyl-1,3,5-triazine, respectively.

[LCMS]: 723

### [Synthesis Example 12-8] Synthesis of Compound B-61

Compound B-61 was synthesized in the same manner as in Synthesis Example 12-1 with the exception of using the target compound of Preparation Example 4 and 4-([1,1′-biphenyl]-3-yl)-6-(4-(3-chloronaphthalen-1-yl)phenyl)-2-phenylpyrimidine instead of the target compound of Preparation Example 2 and 2-([1,1′-biphenyl]-3-yl)-4-(4-(3-chloronaphthalen-1-yl)phenyl)-6-phenyl-1,3,5-triazine, respectively.

[LCMS]: 723

### [Synthesis Example 13-1] Synthesis of Compound A-54

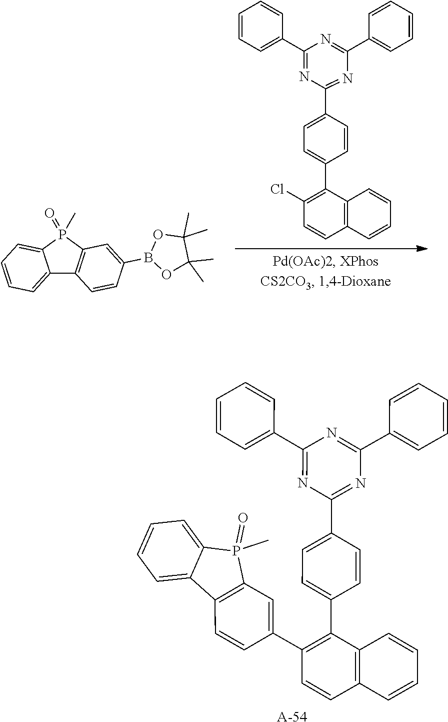 [SMILES: CC1(C)OB(c2ccc3c(c2)P(C)(=O)c2ccccc2-3)OC1(C)C ; Clc1ccc2ccccc2c1-c1ccc(-c2nc(-c3ccccc3)nc(-c3ccccc3)n2)cc1 ; CP1(=O)c2ccccc2-c2ccc(-c3ccc4ccccc4c3-c3ccc(-c4nc(-c5ccccc5)nc(-c5ccccc5)n4)cc3)cc21 ; "A-54"]

In 200 ml of 1,4-dioxane, the target compound of Preparation Example 2 (10 g, 29.4 mmol), 2-(4-(2-chloronaphthalen-1-yl)phenyl)-4,6-diphenyl-1,3,5-triazine (15.2 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-54 (13.71 g, yield 72%).

[LCMS]: 647

### [Synthesis Example 13-2] Synthesis of Compound A-50

Compound A-50 was synthesized in the same manner as in Synthesis Example 13-1 with the exception of using the target compound of Preparation Example 1 instead of the target compound of Preparation Example 2.

[LCMS]: 647

### [Synthesis Example 13-3] Synthesis of Compound A-58

Compound A-58 was synthesized in the same manner as in Synthesis Example 13-1 with the exception of using the target compound of Preparation Example 3 instead of the target compound of Preparation Example 2.

[LCMS]: 647

### [Synthesis Example 13-4] Synthesis of Compound A-62

Compound A-62 was synthesized in the same manner as in Synthesis Example 13-1 with the exception of using the target compound of Preparation Example 4 instead of the target compound of Preparation Example 2.

[LCMS]: 647

### [Synthesis Example 13-5] Synthesis of Compound B-50

Compound B-50 was synthesized in the same manner as in Synthesis Example 13-1 with the exception of using 4-(4-(2-chloronaphthalen-1-yl)phenyl)-2,6-diphenylpyrimidine instead of 2-(4-(2-chloronaphthalen-1-yl)phenyl)-4,6-diphenyl-1,3,5-triazine.

[LCMS]: 647

### [Synthesis Example 13-6] Synthesis of Compound B-54

Compound B-54 was synthesized in the same manner as in Synthesis Example 13-1 with the exception of using the target compound of Preparation Example 1 and 4-(4-(2-chloronaphthalen-1-yl)phenyl)-2,6-diphenylpyrimidineinstead of the target compound of Preparation Example 2 and 2-(4-(2-chloronaphthalen-1-yl)phenyl)-4,6-diphenyl-1,3,5-triazine, respectively.

[LCMS]: 647

### [Synthesis Example 13-7] Synthesis of Compound B-58

Compound B-58 was synthesized in the same manner as in Synthesis Example 13-1 with the exception of using the target compound of Preparation Example 3 and 4-(4-(2-chloronaphthalen-1-yl)phenyl)-2,6-diphenylpyrimidininstead of the target compound of Preparation Example 2 and 2-(4-(2-chloronaphthalen-1-yl)phenyl)-4,6-diphenyl-1,3,5-triazine, respectively.

[LCMS]: 647

### [Synthesis Example 13-8] Synthesis of Compound B-62

Compound B-62 was synthesized in the same manner as in Synthesis Example 13-1 with the exception of using the target compound of Preparation Example 4 and 4-(4-(2-chloronaphthalen-1-yl)phenyl)-2,6-diphenylpyrimidineinstead of the target compound of Preparation Example 2 and 2-(4-(2-chloronaphthalen-1-yl)phenyl)-4,6-diphenyl-1,3,5-triazine, respectively.

[LCMS]: 647

### [Synthesis Example 14-1] Synthesis of Compound A-55

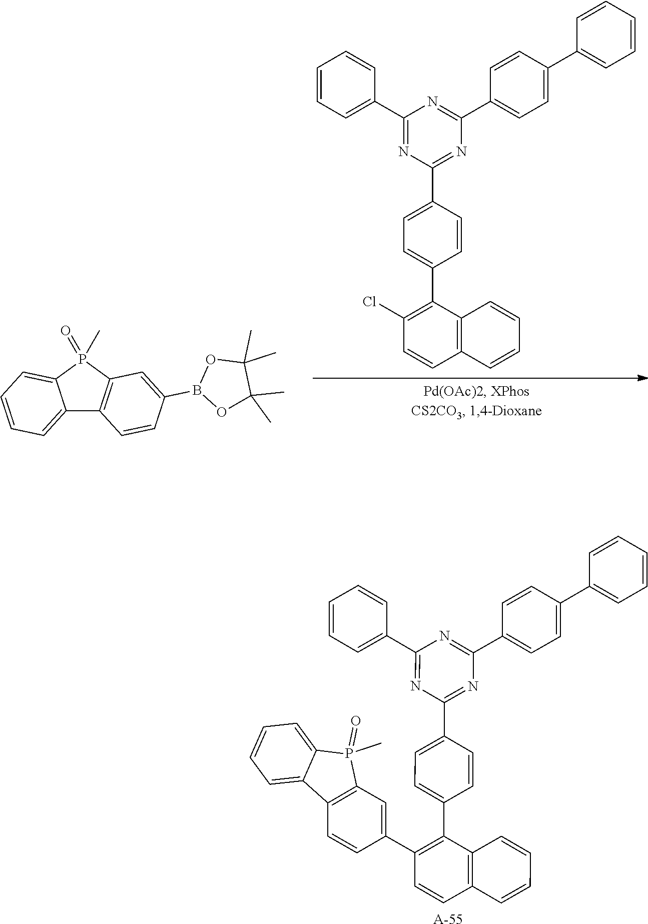

In 200 ml of 1,4-dioxane, the target compound of Preparation Example 2 (10 g, 29.4 mmol), 2-([1,1′-biphenyl]-4-yl)-4-(4-(2-chloronaphthalen-1-yl)phenyl)-6-phenyl-1,3,5-triazine (17.66 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-55 (15.32 g, yield 72%).

[LCMS]: 723

### [Synthesis Example 14-2] Synthesis of Compound A-51

Compound A-51 was synthesized in the same manner as in Synthesis Example 14-1 with the exception of using the target compound of Preparation Example 1 instead of the target compound of Preparation Example 2.

[LCMS]: 723

### [Synthesis Example 14-3] Synthesis of Compound A-59

Compound A-59 was synthesized in the same manner as in Synthesis Example 14-1 with the exception of using the target compound of Preparation Example 3 instead of the target compound of Preparation Example 2.

[LCMS]: 723

### [Synthesis Example 14-4] Synthesis of Compound A-63

Compound A-63 was synthesized in the same manner as in Synthesis Example 14-1 with the exception of using the target compound of Preparation Example 4 instead of the target compound of Preparation Example 2.

[LCMS]: 723

### [Synthesis Example 14-5] Synthesis of Compound B-51

Compound B-51 was synthesized in the same manner as in Synthesis Example 14-1 with the exception of using 4-([1,1′-biphenyl]-4-yl)-6-(4-(2-chloronaphthalen-1-yl)phenyl)-2-phenylpyrimidine instead of 2-([1,1′-biphenyl]-4-yl)-4-(4-(2-chloronaphthalen-1-yl)phenyl)-6-phenyl-1,3,5-triazine.

[LCMS]: 723

### [Synthesis Example 14-6] Synthesis of Compound B-55

Compound B-55 was synthesized in the same manner as in Synthesis Example 14-1 with the exception of using the target compound of Preparation Example 1 and 4-([1,1′-biphenyl]-4-yl)-6-(4-(2-chloronaphthalen-1-yl)phenyl)-2-phenylpyrimidine instead of the target compound of Preparation Example 2 and 2-([1,1′-biphenyl]-4-yl)-4-(4-(2-chloronaphthalen-1-yl)phenyl)-6-phenyl-1,3,5-triazine, respectively.

[LCMS]: 723

### [Synthesis Example 14-7] Synthesis of Compound B-59

Compound B-59 was synthesized in the same manner as in Synthesis Example 14-1 with the exception of using the target compound of Preparation Example 3 and 4-([1,1′-biphenyl]-4-yl)-6-(4-(2-chloronaphthalen-1-yl)phenyl)-2-phenylpyrimidine instead of the target compound of Preparation Example 2 and 2-([1,1′-biphenyl]-4-yl)-4-(4-(2-chloronaphthalen-1-yl)phenyl)-6-phenyl-1,3,5-triazine, respectively.

[LCMS]: 723

### [Synthesis Example 14-8] Synthesis of Compound B-63

Compound B-63 was synthesized in the same manner as in Synthesis Example 14-1 with the exception of using the target compound of Preparation Example 4 and 4-(4-(2-chloronaphthalen-1-yl)phenyl)-2,6-diphenylpyrimidine instead of the target compound of Preparation Example 2 and 2-(4-(2-chloronaphthalen-1-yl)phenyl)-4,6-diphenyl-1,3,5-triazine, respectively.

[LCMS]: 723

### [Synthesis Example 15-1] Synthesis of Compound A-56

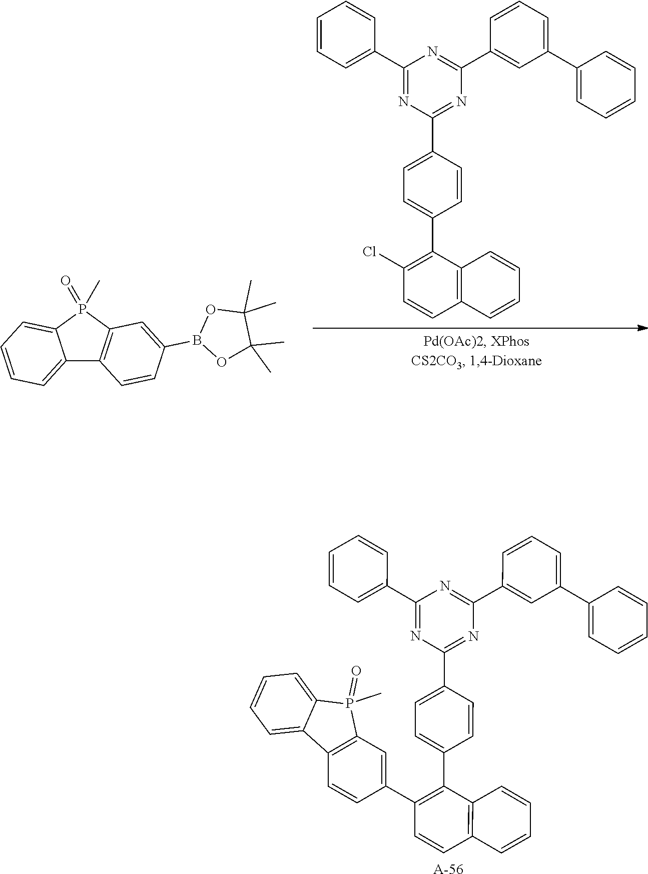

In 200 ml of 1,4-dioxane, the target compound of Preparation Example 2 (10 g, 29.4 mmol), 2-([1,1′-biphenyl]-3-yl)-4-(4-(2-chloronaphthalen-1-yl)phenyl)-6-phenyl-1,3,5-triazine (17.66 g, 32.34 mmol), Pd(OAc)₂ (0.33 g, 1.47 mmol), Cs₂CO₃ (28.73 g, 88.19 mmol), XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-56 (15.32 g. yield 72%).

[LCMS]: 723

### [Synthesis Example 15-2] Synthesis of Compound A-52

Compound A-52 was synthesized in the same manner as in Synthesis Example 15-1 with the exception of using the target compound of Preparation Example 1 instead of the target compound of Preparation Example 2.

[LCMS]: 723

### [Synthesis Example 15-3] Synthesis of Compound A-60

Compound A-60 was synthesized in the same manner as in Synthesis Example 15-1 with the exception of using the target compound of Preparation Example 3 instead of the target compound of Preparation Example 2.

[LCMS]: 723

### [Synthesis Example 15-4] Synthesis of Compound A-64

Compound A-64 was synthesized in the same manner as in Synthesis Example 15-1 with the exception of using the target compound of Preparation Example 4 instead of the target compound of Preparation Example 2.

[LCMS]: 723

### [Synthesis Example 15-5] Synthesis of Compound B-52

Compound B-52 was synthesized in the same manner as in Synthesis Example 15-1 with the exception of using 4-([1,1′-biphenyl]-3-yl)-6-(4-(2-chloronaphthalen-1-yl)phenyl)-2-phenylpyrimidine instead of 2-([1,1′-biphenyl]-3-yl)-4-(4-(2-chloronaphthalen-1-yl)phenyl)-6-phenyl-1,3,5-triazine.

[LCMS]: 723

### [Synthesis Example 15-6] Synthesis of Compound B-56

Compound B-56 was synthesized in the same manner as in Synthesis Example 15-1 with the exception of using the target compound of Preparation Example 1 and 4-([1,1′-biphenyl]-3-yl)-6-(4-(2-chloronaphthalen-1-yl)phenyl)-2-phenylpyrimidine instead of the target compound of Preparation Example 2 and 2-([1,1′-biphenyl]-3-yl)-4-(4-(2-chloronaphthalen-1-yl)phenyl)-6-phenyl-1,3,5-triazine, respectively.

[LCMS]: 723

### [Synthesis Example 15-7] Synthesis of Compound B-60

Compound B-60 was synthesized in the same manner as in Synthesis Example 15-1 with the exception of using the target compound of Preparation Example 3 and 4-([1,1′-biphenyl]-3-yl)-6-(4-(2-chloronaphthalen-1-yl)phenyl)-2-phenylpyrimidine instead of the target compound of Preparation Example 2 and 2-([1,1′-biphenyl]-3-yl)-4-(4-(2-chloronaphthalen-1-yl)phenyl)-6-phenyl-1,3,5-triazine, respectively.

[LCMS]: 723

### [Synthesis Example 15-8] Synthesis of Compound B-64

Compound B-64 was synthesized in the same manner as in Synthesis Example 15-1 with the exception of using the target compound of Preparation Example 4 and 4-([1,1′-biphenyl]-3-yl)-6-(4-(2-chloronaphthalen-1-yl)phenyl)-2-phenylpyrimidine instead of the target compound of Preparation Example 2 and 2-([1,1′-biphenyl]-3-yl)-4-(4-(2-chloronaphthalen-1-yl)phenyl)-6-phenyl-1,3,5-triazine, respectively.

[LCMS]: 723

### [Synthesis Example 16-1] Synthesis of Compound A-69

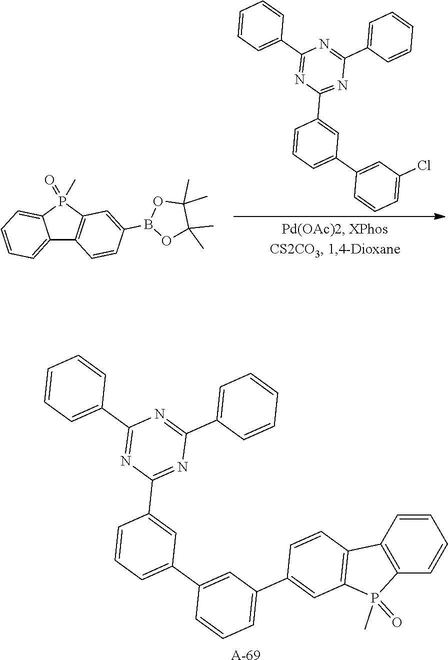

In 200 ml of 1,4-dioxane, the target compound of Preparation Example 2 (10 g, 29.4 mmol), 2-(3′-chloro-[1,1′-biphenyl]-3-yl)-4,6-diphenyl-1,3,5-triazine (13.58 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-69 (12.65 g, yield 72%).

[LCMS]: 597

### [Synthesis Example 16-2] Synthesis of Compound A-65

Compound A-65 was synthesized in the same manner as in Synthesis Example 16-1 with the exception of using the target compound of Preparation Example 1 instead of the target compound of Preparation Example 2.

[LCMS]: 597

### [Synthesis Example 16-3] Synthesis of Compound A-73

Compound A-73 was synthesized in the same manner as in Synthesis Example 16-1 with the exception of using the target compound of Preparation Example 3 instead of the target compound of Preparation Example 2.

[LCMS]: 597

### [Synthesis Example 16-4] Synthesis of Compound A-77

Compound A-77 was synthesized in the same manner as in Synthesis Example 16-1 with the exception of using the target compound of Preparation Example 4 instead of the target compound of Preparation Example 2.

[LCMS]: 597

### [Synthesis Example 16-5] Synthesis of Compound B-65

Compound B-65 was synthesized in the same manner as in Synthesis Example 16-1 with the exception of using 4-(3′-chloro-[1,1′-biphenyl]-3-yl)-2,6-diphenylpyrimidine instead of 2-(3′-chloro-[1,1′-biphenyl]-3-yl)-4,6-diphenyl-1,3,5-triazine.

[LCMS]: 597

### [Synthesis Example 16-6] Synthesis of Compound B-69

Compound B-69 was synthesized in the same manner as in Synthesis Example 16-1 with the exception of using the target compound of Preparation Example 1 and 4-(3′-chloro-[1,1′-biphenyl]-3-yl)-2,6-diphenylpyrimidine instead of the target compound of Preparation Example 2 and 2-(3′-chloro-[1,1′-biphenyl]-3-yl)-4,6-diphenyl-1,3,5-triazine, respectively.

[LCMS]: 597

### [Synthesis Example 16-7] Synthesis of Compound B-73

Compound B-73 was synthesized in the same manner as in Synthesis Example 16-1 with the exception of using the target compound of Preparation Example 3 and 4-(3′-chloro-[1,1′-biphenyl]-3-yl)-2,6-diphenylpyrimidine instead of the target compound of Preparation Example 2 and 2-(3′-chloro-[1,1′-biphenyl]-3-yl)-4,6-diphenyl-1,3,5-triazine, respectively.

[LCMS]: 597

### [Synthesis Example 16-8] Synthesis of Compound B-77

Compound B-77 was synthesized in the same manner as in Synthesis Example 16-1 with the exception of using the target compound of Preparation Example 4 and 4-(3′-chloro-[1,1′-biphenyl]-3-yl)-2,6-diphenylpyrimidine instead of the target compound of Preparation Example 2 and 2-(3′-chloro-[1,1′-biphenyl]-3-yl)-4,6-diphenyl-1,3,5-triazine, respectively.

[LCMS]: 597

### [Synthesis Example 17-1] Synthesis of Compound A-70

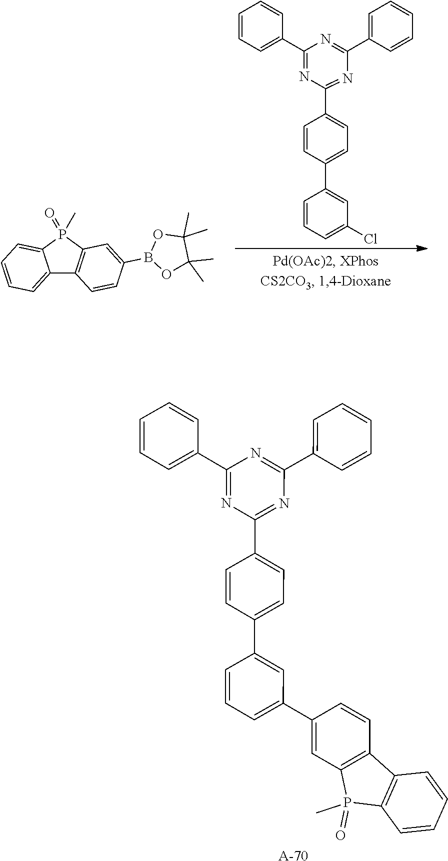 [SMILES: CC1(C)OB(c2ccc3c(c2)P(C)(=O)c2ccccc2-3)OC1(C)C ; Clc1cccc(-c2ccc(-c3nc(-c4ccccc4)nc(-c4ccccc4)n3)cc2)c1 ; CP1(=O)c2ccccc2-c2ccc(-c3cccc(-c4ccc(-c5nc(-c6ccccc6)nc(-c6ccccc6)n5)cc4)c3)cc21 ; "A-70"]

In 200 ml of 1,4-dioxane, the target compound of Preparation Example 2 (10 g, 29.4 mmol), 2-(3′-chloro-[1,1′-biphenyl]-4-yl)-4,6-diphenyl-1,3,5-triazine (13.58 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-70 (12.65 g, yield 72%).

[LCMS]: 597

### [Synthesis Example 17-2] Synthesis of Compound A-66

Compound A-66 was synthesized in the same manner as in Synthesis Example 17-1 with the exception of using the target compound of Preparation Example 1 instead of the target compound of Preparation Example 2.

[LCMS]: 597

### [Synthesis Example 17-3] Synthesis of Compound A-74

Compound A-74 was synthesized in the same manner as in Synthesis Example 17-1 with the exception of using the target compound of Preparation Example 2 instead of the target compound of Preparation Example 3.

[LCMS]: 597

### [Synthesis Example 17-4] Synthesis of Compound A-78

Compound A-78 was synthesized in the same manner as in Synthesis Example 17-1 with the exception of using the target compound of Preparation Example 4 instead of the target compound of Preparation Example 2.

[LCMS]: 597

### [Synthesis Example 17-5] Synthesis of Compound B-66

Compound B-69 was synthesized in the same manner as in Synthesis Example 17-1 with the exception of using 4-(3′-chloro-[1,1′-biphenyl]-4-yl)-2,6-diphenylpyrimidine instead of 2-(3′-chloro-[1,1′-biphenyl]-4-yl)-4,6-diphenyl-1,3,5-triazine.

[LCMS]: 597

### [Synthesis Example 17-6] Synthesis of Compound B-70

Compound B-70 was synthesized in the same manner as in Synthesis Example 17-1 with the exception of using the target compound of Preparation Example 1 and 4-(3′-chloro-[1,1′-biphenyl]-4-yl)-2,6-diphenylpyrimidine instead of the target compound of Preparation Example 2 and 2-(3′-chloro-[1,1′-biphenyl]-4-yl)-4,6-diphenyl-1,3,5-triazine, respectively.

[LCMS]: 597

### [Synthesis Example 17-7] Synthesis of Compound B-74

Compound B-74 was synthesized in the same manner as in Synthesis Example 17-1 with the exception of using the target compound of Preparation Example 3 and 4-(3′-chloro-[1,1′-biphenyl]-4-yl)-2,6-diphenylpyrimidine instead of the target compound of Preparation Example 2 and 2-(3′-chloro-[1,1′-biphenyl]-4-yl)-4,6-diphenyl-1,3,5-triazine, respectively.

[LCMS]: 597

### [Synthesis Example 17-8] Synthesis of Compound B-78

Compound B-78 was synthesized in the same manner as in Synthesis Example 17-1 with the exception of using the target compound of Preparation Example 4 and 4-(3′-chloro-[1,1′-biphenyl]-4-yl)-2,6-diphenylpyrimidine instead of the target compound of Preparation Example 2 and 2-(3′-chloro-[1,1′-biphenyl]-4-yl)-4,6-diphenyl-1,3,5-triazine, respectively.

[LCMS]: 597

### [Synthesis Example 18-1] Synthesis of Compound A-71

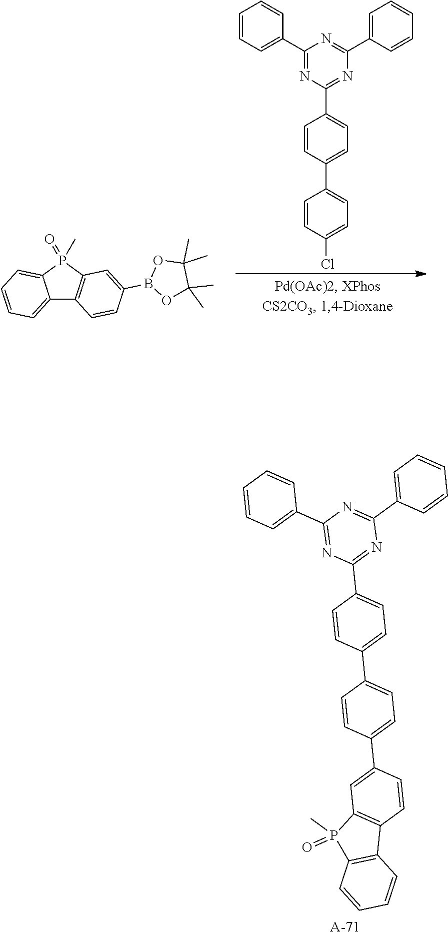

In 200 ml of 1,4-dioxane, the target compound of Preparation Example 2 (10 g, 29.4 mmol), 2-(4′-chloro-[1,1′-biphenyl]-4-yl)-4,6-diphenyl-1,3,5-triazine (13.58 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-71 (12.65 g, yield 72%).

[LCMS]: 597

### [Synthesis Example 18-2] Synthesis of Compound A-67

Compound A-67 was synthesized in the same manner as in Synthesis Example 18-1 with the exception of using the target compound of Preparation Example 1 instead of the target compound of Preparation Example 2.

[LCMS]: 597

### [Synthesis Example 18-3] Synthesis of Compound A-75

Compound A-75 was synthesized in the same manner as in Synthesis Example 18-1 with the exception of using the target compound of Preparation Example 3 instead of the target compound of Preparation Example 2.

[LCMS]: 597

### [Synthesis Example 18-4] Synthesis of Compound A-79

Compound A-79 was synthesized in the same manner as in Synthesis Example 18-1 with the exception of using the target compound of Preparation Example 4 instead of the target compound of Preparation Example 2.

[LCMS]: 597

### [Synthesis Example 18-5] Synthesis of Compound B-67

Compound B-67 was synthesized in the same manner as in Synthesis Example 18-1 with the exception of using 4-(4′-chloro-[1,1′-biphenyl]-4-yl)-2,6-diphenylpyrimidine instead of 2-(4′-chloro-[1,1′-biphenyl]-4-yl)-4,6-diphenyl-1,3,5-triazine.

[LCMS]: 597

### [Synthesis Example 18-6] Synthesis of Compound B-71

Compound B-71 was synthesized in the same manner as in Synthesis Example 18-1 with the exception of using the target compound of Preparation Example 1 and 4-(4′-chloro-[1,1′-biphenyl]-4-yl)-2,6-diphenylpyrimidine instead of the target compound of Preparation Example 2 and 2-(4′-chloro-[1,1′-biphenyl]-4-yl)-4,6-diphenyl-1,3,5-triazine, respectively.

[LCMS]: 597

### [Synthesis Example 18-7] Synthesis of Compound B-75

Compound B-75 was synthesized in the same manner as in Synthesis Example 18-1 with the exception of using the target compound of Preparation Example 3 and 4-(4′-chloro-[1,1′-biphenyl]-4-yl)-2,6-diphenylpyrimidine instead of the target compound of Preparation Example 2 and 2-(4′-chloro-[1,1′-biphenyl]-4-yl)-4,6-diphenyl-1,3,5-triazine, respectively.

[LCMS]: 597

### [Synthesis Example 18-8] Synthesis of Compound B-79

Compound B-79 was synthesized in the same manner as in Synthesis Example 18-1 with the exception of using the target compound of Preparation Example 4 and 4-(4′-chloro-[1,1′-biphenyl]-4-yl)-2,6-diphenylpyrimidine instead of the target compound of Preparation Example 2 and 2-(4′-chloro-[1,1′-biphenyl]-4-yl)-4,6-diphenyl-1,3,5-triazine, respectively.

[LCMS]: 597

### [Synthesis Example 19-1] Synthesis of Compound A-72

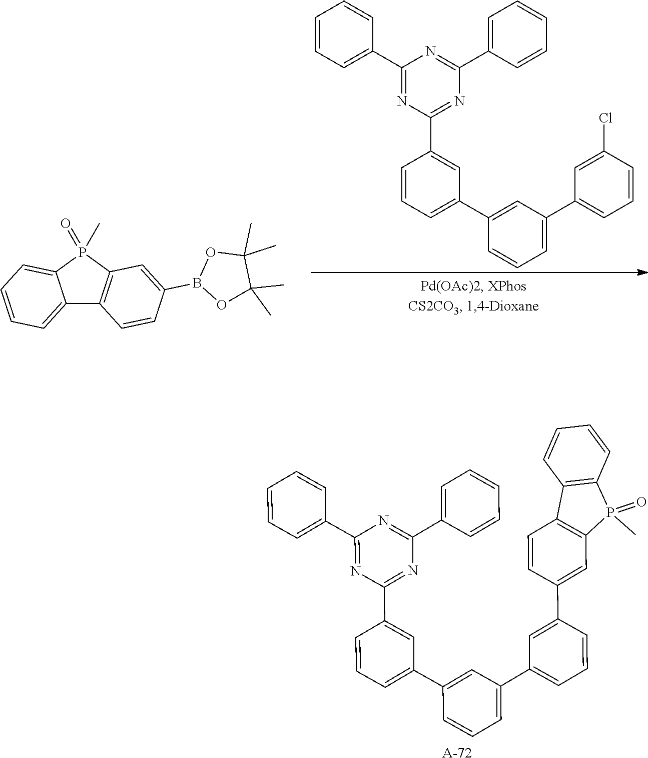

In 200 ml of 1,4-dioxane, the target compound of Preparation Example 2 (10 g, 29.4 mmol), 2-(3″-chloro-[1,1′:3′,1‘ ’-terphenyl]-3-yl)-4,6-diphenyl-1,3,5-triazine (16.04 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound A-72 (14.26 g, yield 72%).

[LCMS]: 673

### [Synthesis Example 19-2] Synthesis of Compound A-68

Compound A-68 was synthesized in the same manner as in Synthesis Example 19-1 with the exception of using the target compound of Preparation Example 1 instead of the target compound of Preparation Example 2.

[LCMS]: 673

### [Synthesis Example 19-3] Synthesis of Compound A-76

Compound A-76 was synthesized in the same manner as in Synthesis Example 19-1 with the exception of using the target compound of Preparation Example 3 instead of the target compound of Preparation Example 2.

[LCMS]: 673

### [Synthesis Example 19-4] Synthesis of Compound A-80

Compound A-80 was synthesized in the same manner as in Synthesis Example 19-1 with the exception of using the target compound of Preparation Example 4 instead of the target compound of Preparation Example 2.

[LCMS]: 673

### [Synthesis Example 19-5] Synthesis of Compound B-68

Compound B-68 was synthesized in the same manner as in Synthesis Example 19-1 with the exception of using 4-(3″-chloro-[1,1′:3′,1″-terphenyl]-3-yl)-2,6-diphenylpyrimidine instead of 2-(3″-chloro-[1,1′:3′,1‘ ’-terphenyl]-3-yl)-4,6-diphenyl-1,3,5-triazine.

[LCMS]: 673

### [Synthesis Example 19-6] Synthesis of Compound B-72

Compound B-72 was synthesized in the same manner as in Synthesis Example 91-1 with the exception of using the target compound of Preparation Example 1 and 4-(3″-chloro-[1,1′:3′,1″-terphenyl]-3-yl)-2,6-diphenylpyrimidine instead of the target compound of Preparation Example 2 and 2-(3″-chloro-[1,1′:3′,1″-terphenyl]-3-yl)-4,6-diphenyl-1,3,5-triazine, respectively.

[LCMS]: 673

### [Synthesis Example 19-7] Synthesis of Compound B-76

Compound B-76 was synthesized in the same manner as in Synthesis Example 19-1 with the exception of using the target compound of Preparation Example 3 and 4-(3″-chloro-[1,1′:3′,1″-terphenyl]-3-yl)-2,6-diphenylpyrimidine instead of the target compound of Preparation Example 2 and 2-(3″-chloro-[1,1′:3′,1″-terphenyl]-3-yl)-4,6-diphenyl-1,3,5-triazine, respectively.

[LCMS]: 673

### [Synthesis Example 19-8] Synthesis of Compound B-80

Compound B-80 was synthesized in the same manner as in Synthesis Example 19-1 with the exception of using the target compound of Preparation Example 4 and 4-(3″-chloro-[1,1′:3′,1″-terphenyl]-3-yl)-2,6-diphenylpyrimidine instead of the target compound of Preparation Example 2 and 2-(3″-chloro-[1,1′:3′,1″-terphenyl]-3-yl)-4,6-diphenyl-1,3,5-triazine, respectively.

[LCMS]: 673

### [Synthesis Example 20-1] Synthesis of Compound C-5

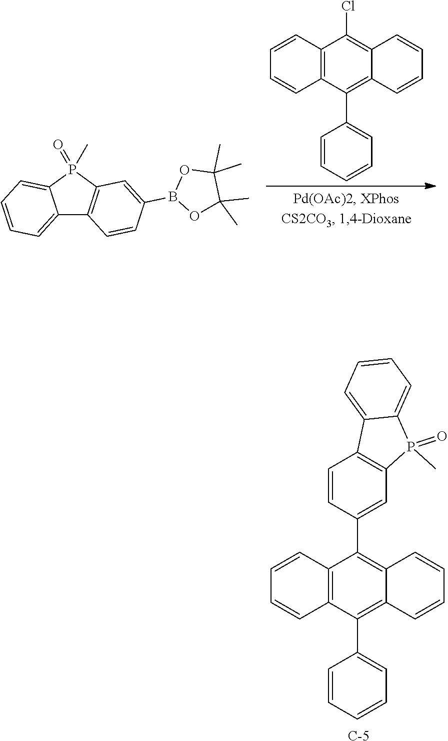

In 200 ml of 1,4-dioxane, the target compound of Preparation Example 2 (10 g, 29.4 mmol), 9-chloro-10-phenylanthracene (9.34 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound C-5 (9.87 g, yield 72%).

[LCMS]: 466

### [Synthesis Example 20-2] Synthesis of Compound C-1

Compound C-1 was synthesized in the same manner as in Synthesis Example 20-1 with the exception of using the target compound of Preparation Example 1 instead of the target compound of Preparation Example 2.

[LCMS]: 466

### [Synthesis Example 20-3] Synthesis of Compound C-9

Compound C-9 was synthesized in the same manner as in Synthesis Example 20-1 with the exception of using the target compound of Preparation Example 3 instead of the target compound of Preparation Example 2.

[LCMS]: 466

### [Synthesis Example 20-4] Synthesis of Compound C-13

Compound C-13 was synthesized in the same manner as in Synthesis Example 20-1 with the exception of using the target compound of Preparation Example 4 instead of the target compound of Preparation Example 2.

[LCMS]: 466

### [Synthesis Example 21-1] Synthesis of Compound C-6

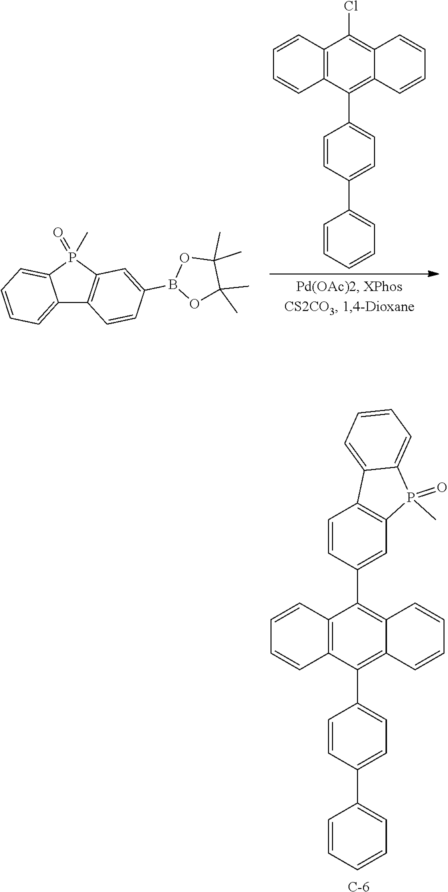

In 200 ml of 1,4-dioxane, the target compound of Preparation Example 2 (10 g, 29.4 mmol), 9-([1,1′-biphenyl]-4-yl)-10-chloroanthracene (11.8 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound C-6 (11.49 g, yield 72%).

[LCMS]: 542

### [Synthesis Example 21-2] Synthesis of Compound C-2

Compound C-2 was synthesized in the same manner as in Synthesis Example 21-1 with the exception of using the target compound of Preparation Example 1 instead of the target compound of Preparation Example 2.

[LCMS]: 542

### [Synthesis Example 21-3] Synthesis of Compound C-10

Compound C-10 was synthesized in the same manner as in Synthesis Example 21-1 with the exception of using the target compound of Preparation Example 3 instead of the target compound of Preparation Example 2.

[LCMS]: 542

### [Synthesis Example 21-4] Synthesis of Compound C-14

Compound C-14 was synthesized in the same manner as in Synthesis Example 21-1 with the exception of using the target compound of Preparation Example 2 instead of the target compound of Preparation Example 4.

[LCMS]: 542

### [Synthesis Example 22-1] Synthesis of Compound C-8

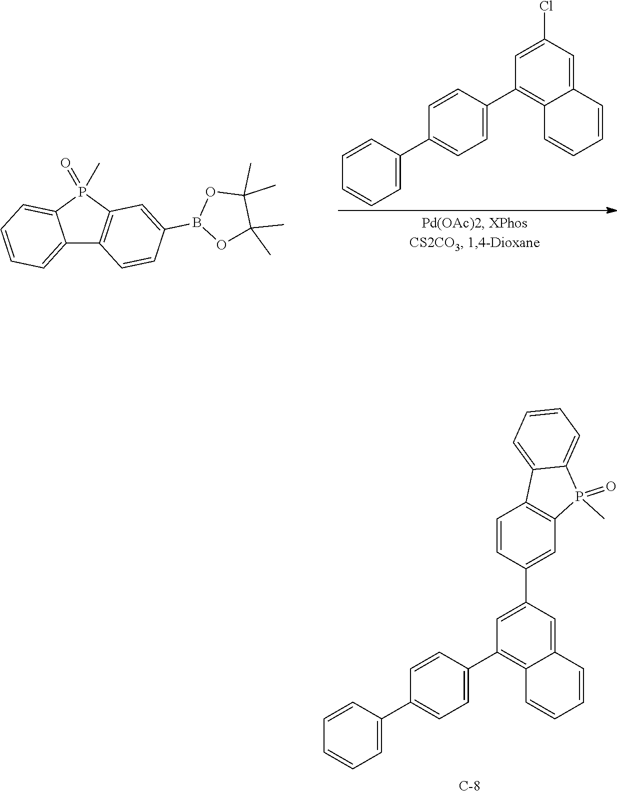

In 200 ml of 1,4-dioxane, the target compound of Preparation Example 2 (10 g, 29.4 mmol), 1-([1,1′-biphenyl]-4-yl)-3-chloronaphthalene (10.43 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound C-8 (10.43 g, yield 72%).

[LCMS]: 492

### [Synthesis Example 22-2] Synthesis of Compound C-4

Compound C-4 was synthesized in the same manner as in Synthesis Example 22-1 with the exception of using the target compound of Preparation Example 1 instead of the target compound of Preparation Example 2.

[LCMS]: 492

### [Synthesis Example 22-3] Synthesis of Compound C-12

Compound C-12 was synthesized in the same manner as in Synthesis Example 22-1 with the exception of using the target compound of Preparation Example 3 instead of the target compound of Preparation Example 2.

[LCMS]: 492

### [Synthesis Example 22-4] Synthesis of Compound C-16

Compound C-16 was synthesized in the same manner as in Synthesis Example 22-1 with the exception of using the target compound of Preparation Example 4 instead of the target compound of Preparation Example 2.

[LCMS]: 492

### [Synthesis Example 23-1] Synthesis of Compound C-22

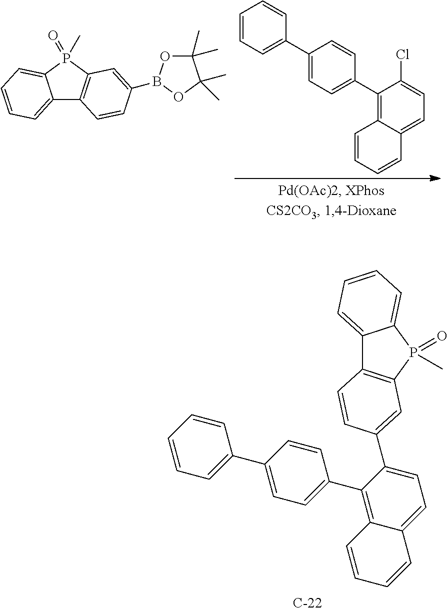

In 200 ml of 1,4-dioxane, the target compound of Preparation Example 2 (10 g, 29.4 mmol), 1-([1,1′-biphenyl]-4-yl)-2-chloronaphthalene (10.43 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound C-22 (10.43 g, yield 72%).

[LCMS]: 492

### [Synthesis Example 23-2] Synthesis of Compound C-18

Compound C-18 was synthesized in the same manner as in Synthesis Example 23-1 with the exception of using the target compound of Preparation Example 1 instead of the target compound of Preparation Example 2.

[LCMS]: 492

### [Synthesis Example 23-3] Synthesis of Compound C-26

Compound C-26 was synthesized in the same manner as in Synthesis Example 23-1 with the exception of using the target compound of Preparation Example 3 instead of the target compound of Preparation Example 2.

[LCMS]: 492

### [Synthesis Example 23-4] Synthesis of Compound C-30

Compound C-30 was synthesized in the same manner as in Synthesis Example 23-1 with the exception of using the target compound of Preparation Example 4 instead of the target compound of Preparation Example 2.

[LCMS]: 492

### [Synthesis Example 24-1] Synthesis of Compound C-23

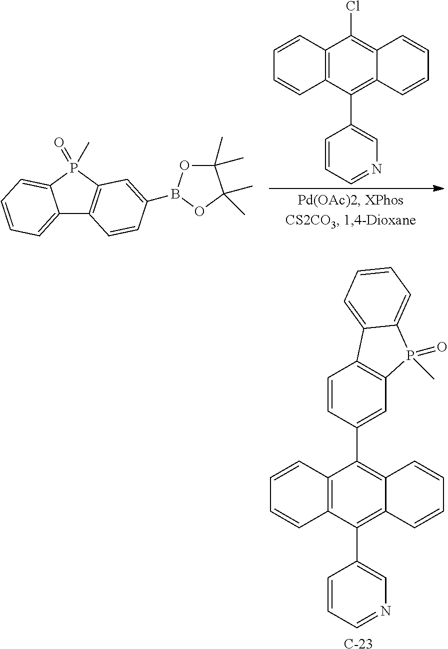

In 200 ml of 1,4-dioxane, the target compound of Preparation Example 2 (10 g, 29.4 mmol), 3-(10-chloroanthracen-9-yl)pyridine (9.37 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound C-23 (9.9 g, yield 72%).

[LCMS]: 467

### [Synthesis Example 24-2] Synthesis of Compound C-19

Compound C-19 was synthesized in the same manner as in Synthesis Example 24-1 with the exception of using the target compound of Preparation Example 1 instead of the target compound of Preparation Example 2.

[LCMS]: 467

### [Synthesis Example 24-3] Synthesis of Compound C-27

Compound C-27 was synthesized in the same manner as in Synthesis Example 24-1 with the exception of using the target compound of Preparation Example 3 instead of the target compound of Preparation Example 2.

[LCMS]: 467

### [Synthesis Example 24-4] Synthesis of Compound C-31

Compound C-31 was synthesized in the same manner as in Synthesis Example 24-1 with the exception of using the target compound of Preparation Example 4 instead of the target compound of Preparation Example 2.

[LCMS]: 467

### [Synthesis Example 25-1] Synthesis of Compound C-24

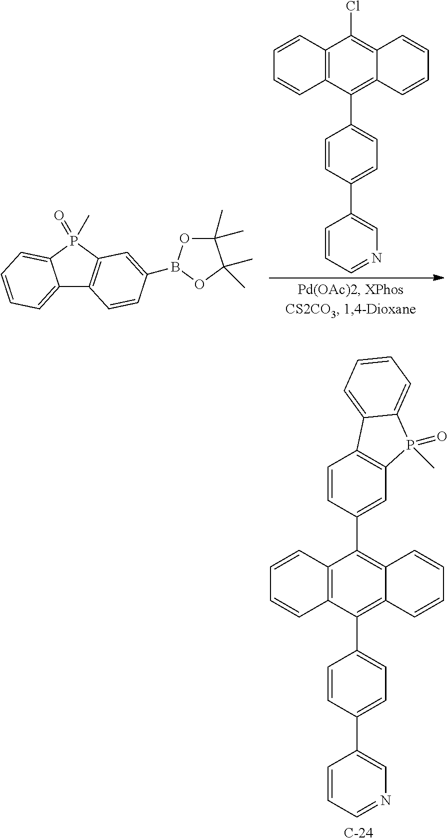

In 200 ml of 1,4-dioxane, the target compound of Preparation Example 2 (10 g, 29.4 mmol), 3-(4-(10-chloroanthracen-9-yl)phenyl)pyridine (11.83 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound C-24 (11.51 g, yield 72%).

[LCMS]: 543

### [Synthesis Example 25-2] Synthesis of Compound C-20

Compound C-20 was synthesized in the same manner as in Synthesis Example 25-1 with the exception of using the target compound of Preparation Example 1 instead of the target compound of Preparation Example 2.

[LCMS]: 543

### [Synthesis Example 25-3] Synthesis of Compound C-28

Compound C-28 was synthesized in the same manner as in Synthesis Example 25-1 with the exception of using the target compound of Preparation Example 3 instead of the target compound of Preparation Example 2.

[LCMS]: 543

### [Synthesis Example 25-4] Synthesis of Compound C-32

Compound C-32 was synthesized in the same manner as in Synthesis Example 25-1 with the exception of using the target compound of Preparation Example 4 instead of the target compound of Preparation Example 2.

[LCMS]: 543

### [Synthesis Example 26-1] Synthesis of Compound C-38

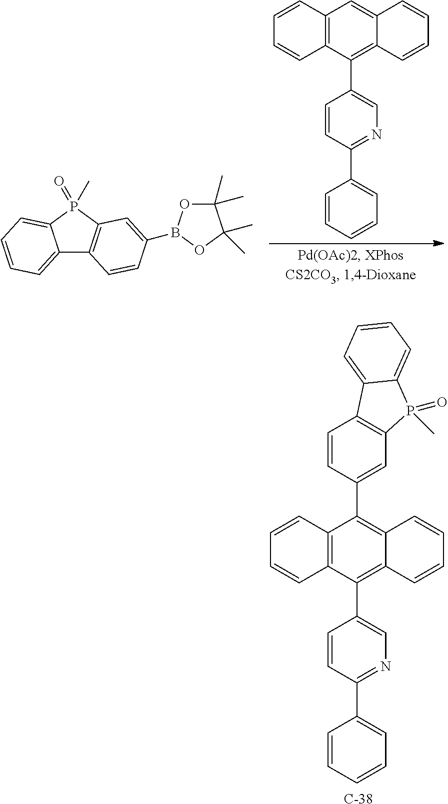

In 200 ml of 1,4-dioxane, the target compound of Preparation Example 2 (10 g, 29.4 mmol), 5-(10-chloroanthracen-9-yl)-2-phenylpyridine (11.83 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound C-38 (11.51 g, yield 72%).

[LCMS]: 543

### [Synthesis Example 26-2] Synthesis of Compound C-33

Compound C-33 was synthesized in the same manner as in Synthesis Example 26-1 with the exception of using the target compound of Preparation Example 1 instead of the target compound of Preparation Example 2.

[LCMS]: 543

### [Synthesis Example 26-3] Synthesis of Compound C-43

Compound C-43 was synthesized in the same manner as in Synthesis Example 26-1 with the exception of using the target compound of Preparation Example 3 instead of the target compound of Preparation Example 2.

[LCMS]: 543

### [Synthesis Example 26-4] Synthesis of Compound C-48

Compound C-48 was synthesized in the same manner as in Synthesis Example 26-1 with the exception of using the target compound of Preparation Example 4 instead of the target compound of Preparation Example 2.

[LCMS]: 543

### [Synthesis Example 27-1] Synthesis of Compound C-40

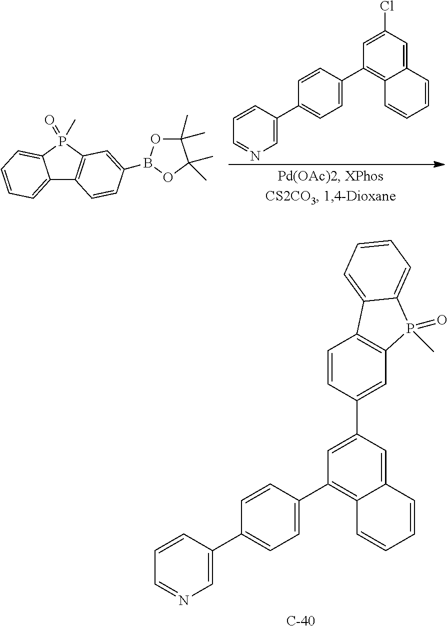

In 200 ml of 1,4-dioxane, the target compound of Preparation Example 2 (10 g, 29.4 mmol), 3-(4-(3-chloronaphthalen-1-yl)phenyl)pyridine (10.21 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound C-40 (10.45 g, yield 72%).

[LCMS]: 493

### [Synthesis Example 27-2] Synthesis of Compound C-35

Compound C-35 was synthesized in the same manner as in Synthesis Example 27-1 with the exception of using the target compound of Preparation Example 1 instead of the target compound of Preparation Example 2.

[LCMS]: 493

### [Synthesis Example 27-3] Synthesis of Compound C-45

Compound C-45 was synthesized in the same manner as in Synthesis Example 27-1 with the exception of using the target compound of Preparation Example 3 instead of the target compound of Preparation Example 2.

[LCMS]: 493

### [Synthesis Example 27-4] Synthesis of Compound C-50

Compound C-50 was synthesized in the same manner as in Synthesis Example 27-1 with the exception of using the target compound of Preparation Example 4 instead of the target compound of Preparation Example 2.

[LCMS]: 493

### [Synthesis Example 28-1] Synthesis of Compound C-42

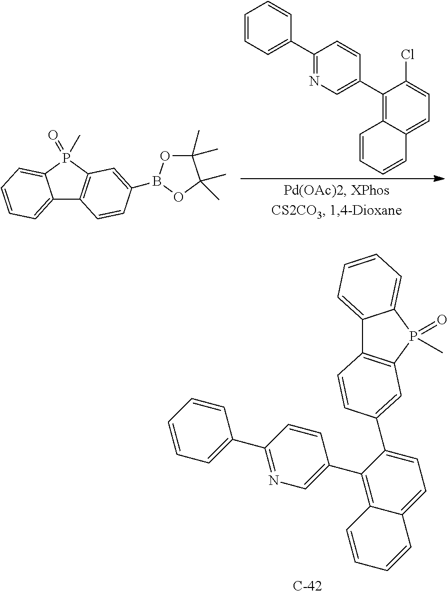

In 200 ml of 1,4-dioxane, the target compound of Preparation Example 2 (10 g, 29.4 mmol), 5-(2-chloronaphthalen-1-yl)-2-phenylpyridine (10.21 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound C-42 (10.45 g, yield 72%).

[LCMS]: 493

### [Synthesis Example 28-2] Synthesis of Compound C-37

Compound C-37 was synthesized in the same manner as in Synthesis Example 28-1 with the exception of using the target compound of Preparation Example 1 instead of the target compound of Preparation Example 2.

[LCMS]: 493

### [Synthesis Example 28-3] Synthesis of Compound C-47

Compound C-47 was synthesized in the same manner as in Synthesis Example 28-1 with the exception of using the target compound of Preparation Example 3 instead of the target compound of Preparation Example 2.

[LCMS]: 493

### [Synthesis Example 28-4] Synthesis of Compound C-52

Compound C-52 was synthesized in the same manner as in Synthesis Example 28-1 with the exception of using the target compound of Preparation Example 4 instead of the target compound of Preparation Example 2.

[LCMS]: 493

### [Synthesis Example 29-1] Synthesis of Compound D-5

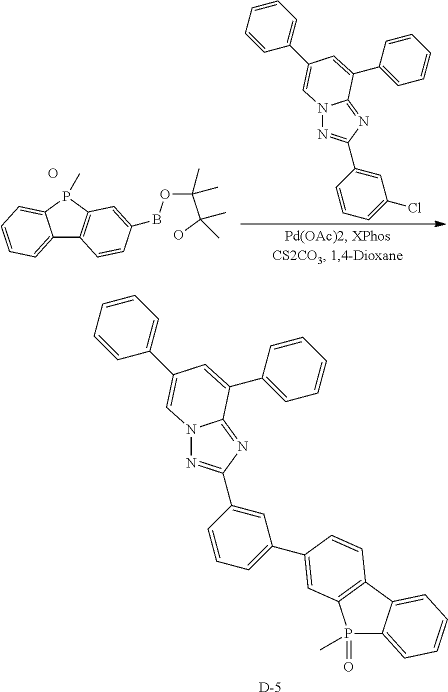

In 200 ml of 1,4-dioxane, the target compound of Preparation Example 2 (10 g, 29.4 mmol), 2-(3-chlorophenyl)-6,8-diphenyl-[1,2,4]triazolo[1,5-a]pyridine (12.35 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound D-5 (11.84 g, yield 72%).

[LCMS]: 559

### [Synthesis Example 29-2] Synthesis of Compound D-1

Compound D-1 was synthesized in the same manner as in Synthesis Example 29-1 with the exception of using the target compound of Preparation Example 1 instead of the target compound of Preparation Example 2.

[LCMS]: 559

### [Synthesis Example 29-3] Synthesis of Compound D-9

Compound D-9 was synthesized in the same manner as in Synthesis Example 29-1 with the exception of using the target compound of Preparation Example 3 instead of the target compound of Preparation Example 2.

[LCMS]: 559

### [Synthesis Example 29-4] Synthesis of Compound D-13

Compound D-13 was synthesized in the same manner as in Synthesis Example 29-1 with the exception of using the target compound of Preparation Example 4 instead of the target compound of Preparation Example 2.

[LCMS]: 559

### [Synthesis Example 30-1] Synthesis of Compound D-6

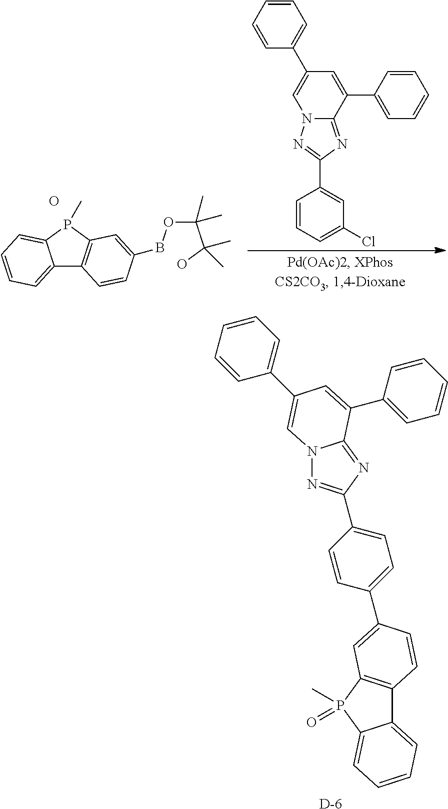

In 200 ml of 1,4-dioxane, the target compound of Preparation Example 2 (10 g, 29.4 mmol), 2-(4-chlorophenyl)-6,8-diphenyl-[1,2,4]triazolo[1,5-a]pyridine (12.35 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound D-6 (11.84 g, yield 72%).

[LCMS]: 559

### [Synthesis Example 30-2] Synthesis of Compound D-2

Compound D-2 was synthesized in the same manner as in Synthesis Example 30-1 with the exception of using the target compound of Preparation Example 1 instead of the target compound of Preparation Example 2.

[LCMS]: 559

### [Synthesis Example 30-3] Synthesis of Compound D-10

Compound D-10 was synthesized in the same manner as in Synthesis Example 30-1 with the exception of using the target compound of Preparation Example 3 instead of the target compound of Preparation Example 2.

[LCMS]: 559

### [Synthesis Example 30-4] Synthesis of Compound D-14

Compound D-14 was synthesized in the same manner as in Synthesis Example 30-1 with the exception of using the target compound of Preparation Example 4 instead of the target compound of Preparation Example 2.

[LCMS]: 559

### [Synthesis Example 31-1] Synthesis of Compound D-8

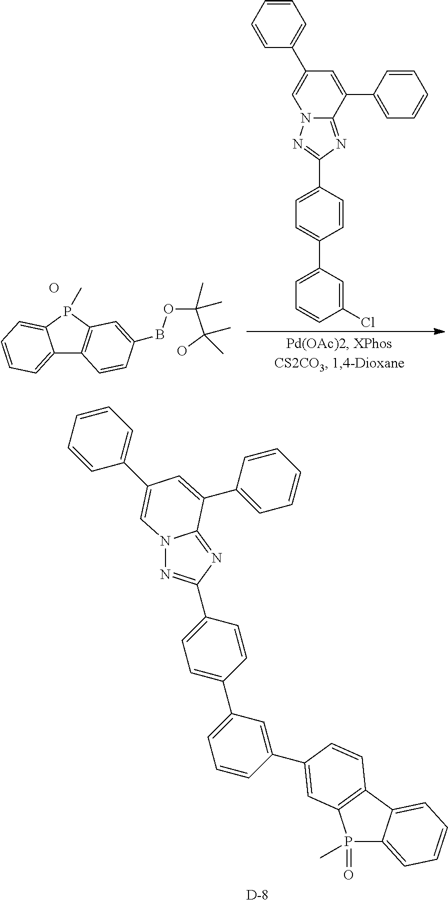

In 200 ml of 1,4-dioxane, the target compound of Preparation Example (10 g, 29.4 mmol), 2-(3′-chloro-[1,1′-biphenyl]-4-yl)-6,8-diphenyl-[1,2,4]triazolo[1,5-a]pyridine (14.81 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound D-8 (13.46 g, yield 72%).

[LCMS]: 635

### [Synthesis Example 31-2] Synthesis of Compound D-4

Compound D-4 was synthesized in the same manner as in Synthesis Example 31-1 with the exception of using the target compound of Preparation Example 1 instead of the target compound of Preparation Example 2

[LCMS]: 635

### [Synthesis Example 31-3] Synthesis of Compound D-12

Compound D-12 was synthesized in the same manner as in Synthesis Example 31-1 with the exception of using the target compound of Preparation Example 3 instead of the target compound of Preparation Example 2.

[LCMS]: 635

### [Synthesis Example 31-4] Synthesis of Compound D-16

Compound D-16 was synthesized in the same manner as in Synthesis Example 31-1 with the exception of using the target compound of Preparation Example 4 instead of the target compound of Preparation Example 2.

[LCMS]: 635

### [Synthesis Example 32-1] Synthesis of Compound D-21

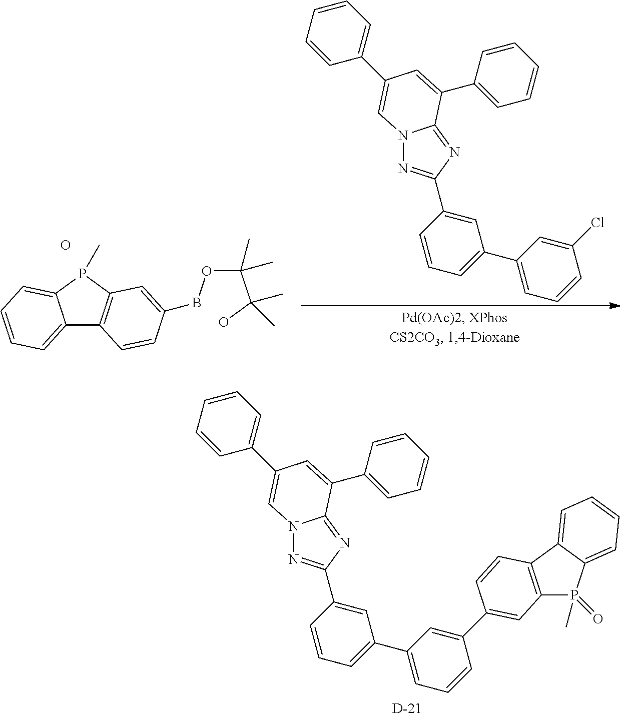

In 200 ml of 1,4-dioxane, the target compound of Preparation Example 2 (10 g, 29.4 mmol), 2-(3′-chloro-[1,1′-biphenyl]-3-yl)-6,8-diphenyl-[1,2,4]triazolo[1,5-a]pyridine (14.81 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound D-21 (13.46 g, yield 72%).

[LCMS]: 635

### [Synthesis Example 32-2] Synthesis of Compound D-17

Compound D-17 was synthesized in the same manner as in Synthesis Example 32-1 with the exception of using the target compound of Preparation Example 1 instead of the target compound of Preparation Example 2.

[LCMS]: 635

### [Synthesis Example 32-3] Synthesis of Compound D-25

Compound D-25 was synthesized in the same manner as in Synthesis Example 32-1 with the exception of using the target compound of Preparation Example 3 instead of the target compound of Preparation Example 2.

[LCMS]: 635

### [Synthesis Example 32-4] Synthesis of Compound D-29

Compound D-29 was synthesized in the same manner as in Synthesis Example 32-1 with the exception of using the target compound of Preparation Example 4 instead of the target compound of Preparation Example 2.

[LCMS]: 635

### [Synthesis Example 33-1] Synthesis of Compound D-24

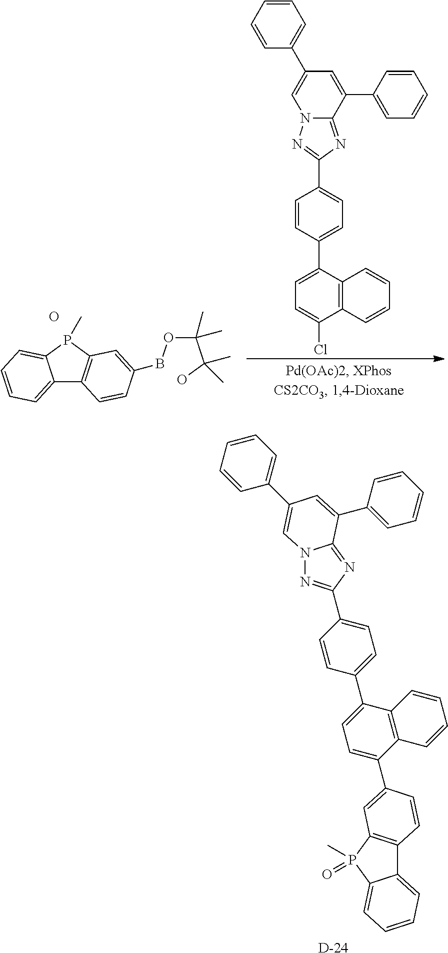

In 200 ml of 1,4-dioxane, the target compound of Preparation Example 2 (10 g, 29.4 mmol), 2-(4-(4-chloronaphthalen-1-yl)phenyl)-6,8-diphenyl-[1,2,4]triazolo[1,5-a]pyridine (16.43 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound D-24 (14.51 g, yield 72%).

[LCMS]: 685

### [Synthesis Example 33-2] Synthesis of Compound D-20

Compound D-20 was synthesized in the same manner as in Synthesis Example 33-1 with the exception of using the target compound of Preparation Example 1 instead of the target compound of Preparation Example 2.

[LCMS]: 685

### [Synthesis Example 33-3] Synthesis of Compound D-28

Compound D-28 was synthesized in the same manner as in Synthesis Example 33-1 with the exception of using the target compound of Preparation Example 3 instead of the target compound of Preparation Example 2.

[LCMS]: 685

### [Synthesis Example 33-4] Synthesis of Compound D-32

Compound D-32 was synthesized in the same manner as in Synthesis Example 33-1 with the exception of using the target compound of Preparation Example 4 instead of the target compound of Preparation Example 2.

[LCMS]: 685

### [Synthesis Example 34-1] Synthesis of Compound D-37

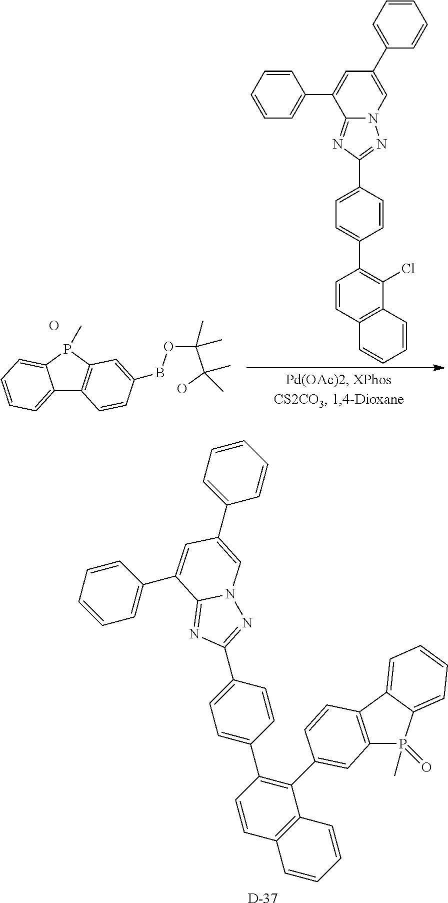

In 200 ml of 1,4-dioxane, the target compound of Preparation Example 2 (10 g, 29.4 mmol), 2-(4-(1-chloronaphthalen-2-yl)phenyl)-6,8-diphenyl-[1,2,4]triazolo[1,5-a]pyridine (16.43 g, 32.34 mmol) 9 Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound D-37 (14.51 g, yield 72%).

[LCMS]: 685

### [Synthesis Example 34-2] Synthesis of Compound D-23

Compound D-23 was synthesized in the same manner as in Synthesis Example 34-1 with the exception of using the target compound of Preparation Example 1 instead of the target compound of Preparation Example 2.

[LCMS]: 685

### [Synthesis Example 34-3] Synthesis of Compound D-41

Compound D-41 was synthesized in the same manner as in Synthesis Example 34-1 with the exception of using the target compound of Preparation Example 3 instead of the target compound of Preparation Example 2.

[LCMS]: 685

### [Synthesis Example 34-4] Synthesis of Compound D-45

Compound D-45 was synthesized in the same manner as in Synthesis Example 34-1 with the exception of using the target compound of Preparation Example 4 instead of the target compound of Preparation Example 2.

[LCMS]: 685

### [Synthesis Example 35-1] Synthesis of Compound D-40

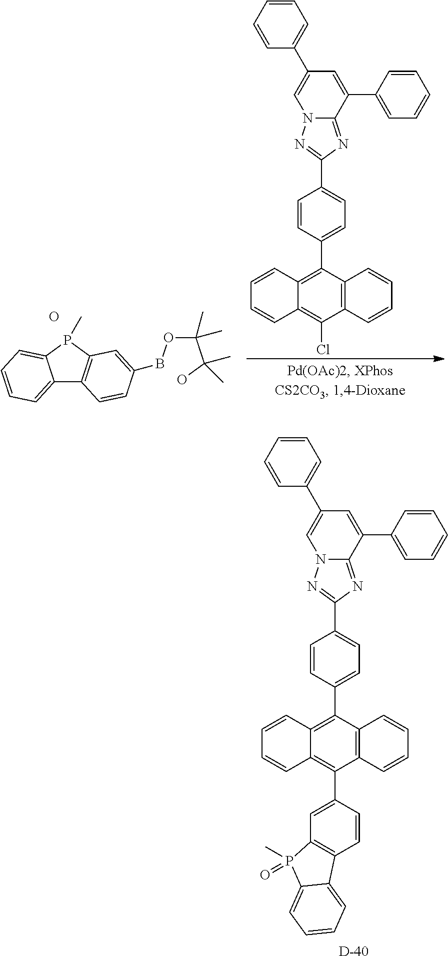

In 200 ml of 1,4-dioxane, the target compound of Preparation Example (10 g, 29.4 mmol), 2-(4-(10-chloroanthracen-9-yl)phenyl)-6,8-diphenyl-[1,2,4]triazolo[1,5-a]pyridine (16.43 g, 32.34 mmol), Pd(OAc)₂ (0.33 g, 1.47 mmol), Cs₂CO₃ (28.73 g, 88.19 mmol), and XPhos (2.77 g, 5.88 mmol) were heated together for 12 hours under reflux. After completion of the reaction, an organic layer was obtained with methylene chloride, added with MgSO₄, and then filtered. The solvent was removed from the filtered layer, followed by column chromatography to afford the target compound D-40 (16.63 g, yield 72%).

[LCMS]: 735

### [Synthesis Example 35-2] Synthesis of Compound D-36

Compound D-36 was synthesized in the same manner as in Synthesis Example 35-1 with the exception of using the target compound of Preparation Example 1 instead of the target compound of Preparation Example 2.

[LCMS]: 735

### [Synthesis Example 35-3] Synthesis of Compound D-44

Compound D-44 was synthesized in the same manner as in Synthesis Example 35-1 with the exception of using the target compound of Preparation Example 3 instead of the target compound of Preparation Example 2.

[LCMS]: 735

### [Synthesis Example 35-4] Synthesis of Compound D-48

Compound D-48 was synthesized in the same manner as in Synthesis Example 35-1 with the exception of using the target compound of Preparation Example 4 instead of the target compound of Preparation Example 2.

[LCMS]: 735

### [Example 1] Fabrication of Green Organic EL Device

Compound A-2 was refined with high purify by sublimation and used in fabricating a green organic EL device according to the following procedure.

First, a glass substrate coated with indium tin oxide (ITO) 1500 Å thick was cleansed by ultrasonication in distilled water and then in a solvent, such as isopropyl alcohol, acetone, methanol, and the like. The glass substrate was dried and cleaned for 5 min using UV in a UV OZONE cleaner (Power sonic 405, Hwashin) before transfer to a vacuum evaporator.

On the transparent ITO electrode thus obtained, m-MTDATA (60 nm)/TCTA (80 nm)/compound A-2+10% Ir(ppy)₃ (30 nm)/BCP (10 nm)/Alq₃ (30 nm)/LiF (1 nm)/Al (200 nm) were deposited in that order to fabricate an organic EL device.

Structures of m-MTDATA, TCTA, Ir(ppy)₃, and BCP are as follows.

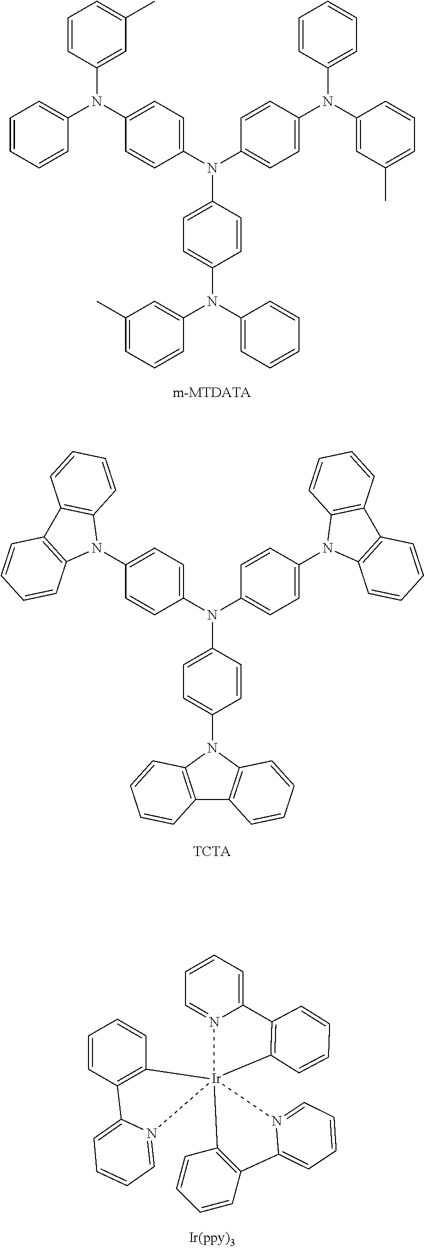

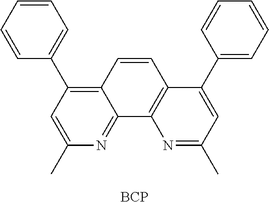

### [Examples 2 TO 24] Fabrication of Green Organic EL Devices

Green organic EL devices were fabricated in the same manner as in Example 1, with the exception that the host materials listed in Table 1, instead of compound A-2, were used as a light-emitting host material for light-emitting layers.

### [Comparative Example 1] Fabrication of Green Organic EL Device

A green organic EL device was fabricated in the same manner as in Example 1, with the exception that CBP, instead of compound A-2, was used as a light-emitting host material for a light-emitting layer. The structure of CBP used was as follows.

### Evaluation Example 1

Green organic EL devices fabricated in Examples 1-24 and Comparative Example 1 were measured for driving voltage, current efficiency, and electroluminescence peak at a current density of 10 mA/cm², and the results are summarized in Table 1, below.

TABLE 1

| | | Driving | EL | Current |
|---|---|---|---|---|
| | | Volt. | Peak | Efficiency |
| Sample | Host | (V) | (nm) | (cd/A) |
| Example 1 | A-2 | 5.43 | 515 | 44.2 |
| Example 2 | A-3 | 5.52 | 517 | 42.2 |
| Example 3 | A-4 | 5.34 | 518 | 45.2 |
| Example 4 | A-19 | 5.69 | 516 | 43.5 |
| Example 5 | A-14 | 5.43 | 514 | 44.2 |
| Example 6 | A-15 | 5.44 | 518 | 49.1 |
| Example 7 | A-16 | 5.53 | 517 | 44.8 |
| Example 8 | A-31 | 5.54 | 517 | 42.3 |
| Example 9 | A-50 | 5.44 | 518 | 49.1 |
| Example 10 | A-51 | 5.53 | 517 | 44.8 |
| Example 11 | A-62 | 5.35 | 517 | 45.1 |
| Example 12 | A-64 | 5.69 | 516 | 43.6 |
| Example 13 | B-2 | 5.43 | 515 | 44.2 |
| Example 14 | B-3 | 5.52 | 517 | 42.2 |
| Example 15 | B-4 | 5.34 | 518 | 45.2 |
| Example 16 | B-19 | 5.69 | 516 | 43.5 |
| Example 17 | B-14 | 5.51 | 518 | 44.8 |
| Example 18 | B-15 | 5.35 | 517 | 45.4 |
| Example 19 | B-16 | 5.69 | 516 | 43.5 |
| Example 20 | B-31 | 5.55 | 517 | 42.3 |
| Example 21 | B-50 | 5.44 | 518 | 49.1 |
| Example 22 | B-51 | 5.53 | 517 | 44.8 |
| Example 23 | B-62 | 5.34 | 516 | 45.3 |
| Example 24 | B-64 | 5.69 | 516 | 43.6 |
| C. Example 1 | CBP | 6.52 | 516 | 38.2 |

As is understood from the data of Table 1, the green organic EL devices of Examples 1 to 24 containing the compounds according to the present disclosure (compounds A-2 to A-64 and B-2 to B-64) in light-emitting layers were observed to be superior to that of Comparative Example 1 employing CBP in the light-emitting layer in terms of current efficiency and driving voltage.

### [Example 25] Fabrication of Blue Organic EL Device

Compound A-6 was refined with high purify by sublimation and used in fabricating a blue organic EL device according to the following procedure.

First, a glass substrate coated with indium tin oxide (ITO) 1500 Å thick was cleansed by ultrasonication in distilled water and then in a solvent, such as isopropyl alcohol, acetone, methanol, and the like. The glass substrate was dried and cleaned for 5 min using UV in a UV OZONE cleaner (Power sonic 405, Hwashin Tech) before transfer to a vacuum evaporator.

On the transparent ITO electrode thus obtained, DS-205 (Solus Advanced Materials, 80 nm)/NPB (15 nm)/ADN+5% DS-405 (Solus Advanced Materials, 30 nm)/compound A-6 (30 nm)/LiF (1 nm)/Al (200 nm) were deposited in that order to fabricate an organic EL device.

Structures of NPB and ADN are as follows.

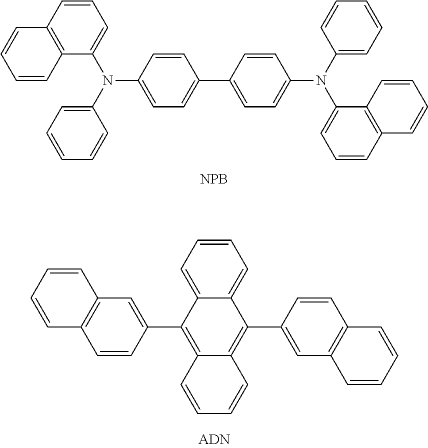

### [Examples 26 to 132] Fabrication of Blue Organic EL Devices

Blue organic EL devices were fabricated in the same manner as in Example 25, with the exception that the materials listed in Table 2, instead of compound A-6, were used as electron transport materials.

### [Comparative Example 2] Fabrication of Blue Organic EL Device

A blue organic EL device was fabricated in the same manner as in Example 25, with the exception that Alq3, instead of compound A-6, was used as an electron transport material. The structure of Alq₃ used was as follows.

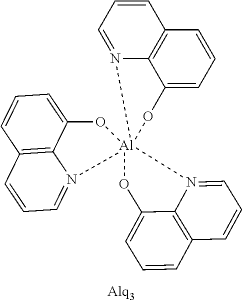

### [Comparative Example 3] Fabrication of Blue Organic EL Device

A blue organic EL device was fabricated in the same manner as in Example 25, with the exception that compound A-6 was not employed.

### Evaluation Example 2

Blue organic EL devices fabricated in Examples 25-132 and Comparative Examples 2-3 were measured for driving voltage, current efficiency, and electroluminescence peak at a current density of 10 mA/cm², and the results are summarized in Table 2, below.

TABLE 2

| | Electron | | | |
|---|---|---|---|---|
| | transport | Driving | EL | Current |
| | layer | Volt. | Peak | Efficiency |
| Sample | material | (V) | (nm) | (cd/A) |
| Example 25 | A-6 | 3.8 | 456 | 6.8 |
| Example 26 | A-7 | 4.0 | 457 | 6.6 |
| Example 27 | A-8 | 3.6 | 456 | 6.6 |
| Example 28 | A-21 | 4.0 | 453 | 6.5 |
| Example 29 | A-22 | 3.8 | 456 | 6.7 |
| Example 30 | A-23 | 3.8 | 456 | 6.8 |
| Example 31 | A-24 | 3.9 | 457 | 6.6 |
| Example 32 | A-37 | 3.6 | 456 | 6.8 |
| Example 33 | A-38 | 3.7 | 456 | 6.5 |
| Example 34 | A-39 | 3.7 | 458 | 6.6 |
| Example 35 | A-40 | 4.1 | 453 | 6.5 |
| Example 36 | A-10 | 3.8 | 456 | 6.8 |
| Example 37 | A-11 | 3.9 | 457 | 6.6 |
| Example 38 | A-12 | 4.1 | 453 | 6.7 |
| Example 39 | A-25 | 3.8 | 456 | 6.8 |
| Example 40 | A-26 | 3.6 | 456 | 6.6 |
| Example 41 | A-27 | 3.7 | 456 | 6.5 |
| Example 42 | A-28 | 3.7 | 458 | 6.6 |
| Example 43 | A-41 | 4.1 | 453 | 6.5 |
| Example 44 | A-42 | 3.8 | 456 | 6.8 |
| Example 45 | A-43 | 3.6 | 456 | 6.8 |
| Example 46 | A-44 | 4.1 | 453 | 6.5 |
| Example 47 | A-53 | 3.8 | 456 | 6.8 |
| Example 48 | A-54 | 3.6 | 456 | 6.7 |
| Example 49 | A-55 | 3.6 | 458 | 6.6 |
| Example 50 | A-56 | 4.1 | 453 | 6.5 |
| Example 51 | A-57 | 4.1 | 453 | 6.5 |
| Example 52 | A-58 | 3.8 | 456 | 6.8 |
| Example 53 | A-59 | 4.1 | 457 | 6.6 |
| Example 54 | A-60 | 3.6 | 456 | 6.6 |
| Example 55 | B-6 | 3.8 | 456 | 6.6 |
| Example 56 | B-7 | 3.8 | 456 | 6.8 |
| Example 57 | B-8 | 3.7 | 456 | 6.6 |
| Example 58 | B-21 | 3.7 | 455 | 6.6 |
| Example 59 | B-22 | 3.7 | 456 | 6.5 |
| Example 60 | B-23 | 3.7 | 458 | 6.6 |
| Example 61 | B-24 | 4.1 | 453 | 6.6 |
| Example 62 | B-37 | 4.1 | 453 | 6.5 |
| Example 63 | B-38 | 3.8 | 456 | 6.8 |
| Example 64 | B-39 | 4.0 | 457 | 6.6 |
| Example 65 | B-40 | 3.6 | 456 | 6.8 |
| Example 66 | B-10 | 4.1 | 453 | 6.5 |
| Example 67 | B-11 | 3.8 | 456 | 6.8 |
| Example 68 | B-12 | 3.8 | 456 | 6.8 |
| Example 69 | B-25 | 3.9 | 457 | 6.6 |
| Example 70 | B-26 | 4.0 | 457 | 6.6 |
| Example 71 | B-27 | 3.8 | 455 | 6.8 |
| Example 72 | B-28 | 3.6 | 456 | 6.7 |
| Example 73 | B-41 | 3.8 | 455 | 6.8 |
| Example 74 | B-42 | 4.0 | 457 | 6.6 |
| Example 75 | B-43 | 4.0 | 457 | 6.6 |
| Example 76 | B-44 | 3.6 | 456 | 6.6 |
| Example 77 | B-53 | 3.8 | 456 | 6.8 |
| Example 78 | B-54 | 4.0 | 457 | 6.7 |
| Example 79 | B-55 | 3.7 | 456 | 6.8 |
| Example 80 | B-56 | 4.0 | 453 | 6.5 |
| Example 81 | B-57 | 3.8 | 456 | 6.8 |
| Example 82 | B-58 | 4.0 | 457 | 6.7 |
| Example 83 | B-59 | 3.6 | 456 | 6.6 |
| Example 84 | B-60 | 4.0 | 453 | 6.5 |
| Example 85 | C-6 | 3.9 | 456 | 6.8 |
| Example 86 | C-23 | 4.0 | 456 | 6.6 |
| Example 87 | C-24 | 3.6 | 456 | 6.7 |
| Example 88 | C-38 | 3.8 | 456 | 6.8 |
| Example 89 | C-40 | 4.0 | 457 | 6.6 |
| Example 90 | C-10 | 3.6 | 456 | 6.6 |
| Example 91 | C-27 | 4.1 | 455 | 6.5 |
| Example 92 | C-28 | 3.8 | 456 | 6.8 |
| Example 93 | C-43 | 3.8 | 456 | 6.8 |
| Example 94 | C-45 | 4.0 | 457 | 6.6 |
| Example 95 | C-58 | 3.7 | 456 | 6.6 |
| Example 96 | C-59 | 4.0 | 453 | 6.5 |
| Example 97 | C-60 | 3.8 | 456 | 6.7 |
| Example 98 | C-73 | 4.0 | 457 | 6.6 |
| Example 99 | C-75 | 3.6 | 458 | 6.6 |
| Example 100 | C-61 | 3.7 | 456 | 6.5 |
| Example 101 | C-62 | 3.7 | 457 | 6.6 |
| Example 102 | C-63 | 4.1 | 453 | 6.5 |
| Example 103 | C-77 | 3.8 | 455 | 6.8 |
| Example 104 | C-79 | 4.0 | 457 | 6.6 |
| Example 105 | D-6 | 3.7 | 456 | 6.5 |
| Example 106 | D-7 | 4.1 | 453 | 6.5 |
| Example 107 | D-8 | 3.8 | 456 | 6.8 |
| Example 108 | D-22 | 4.0 | 456 | 6.6 |
| Example 109 | D-24 | 3.5 | 456 | 6.6 |
| Example 110 | D-37 | 3.6 | 456 | 6.6 |
| Example 111 | D-39 | 3.7 | 456 | 6.5 |
| Example 112 | D-40 | 3.8 | 458 | 6.6 |
| Example 113 | D-10 | 4.0 | 453 | 6.7 |
| Example 114 | D-11 | 3.8 | 456 | 6.7 |
| Example 115 | D-12 | 4.0 | 457 | 6.6 |
| Example 116 | D-26 | 3.8 | 456 | 6.6 |
| Example 117 | D-28 | 3.7 | 456 | 6.5 |
| Example 118 | D-41 | 3.7 | 458 | 6.6 |
| Example 119 | D-43 | 4.1 | 453 | 6.5 |
| Example 120 | D-44 | 3.7 | 456 | 6.7 |
| Example 121 | D-43 | 4.0 | 457 | 6.6 |
| Example 122 | E-5 | 3.8 | 457 | 6.6 |
| Example 123 | E-6 | 4.1 | 453 | 6.5 |
| Example 124 | E-7 | 3.7 | 458 | 6.6 |
| Example 125 | E-8 | 4.1 | 453 | 6.5 |
| Example 126 | C-41 | 3.8 | 456 | 6.8 |
| Example 127 | C-42 | 4.0 | 457 | 6.6 |
| Example 128 | C-43 | 3.8 | 456 | 6.6 |
| Example 129 | D-39 | 3.7 | 456 | 6.5 |
| Example 130 | D-40 | 3.7 | 458 | 6.6 |
| Example 131 | D-41 | 4.1 | 453 | 6.5 |
| Example 132 | D-42 | 3.8 | 456 | 6.7 |
| C. Example 2 | Alq₃ | 4.7 | 459 | 5.6 |
| C. Example 3 | — | 5.5 | 460 | 4.9 |

As is understood from the data of Table 2, the blue organic EL devices of Examples 25 to 132 containing the compounds according to the present disclosure (compounds A-6 to D-42) in electron transport layers were observed to be superior to those of Comparative Example 2 employing Alq₃ and Comparative Example 3 lacking an electron transport layer in terms of current efficiency, electroluminescence light, and driving voltage.

### [Example 133] Fabrication of Blue Organic EL Device

Compound A-65 was refined with high purify by sublimation and used in fabricating a blue organic EL device according to the following procedure.

A glass substrate coated with indium tin oxide (ITO) 1500 Å thick was cleansed by ultrasonication in distilled water and then in a solvent, such as isopropyl alcohol, acetone, methanol, and the like. The glass substrate was dried and cleaned for 5 min using UV in a UV OZONE cleaner (Power sonic 405, Hwashin Tech) before transfer to a vacuum evaporator.

On the transparent ITO electrode thus obtained, DS-205 (80 nm)/NPB (15 nm)/ADN+5% DS-405 (Solus Advanced Materials, 30 nm)/compound A-65 (5 nm)/Alq3 (25 nm)/LiF (1 nm)/Al (200 nm) were deposited in that order to fabricate an organic EL device.

Structures of NPB, AND, and Alq3 are as follows.

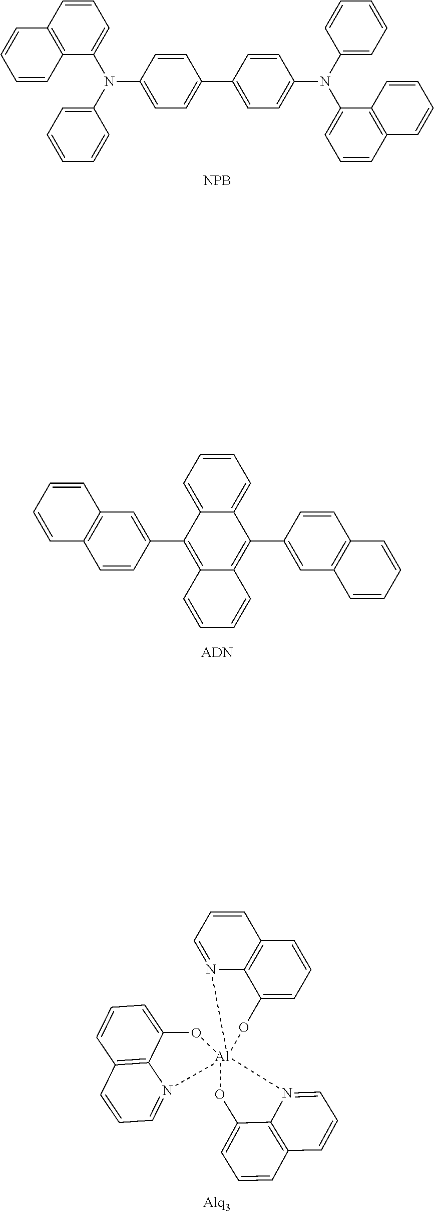

### [Examples 133 to 176] Fabrication of Blue Organic EL Devices

Blue organic EL devices were fabricated in the same manner as in Example 133, with the exception that the materials listed in Table 3, instead of compound A-65, were used as electron transport auxiliary layer materials.

### [Comparative Example 4] Fabrication of Blue Organic EL Device

A blue organic EL device was fabricated in the same manner as in Example 133, with the exception that compound A-65 was not used as a material for an electron transport auxiliary layer and Alq₃ as a material for an electron transport layer was deposited to a thickness of 30 nm, but not 25 nm,

### Evaluation Example 3

Blue organic EL devices fabricated in Examples 133 to 176 and Comparative Example 4 were measured for driving voltage, current efficiency, and electroluminescence peak at a current density of 10 mA/cm², and the results are summarized in Table 3, below.

TABLE 3

| | Electron | | | |
|---|---|---|---|---|
| | transport | Driving | EL | Current |
| | auxiliary | Volt. | Peak | Efficiency |
| Sample | material | (V) | (nm) | (cd/A) |
| Example 133 | A-65 | 3.6 | 456 | 6.6 |
| Example 134 | A-66 | 3.6 | 455 | 6.6 |
| Example 135 | A-67 | 3.7 | 458 | 6.6 |
| Example 136 | A-68 | 4.0 | 454 | 6.5 |
| Example 137 | A-69 | 3.7 | 455 | 6.9 |
| Example 138 | A-70 | 3.6 | 456 | 6.6 |
| Example 139 | A-71 | 3.7 | 455 | 6.6 |
| Example 140 | A-72 | 3.7 | 458 | 6.6 |
| Example 141 | A-73 | 3.6 | 456 | 6.7 |
| Example 142 | A-74 | 3.6 | 454 | 6.5 |
| Example 143 | A-75 | 3.6 | 458 | 6.6 |
| Example 144 | A-76 | 4.0 | 453 | 6.5 |
| Example 145 | A-77 | 3.7 | 455 | 6.9 |
| Example 146 | A-78 | 3.6 | 456 | 6.6 |
| Example 147 | A-79 | 3.7 | 456 | 6.6 |
| Example 148 | A-80 | 3.6 | 457 | 6.6 |
| Example 149 | B-65 | 3.6 | 456 | 6.6 |
| Example 150 | B-66 | 3.6 | 455 | 6.5 |
| Example 151 | B-67 | 3.7 | 454 | 6.8 |
| Example 152 | B-68 | 3.6 | 456 | 6.6 |
| Example 153 | B-69 | 3.7 | 455 | 6.5 |
| Example 154 | B-70 | 3.6 | 457 | 6.5 |
| Example 155 | B-71 | 3.6 | 456 | 6.6 |
| Example 156 | B-72 | 3.6 | 455 | 6.4 |
| Example 157 | B-73 | 3.7 | 458 | 6.6 |
| Example 158 | B-74 | 3.7 | 455 | 6.9 |
| Example 159 | B-75 | 3.6 | 456 | 6.6 |
| Example 160 | B-76 | 3.7 | 456 | 6.6 |
| Example 161 | B-77 | 3.7 | 458 | 6.6 |
| Example 162 | B-78 | 3.6 | 456 | 6.6 |
| Example 163 | B-79 | 3.6 | 455 | 6.5 |
| Example 164 | B-80 | 3.6 | 458 | 6.6 |
| Example 165 | D-4 | 4.0 | 453 | 6.5 |
| Example 166 | D-17 | 3.7 | 455 | 6.9 |
| Example 167 | D-34 | 4.0 | 453 | 6.5 |
| Example 168 | D-8 | 3.7 | 455 | 6.9 |
| Example 169 | D-21 | 3.6 | 456 | 6.6 |
| Example 170 | D-38 | 3.7 | 456 | 6.6 |
| Example 171 | D-12 | 3.6 | 457 | 6.5 |
| Example 172 | D-25 | 3.6 | 456 | 6.6 |
| Example 173 | D-42 | 3.6 | 455 | 6.4 |
| Example 174 | D-16 | 3.7 | 458 | 6.6 |
| Example 175 | D-29 | 4.0 | 453 | 6.5 |
| Example 176 | D-46 | 3.9 | 453 | 6.6 |
| C. Example 4 | — | 4.8 | 457 | 5.8 |

As is understood from the data of Table 3, the blue organic EL devices of Examples 133 to 176 containing the compounds according to the present disclosure (compounds A-65 to D-46) in electron transport auxiliary layer were observed to be superior to those of Comparative Example 4 employing Alq₃ in the electron transport layer in terms of current efficiency and driving voltage.

1. A compound represented by the following chemical formula 1: 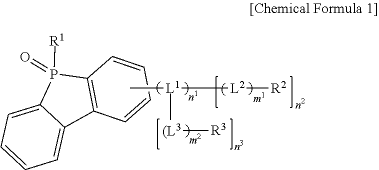
(wherein,
R¹ is selected from the group consisting of an alkyl group of C₁-C₁₂, an aryl group of C₆-C₂₀, and a heteroaryl group of 5 to 20 nuclear atoms,
n¹ is an integer of 0 to 2,
n² and n³ are each 0 or 1, with 1≤n²+n³≤2,
m¹ and m² are each an integer of 0 to 2,
L¹, L², and L³, which are same or different, are each independently an arylene group of C₆-C₁₄ or a heteroarylene group of 3 to 14 nuclear atoms,
R² and R³, which are same or different, are each independently selected from the group consisting of a hydrogen atom, a deuterium atom (D), a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine group oxide of C₆-C₆₀, an arylamine group of C₆-C₆₀, a heteroarylamine group of 5 to 60 nuclear atoms, and an (aryl)(heteroaryl)amine group of (C₆-C₆₀)(5 to 60 nuclear atoms),
the alkyl, aryl, and heteroaryl groups in R¹, the arylene and heteroarylene groups in L¹, L², and L³, and the hydrazino, hydrazono, alkyl, alkenyl, alkynyl, cycloalkyl, heterocycloalkyl, cycloalkenyl, heterocycloalkenyl, aryl, heteroaryl, alkyloxy, aryloxy, alkylsilyl, arylsilyl, alkylboron, arylboron, arylphosphine, arylphosphine oxide, arylamine, heteroarylamine, and (aryl)(heteroaryl)amine groups in R² and R³ are each independently substituted or unsubstituted with one or more substituents selected from the group consisting of the group consisting of a deuterium atom, a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine group oxide of C₆-C₆₀, and an arylamine group of C₆-C₆₀, wherein, when ex is ting, two or more substituents are same or different).

2. The compound of claim 1, wherein R¹ is selected from the group consisting of methyl group, ethyl group, propyl group, butyl group, phenyl group, biphenyl group, naphthyl group, pyridine group, pyrimidine group, and triazine group.

3. The compound of claim 1, wherein the compound represented by chemical formula 1 is a compound represented by chemical formula 2 or 3, below: 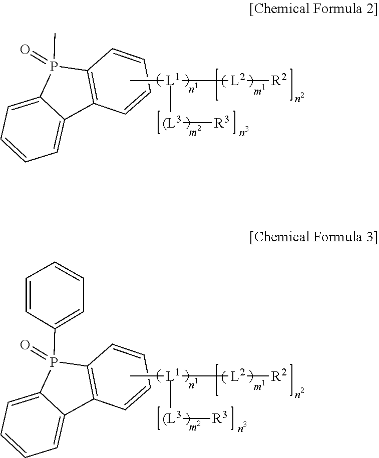
(wherein,
n¹, n², n³, m¹, m², L¹, L², L³, R², and R³ are each defined as in claim 1).

4. The compound of claim 1, wherein the compound represented by chemical formula 1 is a compound represented by chemical formula 4 or 5, below: 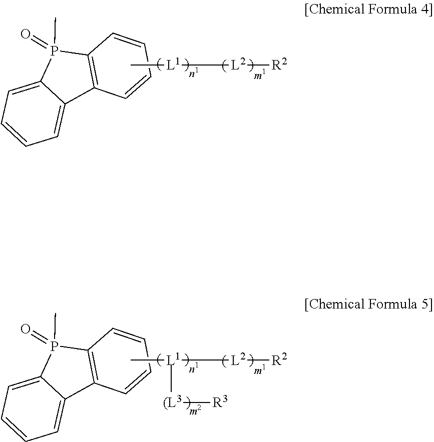
(wherein,
n¹, m¹, m², L¹, L², L³, R², and R³ are each defined as in claim 1).

5. The compound of claim 1, wherein R² and R³ are same or different and are each independently any one of the substituents represented by the following chemical formulas a to j: 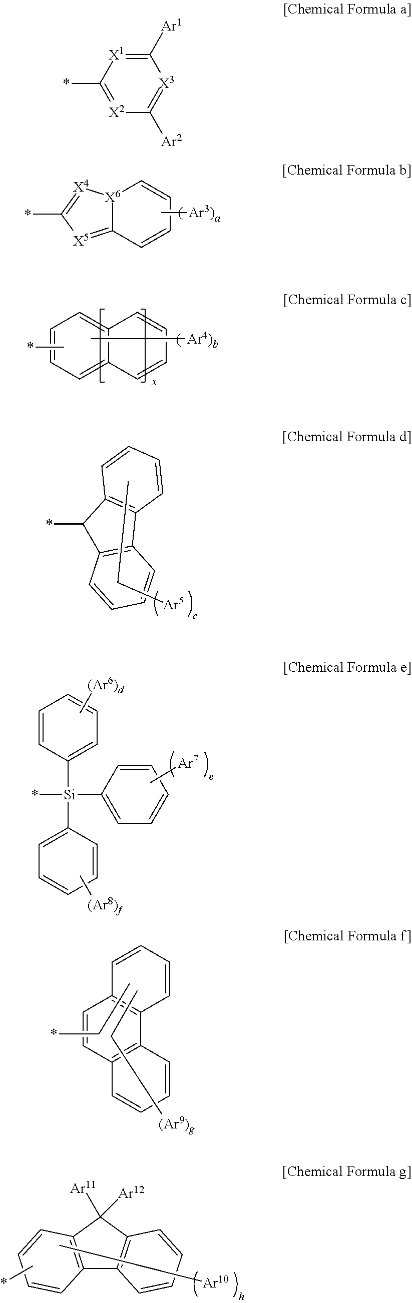 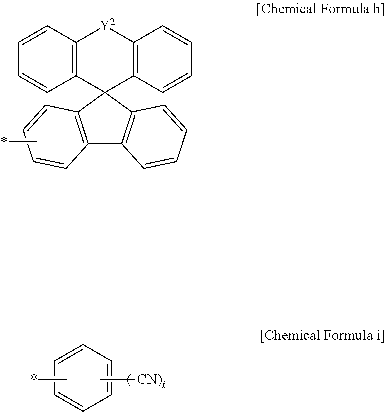
(wherein,
X¹ to X³ are same or different and are each independently N or C(Ar¹³), with a proviso that at least one of X¹ to X³ is N,
X⁴ to X⁶ are same or different and are each independently N or C(Ar¹⁴), with a proviso that at least one of X⁴ to X⁶ is N,
a is an integer of 0 to 4,
b and h are each an integer of 0 to 7,
x is 0 or 1,
c and g are each an integer of 0 to 8,
d, e, f, and I are each an integer of 0 to 5,
Y¹ and Y² are each independently O or S, and
Ar¹ to Ar¹⁴ are same or different and are each independently selected from the group consisting of a hydrogen atom, a deuterium atom, a halogen group, a cyano group, a nitro group, an amino group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀,
the alkyl, alkenyl, alkynyl, cycloalkyl, heterocycloalkyl, aryl, heteroaryl, alkyloxy, aryloxy, alkylsilyl, arylsilyl, alkylboron, arylboron, arylphosphine, arylphosphine oxide, and arylamine groups of Ar¹ to Ar¹⁴ are each independently substituted or unsubstituted with at least one substituent selected from the group consisting of a deuterium atom, a halogen group, a cyano group, a nitro group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀, and two or more substituents, if present, are same or different.)

6. The compound of claim 1, wherein the compound represented by chemical formula 1 is a compound represented by any one of chemical formulas 6 to 10, below: 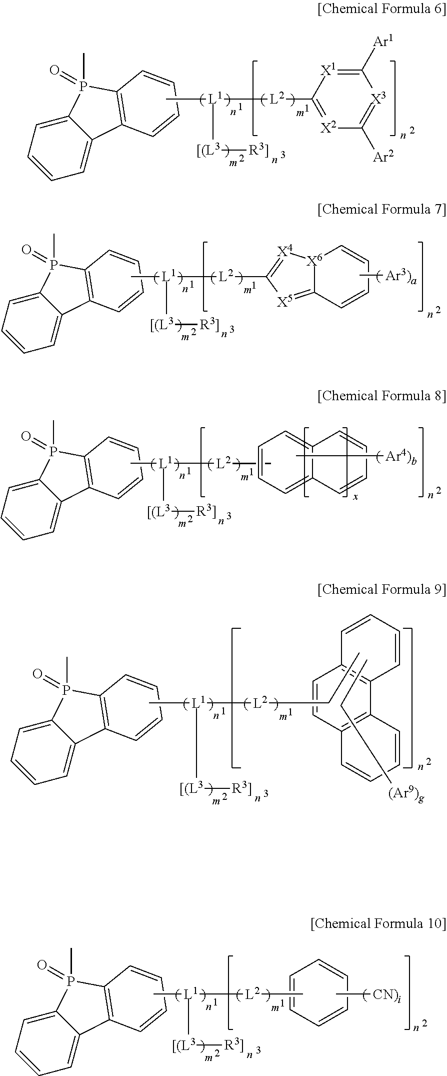
(wherein,
n¹, n², n³, m¹, m², L¹, L², L³, and R³ are each as defined in claim 1,
X¹ to X³ are same or different and are each independently N or C(Ar¹³), with a proviso that at least one of X¹ to X³ is N,
X⁴ to X⁶ are same or different and are each independently N or C(Ar¹⁴), with a proviso that at least one of X⁴ to X⁶ is N,
a is an integer of 0 to 4,
b is an integer of 0 to 7,
x is 0 or 1,
g is an integer of 0 to 8,
i is an integer of 0 to 5, and
Ar¹ to Ar⁴, Ar⁹, Ar¹³, and Ar¹⁴ are same or different and are each independently selected from the group consisting of a hydrogen atom, a deuterium atom, a halogen group, a cyano group, a nitro group, an amino group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀,
the alkyl, alkenyl, alkynyl, cycloalkyl, heterocycloalkyl, aryl, heteroaryl, alkyloxy, aryloxy, alkylsilyl, arylsilyl, alkylboron, arylboron, arylphosphine, arylphosphine oxide, and arylamine groups in Ar¹ to Ar⁴, Ar⁹, Ar¹³, and Ar¹⁴ are each independently substituted or unsubstituted with at least one substituent selected from the group consisting of a deuterium atom, a halogen group, a cyano group, a nitro group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀, and two or more substituents, if present, are same or different).

7. The compound of claim 1, wherein L¹ is a linker selected from the group consisting of the following linkers L1-1 to L1-12, and
L² and L³, which are same or different, are each independently a linker selected from the group consisting of the following linkers L²-1 to L²-6:

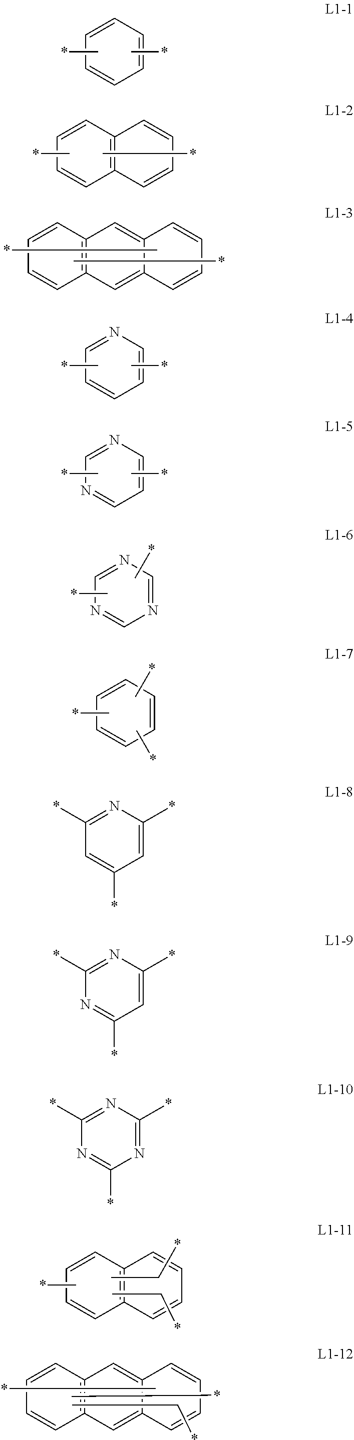

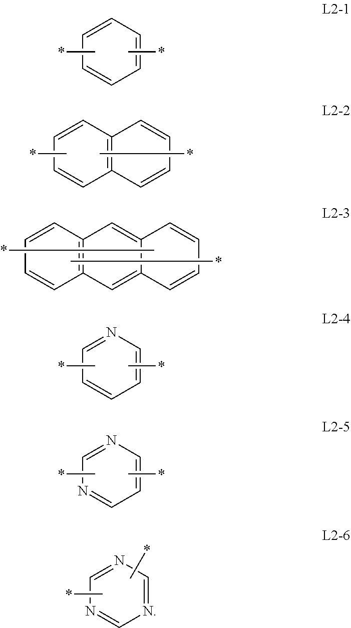

8. The compound of claim 1, wherein the compound represented by chemical formula 1 is a compound represented by any one of chemical formulas 11 to 30: 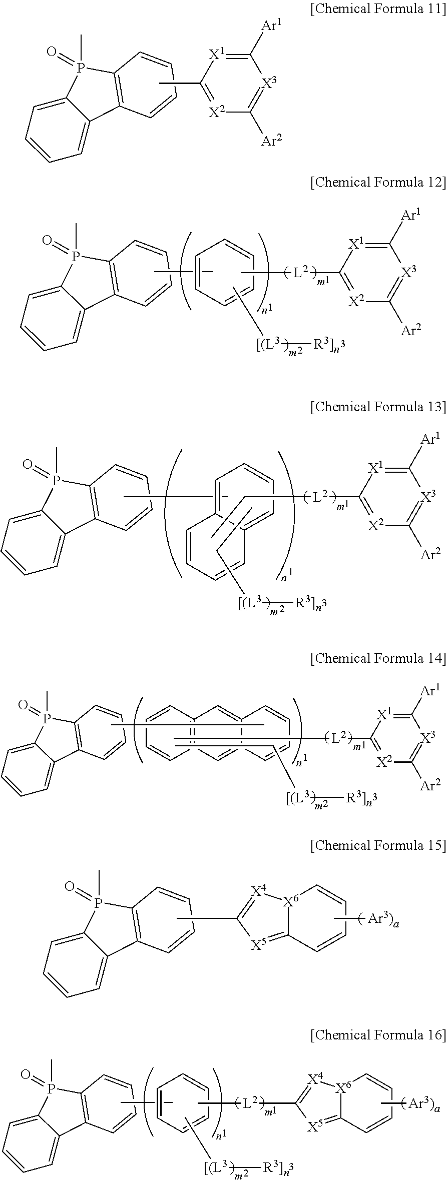 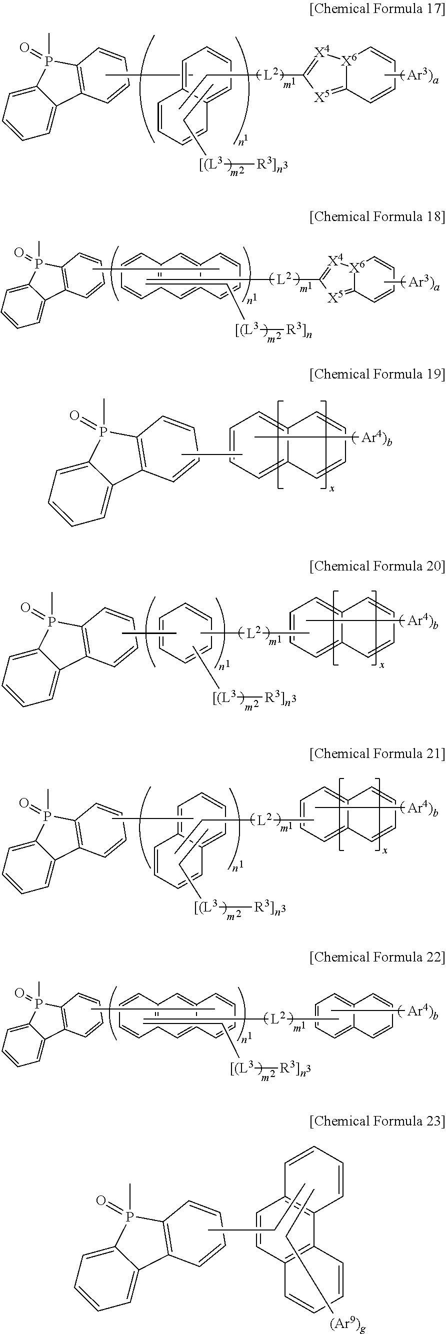 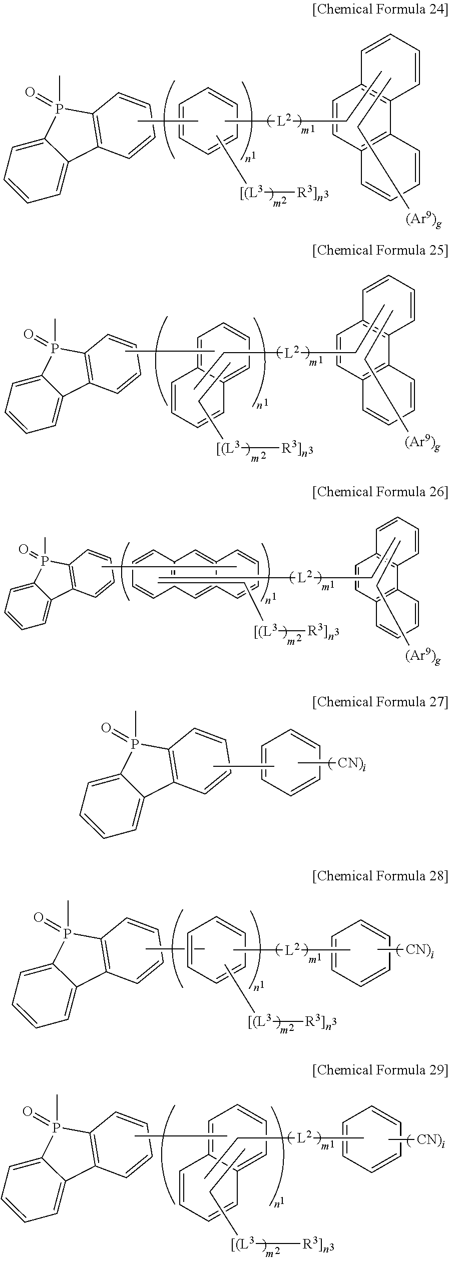 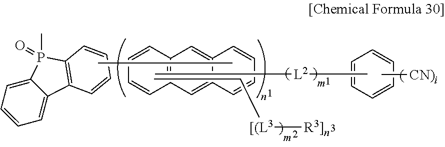
(wherein,
n¹, n³, m¹, m², L², L³, and R³ are each defined as in claim 1,
X¹ to X³ are same or different and are each independently N or C(Ar¹³), with a proviso that at least one of X¹ to X³ is N,
X⁴ to X⁶ are same or different and are each independently N or C(Ar¹⁴), with a proviso that at least one of X⁴ to X⁶ is N,
a is an integer of 0 to 4,
b is an integer of 0 to 7,
x is 0 or 1,
g is an integer of 0 to 8,
i is an integer of 0 to 5, and
Ar¹ to Ar⁴, Ar⁹, Ar¹³, and Ar¹⁴ are same or different and are each independently selected from the group consisting of a hydrogen atom, a deuterium atom, a halogen group, a cyano group, a nitro group, an amino group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀,
the alkyl, alkenyl, alkynyl, cycloalkyl, heterocycloalkyl, aryl, heteroaryl, alkyloxy, aryloxy, alkylsilyl, arylsilyl, alkylboron, arylboron, arylphosphine, arylphosphine oxide, and arylamine groups in Ar¹ to Ar⁴, Ar⁹, Ar¹³, and Ar¹⁴ are each independently substituted or unsubstituted with at least one substituent selected from the group consisting of a deuterium atom, a halogen group, a cyano group, a nitro group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀, and two or more substituents, if present, are same or different).

9. The compound of claim 1, wherein the compound represented by chemical formula 1 is selected from the group consisting of compounds A-1 to D-48, below:

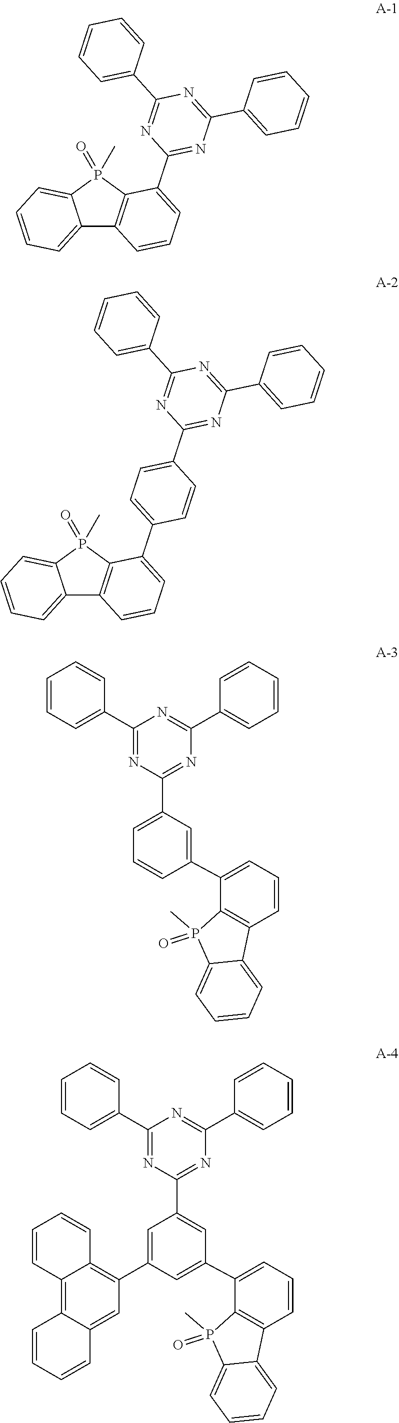

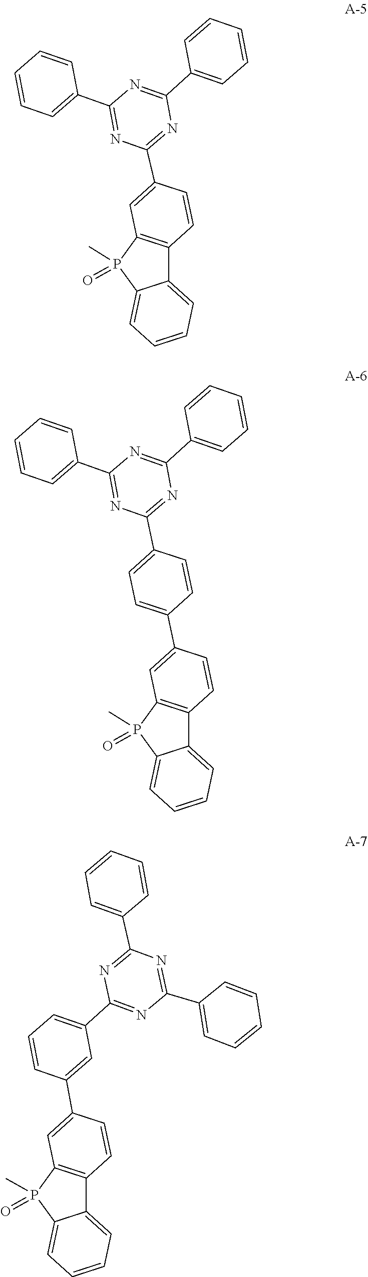 [SMILES: CP1(=O)c2ccccc2-c2ccc(-c3nc(-c4ccccc4)nc(-c4ccccc4)n3)cc21 ; CP1(=O)c2ccccc2-c2ccc(-c3ccc(-c4nc(-c5ccccc5)nc(-c5ccccc5)n4)cc3)cc21 ; CP1(=O)c2ccccc2-c2ccc(-c3cccc(-c4nc(-c5ccccc5)nc(-c5ccccc5)n4)c3)cc21]

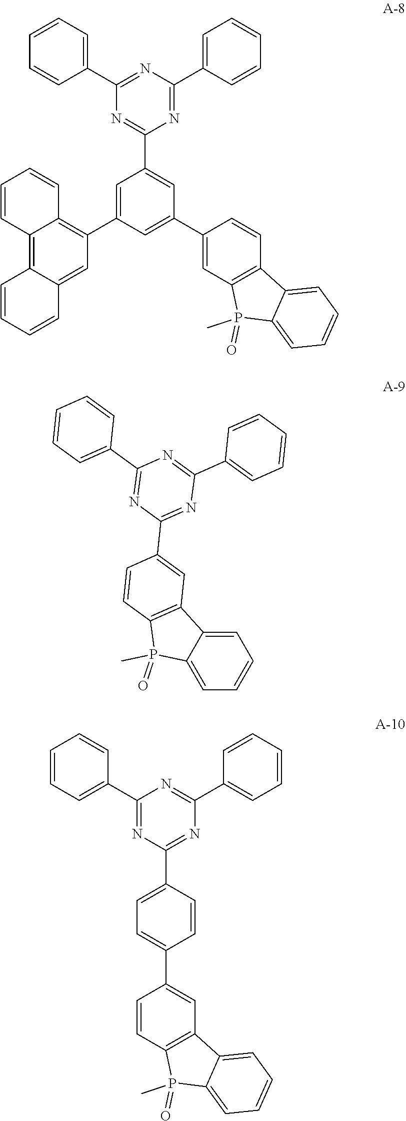 [SMILES: CP1(=O)c2ccccc2-c2ccc(-c3cc(-c4nc(-c5ccccc5)nc(-c5ccccc5)n4)cc(-c4cc5ccccc5c5ccccc45)c3)cc21 ; CP1(=O)c2ccccc2-c2cc(-c3nc(-c4ccccc4)nc(-c4ccccc4)n3)ccc21 ; CP1(=O)c2ccccc2-c2cc(-c3ccc(-c4nc(-c5ccccc5)nc(-c5ccccc5)n4)cc3)ccc21]

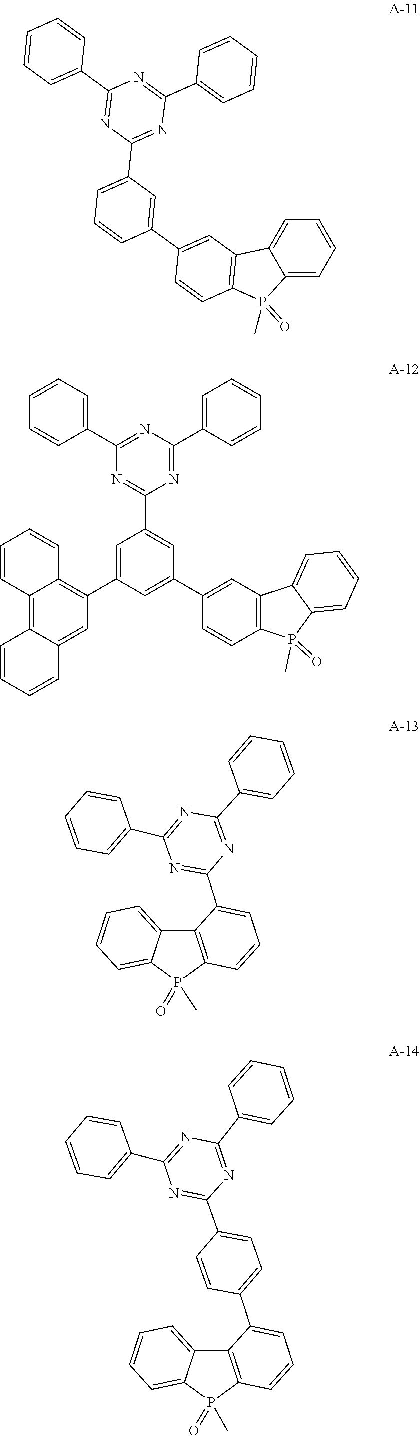 [SMILES: CP1(=O)c2ccccc2-c2cc(-c3cccc(-c4nc(-c5ccccc5)nc(-c5ccccc5)n4)c3)ccc21 ; CP1(=O)c2ccccc2-c2cc(-c3cc(-c4nc(-c5ccccc5)nc(-c5ccccc5)n4)cc(-c4cc5ccccc5c5ccccc45)c3)ccc21 ; CP1(=O)c2ccccc2-c2c(-c3nc(-c4ccccc4)nc(-c4ccccc4)n3)cccc21 ; CP1(=O)c2ccccc2-c2c(-c3ccc(-c4nc(-c5ccccc5)nc(-c5ccccc5)n4)cc3)cccc21]

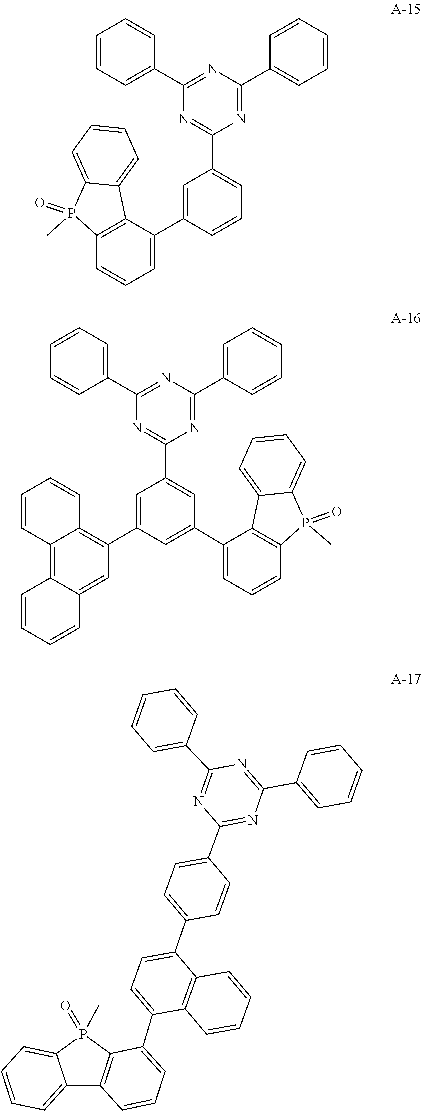 [SMILES: CP1(=O)c2ccccc2-c2c(-c3cccc(-c4nc(-c5ccccc5)nc(-c5ccccc5)n4)c3)cccc21 ; CP1(=O)c2ccccc2-c2c(-c3cc(-c4nc(-c5ccccc5)nc(-c5ccccc5)n4)cc(-c4cc5ccccc5c5ccccc45)c3)cccc21 ; CP1(=O)c2ccccc2-c2cccc(-c3ccc(-c4ccc(-c5nc(-c6ccccc6)nc(-c6ccccc6)n5)cc4)c4ccccc34)c21]

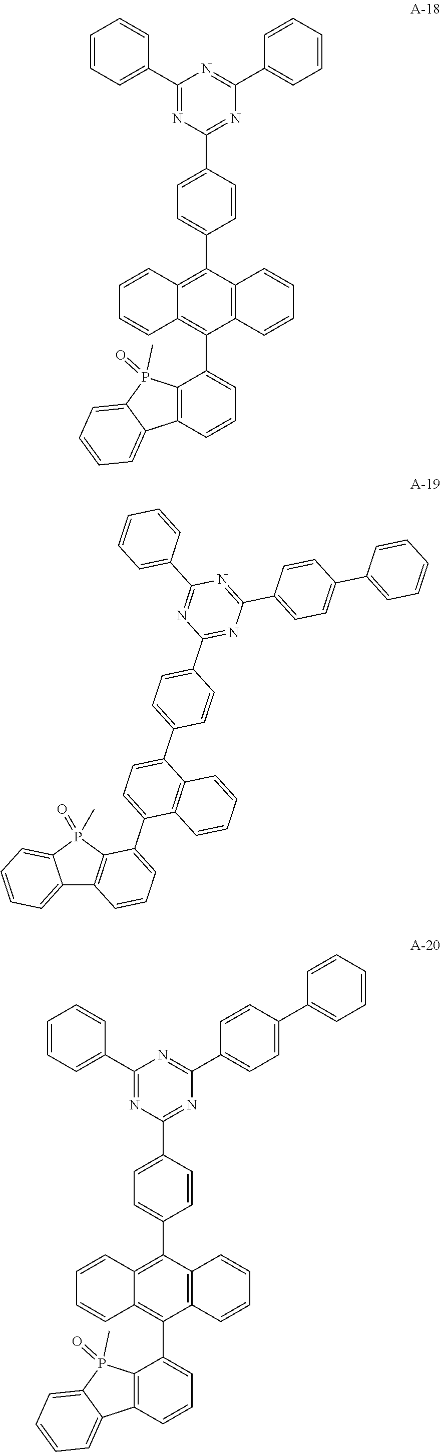 [SMILES: CP1(=O)c2ccccc2-c2cccc(-c3c4ccccc4c(-c4ccc(-c5nc(-c6ccccc6)nc(-c6ccccc6)n5)cc4)c4ccccc34)c21 ; CP1(=O)c2ccccc2-c2cccc(-c3ccc(-c4ccc(-c5nc(-c6ccccc6)nc(-c6ccc(-c7ccccc7)cc6)n5)cc4)c4ccccc34)c21 ; CP1(=O)c2ccccc2-c2cccc(-c3c4ccccc4c(-c4ccc(-c5nc(-c6ccccc6)nc(-c6ccc(-c7ccccc7)cc6)n5)cc4)c4ccccc34)c21]

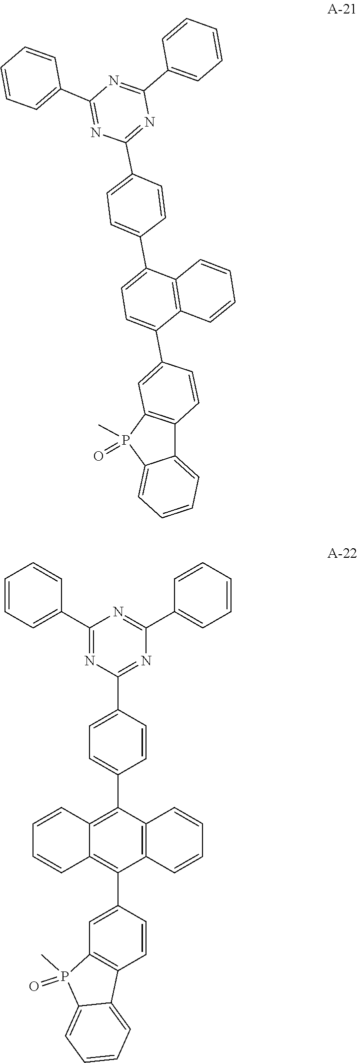 [SMILES: CP1(=O)c2ccccc2-c2ccc(-c3ccc(-c4ccc(-c5nc(-c6ccccc6)nc(-c6ccccc6)n5)cc4)c4ccccc34)cc21 ; CP1(=O)c2ccccc2-c2ccc(-c3c4ccccc4c(-c4ccc(-c5nc(-c6ccccc6)nc(-c6ccccc6)n5)cc4)c4ccccc34)cc21]

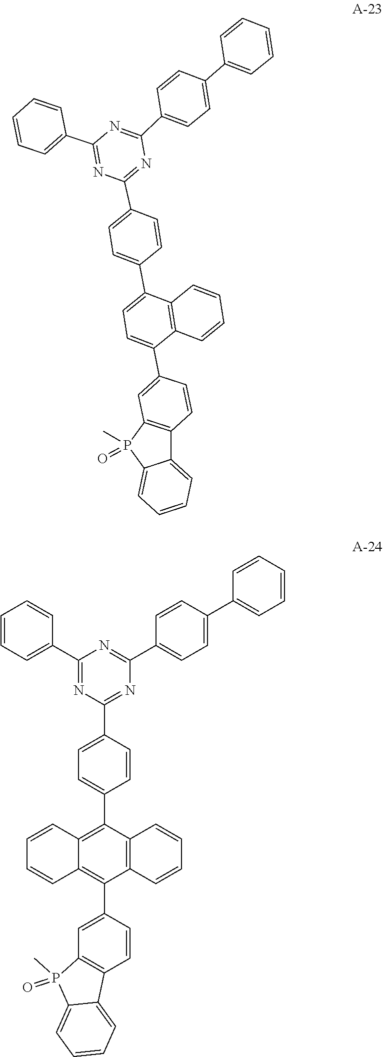 [SMILES: CP1(=O)c2ccccc2-c2ccc(-c3ccc(-c4ccc(-c5nc(-c6ccccc6)nc(-c6ccc(-c7ccccc7)cc6)n5)cc4)c4ccccc34)cc21 ; CP1(=O)c2ccccc2-c2ccc(-c3c4ccccc4c(-c4ccc(-c5nc(-c6ccccc6)nc(-c6ccc(-c7ccccc7)cc6)n5)cc4)c4ccccc34)cc21]

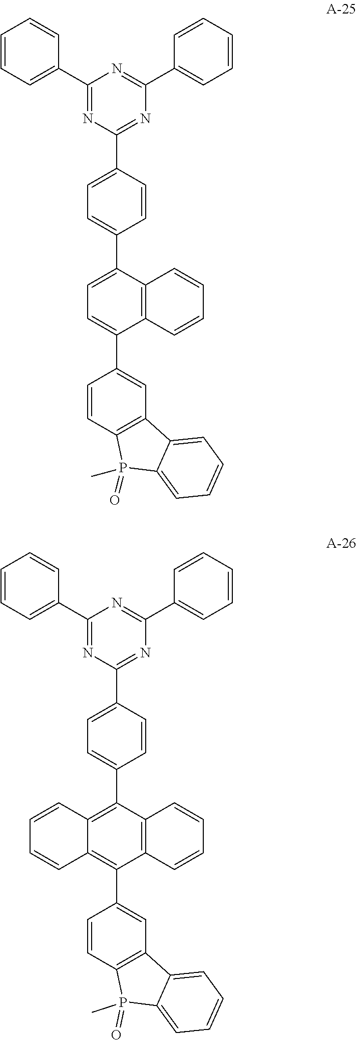 [SMILES: CP1(=O)c2ccccc2-c2cc(-c3ccc(-c4ccc(-c5nc(-c6ccccc6)nc(-c6ccccc6)n5)cc4)c4ccccc34)ccc21 ; CP1(=O)c2ccccc2-c2cc(-c3c4ccccc4c(-c4ccc(-c5nc(-c6ccccc6)nc(-c6ccccc6)n5)cc4)c4ccccc34)ccc21]

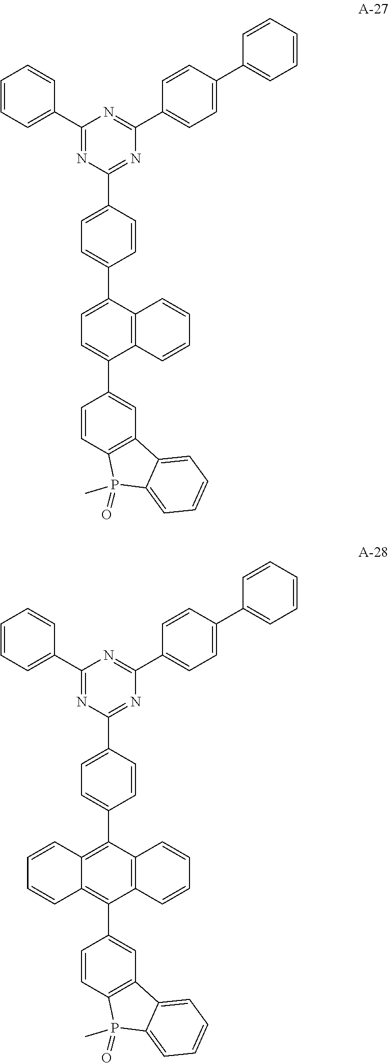 [SMILES: CP1(=O)c2ccccc2-c2cc(-c3ccc(-c4ccc(-c5nc(-c6ccccc6)nc(-c6ccc(-c7ccccc7)cc6)n5)cc4)c4ccccc34)ccc21 ; CP1(=O)c2ccccc2-c2cc(-c3c4ccccc4c(-c4ccc(-c5nc(-c6ccccc6)nc(-c6ccc(-c7ccccc7)cc6)n5)cc4)c4ccccc34)ccc21]

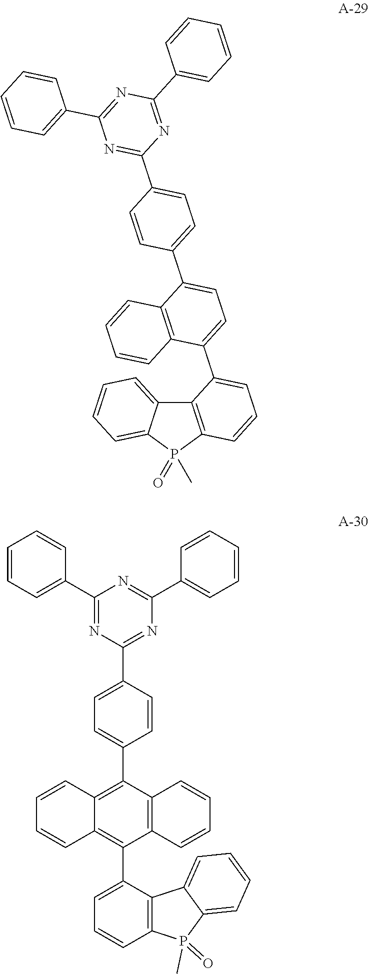 [SMILES: CP1(=O)c2ccccc2-c2c(-c3ccc(-c4ccc(-c5nc(-c6ccccc6)nc(-c6ccccc6)n5)cc4)c4ccccc34)cccc21 ; CP1(=O)c2ccccc2-c2c(-c3c4ccccc4c(-c4ccc(-c5nc(-c6ccccc6)nc(-c6ccccc6)n5)cc4)c4ccccc34)cccc21]

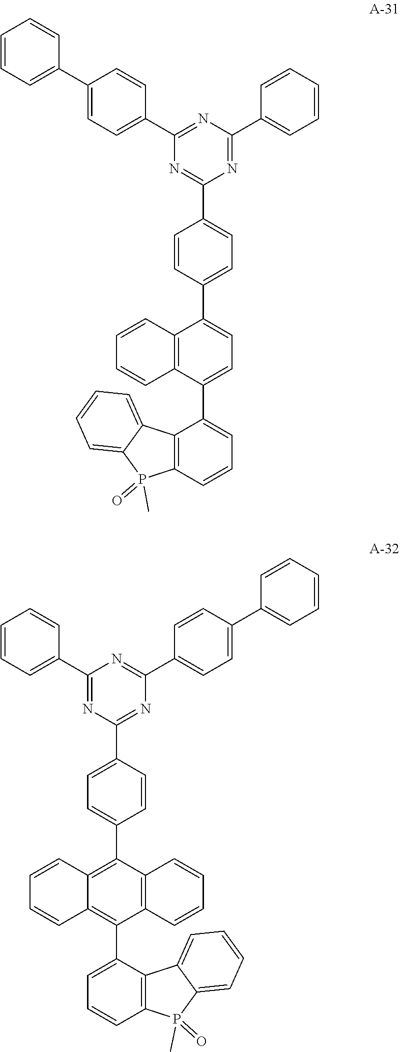 [SMILES: CP1(=O)c2ccccc2-c2c(-c3ccc(-c4ccc(-c5nc(-c6ccccc6)nc(-c6ccc(-c7ccccc7)cc6)n5)cc4)c4ccccc34)cccc21 ; CP1(=O)c2ccccc2-c2c(-c3c4ccccc4c(-c4ccc(-c5nc(-c6ccccc6)nc(-c6ccc(-c7ccccc7)cc6)n5)cc4)c4ccccc34)cccc21]

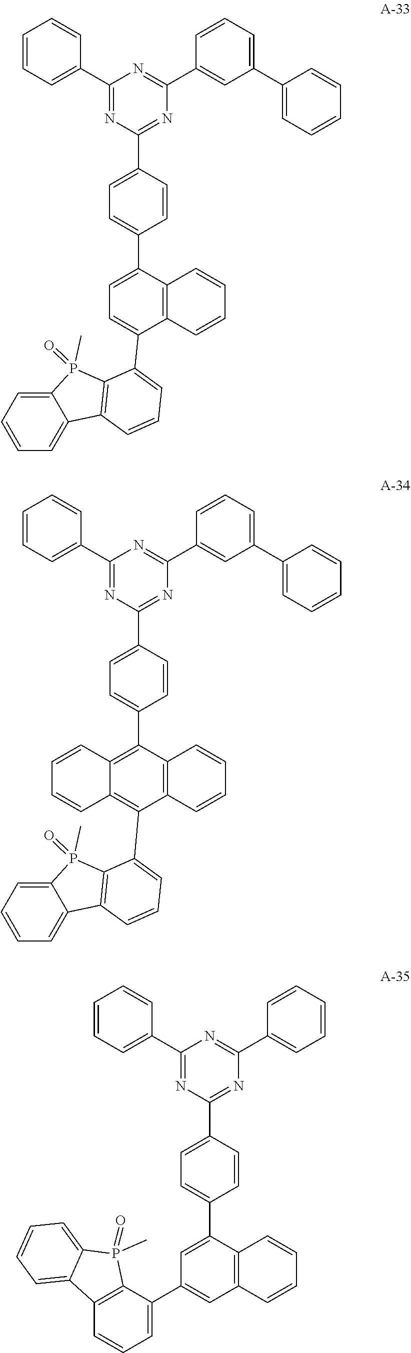

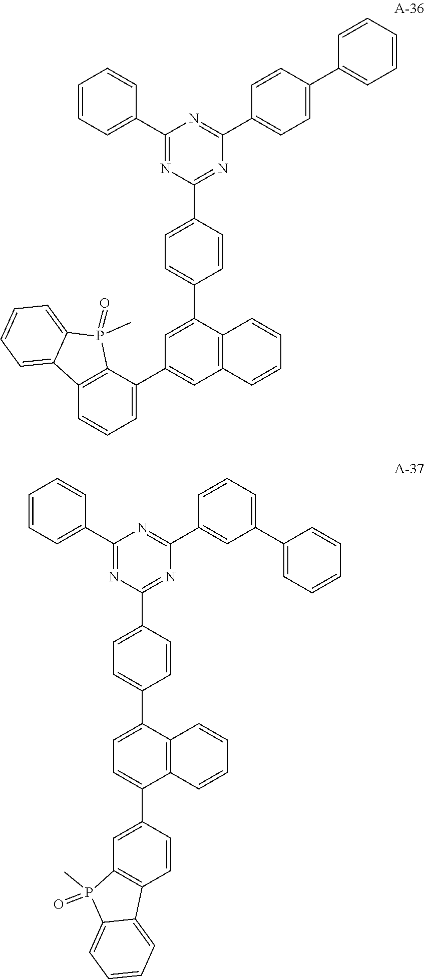 [SMILES: CP1(=O)c2ccccc2-c2cccc(-c3cc(-c4ccc(-c5nc(-c6ccccc6)nc(-c6ccc(-c7ccccc7)cc6)n5)cc4)c4ccccc4c3)c21 ; CP1(=O)c2ccccc2-c2ccc(-c3ccc(-c4ccc(-c5nc(-c6ccccc6)nc(-c6cccc(-c7ccccc7)c6)n5)cc4)c4ccccc34)cc21]

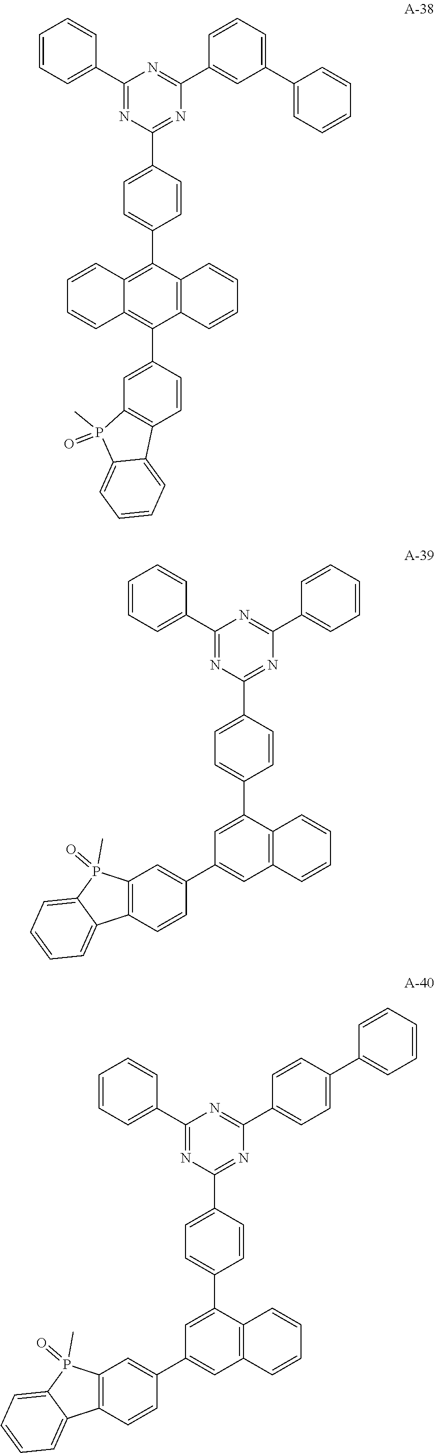 [SMILES: CP1(=O)c2ccccc2-c2ccc(-c3c4ccccc4c(-c4ccc(-c5nc(-c6ccccc6)nc(-c6cccc(-c7ccccc7)c6)n5)cc4)c4ccccc34)cc21 ; CP1(=O)c2ccccc2-c2ccc(-c3cc(-c4ccc(-c5nc(-c6ccccc6)nc(-c6ccccc6)n5)cc4)c4ccccc4c3)cc21 ; CP1(=O)c2ccccc2-c2ccc(-c3cc(-c4ccc(-c5nc(-c6ccccc6)nc(-c6ccc(-c7ccccc7)cc6)n5)cc4)c4ccccc4c3)cc21]

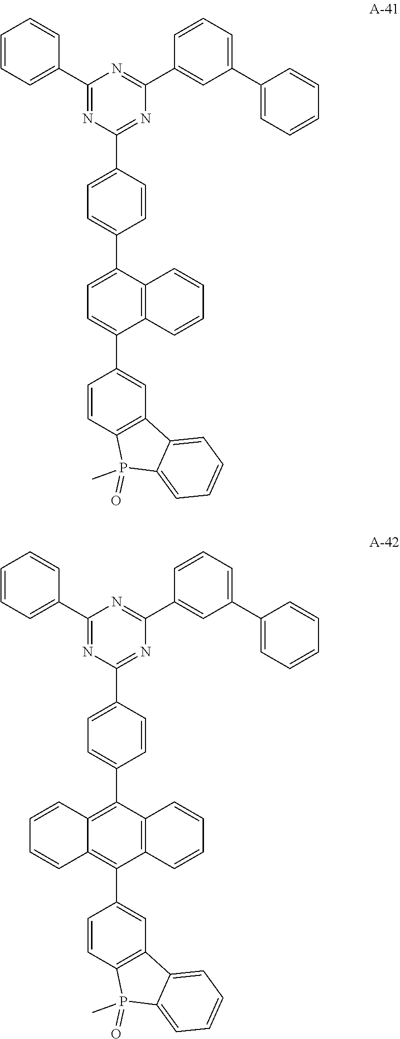 [SMILES: CP1(=O)c2ccccc2-c2cc(-c3ccc(-c4ccc(-c5nc(-c6ccccc6)nc(-c6cccc(-c7ccccc7)c6)n5)cc4)c4ccccc34)ccc21 ; CP1(=O)c2ccccc2-c2cc(-c3c4ccccc4c(-c4ccc(-c5nc(-c6ccccc6)nc(-c6cccc(-c7ccccc7)c6)n5)cc4)c4ccccc34)ccc21]

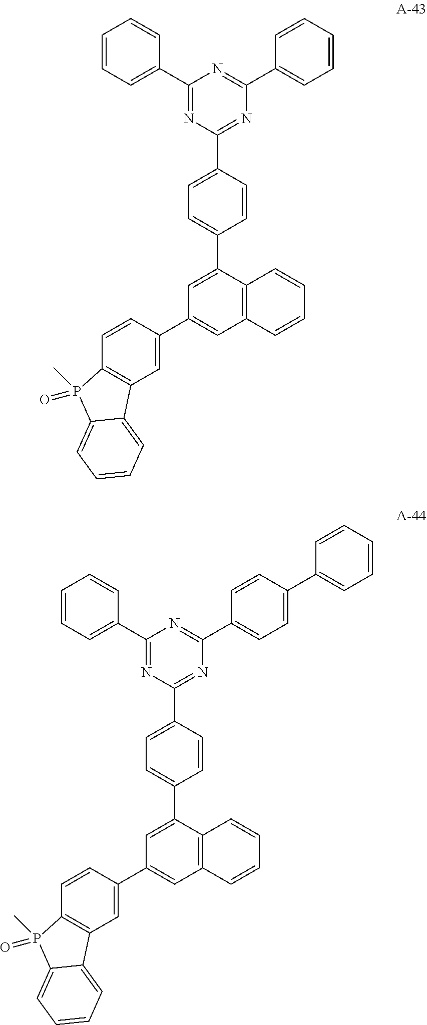 [SMILES: CP1(=O)c2ccccc2-c2cc(-c3cc(-c4ccc(-c5nc(-c6ccccc6)nc(-c6ccccc6)n5)cc4)c4ccccc4c3)ccc21 ; CP1(=O)c2ccccc2-c2cc(-c3cc(-c4ccc(-c5nc(-c6ccccc6)nc(-c6ccc(-c7ccccc7)cc6)n5)cc4)c4ccccc4c3)ccc21]

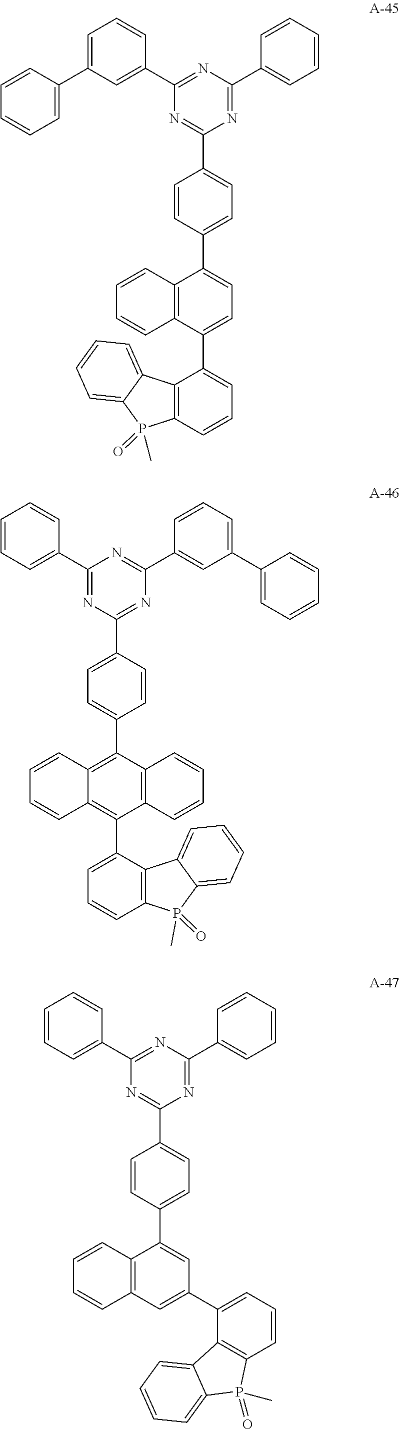 [SMILES: CP1(=O)c2ccccc2-c2c(-c3ccc(-c4ccc(-c5nc(-c6ccccc6)nc(-c6cccc(-c7ccccc7)c6)n5)cc4)c4ccccc34)cccc21 ; CP1(=O)c2ccccc2-c2c(-c3c4ccccc4c(-c4ccc(-c5nc(-c6ccccc6)nc(-c6cccc(-c7ccccc7)c6)n5)cc4)c4ccccc34)cccc21 ; CP1(=O)c2ccccc2-c2c(-c3cc(-c4ccc(-c5nc(-c6ccccc6)nc(-c6ccccc6)n5)cc4)c4ccccc4c3)cccc21]

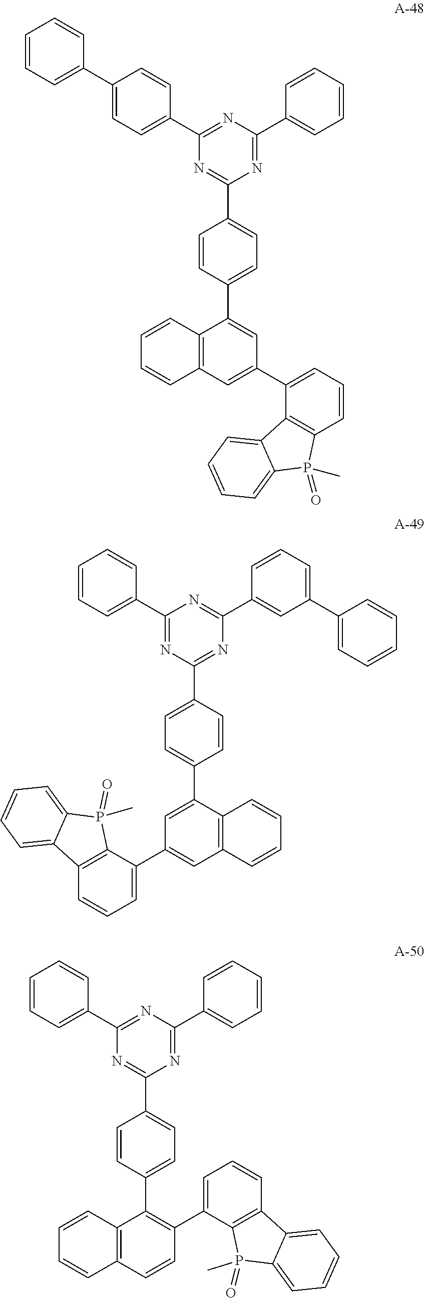 [SMILES: CP1(=O)c2ccccc2-c2c(-c3cc(-c4ccc(-c5nc(-c6ccccc6)nc(-c6ccc(-c7ccccc7)cc6)n5)cc4)c4ccccc4c3)cccc21 ; CP1(=O)c2ccccc2-c2cccc(-c3cc(-c4ccc(-c5nc(-c6ccccc6)nc(-c6cccc(-c7ccccc7)c6)n5)cc4)c4ccccc4c3)c21 ; CP1(=O)c2ccccc2-c2cccc(-c3ccc4ccccc4c3-c3ccc(-c4nc(-c5ccccc5)nc(-c5ccccc5)n4)cc3)c21]

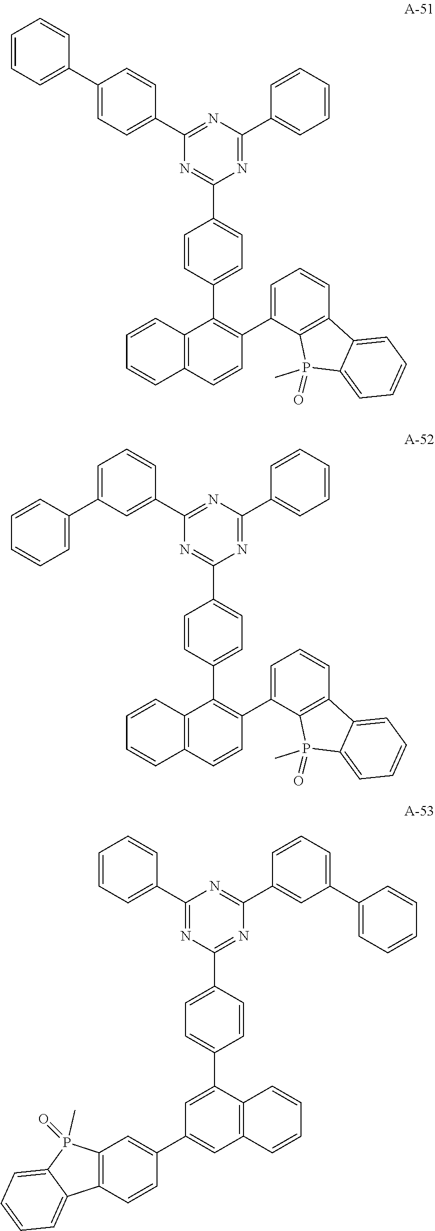 [SMILES: CP1(=O)c2ccccc2-c2cccc(-c3ccc4ccccc4c3-c3ccc(-c4nc(-c5ccccc5)nc(-c5ccc(-c6ccccc6)cc5)n4)cc3)c21 ; CP1(=O)c2ccccc2-c2cccc(-c3ccc4ccccc4c3-c3ccc(-c4nc(-c5ccccc5)nc(-c5cccc(-c6ccccc6)c5)n4)cc3)c21 ; CP1(=O)c2ccccc2-c2ccc(-c3cc(-c4ccc(-c5nc(-c6ccccc6)nc(-c6cccc(-c7ccccc7)c6)n5)cc4)c4ccccc4c3)cc21]

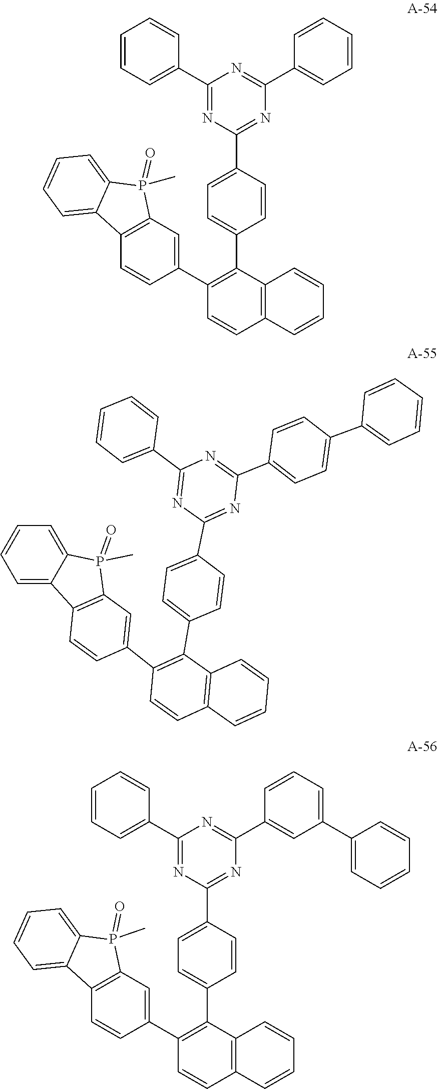 [SMILES: CP1(=O)c2ccccc2-c2ccc(-c3ccc4ccccc4c3-c3ccc(-c4nc(-c5ccccc5)nc(-c5ccccc5)n4)cc3)cc21 ; CP1(=O)c2ccccc2-c2ccc(-c3ccc4ccccc4c3-c3ccc(-c4nc(-c5ccccc5)nc(-c5ccc(-c6ccccc6)cc5)n4)cc3)cc21 ; CP1(=O)c2ccccc2-c2ccc(-c3ccc4ccccc4c3-c3ccc(-c4nc(-c5ccccc5)nc(-c5cccc(-c6ccccc6)c5)n4)cc3)cc21]

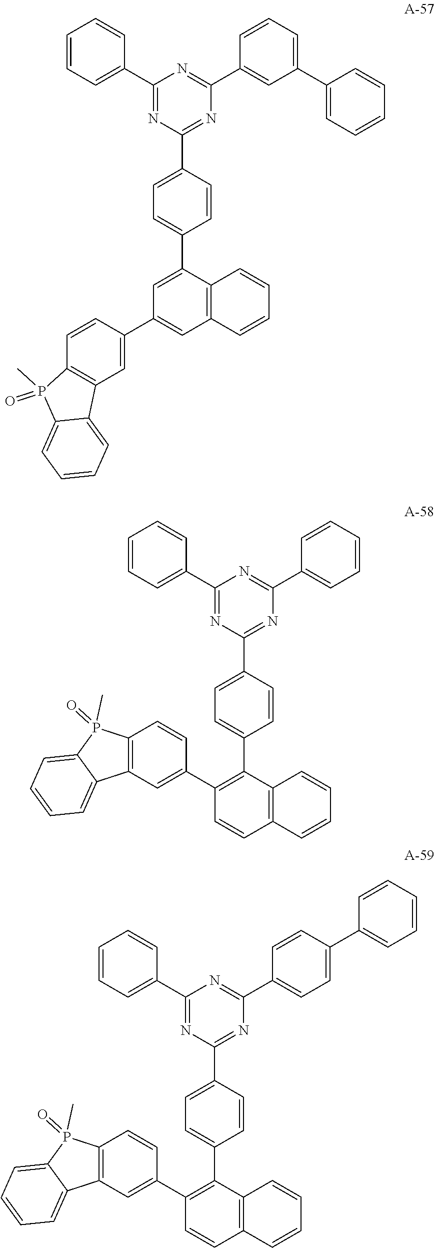 [SMILES: CP1(=O)c2ccccc2-c2cc(-c3cc(-c4ccc(-c5nc(-c6ccccc6)nc(-c6cccc(-c7ccccc7)c6)n5)cc4)c4ccccc4c3)ccc21 ; CP1(=O)c2ccccc2-c2cc(-c3ccc4ccccc4c3-c3ccc(-c4nc(-c5ccccc5)nc(-c5ccccc5)n4)cc3)ccc21 ; CP1(=O)c2ccccc2-c2cc(-c3ccc4ccccc4c3-c3ccc(-c4nc(-c5ccccc5)nc(-c5ccc(-c6ccccc6)cc5)n4)cc3)ccc21]

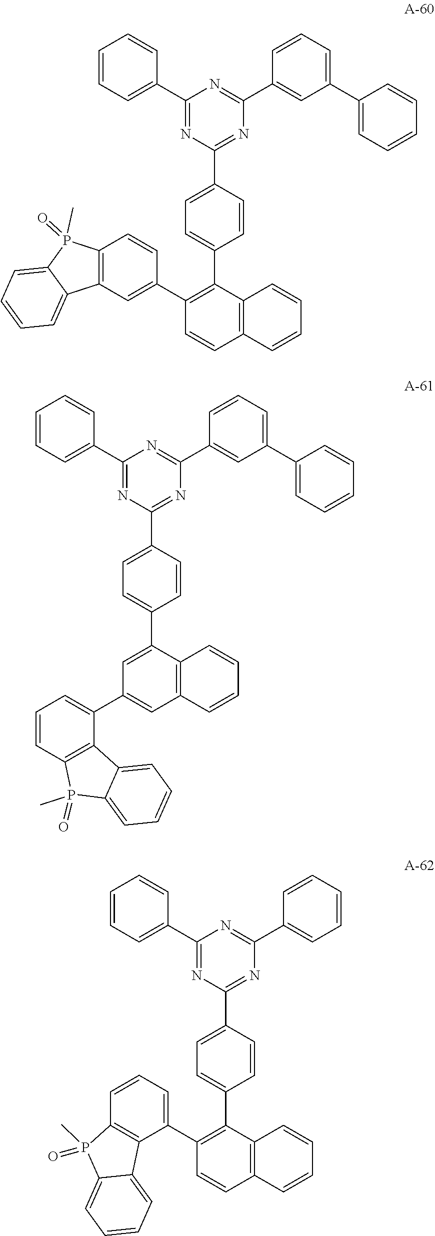 [SMILES: CP1(=O)c2ccccc2-c2cc(-c3ccc4ccccc4c3-c3ccc(-c4nc(-c5ccccc5)nc(-c5cccc(-c6ccccc6)c5)n4)cc3)ccc21 ; CP1(=O)c2ccccc2-c2c(-c3cc(-c4ccc(-c5nc(-c6ccccc6)nc(-c6cccc(-c7ccccc7)c6)n5)cc4)c4ccccc4c3)cccc21 ; CP1(=O)c2ccccc2-c2c(-c3ccc4ccccc4c3-c3ccc(-c4nc(-c5ccccc5)nc(-c5ccccc5)n4)cc3)cccc21]

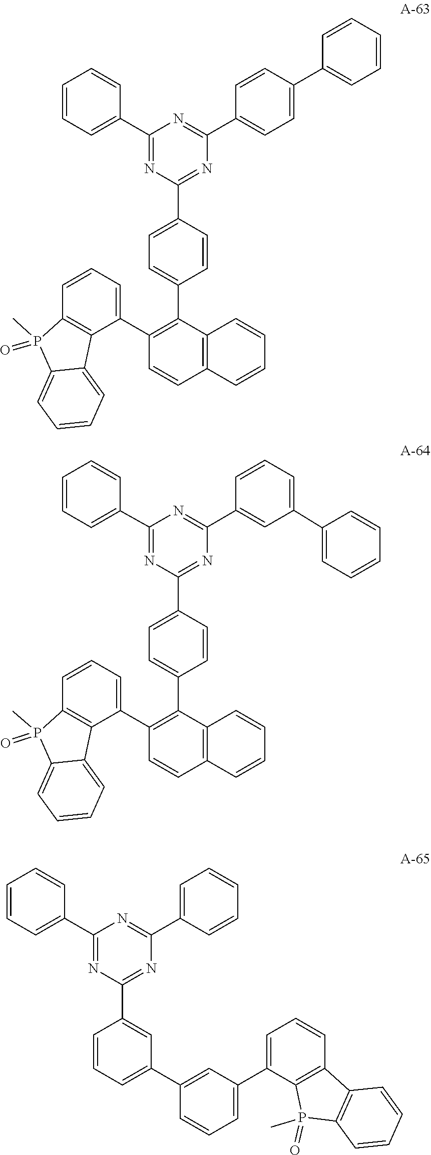

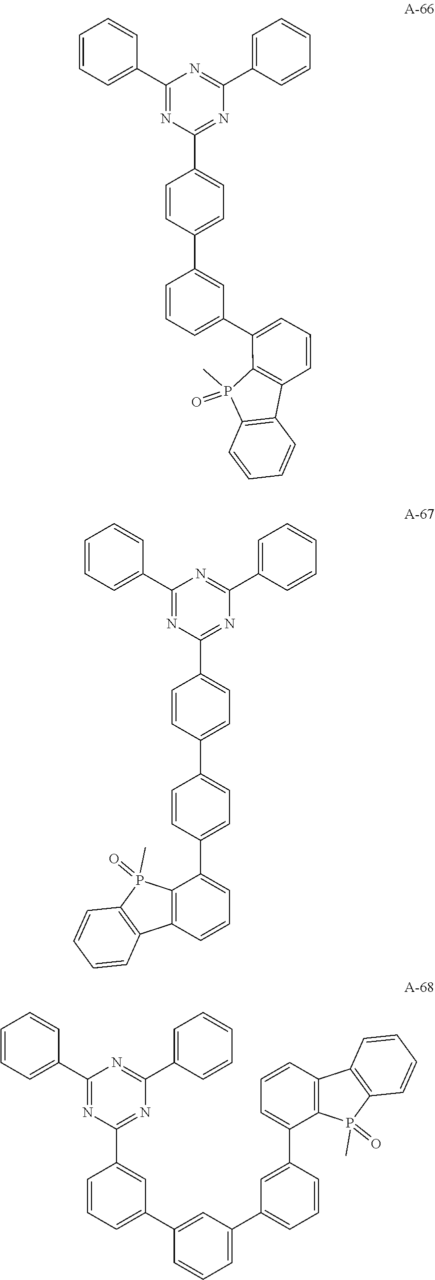 [SMILES: CP1(=O)c2ccccc2-c2cccc(-c3cccc(-c4ccc(-c5nc(-c6ccccc6)nc(-c6ccccc6)n5)cc4)c3)c21 ; CP1(=O)c2ccccc2-c2cccc(-c3ccc(-c4ccc(-c5nc(-c6ccccc6)nc(-c6ccccc6)n5)cc4)cc3)c21 ; CP1(=O)c2ccccc2-c2cccc(-c3cccc(-c4cccc(-c5cccc(-c6nc(-c7ccccc7)nc(-c7ccccc7)n6)c5)c4)c3)c21]

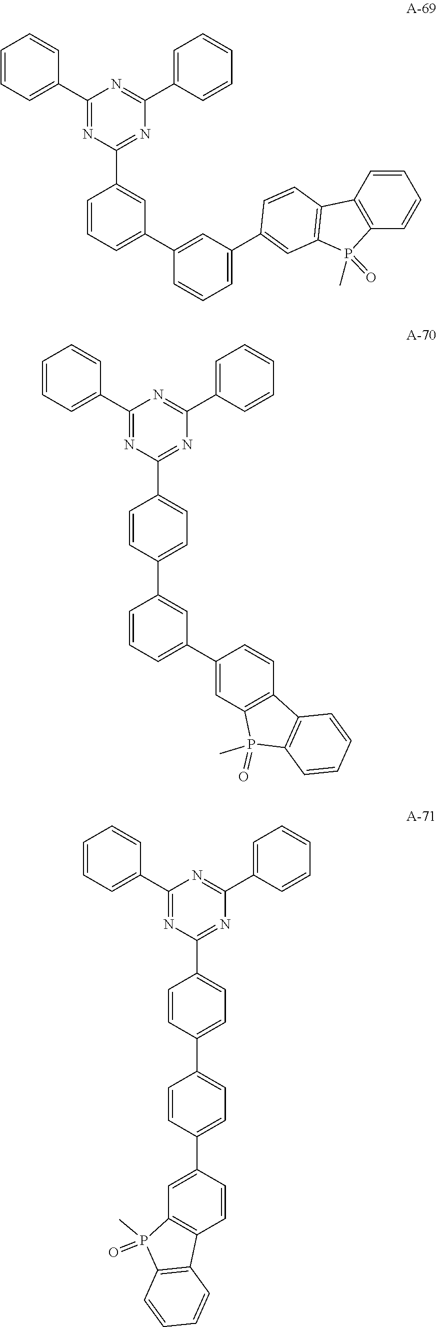 [SMILES: CP1(=O)c2ccccc2-c2ccc(-c3cccc(-c4cccc(-c5nc(-c6ccccc6)nc(-c6ccccc6)n5)c4)c3)cc21 ; CP1(=O)c2ccccc2-c2ccc(-c3cccc(-c4ccc(-c5nc(-c6ccccc6)nc(-c6ccccc6)n5)cc4)c3)cc21 ; CP1(=O)c2ccccc2-c2ccc(-c3ccc(-c4ccc(-c5nc(-c6ccccc6)nc(-c6ccccc6)n5)cc4)cc3)cc21]

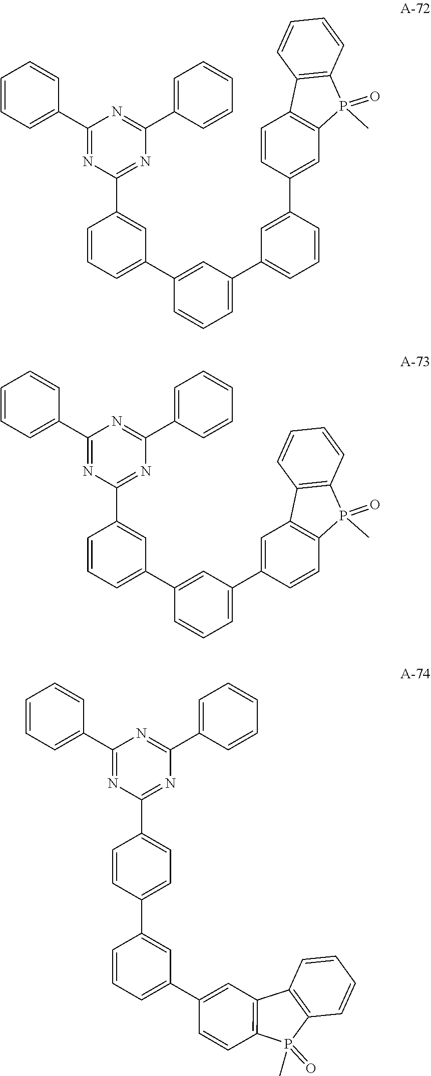

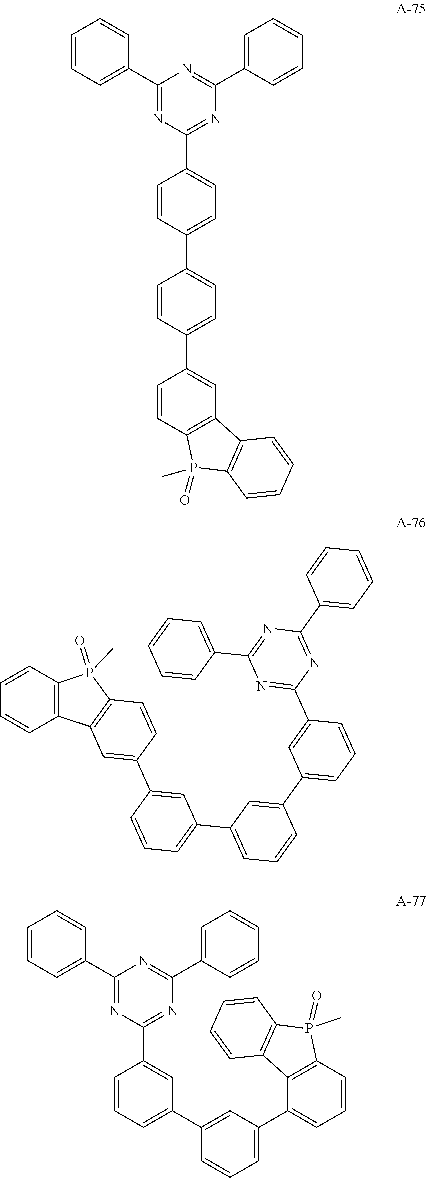 [SMILES: CP1(=O)c2ccccc2-c2cc(-c3ccc(-c4ccc(-c5nc(-c6ccccc6)nc(-c6ccccc6)n5)cc4)cc3)ccc21 ; CP1(=O)c2ccccc2-c2cc(-c3cccc(-c4cccc(-c5cccc(-c6nc(-c7ccccc7)nc(-c7ccccc7)n6)c5)c4)c3)ccc21 ; CP1(=O)c2ccccc2-c2c(-c3cccc(-c4cccc(-c5nc(-c6ccccc6)nc(-c6ccccc6)n5)c4)c3)cccc21]

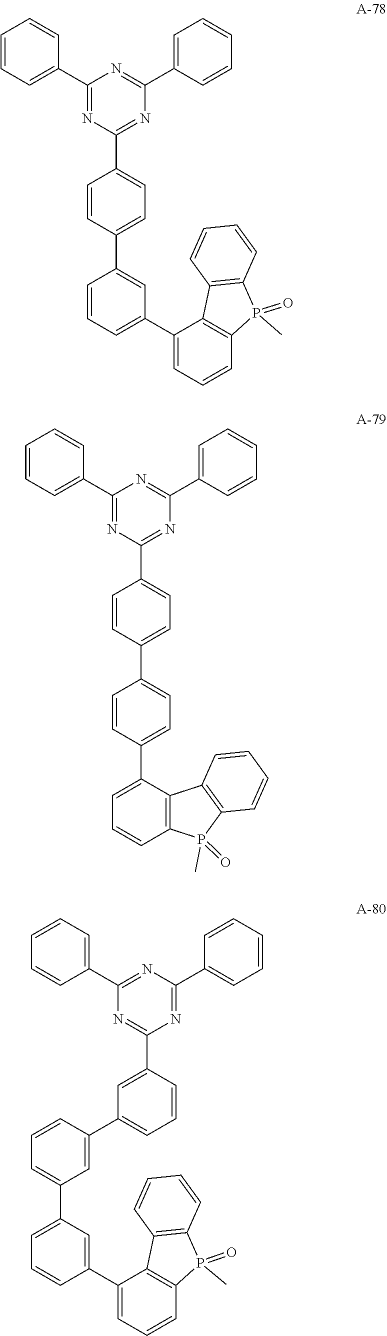 [SMILES: CP1(=O)c2ccccc2-c2c(-c3cccc(-c4ccc(-c5nc(-c6ccccc6)nc(-c6ccccc6)n5)cc4)c3)cccc21 ; CP1(=O)c2ccccc2-c2c(-c3ccc(-c4ccc(-c5nc(-c6ccccc6)nc(-c6ccccc6)n5)cc4)cc3)cccc21 ; CP1(=O)c2ccccc2-c2c(-c3cccc(-c4cccc(-c5cccc(-c6nc(-c7ccccc7)nc(-c7ccccc7)n6)c5)c4)c3)cccc21]

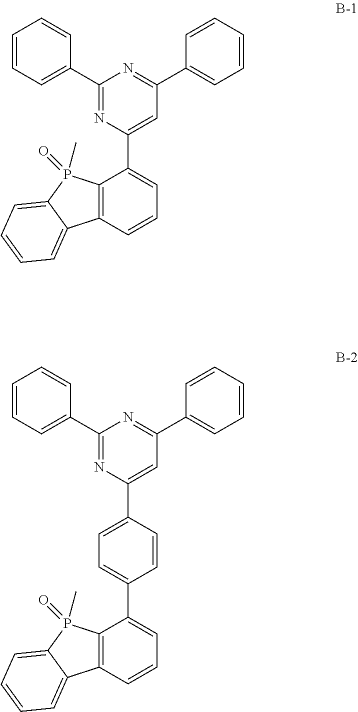 [SMILES: CP1(=O)c2ccccc2-c2cccc(-c3cc(-c4ccccc4)nc(-c4ccccc4)n3)c21 ; CP1(=O)c2ccccc2-c2cccc(-c3ccc(-c4cc(-c5ccccc5)nc(-c5ccccc5)n4)cc3)c21]

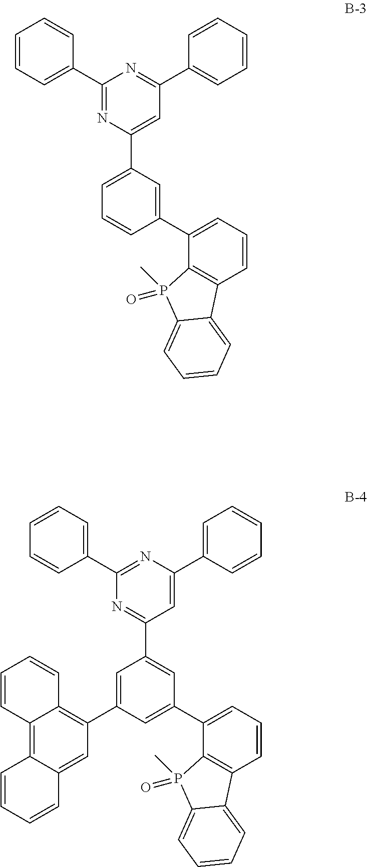 [SMILES: CP1(=O)c2ccccc2-c2cccc(-c3cccc(-c4cc(-c5ccccc5)nc(-c5ccccc5)n4)c3)c21 ; CP1(=O)c2ccccc2-c2cccc(-c3cc(-c4cc(-c5ccccc5)nc(-c5ccccc5)n4)cc(-c4cc5ccccc5c5ccccc45)c3)c21]

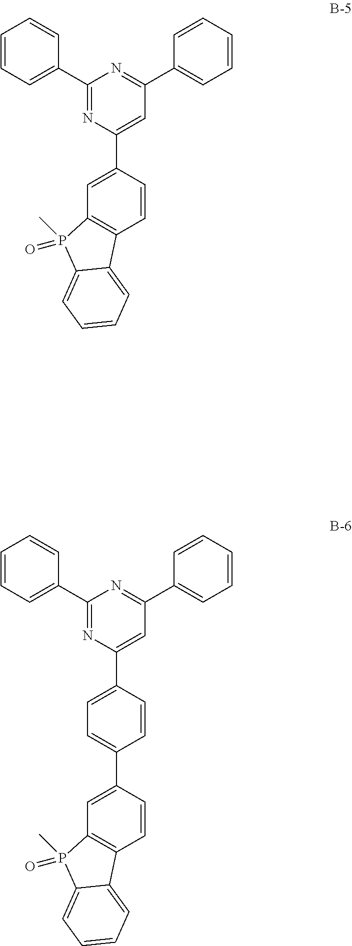 [SMILES: CP1(=O)c2ccccc2-c2ccc(-c3cc(-c4ccccc4)nc(-c4ccccc4)n3)cc21 ; CP1(=O)c2ccccc2-c2ccc(-c3ccc(-c4cc(-c5ccccc5)nc(-c5ccccc5)n4)cc3)cc21]

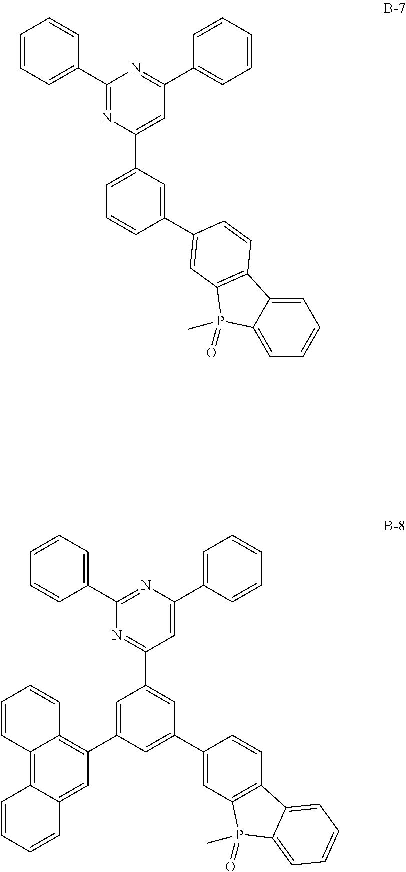 [SMILES: CP1(=O)c2ccccc2-c2ccc(-c3cccc(-c4cc(-c5ccccc5)nc(-c5ccccc5)n4)c3)cc21 ; CP1(=O)c2ccccc2-c2ccc(-c3cc(-c4cc(-c5ccccc5)nc(-c5ccccc5)n4)cc(-c4cc5ccccc5c5ccccc45)c3)cc21]

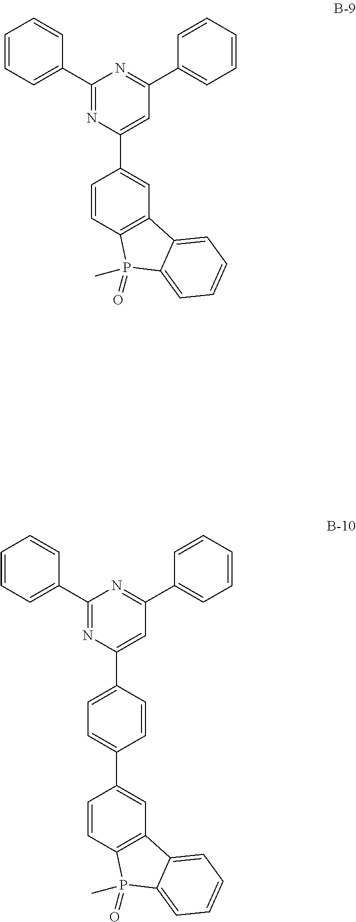 [SMILES: CP1(=O)c2ccccc2-c2cc(-c3cc(-c4ccccc4)nc(-c4ccccc4)n3)ccc21 ; CP1(=O)c2ccccc2-c2cc(-c3ccc(-c4cc(-c5ccccc5)nc(-c5ccccc5)n4)cc3)ccc21]

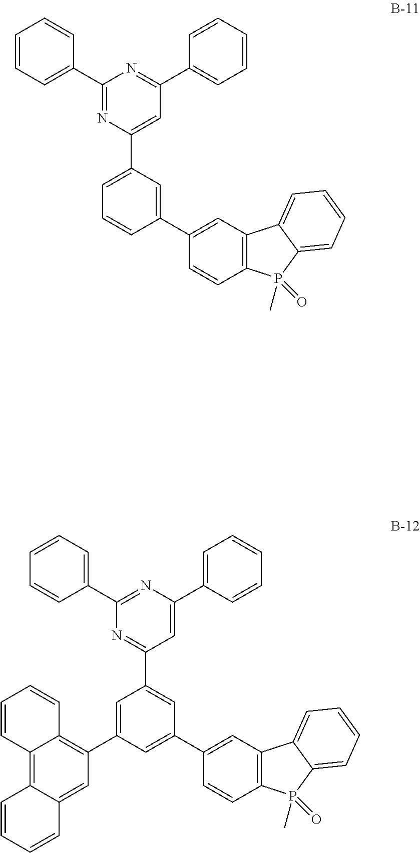 [SMILES: CP1(=O)c2ccccc2-c2cc(-c3cccc(-c4cc(-c5ccccc5)nc(-c5ccccc5)n4)c3)ccc21 ; CP1(=O)c2ccccc2-c2cc(-c3cc(-c4cc(-c5ccccc5)nc(-c5ccccc5)n4)cc(-c4cc5ccccc5c5ccccc45)c3)ccc21]

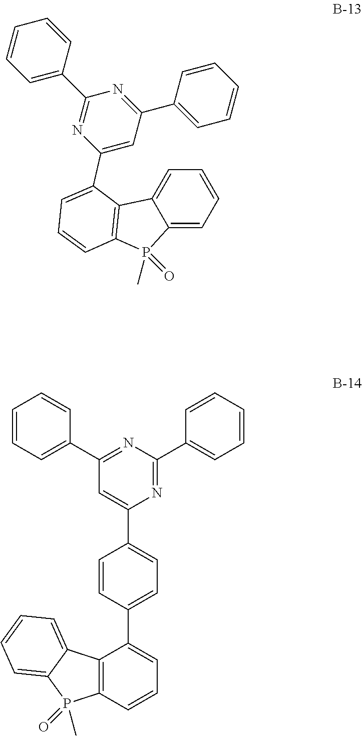 [SMILES: CP1(=O)c2ccccc2-c2c(-c3cc(-c4ccccc4)nc(-c4ccccc4)n3)cccc21 ; CP1(=O)c2ccccc2-c2c(-c3ccc(-c4cc(-c5ccccc5)nc(-c5ccccc5)n4)cc3)cccc21]

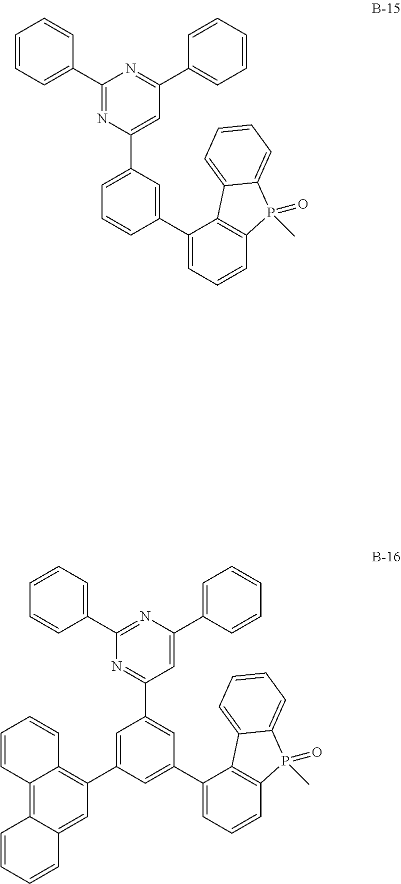 [SMILES: CP1(=O)c2ccccc2-c2c(-c3cccc(-c4cc(-c5ccccc5)nc(-c5ccccc5)n4)c3)cccc21 ; CP1(=O)c2ccccc2-c2c(-c3cc(-c4cc(-c5ccccc5)nc(-c5ccccc5)n4)cc(-c4cc5ccccc5c5ccccc45)c3)cccc21]

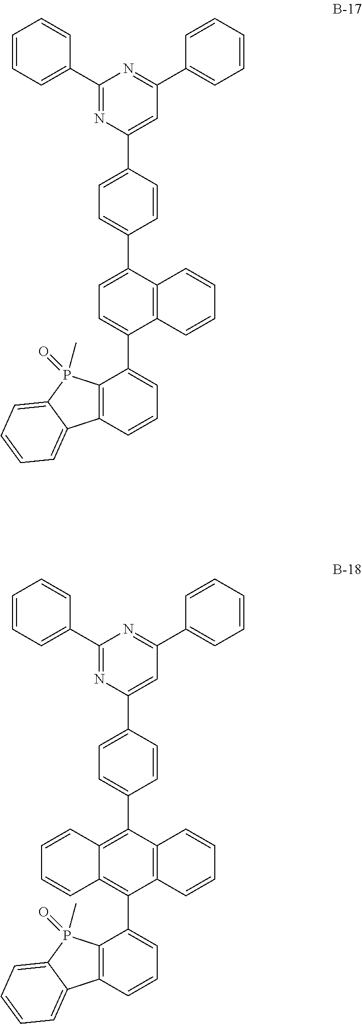 [SMILES: CP1(=O)c2ccccc2-c2cccc(-c3ccc(-c4ccc(-c5cc(-c6ccccc6)nc(-c6ccccc6)n5)cc4)c4ccccc34)c21 ; CP1(=O)c2ccccc2-c2cccc(-c3c4ccccc4c(-c4ccc(-c5cc(-c6ccccc6)nc(-c6ccccc6)n5)cc4)c4ccccc34)c21]

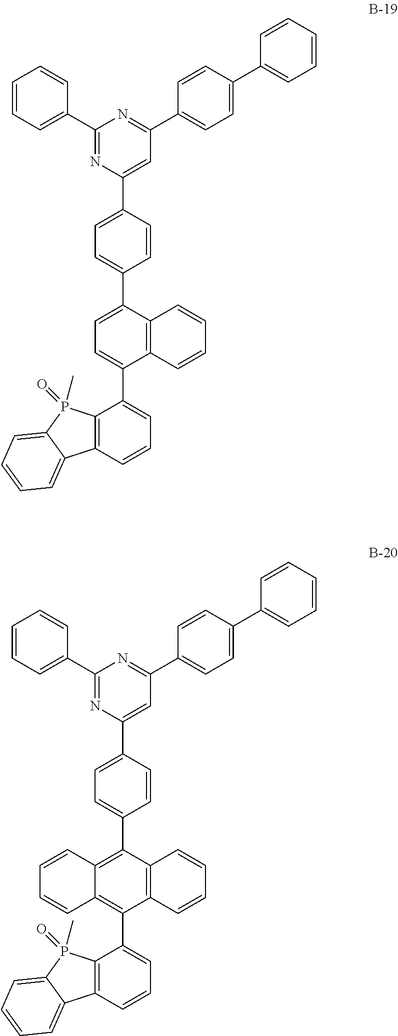 [SMILES: CP1(=O)c2ccccc2-c2cccc(-c3ccc(-c4ccc(-c5cc(-c6ccc(-c7ccccc7)cc6)nc(-c6ccccc6)n5)cc4)c4ccccc34)c21 ; CP1(=O)c2ccccc2-c2cccc(-c3c4ccccc4c(-c4ccc(-c5cc(-c6ccc(-c7ccccc7)cc6)nc(-c6ccccc6)n5)cc4)c4ccccc34)c21]

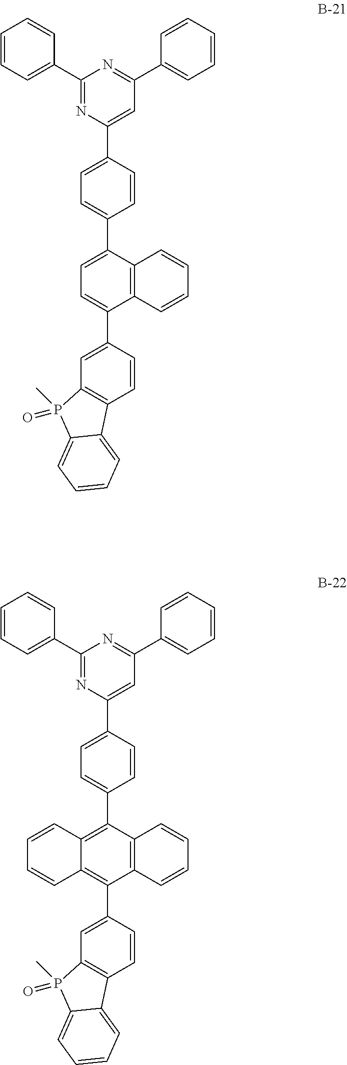 [SMILES: CP1(=O)c2ccccc2-c2ccc(-c3ccc(-c4ccc(-c5cc(-c6ccccc6)nc(-c6ccccc6)n5)cc4)c4ccccc34)cc21 ; CP1(=O)c2ccccc2-c2ccc(-c3c4ccccc4c(-c4ccc(-c5cc(-c6ccccc6)nc(-c6ccccc6)n5)cc4)c4ccccc34)cc21]

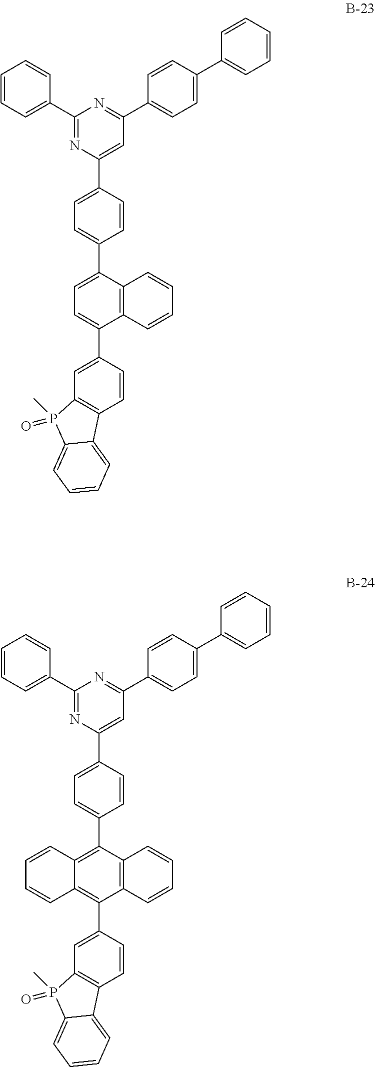 [SMILES: CP1(=O)c2ccccc2-c2ccc(-c3ccc(-c4ccc(-c5cc(-c6ccc(-c7ccccc7)cc6)nc(-c6ccccc6)n5)cc4)c4ccccc34)cc21 ; CP1(=O)c2ccccc2-c2ccc(-c3c4ccccc4c(-c4ccc(-c5cc(-c6ccc(-c7ccccc7)cc6)nc(-c6ccccc6)n5)cc4)c4ccccc34)cc21]

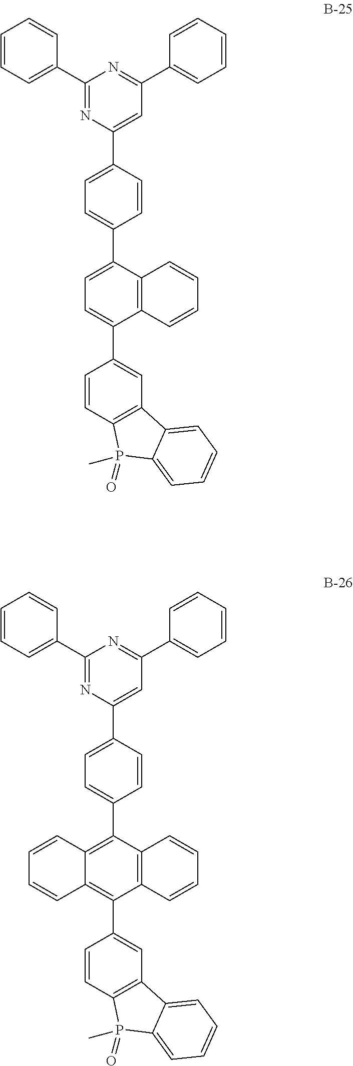 [SMILES: CP1(=O)c2ccccc2-c2cc(-c3ccc(-c4ccc(-c5cc(-c6ccccc6)nc(-c6ccccc6)n5)cc4)c4ccccc34)ccc21 ; CP1(=O)c2ccccc2-c2cc(-c3c4ccccc4c(-c4ccc(-c5cc(-c6ccccc6)nc(-c6ccccc6)n5)cc4)c4ccccc34)ccc21]

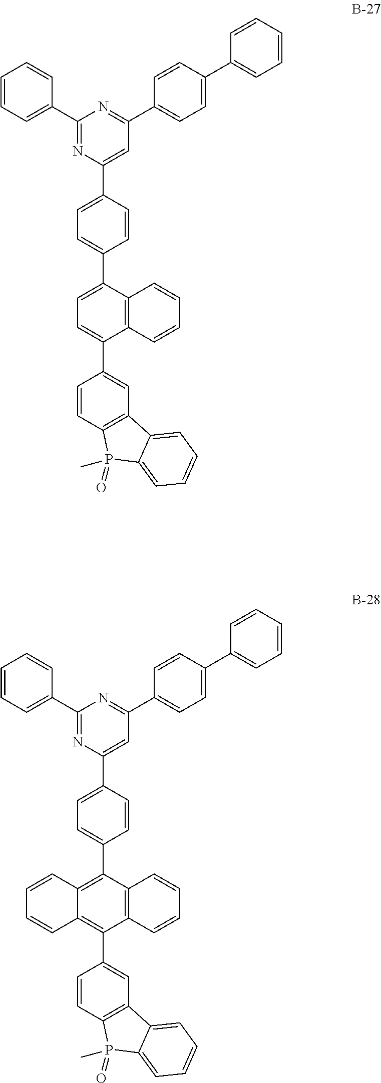 [SMILES: CP1(=O)c2ccccc2-c2cc(-c3ccc(-c4ccc(-c5cc(-c6ccc(-c7ccccc7)cc6)nc(-c6ccccc6)n5)cc4)c4ccccc34)ccc21 ; CP1(=O)c2ccccc2-c2cc(-c3c4ccccc4c(-c4ccc(-c5cc(-c6ccc(-c7ccccc7)cc6)nc(-c6ccccc6)n5)cc4)c4ccccc34)ccc21]

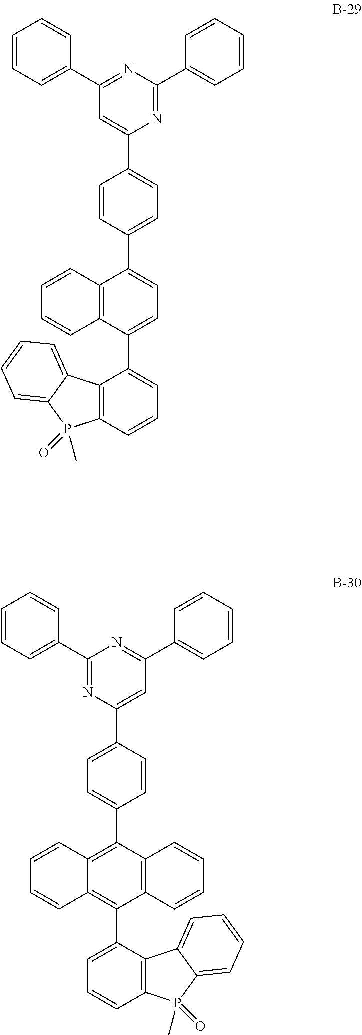 [SMILES: CP1(=O)c2ccccc2-c2c(-c3ccc(-c4ccc(-c5cc(-c6ccccc6)nc(-c6ccccc6)n5)cc4)c4ccccc34)cccc21 ; CP1(=O)c2ccccc2-c2c(-c3c4ccccc4c(-c4ccc(-c5cc(-c6ccccc6)nc(-c6ccccc6)n5)cc4)c4ccccc34)cccc21]

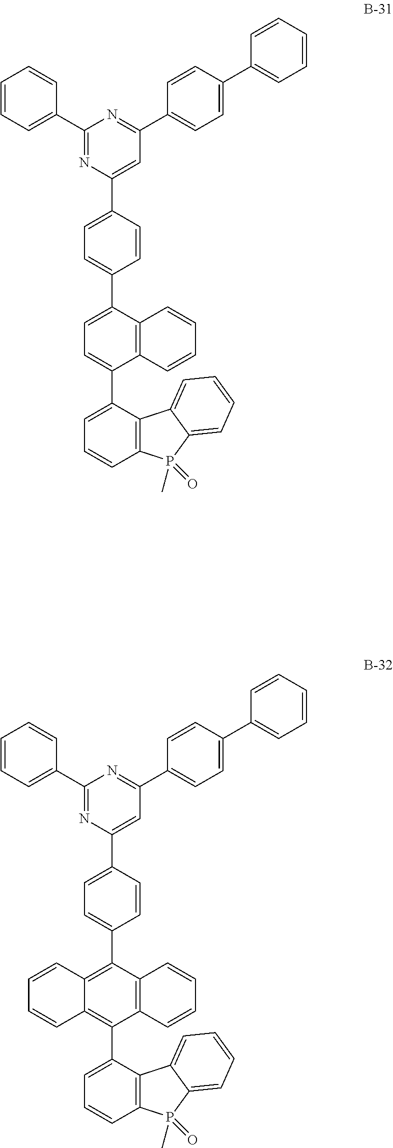 [SMILES: CP1(=O)c2ccccc2-c2c(-c3ccc(-c4ccc(-c5cc(-c6ccc(-c7ccccc7)cc6)nc(-c6ccccc6)n5)cc4)c4ccccc34)cccc21 ; CP1(=O)c2ccccc2-c2c(-c3c4ccccc4c(-c4ccc(-c5cc(-c6ccc(-c7ccccc7)cc6)nc(-c6ccccc6)n5)cc4)c4ccccc34)cccc21]

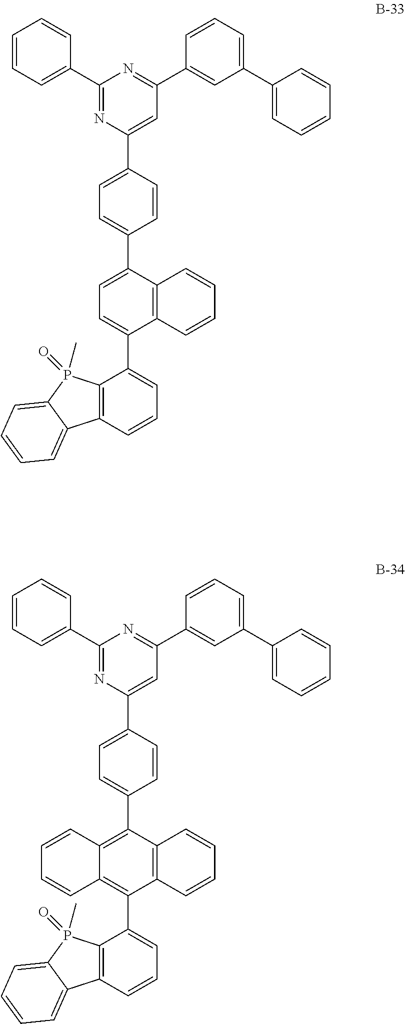 [SMILES: CP1(=O)c2ccccc2-c2cccc(-c3ccc(-c4ccc(-c5cc(-c6cccc(-c7ccccc7)c6)nc(-c6ccccc6)n5)cc4)c4ccccc34)c21 ; CP1(=O)c2ccccc2-c2cccc(-c3c4ccccc4c(-c4ccc(-c5cc(-c6cccc(-c7ccccc7)c6)nc(-c6ccccc6)n5)cc4)c4ccccc34)c21]

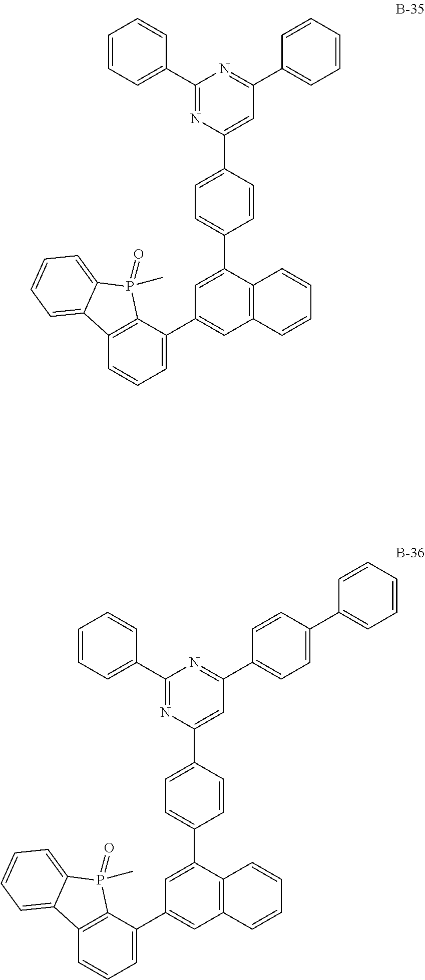 [SMILES: CP1(=O)c2ccccc2-c2cccc(-c3cc(-c4ccc(-c5cc(-c6ccccc6)nc(-c6ccccc6)n5)cc4)c4ccccc4c3)c21 ; CP1(=O)c2ccccc2-c2cccc(-c3cc(-c4ccc(-c5cc(-c6ccc(-c7ccccc7)cc6)nc(-c6ccccc6)n5)cc4)c4ccccc4c3)c21]

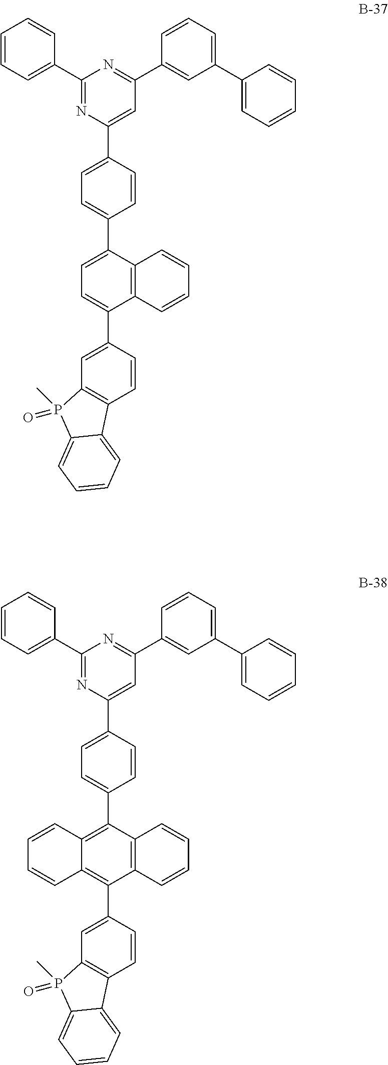 [SMILES: CP1(=O)c2ccccc2-c2ccc(-c3ccc(-c4ccc(-c5cc(-c6cccc(-c7ccccc7)c6)nc(-c6ccccc6)n5)cc4)c4ccccc34)cc21 ; CP1(=O)c2ccccc2-c2ccc(-c3c4ccccc4c(-c4ccc(-c5cc(-c6cccc(-c7ccccc7)c6)nc(-c6ccccc6)n5)cc4)c4ccccc34)cc21]

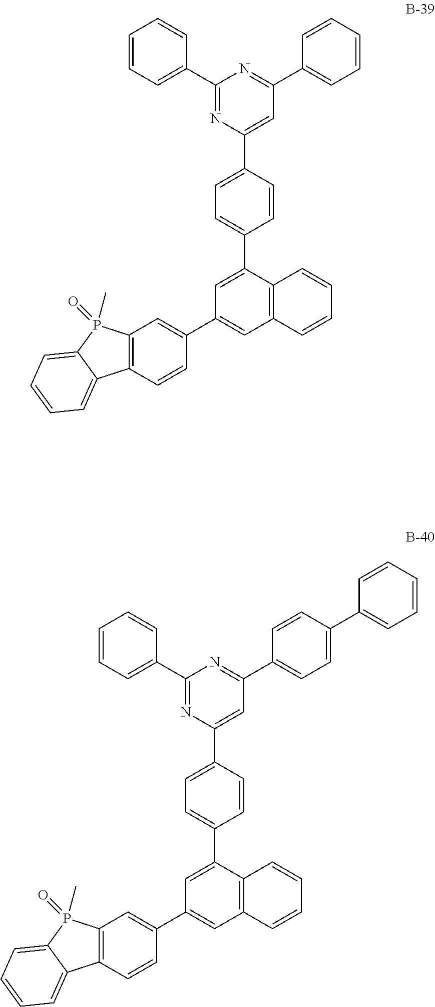 [SMILES: CP1(=O)c2ccccc2-c2ccc(-c3cc(-c4ccc(-c5cc(-c6ccccc6)nc(-c6ccccc6)n5)cc4)c4ccccc4c3)cc21 ; CP1(=O)c2ccccc2-c2ccc(-c3cc(-c4ccc(-c5cc(-c6ccc(-c7ccccc7)cc6)nc(-c6ccccc6)n5)cc4)c4ccccc4c3)cc21]

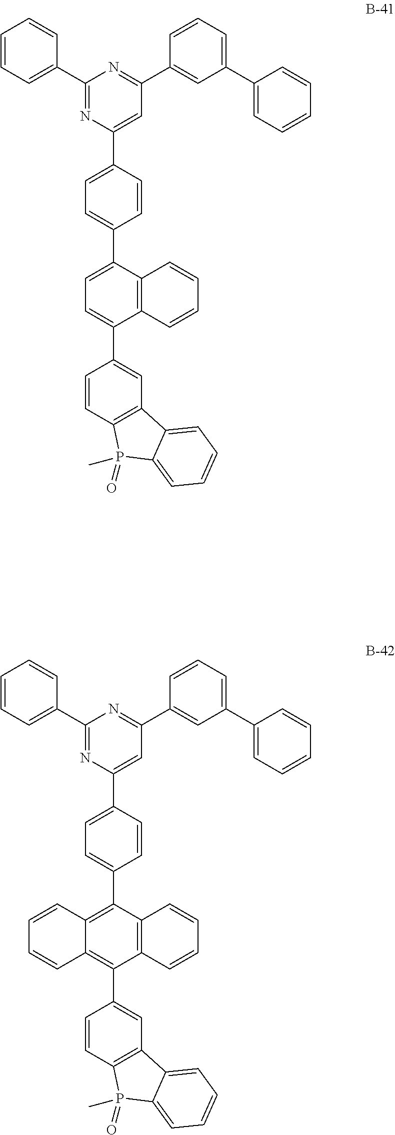 [SMILES: CP1(=O)c2ccccc2-c2cc(-c3ccc(-c4ccc(-c5cc(-c6cccc(-c7ccccc7)c6)nc(-c6ccccc6)n5)cc4)c4ccccc34)ccc21 ; CP1(=O)c2ccccc2-c2cc(-c3c4ccccc4c(-c4ccc(-c5cc(-c6cccc(-c7ccccc7)c6)nc(-c6ccccc6)n5)cc4)c4ccccc34)ccc21]

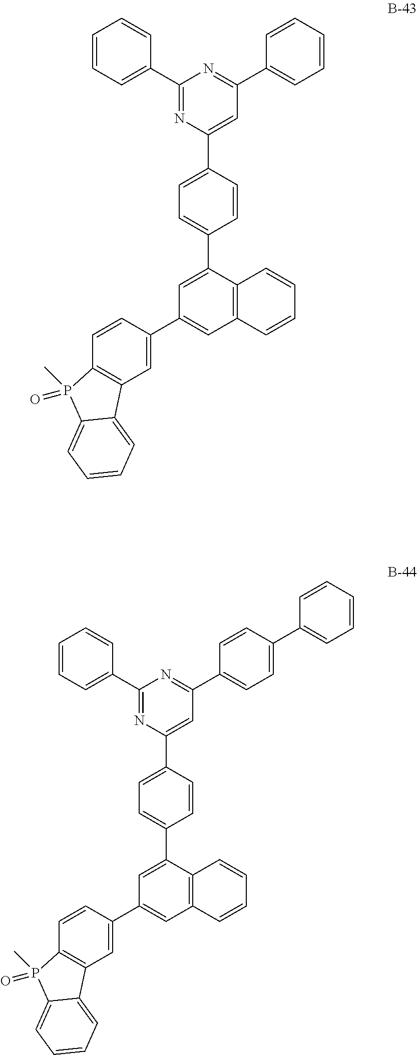 [SMILES: CP1(=O)c2ccccc2-c2cc(-c3cc(-c4ccc(-c5cc(-c6ccccc6)nc(-c6ccccc6)n5)cc4)c4ccccc4c3)ccc21 ; CP1(=O)c2ccccc2-c2cc(-c3cc(-c4ccc(-c5cc(-c6ccc(-c7ccccc7)cc6)nc(-c6ccccc6)n5)cc4)c4ccccc4c3)ccc21]

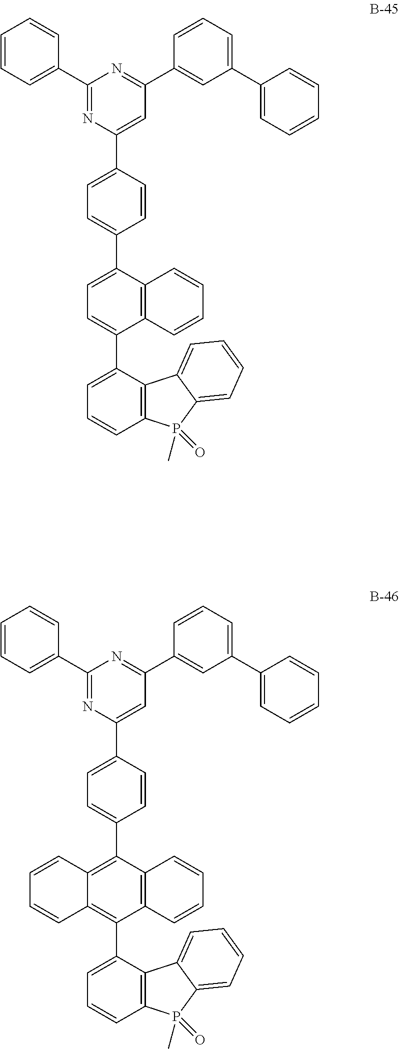 [SMILES: CP1(=O)c2ccccc2-c2c(-c3ccc(-c4ccc(-c5cc(-c6cccc(-c7ccccc7)c6)nc(-c6ccccc6)n5)cc4)c4ccccc34)cccc21 ; CP1(=O)c2ccccc2-c2c(-c3c4ccccc4c(-c4ccc(-c5cc(-c6cccc(-c7ccccc7)c6)nc(-c6ccccc6)n5)cc4)c4ccccc34)cccc21]

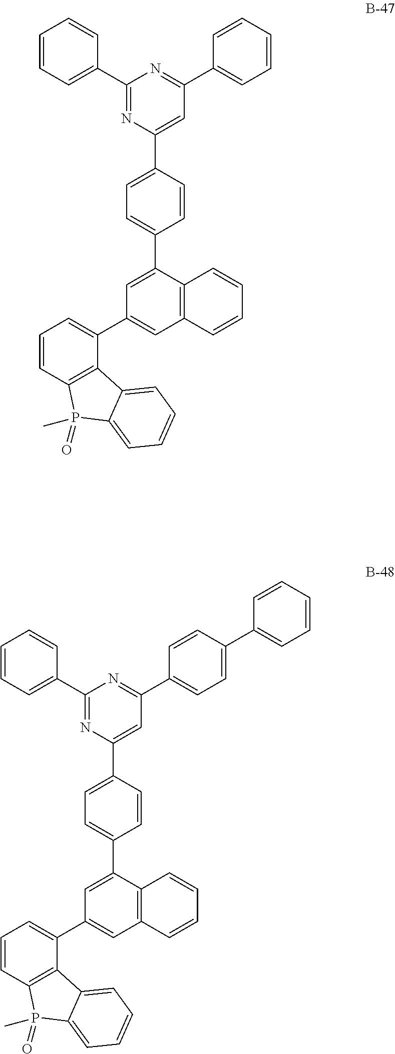 [SMILES: CP1(=O)c2ccccc2-c2c(-c3cc(-c4ccc(-c5cc(-c6ccccc6)nc(-c6ccccc6)n5)cc4)c4ccccc4c3)cccc21 ; CP1(=O)c2ccccc2-c2c(-c3cc(-c4ccc(-c5cc(-c6ccc(-c7ccccc7)cc6)nc(-c6ccccc6)n5)cc4)c4ccccc4c3)cccc21]

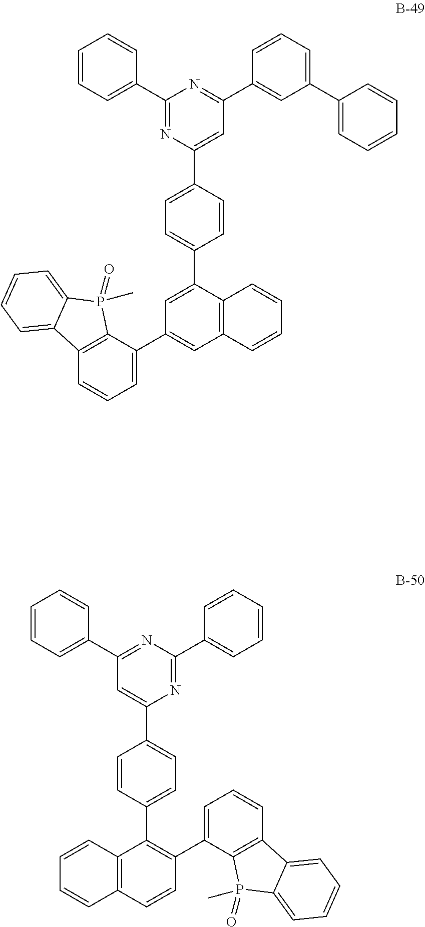 [SMILES: CP1(=O)c2ccccc2-c2cccc(-c3cc(-c4ccc(-c5cc(-c6cccc(-c7ccccc7)c6)nc(-c6ccccc6)n5)cc4)c4ccccc4c3)c21 ; CP1(=O)c2ccccc2-c2cccc(-c3ccc4ccccc4c3-c3ccc(-c4cc(-c5ccccc5)nc(-c5ccccc5)n4)cc3)c21]

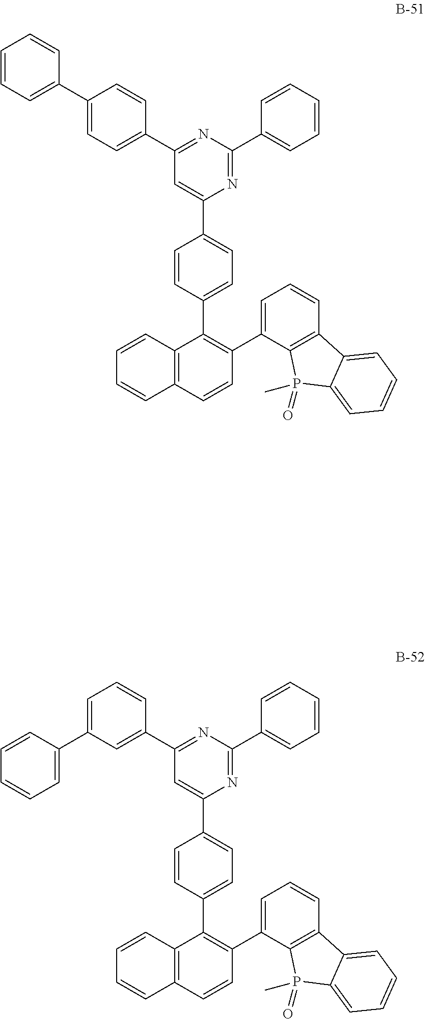 [SMILES: CP1(=O)c2ccccc2-c2cccc(-c3ccc4ccccc4c3-c3ccc(-c4cc(-c5ccc(-c6ccccc6)cc5)nc(-c5ccccc5)n4)cc3)c21 ; CP1(=O)c2ccccc2-c2cccc(-c3ccc4ccccc4c3-c3ccc(-c4cc(-c5cccc(-c6ccccc6)c5)nc(-c5ccccc5)n4)cc3)c21]

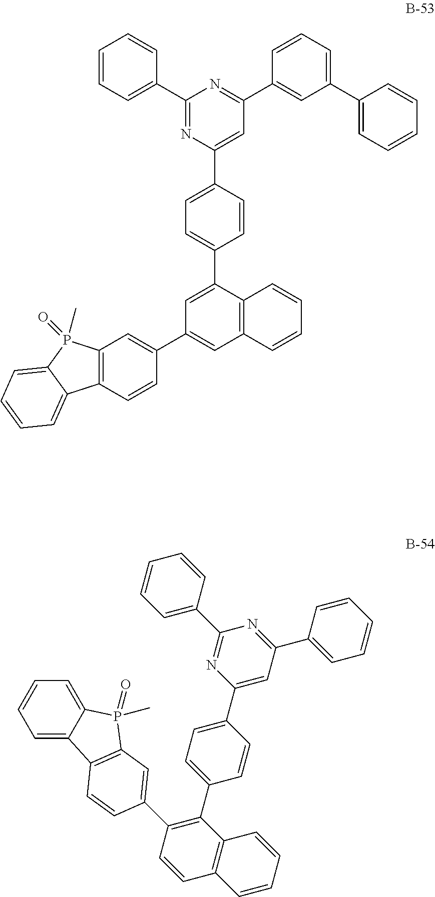 [SMILES: CP1(=O)c2ccccc2-c2ccc(-c3cc(-c4ccc(-c5cc(-c6cccc(-c7ccccc7)c6)nc(-c6ccccc6)n5)cc4)c4ccccc4c3)cc21 ; CP1(=O)c2ccccc2-c2ccc(-c3ccc4ccccc4c3-c3ccc(-c4cc(-c5ccccc5)nc(-c5ccccc5)n4)cc3)cc21]

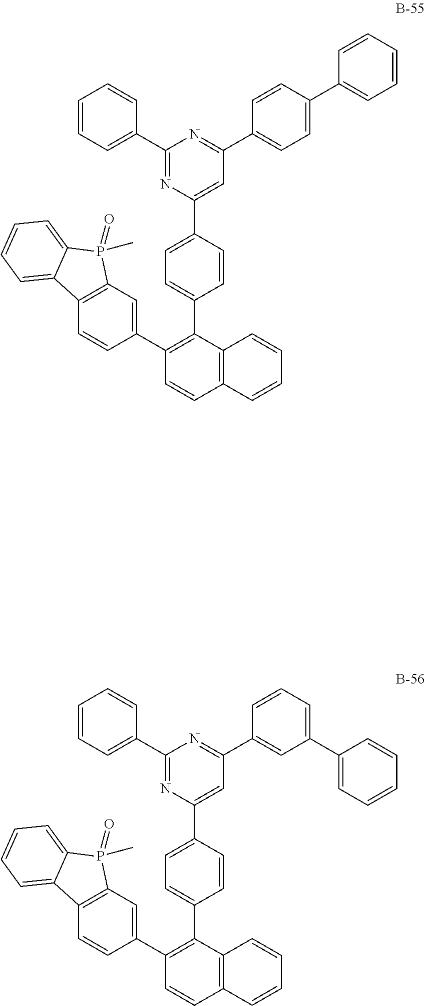 [SMILES: CP1(=O)c2ccccc2-c2ccc(-c3ccc4ccccc4c3-c3ccc(-c4cc(-c5ccc(-c6ccccc6)cc5)nc(-c5ccccc5)n4)cc3)cc21 ; CP1(=O)c2ccccc2-c2ccc(-c3ccc4ccccc4c3-c3ccc(-c4cc(-c5cccc(-c6ccccc6)c5)nc(-c5ccccc5)n4)cc3)cc21]

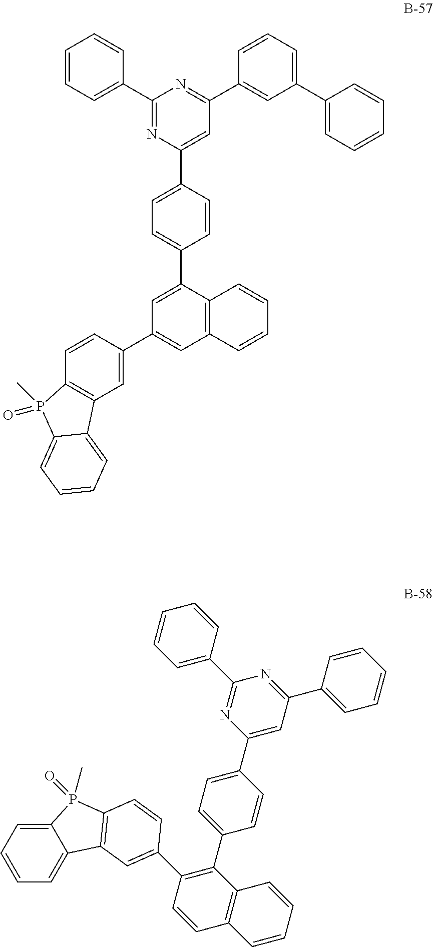 [SMILES: CP1(=O)c2ccccc2-c2cc(-c3cc(-c4ccc(-c5cc(-c6cccc(-c7ccccc7)c6)nc(-c6ccccc6)n5)cc4)c4ccccc4c3)ccc21 ; CP1(=O)c2ccccc2-c2cc(-c3ccc4ccccc4c3-c3ccc(-c4cc(-c5ccccc5)nc(-c5ccccc5)n4)cc3)ccc21]

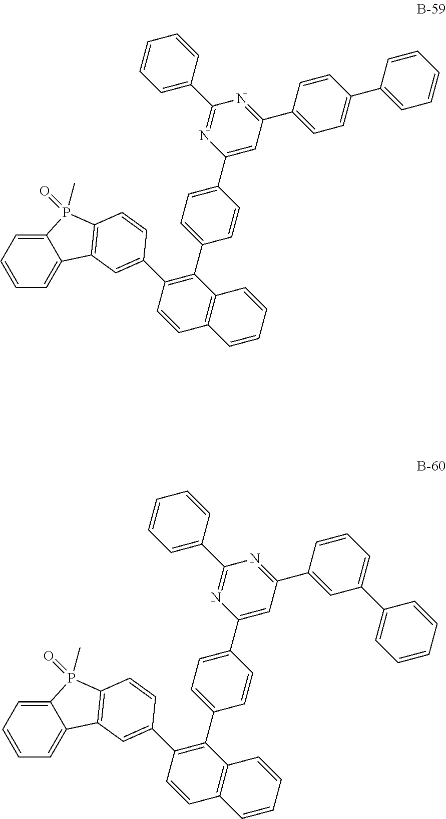 [SMILES: CP1(=O)c2ccccc2-c2cc(-c3ccc4ccccc4c3-c3ccc(-c4cc(-c5ccc(-c6ccccc6)cc5)nc(-c5ccccc5)n4)cc3)ccc21 ; CP1(=O)c2ccccc2-c2cc(-c3ccc4ccccc4c3-c3ccc(-c4cc(-c5cccc(-c6ccccc6)c5)nc(-c5ccccc5)n4)cc3)ccc21]

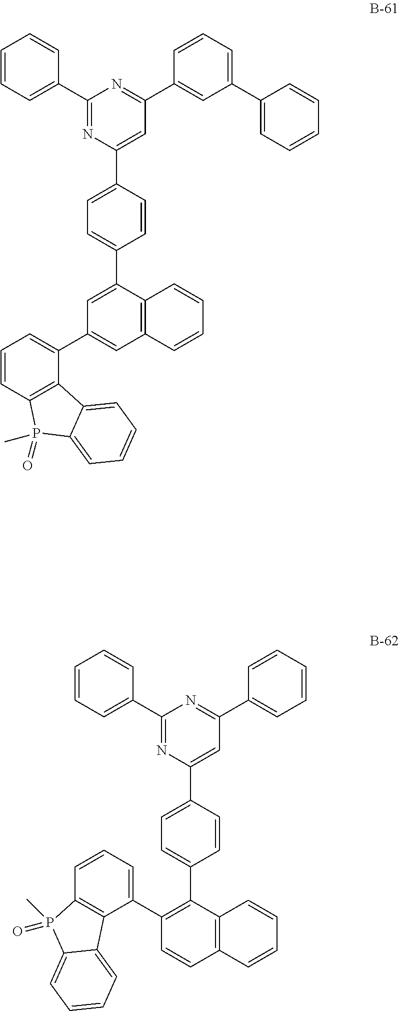 [SMILES: CP1(=O)c2ccccc2-c2c(-c3cc(-c4ccc(-c5cc(-c6cccc(-c7ccccc7)c6)nc(-c6ccccc6)n5)cc4)c4ccccc4c3)cccc21 ; CP1(=O)c2ccccc2-c2c(-c3ccc4ccccc4c3-c3ccc(-c4cc(-c5ccccc5)nc(-c5ccccc5)n4)cc3)cccc21]

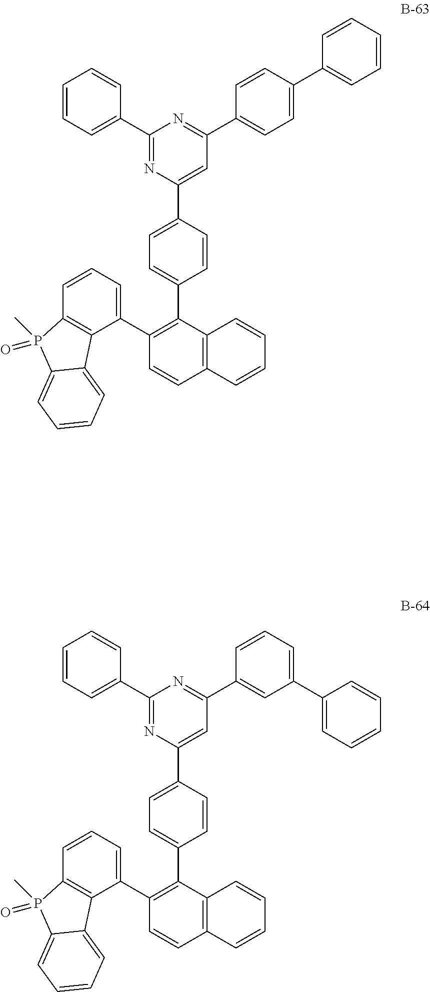 [SMILES: CP1(=O)c2ccccc2-c2c(-c3ccc4ccccc4c3-c3ccc(-c4cc(-c5ccc(-c6ccccc6)cc5)nc(-c5ccccc5)n4)cc3)cccc21 ; CP1(=O)c2ccccc2-c2c(-c3ccc4ccccc4c3-c3ccc(-c4cc(-c5cccc(-c6ccccc6)c5)nc(-c5ccccc5)n4)cc3)cccc21]

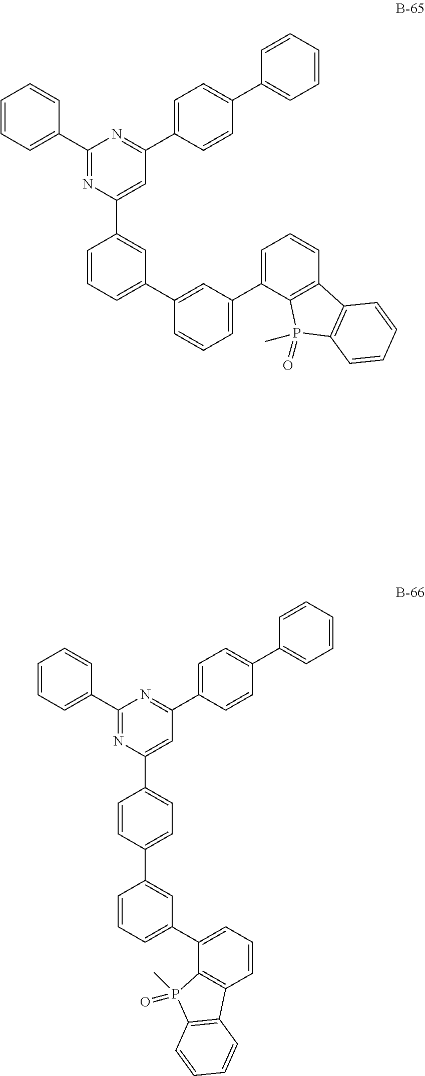 [SMILES: CP1(=O)c2ccccc2-c2cccc(-c3cccc(-c4cccc(-c5cc(-c6ccc(-c7ccccc7)cc6)nc(-c6ccccc6)n5)c4)c3)c21 ; CP1(=O)c2ccccc2-c2cccc(-c3cccc(-c4ccc(-c5cc(-c6ccc(-c7ccccc7)cc6)nc(-c6ccccc6)n5)cc4)c3)c21]

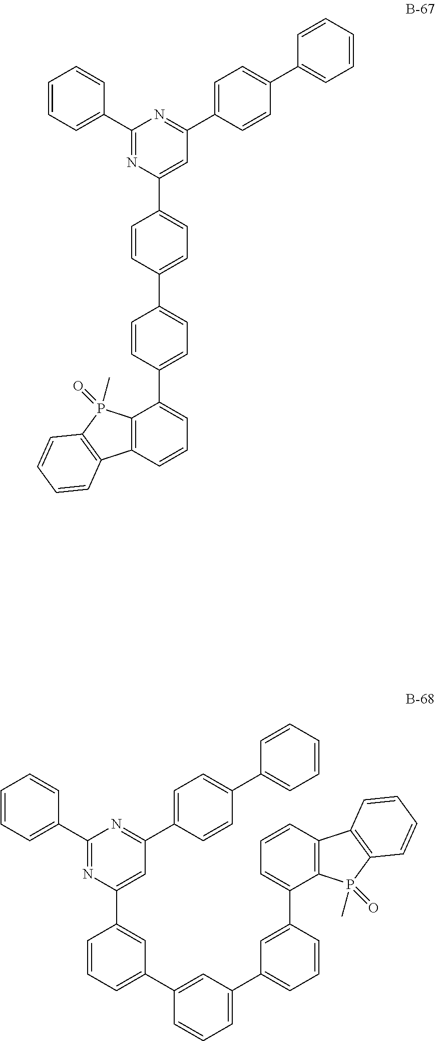 [SMILES: CP1(=O)c2ccccc2-c2cccc(-c3ccc(-c4ccc(-c5cc(-c6ccc(-c7ccccc7)cc6)nc(-c6ccccc6)n5)cc4)cc3)c21 ; CP1(=O)c2ccccc2-c2cccc(-c3cccc(-c4cccc(-c5cccc(-c6cc(-c7ccc(-c8ccccc8)cc7)nc(-c7ccccc7)n6)c5)c4)c3)c21]

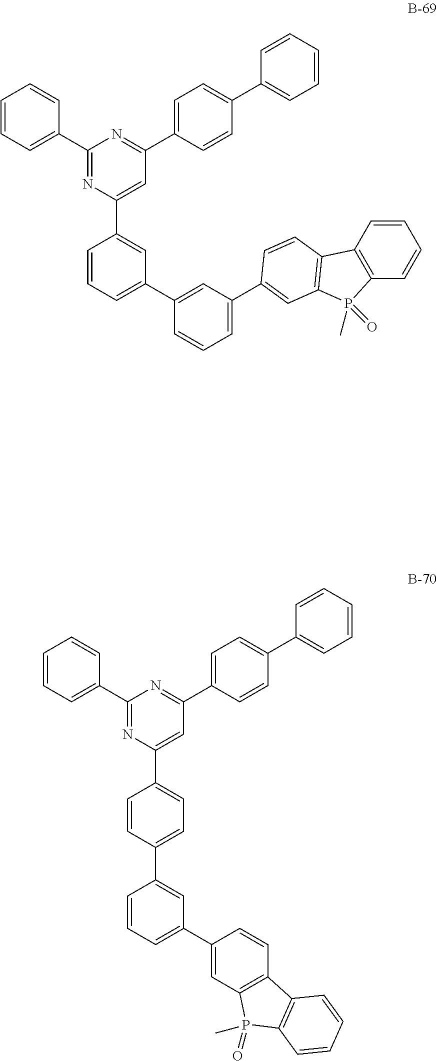 [SMILES: CP1(=O)c2ccccc2-c2ccc(-c3cccc(-c4cccc(-c5cc(-c6ccc(-c7ccccc7)cc6)nc(-c6ccccc6)n5)c4)c3)cc21 ; CP1(=O)c2ccccc2-c2ccc(-c3cccc(-c4ccc(-c5cc(-c6ccc(-c7ccccc7)cc6)nc(-c6ccccc6)n5)cc4)c3)cc21]

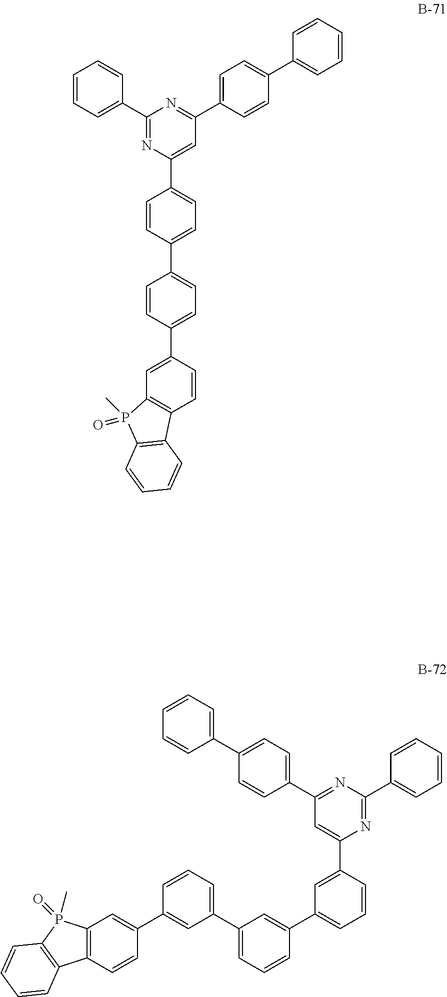 [SMILES: CP1(=O)c2ccccc2-c2ccc(-c3ccc(-c4ccc(-c5cc(-c6ccc(-c7ccccc7)cc6)nc(-c6ccccc6)n5)cc4)cc3)cc21 ; CP1(=O)c2ccccc2-c2ccc(-c3cccc(-c4cccc(-c5cccc(-c6cc(-c7ccc(-c8ccccc8)cc7)nc(-c7ccccc7)n6)c5)c4)c3)cc21]

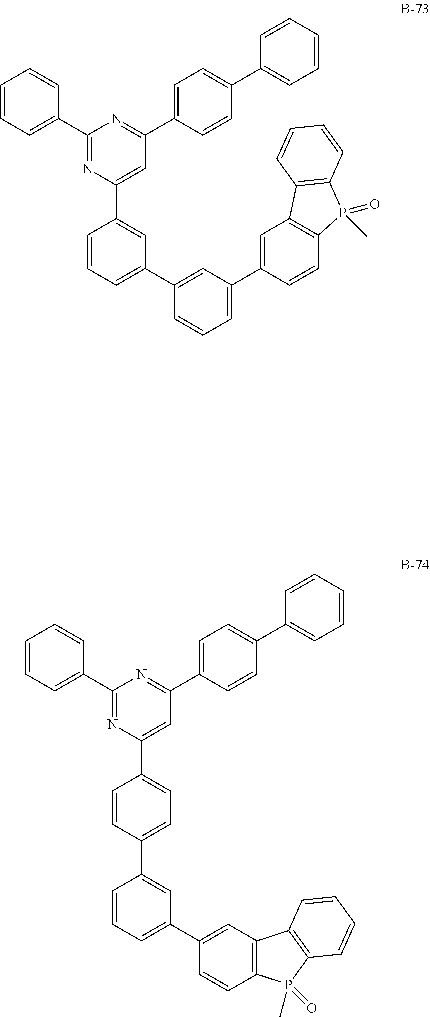 [SMILES: CP1(=O)c2ccccc2-c2cc(-c3cccc(-c4cccc(-c5cc(-c6ccc(-c7ccccc7)cc6)nc(-c6ccccc6)n5)c4)c3)ccc21 ; CP1(=O)c2ccccc2-c2cc(-c3cccc(-c4ccc(-c5cc(-c6ccc(-c7ccccc7)cc6)nc(-c6ccccc6)n5)cc4)c3)ccc21]

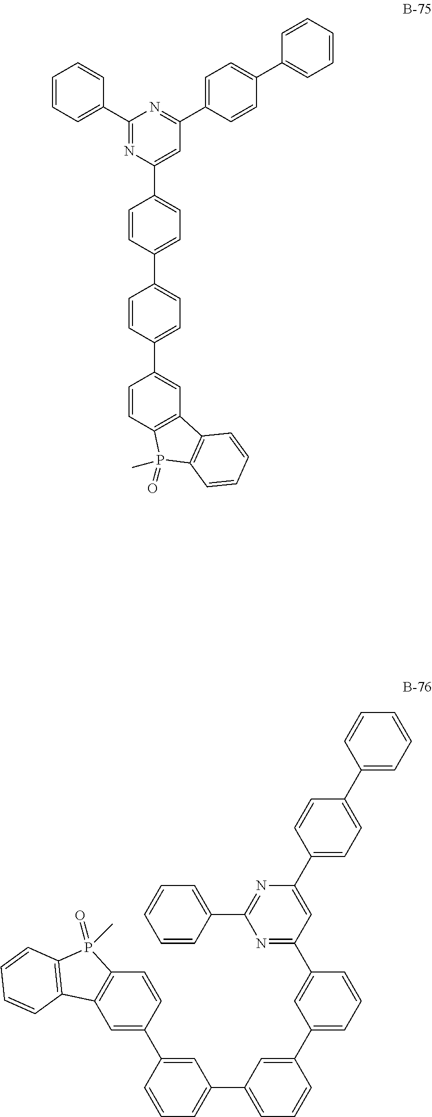 [SMILES: CP1(=O)c2ccccc2-c2cc(-c3ccc(-c4ccc(-c5cc(-c6ccc(-c7ccccc7)cc6)nc(-c6ccccc6)n5)cc4)cc3)ccc21 ; CP1(=O)c2ccccc2-c2cc(-c3cccc(-c4cccc(-c5cccc(-c6cc(-c7ccc(-c8ccccc8)cc7)nc(-c7ccccc7)n6)c5)c4)c3)ccc21]

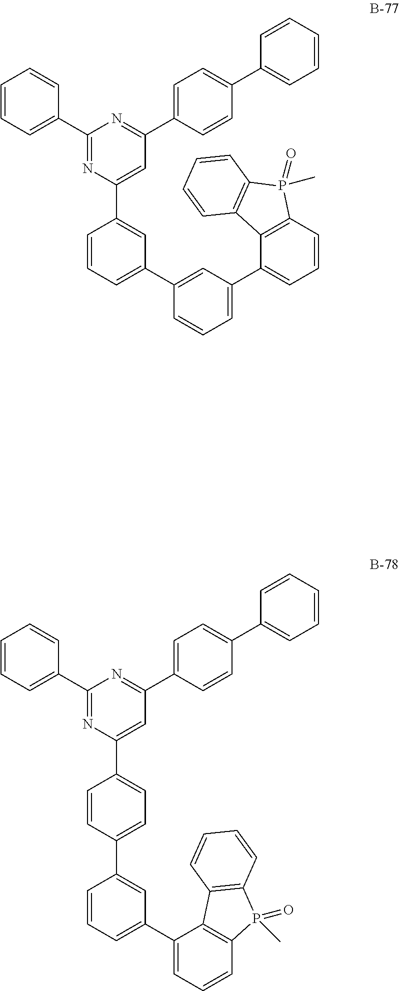 [SMILES: CP1(=O)c2ccccc2-c2c(-c3cccc(-c4cccc(-c5cc(-c6ccc(-c7ccccc7)cc6)nc(-c6ccccc6)n5)c4)c3)cccc21 ; CP1(=O)c2ccccc2-c2c(-c3cccc(-c4ccc(-c5cc(-c6ccc(-c7ccccc7)cc6)nc(-c6ccccc6)n5)cc4)c3)cccc21]

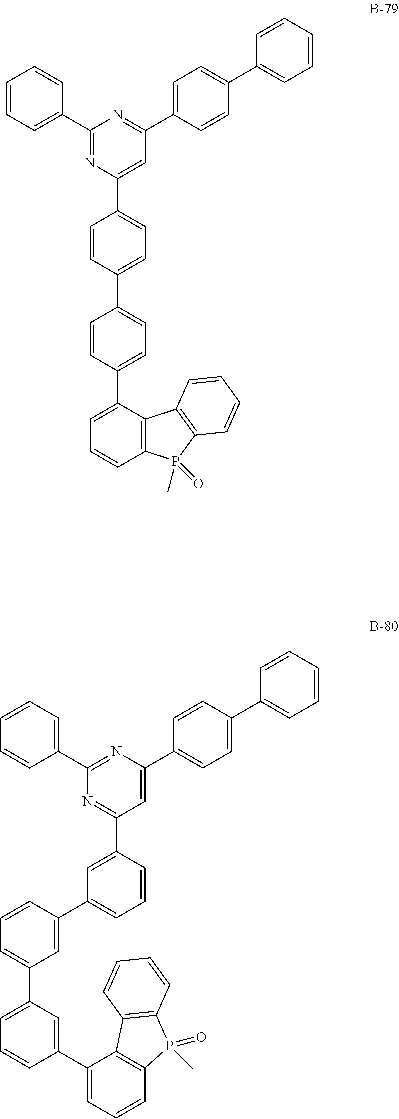 [SMILES: CP1(=O)c2ccccc2-c2c(-c3ccc(-c4ccc(-c5cc(-c6ccc(-c7ccccc7)cc6)nc(-c6ccccc6)n5)cc4)cc3)cccc21 ; CP1(=O)c2ccccc2-c2c(-c3cccc(-c4cccc(-c5cccc(-c6cc(-c7ccc(-c8ccccc8)cc7)nc(-c7ccccc7)n6)c5)c4)c3)cccc21]

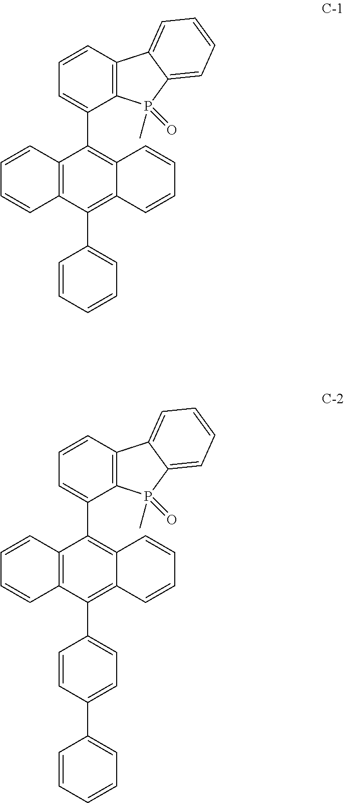 [SMILES: CP1(=O)c2ccccc2-c2cccc(-c3c4ccccc4c(-c4ccccc4)c4ccccc34)c21 ; CP1(=O)c2ccccc2-c2cccc(-c3c4ccccc4c(-c4ccc(-c5ccccc5)cc4)c4ccccc34)c21]

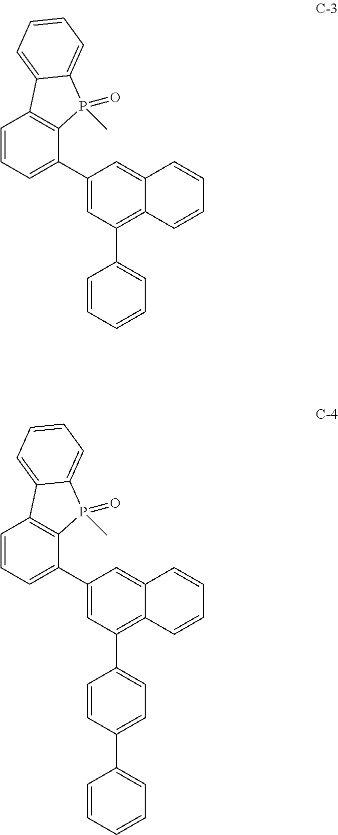 [SMILES: CP1(=O)c2ccccc2-c2cccc(-c3cc(-c4ccccc4)c4ccccc4c3)c21 ; CP1(=O)c2ccccc2-c2cccc(-c3cc(-c4ccc(-c5ccccc5)cc4)c4ccccc4c3)c21]

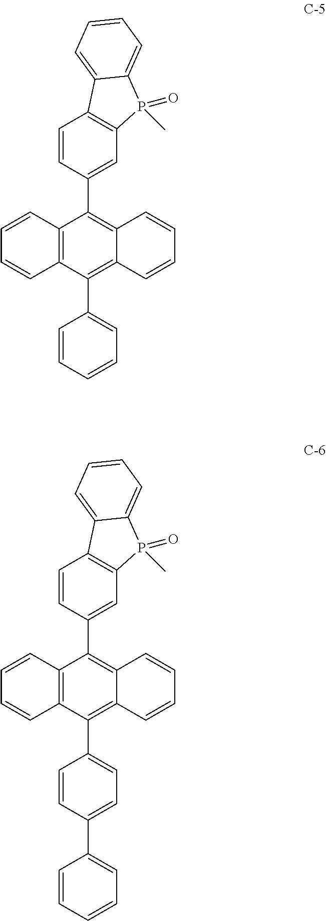 [SMILES: CP1(=O)c2ccccc2-c2ccc(-c3c4ccccc4c(-c4ccccc4)c4ccccc34)cc21 ; CP1(=O)c2ccccc2-c2ccc(-c3c4ccccc4c(-c4ccc(-c5ccccc5)cc4)c4ccccc34)cc21]

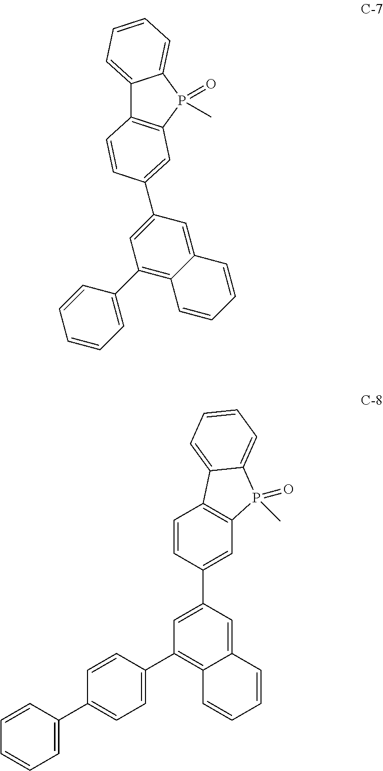 [SMILES: CP1(=O)c2ccccc2-c2ccc(-c3cc(-c4ccccc4)c4ccccc4c3)cc21 ; CP1(=O)c2ccccc2-c2ccc(-c3cc(-c4ccc(-c5ccccc5)cc4)c4ccccc4c3)cc21]

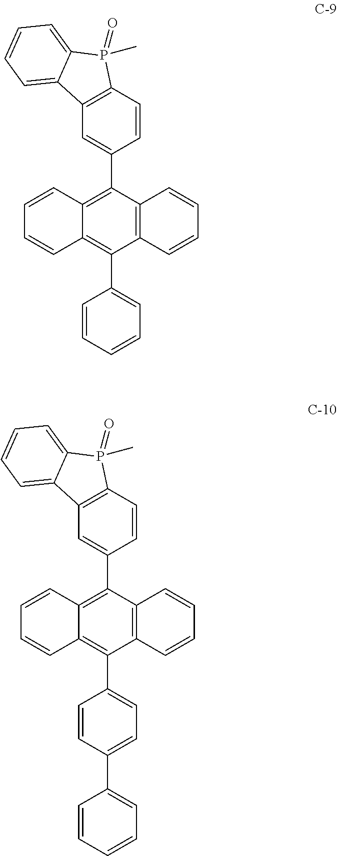 [SMILES: CP1(=O)c2ccccc2-c2cc(-c3c4ccccc4c(-c4ccccc4)c4ccccc34)ccc21 ; CP1(=O)c2ccccc2-c2cc(-c3c4ccccc4c(-c4ccc(-c5ccccc5)cc4)c4ccccc34)ccc21]

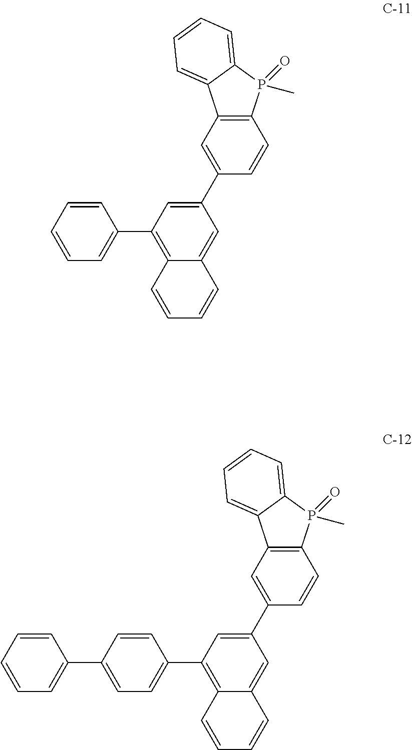 [SMILES: CP1(=O)c2ccccc2-c2cc(-c3cc(-c4ccccc4)c4ccccc4c3)ccc21 ; CP1(=O)c2ccccc2-c2cc(-c3cc(-c4ccc(-c5ccccc5)cc4)c4ccccc4c3)ccc21]

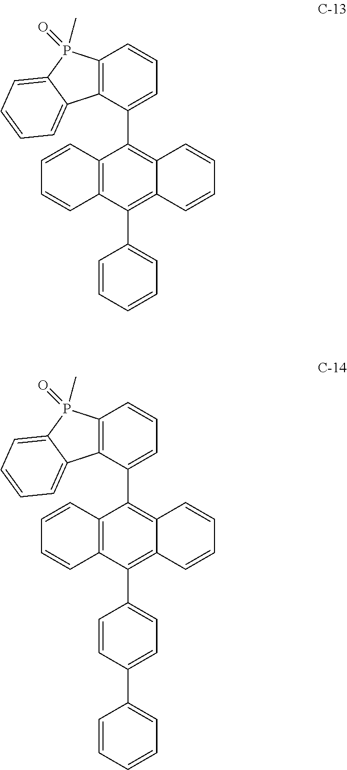 [SMILES: CP1(=O)c2ccccc2-c2c(-c3c4ccccc4c(-c4ccccc4)c4ccccc34)cccc21 ; CP1(=O)c2ccccc2-c2c(-c3c4ccccc4c(-c4ccc(-c5ccccc5)cc4)c4ccccc34)cccc21]

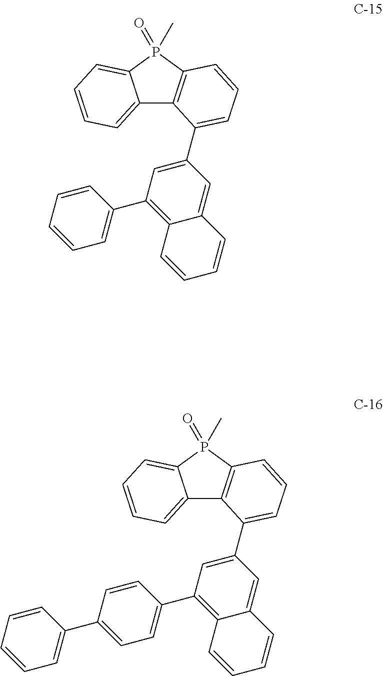 [SMILES: CP1(=O)c2ccccc2-c2c(-c3cc(-c4ccccc4)c4ccccc4c3)cccc21 ; CP1(=O)c2ccccc2-c2c(-c3cc(-c4ccc(-c5ccccc5)cc4)c4ccccc4c3)cccc21]

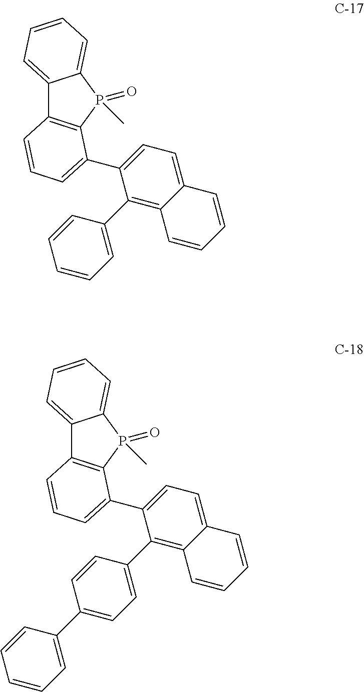 [SMILES: CP1(=O)c2ccccc2-c2cccc(-c3ccc4ccccc4c3-c3ccccc3)c21 ; CP1(=O)c2ccccc2-c2cccc(-c3ccc4ccccc4c3-c3ccc(-c4ccccc4)cc3)c21]

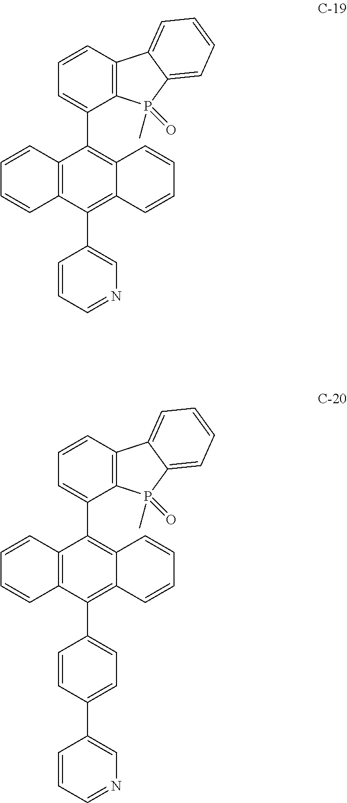 [SMILES: CP1(=O)c2ccccc2-c2cccc(-c3c4ccccc4c(-c4cccnc4)c4ccccc34)c21 ; CP1(=O)c2ccccc2-c2cccc(-c3c4ccccc4c(-c4ccc(-c5cccnc5)cc4)c4ccccc34)c21]

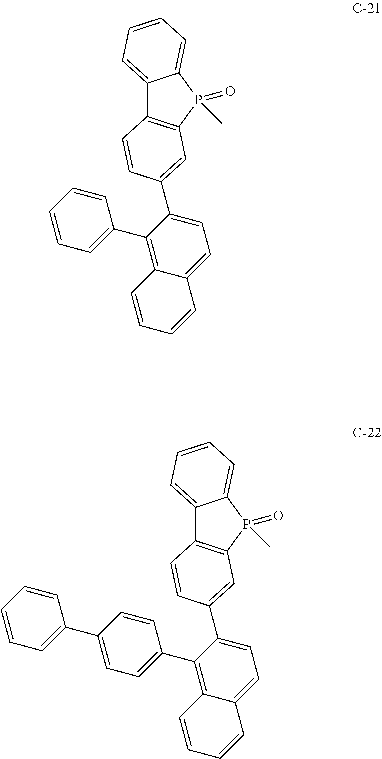 [SMILES: CP1(=O)c2ccccc2-c2ccc(-c3ccc4ccccc4c3-c3ccccc3)cc21 ; CP1(=O)c2ccccc2-c2ccc(-c3ccc4ccccc4c3-c3ccc(-c4ccccc4)cc3)cc21]

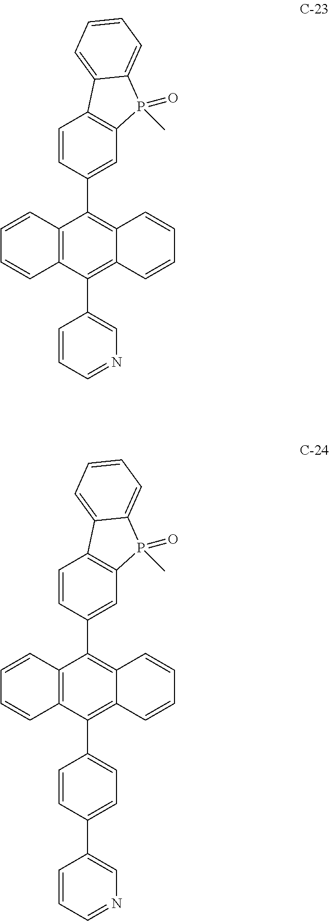 [SMILES: CP1(=O)c2ccccc2-c2ccc(-c3c4ccccc4c(-c4cccnc4)c4ccccc34)cc21 ; CP1(=O)c2ccccc2-c2ccc(-c3c4ccccc4c(-c4ccc(-c5cccnc5)cc4)c4ccccc34)cc21]

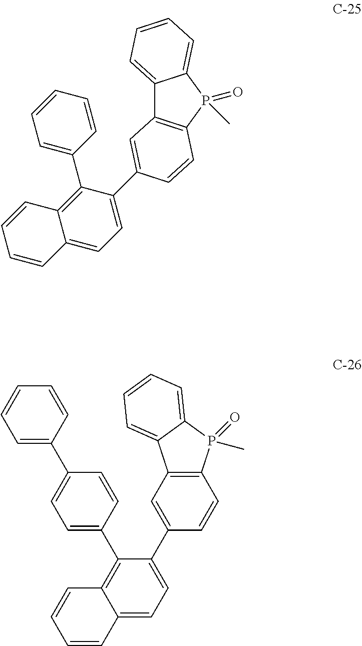 [SMILES: CP1(=O)c2ccccc2-c2cc(-c3ccc4ccccc4c3-c3ccccc3)ccc21 ; CP1(=O)c2ccccc2-c2cc(-c3ccc4ccccc4c3-c3ccc(-c4ccccc4)cc3)ccc21]

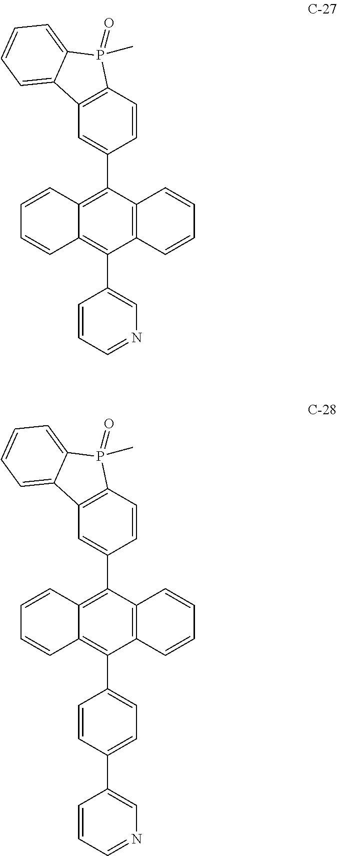 [SMILES: CP1(=O)c2ccccc2-c2cc(-c3c4ccccc4c(-c4cccnc4)c4ccccc34)ccc21 ; CP1(=O)c2ccccc2-c2cc(-c3c4ccccc4c(-c4ccc(-c5cccnc5)cc4)c4ccccc34)ccc21]

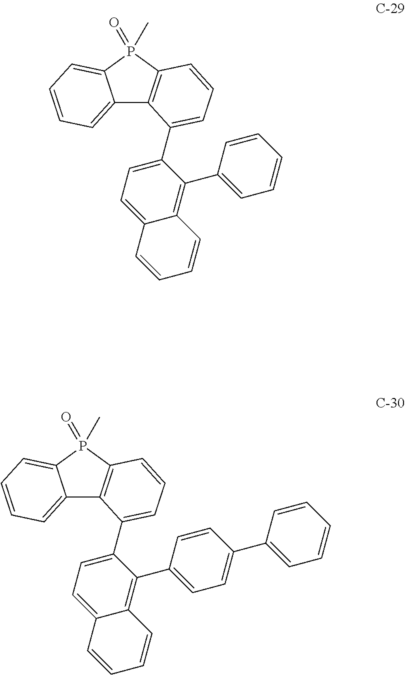 [SMILES: CP1(=O)c2ccccc2-c2c(-c3ccc4ccccc4c3-c3ccccc3)cccc21 ; CP1(=O)c2ccccc2-c2c(-c3ccc4ccccc4c3-c3ccc(-c4ccccc4)cc3)cccc21]

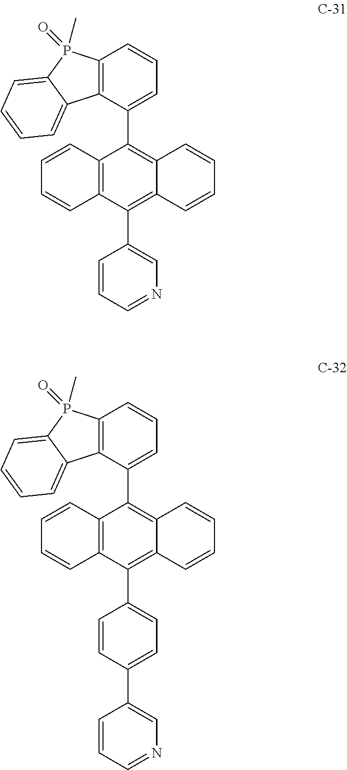 [SMILES: CP1(=O)c2ccccc2-c2c(-c3c4ccccc4c(-c4cccnc4)c4ccccc34)cccc21 ; CP1(=O)c2ccccc2-c2c(-c3c4ccccc4c(-c4ccc(-c5cccnc5)cc4)c4ccccc34)cccc21]

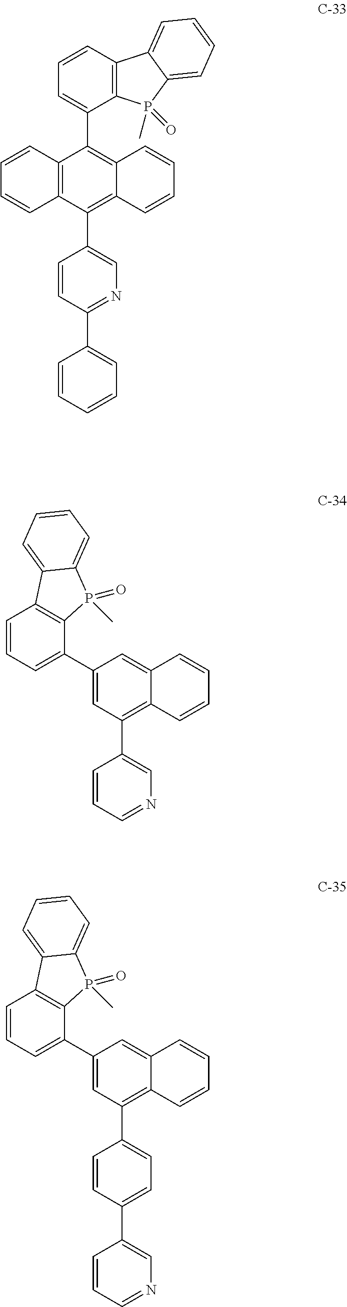 [SMILES: CP1(=O)c2ccccc2-c2cccc(-c3c4ccccc4c(-c4ccc(-c5ccccc5)nc4)c4ccccc34)c21 ; CP1(=O)c2ccccc2-c2cccc(-c3cc(-c4cccnc4)c4ccccc4c3)c21 ; CP1(=O)c2ccccc2-c2cccc(-c3cc(-c4ccc(-c5cccnc5)cc4)c4ccccc4c3)c21]

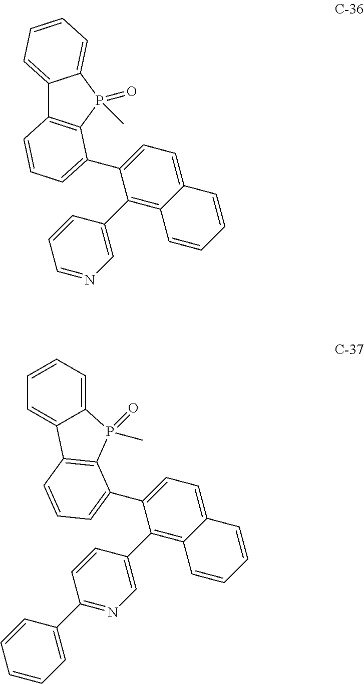 [SMILES: CP1(=O)c2ccccc2-c2cccc(-c3ccc4ccccc4c3-c3cccnc3)c21 ; CP1(=O)c2ccccc2-c2cccc(-c3ccc4ccccc4c3-c3ccc(-c4ccccc4)nc3)c21]

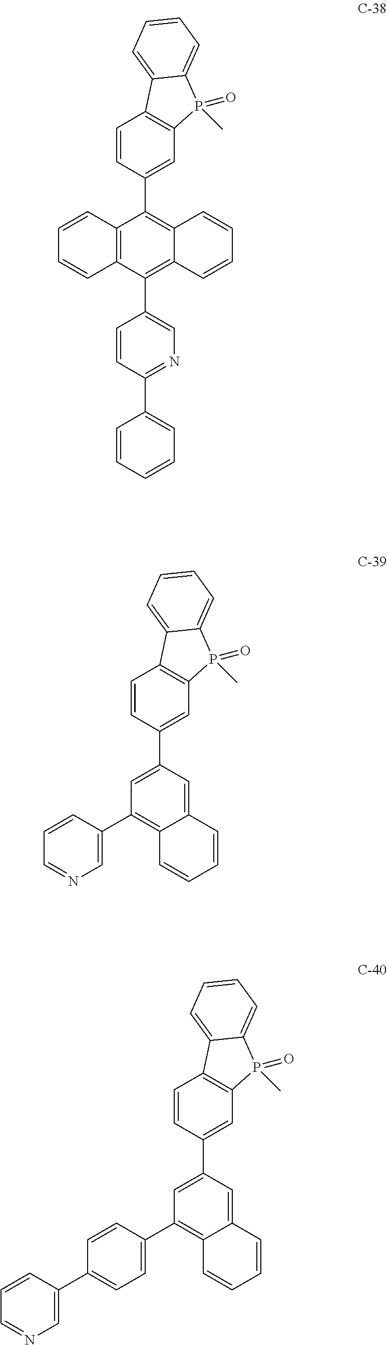 [SMILES: CP1(=O)c2ccccc2-c2ccc(-c3c4ccccc4c(-c4ccc(-c5ccccc5)nc4)c4ccccc34)cc21 ; CP1(=O)c2ccccc2-c2ccc(-c3cc(-c4cccnc4)c4ccccc4c3)cc21 ; CP1(=O)c2ccccc2-c2ccc(-c3cc(-c4ccc(-c5cccnc5)cc4)c4ccccc4c3)cc21]

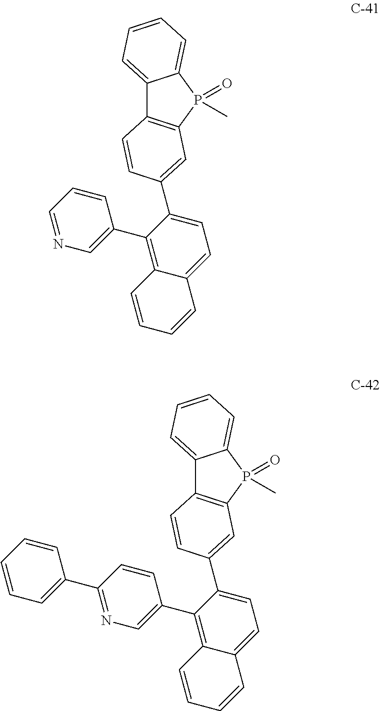 [SMILES: CP1(=O)c2ccccc2-c2ccc(-c3ccc4ccccc4c3-c3cccnc3)cc21 ; CP1(=O)c2ccccc2-c2ccc(-c3ccc4ccccc4c3-c3ccc(-c4ccccc4)nc3)cc21]

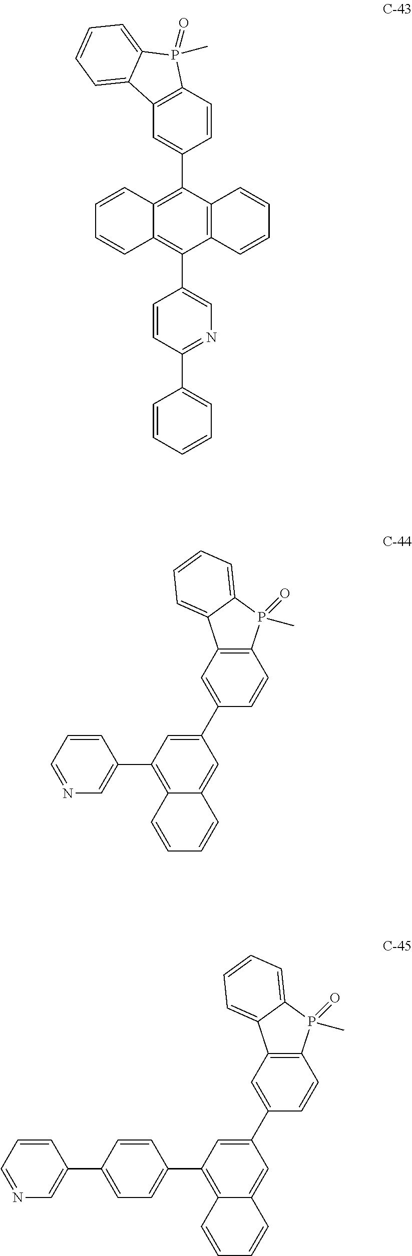 [SMILES: CP1(=O)c2ccccc2-c2cc(-c3c4ccccc4c(-c4ccc(-c5ccccc5)nc4)c4ccccc34)ccc21 ; CP1(=O)c2ccccc2-c2cc(-c3cc(-c4cccnc4)c4ccccc4c3)ccc21 ; CP1(=O)c2ccccc2-c2cc(-c3cc(-c4ccc(-c5cccnc5)cc4)c4ccccc4c3)ccc21]

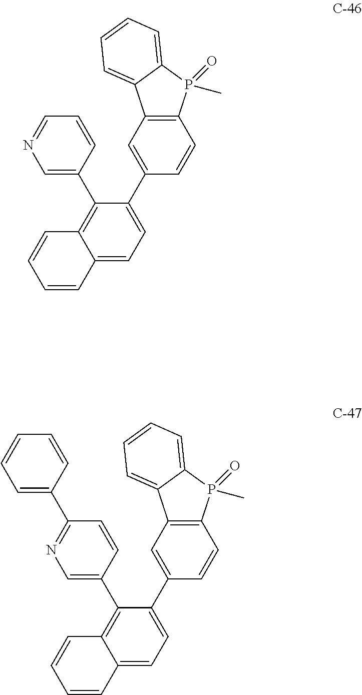 [SMILES: CP1(=O)c2ccccc2-c2cc(-c3ccc4ccccc4c3-c3cccnc3)ccc21 ; CP1(=O)c2ccccc2-c2cc(-c3ccc4ccccc4c3-c3ccc(-c4ccccc4)nc3)ccc21]

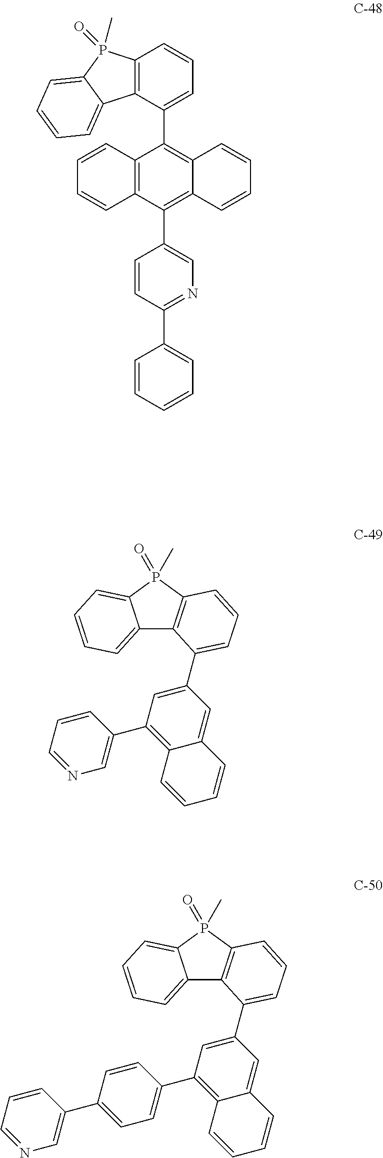 [SMILES: CP1(=O)c2ccccc2-c2c(-c3c4ccccc4c(-c4ccc(-c5ccccc5)nc4)c4ccccc34)cccc21 ; CP1(=O)c2ccccc2-c2c(-c3cc(-c4cccnc4)c4ccccc4c3)cccc21 ; CP1(=O)c2ccccc2-c2c(-c3cc(-c4ccc(-c5cccnc5)cc4)c4ccccc4c3)cccc21]

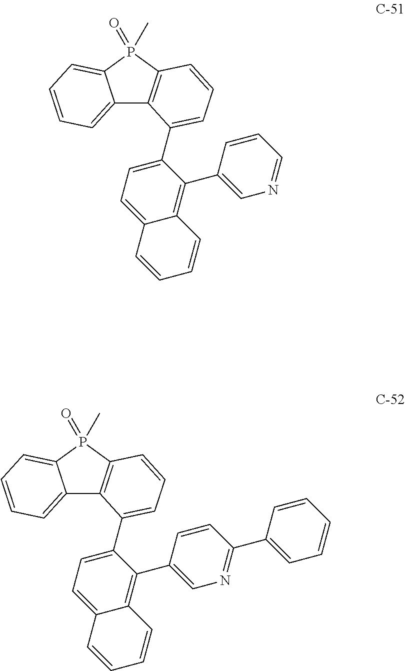 [SMILES: CP1(=O)c2ccccc2-c2c(-c3ccc4ccccc4c3-c3cccnc3)cccc21 ; CP1(=O)c2ccccc2-c2c(-c3ccc4ccccc4c3-c3ccc(-c4ccccc4)nc3)cccc21]

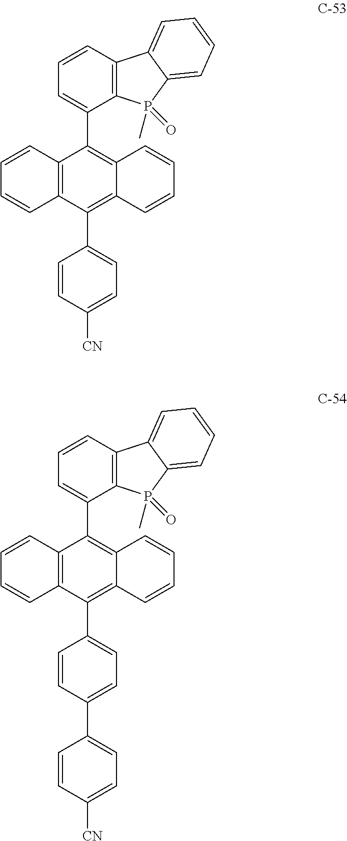 [SMILES: CP1(=O)c2ccccc2-c2cccc(-c3c4ccccc4c(-c4ccc(C#N)cc4)c4ccccc34)c21 ; CP1(=O)c2ccccc2-c2cccc(-c3c4ccccc4c(-c4ccc(-c5ccc(C#N)cc5)cc4)c4ccccc34)c21]

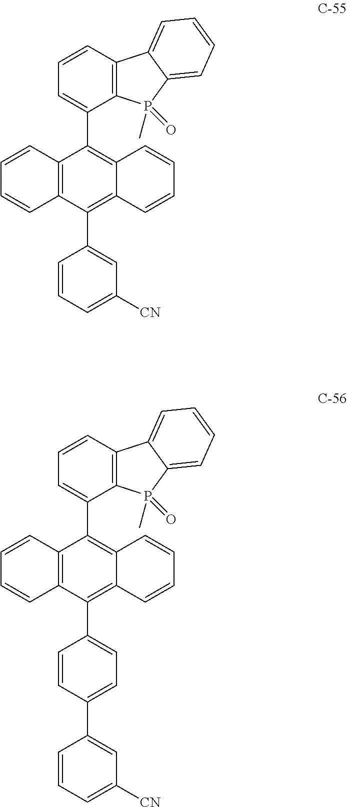 [SMILES: CP1(=O)c2ccccc2-c2cccc(-c3c4ccccc4c(-c4cccc(C#N)c4)c4ccccc34)c21 ; CP1(=O)c2ccccc2-c2cccc(-c3c4ccccc4c(-c4ccc(-c5cccc(C#N)c5)cc4)c4ccccc34)c21]

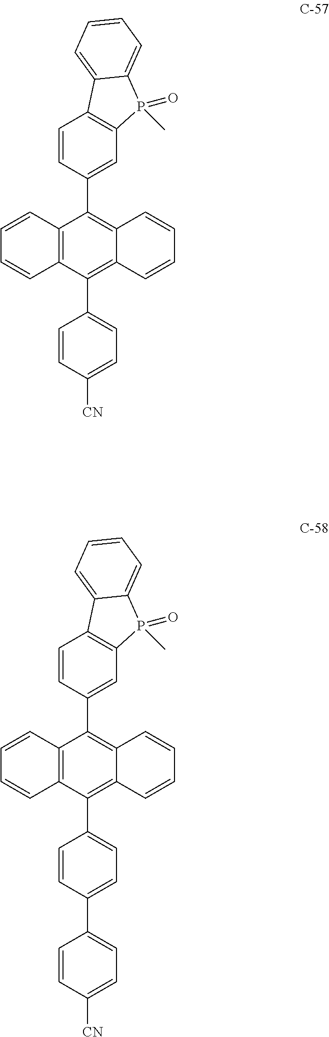 [SMILES: CP1(=O)c2ccccc2-c2ccc(-c3c4ccccc4c(-c4ccc(C#N)cc4)c4ccccc34)cc21 ; CP1(=O)c2ccccc2-c2ccc(-c3c4ccccc4c(-c4ccc(-c5ccc(C#N)cc5)cc4)c4ccccc34)cc21]

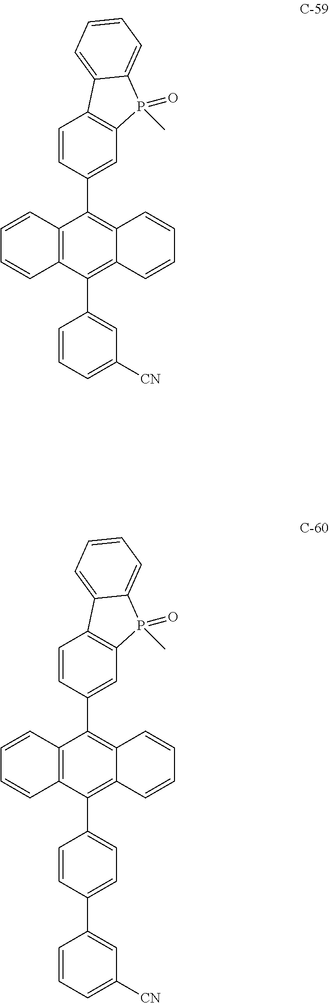 [SMILES: CP1(=O)c2ccccc2-c2ccc(-c3c4ccccc4c(-c4cccc(C#N)c4)c4ccccc34)cc21 ; CP1(=O)c2ccccc2-c2ccc(-c3c4ccccc4c(-c4ccc(-c5cccc(C#N)c5)cc4)c4ccccc34)cc21]

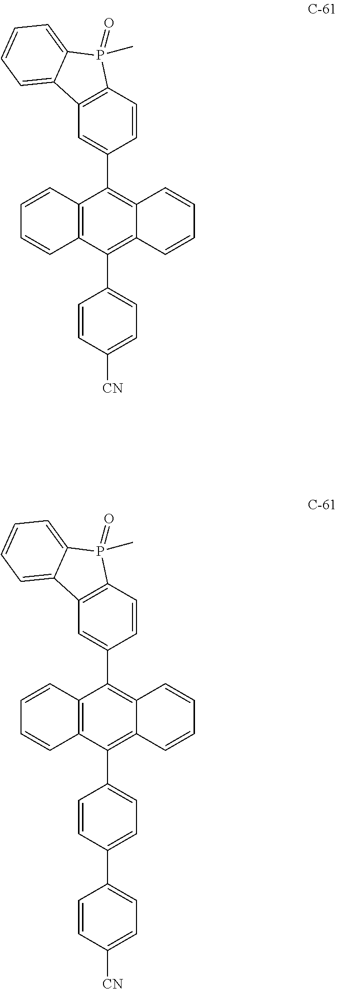 [SMILES: CP1(=O)c2ccccc2-c2cc(-c3c4ccccc4c(-c4ccc(C#N)cc4)c4ccccc34)ccc21 ; CP1(=O)c2ccccc2-c2cc(-c3c4ccccc4c(-c4ccc(-c5ccc(C#N)cc5)cc4)c4ccccc34)ccc21]

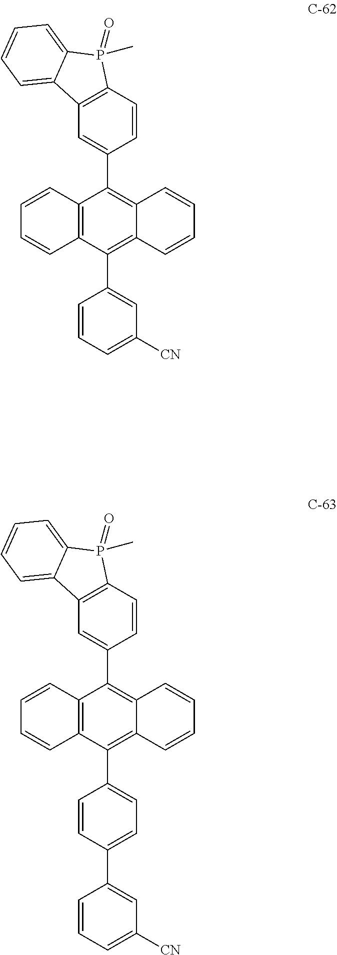 [SMILES: CP1(=O)c2ccccc2-c2cc(-c3c4ccccc4c(-c4cccc(C#N)c4)c4ccccc34)ccc21 ; CP1(=O)c2ccccc2-c2cc(-c3c4ccccc4c(-c4ccc(-c5cccc(C#N)c5)cc4)c4ccccc34)ccc21]

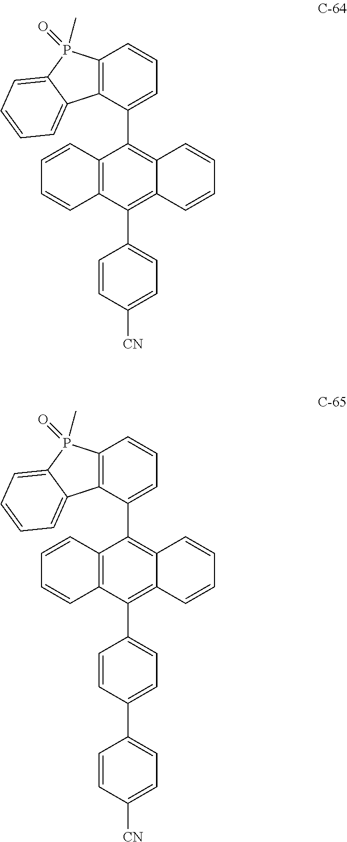 [SMILES: CP1(=O)c2ccccc2-c2c(-c3c4ccccc4c(-c4ccc(C#N)cc4)c4ccccc34)cccc21 ; CP1(=O)c2ccccc2-c2c(-c3c4ccccc4c(-c4ccc(-c5ccc(C#N)cc5)cc4)c4ccccc34)cccc21]

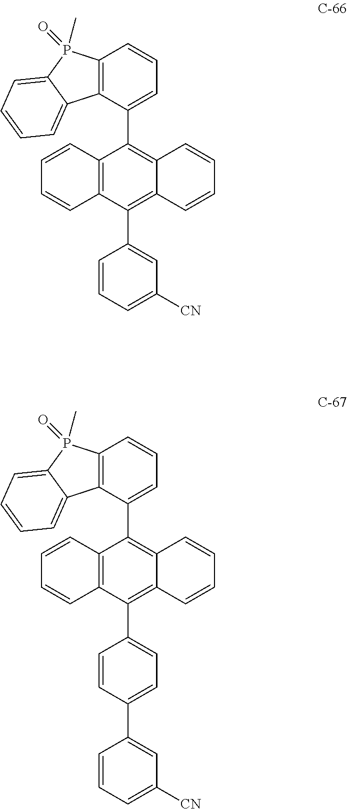 [SMILES: CP1(=O)c2ccccc2-c2c(-c3c4ccccc4c(-c4cccc(C#N)c4)c4ccccc34)cccc21 ; CP1(=O)c2ccccc2-c2c(-c3c4ccccc4c(-c4ccc(-c5cccc(C#N)c5)cc4)c4ccccc34)cccc21]

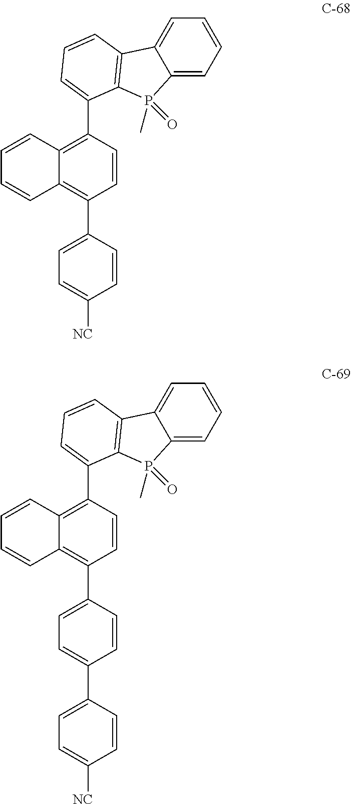 [SMILES: CP1(=O)c2ccccc2-c2cccc(-c3ccc(-c4ccc(C#N)cc4)c4ccccc34)c21 ; CP1(=O)c2ccccc2-c2cccc(-c3ccc(-c4ccc(-c5ccc(C#N)cc5)cc4)c4ccccc34)c21]

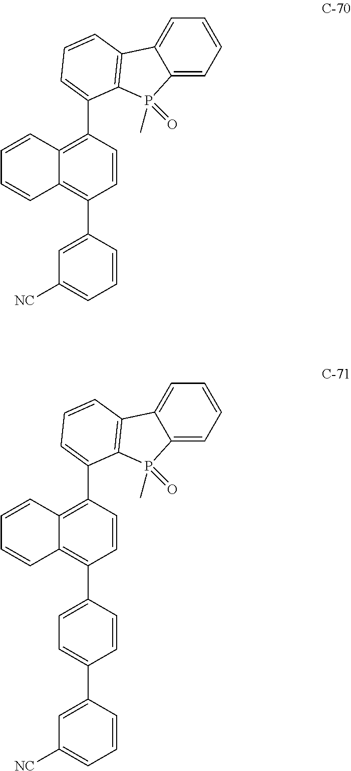 [SMILES: CP1(=O)c2ccccc2-c2cccc(-c3ccc(-c4cccc(C#N)c4)c4ccccc34)c21 ; CP1(=O)c2ccccc2-c2cccc(-c3ccc(-c4ccc(-c5cccc(C#N)c5)cc4)c4ccccc34)c21]

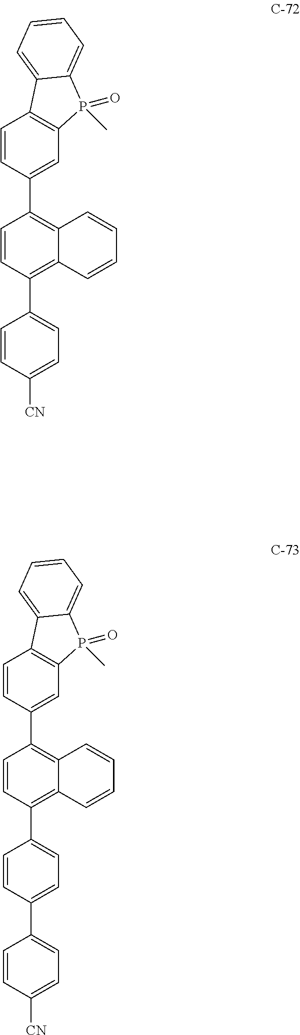 [SMILES: CP1(=O)c2ccccc2-c2ccc(-c3ccc(-c4ccc(C#N)cc4)c4ccccc34)cc21 ; CP1(=O)c2ccccc2-c2ccc(-c3ccc(-c4ccc(-c5ccc(C#N)cc5)cc4)c4ccccc34)cc21]

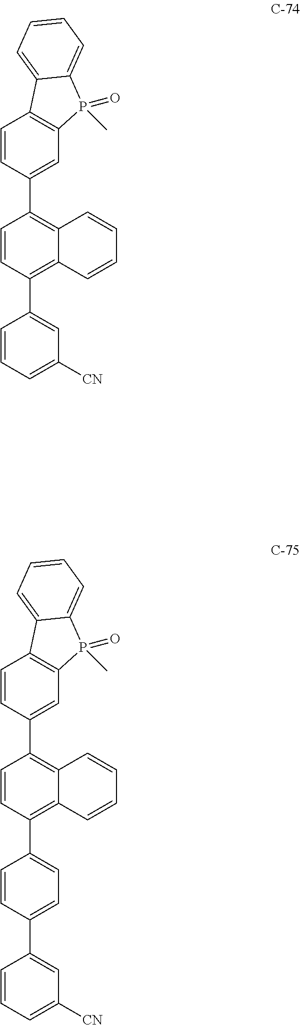 [SMILES: CP1(=O)c2ccccc2-c2ccc(-c3ccc(-c4cccc(C#N)c4)c4ccccc34)cc21 ; CP1(=O)c2ccccc2-c2ccc(-c3ccc(-c4ccc(-c5cccc(C#N)c5)cc4)c4ccccc34)cc21]

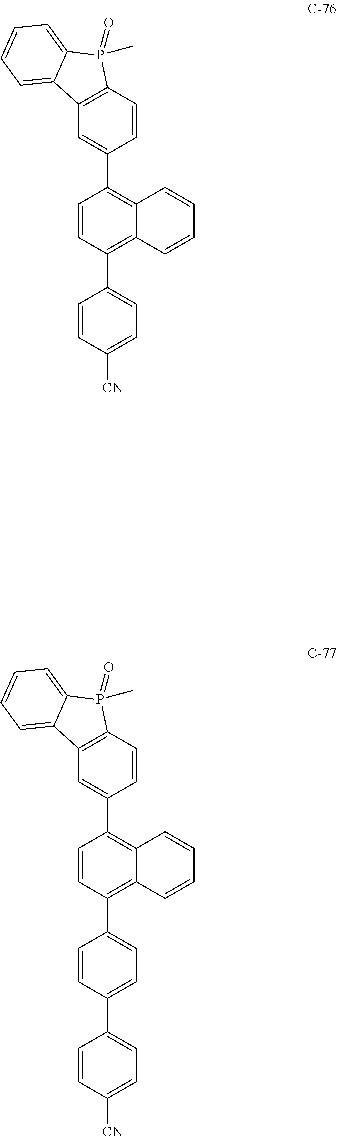 [SMILES: CP1(=O)c2ccccc2-c2cc(-c3ccc(-c4ccc(C#N)cc4)c4ccccc34)ccc21 ; CP1(=O)c2ccccc2-c2cc(-c3ccc(-c4ccc(-c5ccc(C#N)cc5)cc4)c4ccccc34)ccc21]

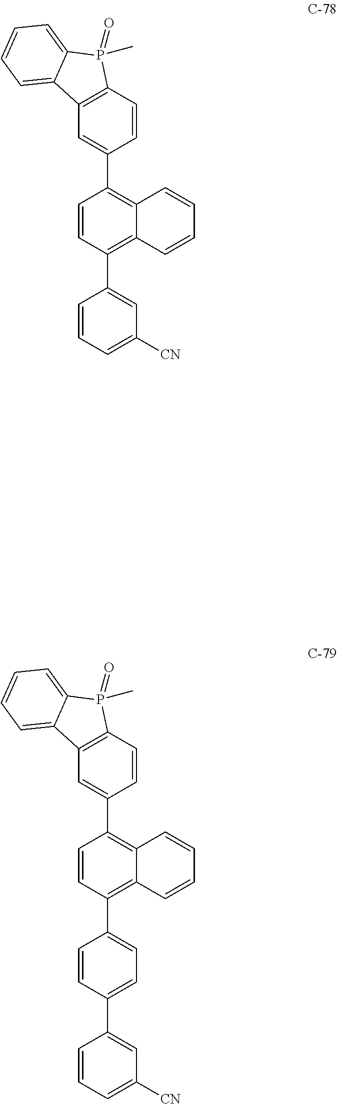 [SMILES: CP1(=O)c2ccccc2-c2cc(-c3ccc(-c4cccc(C#N)c4)c4ccccc34)ccc21 ; CP1(=O)c2ccccc2-c2cc(-c3ccc(-c4ccc(-c5cccc(C#N)c5)cc4)c4ccccc34)ccc21]

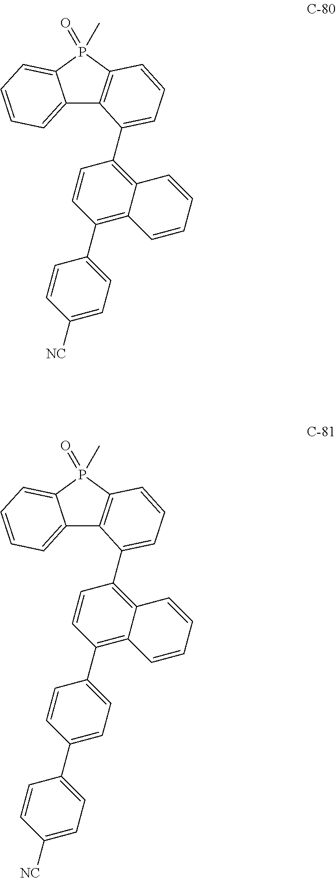 [SMILES: CP1(=O)c2ccccc2-c2c(-c3ccc(-c4ccc(C#N)cc4)c4ccccc34)cccc21 ; CP1(=O)c2ccccc2-c2c(-c3ccc(-c4ccc(-c5ccc(C#N)cc5)cc4)c4ccccc34)cccc21]

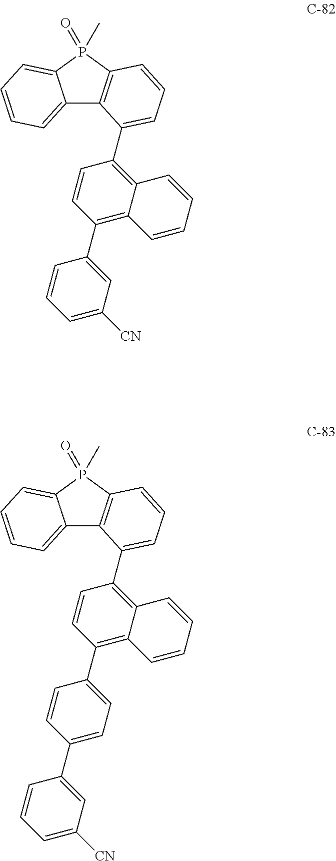 [SMILES: CP1(=O)c2ccccc2-c2c(-c3ccc(-c4cccc(C#N)c4)c4ccccc34)cccc21 ; CP1(=O)c2ccccc2-c2c(-c3ccc(-c4ccc(-c5cccc(C#N)c5)cc4)c4ccccc34)cccc21]

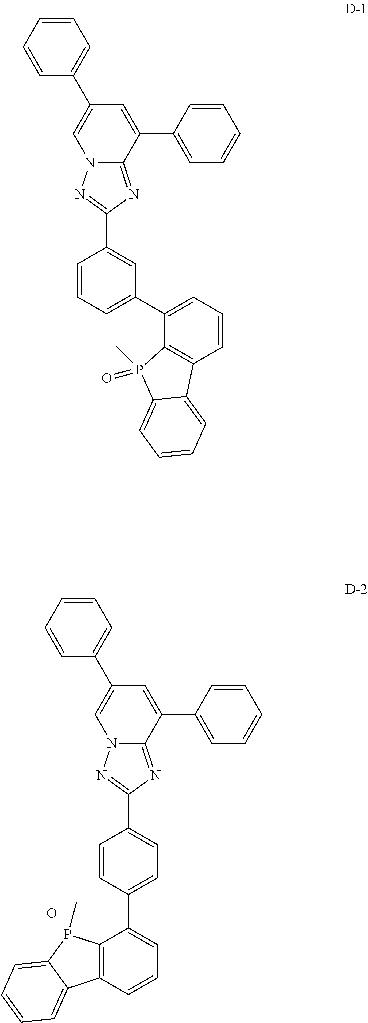

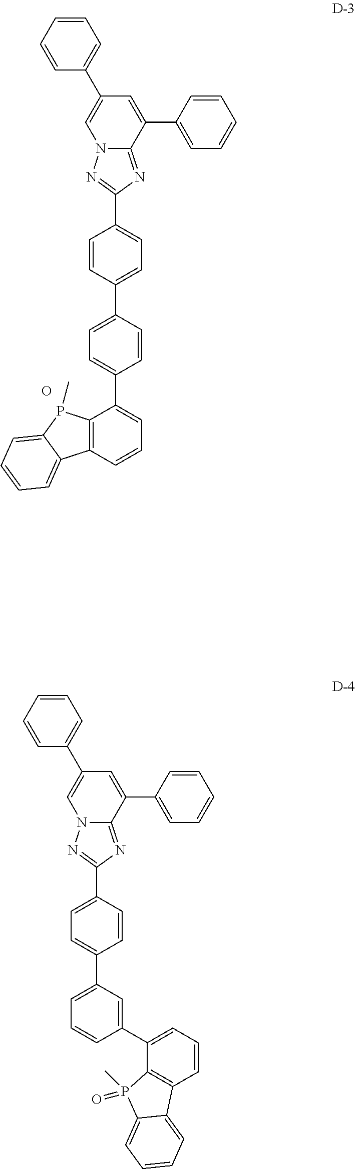

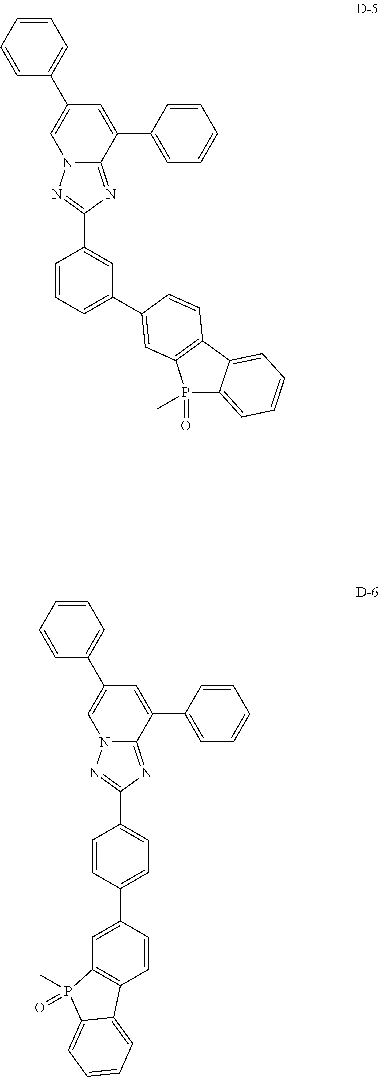 [SMILES: CP1(=O)c2ccccc2-c2ccc(-c3cccc(-c4nc5c(-c6ccccc6)cc(-c6ccccc6)cn5n4)c3)cc21 ; CP1(=O)c2ccccc2-c2ccc(-c3ccc(-c4nc5c(-c6ccccc6)cc(-c6ccccc6)cn5n4)cc3)cc21]

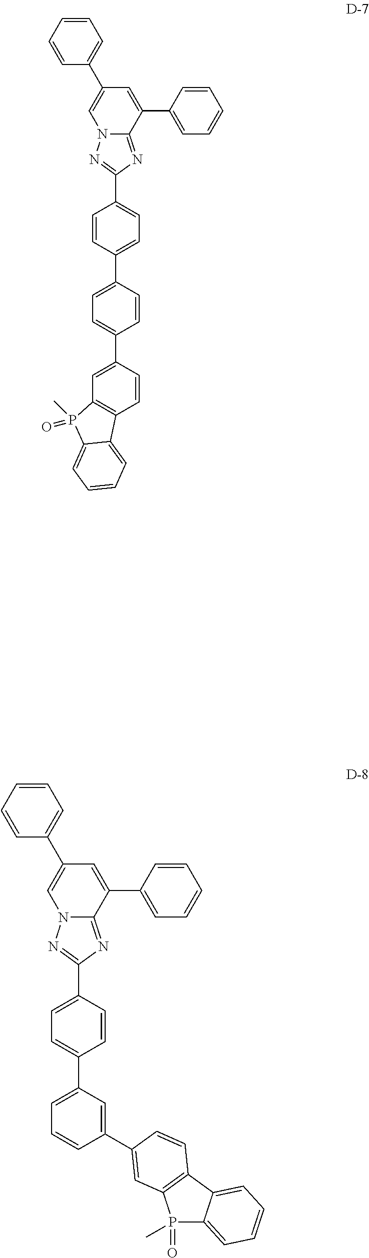 [SMILES: CP1(=O)c2ccccc2-c2ccc(-c3ccc(-c4ccc(-c5nc6c(-c7ccccc7)cc(-c7ccccc7)cn6n5)cc4)cc3)cc21 ; CP1(=O)c2ccccc2-c2ccc(-c3cccc(-c4ccc(-c5nc6c(-c7ccccc7)cc(-c7ccccc7)cn6n5)cc4)c3)cc21]

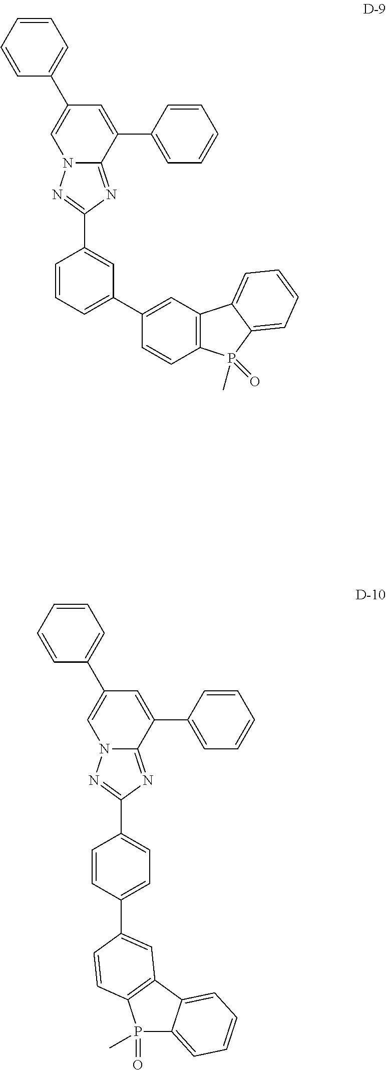 [SMILES: CP1(=O)c2ccccc2-c2cc(-c3cccc(-c4nc5c(-c6ccccc6)cc(-c6ccccc6)cn5n4)c3)ccc21 ; CP1(=O)c2ccccc2-c2cc(-c3ccc(-c4nc5c(-c6ccccc6)cc(-c6ccccc6)cn5n4)cc3)ccc21]

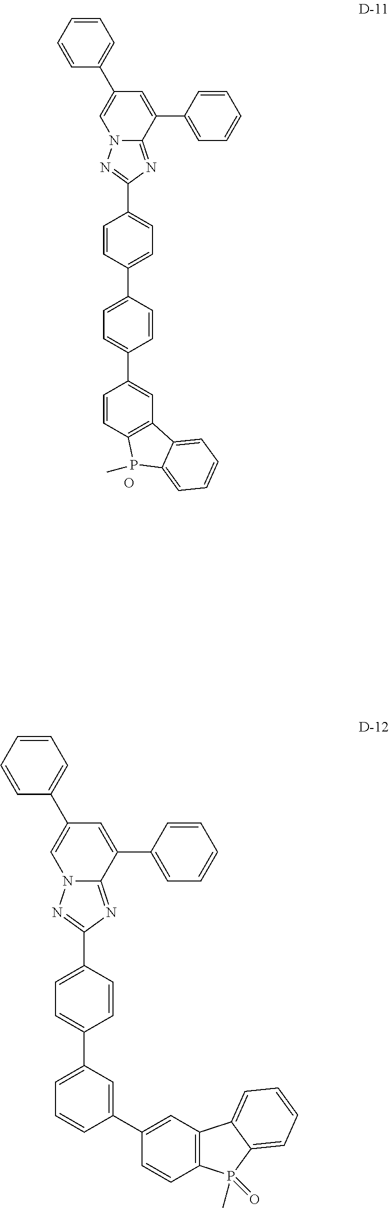

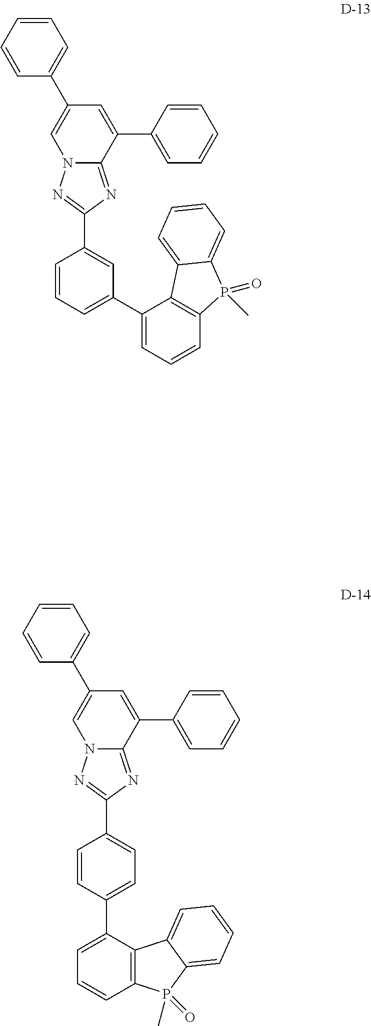 [SMILES: CP1(=O)c2ccccc2-c2c(-c3cccc(-c4nc5c(-c6ccccc6)cc(-c6ccccc6)cn5n4)c3)cccc21 ; CP1(=O)c2ccccc2-c2c(-c3ccc(-c4nc5c(-c6ccccc6)cc(-c6ccccc6)cn5n4)cc3)cccc21]

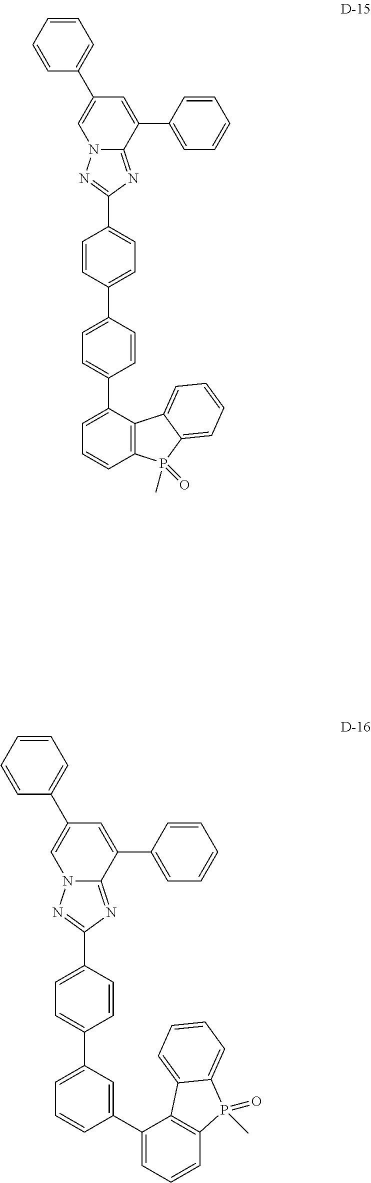 [SMILES: CP1(=O)c2ccccc2-c2c(-c3ccc(-c4ccc(-c5nc6c(-c7ccccc7)cc(-c7ccccc7)cn6n5)cc4)cc3)cccc21 ; CP1(=O)c2ccccc2-c2c(-c3cccc(-c4ccc(-c5nc6c(-c7ccccc7)cc(-c7ccccc7)cn6n5)cc4)c3)cccc21]

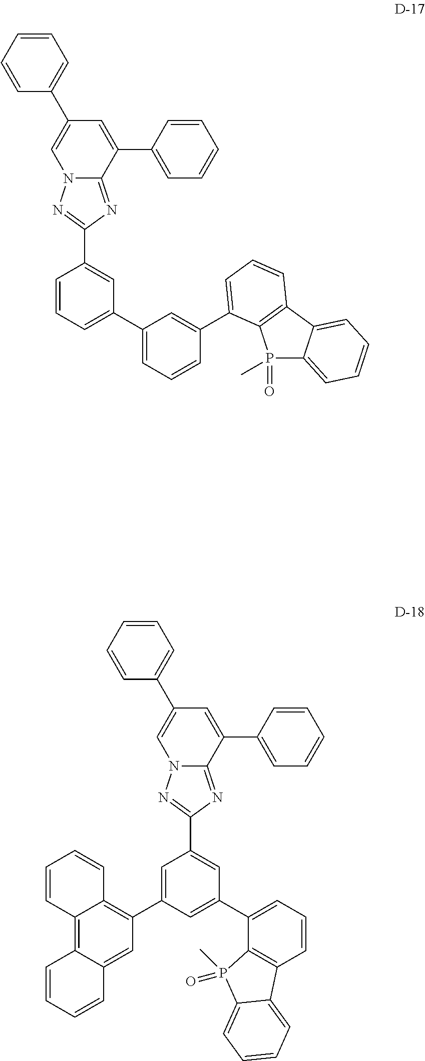 [SMILES: CP1(=O)c2ccccc2-c2cccc(-c3cccc(-c4cccc(-c5nc6c(-c7ccccc7)cc(-c7ccccc7)cn6n5)c4)c3)c21 ; CP1(=O)c2ccccc2-c2cccc(-c3cc(-c4nc5c(-c6ccccc6)cc(-c6ccccc6)cn5n4)cc(-c4cc5ccccc5c5ccccc45)c3)c21]

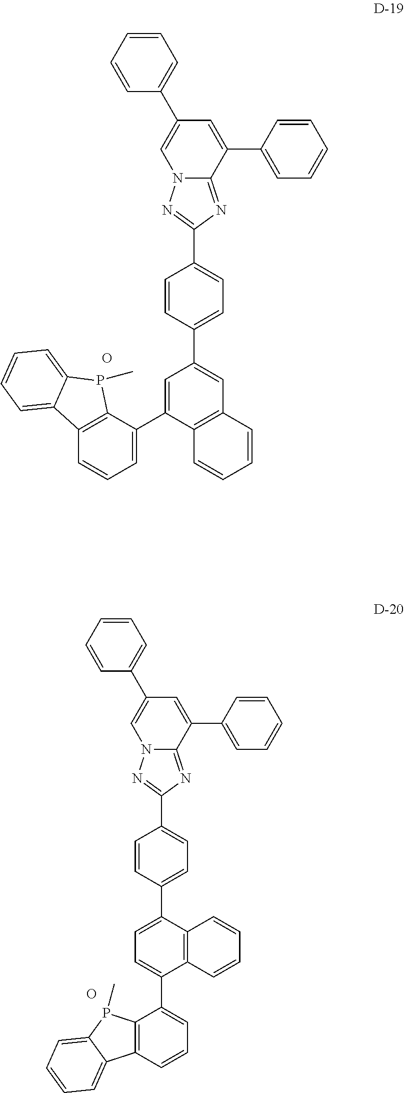

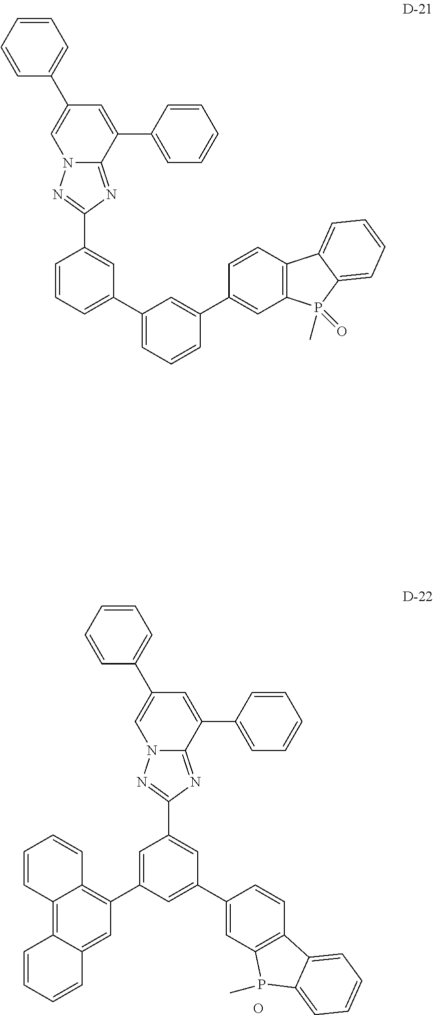

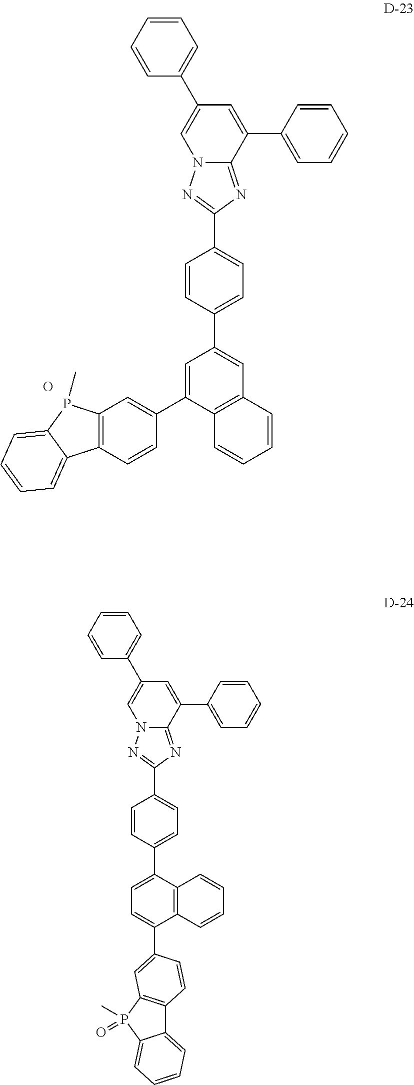

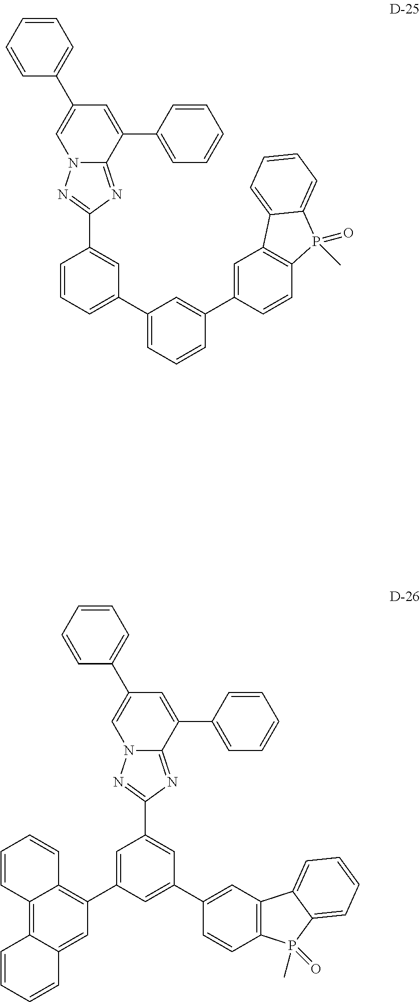 [SMILES: CP1(=O)c2ccccc2-c2cc(-c3cccc(-c4cccc(-c5nc6c(-c7ccccc7)cc(-c7ccccc7)cn6n5)c4)c3)ccc21 ; CP1(=O)c2ccccc2-c2cc(-c3cc(-c4nc5c(-c6ccccc6)cc(-c6ccccc6)cn5n4)cc(-c4cc5ccccc5c5ccccc45)c3)ccc21]

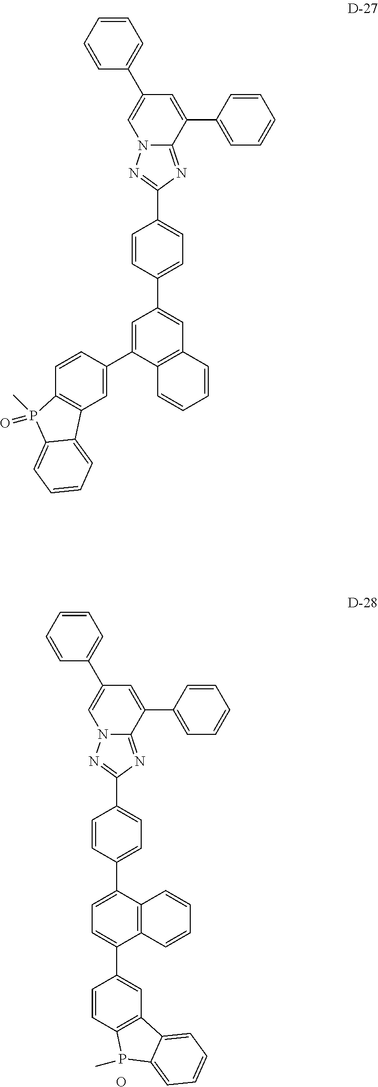

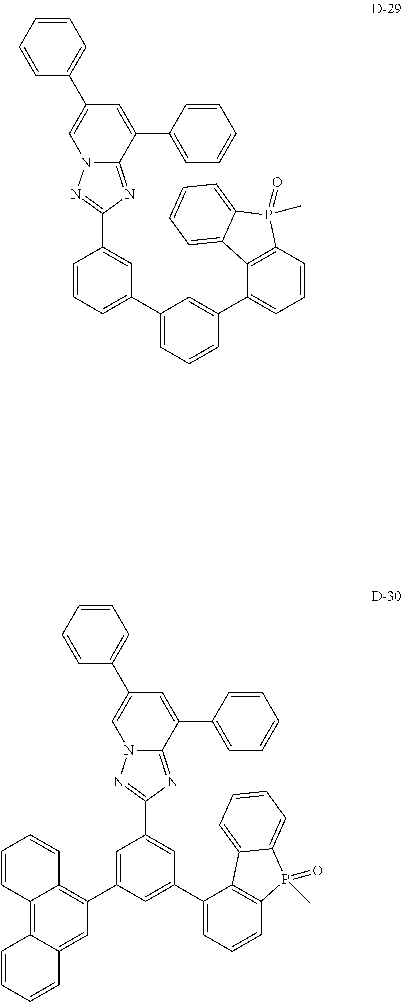 [SMILES: CP1(=O)c2ccccc2-c2c(-c3cccc(-c4cccc(-c5nc6c(-c7ccccc7)cc(-c7ccccc7)cn6n5)c4)c3)cccc21 ; CP1(=O)c2ccccc2-c2c(-c3cc(-c4nc5c(-c6ccccc6)cc(-c6ccccc6)cn5n4)cc(-c4cc5ccccc5c5ccccc45)c3)cccc21]

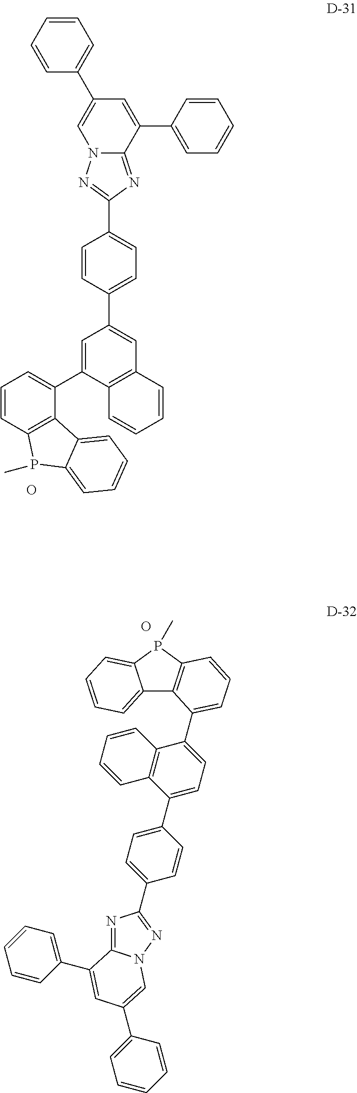

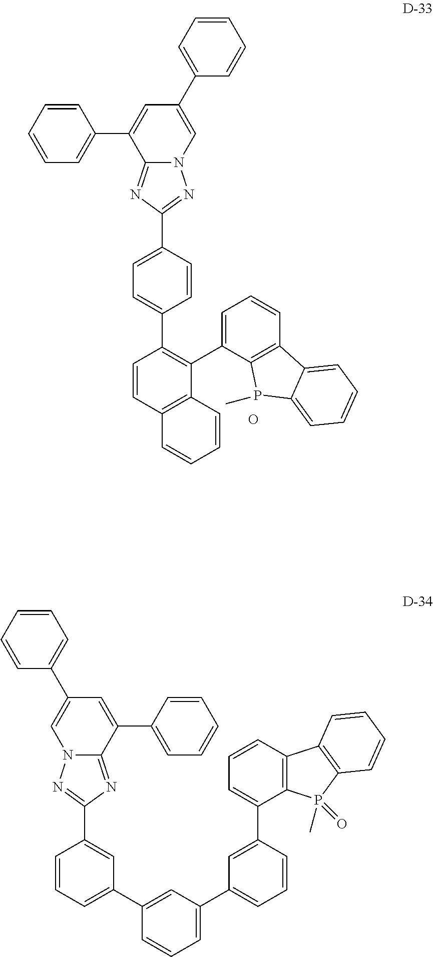

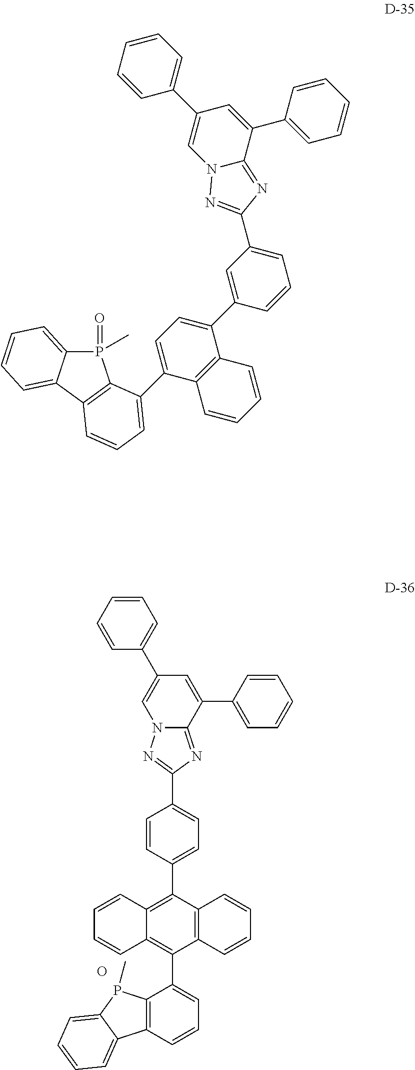

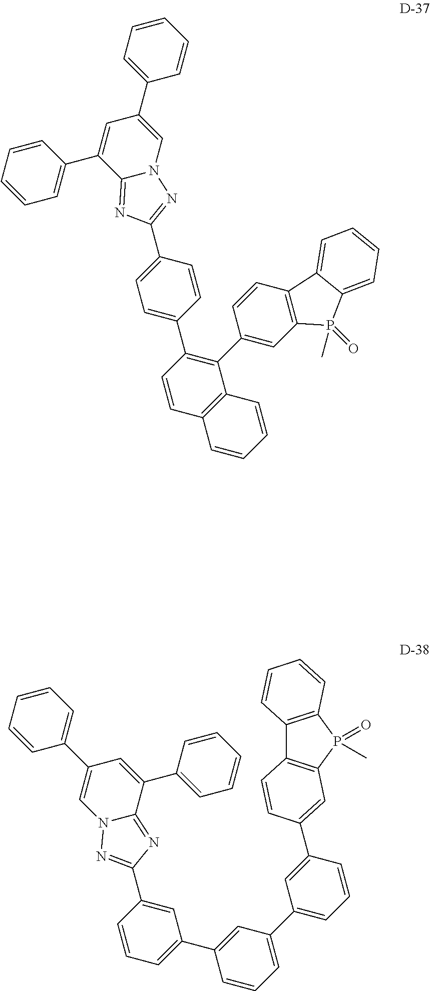 [SMILES: CP1(=O)c2ccccc2-c2ccc(-c3c(-c4ccc(-c5nc6c(-c7ccccc7)cc(-c7ccccc7)cn6n5)cc4)ccc4ccccc34)cc21 ; CP1(=O)c2ccccc2-c2ccc(-c3cccc(-c4cccc(-c5cccc(-c6nc7c(-c8ccccc8)cc(-c8ccccc8)cn7n6)c5)c4)c3)cc21]

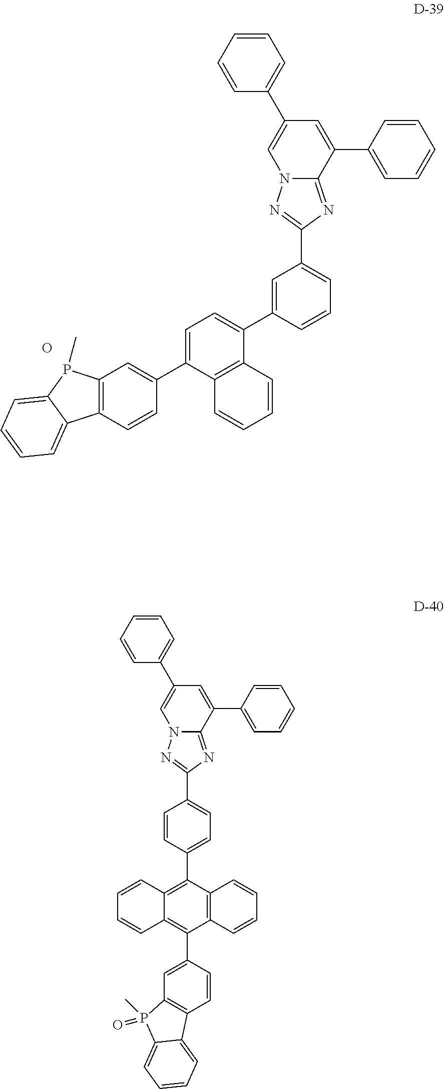

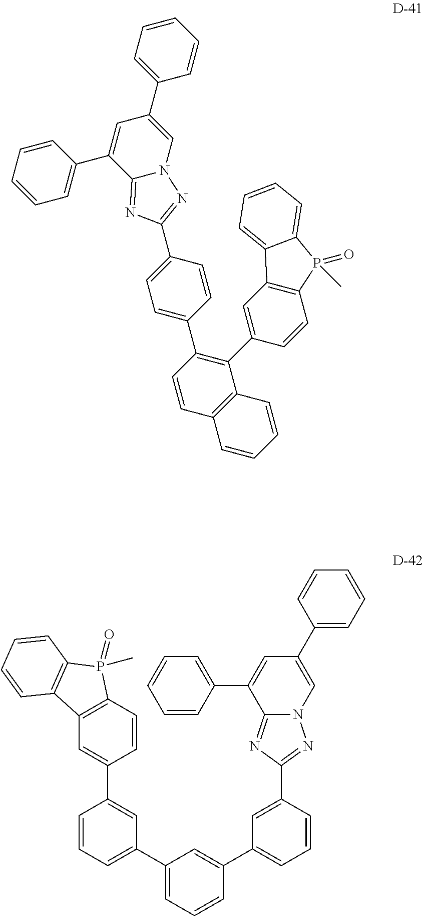 [SMILES: CP1(=O)c2ccccc2-c2cc(-c3c(-c4ccc(-c5nc6c(-c7ccccc7)cc(-c7ccccc7)cn6n5)cc4)ccc4ccccc34)ccc21 ; CP1(=O)c2ccccc2-c2cc(-c3cccc(-c4cccc(-c5cccc(-c6nc7c(-c8ccccc8)cc(-c8ccccc8)cn7n6)c5)c4)c3)ccc21]

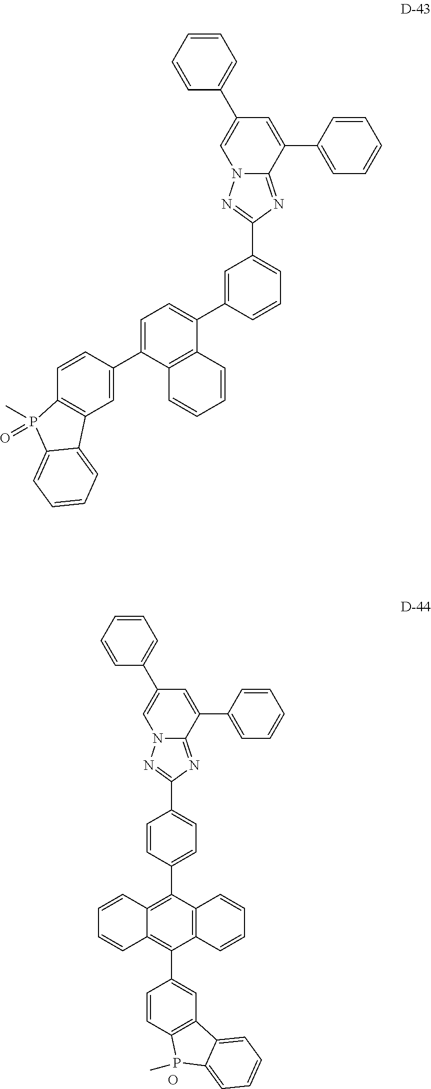

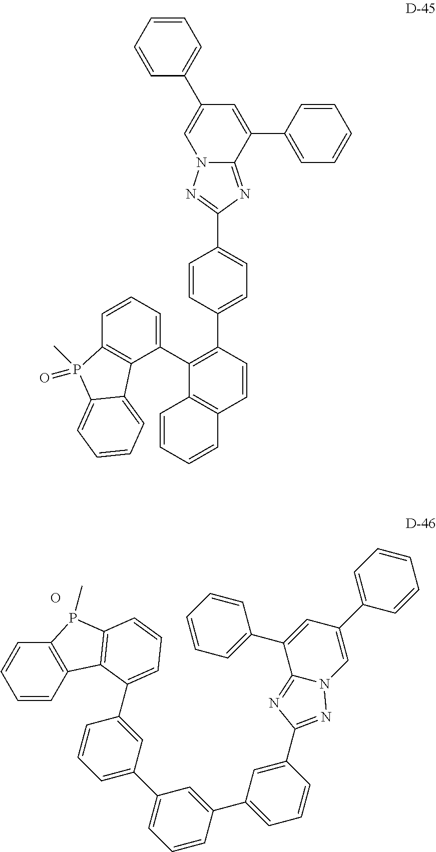

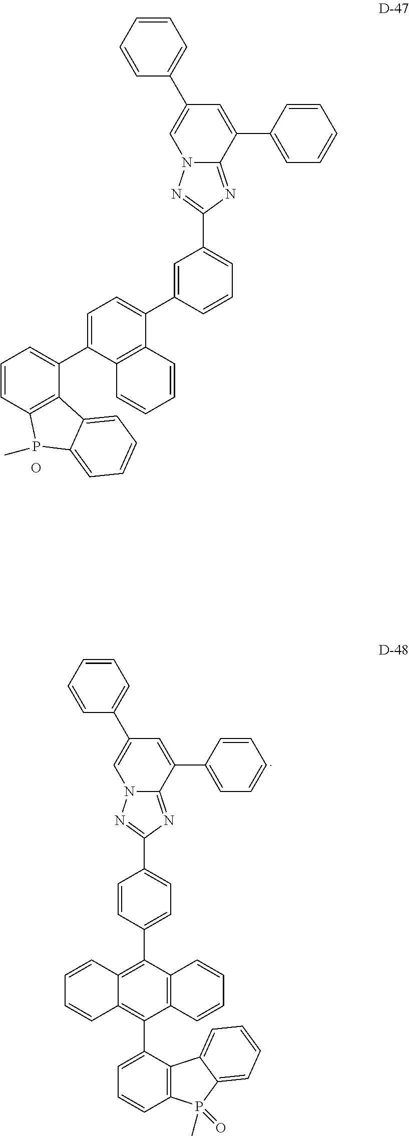

10. An organic electroluminescent device, comprising:
an anode;
a cathode; and
one or more organic layers interposed between the anode and the cathode,
wherein at least one of the one or more organic includes the compound represented by the following Chemical Formula 1 according to claim 1: 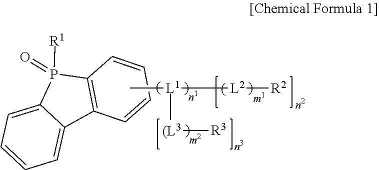
(wherein,
R¹ is selected from the group consisting of an alkyl group of C₁-C₁₂, an aryl group of C₆-C₂₀, and a heteroaryl group of 5 to 20 nuclear atoms,
n¹ is an integer of 0 to 2,
n² and n³ are each 0 or 1, with 1≤n²+n³≤2,
m¹ and m² are each an integer of 0 to 2,
L¹, L², and L³, which are same or different, are each independently an arylene group of C₆-C₁₄ or a heteroarylene group of 3 to 14 nuclear atoms,
R² and R³, which are same or different, are each independently selected from the group consisting of a hydrogen atom, a deuterium atom (D), a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine group oxide of C₆-C₆₀, an arylamine group of C₆-C₆₀, a heteroarylamine group of 5 to 60 nuclear atoms, and an (aryl)(heteroaryl)amine group of (C₆-C₆₀)(5 to 60 nuclear atoms),
the alkyl, aryl, and heteroaryl groups in R¹, the arylene and heteroarylene groups in L¹, L², and L³, and the hydrazino, hydrazono, alkyl, alkenyl, alkynyl, cycloalkyl, heterocycloalkyl, cycloalkenyl, heterocycloalkenyl, aryl, heteroaryl, alkyloxy, aryloxy, alkylsilyl, arylsilyl, alkylboron, arylboron, arylphosphine, arylphosphine oxide, arylamine, heteroarylamine, and (aryl)(heteroaryl)amine groups in R² and R³ are each independently substituted or unsubstituted with one or more substituents selected from the group consisting of the group consisting of a deuterium atom, a halogen group, a hydroxy group, a cyano group, a nitro group, an amino group, an amidino group, a hydrazino group, a hydrazono group, an alkyl group of C₁-C₆₀, an alkenyl group of C₂-C₆₀, an alkynyl group of C₂-C₆₀, a cycloalkyl group of C₃-C₆₀, a heterocycloalkyl group of 3 to 60 nuclear atoms, a cycloalkenyl group of C₃-C₆₀, a heterocycloalkenyl group of 3 to 60 nuclear atoms, an aryl group of C₆-C₆₀, a heteroaryl group of 5 to 60 nuclear atoms, an alkyloxy group of C₁-C₆₀, an aryloxy group of C₆-C₆₀, an alkylsilyl group of C₁-C₆₀, an arylsilyl group of C₆-C₆₀, an alkylboron group of C₁-C₄₀, an arylboron group of C₆-C₆₀, an arylphosphine group of C₆-C₆₀, an aryl phosphine group oxide of C₆-C₆₀, and an arylamine group of C₆-C₆₀, wherein, when ex is ting, two or more substituents are same or different).

11. The organic electroluminescent device of claim 10, wherein the organic layer comprising the organic compound is at least one selected from the group consisting of a light-emitting layer, an electron transport layer, and an electron transport auxiliary layer.

12. The organic electroluminescent device of claim 10, wherein R¹ is selected from the group consisting of methyl group, ethyl group, propyl group, butyl group, phenyl group, biphenyl group, naphthyl group, pyridine group, pyrimidine group, and triazine group.

13. The organic electroluminescent device of claim 10, wherein the compound represented by chemical formula 1 is a compound represented by chemical formula 2 or 3, below: 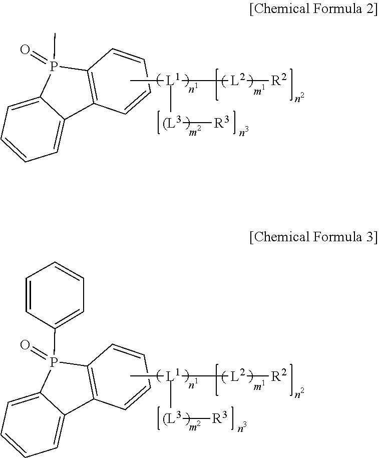
wherein,
n¹, n², n³, m¹, m², L¹, L², L³, R², and R³ are each defined as in claim 10.

14. The organic electroluminescent device of claim 10, wherein the compound represented by chemical formula 1 is a compound represented by chemical formula 4 or 5, below: 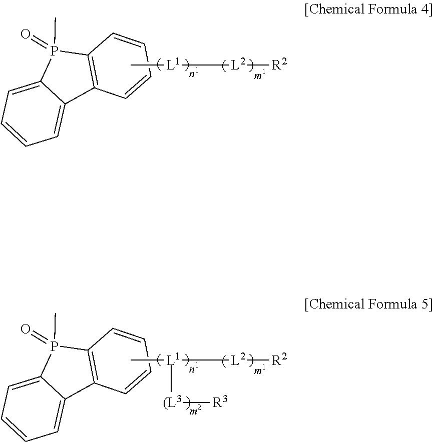
wherein,
n¹, m¹, m², L¹, L², L³, R², and R³ are each defined as in claim 10.

15. The organic electroluminescent device of claim 10, wherein R² and R³ are same or different and are each independently any one of the substituents represented by the following chemical formulas a to j: 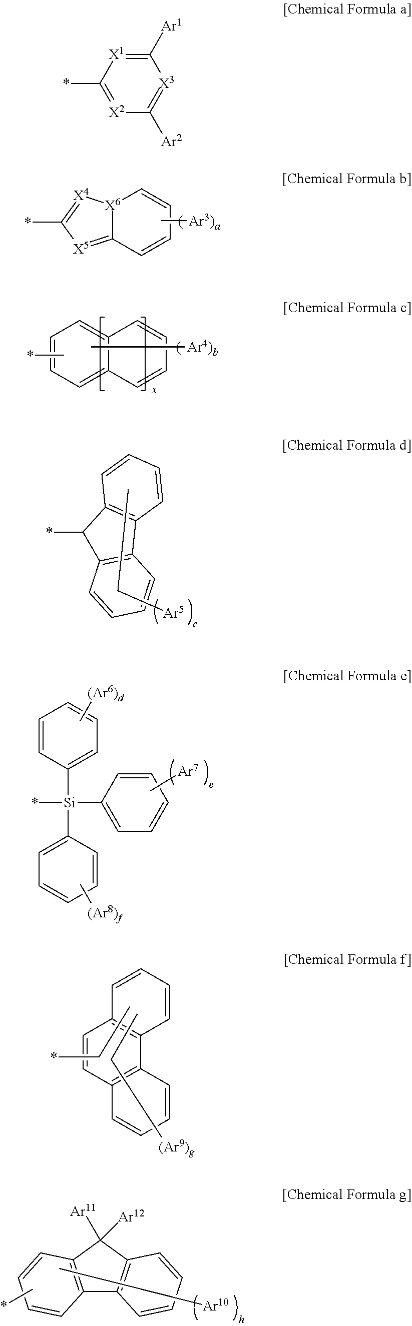 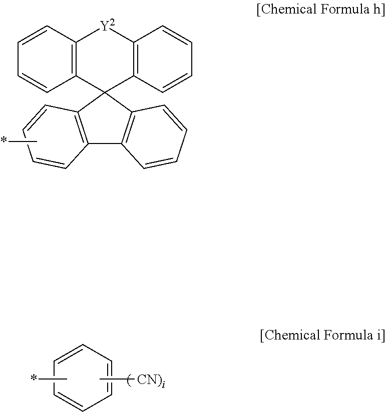
wherein,
X¹ to X³ are same or different and are each independently N or C(Ar¹³), with a proviso that at least one of X¹ to X³ is N,
X⁴ to X⁶ are same or different and are each independently N or C(Ar¹⁴), with a proviso that at least one of X⁴ to X⁶ is N,
a is an integer of 0 to 4,
b and h are each an integer of 0 to 7,
x is 0 or 1,
c and g are each an integer of 0 to 8,
d, e, f, and I are each an integer of 0 to 5,
Y¹ and Y² are each independently O or S, and
Ar¹ to Ar¹⁴ are same or different and are each independently selected from the group consisting of a hydrogen atom, a deuterium atom, a halogen group, a cyano group, a nitro group, an amino group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀,
the alkyl, alkenyl, alkynyl, cycloalkyl, heterocycloalkyl, aryl, heteroaryl, alkyloxy, aryloxy, alkylsilyl, arylsilyl, alkylboron, arylboron, arylphosphine, arylphosphine oxide, and arylamine groups of Ar¹ to Ar¹⁴ are each independently substituted or unsubstituted with at least one substituent selected from the group consisting of a deuterium atom, a halogen group, a cyano group, a nitro group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀, and two or more substituents, if present, are same or different.

16. The organic electroluminescent device of claim 10, wherein the compound represented by chemical formula 1 is a compound represented by any one of chemical formulas 6 to 10, below: 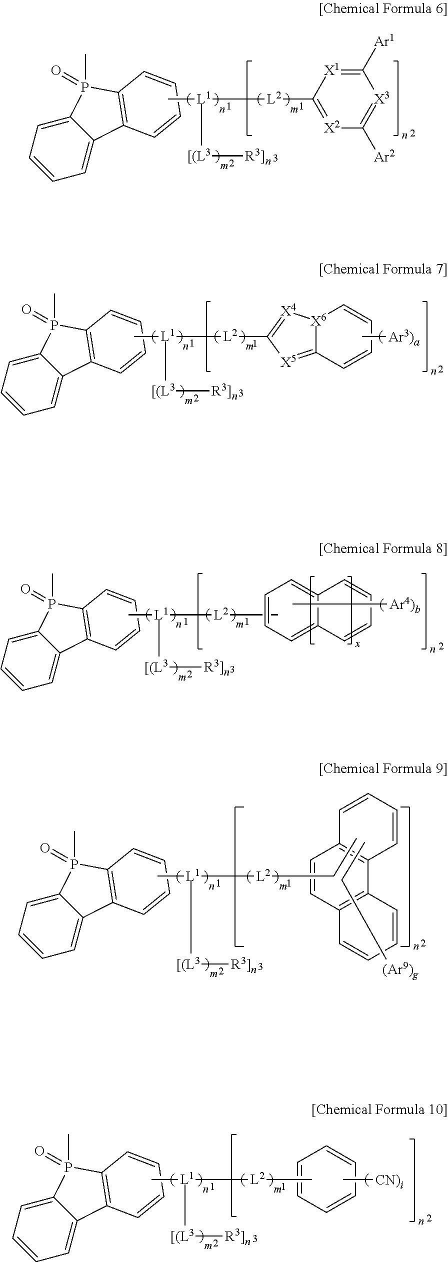
wherein,
n¹, n², n³, m¹, m², L¹, L², L³, and R³ are each as defined in claim 10,
X¹ to X³ are same or different and are each independently N or C(Ar¹³), with a proviso that at least one of X¹ to X³ is N,
X⁴ to X⁶ are same or different and are each independently N or C(Ar¹⁴), with a proviso that at least one of X⁴ to X⁶ is N,
a is an integer of 0 to 4,
b is an integer of 0 to 7,
x is 0 or 1,
g is an integer of 0 to 8,
i is an integer of 0 to 5, and
Ar¹ to Ar⁴, Ar⁹, Ar¹³, and Ar¹⁴ are same or different and are each independently selected from the group consisting of a hydrogen atom, a deuterium atom, a halogen group, a cyano group, a nitro group, an amino group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀,
the alkyl, alkenyl, alkynyl, cycloalkyl, heterocycloalkyl, aryl, heteroaryl, alkyloxy, aryloxy, alkylsilyl, arylsilyl, alkylboron, arylboron, arylphosphine, arylphosphine oxide, and arylamine groups in Ar¹ to Ar⁴, Ar⁹, Ar¹³, and Ar¹⁴ are each independently substituted or unsubstituted with at least one substituent selected from the group consisting of a deuterium atom, a halogen group, a cyano group, a nitro group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀, and two or more substituents, if present, are same or different.

17. The organic electroluminescent device of claim 10, wherein L¹ is a linker selected from the group consisting of the following linkers L1-1 to L1-12, and
L² and L³, which are same or different, are each independently a linker selected from the group consisting of the following linkers L2-1 to L2-6:

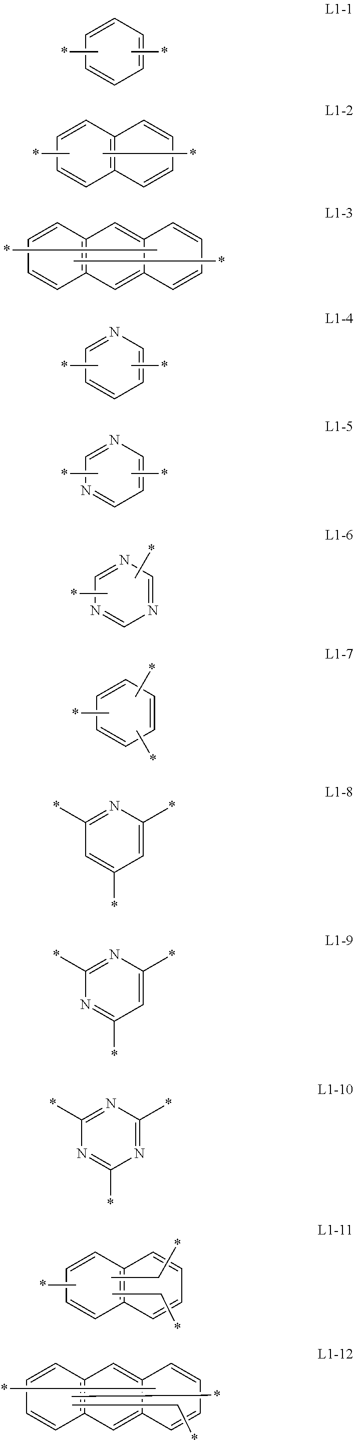

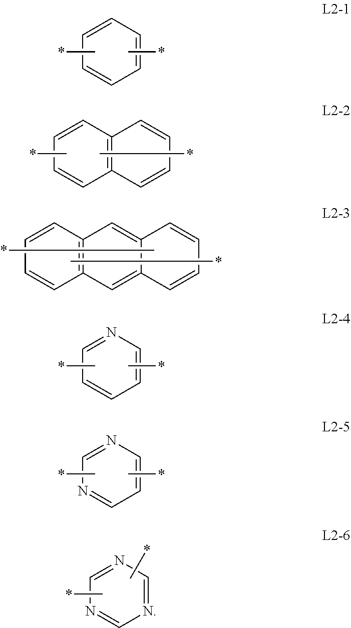

18. The organic electroluminescent device of claim 10, wherein the compound represented by chemical formula 1 is a compound represented by any one of chemical formulas 11 to 30: 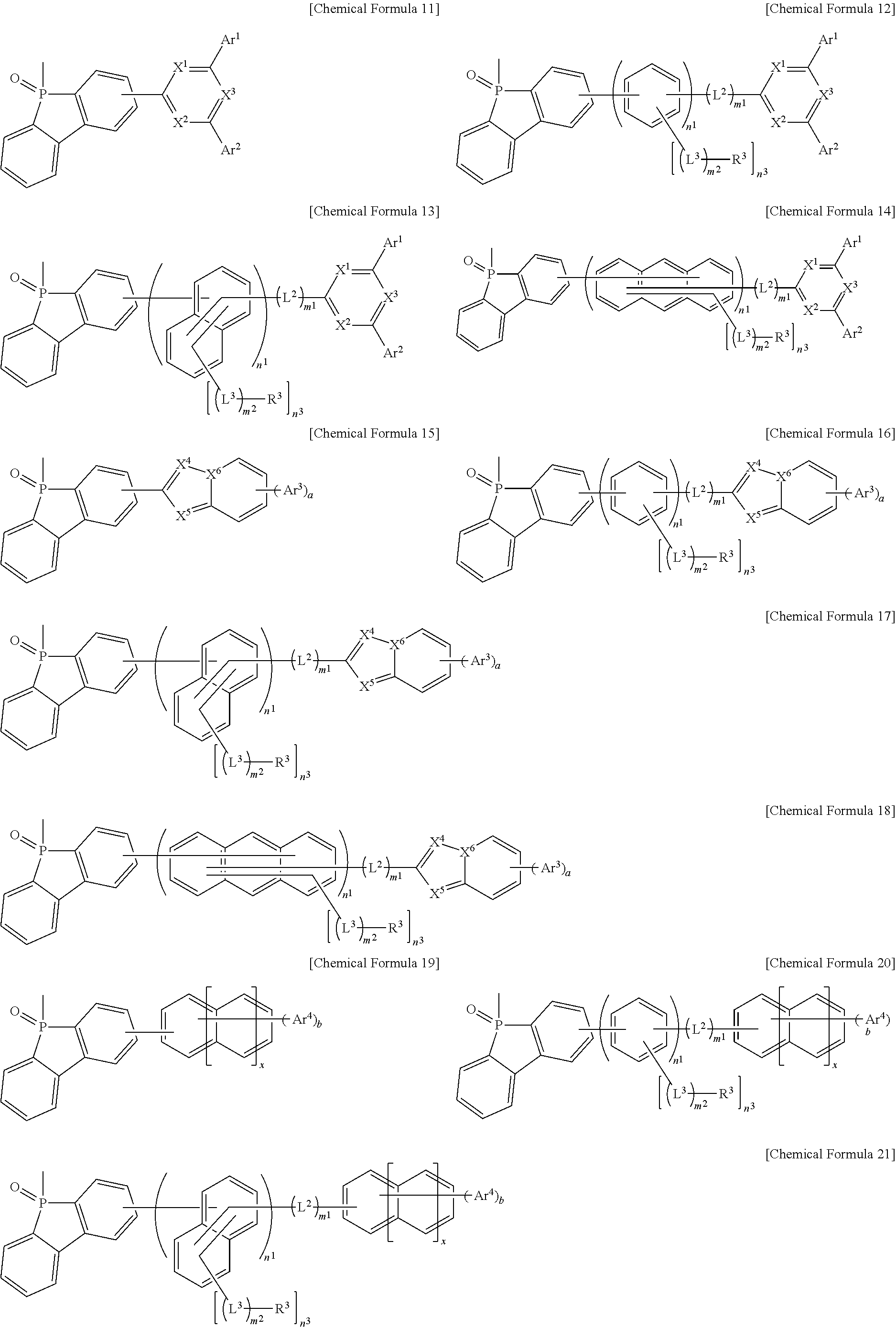 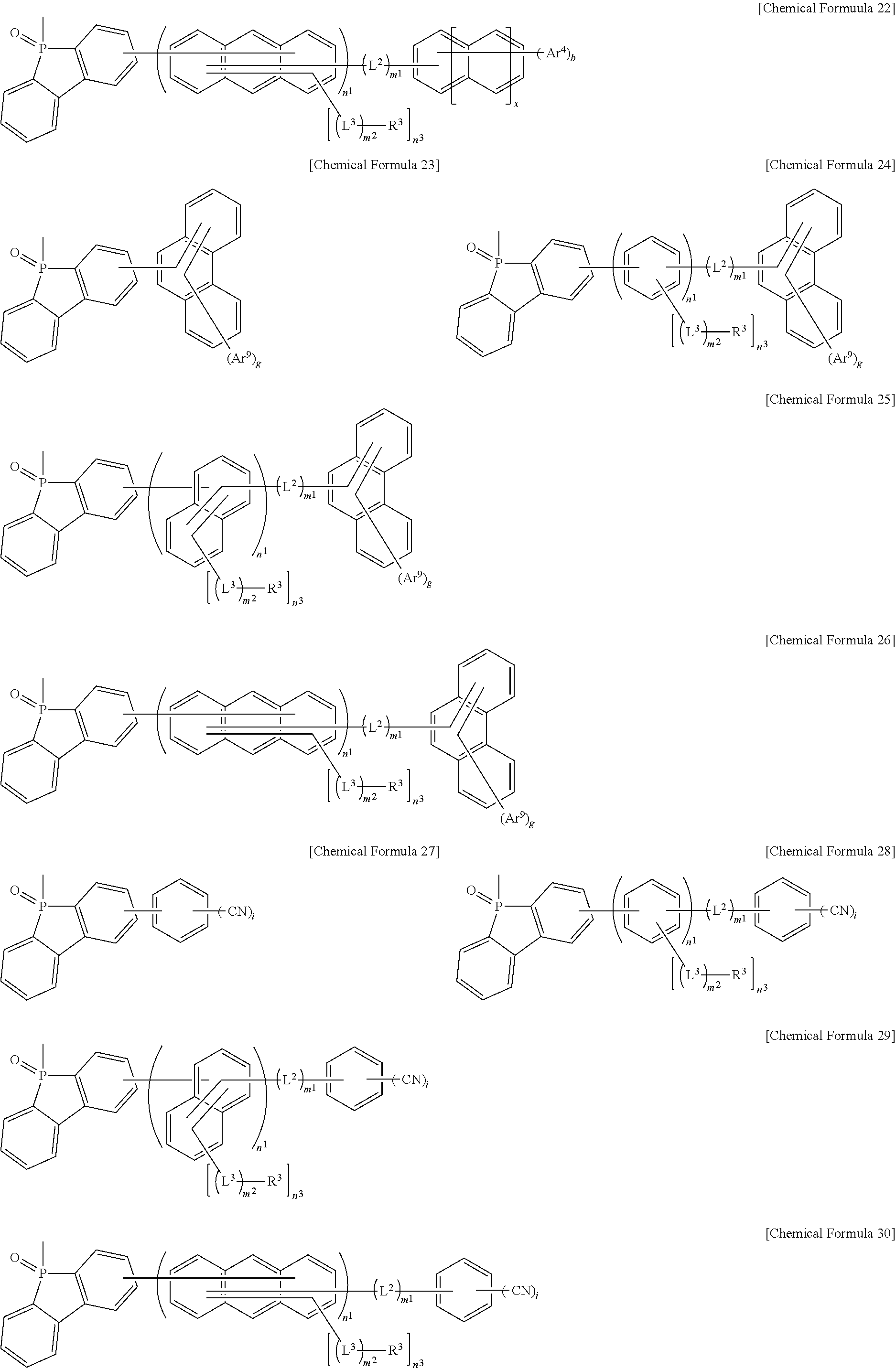
wherein,
n¹, n³, m¹, m², L², L³, and R³ are each defined as in claim 10,
X¹ to X³ are same or different and are each independently N or C(Ar¹³), with a proviso that at least one of X¹ to X³ is N,
X⁴ to X⁶ are same or different and are each independently N or C(Ar¹⁴), with a proviso that at least one of X⁴ to X⁶ is N,
a is an integer of 0 to 4,
b is an integer of 0 to 7,
x is 0 or 1,
g is an integer of 0 to 8,
i is an integer of 0 to 5, and
Ar¹ to Ar⁴, Ar⁹, Ar¹³, and Ar¹⁴ are same or different and are each independently selected from the group consisting of a hydrogen atom, a deuterium atom, a halogen group, a cyano group, a nitro group, an amino group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀,
the alkyl, alkenyl, alkynyl, cycloalkyl, heterocycloalkyl, aryl, heteroaryl, alkyloxy, aryloxy, alkylsilyl, arylsilyl, alkylboron, arylboron, arylphosphine, arylphosphine oxide, and arylamine groups in Ar¹ to Ar⁴, Ar⁹, Ar¹³, and Ar¹⁴ are each independently substituted or unsubstituted with at least one substituent selected from the group consisting of a deuterium atom, a halogen group, a cyano group, a nitro group, an alkyl group of C₁-C₄₀, an alkenyl group of C₂-C₄₀, an alkynyl group of C₂-C₄₀, a cycloalkyl group of C₃-C₄₀, a heterocycloalkyl group of 3 to 40 nuclear atoms, an aryl group of C₆-C₆₀, a heteroaryl group of 5 to 60 nuclear atoms, an alkyloxy group of C₁-C₄₀, an aryloxy group of C₆-C₆₀, an alkylsilyl group of C₁-C₄₀, an arylsilyl group of C₆-C₆₀, an alkylboron group of C₁-C₄₀, an arylboron group of C₆-C₆₀, an arylphosphine group of C₆-C₆₀, an aryl phosphine oxide group of C₆-C₆₀, and an arylamine group of C₆-C₆₀, and two or more substituents, if present, are same or different.

19. The organic electroluminescent device of claim 10, wherein the compound represented by chemical formula 1 is selected from the group consisting of compounds A-1 to D-48, below: 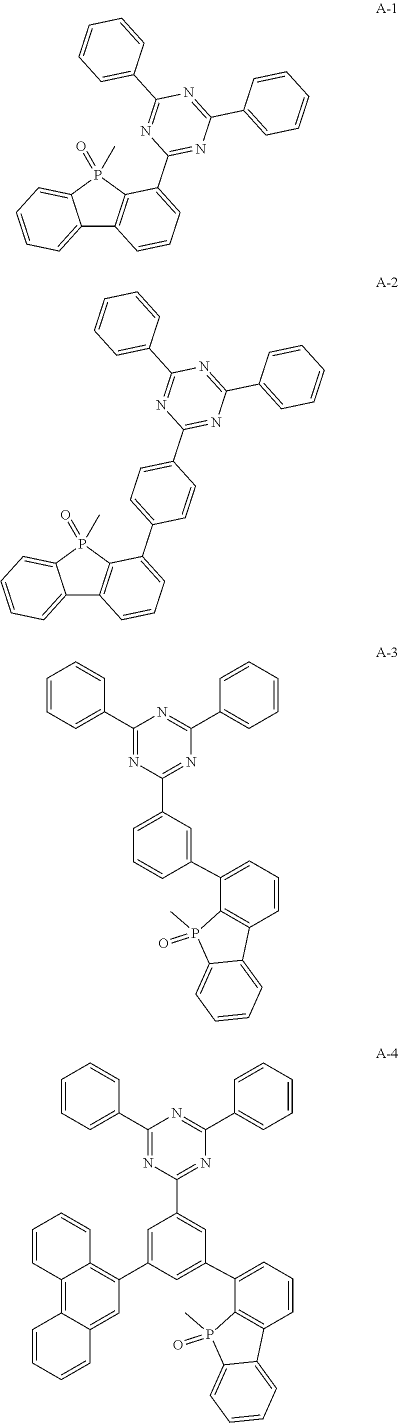 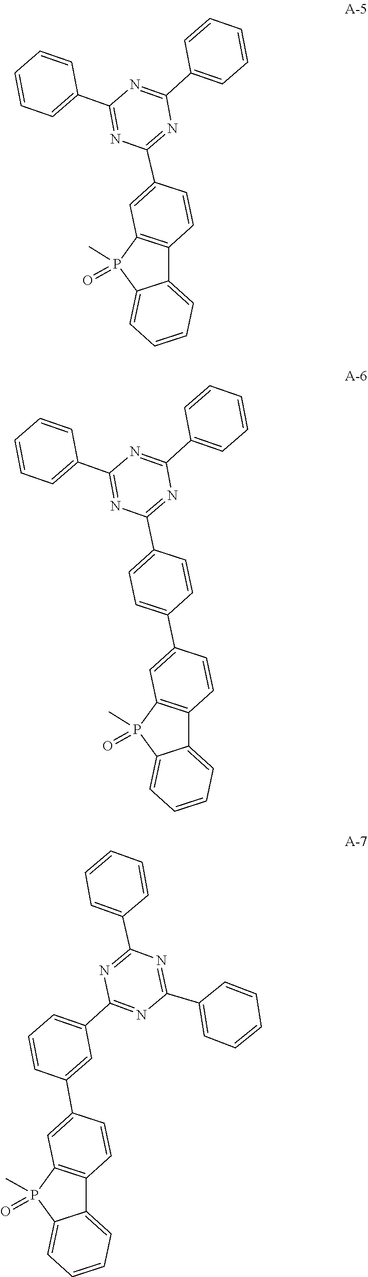 [SMILES: CP1(=O)c2ccccc2-c2ccc(-c3nc(-c4ccccc4)nc(-c4ccccc4)n3)cc21 ; CP1(=O)c2ccccc2-c2ccc(-c3ccc(-c4nc(-c5ccccc5)nc(-c5ccccc5)n4)cc3)cc21 ; CP1(=O)c2ccccc2-c2ccc(-c3cccc(-c4nc(-c5ccccc5)nc(-c5ccccc5)n4)c3)cc21] 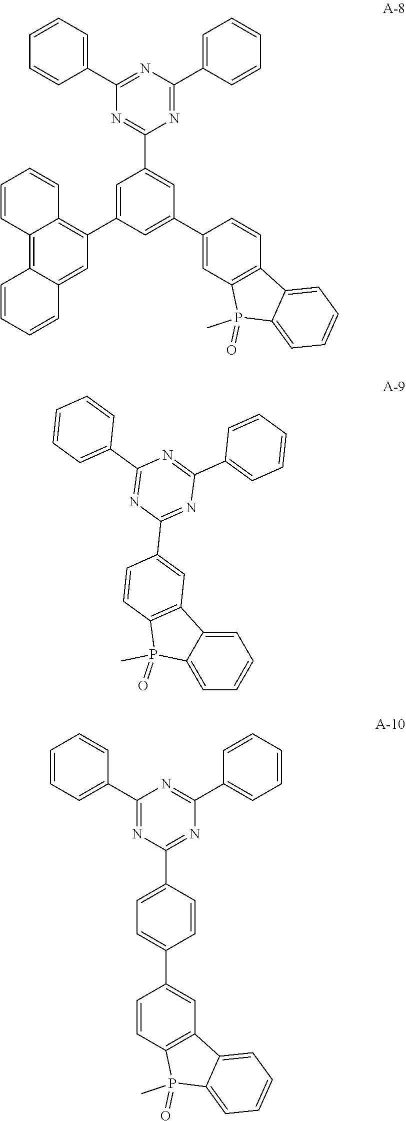 [SMILES: CP1(=O)c2ccccc2-c2ccc(-c3cc(-c4nc(-c5ccccc5)nc(-c5ccccc5)n4)cc(-c4cc5ccccc5c5ccccc45)c3)cc21 ; CP1(=O)c2ccccc2-c2cc(-c3nc(-c4ccccc4)nc(-c4ccccc4)n3)ccc21 ; CP1(=O)c2ccccc2-c2cc(-c3ccc(-c4nc(-c5ccccc5)nc(-c5ccccc5)n4)cc3)ccc21] 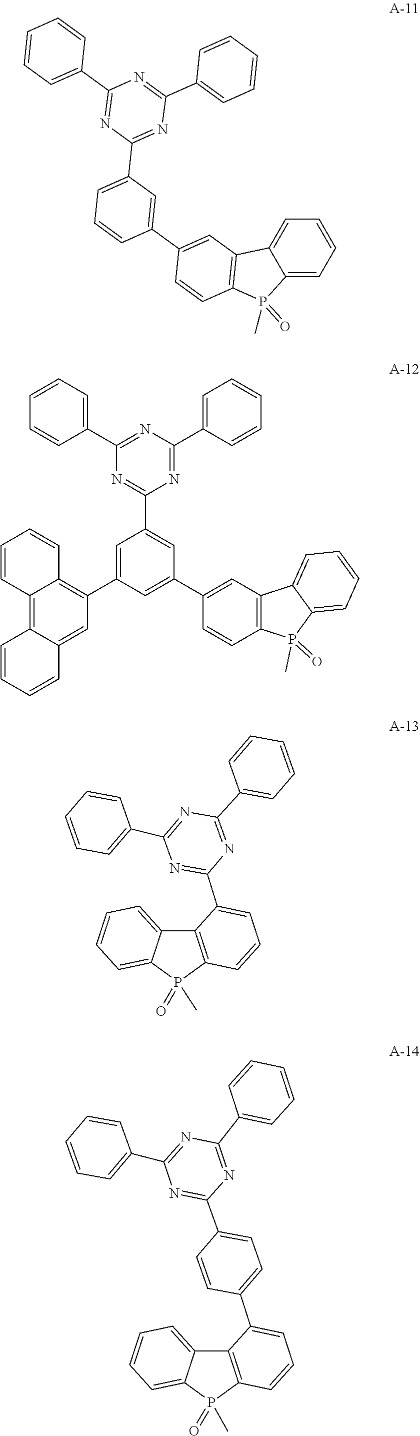 [SMILES: CP1(=O)c2ccccc2-c2cc(-c3cccc(-c4nc(-c5ccccc5)nc(-c5ccccc5)n4)c3)ccc21 ; CP1(=O)c2ccccc2-c2cc(-c3cc(-c4nc(-c5ccccc5)nc(-c5ccccc5)n4)cc(-c4cc5ccccc5c5ccccc45)c3)ccc21 ; CP1(=O)c2ccccc2-c2c(-c3nc(-c4ccccc4)nc(-c4ccccc4)n3)cccc21 ; CP1(=O)c2ccccc2-c2c(-c3ccc(-c4nc(-c5ccccc5)nc(-c5ccccc5)n4)cc3)cccc21] 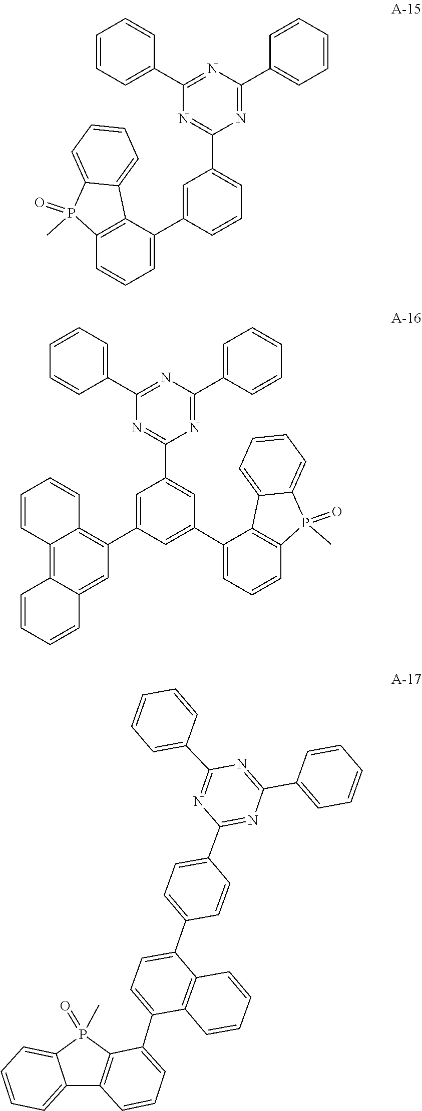 [SMILES: CP1(=O)c2ccccc2-c2c(-c3cccc(-c4nc(-c5ccccc5)nc(-c5ccccc5)n4)c3)cccc21 ; CP1(=O)c2ccccc2-c2c(-c3cc(-c4nc(-c5ccccc5)nc(-c5ccccc5)n4)cc(-c4cc5ccccc5c5ccccc45)c3)cccc21 ; CP1(=O)c2ccccc2-c2cccc(-c3ccc(-c4ccc(-c5nc(-c6ccccc6)nc(-c6ccccc6)n5)cc4)c4ccccc34)c21] 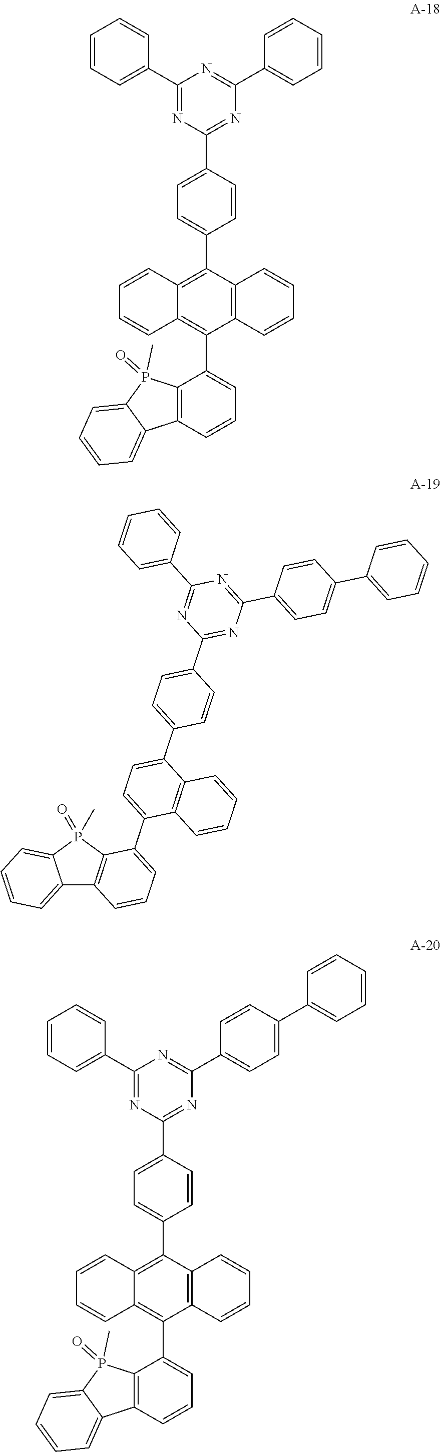 [SMILES: CP1(=O)c2ccccc2-c2cccc(-c3c4ccccc4c(-c4ccc(-c5nc(-c6ccccc6)nc(-c6ccccc6)n5)cc4)c4ccccc34)c21 ; CP1(=O)c2ccccc2-c2cccc(-c3ccc(-c4ccc(-c5nc(-c6ccccc6)nc(-c6ccc(-c7ccccc7)cc6)n5)cc4)c4ccccc34)c21 ; CP1(=O)c2ccccc2-c2cccc(-c3c4ccccc4c(-c4ccc(-c5nc(-c6ccccc6)nc(-c6ccc(-c7ccccc7)cc6)n5)cc4)c4ccccc34)c21] 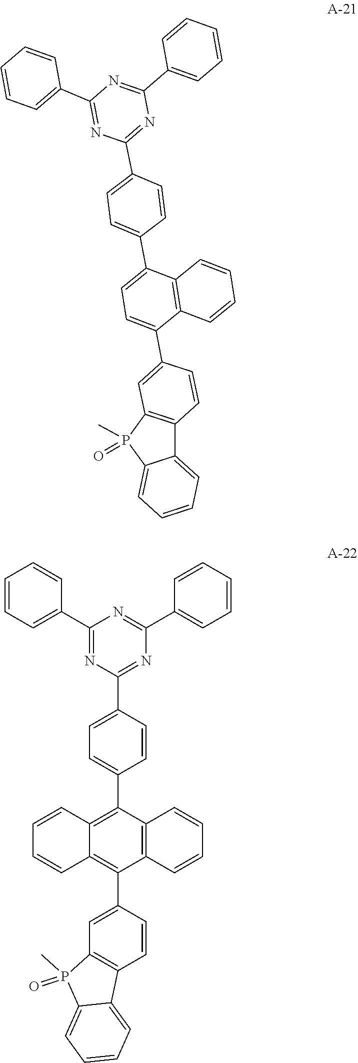 [SMILES: CP1(=O)c2ccccc2-c2ccc(-c3ccc(-c4ccc(-c5nc(-c6ccccc6)nc(-c6ccccc6)n5)cc4)c4ccccc34)cc21 ; CP1(=O)c2ccccc2-c2ccc(-c3c4ccccc4c(-c4ccc(-c5nc(-c6ccccc6)nc(-c6ccccc6)n5)cc4)c4ccccc34)cc21] 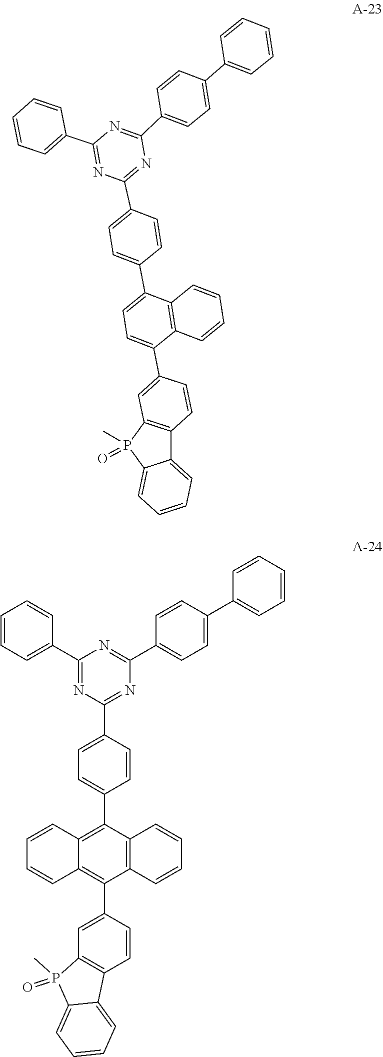 [SMILES: CP1(=O)c2ccccc2-c2ccc(-c3ccc(-c4ccc(-c5nc(-c6ccccc6)nc(-c6ccc(-c7ccccc7)cc6)n5)cc4)c4ccccc34)cc21 ; CP1(=O)c2ccccc2-c2ccc(-c3c4ccccc4c(-c4ccc(-c5nc(-c6ccccc6)nc(-c6ccc(-c7ccccc7)cc6)n5)cc4)c4ccccc34)cc21] 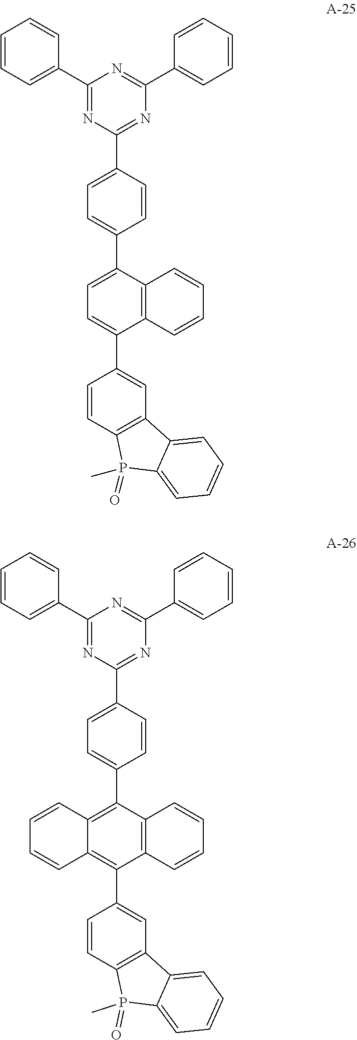 [SMILES: CP1(=O)c2ccccc2-c2cc(-c3ccc(-c4ccc(-c5nc(-c6ccccc6)nc(-c6ccccc6)n5)cc4)c4ccccc34)ccc21 ; CP1(=O)c2ccccc2-c2cc(-c3c4ccccc4c(-c4ccc(-c5nc(-c6ccccc6)nc(-c6ccccc6)n5)cc4)c4ccccc34)ccc21] 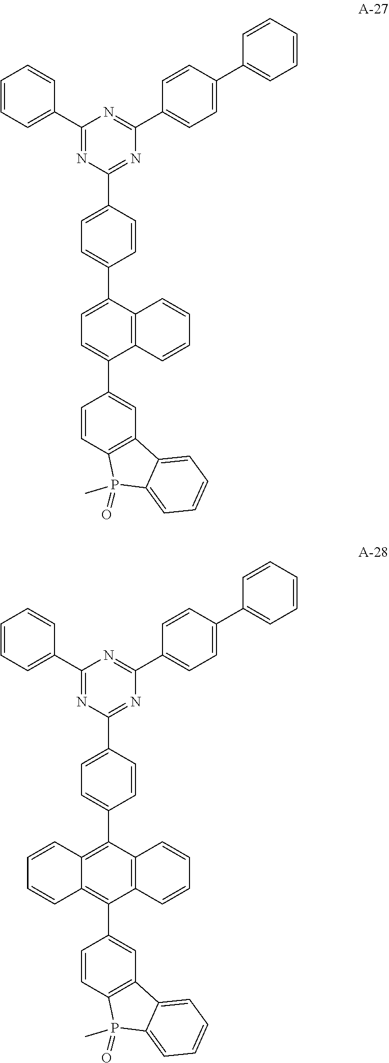 [SMILES: CP1(=O)c2ccccc2-c2cc(-c3ccc(-c4ccc(-c5nc(-c6ccccc6)nc(-c6ccc(-c7ccccc7)cc6)n5)cc4)c4ccccc34)ccc21 ; CP1(=O)c2ccccc2-c2cc(-c3c4ccccc4c(-c4ccc(-c5nc(-c6ccccc6)nc(-c6ccc(-c7ccccc7)cc6)n5)cc4)c4ccccc34)ccc21] 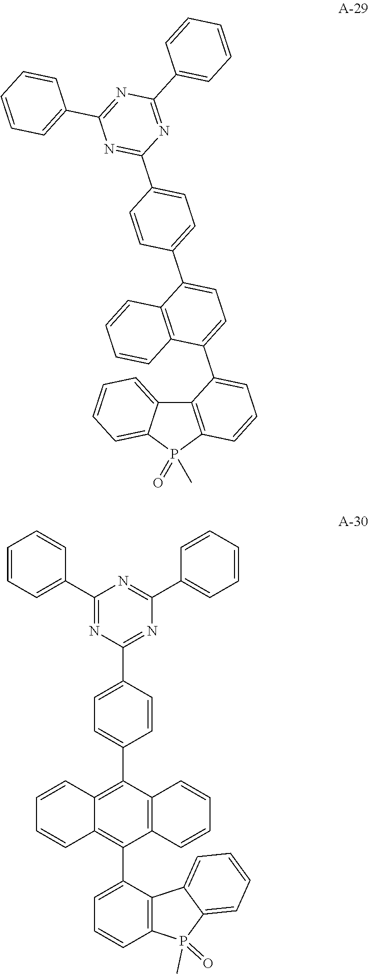 [SMILES: CP1(=O)c2ccccc2-c2c(-c3ccc(-c4ccc(-c5nc(-c6ccccc6)nc(-c6ccccc6)n5)cc4)c4ccccc34)cccc21 ; CP1(=O)c2ccccc2-c2c(-c3c4ccccc4c(-c4ccc(-c5nc(-c6ccccc6)nc(-c6ccccc6)n5)cc4)c4ccccc34)cccc21] 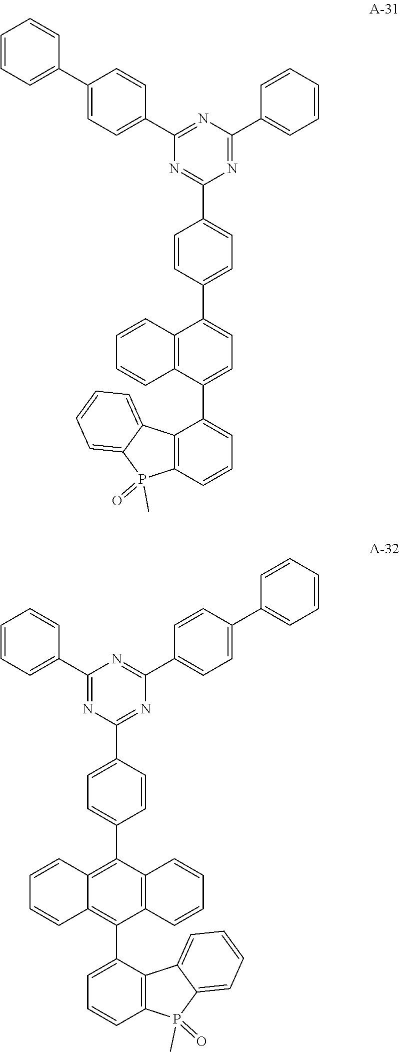 [SMILES: CP1(=O)c2ccccc2-c2c(-c3ccc(-c4ccc(-c5nc(-c6ccccc6)nc(-c6ccc(-c7ccccc7)cc6)n5)cc4)c4ccccc34)cccc21 ; CP1(=O)c2ccccc2-c2c(-c3c4ccccc4c(-c4ccc(-c5nc(-c6ccccc6)nc(-c6ccc(-c7ccccc7)cc6)n5)cc4)c4ccccc34)cccc21] 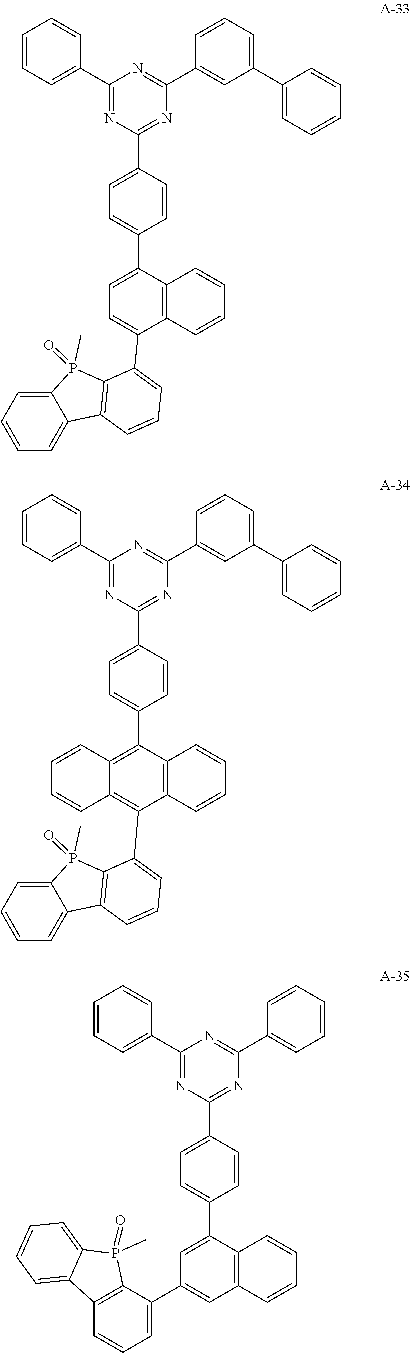 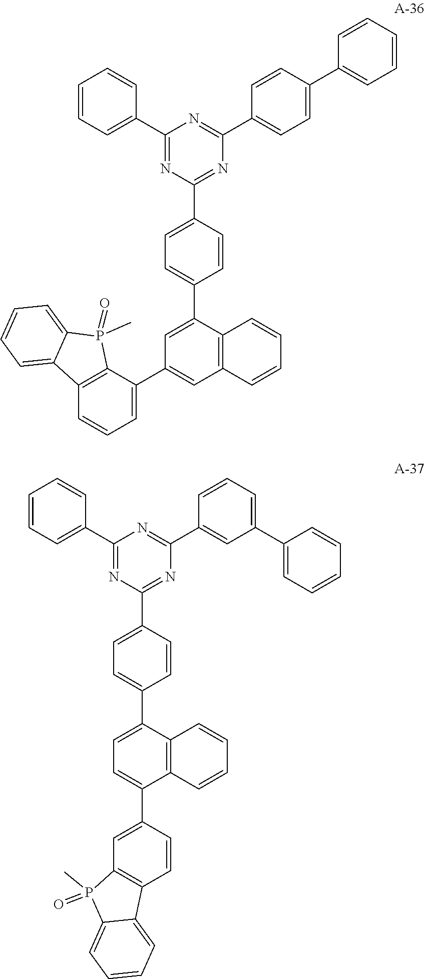 [SMILES: CP1(=O)c2ccccc2-c2cccc(-c3cc(-c4ccc(-c5nc(-c6ccccc6)nc(-c6ccc(-c7ccccc7)cc6)n5)cc4)c4ccccc4c3)c21 ; CP1(=O)c2ccccc2-c2ccc(-c3ccc(-c4ccc(-c5nc(-c6ccccc6)nc(-c6cccc(-c7ccccc7)c6)n5)cc4)c4ccccc34)cc21] 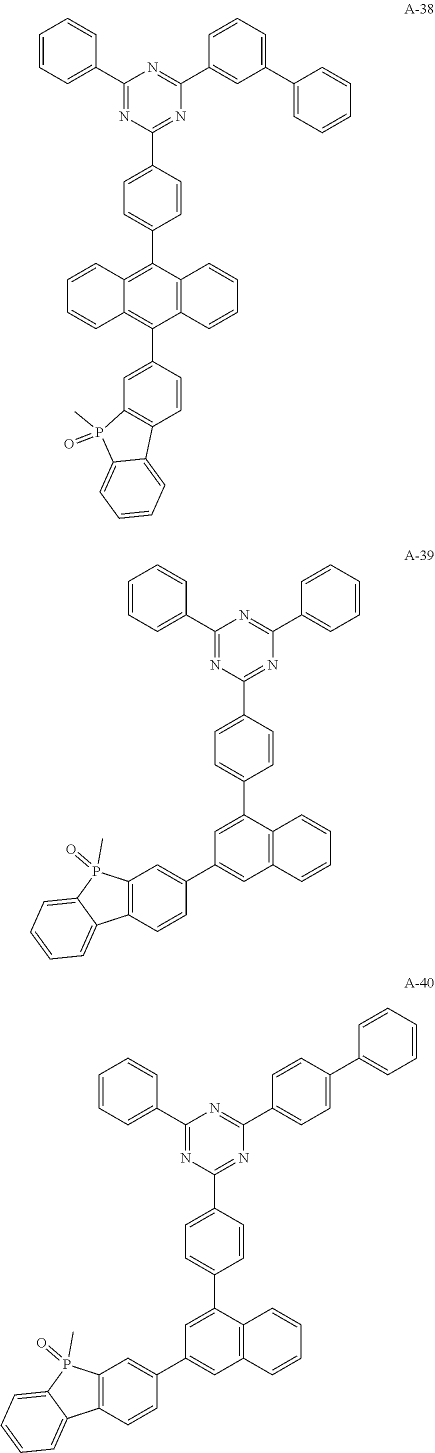 [SMILES: CP1(=O)c2ccccc2-c2ccc(-c3c4ccccc4c(-c4ccc(-c5nc(-c6ccccc6)nc(-c6cccc(-c7ccccc7)c6)n5)cc4)c4ccccc34)cc21 ; CP1(=O)c2ccccc2-c2ccc(-c3cc(-c4ccc(-c5nc(-c6ccccc6)nc(-c6ccccc6)n5)cc4)c4ccccc4c3)cc21 ; CP1(=O)c2ccccc2-c2ccc(-c3cc(-c4ccc(-c5nc(-c6ccccc6)nc(-c6ccc(-c7ccccc7)cc6)n5)cc4)c4ccccc4c3)cc21] 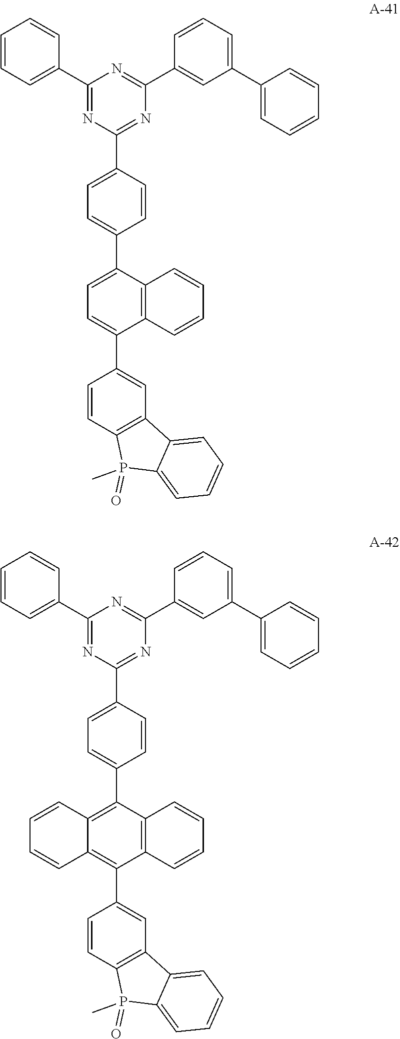 [SMILES: CP1(=O)c2ccccc2-c2cc(-c3ccc(-c4ccc(-c5nc(-c6ccccc6)nc(-c6cccc(-c7ccccc7)c6)n5)cc4)c4ccccc34)ccc21 ; CP1(=O)c2ccccc2-c2cc(-c3c4ccccc4c(-c4ccc(-c5nc(-c6ccccc6)nc(-c6cccc(-c7ccccc7)c6)n5)cc4)c4ccccc34)ccc21] 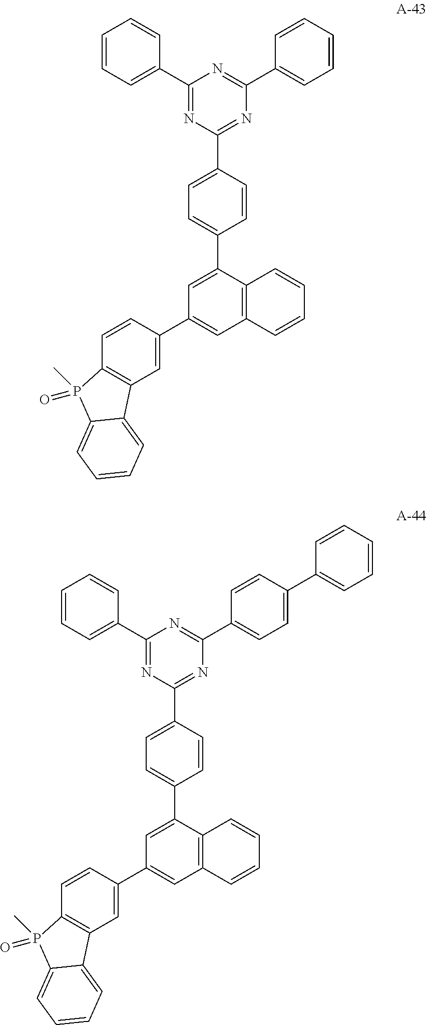 [SMILES: CP1(=O)c2ccccc2-c2cc(-c3cc(-c4ccc(-c5nc(-c6ccccc6)nc(-c6ccccc6)n5)cc4)c4ccccc4c3)ccc21 ; CP1(=O)c2ccccc2-c2cc(-c3cc(-c4ccc(-c5nc(-c6ccccc6)nc(-c6ccc(-c7ccccc7)cc6)n5)cc4)c4ccccc4c3)ccc21] 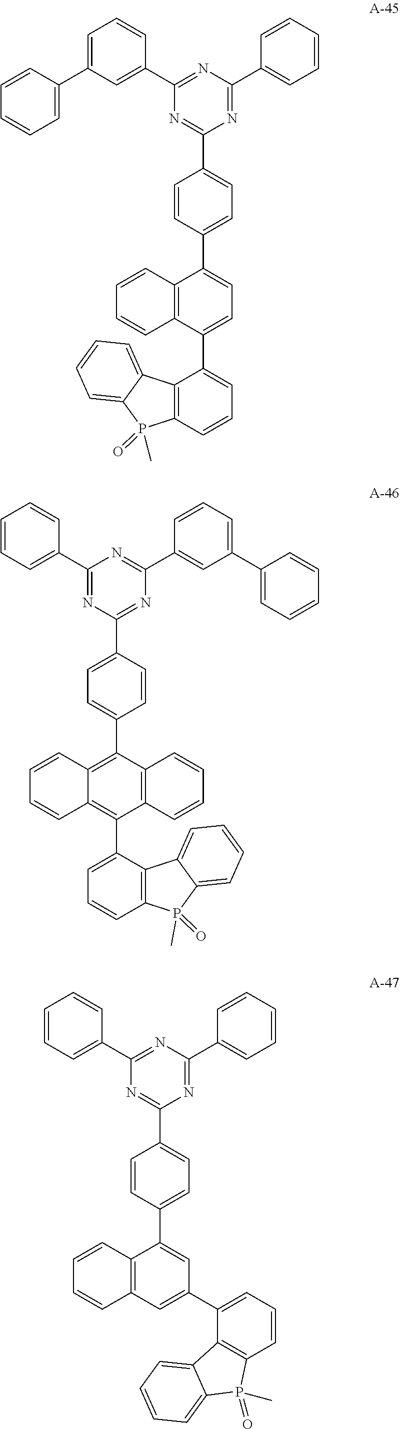 [SMILES: CP1(=O)c2ccccc2-c2c(-c3ccc(-c4ccc(-c5nc(-c6ccccc6)nc(-c6cccc(-c7ccccc7)c6)n5)cc4)c4ccccc34)cccc21 ; CP1(=O)c2ccccc2-c2c(-c3c4ccccc4c(-c4ccc(-c5nc(-c6ccccc6)nc(-c6cccc(-c7ccccc7)c6)n5)cc4)c4ccccc34)cccc21 ; CP1(=O)c2ccccc2-c2c(-c3cc(-c4ccc(-c5nc(-c6ccccc6)nc(-c6ccccc6)n5)cc4)c4ccccc4c3)cccc21] 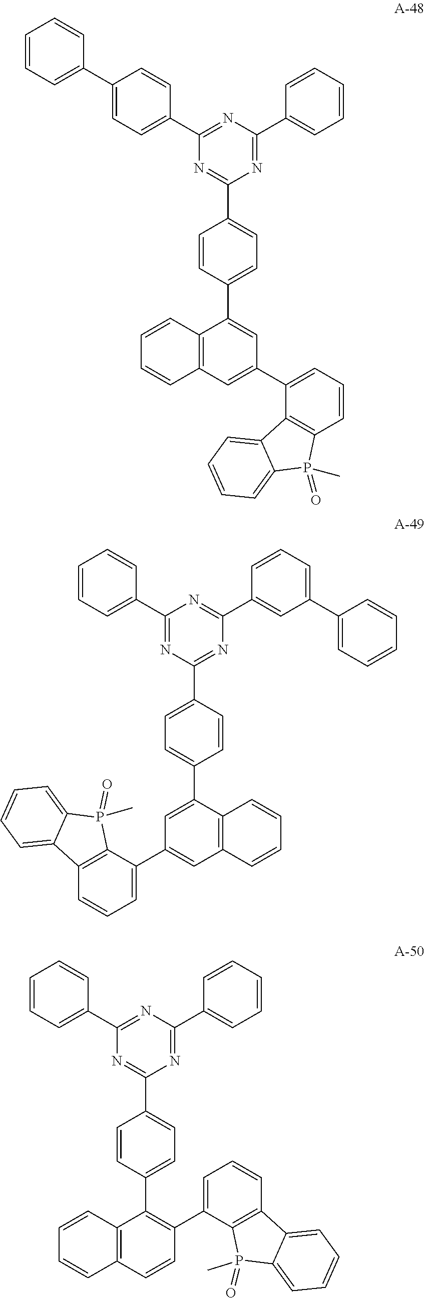 [SMILES: CP1(=O)c2ccccc2-c2c(-c3cc(-c4ccc(-c5nc(-c6ccccc6)nc(-c6ccc(-c7ccccc7)cc6)n5)cc4)c4ccccc4c3)cccc21 ; CP1(=O)c2ccccc2-c2cccc(-c3cc(-c4ccc(-c5nc(-c6ccccc6)nc(-c6cccc(-c7ccccc7)c6)n5)cc4)c4ccccc4c3)c21 ; CP1(=O)c2ccccc2-c2cccc(-c3ccc4ccccc4c3-c3ccc(-c4nc(-c5ccccc5)nc(-c5ccccc5)n4)cc3)c21] 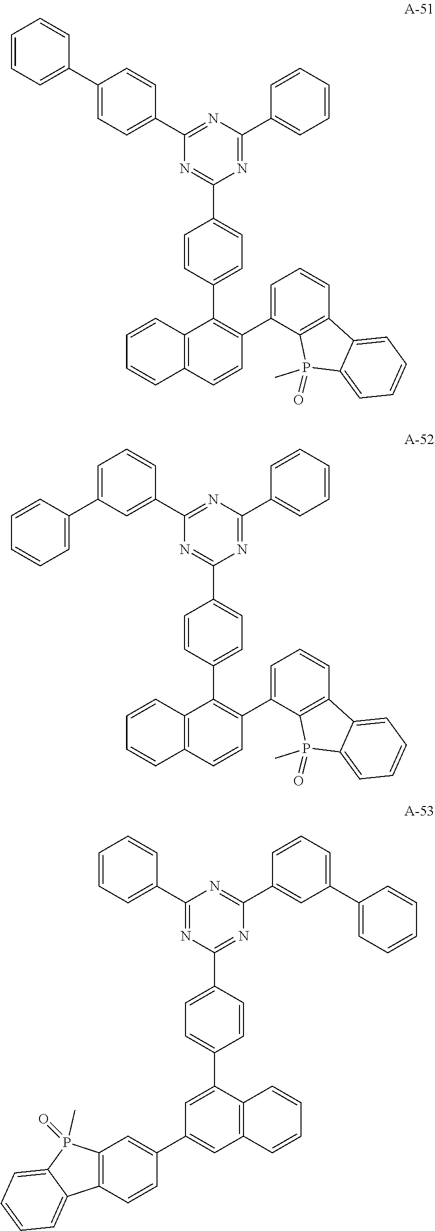 [SMILES: CP1(=O)c2ccccc2-c2cccc(-c3ccc4ccccc4c3-c3ccc(-c4nc(-c5ccccc5)nc(-c5ccc(-c6ccccc6)cc5)n4)cc3)c21 ; CP1(=O)c2ccccc2-c2cccc(-c3ccc4ccccc4c3-c3ccc(-c4nc(-c5ccccc5)nc(-c5cccc(-c6ccccc6)c5)n4)cc3)c21 ; CP1(=O)c2ccccc2-c2ccc(-c3cc(-c4ccc(-c5nc(-c6ccccc6)nc(-c6cccc(-c7ccccc7)c6)n5)cc4)c4ccccc4c3)cc21] 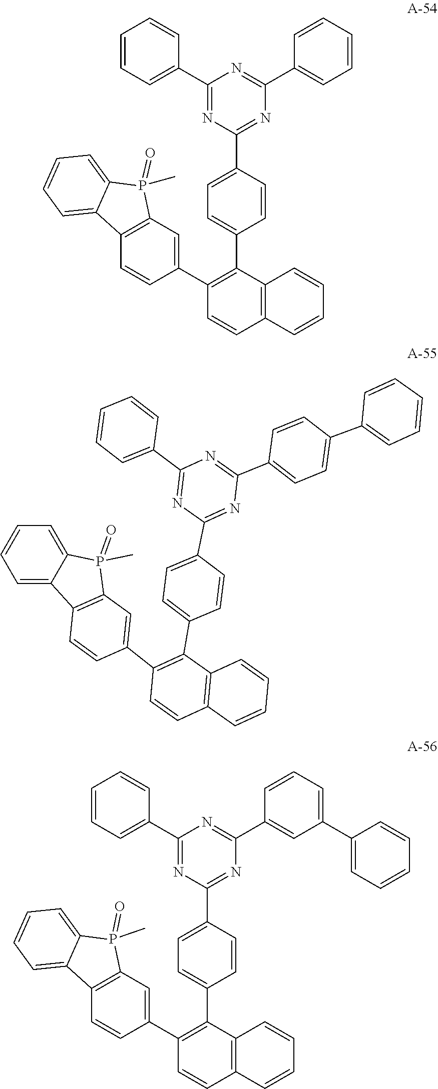 [SMILES: CP1(=O)c2ccccc2-c2ccc(-c3ccc4ccccc4c3-c3ccc(-c4nc(-c5ccccc5)nc(-c5ccccc5)n4)cc3)cc21 ; CP1(=O)c2ccccc2-c2ccc(-c3ccc4ccccc4c3-c3ccc(-c4nc(-c5ccccc5)nc(-c5ccc(-c6ccccc6)cc5)n4)cc3)cc21 ; CP1(=O)c2ccccc2-c2ccc(-c3ccc4ccccc4c3-c3ccc(-c4nc(-c5ccccc5)nc(-c5cccc(-c6ccccc6)c5)n4)cc3)cc21] 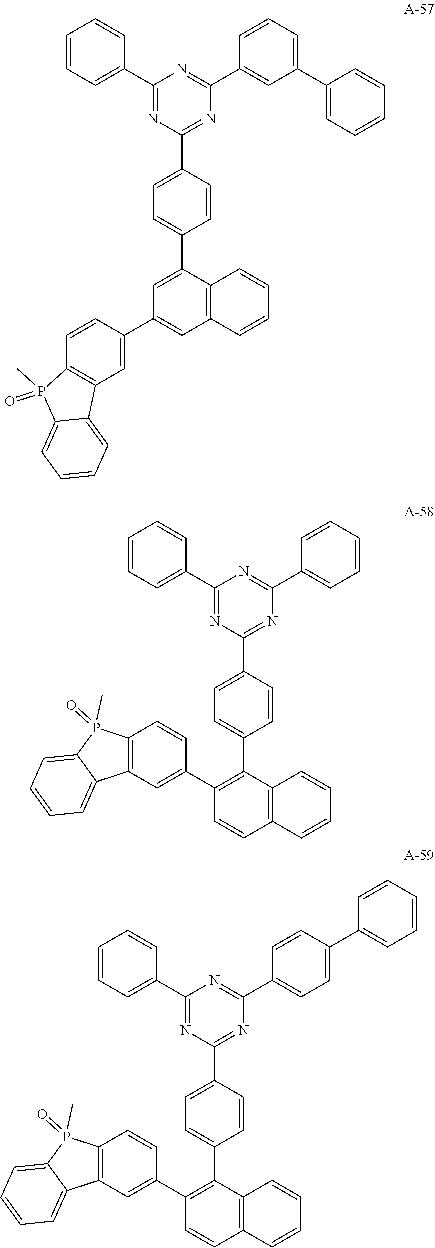 [SMILES: CP1(=O)c2ccccc2-c2cc(-c3cc(-c4ccc(-c5nc(-c6ccccc6)nc(-c6cccc(-c7ccccc7)c6)n5)cc4)c4ccccc4c3)ccc21 ; CP1(=O)c2ccccc2-c2cc(-c3ccc4ccccc4c3-c3ccc(-c4nc(-c5ccccc5)nc(-c5ccccc5)n4)cc3)ccc21 ; CP1(=O)c2ccccc2-c2cc(-c3ccc4ccccc4c3-c3ccc(-c4nc(-c5ccccc5)nc(-c5ccc(-c6ccccc6)cc5)n4)cc3)ccc21] 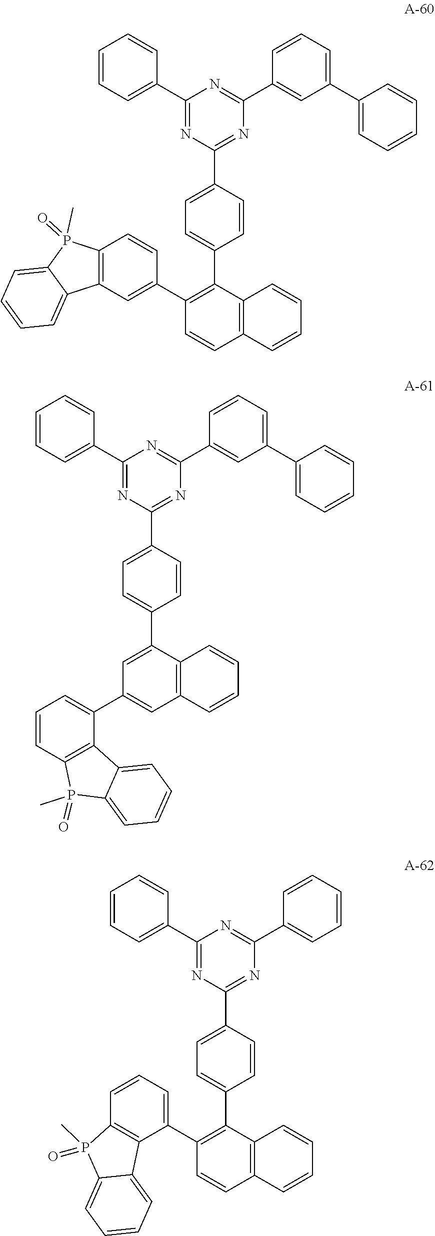 [SMILES: CP1(=O)c2ccccc2-c2cc(-c3ccc4ccccc4c3-c3ccc(-c4nc(-c5ccccc5)nc(-c5cccc(-c6ccccc6)c5)n4)cc3)ccc21 ; CP1(=O)c2ccccc2-c2c(-c3cc(-c4ccc(-c5nc(-c6ccccc6)nc(-c6cccc(-c7ccccc7)c6)n5)cc4)c4ccccc4c3)cccc21 ; CP1(=O)c2ccccc2-c2c(-c3ccc4ccccc4c3-c3ccc(-c4nc(-c5ccccc5)nc(-c5ccccc5)n4)cc3)cccc21] 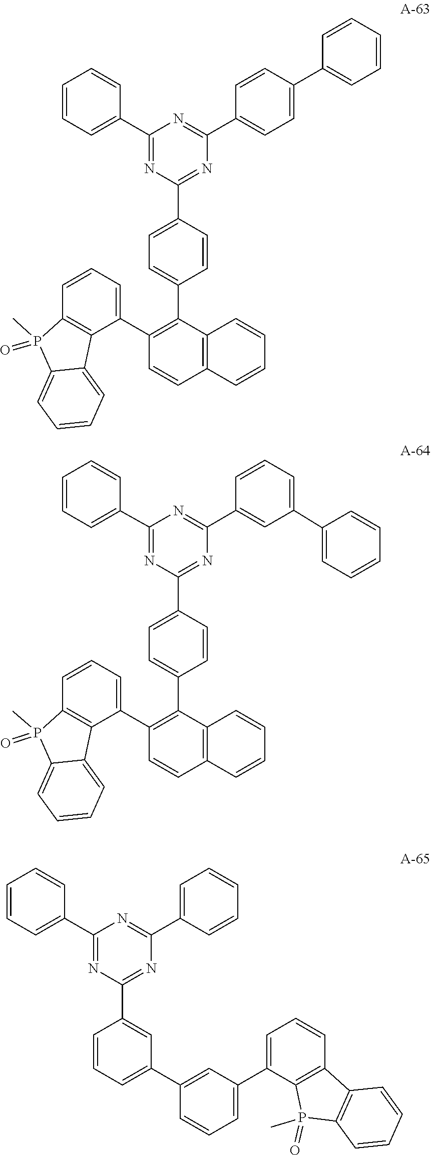 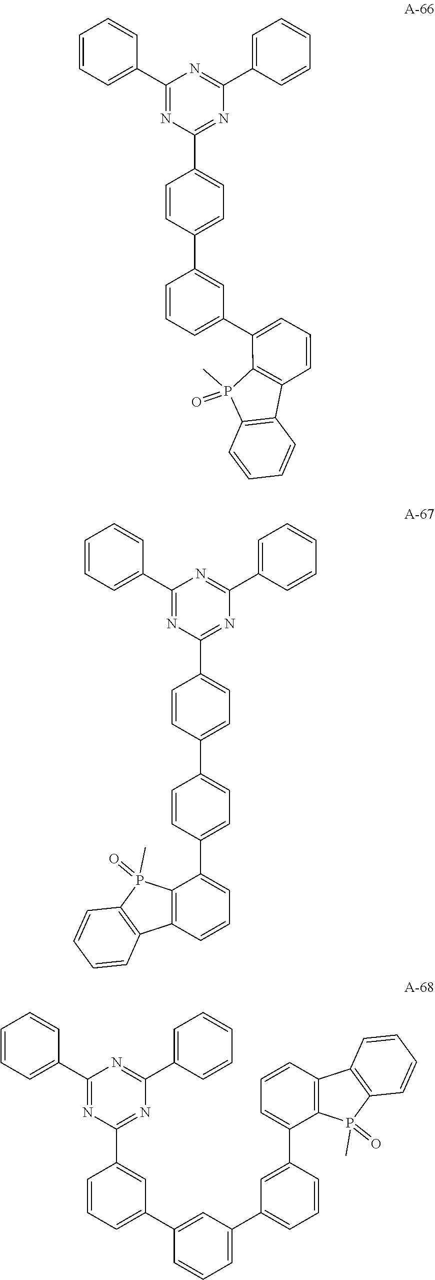 [SMILES: CP1(=O)c2ccccc2-c2cccc(-c3cccc(-c4ccc(-c5nc(-c6ccccc6)nc(-c6ccccc6)n5)cc4)c3)c21 ; CP1(=O)c2ccccc2-c2cccc(-c3ccc(-c4ccc(-c5nc(-c6ccccc6)nc(-c6ccccc6)n5)cc4)cc3)c21 ; CP1(=O)c2ccccc2-c2cccc(-c3cccc(-c4cccc(-c5cccc(-c6nc(-c7ccccc7)nc(-c7ccccc7)n6)c5)c4)c3)c21] 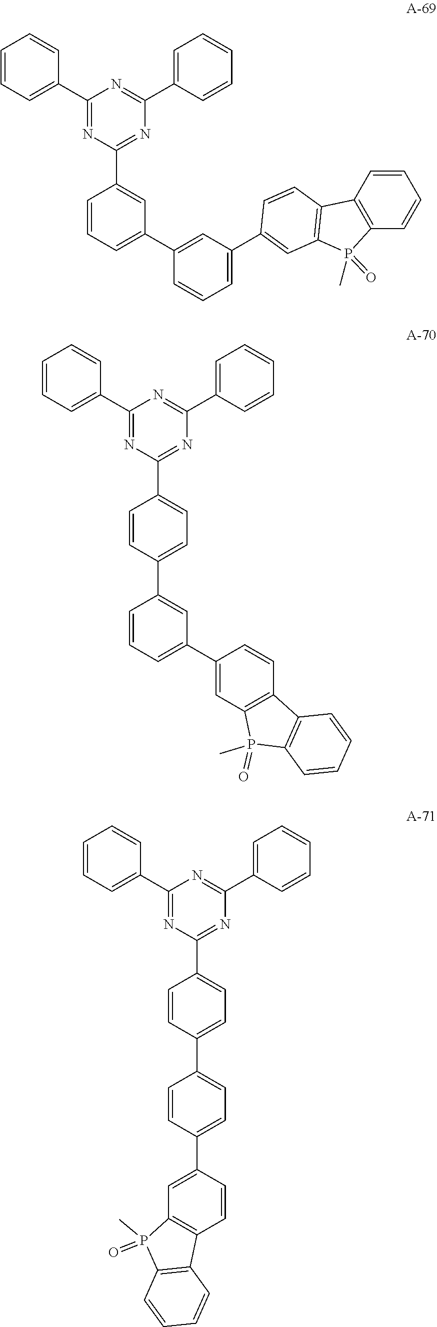 [SMILES: CP1(=O)c2ccccc2-c2ccc(-c3cccc(-c4cccc(-c5nc(-c6ccccc6)nc(-c6ccccc6)n5)c4)c3)cc21 ; CP1(=O)c2ccccc2-c2ccc(-c3cccc(-c4ccc(-c5nc(-c6ccccc6)nc(-c6ccccc6)n5)cc4)c3)cc21 ; CP1(=O)c2ccccc2-c2ccc(-c3ccc(-c4ccc(-c5nc(-c6ccccc6)nc(-c6ccccc6)n5)cc4)cc3)cc21] 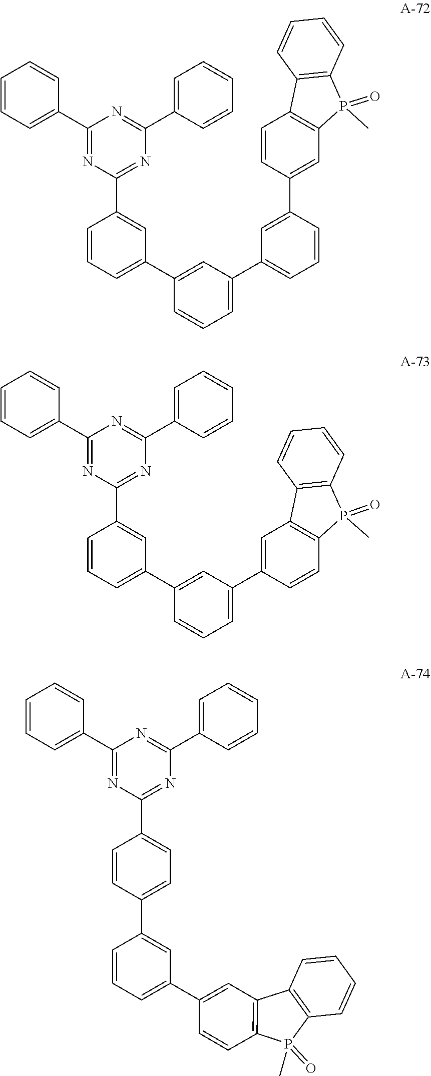 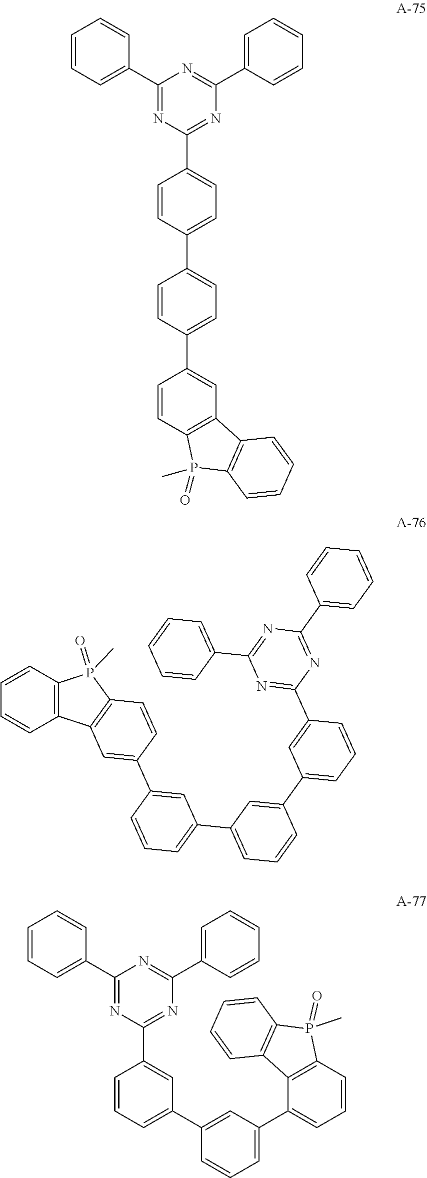 [SMILES: CP1(=O)c2ccccc2-c2cc(-c3ccc(-c4ccc(-c5nc(-c6ccccc6)nc(-c6ccccc6)n5)cc4)cc3)ccc21 ; CP1(=O)c2ccccc2-c2cc(-c3cccc(-c4cccc(-c5cccc(-c6nc(-c7ccccc7)nc(-c7ccccc7)n6)c5)c4)c3)ccc21 ; CP1(=O)c2ccccc2-c2c(-c3cccc(-c4cccc(-c5nc(-c6ccccc6)nc(-c6ccccc6)n5)c4)c3)cccc21] 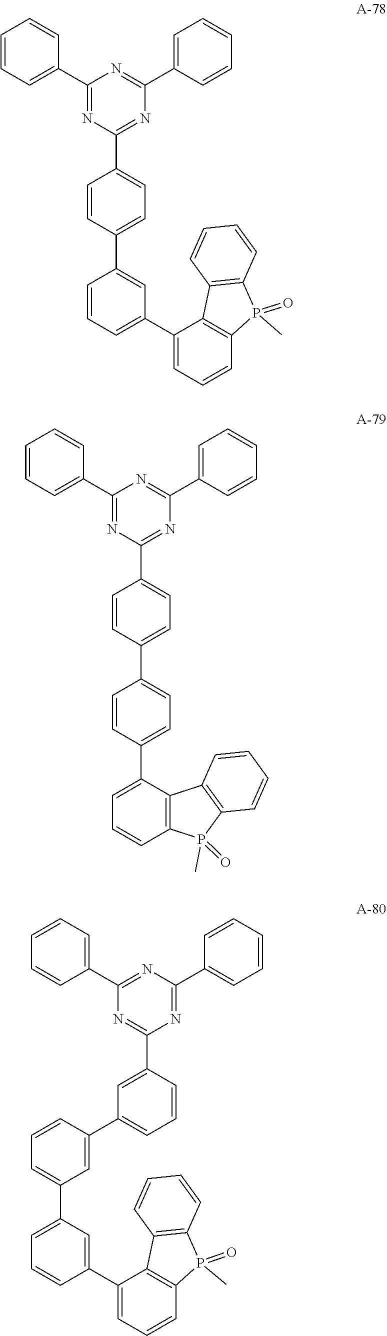 [SMILES: CP1(=O)c2ccccc2-c2c(-c3cccc(-c4ccc(-c5nc(-c6ccccc6)nc(-c6ccccc6)n5)cc4)c3)cccc21 ; CP1(=O)c2ccccc2-c2c(-c3ccc(-c4ccc(-c5nc(-c6ccccc6)nc(-c6ccccc6)n5)cc4)cc3)cccc21 ; CP1(=O)c2ccccc2-c2c(-c3cccc(-c4cccc(-c5cccc(-c6nc(-c7ccccc7)nc(-c7ccccc7)n6)c5)c4)c3)cccc21] 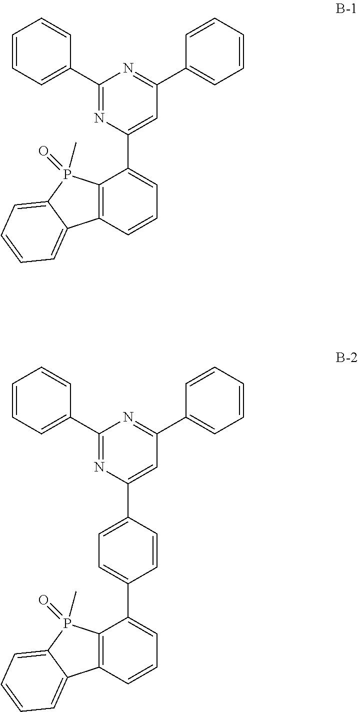 [SMILES: CP1(=O)c2ccccc2-c2cccc(-c3cc(-c4ccccc4)nc(-c4ccccc4)n3)c21 ; CP1(=O)c2ccccc2-c2cccc(-c3ccc(-c4cc(-c5ccccc5)nc(-c5ccccc5)n4)cc3)c21] 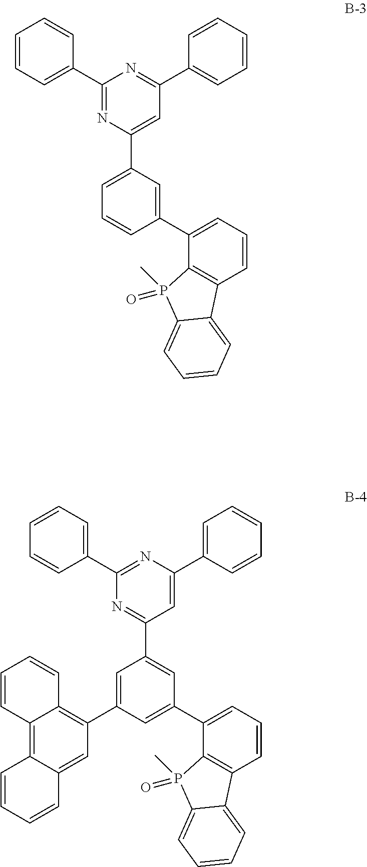 [SMILES: CP1(=O)c2ccccc2-c2cccc(-c3cccc(-c4cc(-c5ccccc5)nc(-c5ccccc5)n4)c3)c21 ; CP1(=O)c2ccccc2-c2cccc(-c3cc(-c4cc(-c5ccccc5)nc(-c5ccccc5)n4)cc(-c4cc5ccccc5c5ccccc45)c3)c21] 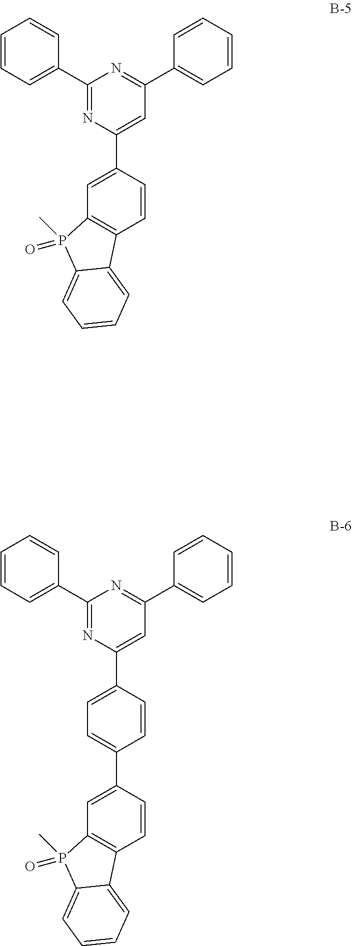 [SMILES: CP1(=O)c2ccccc2-c2ccc(-c3cc(-c4ccccc4)nc(-c4ccccc4)n3)cc21 ; CP1(=O)c2ccccc2-c2ccc(-c3ccc(-c4cc(-c5ccccc5)nc(-c5ccccc5)n4)cc3)cc21] 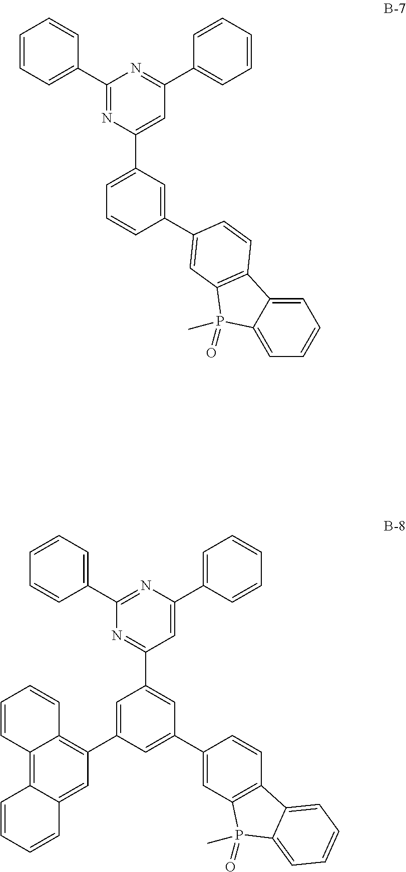 [SMILES: CP1(=O)c2ccccc2-c2ccc(-c3cccc(-c4cc(-c5ccccc5)nc(-c5ccccc5)n4)c3)cc21 ; CP1(=O)c2ccccc2-c2ccc(-c3cc(-c4cc(-c5ccccc5)nc(-c5ccccc5)n4)cc(-c4cc5ccccc5c5ccccc45)c3)cc21] 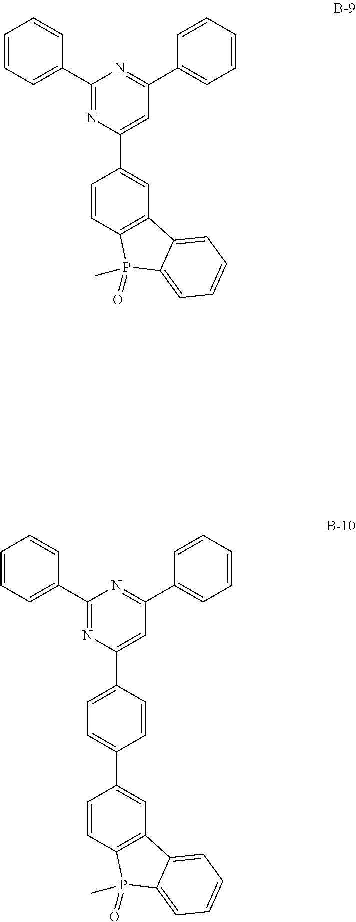 [SMILES: CP1(=O)c2ccccc2-c2cc(-c3cc(-c4ccccc4)nc(-c4ccccc4)n3)ccc21 ; CP1(=O)c2ccccc2-c2cc(-c3ccc(-c4cc(-c5ccccc5)nc(-c5ccccc5)n4)cc3)ccc21] 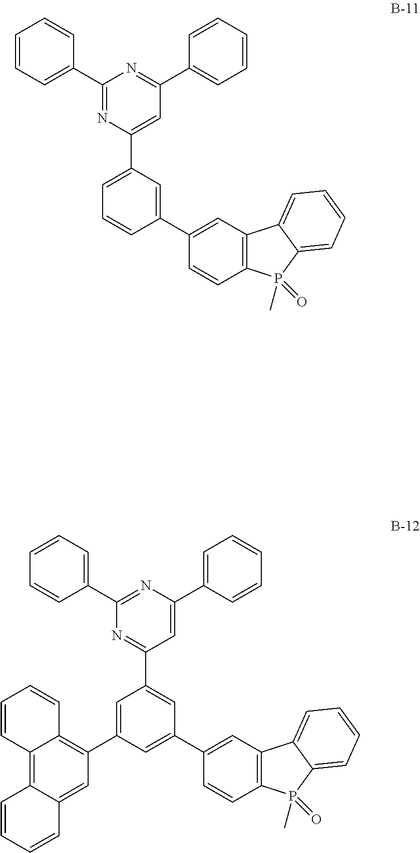 [SMILES: CP1(=O)c2ccccc2-c2cc(-c3cccc(-c4cc(-c5ccccc5)nc(-c5ccccc5)n4)c3)ccc21 ; CP1(=O)c2ccccc2-c2cc(-c3cc(-c4cc(-c5ccccc5)nc(-c5ccccc5)n4)cc(-c4cc5ccccc5c5ccccc45)c3)ccc21] 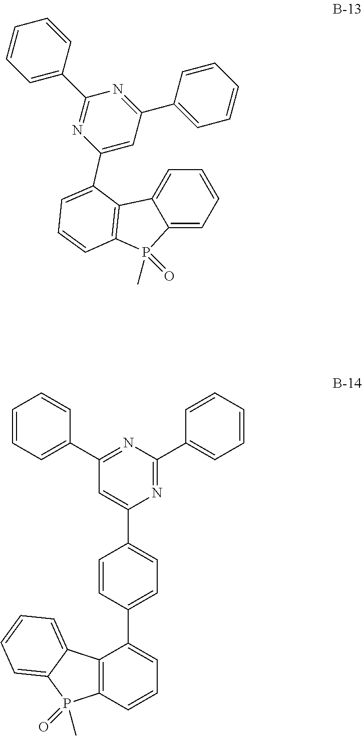 [SMILES: CP1(=O)c2ccccc2-c2c(-c3cc(-c4ccccc4)nc(-c4ccccc4)n3)cccc21 ; CP1(=O)c2ccccc2-c2c(-c3ccc(-c4cc(-c5ccccc5)nc(-c5ccccc5)n4)cc3)cccc21] 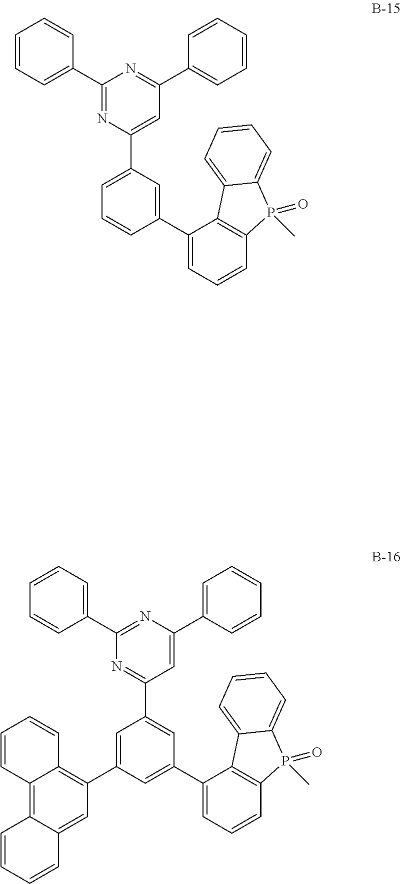 [SMILES: CP1(=O)c2ccccc2-c2c(-c3cccc(-c4cc(-c5ccccc5)nc(-c5ccccc5)n4)c3)cccc21 ; CP1(=O)c2ccccc2-c2c(-c3cc(-c4cc(-c5ccccc5)nc(-c5ccccc5)n4)cc(-c4cc5ccccc5c5ccccc45)c3)cccc21] 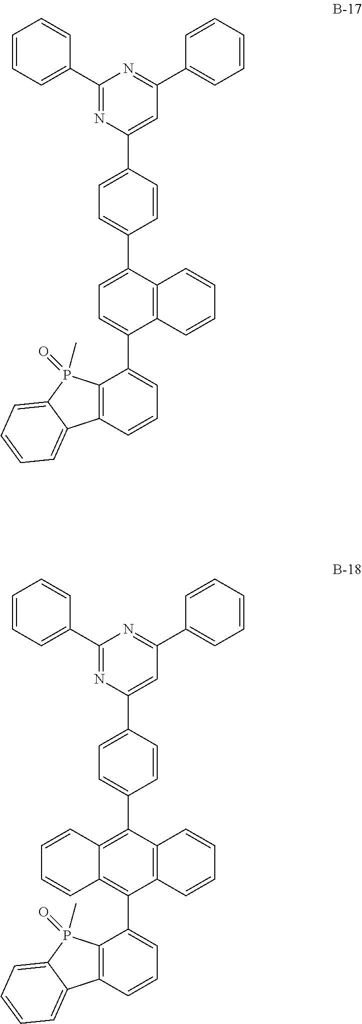 [SMILES: CP1(=O)c2ccccc2-c2cccc(-c3ccc(-c4ccc(-c5cc(-c6ccccc6)nc(-c6ccccc6)n5)cc4)c4ccccc34)c21 ; CP1(=O)c2ccccc2-c2cccc(-c3c4ccccc4c(-c4ccc(-c5cc(-c6ccccc6)nc(-c6ccccc6)n5)cc4)c4ccccc34)c21] 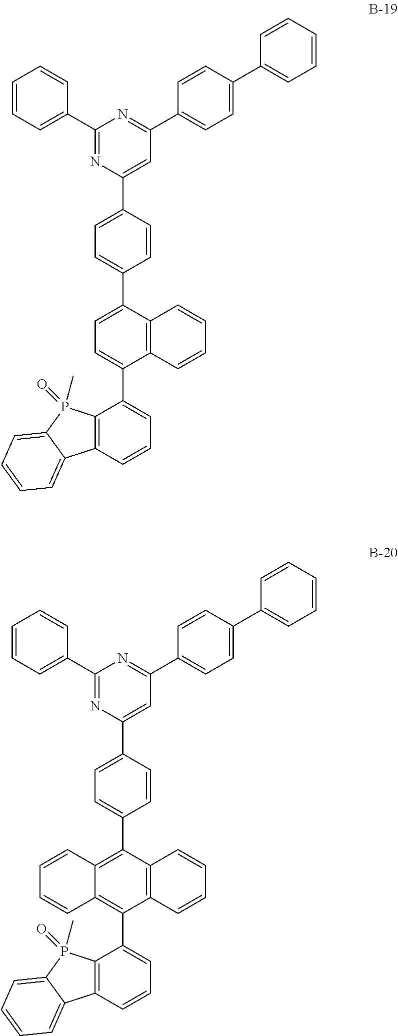 [SMILES: CP1(=O)c2ccccc2-c2cccc(-c3ccc(-c4ccc(-c5cc(-c6ccc(-c7ccccc7)cc6)nc(-c6ccccc6)n5)cc4)c4ccccc34)c21 ; CP1(=O)c2ccccc2-c2cccc(-c3c4ccccc4c(-c4ccc(-c5cc(-c6ccc(-c7ccccc7)cc6)nc(-c6ccccc6)n5)cc4)c4ccccc34)c21] 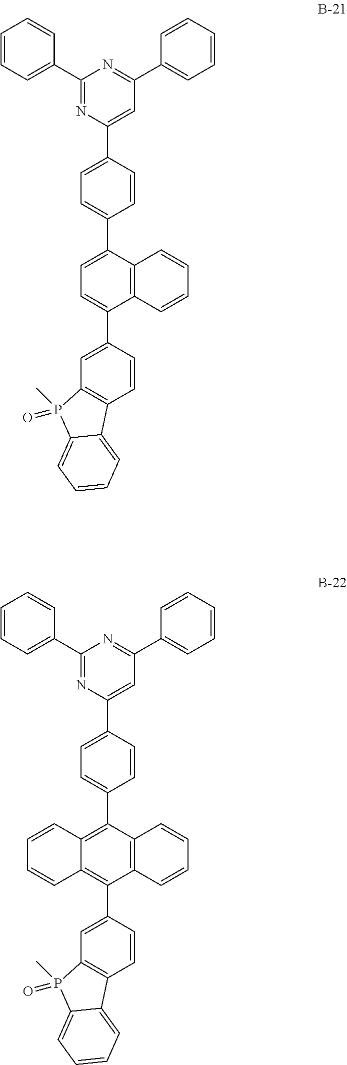 [SMILES: CP1(=O)c2ccccc2-c2ccc(-c3ccc(-c4ccc(-c5cc(-c6ccccc6)nc(-c6ccccc6)n5)cc4)c4ccccc34)cc21 ; CP1(=O)c2ccccc2-c2ccc(-c3c4ccccc4c(-c4ccc(-c5cc(-c6ccccc6)nc(-c6ccccc6)n5)cc4)c4ccccc34)cc21] 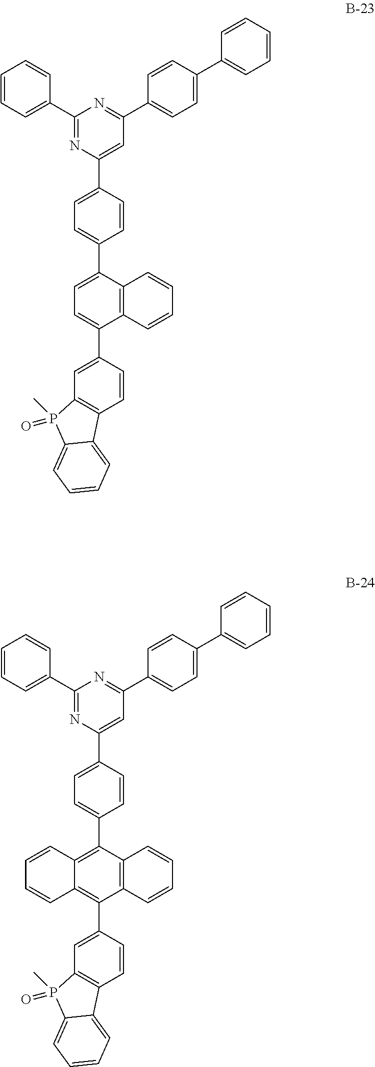 [SMILES: CP1(=O)c2ccccc2-c2ccc(-c3ccc(-c4ccc(-c5cc(-c6ccc(-c7ccccc7)cc6)nc(-c6ccccc6)n5)cc4)c4ccccc34)cc21 ; CP1(=O)c2ccccc2-c2ccc(-c3c4ccccc4c(-c4ccc(-c5cc(-c6ccc(-c7ccccc7)cc6)nc(-c6ccccc6)n5)cc4)c4ccccc34)cc21] 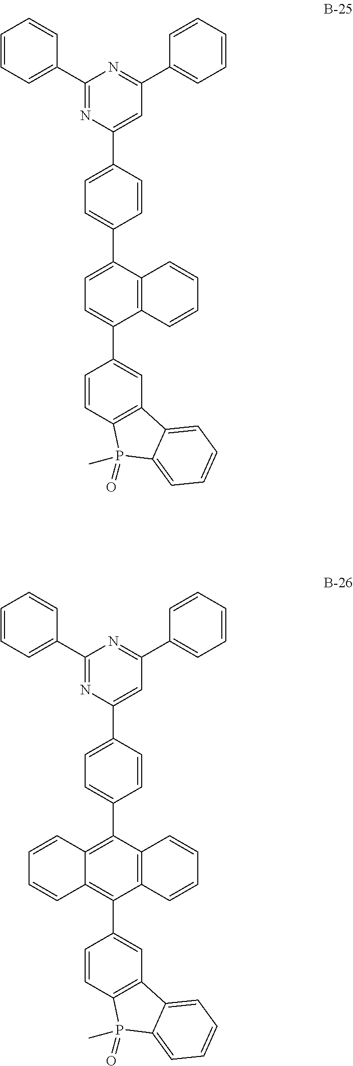 [SMILES: CP1(=O)c2ccccc2-c2cc(-c3ccc(-c4ccc(-c5cc(-c6ccccc6)nc(-c6ccccc6)n5)cc4)c4ccccc34)ccc21 ; CP1(=O)c2ccccc2-c2cc(-c3c4ccccc4c(-c4ccc(-c5cc(-c6ccccc6)nc(-c6ccccc6)n5)cc4)c4ccccc34)ccc21] 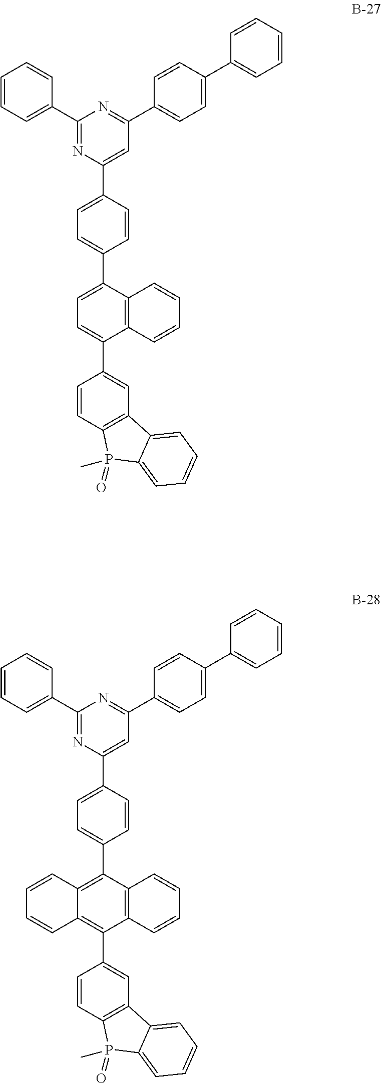 [SMILES: CP1(=O)c2ccccc2-c2cc(-c3ccc(-c4ccc(-c5cc(-c6ccc(-c7ccccc7)cc6)nc(-c6ccccc6)n5)cc4)c4ccccc34)ccc21 ; CP1(=O)c2ccccc2-c2cc(-c3c4ccccc4c(-c4ccc(-c5cc(-c6ccc(-c7ccccc7)cc6)nc(-c6ccccc6)n5)cc4)c4ccccc34)ccc21] 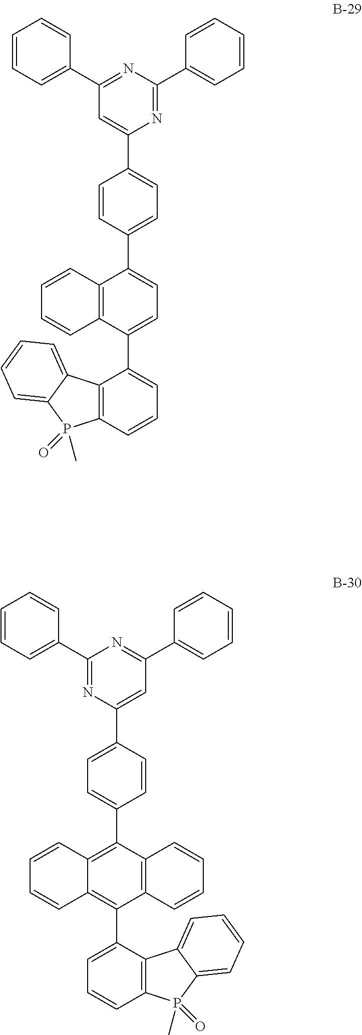 [SMILES: CP1(=O)c2ccccc2-c2c(-c3ccc(-c4ccc(-c5cc(-c6ccccc6)nc(-c6ccccc6)n5)cc4)c4ccccc34)cccc21 ; CP1(=O)c2ccccc2-c2c(-c3c4ccccc4c(-c4ccc(-c5cc(-c6ccccc6)nc(-c6ccccc6)n5)cc4)c4ccccc34)cccc21] 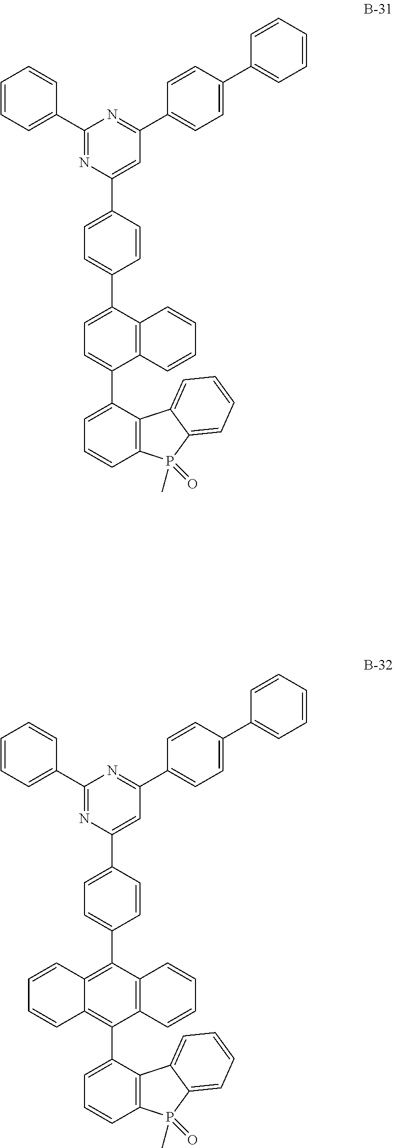 [SMILES: CP1(=O)c2ccccc2-c2c(-c3ccc(-c4ccc(-c5cc(-c6ccc(-c7ccccc7)cc6)nc(-c6ccccc6)n5)cc4)c4ccccc34)cccc21 ; CP1(=O)c2ccccc2-c2c(-c3c4ccccc4c(-c4ccc(-c5cc(-c6ccc(-c7ccccc7)cc6)nc(-c6ccccc6)n5)cc4)c4ccccc34)cccc21] 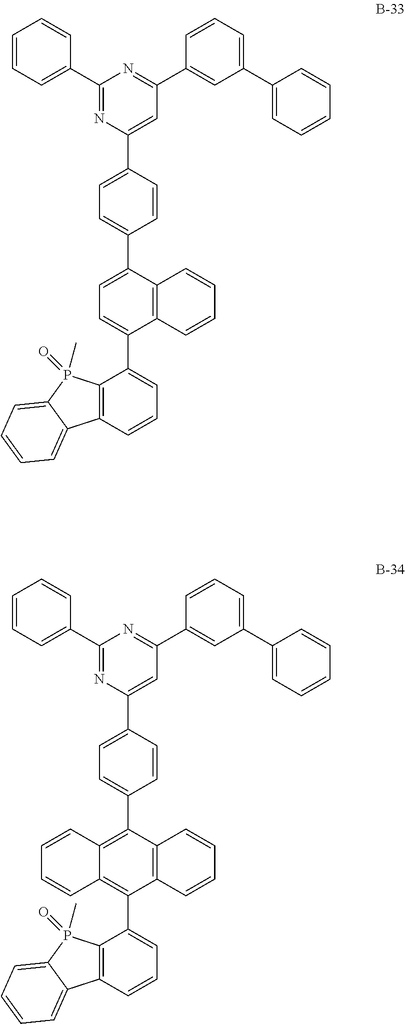 [SMILES: CP1(=O)c2ccccc2-c2cccc(-c3ccc(-c4ccc(-c5cc(-c6cccc(-c7ccccc7)c6)nc(-c6ccccc6)n5)cc4)c4ccccc34)c21 ; CP1(=O)c2ccccc2-c2cccc(-c3c4ccccc4c(-c4ccc(-c5cc(-c6cccc(-c7ccccc7)c6)nc(-c6ccccc6)n5)cc4)c4ccccc34)c21] 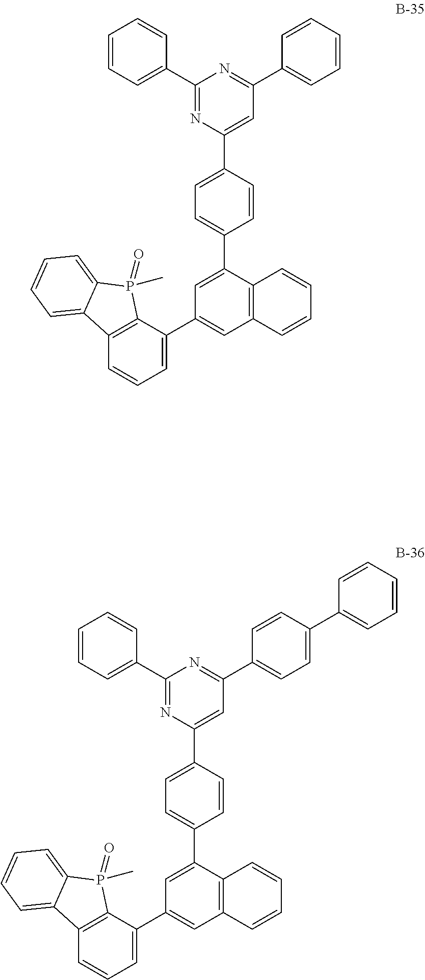 [SMILES: CP1(=O)c2ccccc2-c2cccc(-c3cc(-c4ccc(-c5cc(-c6ccccc6)nc(-c6ccccc6)n5)cc4)c4ccccc4c3)c21 ; CP1(=O)c2ccccc2-c2cccc(-c3cc(-c4ccc(-c5cc(-c6ccc(-c7ccccc7)cc6)nc(-c6ccccc6)n5)cc4)c4ccccc4c3)c21] 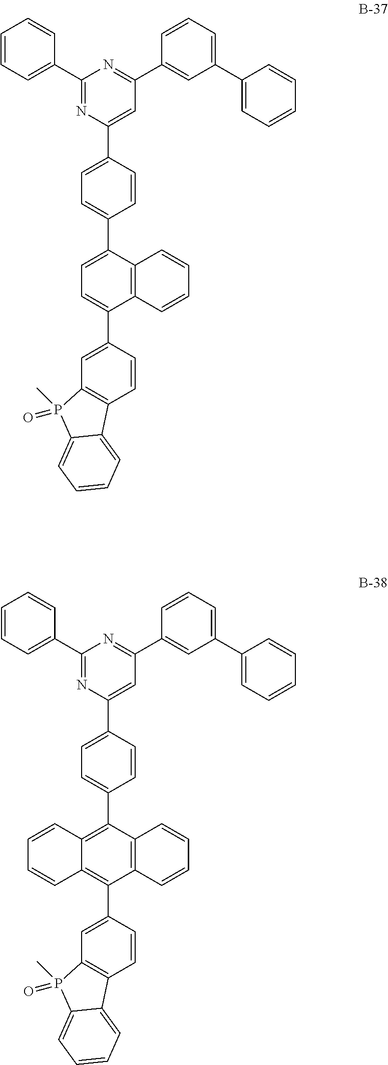 [SMILES: CP1(=O)c2ccccc2-c2ccc(-c3ccc(-c4ccc(-c5cc(-c6cccc(-c7ccccc7)c6)nc(-c6ccccc6)n5)cc4)c4ccccc34)cc21 ; CP1(=O)c2ccccc2-c2ccc(-c3c4ccccc4c(-c4ccc(-c5cc(-c6cccc(-c7ccccc7)c6)nc(-c6ccccc6)n5)cc4)c4ccccc34)cc21] 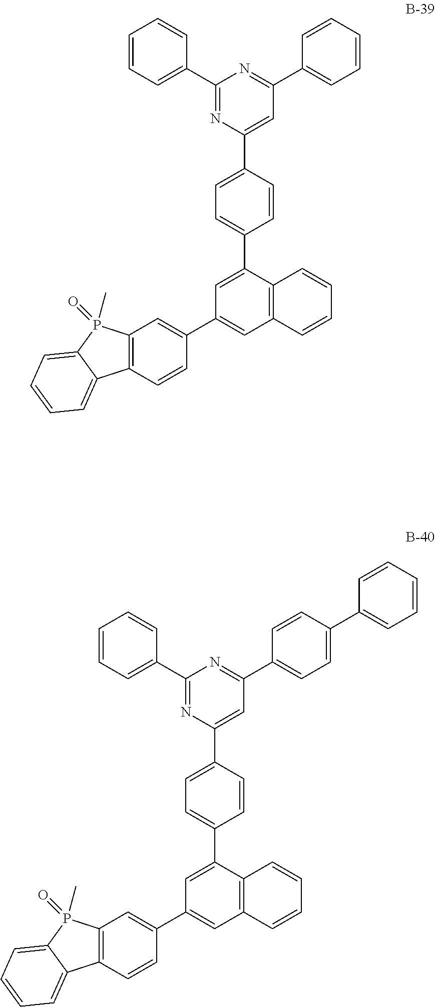 [SMILES: CP1(=O)c2ccccc2-c2ccc(-c3cc(-c4ccc(-c5cc(-c6ccccc6)nc(-c6ccccc6)n5)cc4)c4ccccc4c3)cc21 ; CP1(=O)c2ccccc2-c2ccc(-c3cc(-c4ccc(-c5cc(-c6ccc(-c7ccccc7)cc6)nc(-c6ccccc6)n5)cc4)c4ccccc4c3)cc21] 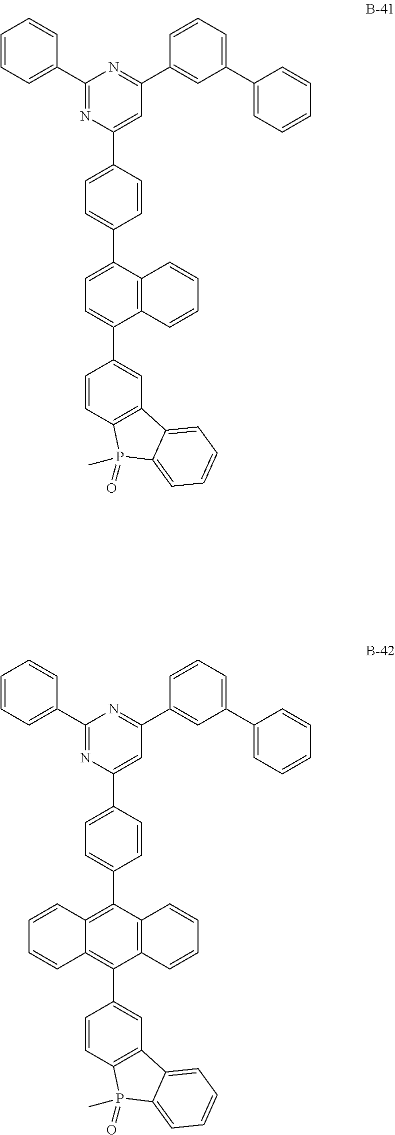 [SMILES: CP1(=O)c2ccccc2-c2cc(-c3ccc(-c4ccc(-c5cc(-c6cccc(-c7ccccc7)c6)nc(-c6ccccc6)n5)cc4)c4ccccc34)ccc21 ; CP1(=O)c2ccccc2-c2cc(-c3c4ccccc4c(-c4ccc(-c5cc(-c6cccc(-c7ccccc7)c6)nc(-c6ccccc6)n5)cc4)c4ccccc34)ccc21] 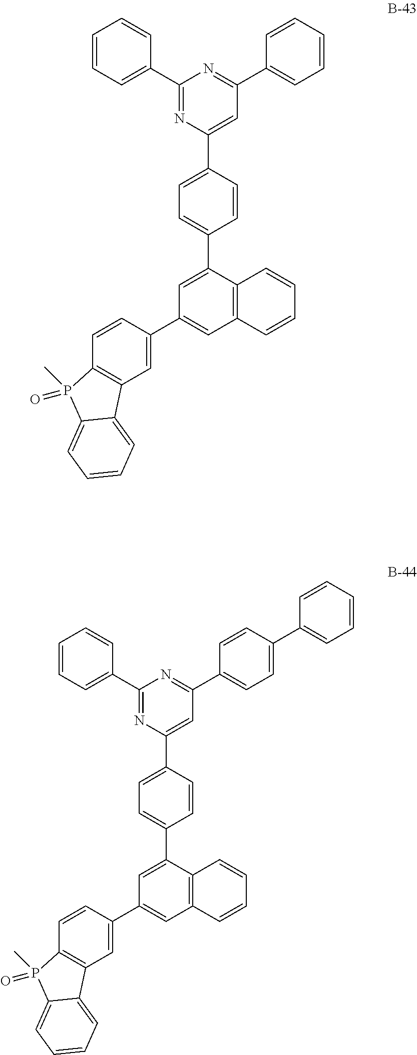 [SMILES: CP1(=O)c2ccccc2-c2cc(-c3cc(-c4ccc(-c5cc(-c6ccccc6)nc(-c6ccccc6)n5)cc4)c4ccccc4c3)ccc21 ; CP1(=O)c2ccccc2-c2cc(-c3cc(-c4ccc(-c5cc(-c6ccc(-c7ccccc7)cc6)nc(-c6ccccc6)n5)cc4)c4ccccc4c3)ccc21] 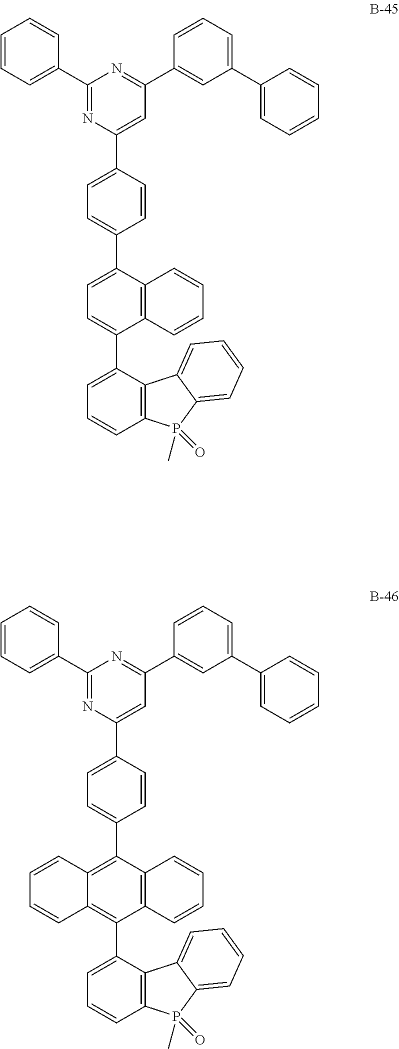 [SMILES: CP1(=O)c2ccccc2-c2c(-c3ccc(-c4ccc(-c5cc(-c6cccc(-c7ccccc7)c6)nc(-c6ccccc6)n5)cc4)c4ccccc34)cccc21 ; CP1(=O)c2ccccc2-c2c(-c3c4ccccc4c(-c4ccc(-c5cc(-c6cccc(-c7ccccc7)c6)nc(-c6ccccc6)n5)cc4)c4ccccc34)cccc21] 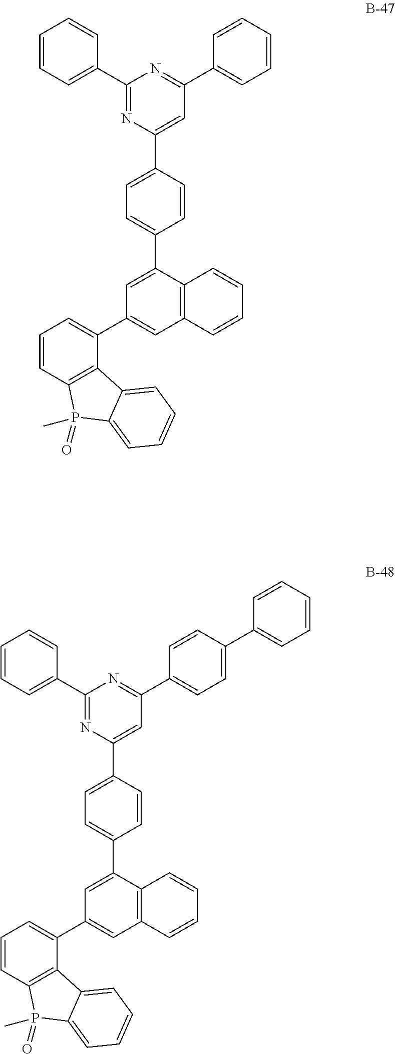 [SMILES: CP1(=O)c2ccccc2-c2c(-c3cc(-c4ccc(-c5cc(-c6ccccc6)nc(-c6ccccc6)n5)cc4)c4ccccc4c3)cccc21 ; CP1(=O)c2ccccc2-c2c(-c3cc(-c4ccc(-c5cc(-c6ccc(-c7ccccc7)cc6)nc(-c6ccccc6)n5)cc4)c4ccccc4c3)cccc21] 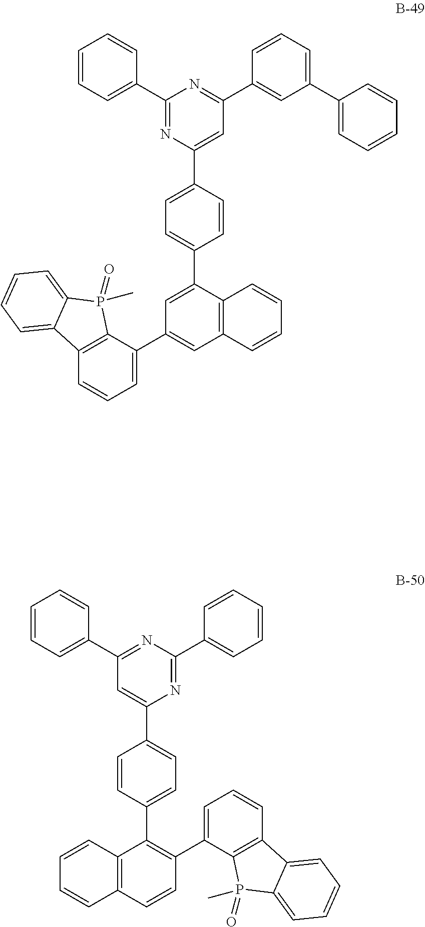 [SMILES: CP1(=O)c2ccccc2-c2cccc(-c3cc(-c4ccc(-c5cc(-c6cccc(-c7ccccc7)c6)nc(-c6ccccc6)n5)cc4)c4ccccc4c3)c21 ; CP1(=O)c2ccccc2-c2cccc(-c3ccc4ccccc4c3-c3ccc(-c4cc(-c5ccccc5)nc(-c5ccccc5)n4)cc3)c21] 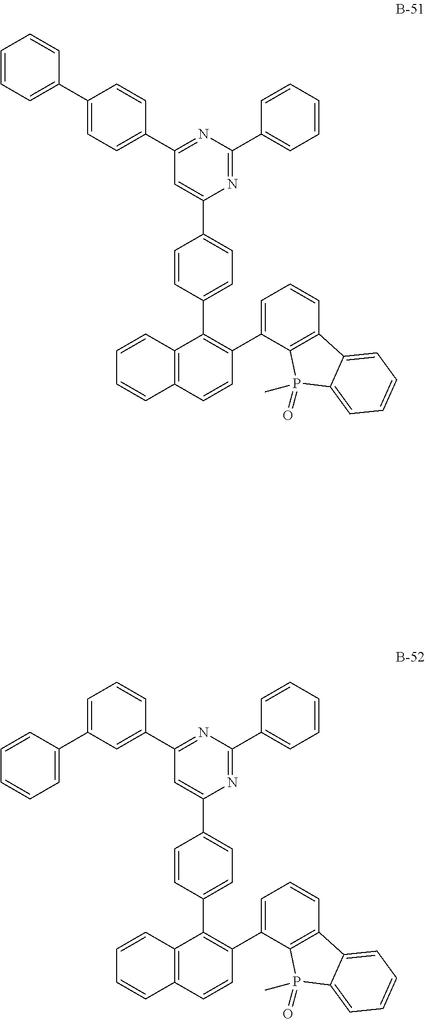 [SMILES: CP1(=O)c2ccccc2-c2cccc(-c3ccc4ccccc4c3-c3ccc(-c4cc(-c5ccc(-c6ccccc6)cc5)nc(-c5ccccc5)n4)cc3)c21 ; CP1(=O)c2ccccc2-c2cccc(-c3ccc4ccccc4c3-c3ccc(-c4cc(-c5cccc(-c6ccccc6)c5)nc(-c5ccccc5)n4)cc3)c21] 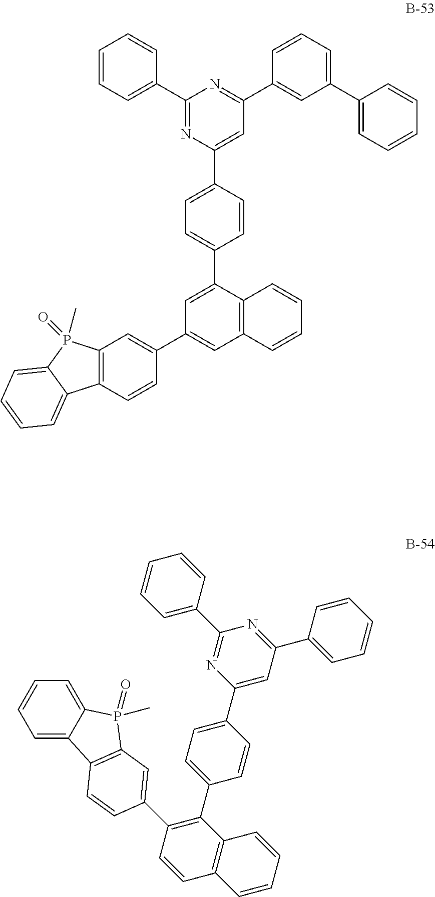 [SMILES: CP1(=O)c2ccccc2-c2ccc(-c3cc(-c4ccc(-c5cc(-c6cccc(-c7ccccc7)c6)nc(-c6ccccc6)n5)cc4)c4ccccc4c3)cc21 ; CP1(=O)c2ccccc2-c2ccc(-c3ccc4ccccc4c3-c3ccc(-c4cc(-c5ccccc5)nc(-c5ccccc5)n4)cc3)cc21] 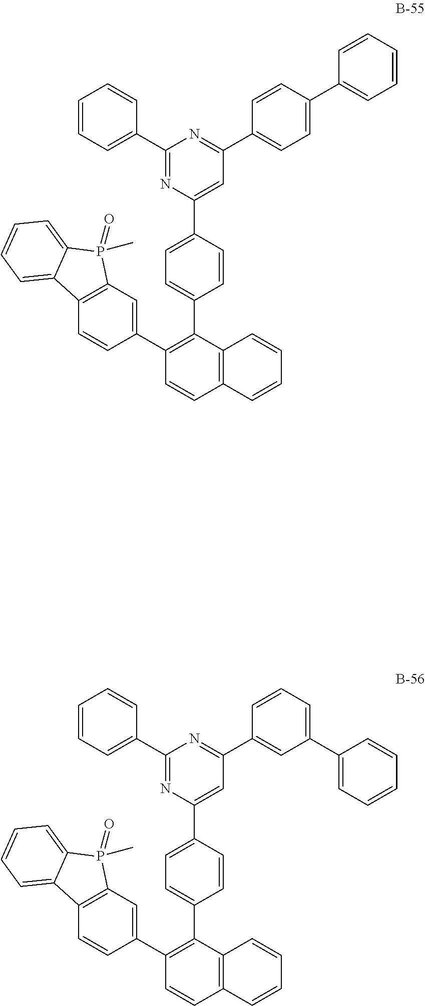 [SMILES: CP1(=O)c2ccccc2-c2ccc(-c3ccc4ccccc4c3-c3ccc(-c4cc(-c5ccc(-c6ccccc6)cc5)nc(-c5ccccc5)n4)cc3)cc21 ; CP1(=O)c2ccccc2-c2ccc(-c3ccc4ccccc4c3-c3ccc(-c4cc(-c5cccc(-c6ccccc6)c5)nc(-c5ccccc5)n4)cc3)cc21] 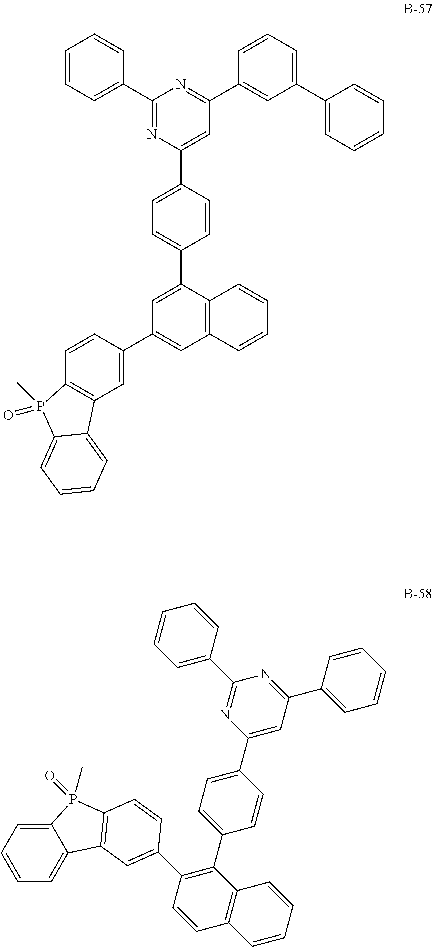 [SMILES: CP1(=O)c2ccccc2-c2cc(-c3cc(-c4ccc(-c5cc(-c6cccc(-c7ccccc7)c6)nc(-c6ccccc6)n5)cc4)c4ccccc4c3)ccc21 ; CP1(=O)c2ccccc2-c2cc(-c3ccc4ccccc4c3-c3ccc(-c4cc(-c5ccccc5)nc(-c5ccccc5)n4)cc3)ccc21] 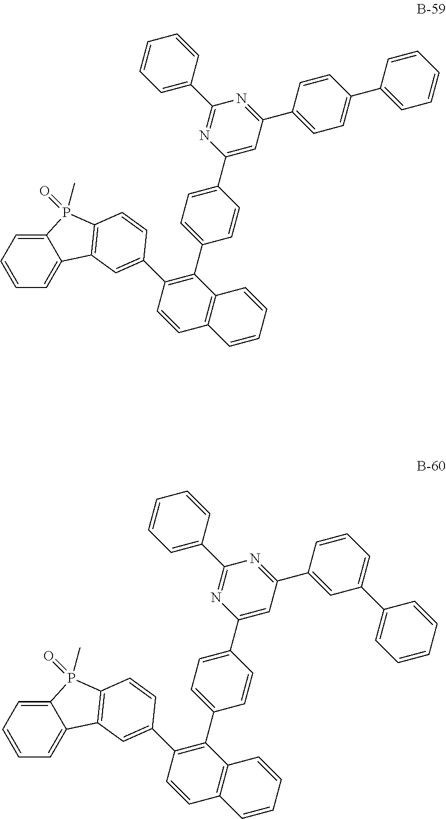 [SMILES: CP1(=O)c2ccccc2-c2cc(-c3ccc4ccccc4c3-c3ccc(-c4cc(-c5ccc(-c6ccccc6)cc5)nc(-c5ccccc5)n4)cc3)ccc21 ; CP1(=O)c2ccccc2-c2cc(-c3ccc4ccccc4c3-c3ccc(-c4cc(-c5cccc(-c6ccccc6)c5)nc(-c5ccccc5)n4)cc3)ccc21] 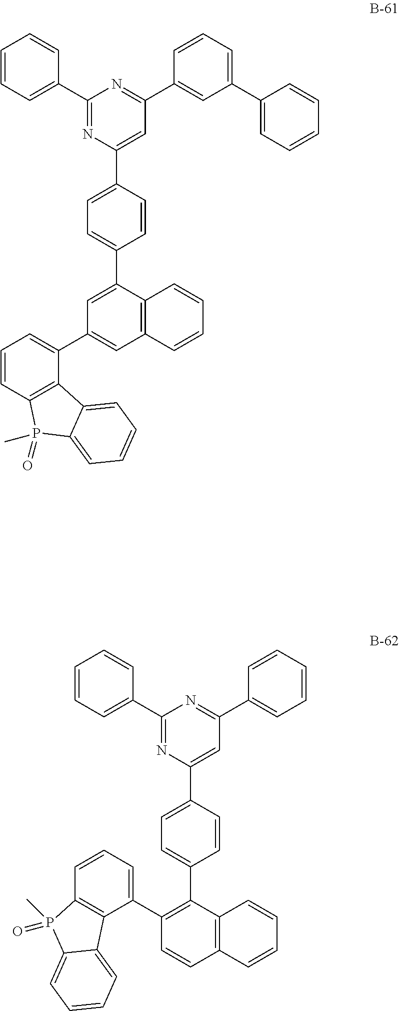 [SMILES: CP1(=O)c2ccccc2-c2c(-c3cc(-c4ccc(-c5cc(-c6cccc(-c7ccccc7)c6)nc(-c6ccccc6)n5)cc4)c4ccccc4c3)cccc21 ; CP1(=O)c2ccccc2-c2c(-c3ccc4ccccc4c3-c3ccc(-c4cc(-c5ccccc5)nc(-c5ccccc5)n4)cc3)cccc21] 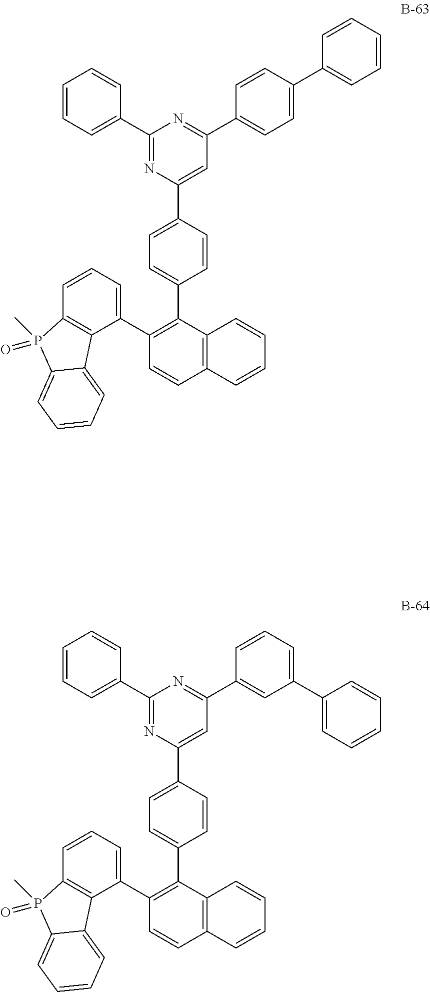 [SMILES: CP1(=O)c2ccccc2-c2c(-c3ccc4ccccc4c3-c3ccc(-c4cc(-c5ccc(-c6ccccc6)cc5)nc(-c5ccccc5)n4)cc3)cccc21 ; CP1(=O)c2ccccc2-c2c(-c3ccc4ccccc4c3-c3ccc(-c4cc(-c5cccc(-c6ccccc6)c5)nc(-c5ccccc5)n4)cc3)cccc21] 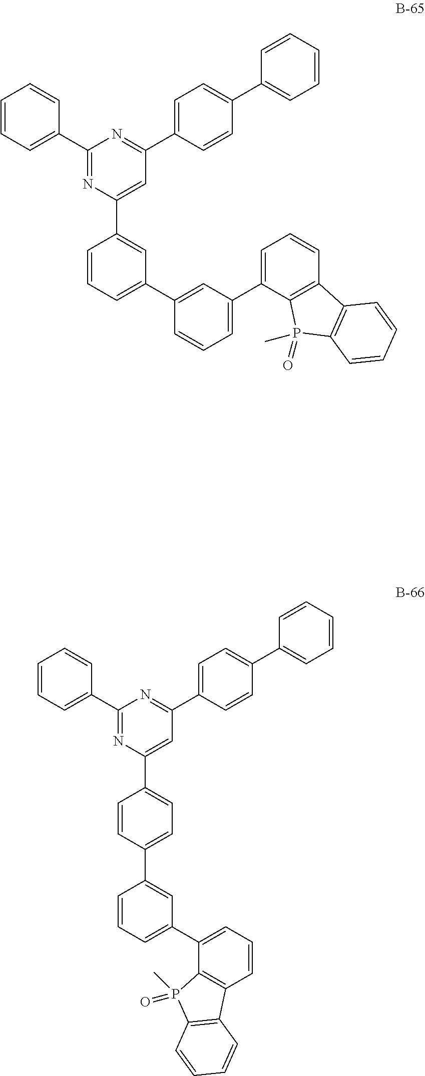 [SMILES: CP1(=O)c2ccccc2-c2cccc(-c3cccc(-c4cccc(-c5cc(-c6ccc(-c7ccccc7)cc6)nc(-c6ccccc6)n5)c4)c3)c21 ; CP1(=O)c2ccccc2-c2cccc(-c3cccc(-c4ccc(-c5cc(-c6ccc(-c7ccccc7)cc6)nc(-c6ccccc6)n5)cc4)c3)c21] 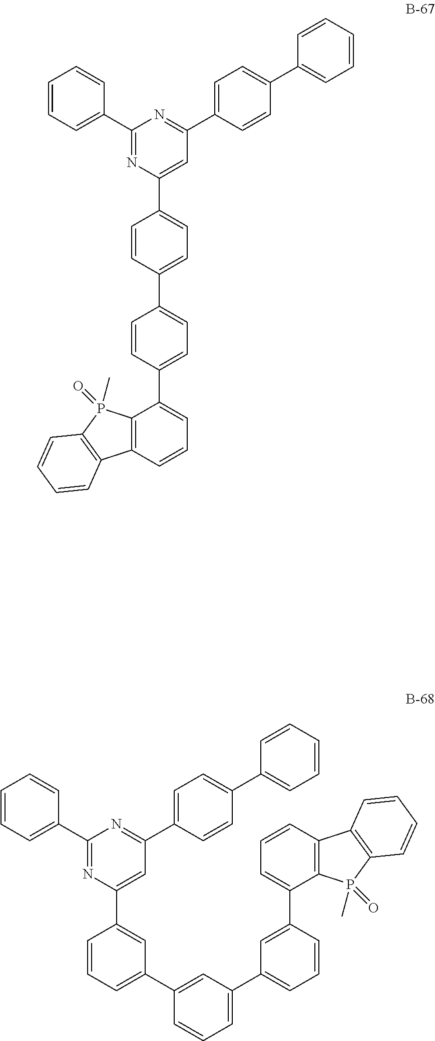 [SMILES: CP1(=O)c2ccccc2-c2cccc(-c3ccc(-c4ccc(-c5cc(-c6ccc(-c7ccccc7)cc6)nc(-c6ccccc6)n5)cc4)cc3)c21 ; CP1(=O)c2ccccc2-c2cccc(-c3cccc(-c4cccc(-c5cccc(-c6cc(-c7ccc(-c8ccccc8)cc7)nc(-c7ccccc7)n6)c5)c4)c3)c21] 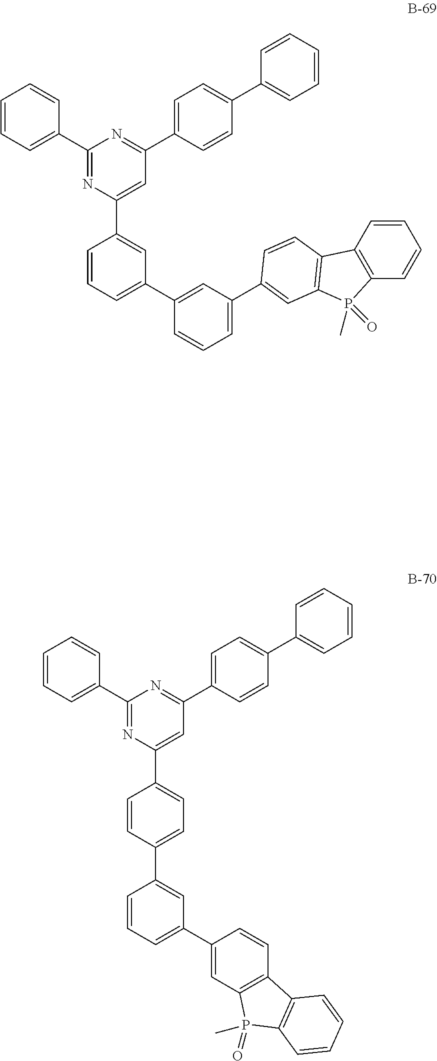 [SMILES: CP1(=O)c2ccccc2-c2ccc(-c3cccc(-c4cccc(-c5cc(-c6ccc(-c7ccccc7)cc6)nc(-c6ccccc6)n5)c4)c3)cc21 ; CP1(=O)c2ccccc2-c2ccc(-c3cccc(-c4ccc(-c5cc(-c6ccc(-c7ccccc7)cc6)nc(-c6ccccc6)n5)cc4)c3)cc21] 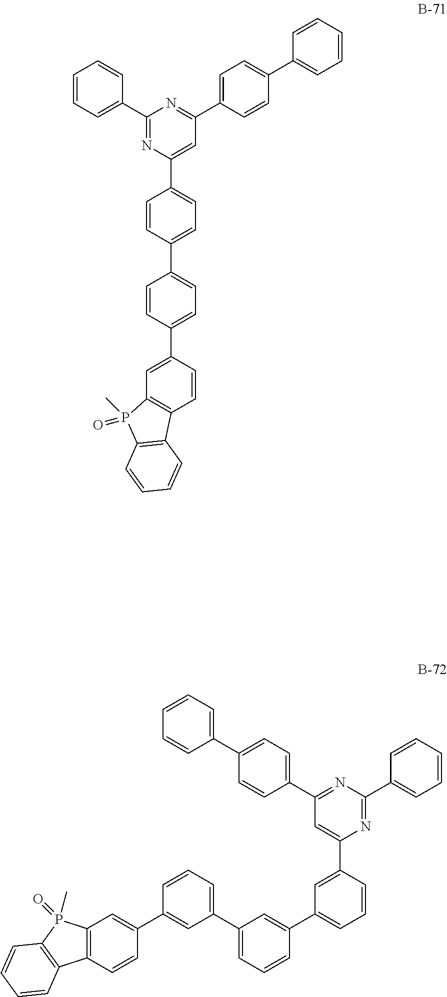 [SMILES: CP1(=O)c2ccccc2-c2ccc(-c3ccc(-c4ccc(-c5cc(-c6ccc(-c7ccccc7)cc6)nc(-c6ccccc6)n5)cc4)cc3)cc21 ; CP1(=O)c2ccccc2-c2ccc(-c3cccc(-c4cccc(-c5cccc(-c6cc(-c7ccc(-c8ccccc8)cc7)nc(-c7ccccc7)n6)c5)c4)c3)cc21] 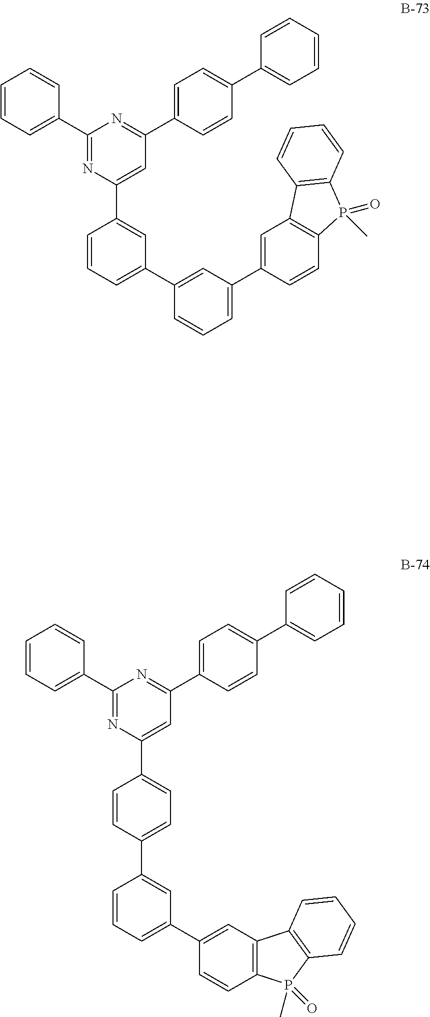 [SMILES: CP1(=O)c2ccccc2-c2cc(-c3cccc(-c4cccc(-c5cc(-c6ccc(-c7ccccc7)cc6)nc(-c6ccccc6)n5)c4)c3)ccc21 ; CP1(=O)c2ccccc2-c2cc(-c3cccc(-c4ccc(-c5cc(-c6ccc(-c7ccccc7)cc6)nc(-c6ccccc6)n5)cc4)c3)ccc21] 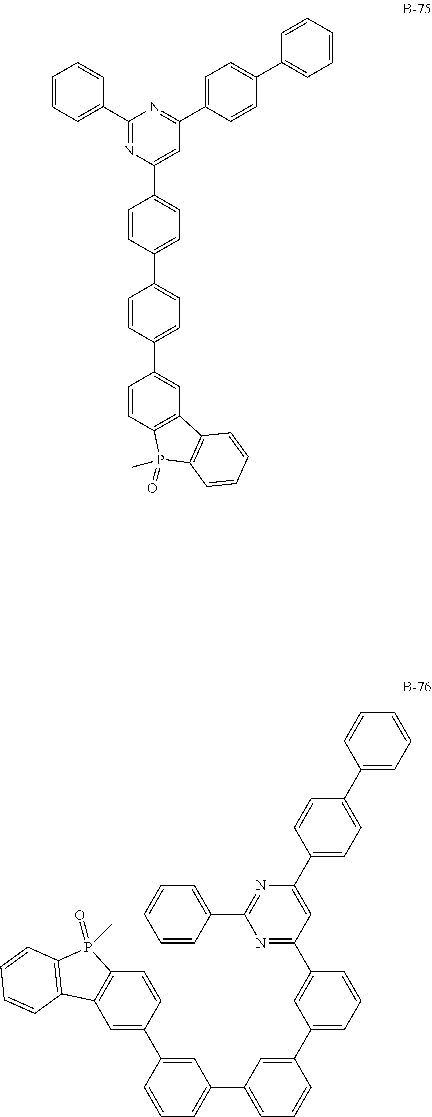 [SMILES: CP1(=O)c2ccccc2-c2cc(-c3ccc(-c4ccc(-c5cc(-c6ccc(-c7ccccc7)cc6)nc(-c6ccccc6)n5)cc4)cc3)ccc21 ; CP1(=O)c2ccccc2-c2cc(-c3cccc(-c4cccc(-c5cccc(-c6cc(-c7ccc(-c8ccccc8)cc7)nc(-c7ccccc7)n6)c5)c4)c3)ccc21] 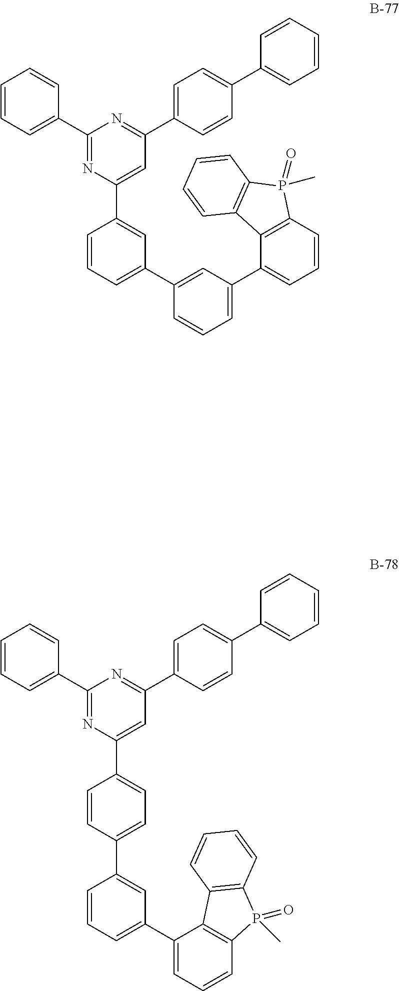 [SMILES: CP1(=O)c2ccccc2-c2c(-c3cccc(-c4cccc(-c5cc(-c6ccc(-c7ccccc7)cc6)nc(-c6ccccc6)n5)c4)c3)cccc21 ; CP1(=O)c2ccccc2-c2c(-c3cccc(-c4ccc(-c5cc(-c6ccc(-c7ccccc7)cc6)nc(-c6ccccc6)n5)cc4)c3)cccc21] 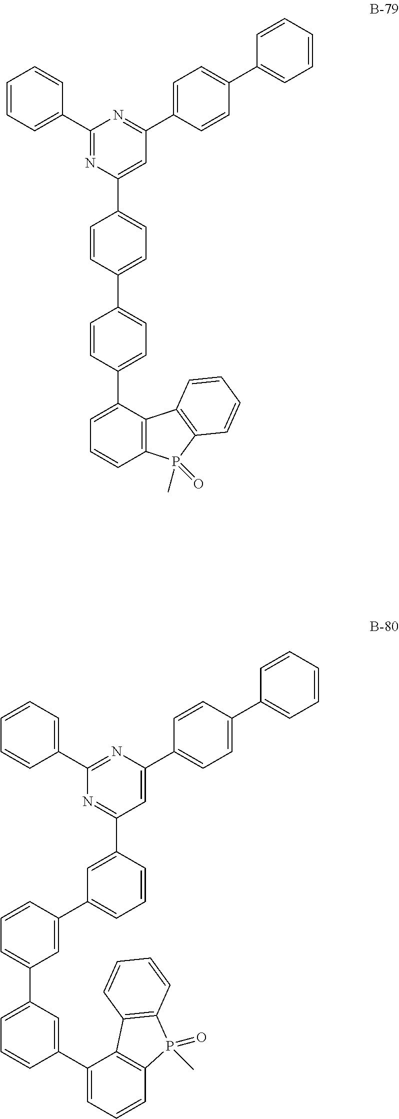 [SMILES: CP1(=O)c2ccccc2-c2c(-c3ccc(-c4ccc(-c5cc(-c6ccc(-c7ccccc7)cc6)nc(-c6ccccc6)n5)cc4)cc3)cccc21 ; CP1(=O)c2ccccc2-c2c(-c3cccc(-c4cccc(-c5cccc(-c6cc(-c7ccc(-c8ccccc8)cc7)nc(-c7ccccc7)n6)c5)c4)c3)cccc21] 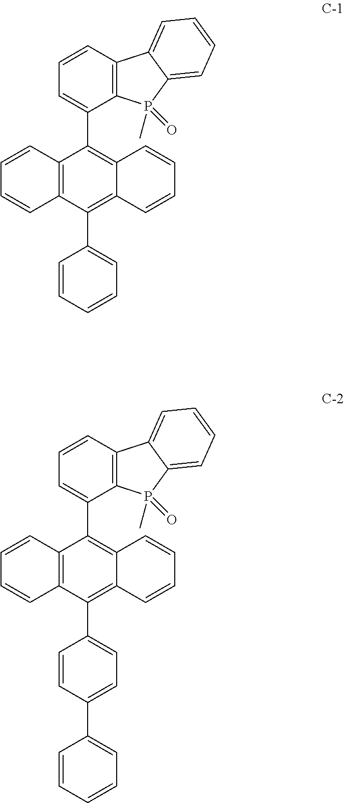 [SMILES: CP1(=O)c2ccccc2-c2cccc(-c3c4ccccc4c(-c4ccccc4)c4ccccc34)c21 ; CP1(=O)c2ccccc2-c2cccc(-c3c4ccccc4c(-c4ccc(-c5ccccc5)cc4)c4ccccc34)c21] 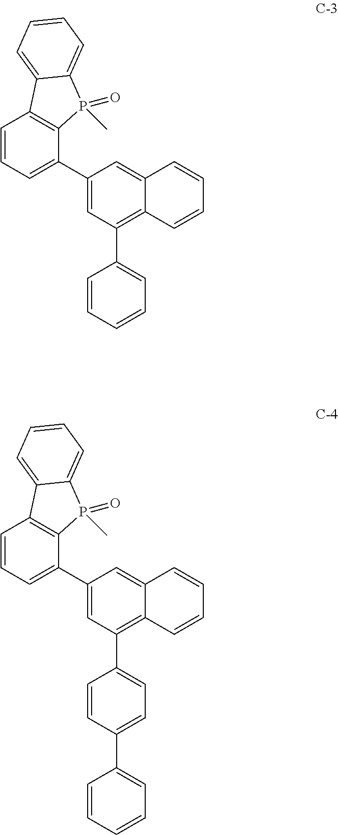 [SMILES: CP1(=O)c2ccccc2-c2cccc(-c3cc(-c4ccccc4)c4ccccc4c3)c21 ; CP1(=O)c2ccccc2-c2cccc(-c3cc(-c4ccc(-c5ccccc5)cc4)c4ccccc4c3)c21] 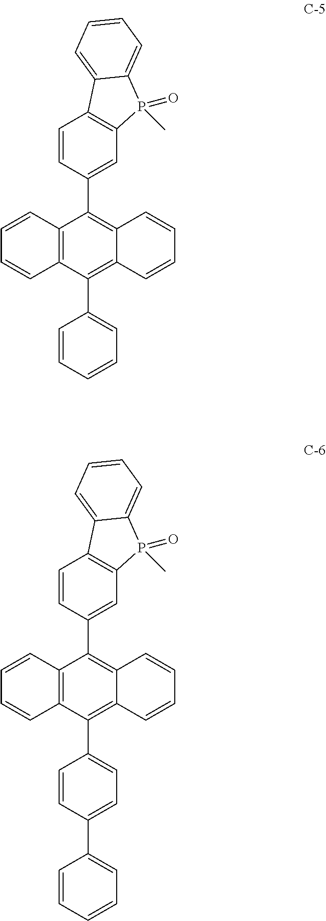 [SMILES: CP1(=O)c2ccccc2-c2ccc(-c3c4ccccc4c(-c4ccccc4)c4ccccc34)cc21 ; CP1(=O)c2ccccc2-c2ccc(-c3c4ccccc4c(-c4ccc(-c5ccccc5)cc4)c4ccccc34)cc21] 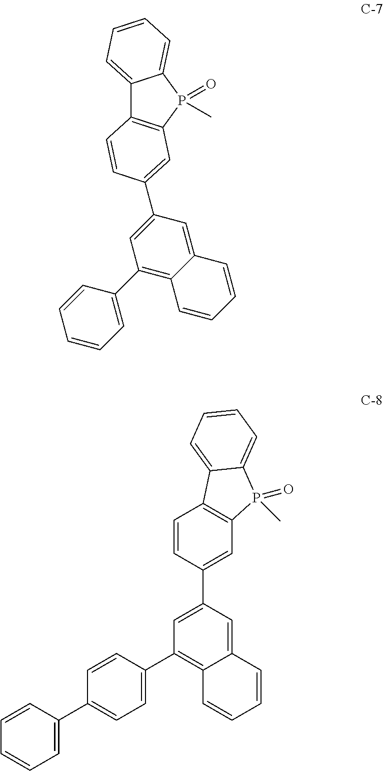 [SMILES: CP1(=O)c2ccccc2-c2ccc(-c3cc(-c4ccccc4)c4ccccc4c3)cc21 ; CP1(=O)c2ccccc2-c2ccc(-c3cc(-c4ccc(-c5ccccc5)cc4)c4ccccc4c3)cc21] 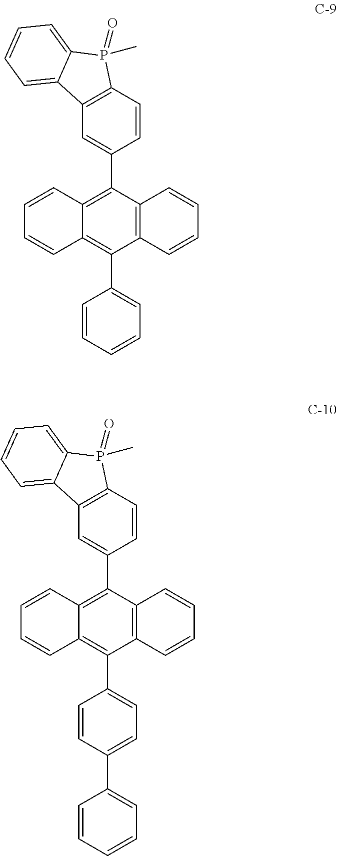 [SMILES: CP1(=O)c2ccccc2-c2cc(-c3c4ccccc4c(-c4ccccc4)c4ccccc34)ccc21 ; CP1(=O)c2ccccc2-c2cc(-c3c4ccccc4c(-c4ccc(-c5ccccc5)cc4)c4ccccc34)ccc21] 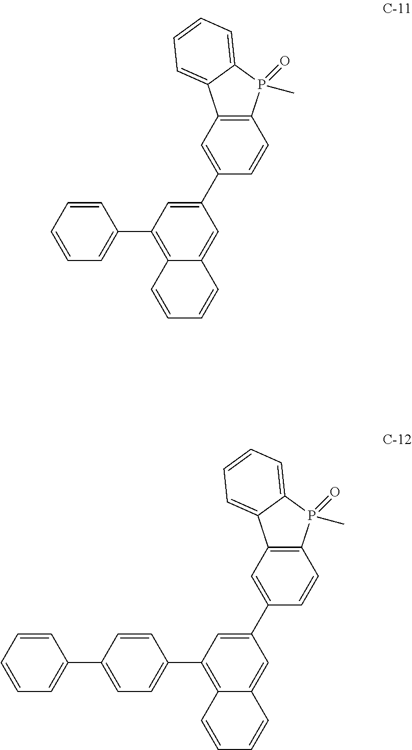 [SMILES: CP1(=O)c2ccccc2-c2cc(-c3cc(-c4ccccc4)c4ccccc4c3)ccc21 ; CP1(=O)c2ccccc2-c2cc(-c3cc(-c4ccc(-c5ccccc5)cc4)c4ccccc4c3)ccc21] 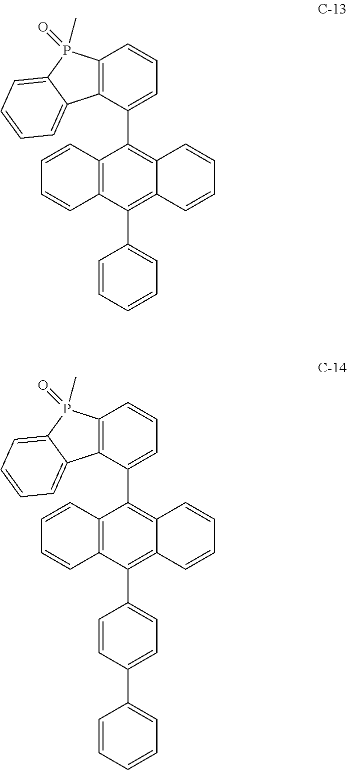 [SMILES: CP1(=O)c2ccccc2-c2c(-c3c4ccccc4c(-c4ccccc4)c4ccccc34)cccc21 ; CP1(=O)c2ccccc2-c2c(-c3c4ccccc4c(-c4ccc(-c5ccccc5)cc4)c4ccccc34)cccc21] 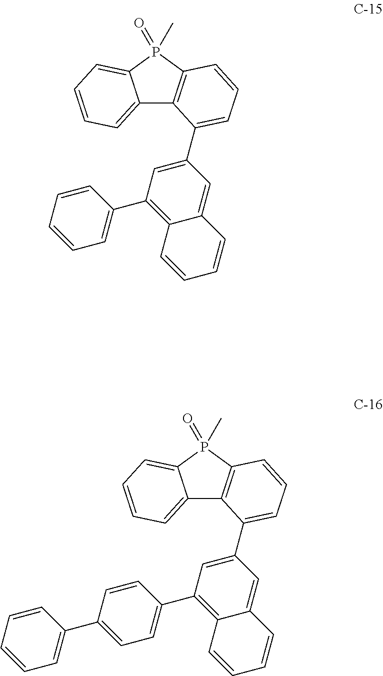 [SMILES: CP1(=O)c2ccccc2-c2c(-c3cc(-c4ccccc4)c4ccccc4c3)cccc21 ; CP1(=O)c2ccccc2-c2c(-c3cc(-c4ccc(-c5ccccc5)cc4)c4ccccc4c3)cccc21] 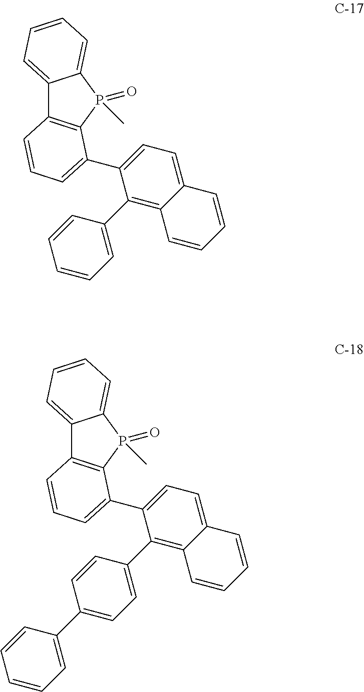 [SMILES: CP1(=O)c2ccccc2-c2cccc(-c3ccc4ccccc4c3-c3ccccc3)c21 ; CP1(=O)c2ccccc2-c2cccc(-c3ccc4ccccc4c3-c3ccc(-c4ccccc4)cc3)c21] 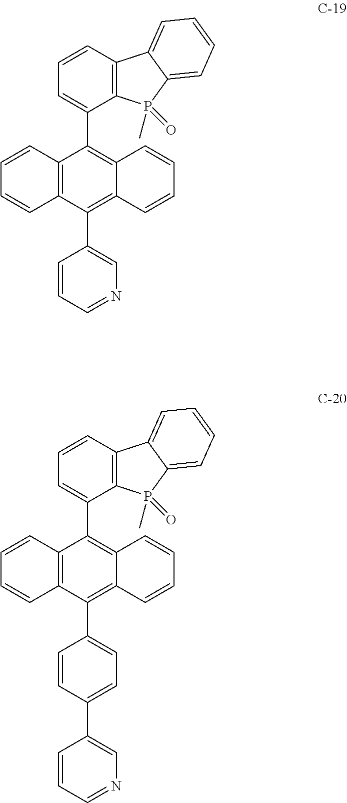 [SMILES: CP1(=O)c2ccccc2-c2cccc(-c3c4ccccc4c(-c4cccnc4)c4ccccc34)c21 ; CP1(=O)c2ccccc2-c2cccc(-c3c4ccccc4c(-c4ccc(-c5cccnc5)cc4)c4ccccc34)c21] 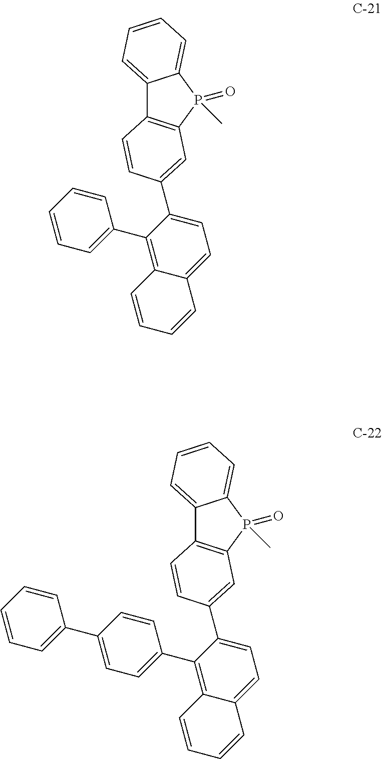 [SMILES: CP1(=O)c2ccccc2-c2ccc(-c3ccc4ccccc4c3-c3ccccc3)cc21 ; CP1(=O)c2ccccc2-c2ccc(-c3ccc4ccccc4c3-c3ccc(-c4ccccc4)cc3)cc21] 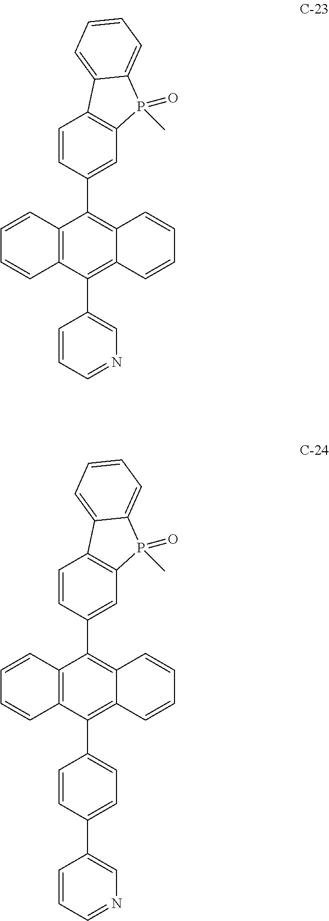 [SMILES: CP1(=O)c2ccccc2-c2ccc(-c3c4ccccc4c(-c4cccnc4)c4ccccc34)cc21 ; CP1(=O)c2ccccc2-c2ccc(-c3c4ccccc4c(-c4ccc(-c5cccnc5)cc4)c4ccccc34)cc21] 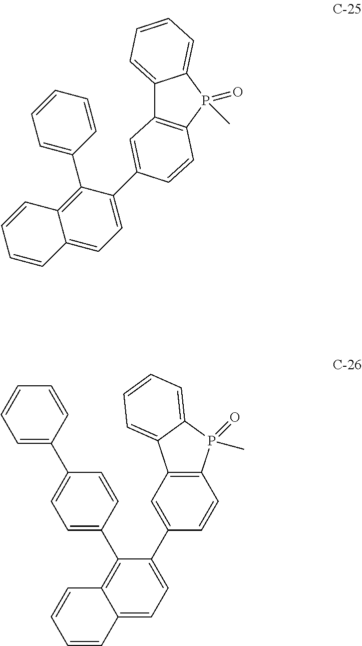 [SMILES: CP1(=O)c2ccccc2-c2cc(-c3ccc4ccccc4c3-c3ccccc3)ccc21 ; CP1(=O)c2ccccc2-c2cc(-c3ccc4ccccc4c3-c3ccc(-c4ccccc4)cc3)ccc21] 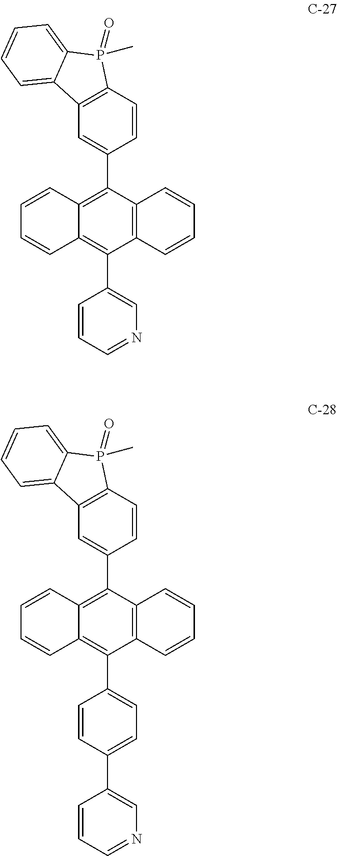 [SMILES: CP1(=O)c2ccccc2-c2cc(-c3c4ccccc4c(-c4cccnc4)c4ccccc34)ccc21 ; CP1(=O)c2ccccc2-c2cc(-c3c4ccccc4c(-c4ccc(-c5cccnc5)cc4)c4ccccc34)ccc21] 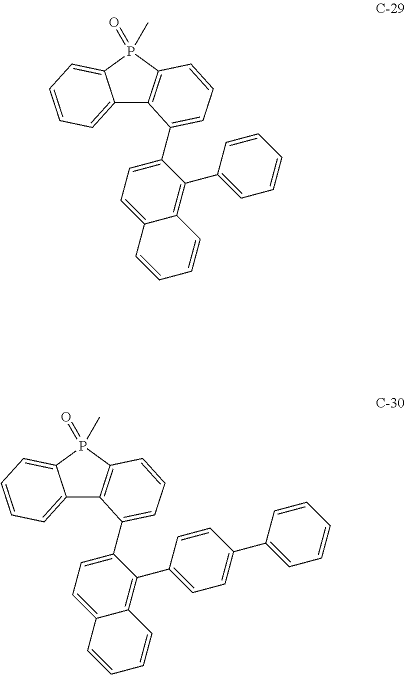 [SMILES: CP1(=O)c2ccccc2-c2c(-c3ccc4ccccc4c3-c3ccccc3)cccc21 ; CP1(=O)c2ccccc2-c2c(-c3ccc4ccccc4c3-c3ccc(-c4ccccc4)cc3)cccc21] 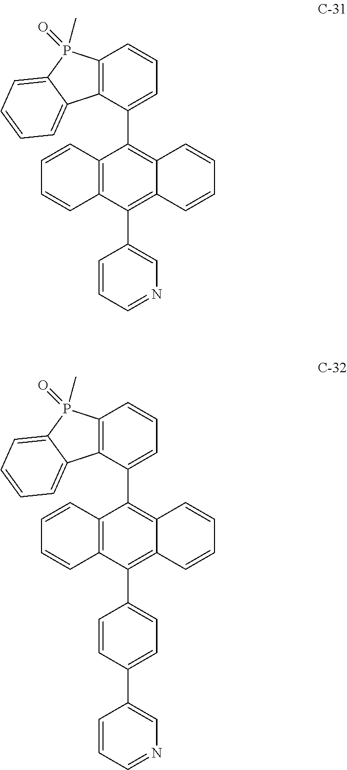 [SMILES: CP1(=O)c2ccccc2-c2c(-c3c4ccccc4c(-c4cccnc4)c4ccccc34)cccc21 ; CP1(=O)c2ccccc2-c2c(-c3c4ccccc4c(-c4ccc(-c5cccnc5)cc4)c4ccccc34)cccc21] 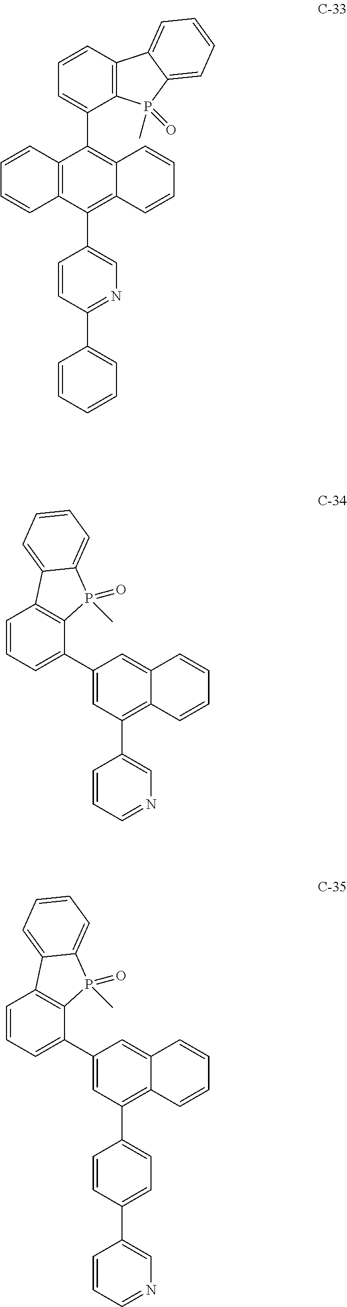 [SMILES: CP1(=O)c2ccccc2-c2cccc(-c3c4ccccc4c(-c4ccc(-c5ccccc5)nc4)c4ccccc34)c21 ; CP1(=O)c2ccccc2-c2cccc(-c3cc(-c4cccnc4)c4ccccc4c3)c21 ; CP1(=O)c2ccccc2-c2cccc(-c3cc(-c4ccc(-c5cccnc5)cc4)c4ccccc4c3)c21] 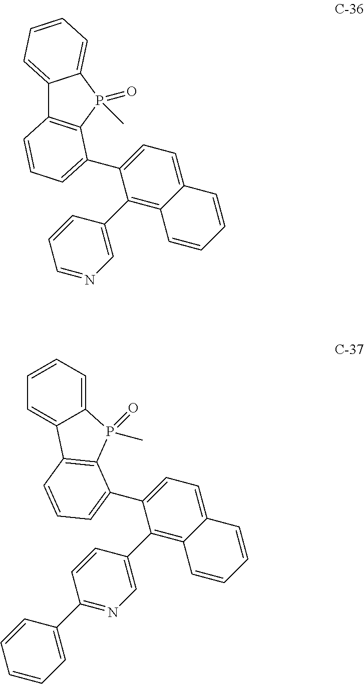 [SMILES: CP1(=O)c2ccccc2-c2cccc(-c3ccc4ccccc4c3-c3cccnc3)c21 ; CP1(=O)c2ccccc2-c2cccc(-c3ccc4ccccc4c3-c3ccc(-c4ccccc4)nc3)c21] 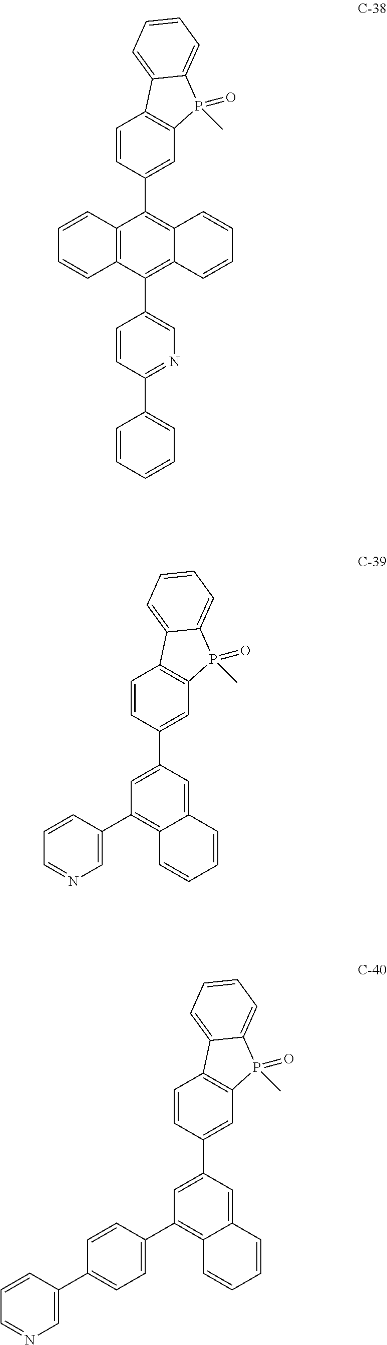 [SMILES: CP1(=O)c2ccccc2-c2ccc(-c3c4ccccc4c(-c4ccc(-c5ccccc5)nc4)c4ccccc34)cc21 ; CP1(=O)c2ccccc2-c2ccc(-c3cc(-c4cccnc4)c4ccccc4c3)cc21 ; CP1(=O)c2ccccc2-c2ccc(-c3cc(-c4ccc(-c5cccnc5)cc4)c4ccccc4c3)cc21] 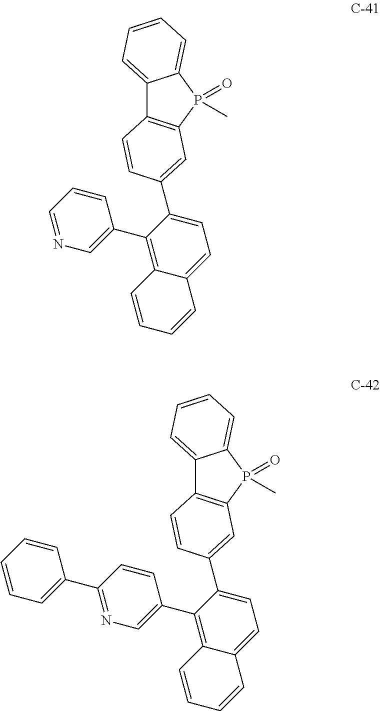 [SMILES: CP1(=O)c2ccccc2-c2ccc(-c3ccc4ccccc4c3-c3cccnc3)cc21 ; CP1(=O)c2ccccc2-c2ccc(-c3ccc4ccccc4c3-c3ccc(-c4ccccc4)nc3)cc21] 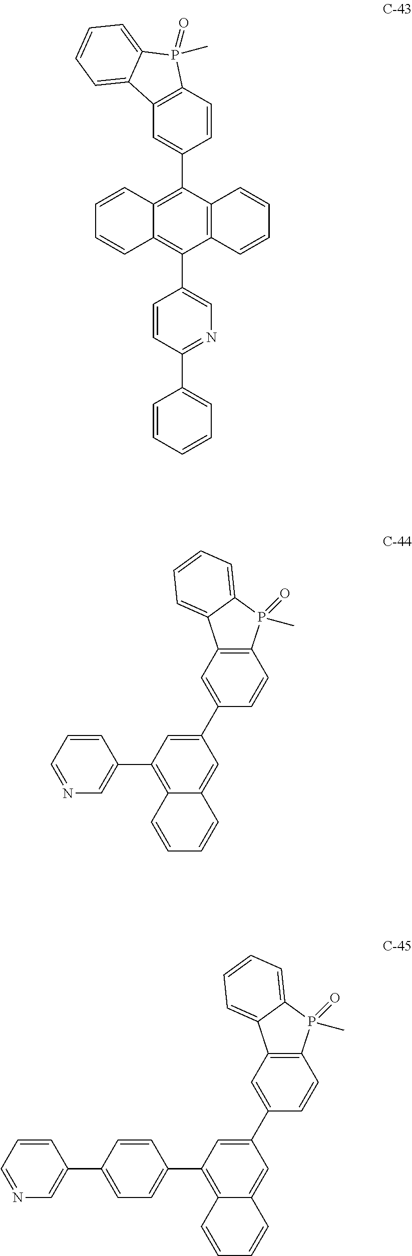 [SMILES: CP1(=O)c2ccccc2-c2cc(-c3c4ccccc4c(-c4ccc(-c5ccccc5)nc4)c4ccccc34)ccc21 ; CP1(=O)c2ccccc2-c2cc(-c3cc(-c4cccnc4)c4ccccc4c3)ccc21 ; CP1(=O)c2ccccc2-c2cc(-c3cc(-c4ccc(-c5cccnc5)cc4)c4ccccc4c3)ccc21] 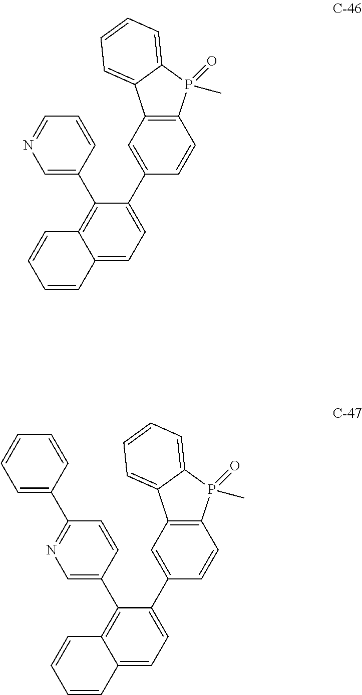 [SMILES: CP1(=O)c2ccccc2-c2cc(-c3ccc4ccccc4c3-c3cccnc3)ccc21 ; CP1(=O)c2ccccc2-c2cc(-c3ccc4ccccc4c3-c3ccc(-c4ccccc4)nc3)ccc21] 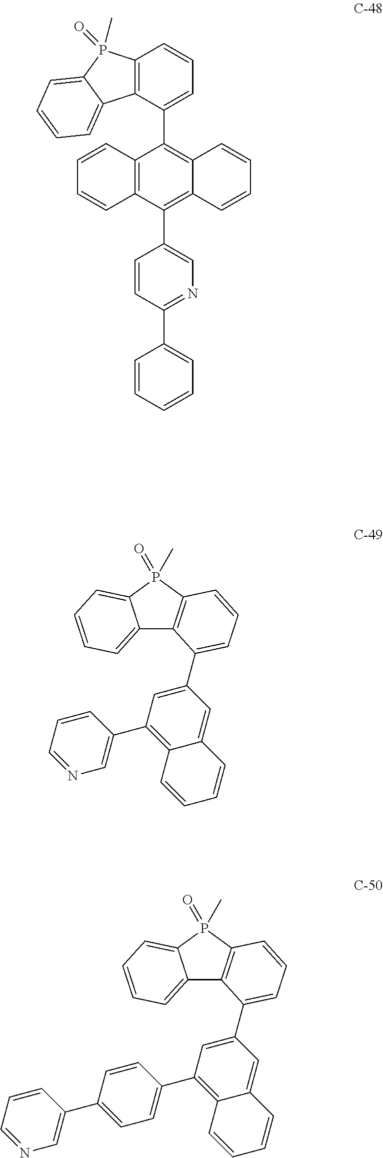 [SMILES: CP1(=O)c2ccccc2-c2c(-c3c4ccccc4c(-c4ccc(-c5ccccc5)nc4)c4ccccc34)cccc21 ; CP1(=O)c2ccccc2-c2c(-c3cc(-c4cccnc4)c4ccccc4c3)cccc21 ; CP1(=O)c2ccccc2-c2c(-c3cc(-c4ccc(-c5cccnc5)cc4)c4ccccc4c3)cccc21] 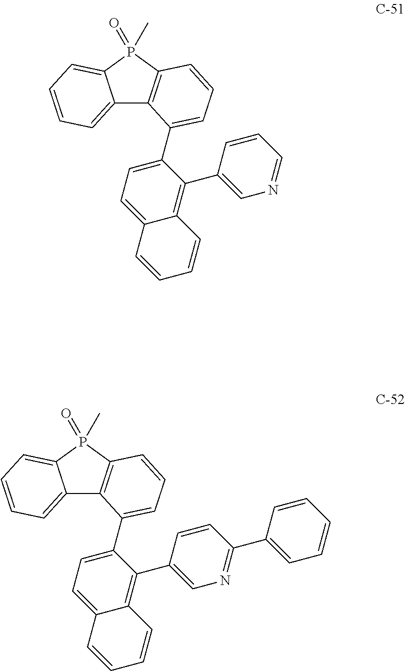 [SMILES: CP1(=O)c2ccccc2-c2c(-c3ccc4ccccc4c3-c3cccnc3)cccc21 ; CP1(=O)c2ccccc2-c2c(-c3ccc4ccccc4c3-c3ccc(-c4ccccc4)nc3)cccc21] 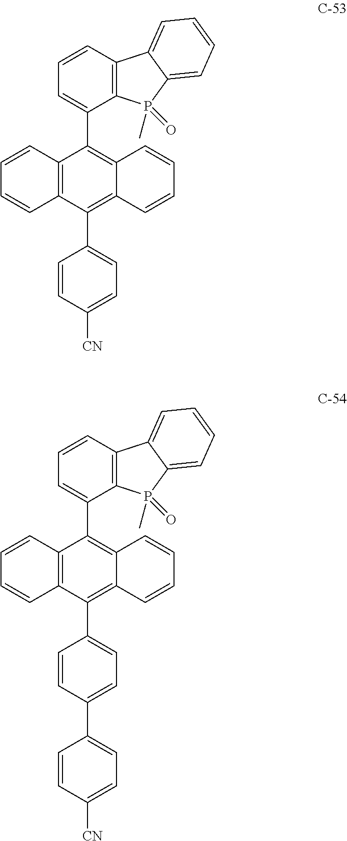 [SMILES: CP1(=O)c2ccccc2-c2cccc(-c3c4ccccc4c(-c4ccc(C#N)cc4)c4ccccc34)c21 ; CP1(=O)c2ccccc2-c2cccc(-c3c4ccccc4c(-c4ccc(-c5ccc(C#N)cc5)cc4)c4ccccc34)c21] 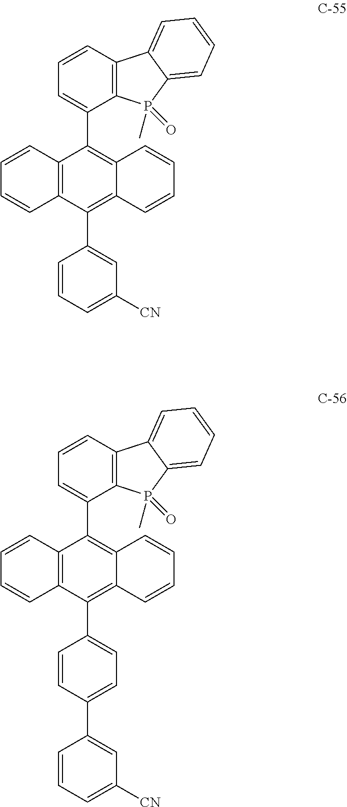 [SMILES: CP1(=O)c2ccccc2-c2cccc(-c3c4ccccc4c(-c4cccc(C#N)c4)c4ccccc34)c21 ; CP1(=O)c2ccccc2-c2cccc(-c3c4ccccc4c(-c4ccc(-c5cccc(C#N)c5)cc4)c4ccccc34)c21] 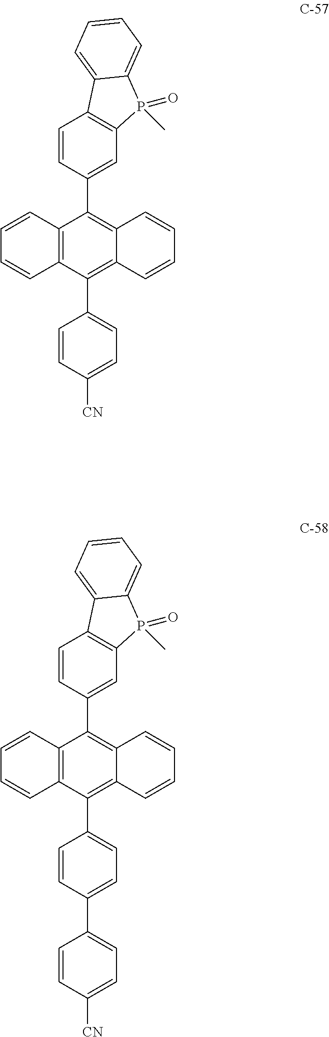 [SMILES: CP1(=O)c2ccccc2-c2ccc(-c3c4ccccc4c(-c4ccc(C#N)cc4)c4ccccc34)cc21 ; CP1(=O)c2ccccc2-c2ccc(-c3c4ccccc4c(-c4ccc(-c5ccc(C#N)cc5)cc4)c4ccccc34)cc21] 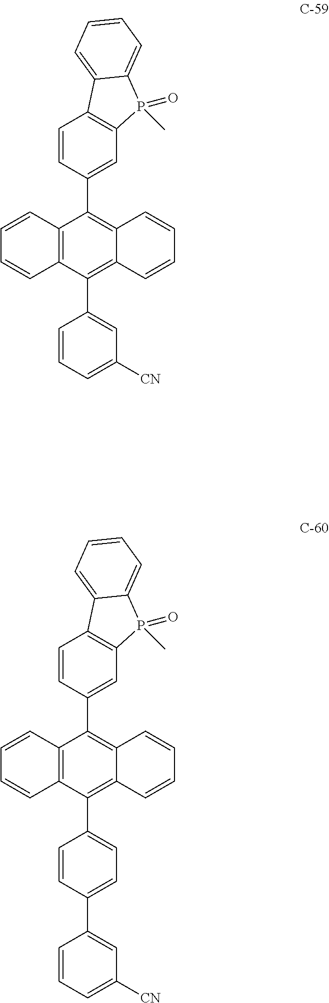 [SMILES: CP1(=O)c2ccccc2-c2ccc(-c3c4ccccc4c(-c4cccc(C#N)c4)c4ccccc34)cc21 ; CP1(=O)c2ccccc2-c2ccc(-c3c4ccccc4c(-c4ccc(-c5cccc(C#N)c5)cc4)c4ccccc34)cc21] 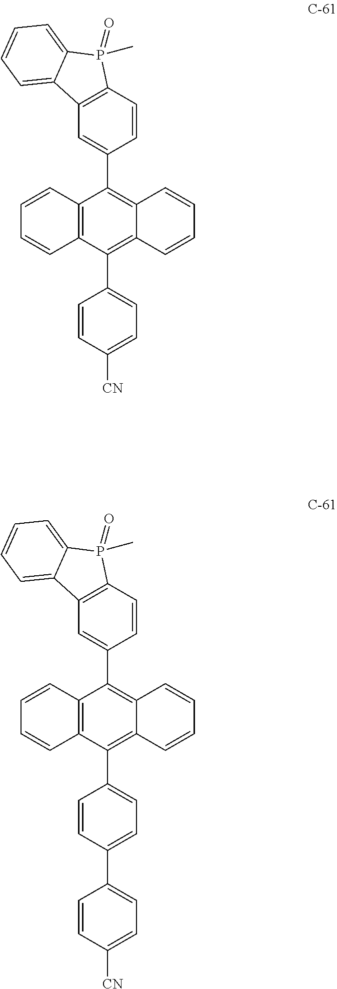 [SMILES: CP1(=O)c2ccccc2-c2cc(-c3c4ccccc4c(-c4ccc(C#N)cc4)c4ccccc34)ccc21 ; CP1(=O)c2ccccc2-c2cc(-c3c4ccccc4c(-c4ccc(-c5ccc(C#N)cc5)cc4)c4ccccc34)ccc21] 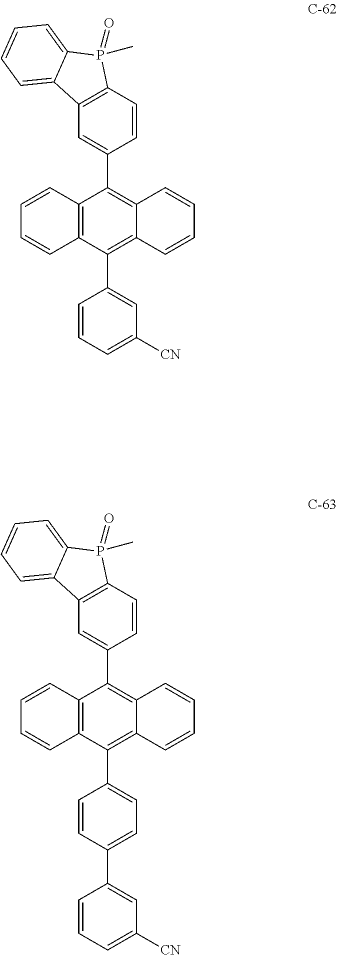 [SMILES: CP1(=O)c2ccccc2-c2cc(-c3c4ccccc4c(-c4cccc(C#N)c4)c4ccccc34)ccc21 ; CP1(=O)c2ccccc2-c2cc(-c3c4ccccc4c(-c4ccc(-c5cccc(C#N)c5)cc4)c4ccccc34)ccc21] 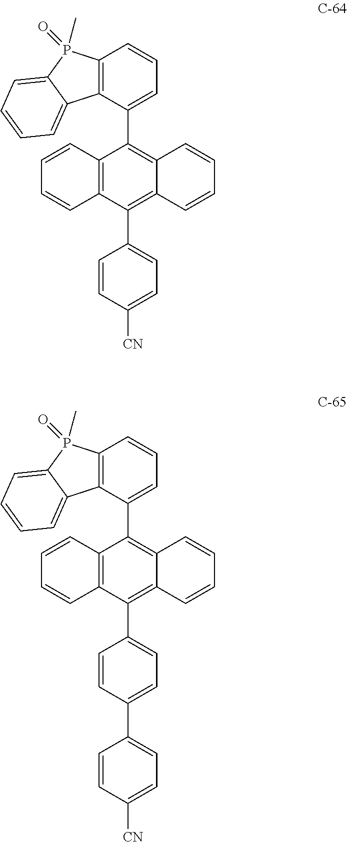 [SMILES: CP1(=O)c2ccccc2-c2c(-c3c4ccccc4c(-c4ccc(C#N)cc4)c4ccccc34)cccc21 ; CP1(=O)c2ccccc2-c2c(-c3c4ccccc4c(-c4ccc(-c5ccc(C#N)cc5)cc4)c4ccccc34)cccc21] 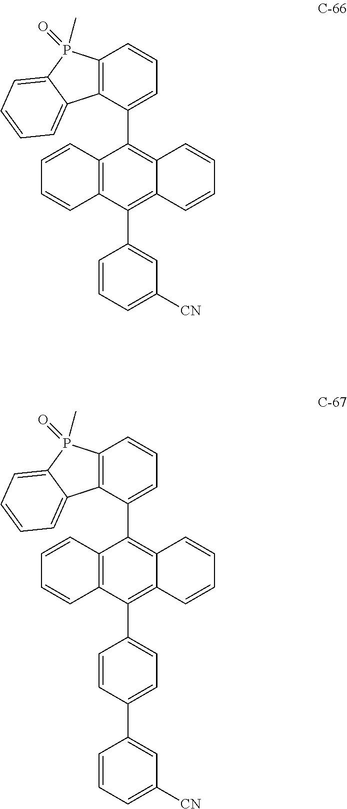 [SMILES: CP1(=O)c2ccccc2-c2c(-c3c4ccccc4c(-c4cccc(C#N)c4)c4ccccc34)cccc21 ; CP1(=O)c2ccccc2-c2c(-c3c4ccccc4c(-c4ccc(-c5cccc(C#N)c5)cc4)c4ccccc34)cccc21] 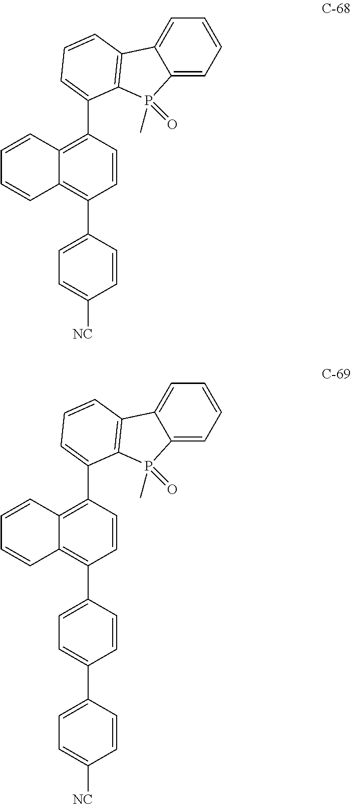 [SMILES: CP1(=O)c2ccccc2-c2cccc(-c3ccc(-c4ccc(C#N)cc4)c4ccccc34)c21 ; CP1(=O)c2ccccc2-c2cccc(-c3ccc(-c4ccc(-c5ccc(C#N)cc5)cc4)c4ccccc34)c21] 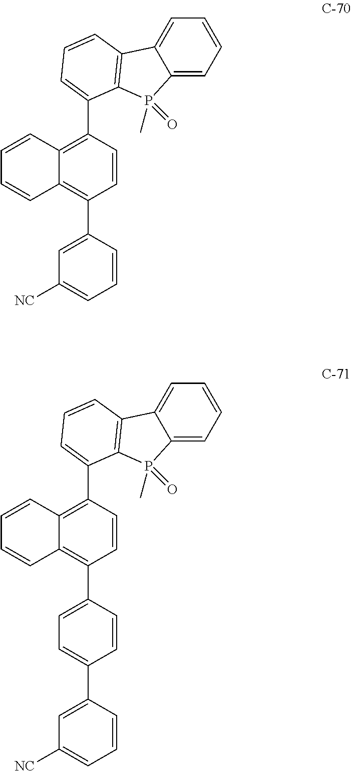 [SMILES: CP1(=O)c2ccccc2-c2cccc(-c3ccc(-c4cccc(C#N)c4)c4ccccc34)c21 ; CP1(=O)c2ccccc2-c2cccc(-c3ccc(-c4ccc(-c5cccc(C#N)c5)cc4)c4ccccc34)c21] 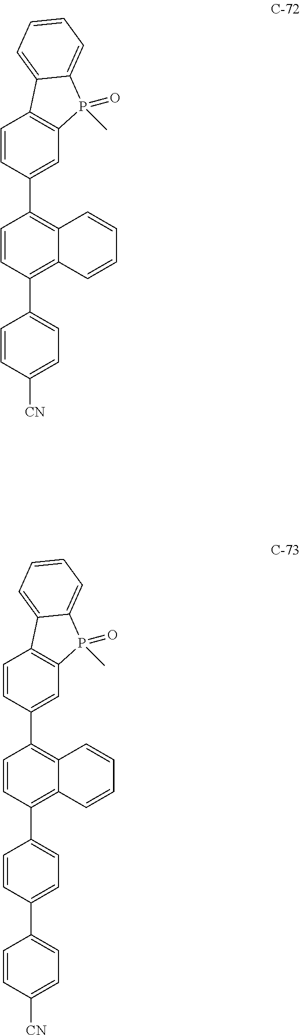 [SMILES: CP1(=O)c2ccccc2-c2ccc(-c3ccc(-c4ccc(C#N)cc4)c4ccccc34)cc21 ; CP1(=O)c2ccccc2-c2ccc(-c3ccc(-c4ccc(-c5ccc(C#N)cc5)cc4)c4ccccc34)cc21] 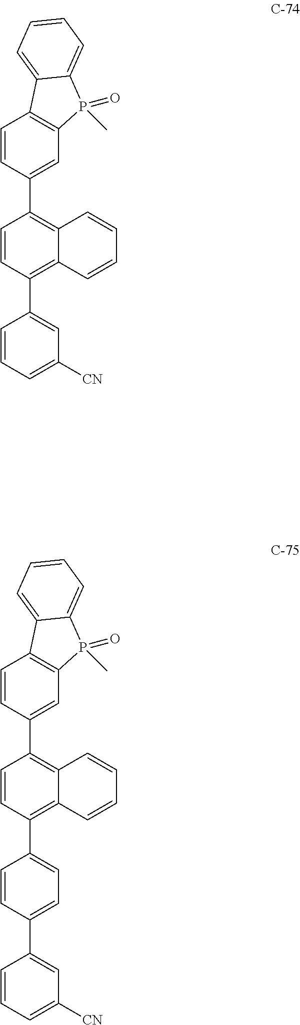 [SMILES: CP1(=O)c2ccccc2-c2ccc(-c3ccc(-c4cccc(C#N)c4)c4ccccc34)cc21 ; CP1(=O)c2ccccc2-c2ccc(-c3ccc(-c4ccc(-c5cccc(C#N)c5)cc4)c4ccccc34)cc21] 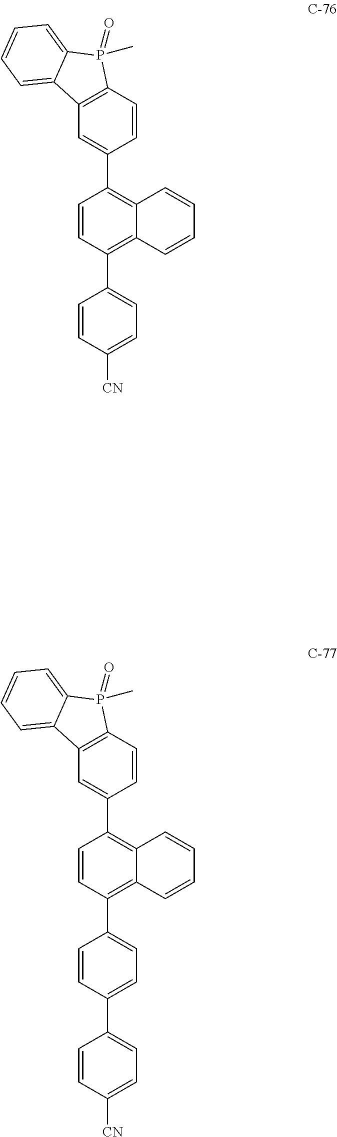 [SMILES: CP1(=O)c2ccccc2-c2cc(-c3ccc(-c4ccc(C#N)cc4)c4ccccc34)ccc21 ; CP1(=O)c2ccccc2-c2cc(-c3ccc(-c4ccc(-c5ccc(C#N)cc5)cc4)c4ccccc34)ccc21] 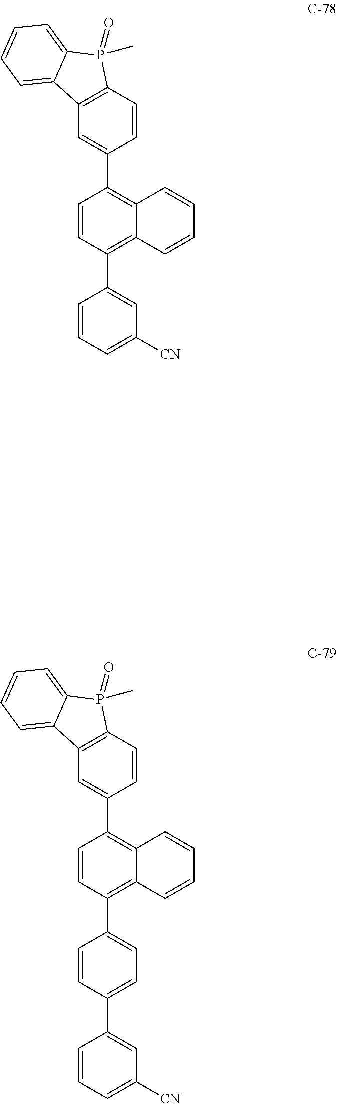 [SMILES: CP1(=O)c2ccccc2-c2cc(-c3ccc(-c4cccc(C#N)c4)c4ccccc34)ccc21 ; CP1(=O)c2ccccc2-c2cc(-c3ccc(-c4ccc(-c5cccc(C#N)c5)cc4)c4ccccc34)ccc21] 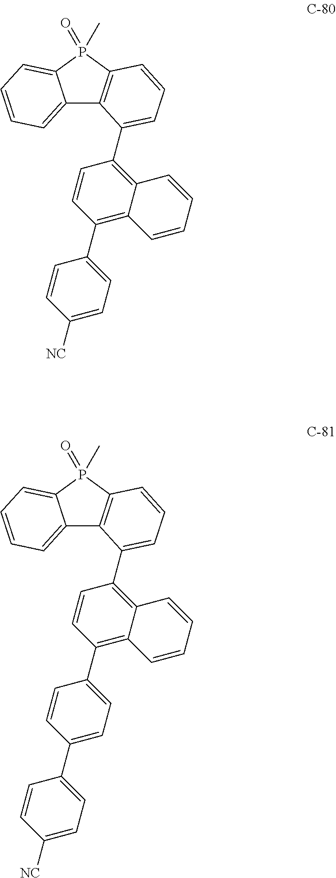 [SMILES: CP1(=O)c2ccccc2-c2c(-c3ccc(-c4ccc(C#N)cc4)c4ccccc34)cccc21 ; CP1(=O)c2ccccc2-c2c(-c3ccc(-c4ccc(-c5ccc(C#N)cc5)cc4)c4ccccc34)cccc21] 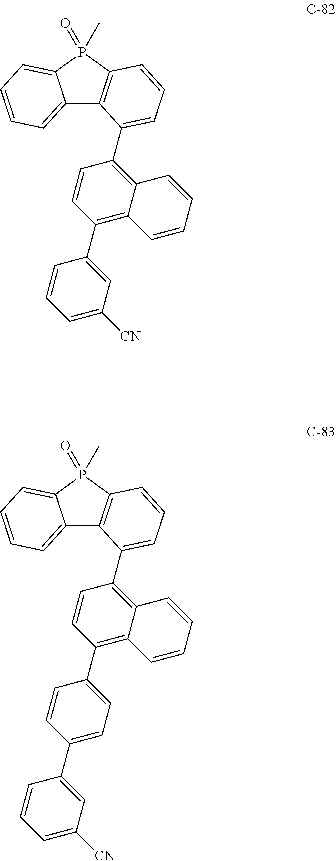 [SMILES: CP1(=O)c2ccccc2-c2c(-c3ccc(-c4cccc(C#N)c4)c4ccccc34)cccc21 ; CP1(=O)c2ccccc2-c2c(-c3ccc(-c4ccc(-c5cccc(C#N)c5)cc4)c4ccccc34)cccc21] 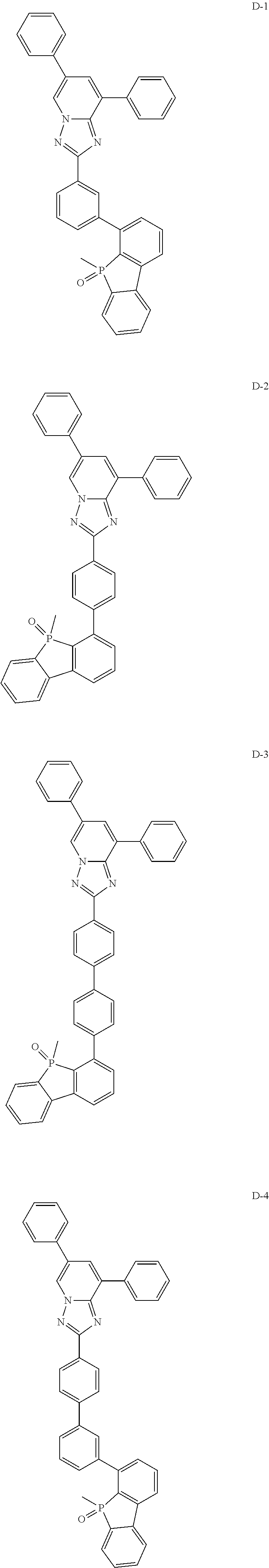 [SMILES: CP1(=O)c2ccccc2-c2cccc(-c3cccc(-c4nc5c(-c6ccccc6)cc(-c6ccccc6)cn5n4)c3)c21 ; CP1(=O)c2ccccc2-c2cccc(-c3ccc(-c4nc5c(-c6ccccc6)cc(-c6ccccc6)cn5n4)cc3)c21 ; CP1(=O)c2ccccc2-c2cccc(-c3ccc(-c4ccc(-c5nc6c(-c7ccccc7)cc(-c7ccccc7)cn6n5)cc4)cc3)c21 ; CP1(=O)c2ccccc2-c2cccc(-c3cccc(-c4ccc(-c5nc6c(-c7ccccc7)cc(-c7ccccc7)cn6n5)cc4)c3)c21] 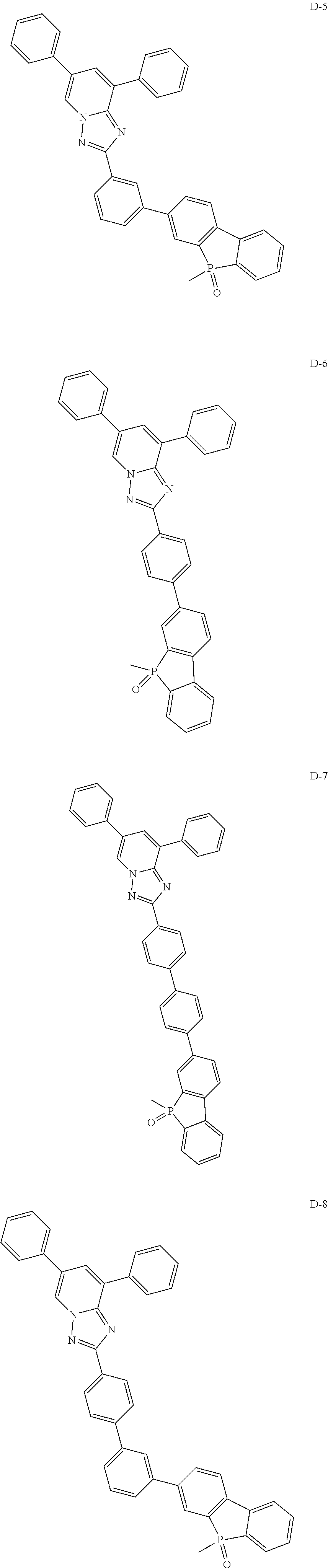 [SMILES: CP1(=O)c2ccccc2-c2ccc(-c3cccc(-c4nc5c(-c6ccccc6)cc(-c6ccccc6)cn5n4)c3)cc21 ; CP1(=O)c2ccccc2-c2ccc(-c3ccc(-c4nc5c(-c6ccccc6)cc(-c6ccccc6)cn5n4)cc3)cc21 ; CP1(=O)c2ccccc2-c2ccc(-c3ccc(-c4ccc(-c5nc6c(-c7ccccc7)cc(-c7ccccc7)cn6n5)cc4)cc3)cc21 ; CP1(=O)c2ccccc2-c2ccc(-c3cccc(-c4ccc(-c5nc6c(-c7ccccc7)cc(-c7ccccc7)cn6n5)cc4)c3)cc21] 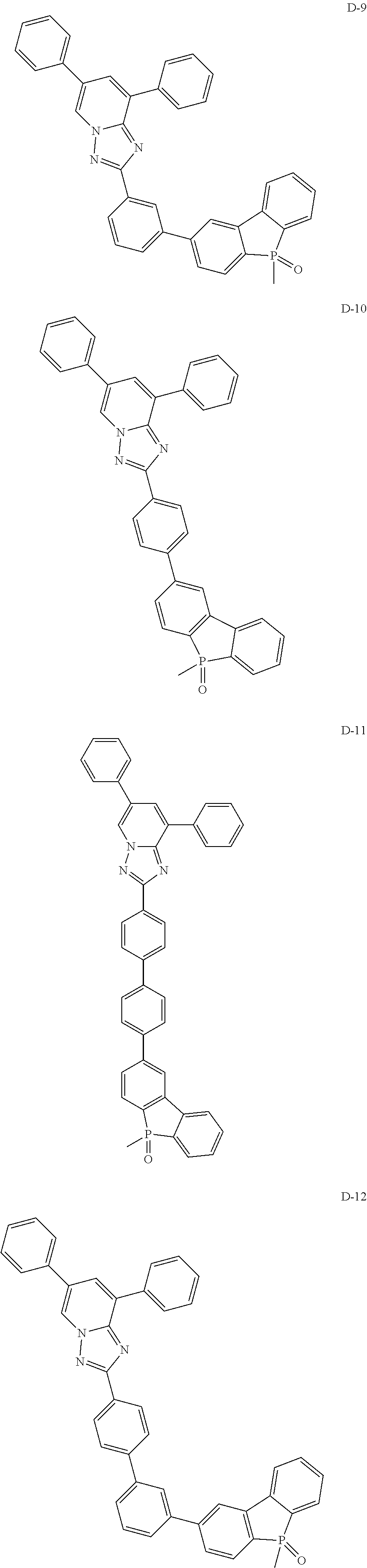 [SMILES: CP1(=O)c2ccccc2-c2cc(-c3cccc(-c4nc5c(-c6ccccc6)cc(-c6ccccc6)cn5n4)c3)ccc21 ; CP1(=O)c2ccccc2-c2cc(-c3ccc(-c4nc5c(-c6ccccc6)cc(-c6ccccc6)cn5n4)cc3)ccc21 ; CP1(=O)c2ccccc2-c2cc(-c3ccc(-c4ccc(-c5nc6c(-c7ccccc7)cc(-c7ccccc7)cn6n5)cc4)cc3)ccc21 ; CP1(=O)c2ccccc2-c2cc(-c3cccc(-c4ccc(-c5nc6c(-c7ccccc7)cc(-c7ccccc7)cn6n5)cc4)c3)ccc21] 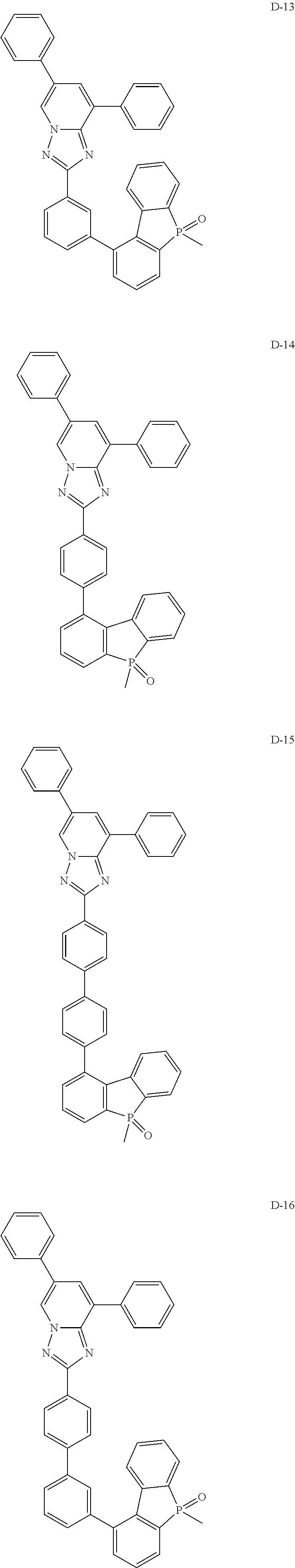 [SMILES: CP1(=O)c2ccccc2-c2c(-c3cccc(-c4nc5c(-c6ccccc6)cc(-c6ccccc6)cn5n4)c3)cccc21 ; CP1(=O)c2ccccc2-c2c(-c3ccc(-c4nc5c(-c6ccccc6)cc(-c6ccccc6)cn5n4)cc3)cccc21 ; CP1(=O)c2ccccc2-c2c(-c3ccc(-c4ccc(-c5nc6c(-c7ccccc7)cc(-c7ccccc7)cn6n5)cc4)cc3)cccc21 ; CP1(=O)c2ccccc2-c2c(-c3cccc(-c4ccc(-c5nc6c(-c7ccccc7)cc(-c7ccccc7)cn6n5)cc4)c3)cccc21] 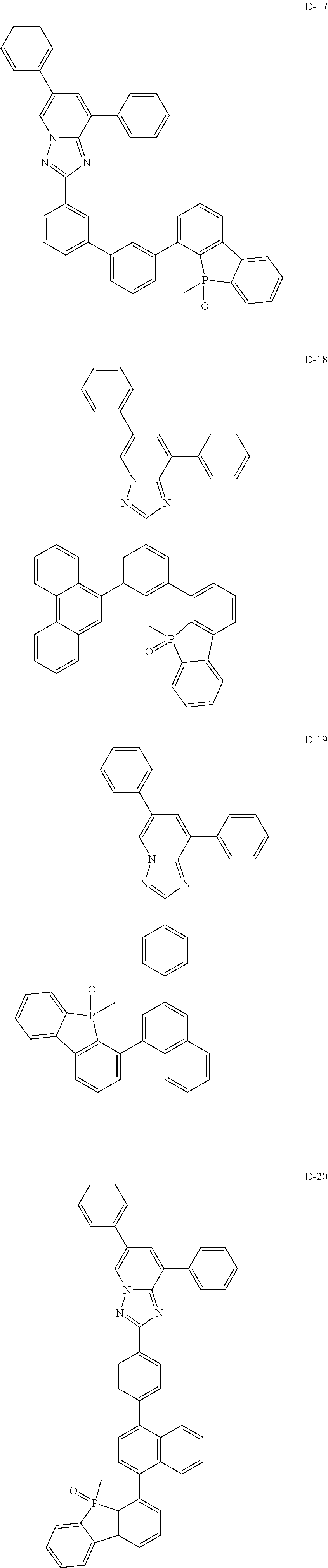 [SMILES: CP1(=O)c2ccccc2-c2cccc(-c3cccc(-c4cccc(-c5nc6c(-c7ccccc7)cc(-c7ccccc7)cn6n5)c4)c3)c21 ; CP1(=O)c2ccccc2-c2cccc(-c3cc(-c4nc5c(-c6ccccc6)cc(-c6ccccc6)cn5n4)cc(-c4cc5ccccc5c5ccccc45)c3)c21 ; CP1(=O)c2ccccc2-c2cccc(-c3cc(-c4ccc(-c5nc6c(-c7ccccc7)cc(-c7ccccc7)cn6n5)cc4)cc4ccccc34)c21 ; CP1(=O)c2ccccc2-c2cccc(-c3ccc(-c4ccc(-c5nc6c(-c7ccccc7)cc(-c7ccccc7)cn6n5)cc4)c4ccccc34)c21] 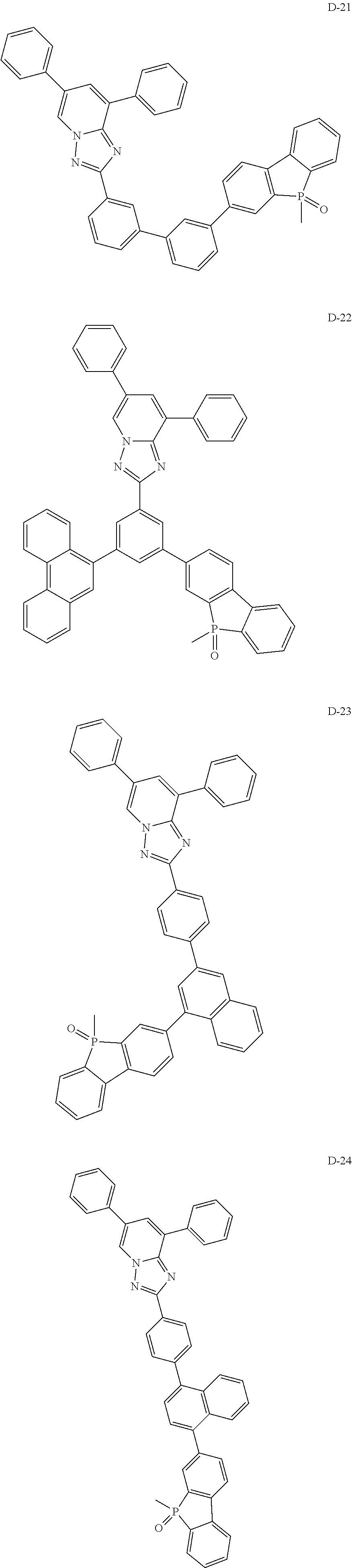 [SMILES: CP1(=O)c2ccccc2-c2ccc(-c3cccc(-c4cccc(-c5nc6c(-c7ccccc7)cc(-c7ccccc7)cn6n5)c4)c3)cc21 ; CP1(=O)c2ccccc2-c2ccc(-c3cc(-c4nc5c(-c6ccccc6)cc(-c6ccccc6)cn5n4)cc(-c4cc5ccccc5c5ccccc45)c3)cc21 ; CP1(=O)c2ccccc2-c2ccc(-c3cc(-c4ccc(-c5nc6c(-c7ccccc7)cc(-c7ccccc7)cn6n5)cc4)cc4ccccc34)cc21 ; CP1(=O)c2ccccc2-c2ccc(-c3ccc(-c4ccc(-c5nc6c(-c7ccccc7)cc(-c7ccccc7)cn6n5)cc4)c4ccccc34)cc21] 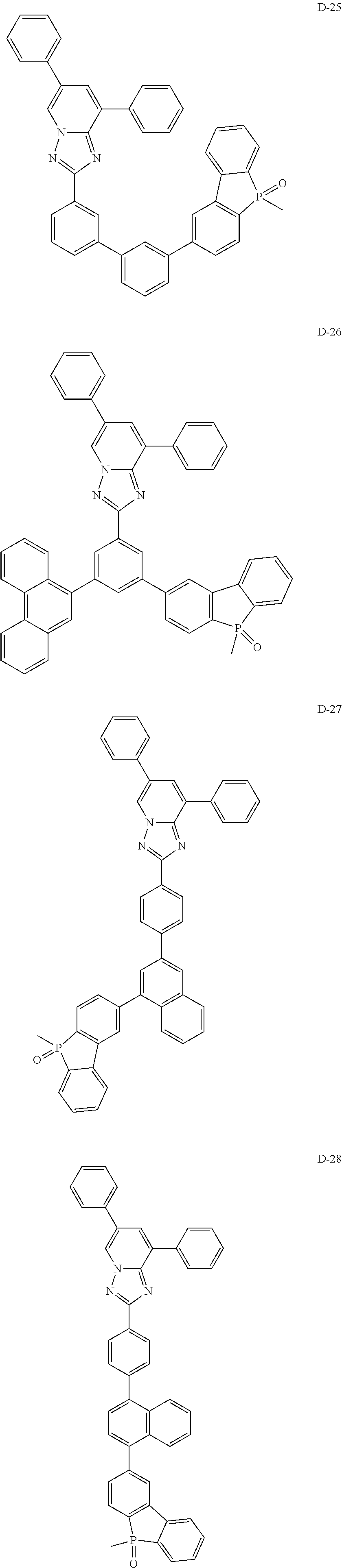 [SMILES: CP1(=O)c2ccccc2-c2cc(-c3cccc(-c4cccc(-c5nc6c(-c7ccccc7)cc(-c7ccccc7)cn6n5)c4)c3)ccc21 ; CP1(=O)c2ccccc2-c2cc(-c3cc(-c4nc5c(-c6ccccc6)cc(-c6ccccc6)cn5n4)cc(-c4cc5ccccc5c5ccccc45)c3)ccc21 ; CP1(=O)c2ccccc2-c2cc(-c3cc(-c4ccc(-c5nc6c(-c7ccccc7)cc(-c7ccccc7)cn6n5)cc4)cc4ccccc34)ccc21 ; CP1(=O)c2ccccc2-c2cc(-c3ccc(-c4ccc(-c5nc6c(-c7ccccc7)cc(-c7ccccc7)cn6n5)cc4)c4ccccc34)ccc21] 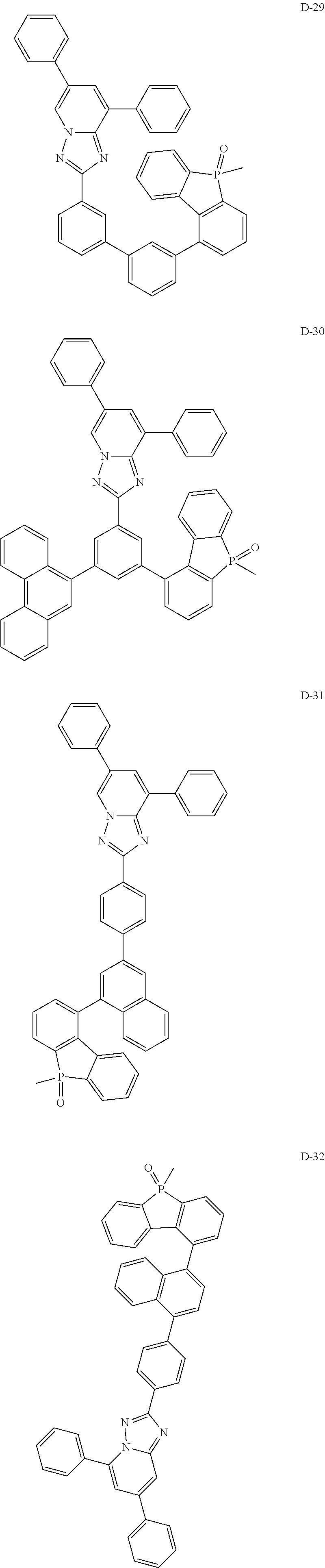 [SMILES: CP1(=O)c2ccccc2-c2c(-c3cccc(-c4cccc(-c5nc6c(-c7ccccc7)cc(-c7ccccc7)cn6n5)c4)c3)cccc21 ; CP1(=O)c2ccccc2-c2c(-c3cc(-c4nc5c(-c6ccccc6)cc(-c6ccccc6)cn5n4)cc(-c4cc5ccccc5c5ccccc45)c3)cccc21 ; CP1(=O)c2ccccc2-c2c(-c3cc(-c4ccc(-c5nc6c(-c7ccccc7)cc(-c7ccccc7)cn6n5)cc4)cc4ccccc34)cccc21 ; CP1(=O)c2ccccc2-c2c(-c3ccc(-c4ccc(-c5nc6cc(-c7ccccc7)cc(-c7ccccc7)n6n5)cc4)c4ccccc34)cccc21] 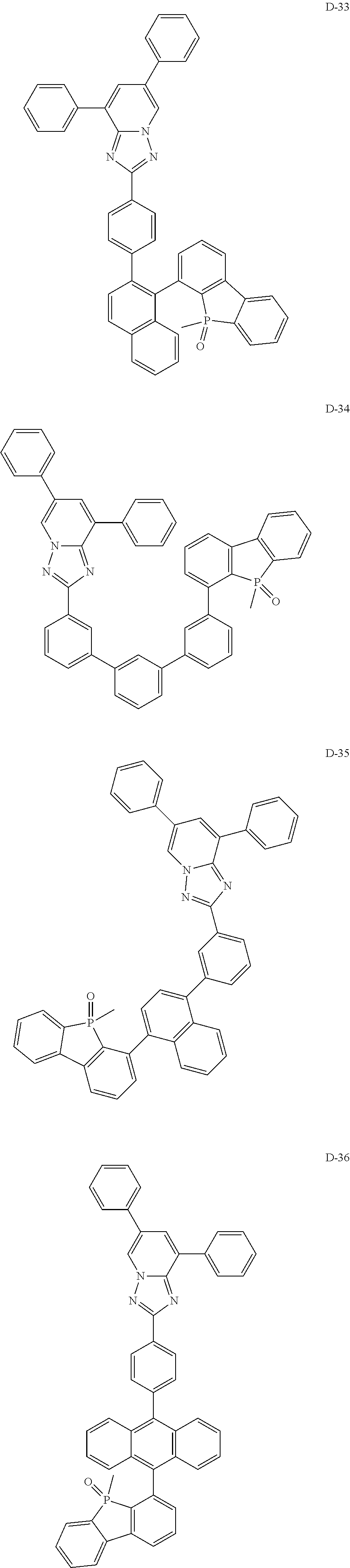 [SMILES: CP1(=O)c2ccccc2-c2cccc(-c3c(-c4ccc(-c5nc6c(-c7ccccc7)cc(-c7ccccc7)cn6n5)cc4)ccc4ccccc34)c21 ; CP1(=O)c2ccccc2-c2cccc(-c3cccc(-c4cccc(-c5cccc(-c6nc7c(-c8ccccc8)cc(-c8ccccc8)cn7n6)c5)c4)c3)c21 ; CP1(=O)c2ccccc2-c2cccc(-c3ccc(-c4cccc(-c5nc6c(-c7ccccc7)cc(-c7ccccc7)cn6n5)c4)c4ccccc34)c21 ; CP1(=O)c2ccccc2-c2cccc(-c3c4ccccc4c(-c4ccc(-c5nc6c(-c7ccccc7)cc(-c7ccccc7)cn6n5)cc4)c4ccccc34)c21] 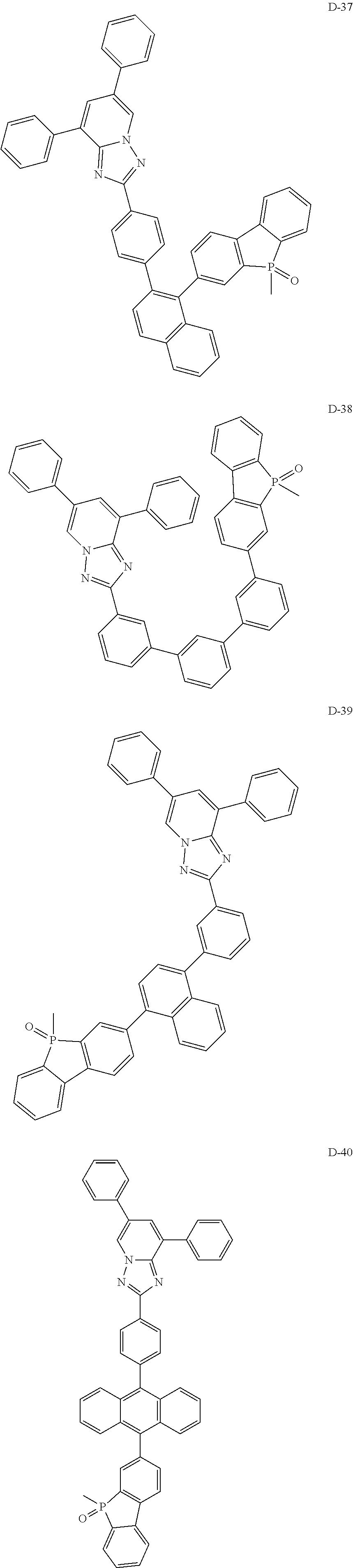 [SMILES: CP1(=O)c2ccccc2-c2ccc(-c3c(-c4ccc(-c5nc6c(-c7ccccc7)cc(-c7ccccc7)cn6n5)cc4)ccc4ccccc34)cc21 ; CP1(=O)c2ccccc2-c2ccc(-c3cccc(-c4cccc(-c5cccc(-c6nc7c(-c8ccccc8)cc(-c8ccccc8)cn7n6)c5)c4)c3)cc21 ; CP1(=O)c2ccccc2-c2ccc(-c3ccc(-c4cccc(-c5nc6c(-c7ccccc7)cc(-c7ccccc7)cn6n5)c4)c4ccccc34)cc21 ; CP1(=O)c2ccccc2-c2ccc(-c3c4ccccc4c(-c4ccc(-c5nc6c(-c7ccccc7)cc(-c7ccccc7)cn6n5)cc4)c4ccccc34)cc21] 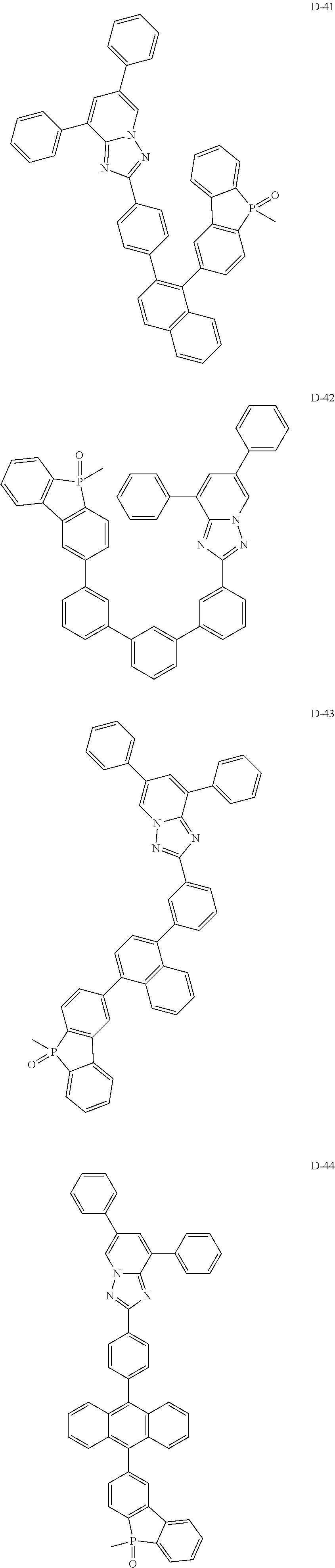 [SMILES: CP1(=O)c2ccccc2-c2cc(-c3c(-c4ccc(-c5nc6c(-c7ccccc7)cc(-c7ccccc7)cn6n5)cc4)ccc4ccccc34)ccc21 ; CP1(=O)c2ccccc2-c2cc(-c3cccc(-c4cccc(-c5cccc(-c6nc7c(-c8ccccc8)cc(-c8ccccc8)cn7n6)c5)c4)c3)ccc21 ; CP1(=O)c2ccccc2-c2cc(-c3ccc(-c4cccc(-c5nc6c(-c7ccccc7)cc(-c7ccccc7)cn6n5)c4)c4ccccc34)ccc21 ; CP1(=O)c2ccccc2-c2cc(-c3c4ccccc4c(-c4ccc(-c5nc6c(-c7ccccc7)cc(-c7ccccc7)cn6n5)cc4)c4ccccc34)ccc21] 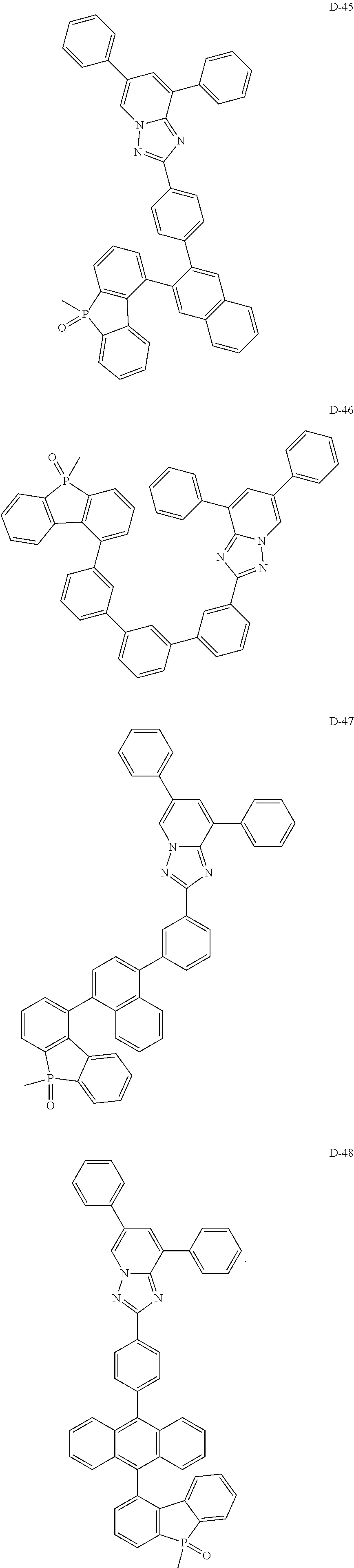 [SMILES: CP1(=O)c2ccccc2-c2c(-c3cc4ccccc4cc3-c3ccc(-c4nc5c(-c6ccccc6)cc(-c6ccccc6)cn5n4)cc3)cccc21 ; CP1(=O)c2ccccc2-c2c(-c3cccc(-c4cccc(-c5cccc(-c6nc7c(-c8ccccc8)cc(-c8ccccc8)cn7n6)c5)c4)c3)cccc21 ; CP1(=O)c2ccccc2-c2c(-c3ccc(-c4cccc(-c5nc6c(-c7ccccc7)cc(-c7ccccc7)cn6n5)c4)c4ccccc34)cccc21 ; CP1(=O)c2ccccc2-c2c(-c3c4ccccc4c(-c4ccc(-c5nc6c(-c7ccccc7)cc(-c7ccccc7)cn6n5)cc4)c4ccccc34)cccc21]
